(19) United States
(12) Patent Application Publication
(10) Pub. No.: US 2024/0276880 A1
(43) Pub. Date: Aug. 15, 2024

(54) LIGHT EMITTING ELEMENT AND FUSED POLYCYCLIC COMPOUND FOR THE LIGHT EMITTING ELEMENT

(71) Applicant: Samsung Display Co., Ltd., Yongin-si (KR)

(72) Inventors: MUN-KI SIM, Yongin-si (KR); TAEIL KIM, Yongin-si (KR); SUN YOUNG PAK, Yongin-si (KR); JUNHA PARK, Yongin-si (KR); Kyoung SUNWOO, Yongin-si, Gyeonggi-do (KR); MinJae SUNG, Yongin-si, Gyeonggi-do (KR); CHANSEOK OH, Yongin-si (KR)

(73) Assignee: Samsung Display Co., Ltd., Yongin-si (KR)

(21) Appl. No.: 18/480,744

(22) Filed: Oct. 4, 2023

(30) Foreign Application Priority Data
Jan. 9, 2023 (KR) 10-2023-0003116

(51) Int. Cl. H10K 85/60; C09K 11/06

(52) U.S. Cl. CPC H10K 85/658; C09K 11/06; H10K 85/6572; H10K 85/6574; H10K 2101/20

(57) ABSTRACT

Embodiments provide a light emitting element that includes a first electrode, a second electrode facing the first electrode, and an emission layer which is disposed between the first electrode and the second electrode and includes a first compound represented by Formula 1, which is explained in the specification.

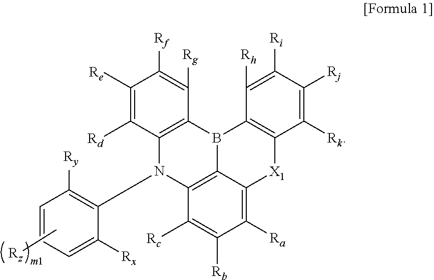

### CROSS-REFERENCE TO RELATED APPLICATION(S)

This application claims priority to and benefits of Korean Patent Application No. 10-2023-0003116 under 35 U.S.C. § 119, filed on Jan. 9, 2023, in the Korean Intellectual Property Office, the entire contents of which are incorporated herein by reference.

### BACKGROUND

### 1. Technical Field

The disclosure relates to a light emitting element and a fused polycyclic compound used in the light emitting element.

### 2. Description of the Related Art

Active development continues for an organic electroluminescence display device as an image display device. In contrast to liquid crystal display devices and the like, an organic electroluminescence display is a so-called self-luminescent display device in which holes and electrons respectively injected from a first electrode and a second electrode recombine in an emission layer, so that a luminescent material including an organic compound in the emission layer emits light to achieve display.

In the application of an organic electroluminescence device to a display device, there is a demand for an organic electroluminescence device having a low driving voltage, high luminous efficiency, and a long service life, and continuous development is required on materials for an organic electroluminescence device that are capable of stably achieving such characteristics.

In order to implement a highly efficient organic electroluminescence device, technologies pertaining to phosphorescence emission using triplet state energy or to fluorescence emission using triplet-triplet annihilation (TTA) in which singlet excitons are generated by the collision of triplet excitons are being developed. Development is currently directed to thermally activated delayed fluorescence (TADF) materials which use delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element in which luminous efficiency and an element service life are improved.

The disclosure also provides a fused polycyclic compound capable of improving luminous efficiency and element service life of a light emitting element.

An embodiment provides a light emitting element which may include a first electrode, a second electrode facing the first electrode, and an emission layer disposed between the first electrode and the second electrode, wherein the emission layer includes a first compound represented by Formula 1:

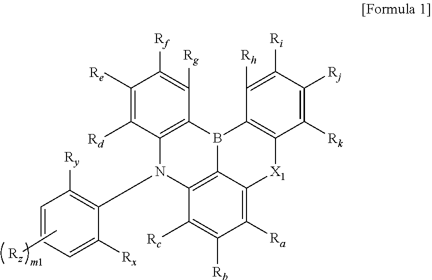

In Formula 1, X₁ may be O, S, or N(R₁); R₁ may be a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring; Rₐ to Rₖ and R_{z} may each independently be a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring; Rₓ and R_{y} may each independently be a substituted or unsubstituted aryl group having 6 to 30 ring-forming carbon atoms, a substituted or unsubstituted heteroaryl group having 2 to 30 ring-forming carbon atoms, or a group represented by Formula 2; m1 may be an integer from 0 to 3; and at least one of Rₓ and R_{y} may each independently be a group represented by Formula 2:

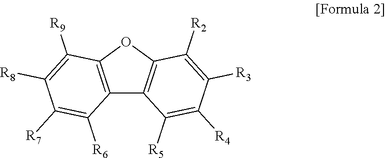

In Formula 2, R₂ to R₉ may each independently be a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; except that R₂ or R₅ is a position linked to Formula 1.

In an embodiment, the light emitting element may further include a hole transport region disposed between the first electrode and the emission layer, and an electron transport region disposed between the emission layer and the second electrode.

In an embodiment, the emission layer may emit delayed fluorescence.

In an embodiment, the emission layer may emit light having a central wavelength in a range of about 430 nm to about 490 nm.

In an embodiment, the group represented by Formula 2 may be represented by Formula 2-1 or Formula 2-2:

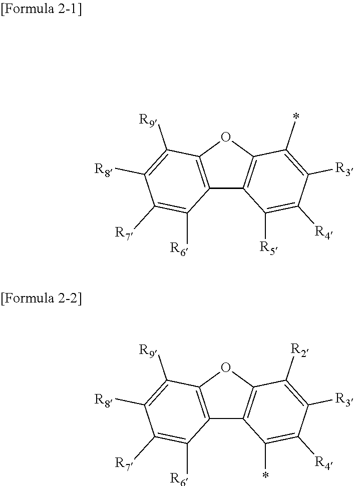

In Formula 2-1 and Formula 2-2, R₂′ to R₉′ may each independently be a hydrogen atom, a deuterium atom, or a substituted or unsubstituted phenyl group; and -* is a position linked to Formula 1.

In an embodiment, the first compound may be represented by one of Formula 1-1 to Formula 1-3:

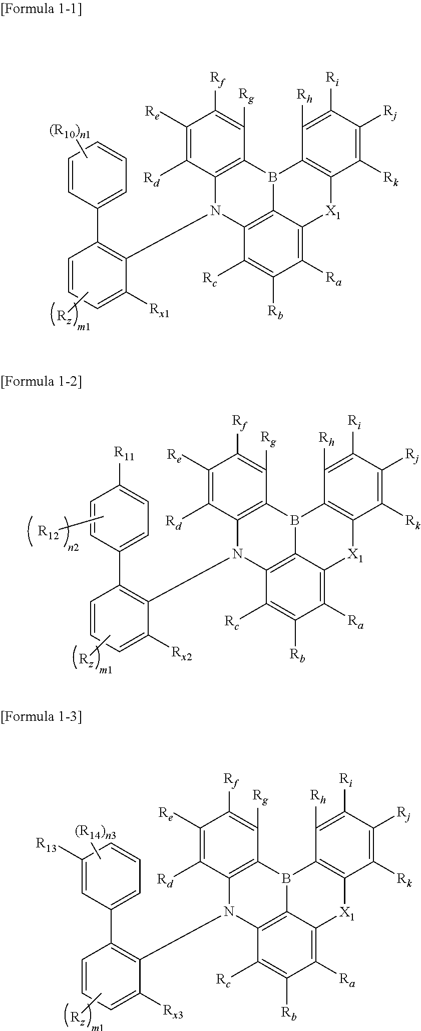

In Formula 1-1 to Formula 1-3, Rₓ₁ to Rₓ₃ may each independently be a group represented by Formula 2; R₁₀, R₁₂, and R₁₄ may each independently be a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; R₁₁ and R₁₃ may each independently be a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; n1 may be an integer from 0 to 5; and n2 and n3 may each independently be an integer from 0 to 4.

In Formula 1-1 to Formula 1-3, Rₐ to Rₖ, R_{z}, m1, and X₁ are the same as defined in Formula 1.

In an embodiment, the first compound may be represented by Formula 3:

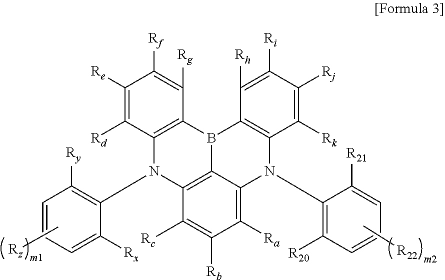

In Formula 3, R₂₀ and R₂₁ may each independently be a substituted or unsubstituted aryl group having 6 to 30 ring-forming carbon atoms, a substituted or unsubstituted heteroaryl group having 2 to 30 ring-forming carbon atoms, or a group represented by Formula 2; R₂₂ may be a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring; and m2 may be an integer from 0 to 3.

In Formula 3, Rₐ to Rₖ, Rₓ, R_{y}, R_{z}, and m1 are the same as defined in Formula 1.

In an embodiment, in Formula 3, Rₓ and R₂₀ may be the same; and R_{y} and R₂₁ may be the same.

In an embodiment, the first compound may be represented by one of Formula 4-1 to Formula 4-3:

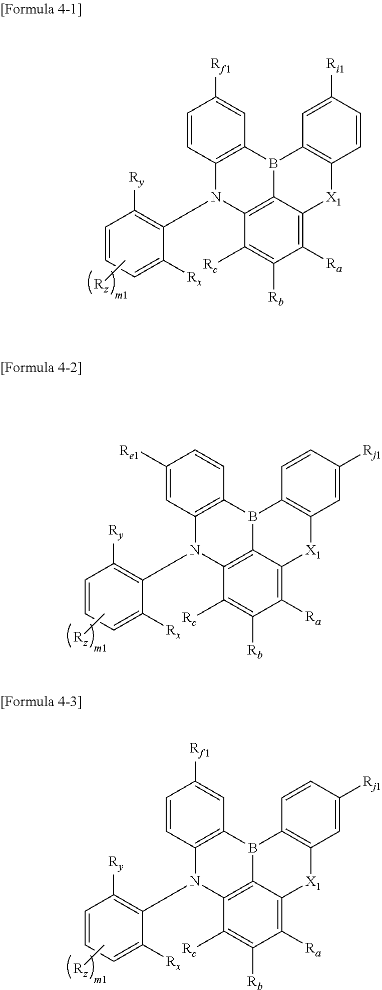

In Formula 4-1 to Formula 4-3, Rₑ₁, R_{f1}, Rᵢ₁, and Rⱼ₁ may each independently be a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 4-1 to Formula 4-3, Rₐ to R_{c}, X₁, Rₓ, R_{y}, R_{z}, and m1 are the same as defined in Formula 1.

In an embodiment, in Formula 1, R_{d} to Rₖ may each independently be a hydrogen atom, a deuterium atom, a substituted or unsubstituted phenyl group, a substituted or unsubstituted diphenylamine group, a substituted or unsubstituted carbazole group, a substituted or unsubstituted phenoxazine group, or a substituted or unsubstituted indolocarbazole group.

In an embodiment, the first compound may be represented by Formula 5:

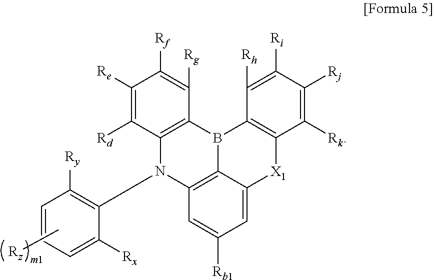

In Formula 5 above, Rei may be a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 5, R_{d} to Rₖ, X₁, Rₓ, R_{y}, R_{z}, and m1 are the same as defined in Formula 1.

In an embodiment, the first compound may be represented by Formula 6:

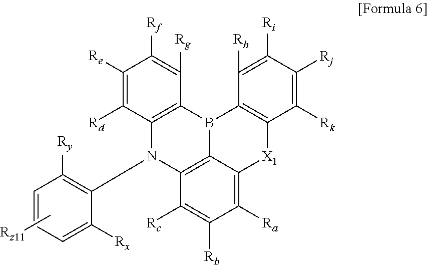

In Formula 6, R_{z11} may be a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 6 above, Rₐ to Rₖ, X₁, Rₓ, and R_{y} are the same as defined in Formula 1.

In an embodiment, the first compound may include at least compound selected from Compound Group 1, which is explained below.

In an embodiment, the emission layer may further include at least one of a second compound represented by Formula HT-1 and a third compound represented by Formula ET-1:

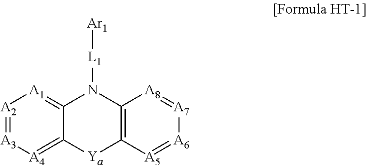

In Formula HT-1, A₁ to A₈ may each independently be N or C(R₄₁); L₁ may be a direct linkage, a substituted or unsubstituted arylene group having 6 to 30 ring-forming carbon atoms, or a substituted or unsubstituted heteroarylene group having 2 to 30 ring-forming carbon atoms; Yₐ may be a direct linkage, C(R₄₂)(R₄₃), or Si(R₄₄)(R₄₅); Ar₁ may be a substituted or unsubstituted aryl group having 6 to 30 ring-forming carbon atoms or a substituted or unsubstituted heteroaryl group having 2 to 30 ring-forming carbon atoms; and R₄₁ to R₄₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

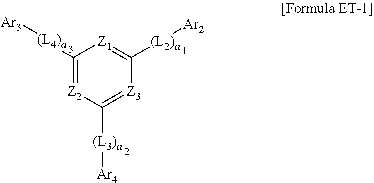

In Formula ET-1, at least one of Z₁ to Z₃ may each be N; the remainder of Z₁ to Z₃ may each independently be C(R₄₆); R₄₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; a₁ to a₃ may each independently be an integer from 0 to 10; L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms; when a₁ is 2 or greater, L₂ may be a substituted or unsubstituted arylene group having 6 to 30 ring-forming carbon atoms or a substituted or unsubstituted heteroarylene group having 2 to 30 ring-forming carbon atoms; when a₂ is 2 or greater, L₃ may be a substituted or unsubstituted arylene group having 6 to 30 ring-forming carbon atoms or a substituted or unsubstituted heteroarylene group having 2 to 30 ring-forming carbon atoms; when a₃ is 2 or greater, L₄ may be a substituted or unsubstituted arylene group having 6 to 30 ring-forming carbon atoms or a substituted or unsubstituted heteroarylene group having 2 to 30 ring-forming carbon atoms; and Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, the emission layer may further include a fourth compound represented by Formula D-1:

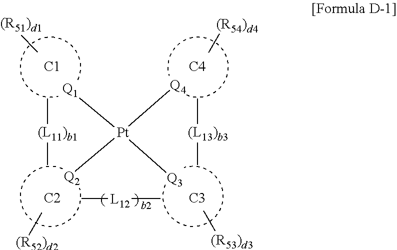

In Formula D-1, Q₁ to Q₄ may each independently be C or N; C1 to C4 may each independently be a substituted or unsubstituted hydrocarbon ring having 5 to 30 ring-forming carbon atoms or a substituted or unsubstituted heterocycle having 2 to 30 ring-forming carbon atoms; L₁₁ to L₁₃ may each independently be a direct linkage, *—O—*, *—S—*,

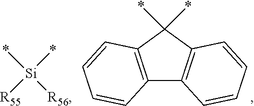

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; b1 to b3 may each independently be 0 or 1; R₅₁ to R₅₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; and d1 to d4 may each independently be an integer from 0 to 4.

An embodiment provides a fused polycyclic compound which may be represented by Formula 1, which is explained herein.

In an embodiment, the group represented by Formula 2 may be represented by Formula 2-1 or Formula 2-2, which are explained herein.

In an embodiment, the fused polycyclic compound represented by Formula 1 may be represented by one of Formula 1-1 to Formula 1-3, which are explained herein.

In an embodiment, the fused polycyclic compound represented by Formula 1 may be represented by Formula 3, which is explained herein.

In an embodiment, the fused polycyclic compound may be selected from Compound Group 1, which is explained below.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a display apparatus according to an embodiment;

FIG. 8 is a schematic cross-sectional view of a display apparatus according to an embodiment;

FIG. 9 is a schematic cross-sectional view of a display apparatus according to an embodiment;

FIG. 10 is a schematic cross-sectional view of a display apparatus according to an embodiment; and

FIG. 11 is a schematic perspective view of a vehicle in which display apparatuses are disposed according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group including at least one carbon-carbon double bond in the middle or a terminus of an alkyl group having 2 or more carbon atoms. An alkenyl group may be linear or branched. The number of carbon atoms in the alkenyl group is not particularly limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group including at least one carbon-carbon triple bond in the middle or a terminus of an alkyl group having 2 or more carbon atoms. An alkynyl group may be linear or branched. The number of carbon atoms in an alkynyl group is not particularly limited, but may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15.

Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

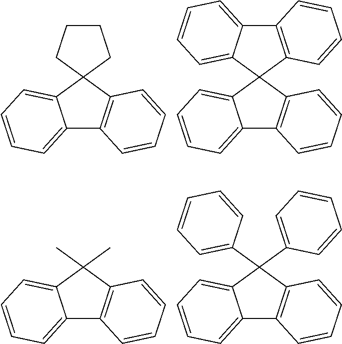

In the specification, a heterocyclic group may be any functional group or substituent derived from a ring including at least one of B, O, N, P, Si, S, and Se as a heteroatom. A heterocyclic group may be an aliphatic heterocyclic group or an aromatic heterocyclic group.

An aromatic heterocyclic group may be a heteroaryl group. An aliphatic heterocycle and an aromatic heterocycle may each independently be monocyclic or polycyclic.

In the specification, a heterocyclic group may include at least one of B, O, N, P, Si, S, and Se as a heteroatom. If a heterocyclic group includes two or more heteroatoms, the two or more heteroatoms may be the same as or different from each other. A heterocyclic group may be monocyclic or polycyclic. A heterocyclic group may be a heteroaryl group. The number of ring-forming carbon atoms in a heterocyclic group may be 2 to 30, 2 to 20, or 2 to 10.

In the specification, an aliphatic heterocyclic group may include at least one of B, O, N, P, Si, S, and Se as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may include at least one of B, O, N, P, Si, S, and Se as a heteroatom. If a heteroaryl group includes two or more heteroatoms, the two or more heteroatoms may be the same as or different from each other. A heteroaryl group may be monocyclic or polycyclic. The number of ring-forming carbon atoms in a heteroaryl group may be 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. The above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, but may be 1 to 40, 1 to 30, or 1 to 20. For example, a carbonyl group may have one of the following structures, but embodiments are not limited thereto.

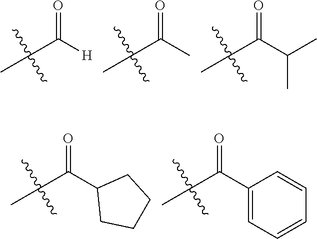

In the specification, the number of carbon atoms in a sulfinyl group or a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not particularly limited, but may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not particularly limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols

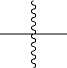

and -* each represent a bond to a neighboring atom in a corresponding formula or moiety.

Hereinafter, embodiments will be described with reference to the accompanying drawings.

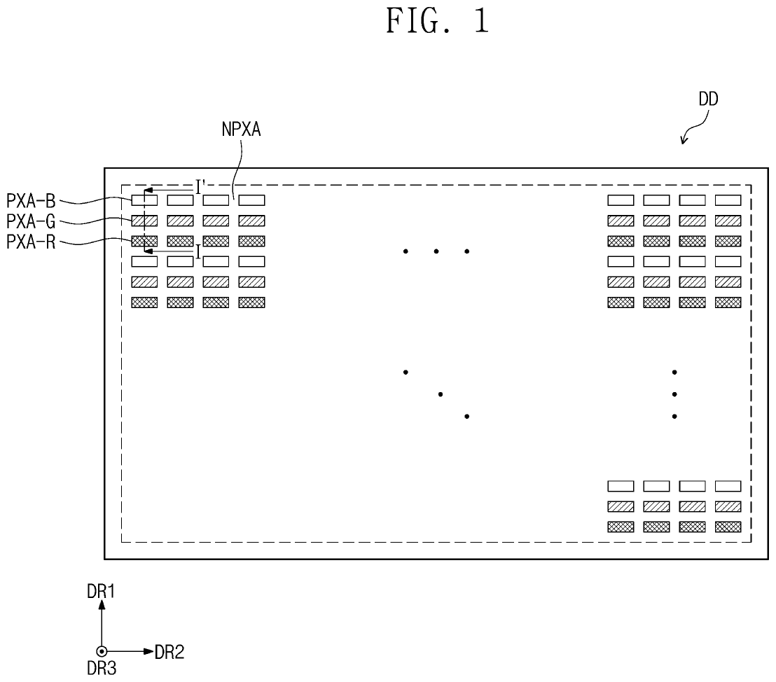

FIG. 1 is a schematic plan view of a display apparatus DD according to an embodiment.

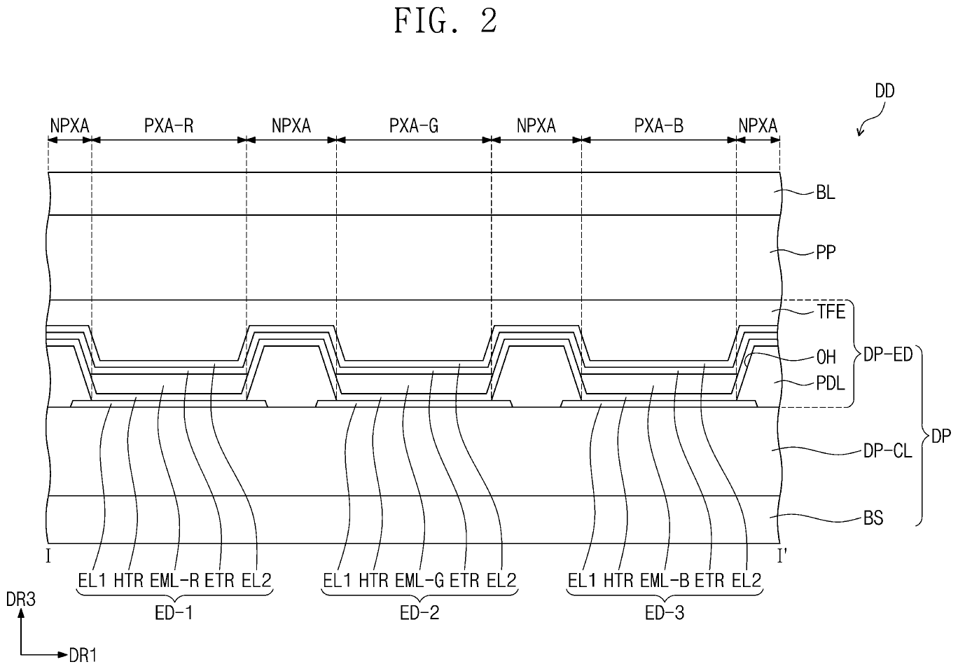

FIG. 2 is a schematic cross-sectional view of a display apparatus DD according to an embodiment. FIG. 2 is a schematic cross-sectional view illustrating a part taken along line I-I′ in FIG. 1.

The display apparatus DD may include a display panel DP and an optical layer PP disposed on the display panel DP. The display panel DP includes light emitting elements ED-1, ED-2, and ED-3. The display apparatus DD may include multiples of each of the light emitting elements ED-1, ED-2, and ED-3. The optical layer PP may be disposed on the display panel DP to control light that is reflected at the display panel DP from an external light.

The optical layer PP may include, for example, a polarization layer or a color filter layer.

Although not shown in the drawings, in an embodiment, the optical layer PP may be omitted from the display apparatus DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display apparatus DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display device layer DP-ED. The display device layer DP-ED may include a pixel defining film PDL, light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display device layer DP-ED.

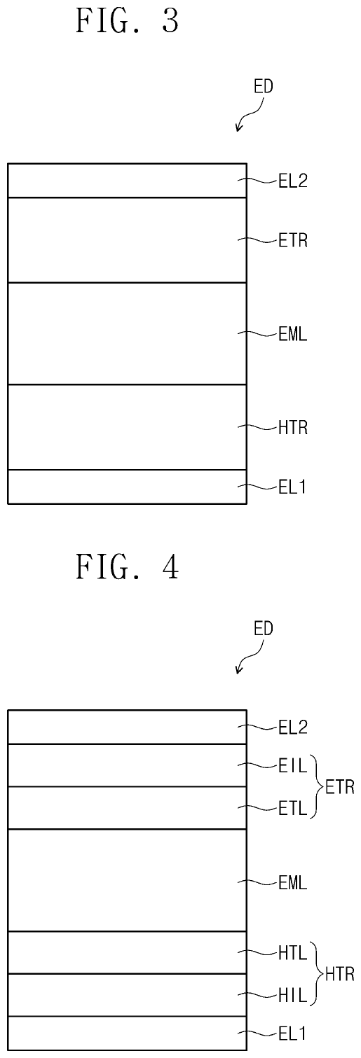

The light emitting elements ED-1, ED-2, and ED-3 may each have a structure of a light emitting element ED of an embodiment according to any of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for all of the light emitting elements ED-1, ED-2, and ED-3. However, embodiments are not limited thereto. Although not illustrated in FIG. 2, in an embodiment, the hole transport region HTR and the electron transport region ETR may each be provided by being patterned in the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3 may each be provided by being patterned through an inkjet printing method.

The encapsulation layer TFE may cover the light emitting elements ED-1, ED-2, and ED-3. The encapsulation layer TFE may seal the display device layer DP-ED. The encapsulation layer TFE may be a thin film encapsulation layer. The encapsulation layer TFE may be formed of a single layer or of multiple layers. The encapsulation layer TFE may include at least one insulation layer. In an embodiment, the encapsulation layer TFE may include at least one inorganic film (hereinafter, an encapsulation-inorganic film). In an embodiment, the encapsulation layer TFE may include at least one organic film (hereinafter, an encapsulation-organic film) and at least one encapsulation-inorganic film.

The encapsulation-inorganic film protects the display device layer DP-ED from moisture and/or oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display apparatus DD may include non-light emitting regions NPXA and light emitting regions PXA-R, PXA-G, and PXA-B. The light emitting regions PXA-R, PXA-G, and PXA-B may each be a region that emits light generated from each of light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining film PDL. The non-light emitting regions NPXA may be areas between the adjacent light emitting areas PXA-R, PXA-G, and PXA-B, and which correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in openings OH defined by the pixel defining film PDL and separated from each other.

The light emitting regions PXA-R, PXA-G, and PXA-B may be arranged into groups according to the color of light generated from the light emitting elements ED-1, ED-2, and ED-3. In the display apparatus DD according to an embodiment illustrated in FIGS. 1 and 2, three light emitting regions PXA-R, PXA-G, and PXA-B, which respectively emit red light, green light, and blue light, are illustrated as an example. For example, the display apparatus DD may include a red light emitting region PXA-R, a green light emitting region PXA-G, and a blue light emitting region PXA-B, which are distinct from one another.

In the display apparatus DD according to an embodiment, the light emitting elements ED-1, ED-2 and ED-3 may emit light having wavelengths that are different from each other.

For example, in an embodiment, the display apparatus DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display apparatus DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range, or at least one light emitting element may emit light in a wavelength range that is different from the remainder. For example, the first to third light emitting elements ED-1, ED-2, and ED-3 may each emit blue light.

The light emitting regions PXA-R, PXA-G, and PXA-B in the display apparatus DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be alternately arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R, PXA-G, and PXA-B may be different in size from each other, according to a wavelength range of emitted light. The areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics that are required for the display apparatus DD. For example, the light emitting regions PXA-R, PXA-G, and PXA-B may be arranged in a pentile configuration (such as PENTILE™) or in a diamond configuration (such as Diamond Pixel™).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIG. 3 to FIG. 6 are each a schematic cross-sectional view of a light emitting device according to an embodiment. The light emitting element ED according to an embodiment may include a first electrode EL1, a hole transport region HTR, an emission layer EML, an electron transport region ETR, and a second electrode EL2.

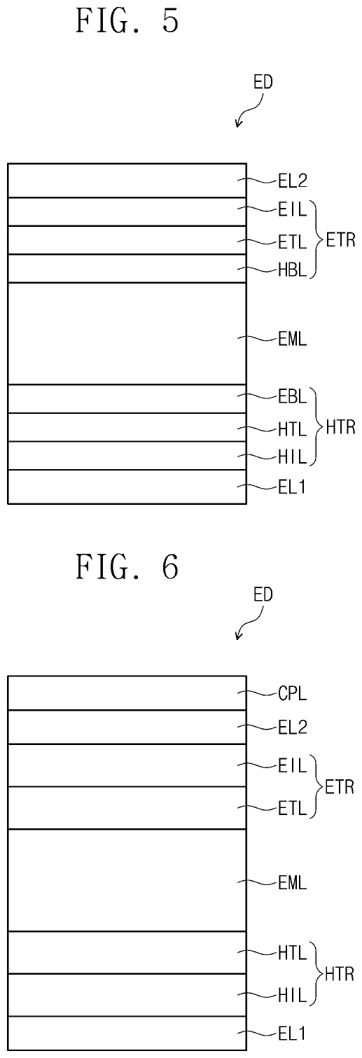

In comparison to FIG. 3, FIG. 4 is a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 is a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 is a schematic cross-sectional view of a light emitting element ED according to an embodiment that includes a capping layer CPL disposed on a second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. In an embodiment, the first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), or an electron blocking layer EBL. A thickness of the hole transport region HTR may be, for example, in a range of about 50 Å to about 15,000 Å.

The hole transport region HTR may be a layer consisting of a single material, a layer including different materials, or a structure including multiple layers including different materials.

In embodiments, the hole transport region HTR may have a single layer structure of a hole injection layer HIL or a hole transport layer HTL, or may have a single layer structure formed of a hole injection material and a hole transport material. In embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1:

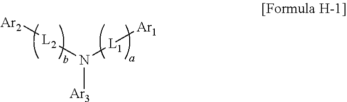

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ groups or multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, a compound represented by Formula H-1 may be a monoamine compound. In an embodiment, the compound represented by Formula H-1 may be a diamine compound in which at least one of Ar₁ to Ar₃ includes an amine group as a substituent. In another embodiment, the compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and the compound represented by Formula H-1 is not limited to Compound Group H:

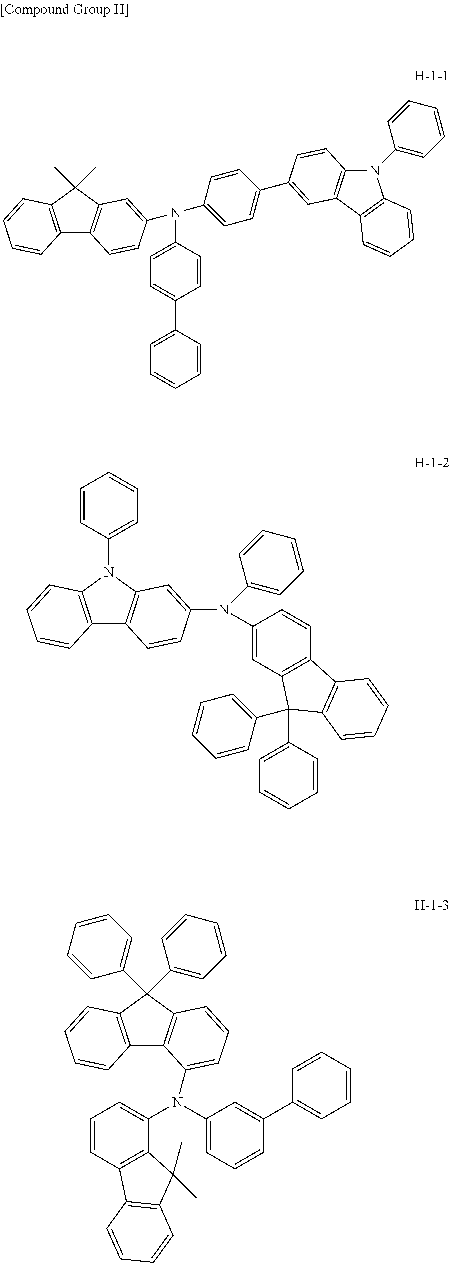 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

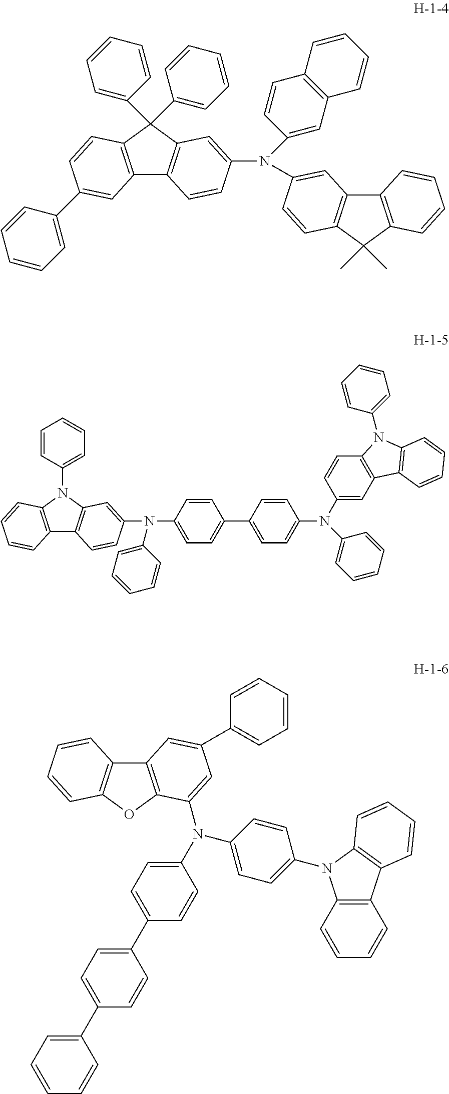 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

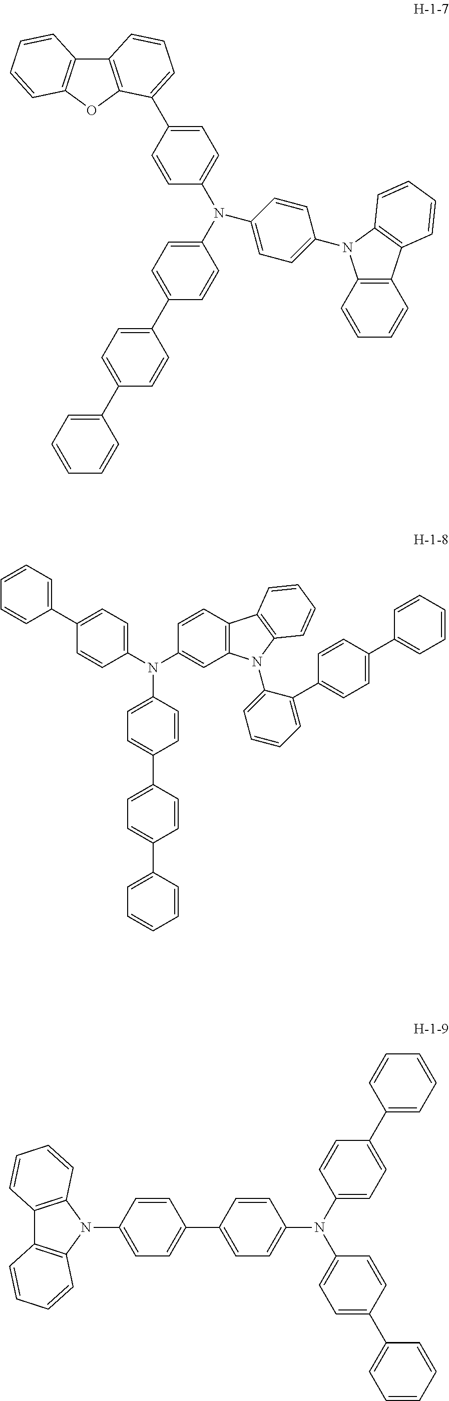 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

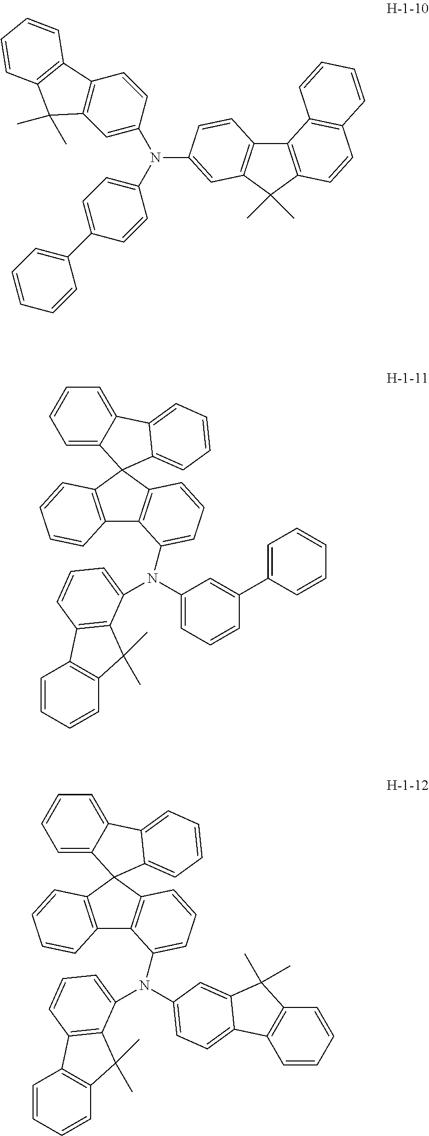 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

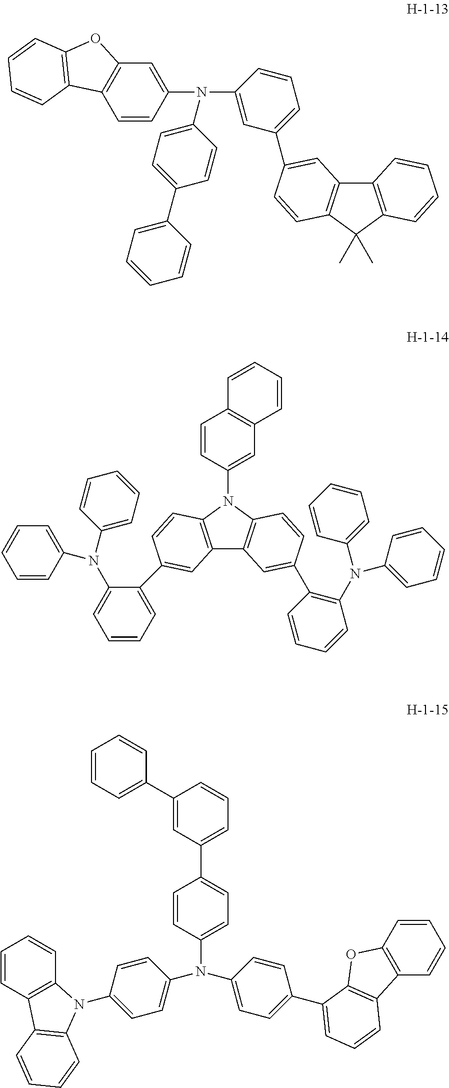 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

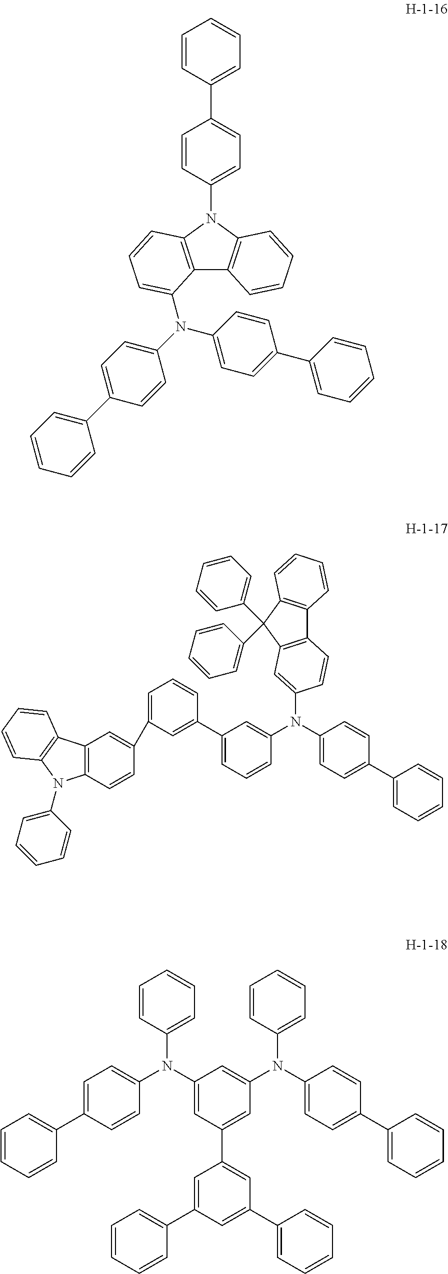 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

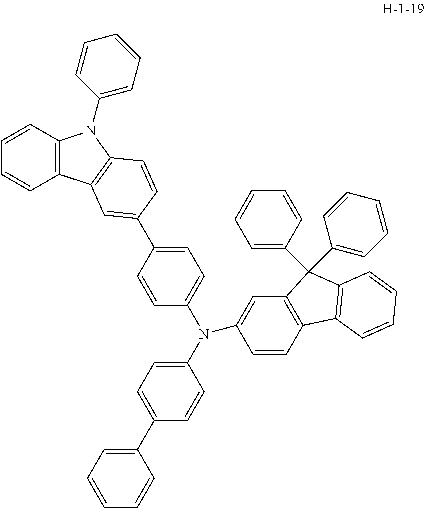 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, or an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 250 Å to about 1,000 Å.

When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, and a cyano group-containing compound, but embodiments are not limited thereto.

For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) or an electron blocking layer EBL, in addition to a hole injection layer HIL and a hole transport layer HTL. The buffer layer (not shown) may compensate for a resonance distance according to a wavelength of light emitted from the emission layer EML and may thus increase light emission efficiency. A material that may be included in the hole transport region HTR may be used as a material to be included in the buffer layer (not shown).

The electron blocking layer EBL may prevent the injection of electrons from an electron transport region ETR to a hole transport region HTR.

The emission layer EML may be provided on the hole transport region HTR. The emission layer EML may have a thickness in a range of about 100 Å to about 1,000 Å. For example, the emission layer EML may have a thickness in a range of about 100 Å to about 300 Å. The emission layer EML may be a layer consisting of a single material, a layer including different materials, or a structure including multiple layers including different materials.

The light emitting element ED may include a fused polycyclic compound represented by Formula 1 below in at least one functional layer disposed between the first electrode EL1 and the second electrode EL2. The emission layer EML in the light emitting element ED may include a fused polycyclic compound according to an embodiment. In an embodiment, the emission layer EML may include the fused polycyclic compound as a dopant. The fused polycyclic compound may be a dopant material of the emission layer EML. In the specification, the fused polycyclic compound according to an embodiment, which will be described later, may be referred to as a first compound.

The fused polycyclic compound may include a structure in which multiple aromatic rings are fused through at least one boron atom and at least two heteroatoms.

In an embodiment, the fused polycyclic compound may include a structure in which multiple aromatic rings are fused via a boron atom and two heteroatoms. The fused polycyclic compound may have a structure in which first to third aromatic rings are fused via a boron atom, a first heteroatom, and a second heteroatom. The first to third aromatic rings may each be linked to the boron atom, the first aromatic ring and the second aromatic ring may be linked to each other via the first heteroatom, and the first aromatic ring and the third aromatic ring may be linked to each other via the second heteroatom. The first heteroatom may be a nitrogen atom, and the second heteroatom may be a nitrogen atom, an oxygen atom, or a sulfur atom.

In the specification, a structure in which the first to third aromatic rings are fused via the boron atom, the first heteroatom, and the second heteroatom may be referred to as a “fused ring core.”

The fused polycyclic compound may include a first substituent and a second substituent. In the fused polycyclic compound according to an embodiment, a first phenyl group may be linked to the nitrogen atom that is the first heteroatom, and the first substituent and the second substituent may each be substituted at the first phenyl group. The first substituent and the second substituent may each be substituted at an ortho position with respect to the carbon atom of the first phenyl group that is linked to the first heteroatom.

The first substituent and the second substituent may each be a substituted or unsubstituted aryl group having 6 to 30 ring-forming carbon atoms or a substituted or unsubstituted heteroaryl group having 2 to 30 ring-forming carbon atoms. In another embodiment, the first substituent and the second substituent may each include a dibenzofuran moiety represented by Formula a below. At least one of the first substituent and the second substituent may include a dibenzofuran moiety represented by Formula a below. In Formula a, the carbon number of the dibenzofuran moiety is indicated. For convenience of description, each substituent substituted at the dibenzofuran moiety is omitted and indicated as a hydrogen atom, but a substituent other than a hydrogen atom may be substituted at each carbon.

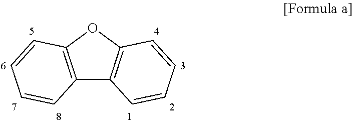 [SMILES: c1ccc2c(c1)oc1ccccc12]

At least one of the first substituent and the second substituent may include the dibenzofuran moiety represented by Formula a, and may be linked to the aforementioned first phenyl group at carbon 1 or carbon 4 in the dibenzofuran moiety represented by Formula a.

The fused polycyclic compound according to an embodiment may be represented by Formula 1:

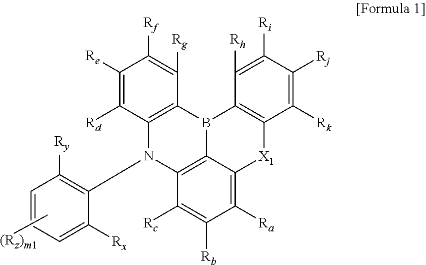

The fused polycyclic compound represented by Formula 1 has a structure in which three benzene rings are fused via a boron atom and two heteroatoms. One of the heteroatoms may be a nitrogen atom, and the other may be a nitrogen atom, an oxygen atom, or a sulfur atom. In the specification, in Formula 1, the benzene ring which is substituted with Rₐ to R_{c} may correspond to the aforementioned first aromatic ring, the benzene ring which is substituted with R_{d} to R_{g} may correspond to the aforementioned second aromatic ring, and the benzene ring which is substituted with Rₕ to Rₖ may correspond to the aforementioned third aromatic ring. The nitrogen atom of the fused ring core may correspond to the aforementioned first heteroatom, and X₁ may correspond to the aforementioned second heteroatom. The benzene ring which is linked to the nitrogen atom and is substituted with Rₓ to R_{z} may correspond to the aforementioned first phenyl group, and substituents represented by Rₓ and R_{y} may respectively correspond to the first substituent and the second substituent.

In Formula 1, X₁ may be O, S, or N(R₁).

In Formula 1, R₁ may be a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In an embodiment, R₁ may be a substituted or unsubstituted aryl group having 6 to 30 ring-forming carbon atoms. For example, R₁ may be a substituted or unsubstituted phenyl group, a substituted or unsubstituted biphenyl group, or a substituted or unsubstituted terphenyl group.

In Formula 1, Rₐ to Rₖ and R_{z} may each independently be a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, may be bonded to an adjacent group to form a ring. For example, Rₐ to Rₖ, and R_{z} may each independently be a hydrogen atom, a deuterium atom, a cyano group, a substituted or unsubstituted t-butyl group, a substituted or unsubstituted phenyl group, a substituted or unsubstituted biphenyl group, a substituted or unsubstituted terphenyl group, a substituted or unsubstituted diphenylamine group, a substituted or unsubstituted carbazole group, a substituted or unsubstituted phenoxazine group, a substituted or unsubstituted indolocarbazole group, or a substituted or unsubstituted dibenzofuran group. For example, Rₐ to R_{c} may each independently be a hydrogen atom, a deuterium atom, a substituted or unsubstituted t-butyl group, a substituted or unsubstituted phenyl group, a substituted or unsubstituted biphenyl group, a substituted or unsubstituted terphenyl group, a substituted or unsubstituted carbazole group, or a substituted or unsubstituted dibenzofuran group.

In an embodiment, R_{d} to Rₖ may each independently be a hydrogen atom, a deuterium atom, a substituted or unsubstituted phenyl group, a substituted or unsubstituted diphenylamine group, a substituted or unsubstituted carbazole group, a substituted or unsubstituted phenoxazine group, or a substituted or unsubstituted indolocarbazole group.

In an embodiment, in Formula 1, Rₐ to R_{c} may each independently be a hydrogen atom, a deuterium atom, or a group represented by one of Formula a-1 to Formula a-13:

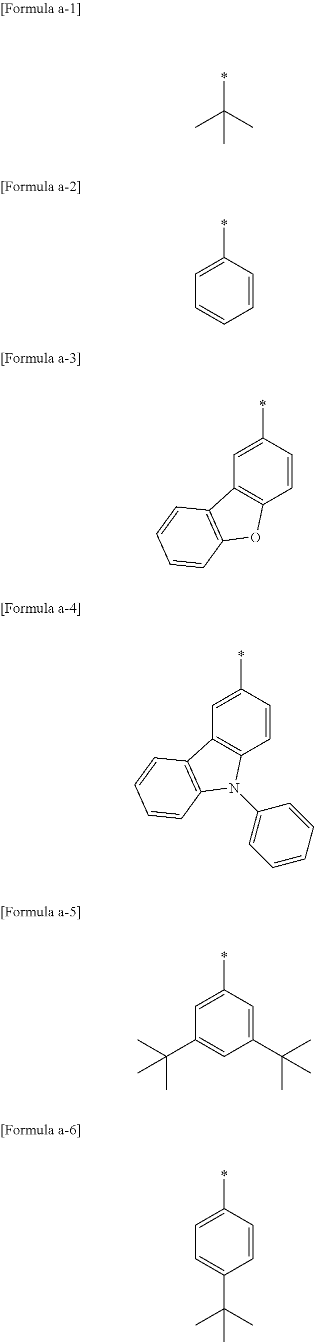

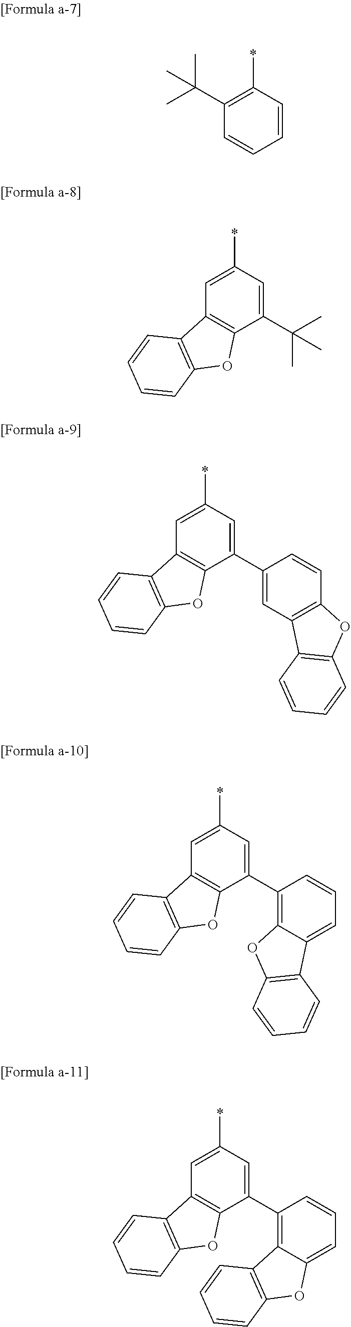 [SMILES: *c1ccccc1C(C)(C)C ; *c1cc(C(C)(C)C)c2oc3ccccc3c2c1 ; *c1cc(-c2ccc3oc4ccccc4c3c2)c2oc3ccccc3c2c1 ; *c1cc(-c2cccc3c2oc2ccccc23)c2oc3ccccc3c2c1 ; *c1cc(-c2cccc3oc4ccccc4c23)c2oc3ccccc3c2c1]

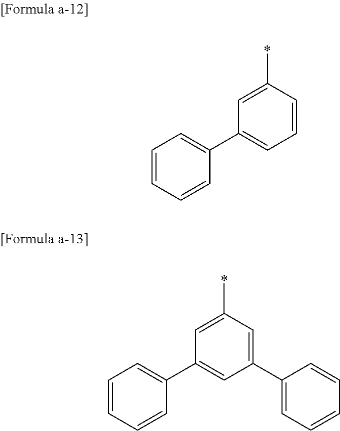 [SMILES: *c1cccc(-c2ccccc2)c1 ; *c1cc(-c2ccccc2)cc(-c2ccccc2)c1]

In Formula a-1 to Formula a-13, * is a position linked to Formula 1.

In an embodiment, in Formula 1, R_{d} to Rₖ may each independently be a hydrogen atom, a deuterium atom, or a group represented by one of Formula b-1 to Formula b-22:

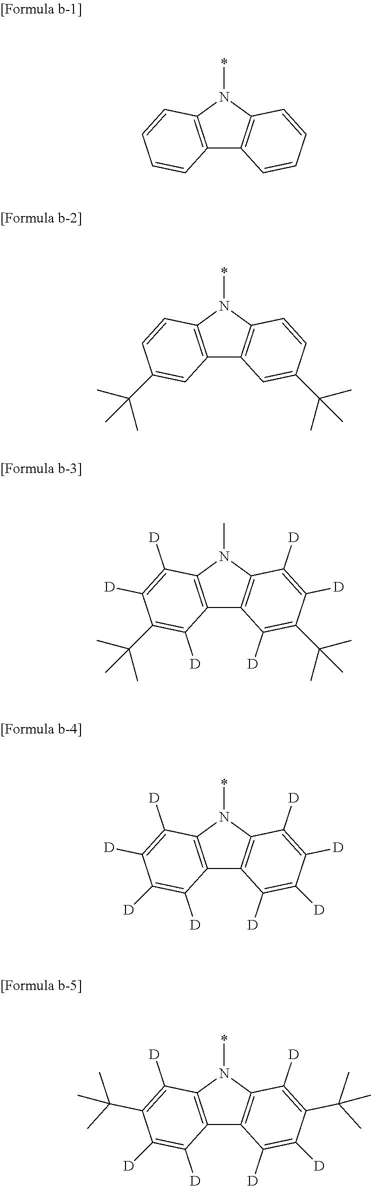

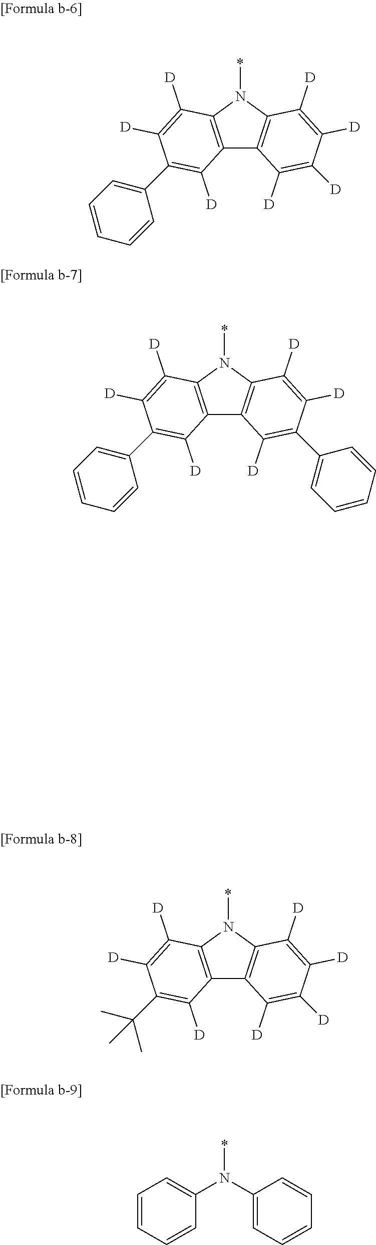 [SMILES: *n1c2c([2H])c([2H])c([2H])c([2H])c2c2c([2H])c(-c3ccccc3)c([2H])c([2H])c21 ; *n1c2c([2H])c([2H])c(-c3ccccc3)c([2H])c2c2c([2H])c(-c3ccccc3)c([2H])c([2H])c21 ; *n1c2c([2H])c([2H])c([2H])c([2H])c2c2c([2H])c(C(C)(C)C)c([2H])c([2H])c21 ; *N(c1ccccc1)c1ccccc1]

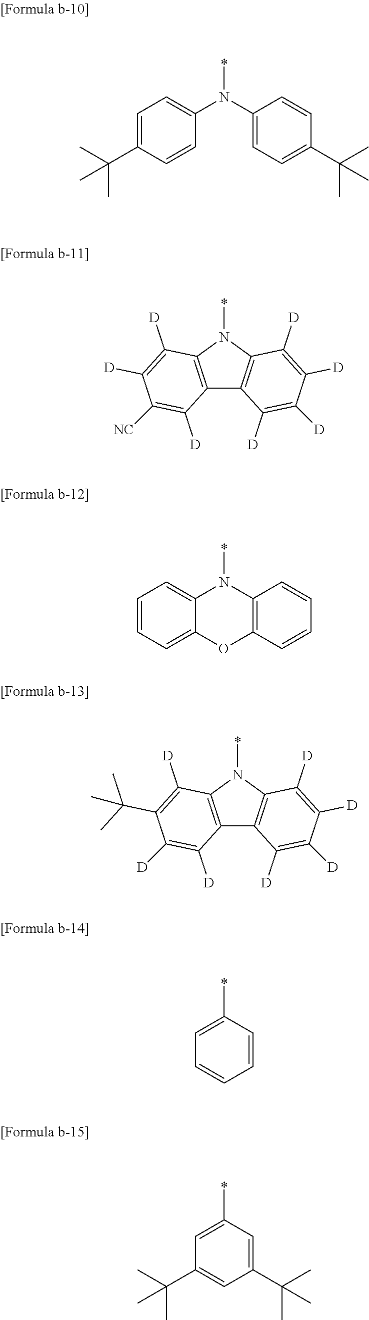

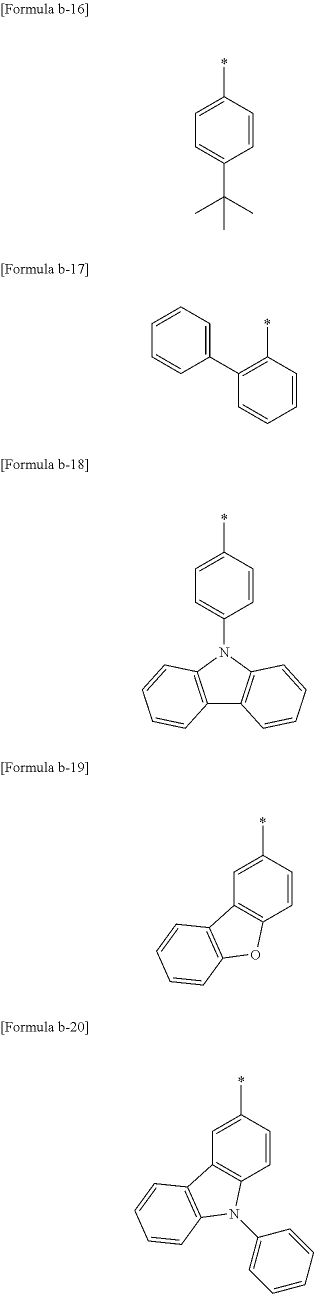 [SMILES: *c1ccc(C(C)(C)C)cc1 ; *c1ccccc1-c1ccccc1 ; *c1ccc(-n2c3ccccc3c3ccccc32)cc1 ; *c1ccc2oc3ccccc3c2c1 ; *c1ccc2c(c1)c1ccccc1n2-c1ccccc1]

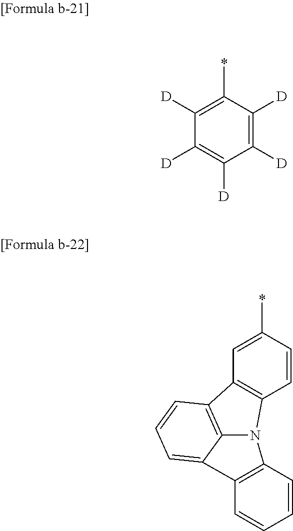 [SMILES: *c1c([2H])c([2H])c([2H])c([2H])c1[2H] ; *c1ccc2c(c1)c1cccc3c4ccccc4n2c31]

In Formula b-1 to Formula b-22, -* is a position linked to Formula 1, D represents a deuterium atom, and CN represents a cyano group.

In Formula 1, m1 may be an integer from 0 to 3. In Formula 1, if m1 is 0, the fused polycyclic compound may not be substituted with R_{z}. A where m1 is 3 and all R_{z} groups are hydrogen atoms may be the same as a case where m1 is 0. If m1 is 2 or greater, multiple R_{z} groups may all be the same as each other, or at least one group thereof may be different from the remainder.

In Formula 1, Rₓ and R_{y} may each independently be a substituted or unsubstituted aryl group having 6 to 30 ring-forming carbon atoms, a substituted or unsubstituted heteroaryl group having 2 to 30 ring-forming carbon atoms, or a group represented by Formula 2. For example, Rₓ and R_{y} may each independently be a substituted or unsubstituted phenyl group, a substituted or unsubstituted biphenyl group, a substituted or unsubstituted terphenyl group, a substituted or unsubstituted dibenzofuran group, or a group represented by Formula 2. In Formula 1, at least one of Rₓ and R_{y} may each independently be a group represented by Formula 2. In this regard, the group represented by Formula 2 may correspond to the first substituent or the second substituent including the “dibenzofuran moiety represented by Formula a” as described above. The fused polycyclic compound represented by Formula 1 includes at least one group represented by Formula 2:

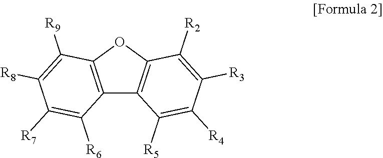

In Formula 2, R₂ to R₉ may each independently be a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, except that R₂ or R₅ is a position linked to Formula 1. For example, R₂ to R₉ may each independently be a hydrogen atom, a deuterium atom, a substituted or unsubstituted t-butyl group, or a substituted or unsubstituted phenyl group, except that R₂ or R₉ is a position linked to Formula 1.

In Formula 2, R₂ or R₉ is a position linked to Formula 1. For example, the dibenzofuran moiety represented by Formula 2 may be linked at carbon 1, which is a position of R₅, to the phenyl group linked to the nitrogen atom in the structure represented by Formula 1, or may be linked at carbon 4, which is a position of R₂, to the phenyl group linked to the nitrogen atom in the structure represented by Formula 1.

In an embodiment, the group represented by Formula 2 may be represented by Formula 2-1 or Formula 2-2:

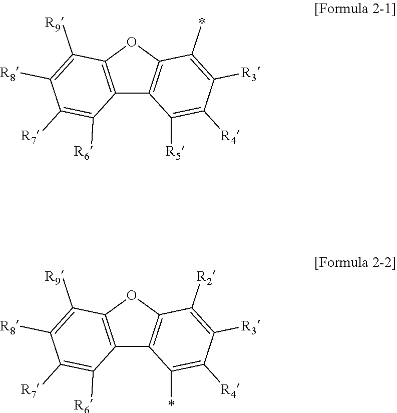

In Formula 2-1 and Formula 2-2, R₂′ to R₉′ may each independently be a hydrogen atom, a deuterium atom, or a substituted or unsubstituted phenyl group. For example, R₄′ may be a substituted or unsubstituted phenyl group.

In Formula 2-1 and Formula 2-2, -* is a position linked to Formula 1. For example, the dibenzofuran moiety represented by Formula 2-1 may be linked, via carbon 1, to the phenyl group linked to the nitrogen atom in the structure represented by Formula 1, or the dibenzofuran moiety represented by Formula 2-2 may be linked, via carbon 4, to the phenyl group linked to the nitrogen atom in the structure represented by Formula 1.

In an embodiment, the fused polycyclic compound represented by Formula 1 may be represented by one of Formula 1-1 to Formula 1-3:

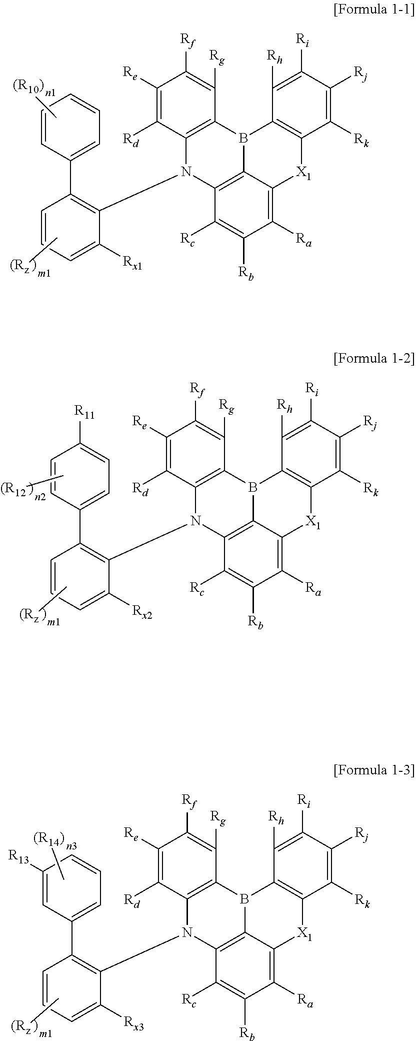

Formula 1-1 to Formula 1-3 each represents a case where Rₓ and R_{y} in Formula 1 are further defined.

In Formula 1-1 to Formula 1-3, Rₓ₁ to Rₓ₃ may each independently be a group represented by Formula 2. In an embodiment, in Formula 1-1 to Formula 1-3, Rₓ₁ to Rₓ₃ may each independently be a group represented by Formula 2-1 or Formula 2-2.

In Formula 1-1 to Formula 1-3, R₁₀, R₁₂, and R₁₄ may each independently be a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₁₀, R₁₂, and R₁₄ may each independently be a hydrogen atom or a deuterium atom.

In Formula 1-2 and Formula 1-3, R₁₁ and R₁₃ may each independently be a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ru and R₁₃ may each independently be a deuterium atom, a substituted or unsubstituted t-butyl group, a substituted or unsubstituted phenyl group, a substituted or unsubstituted biphenyl group, or a substituted or unsubstituted terphenyl group.

In Formula 1-1, n1 may be an integer from 0 to 5. In Formula 1-1, if n1 is 0, the fused polycyclic compound may not be substituted with R₁₀. A case where n1 is 5 and all R₁₀ groups are hydrogen atoms may be the same as a case where n1 is 0. If n1 is 2 or greater, multiple R₁₀ groups may all be the same as each other, or at least one group thereof may be different from the remainder.

In Formula 1-2 and Formula 1-3, n2 and n3 may each independently be an integer from 0 to 4. In Formula 1-2 and Formula 1-3, if n2 and n3 are each 0, the fused polycyclic compound may not be substituted with R₁₂ or R₁₄. A case where n2 and n3 are each 4 and all R₁₂ groups and all R₁₄ groups are hydrogen atoms may be the same as a case where n2 and n3 are each 0. When n2 and n3 are each 2 or greater, multiple groups of each of R₁₂ and R₁₄ may be the same as each other, or at least one group thereof may be different from the remainder.

In Formula 1-1 to Formula 1-3, Rₐ to Rₖ, R_{z}, m1, and X₁ are the same as described in Formula 1.

In an embodiment, the fused polycyclic compound represented by Formula 1 may be represented by one of Formula 1-1-1 to Formula 1-3-2:

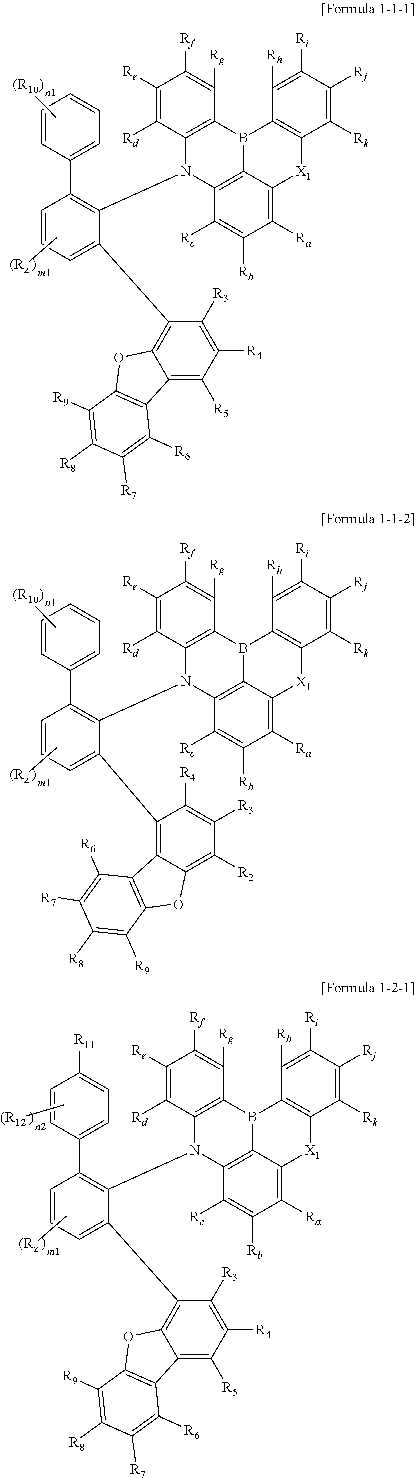

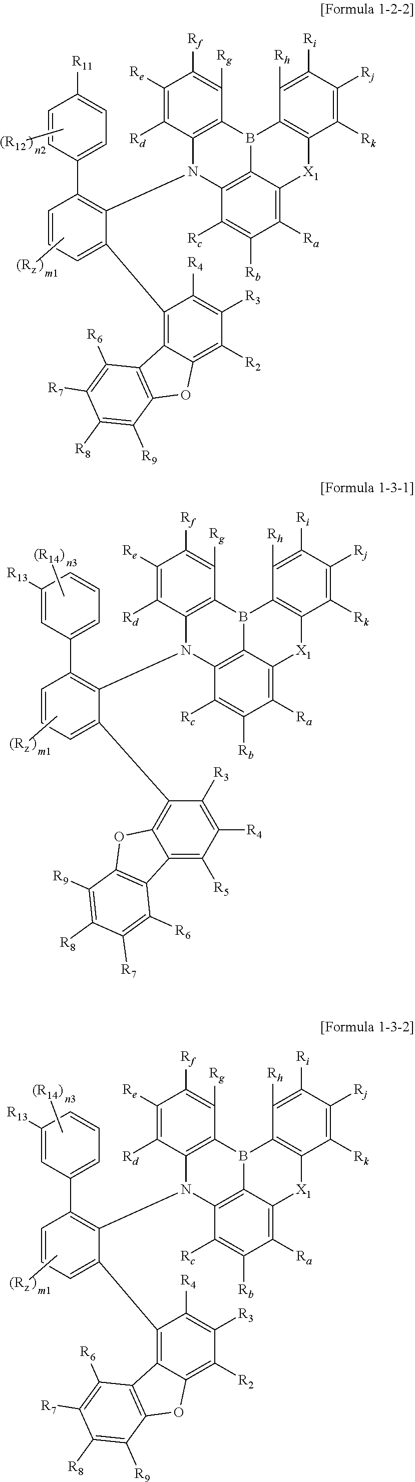

Formula 1-1-1 to Formula 1-3-2 each represents a case where Rₓ₁ to Rₓ₃ in Formula 1-1 to Formula 1-3 are further defined.

In Formula 1-1-1 to Formula 1-3-2, Rₐ to Rₖ, R_{z}, m1, and X₁ are the same as described in Formula 1. In Formula 1-1-1 to Formula 1-3-2, R₁₀ to R₁₄ and n₁ to n₃ are the same as described in Formula 1-1 to Formula 1-3. In Formula 1-1-1 to Formula 1-3-2, R₂ to R₉ are the same as described in Formula 2.

In an embodiment, the fused polycyclic compound represented by Formula 1 may be represented by Formula 3:

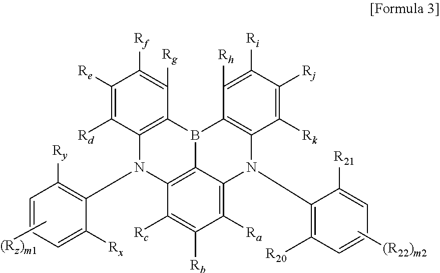

Formula 3 represents a case where X₁ in Formula 1 is further defined.

In Formula 3, R₂₀ and R₂₁ may each independently be a substituted or unsubstituted aryl group having 6 to 30 ring-forming carbon atoms, a substituted or unsubstituted heteroaryl group having 2 to 30 ring-forming carbon atoms, or a group represented by Formula 2. For example, R₂₀ and R₂₁ may each independently be a substituted or unsubstituted phenyl group, a substituted or unsubstituted biphenyl group, a substituted or unsubstituted terphenyl group, a substituted or unsubstituted dibenzofuran group, or a group represented by Formula 2. For example, at least one of R₂₀ and R₂₁ may be a group represented by Formula 2.

In Formula 3, R₂₂ may be a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, R₂₂ groups may each independently be a hydrogen atom, a deuterium atom, a substituted or unsubstituted t-butyl group, a substituted or unsubstituted phenyl group, a substituted or unsubstituted biphenyl group, or a substituted or unsubstituted terphenyl group.

In Formula 3, m2 may be an integer from 0 to 3. In Formula 3, if m2 is 0, the fused polycyclic compound may not be substituted with R₂₂. A case where m2 is 3 and all R₂₂ groups are hydrogen atoms may be the same as a case where m2 is 0. If m2 is 2 or greater, multiple R₂₂ groups may all be the same as each other, or at least one group thereof may be different from the remainder.

In an embodiment, the fused polycyclic compound represented by Formula 3 may have a symmetric structure with respect to the boron atom disposed at the center thereof. For example, the fused polycyclic compound represented by Formula 3 may have the same substituents substituted at a nitrogen atom respectively disposed at either side of the boron atom.

In an embodiment, in Formula 3, Rₓ and R₂₀ may be the same. In an embodiment, in Formula 3, R_{y} and R₂₁ may be the same.

In Formula 3, Rₐ to Rₖ, Rₓ, R_{y}, R_{z}, and m1 are the same as described in Formula 1.

In an embodiment, the fused polycyclic compound represented by Formula 1 may be represented by Formula 3-a:

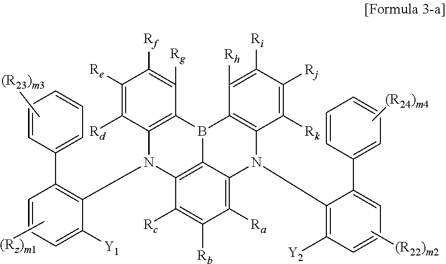

Formula 3-a represents a case where Rₓ, R_{y}, R₂₀, and R₂₁ in Formula 3 are further defined.

In Formula 3-a, Y₁ and Y₂ may each independently be a group represented by Formula 2. In an embodiment, Y₁ and Y₂ may each independently be a group represented by Formula 2-1 or Formula 2-2.

In Formula 3-a, R₂₃ and R₂₄ may each independently be a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₂₃ and R₂₄ may each independently be a hydrogen atom, a deuterium atom, a substituted or unsubstituted t-butyl group, a substituted or unsubstituted phenyl group, a substituted or unsubstituted biphenyl group, or a substituted or unsubstituted terphenyl group.

In Formula 3-a, m3 and m4 may each independently be an integer from 0 to 5. In Formula 3-a, if m3 and m4 are each 0, the fused polycyclic compound may not be substituted with R₂₃ or R₂₄. A case where m3 and m4 are each 5 and all R₂₃ groups and all R₂₄ groups are hydrogen atoms may be the same as a case where m3 and m4 are each 0. When m3 and m4 are each 2 or greater, multiple groups of each of R₂₃ and R₂₄ may be the same as each other, or at least one group thereof may be different from the remainder.

In Formula 3-a, Rₐ to Rₖ, R_{z}, and m1 are the same as described in Formula 1. In Formula 3-a, R₂₂ and m2 are the same as described in Formula 3.

In an embodiment, the fused polycyclic compound represented by Formula 1 may be represented by one of Formula 4-1 to Formula 4-3:

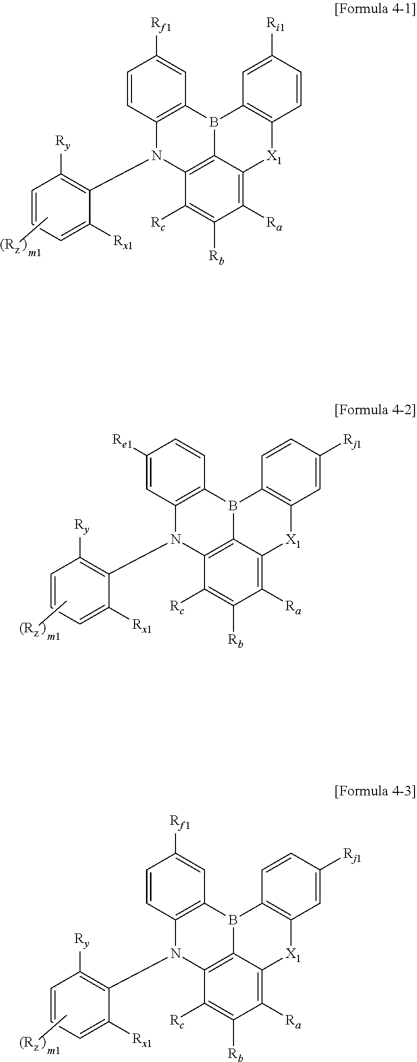

In Formula 4-1 to Formula 4-3, Rₑ₁, R_{f1}, Rᵢ₁, and Rⱼ₁ may each independently be a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₑ₁, R_{f1}, Rᵢ₁, and Rⱼ₁ may each independently be a substituted or unsubstituted phenyl group, a substituted or unsubstituted diphenylamine group, a substituted or unsubstituted carbazole group, a substituted or unsubstituted phenoxazine group, or a substituted or unsubstituted indolocarbazole group. In an embodiment, Rₑ₁, R_{f1}, Rᵢ₁, and Rⱼ₁ may each independently be a group represented by one of Formula b-1 to Formula b-22 as described above.

In Formula 4-1 to Formula 4-3, Rₐ to R_{c}, X₁, Rₓ, R_{y}, R_{z}, and m1 are the same as described in Formula 1.

In an embodiment, the fused polycyclic compound represented by Formula 1 may be represented by Formula 5:

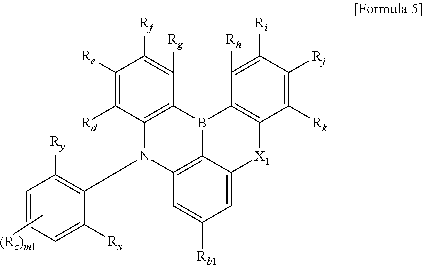

In Formula 5, Rei may be a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rei may be a deuterium atom, a substituted or unsubstituted t-butyl group, a substituted or unsubstituted phenyl group, a substituted or unsubstituted biphenyl group, a substituted or unsubstituted terphenyl group, a substituted or unsubstituted carbazole group, or a substituted or unsubstituted dibenzofuran group. In an embodiment, Rei may be a group represented by one of Formula a-1 to Formula a-13 as described above.

In Formula 5, R_{d} to Rₖ, X₁, Rₓ, R_{y}, R_{z}, and m1 are the same as described in Formula 1.

In an embodiment, the fused polycyclic compound represented by Formula 1 may be represented by Formula 6:

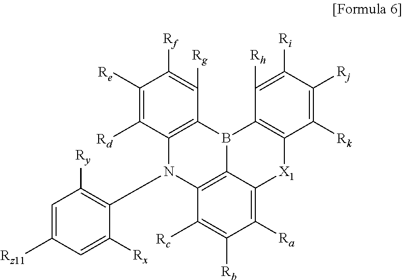

In Formula 6, R_{z11} may be a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R_{z11} may be a deuterium atom, a substituted or unsubstituted t-butyl group, or a substituted or unsubstituted phenyl group.

In Formula 6, Rₐ to Rₖ, X₁, Rₓ, and R_{y} are the same as described in Formula 1.

In an embodiment, the fused polycyclic compound represented by Formula 1 may include at least one deuterium atom as a substituent. In an embodiment, the group represented by Formula 2 may include at least one deuterium atom as a substituent.

In an embodiment, the fused polycyclic compound may be any compound selected from Compound Group 1. In an embodiment, in the light emitting element ED, the emission layer EML may include, as a first compound, at least one compound selected from Compound Group 1.

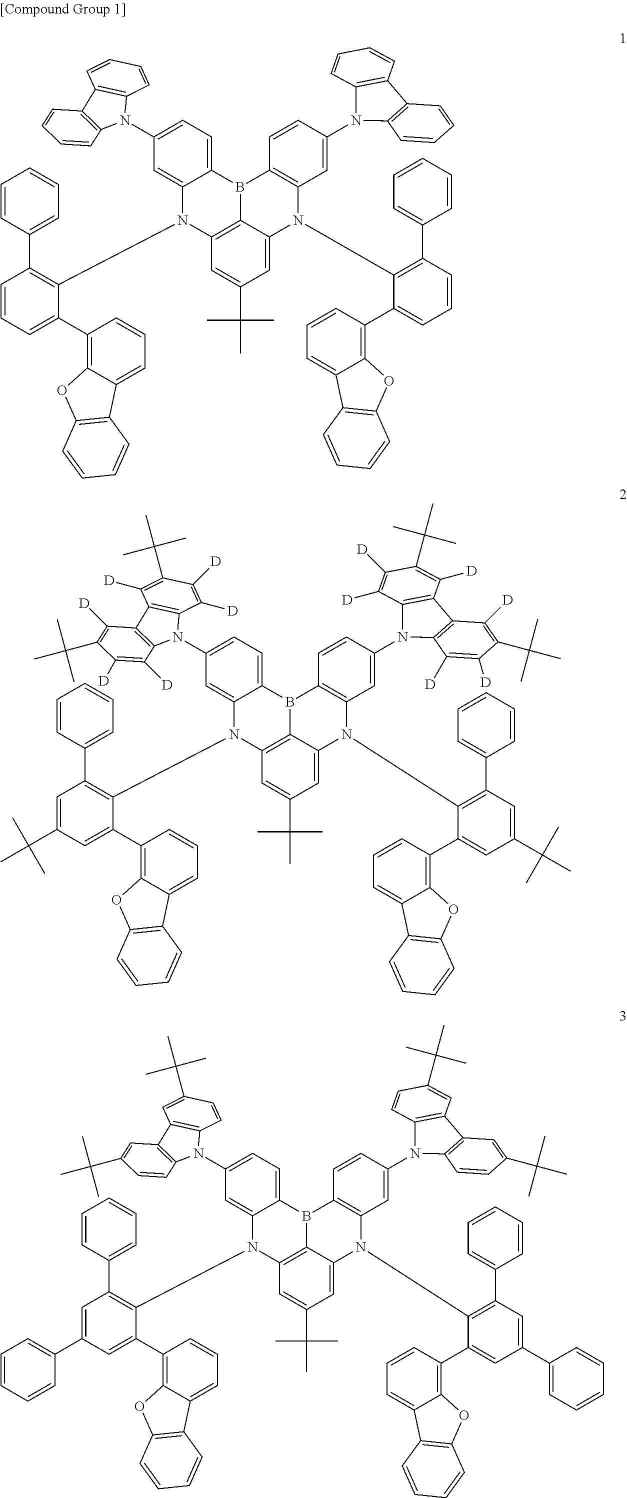

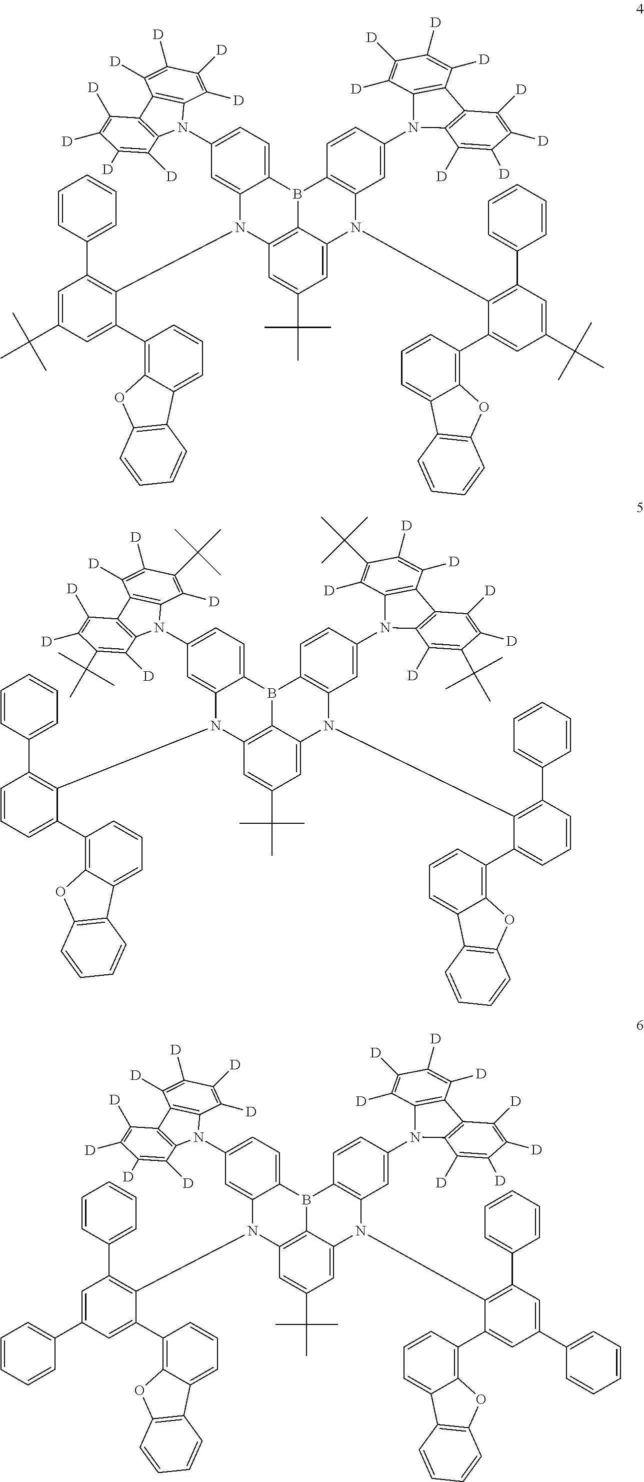

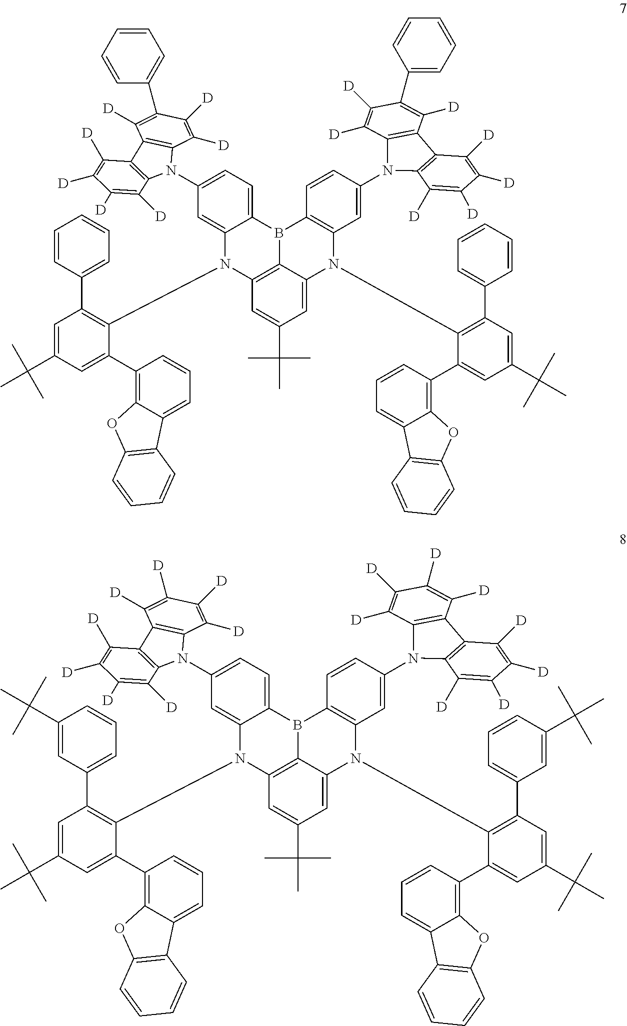

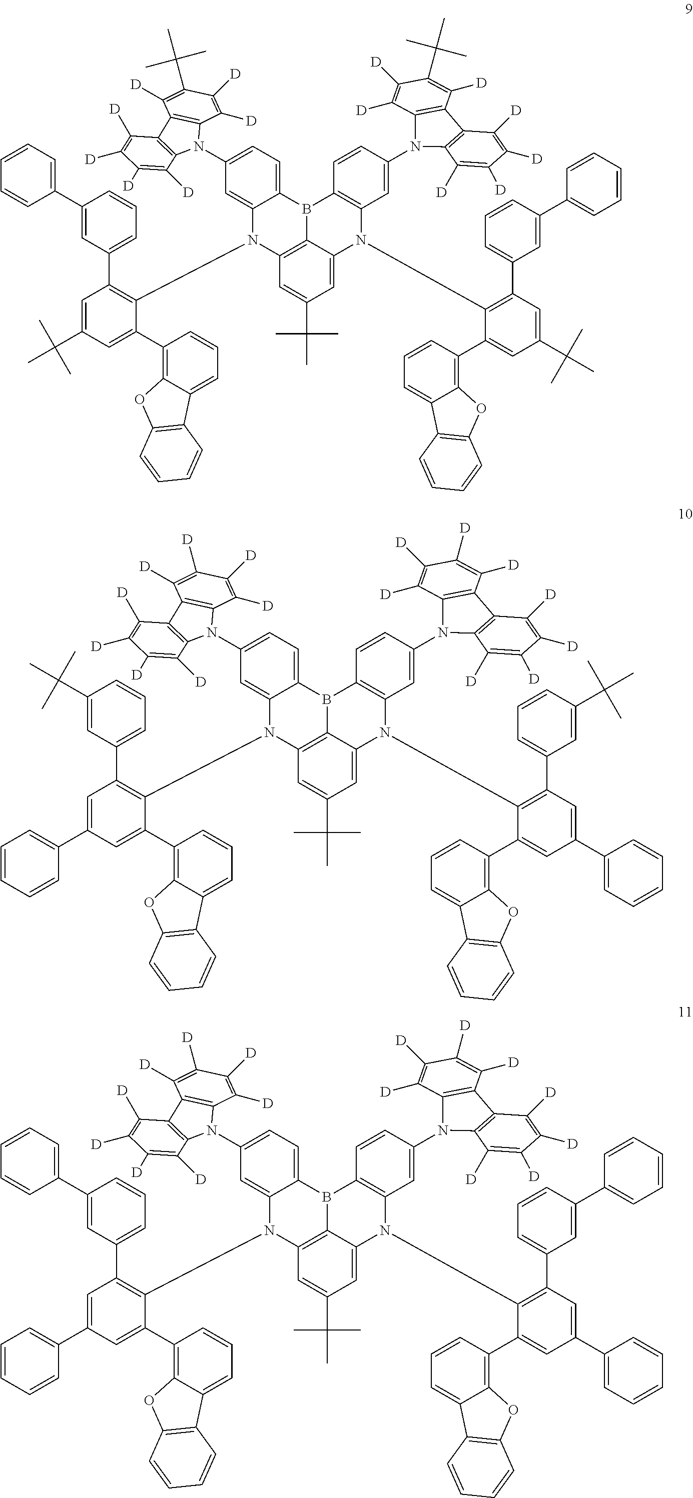

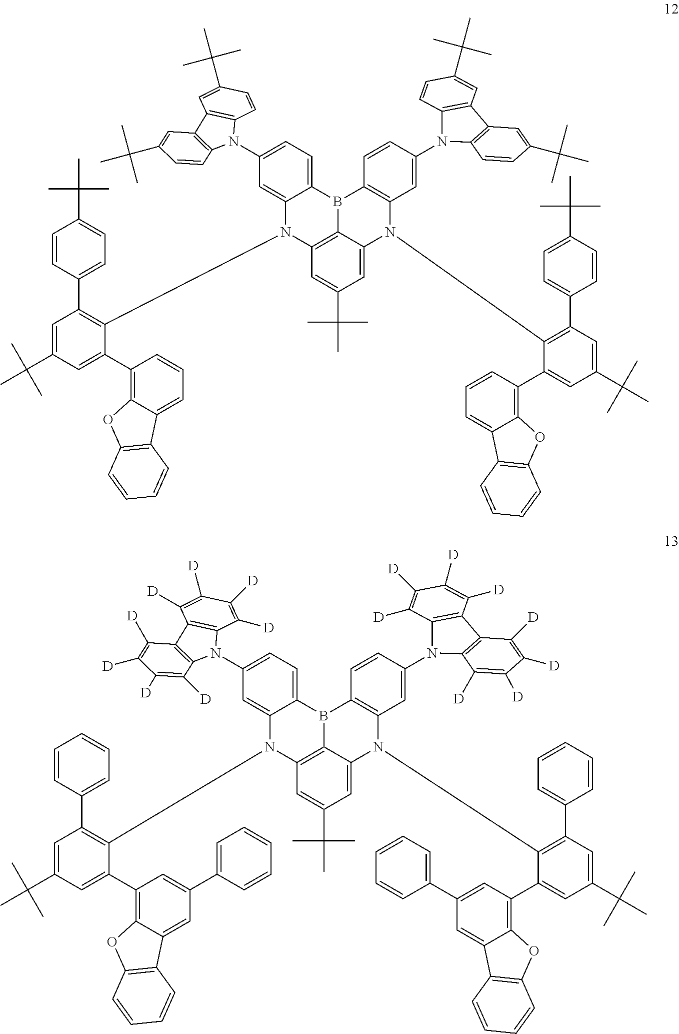

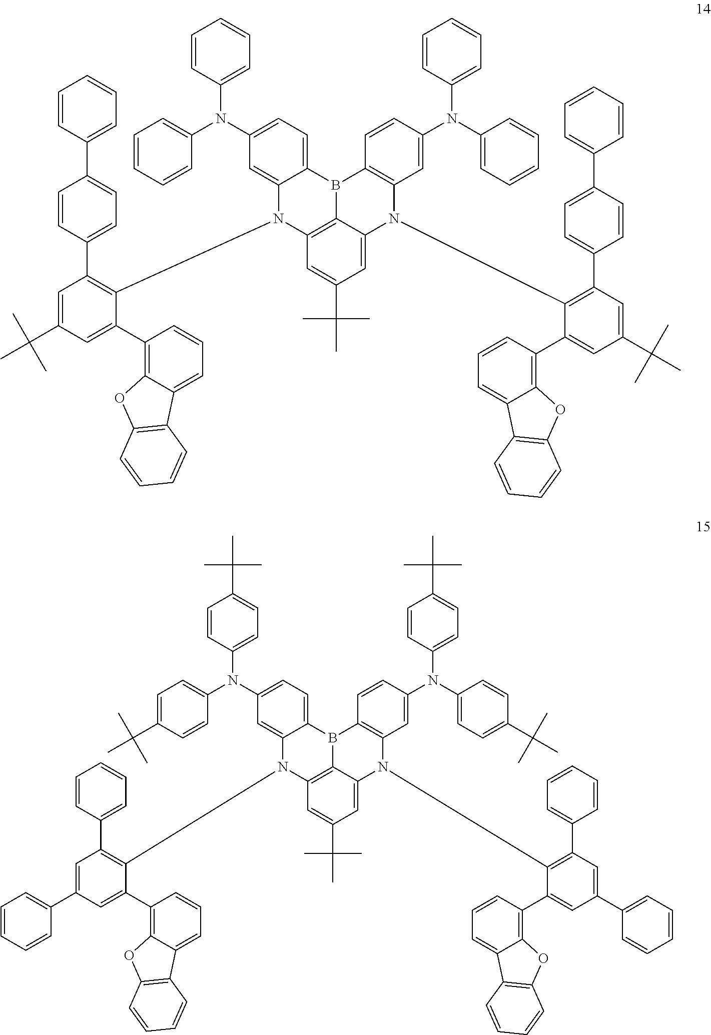 [SMILES: CC(C)(C)c1cc(-c2ccc(-c3ccccc3)cc2)c(N2c3cc(N(c4ccccc4)c4ccccc4)ccc3B3c4ccc(N(c5ccccc5)c5ccccc5)cc4N(c4c(-c5ccc(-c6ccccc6)cc5)cc(C(C)(C)C)cc4-c4cccc5c4oc4ccccc45)c4cc(C(C)(C)C)cc2c43)c(-c2cccc3c2oc2ccccc23)c1 ; CC(C)(C)c1ccc(N(c2ccc(C(C)(C)C)cc2)c2ccc3c(c2)N(c2c(-c4ccccc4)cc(-c4ccccc4)cc2-c2cccc4c2oc2ccccc24)c2cc(C(C)(C)C)cc4c2B3c2ccc(N(c3ccc(C(C)(C)C)cc3)c3ccc(C(C)(C)C)cc3)cc2N4c2c(-c3ccccc3)cc(-c3ccccc3)cc2-c2cccc3c2oc2ccccc23)cc1]

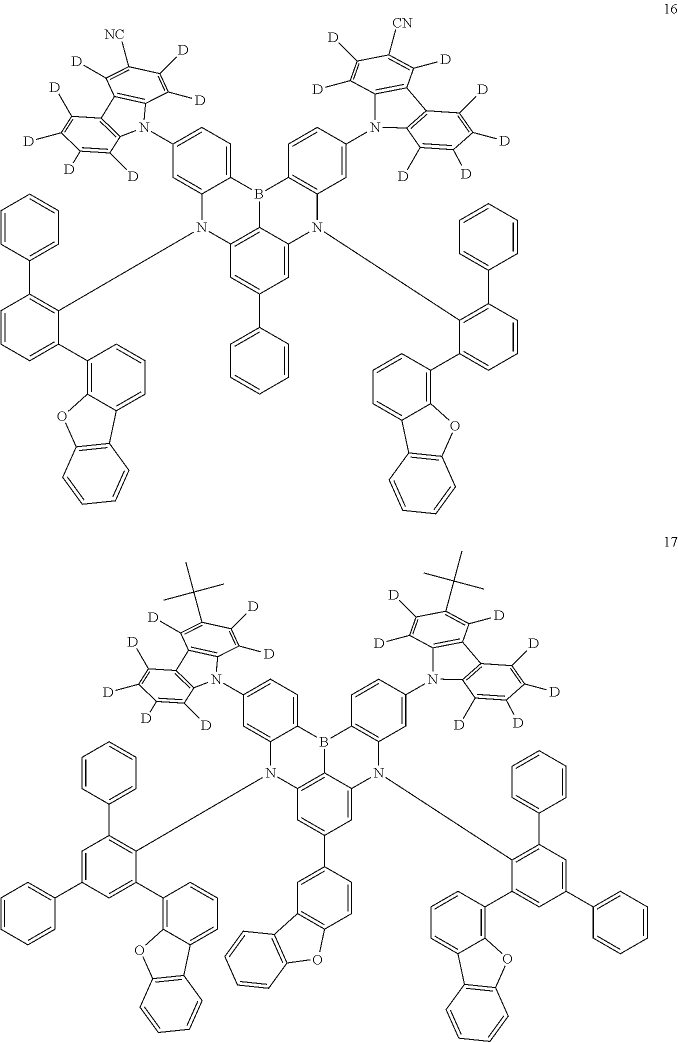

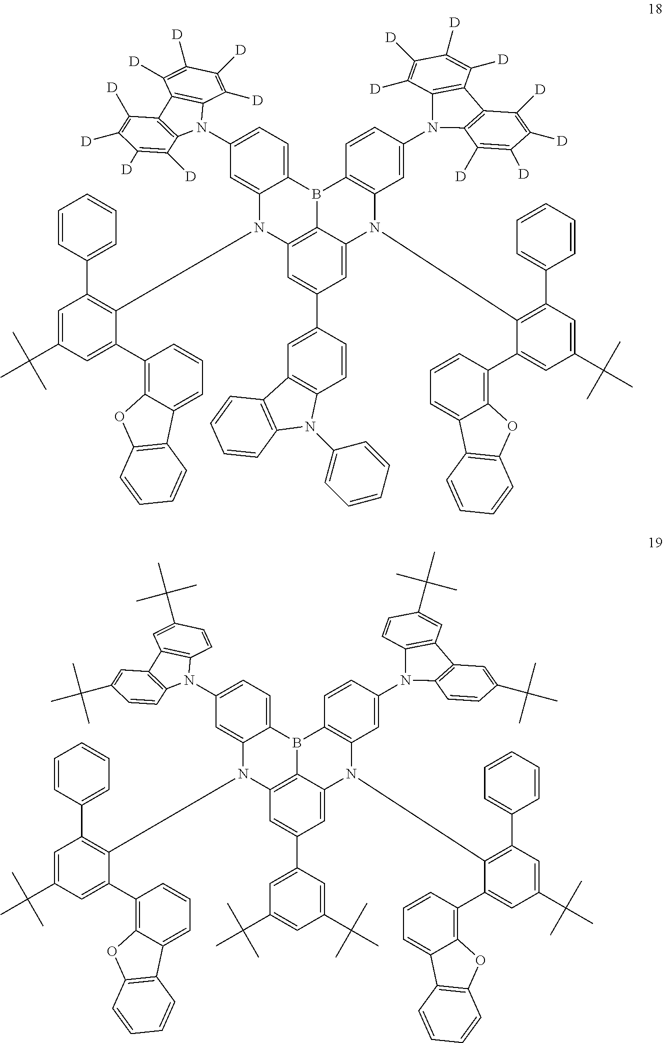

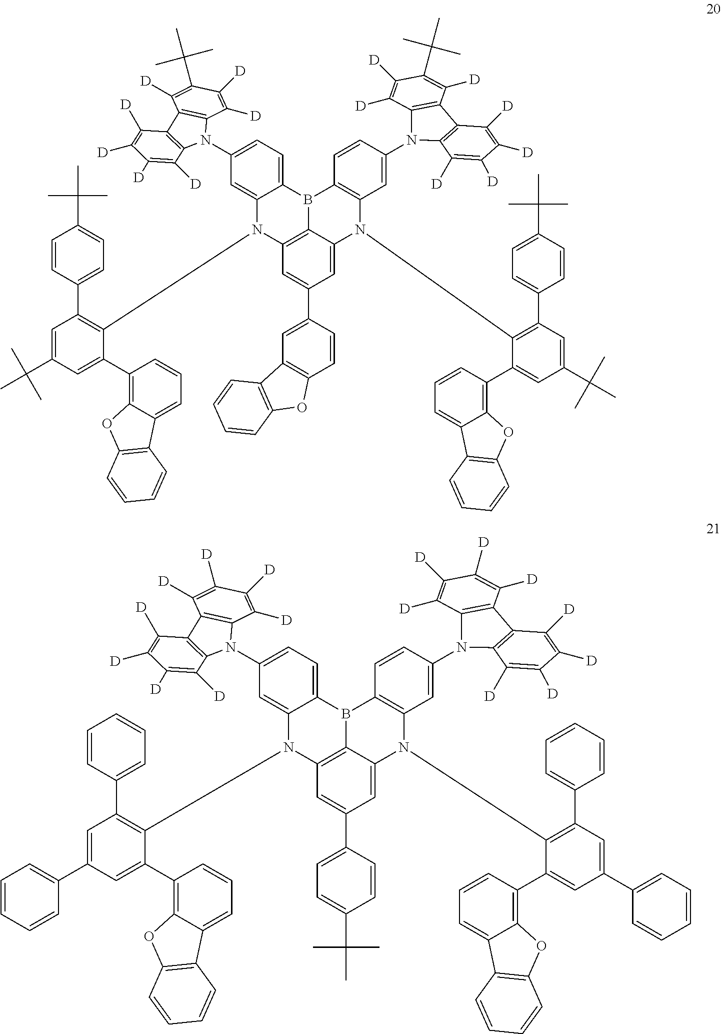

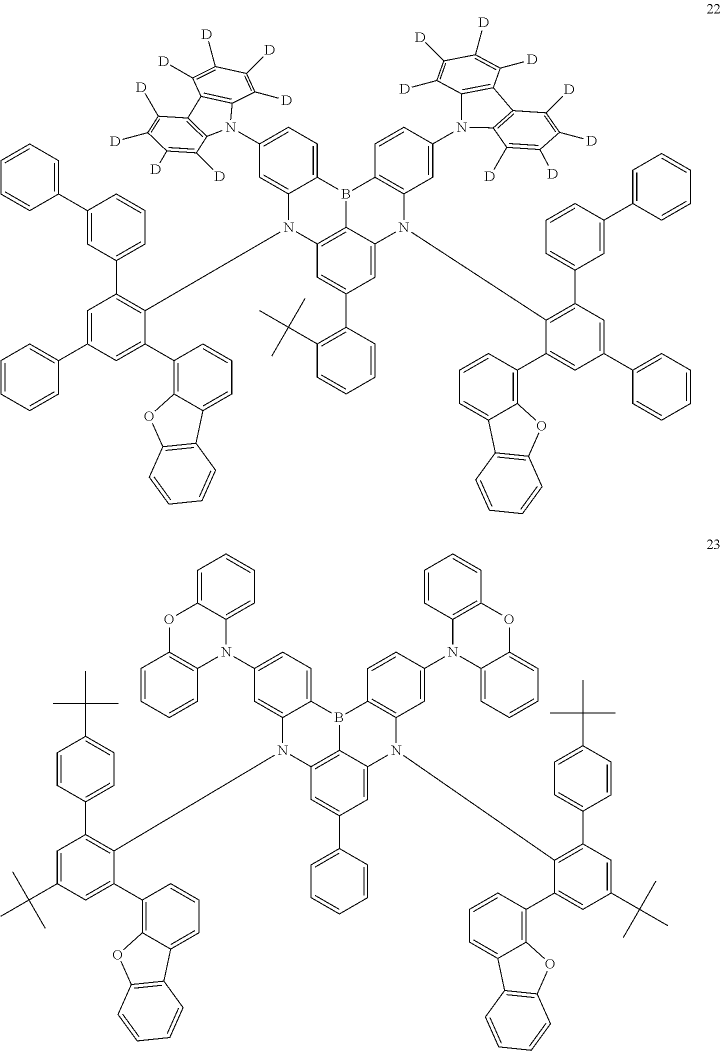

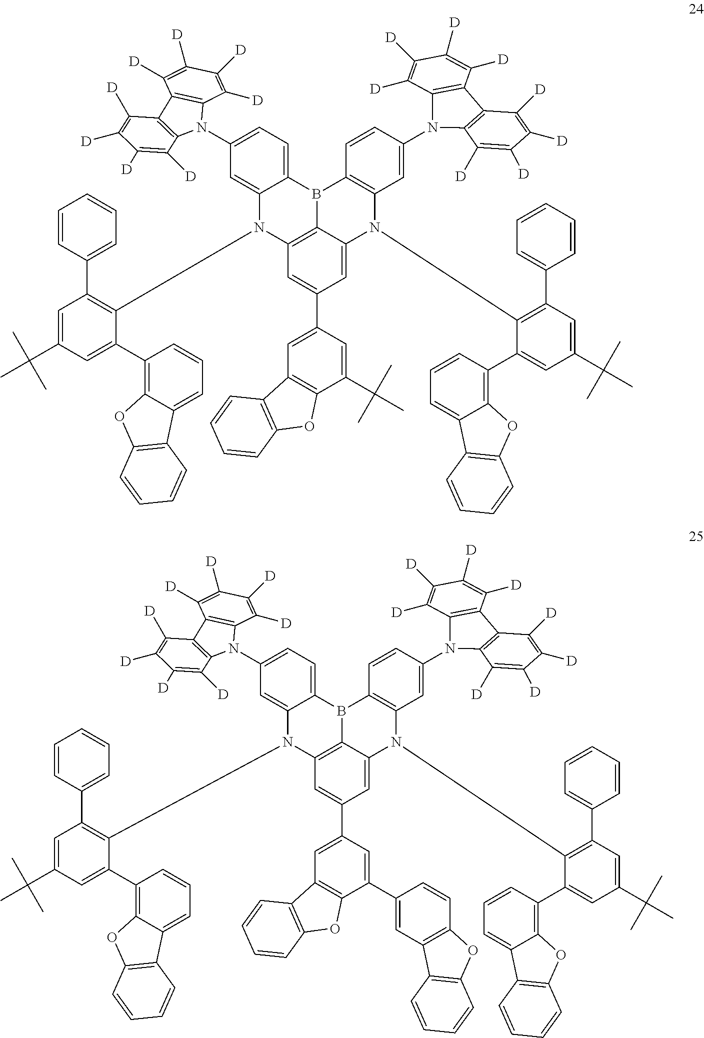

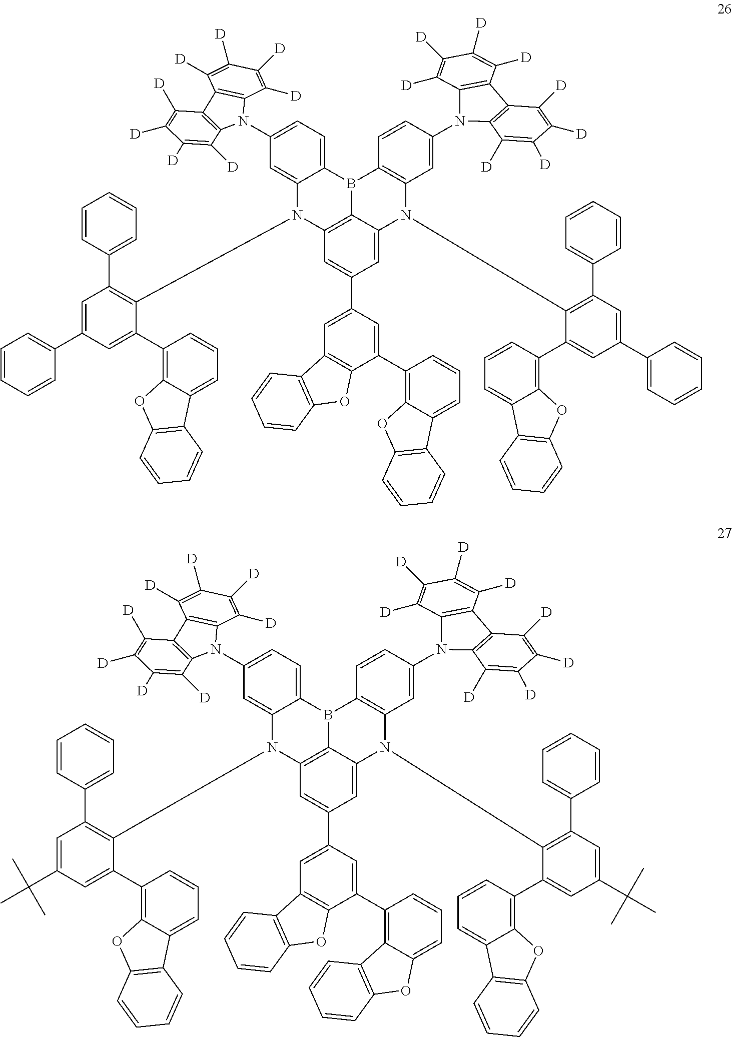

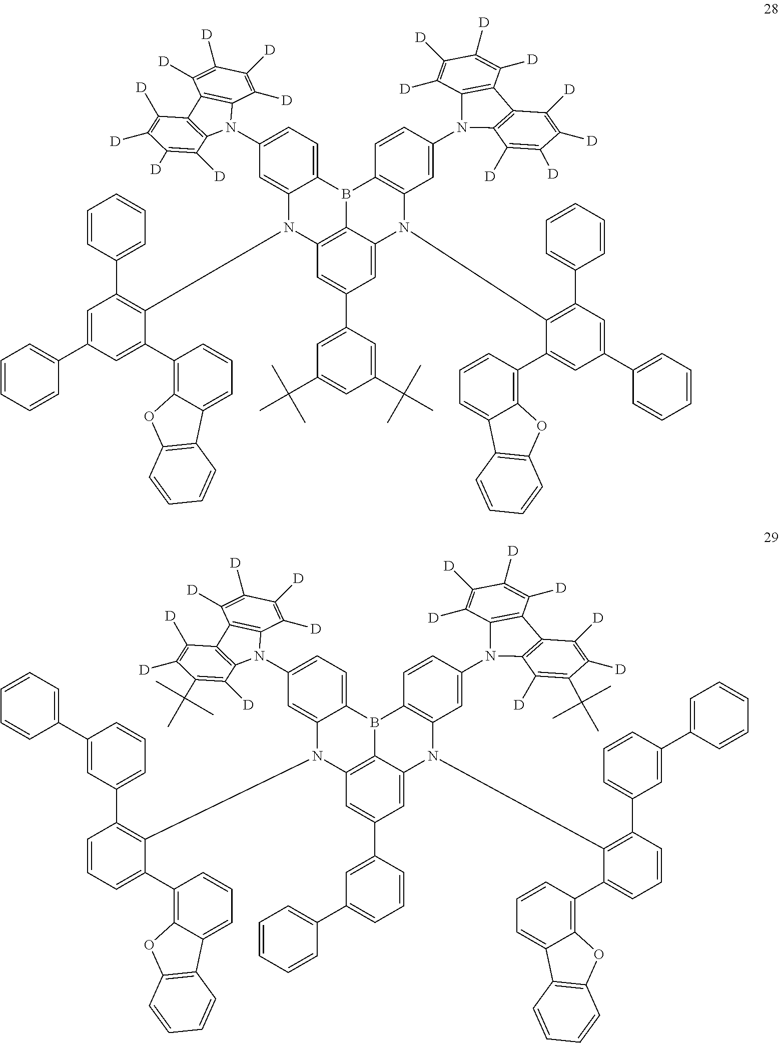

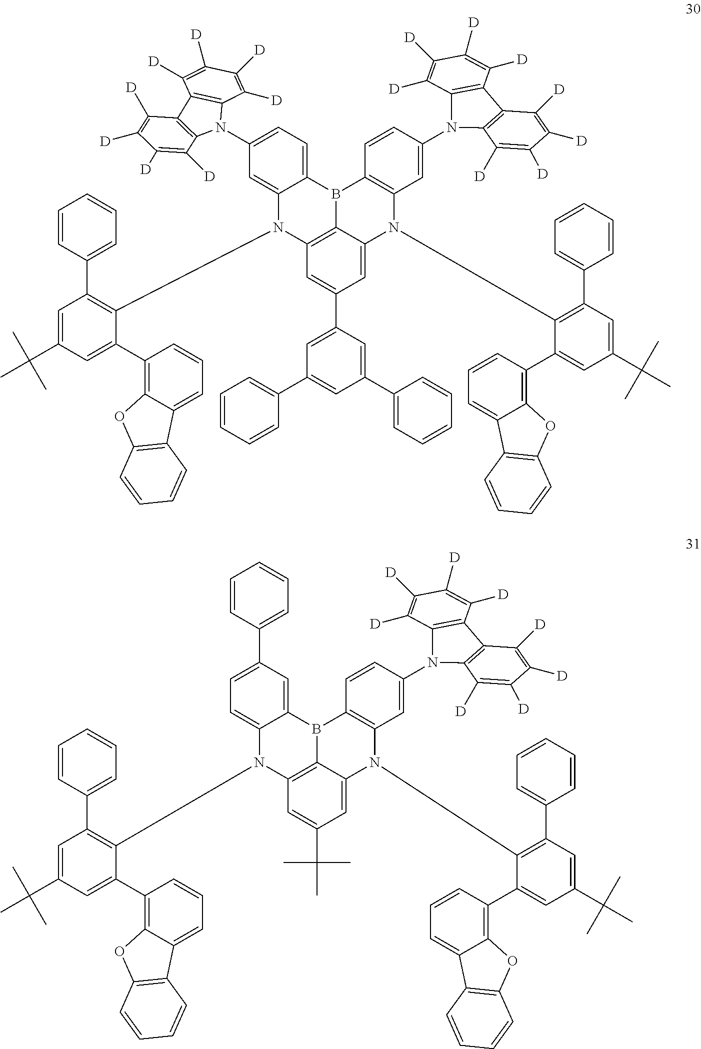

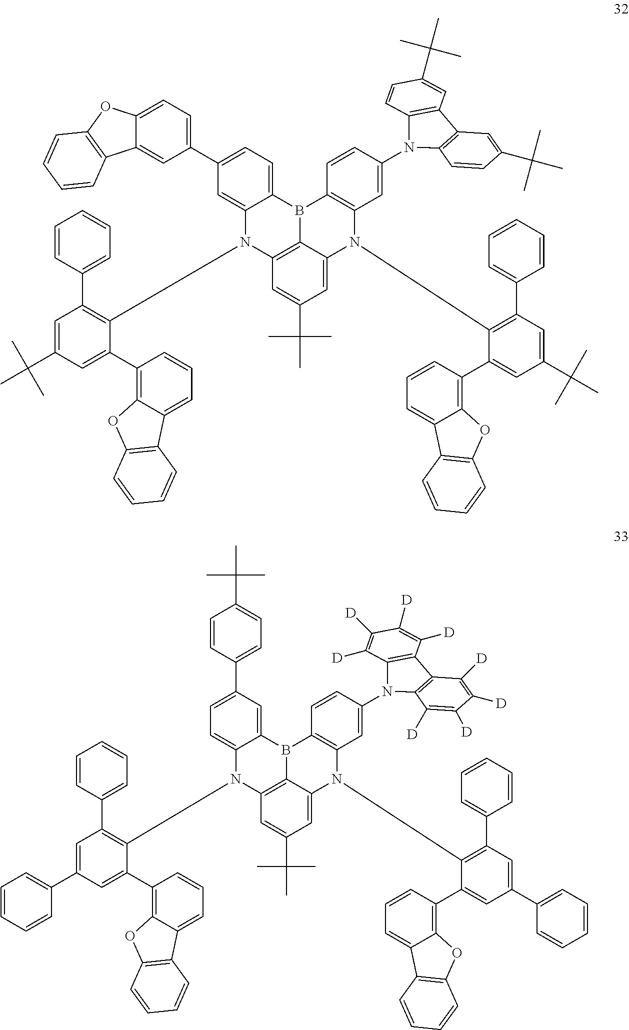 [SMILES: CC(C)(C)c1cc(-c2ccccc2)c(N2c3cc(-c4ccc5oc6ccccc6c5c4)ccc3B3c4ccc(-n5c6ccc(C(C)(C)C)cc6c6cc(C(C)(C)C)ccc65)cc4N(c4c(-c5ccccc5)cc(C(C)(C)C)cc4-c4cccc5c4oc4ccccc45)c4cc(C(C)(C)C)cc2c43)c(-c2cccc3c2oc2ccccc23)c1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3c1oc1ccccc13)c1cc(C(C)(C)C)cc3c1B2c1cc(-c2ccc(C(C)(C)C)cc2)ccc1N3c1c(-c2ccccc2)cc(-c2ccccc2)cc1-c1cccc2c1oc1ccccc12]

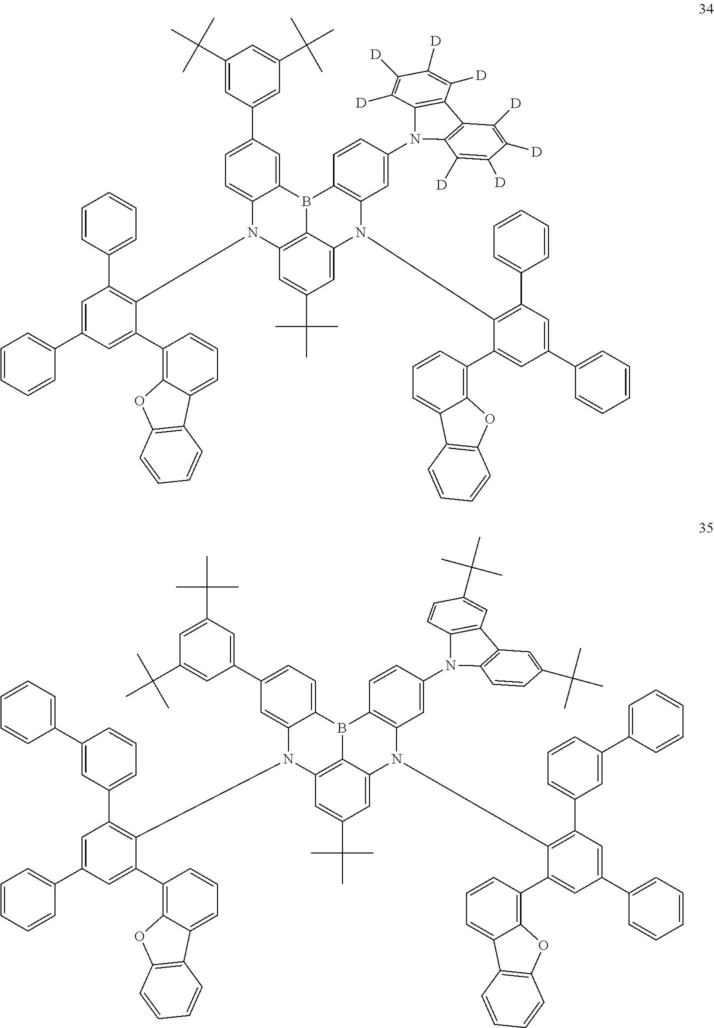

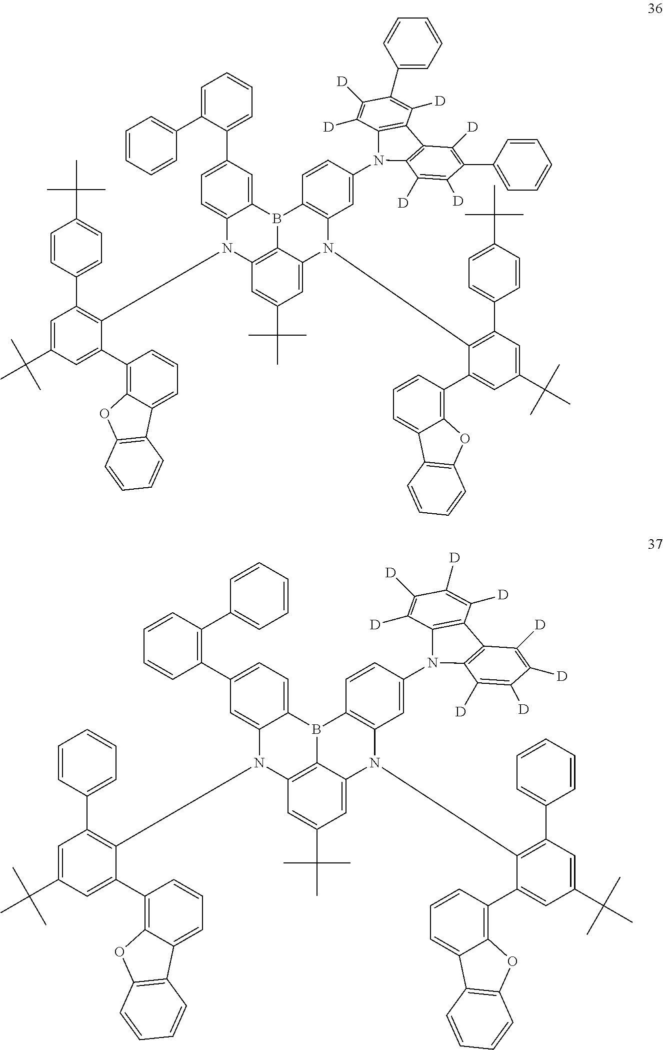

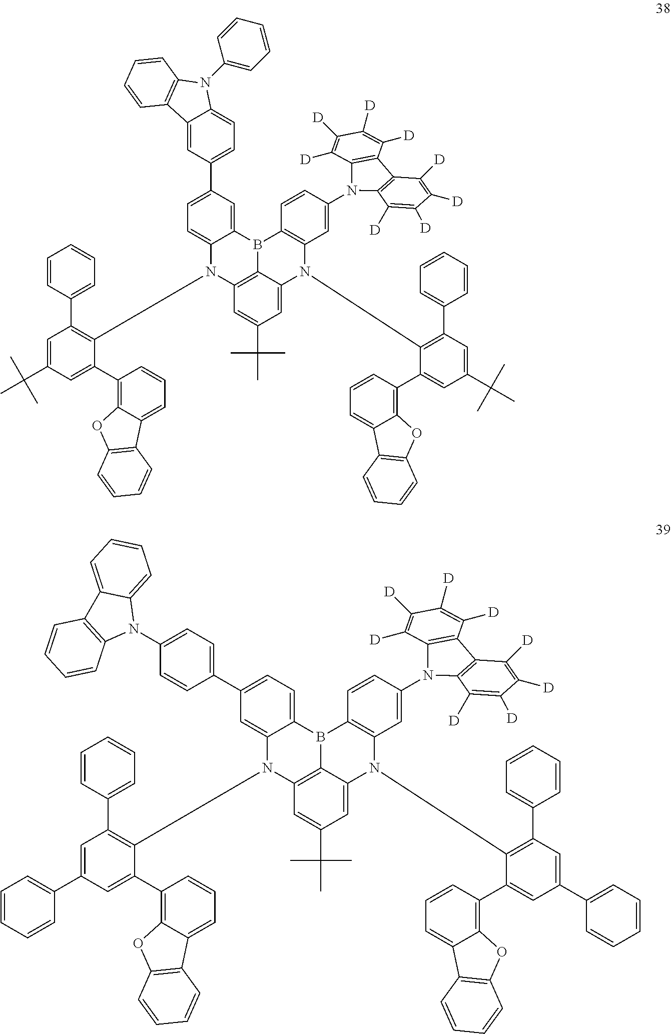 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc3c1oc1ccccc13)c1cc(C(C)(C)C)cc3c1B2c1cc(-c2ccc4c(c2)c2ccccc2n4-c2ccccc2)ccc1N3c1c(-c2ccccc2)cc(C(C)(C)C)cc1-c1cccc2c1oc1ccccc12 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3c1oc1ccccc13)c1cc(C(C)(C)C)cc3c1B2c1ccc(-c2ccc(-n4c5ccccc5c5ccccc54)cc2)cc1N3c1c(-c2ccccc2)cc(-c2ccccc2)cc1-c1cccc2c1oc1ccccc12]

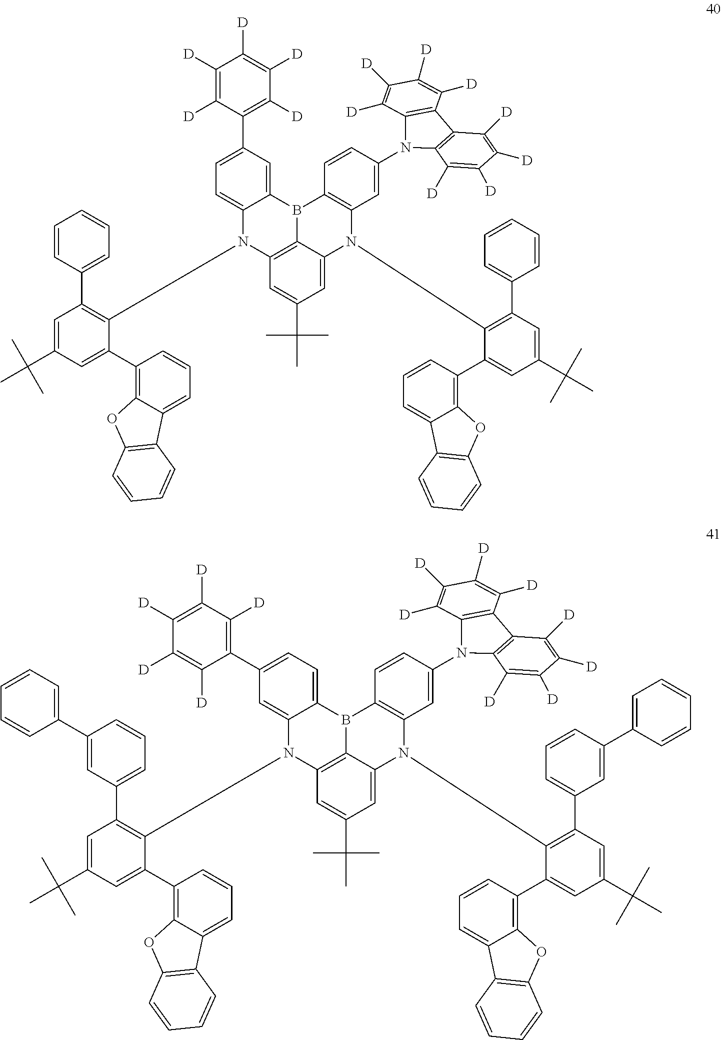

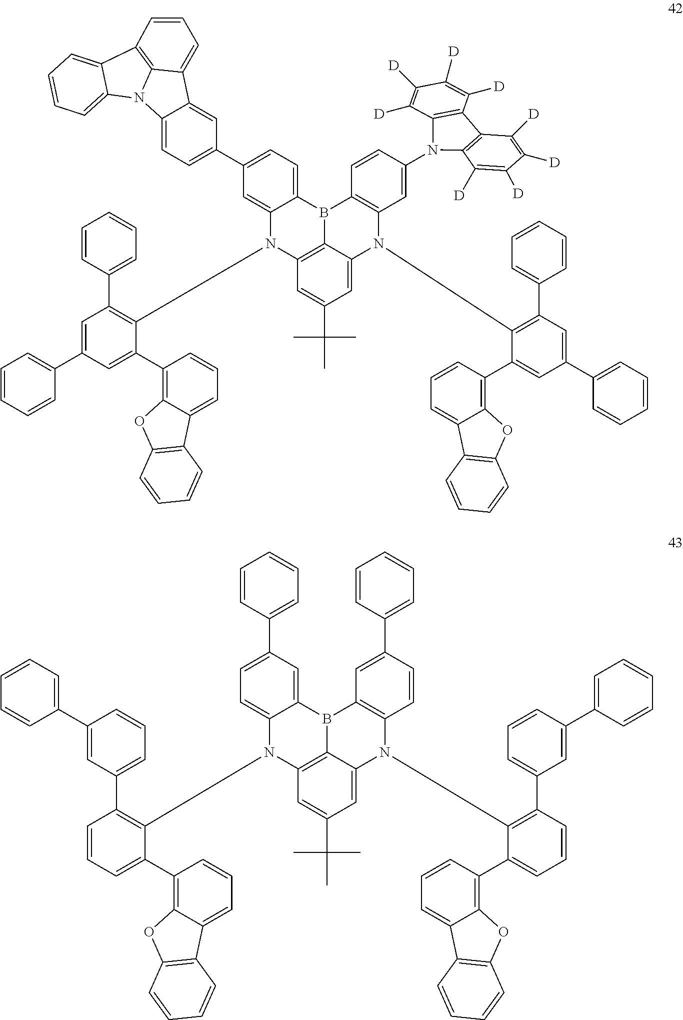 [SMILES: [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3c1oc1ccccc13)c1cc(C(C)(C)C)cc3c1B2c1ccc(-c2ccc4c(c2)c2cccc5c6ccccc6n4c52)cc1N3c1c(-c2ccccc2)cc(-c2ccccc2)cc1-c1cccc2c1oc1ccccc12 ; CC(C)(C)c1cc2c3c(c1)N(c1c(-c4cccc(-c5ccccc5)c4)cccc1-c1cccc4c1oc1ccccc14)c1ccc(-c4ccccc4)cc1B3c1cc(-c3ccccc3)ccc1N2c1c(-c2cccc(-c3ccccc3)c2)cccc1-c1cccc2c1oc1ccccc12]

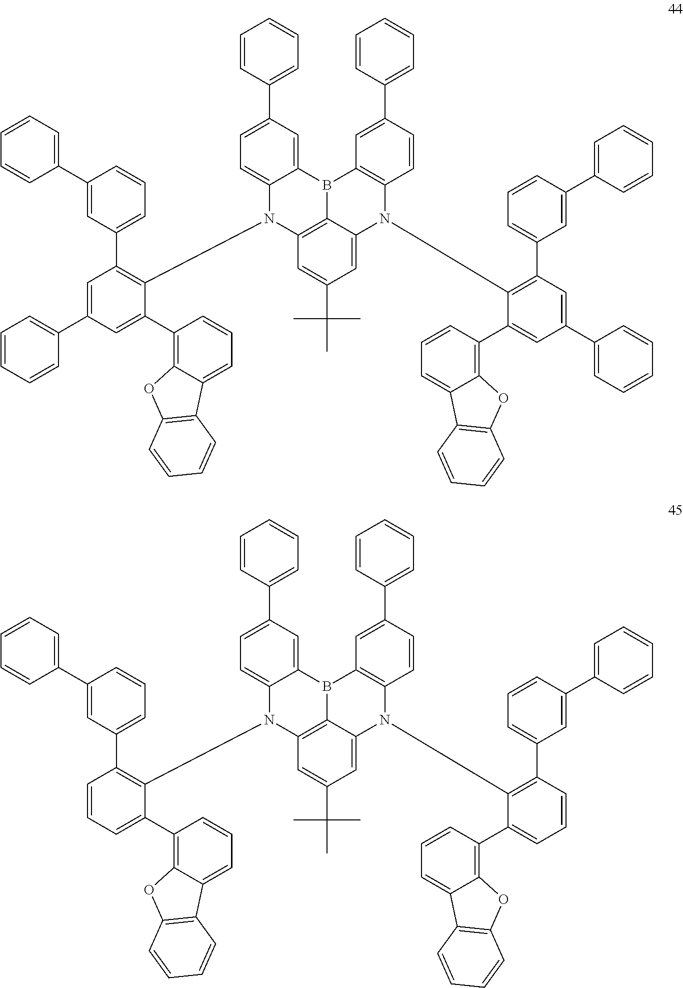 [SMILES: CC(C)(C)c1cc2c3c(c1)N(c1c(-c4cccc(-c5ccccc5)c4)cc(-c4ccccc4)cc1-c1cccc4c1oc1ccccc14)c1ccc(-c4ccccc4)cc1B3c1cc(-c3ccccc3)ccc1N2c1c(-c2cccc(-c3ccccc3)c2)cc(-c2ccccc2)cc1-c1cccc2c1oc1ccccc12 ; CC(C)(C)c1cc2c3c(c1)N(c1c(-c4cccc(-c5ccccc5)c4)cccc1-c1cccc4c1oc1ccccc14)c1ccc(-c4ccccc4)cc1B3c1cc(-c3ccccc3)ccc1N2c1c(-c2cccc(-c3ccccc3)c2)cccc1-c1cccc2c1oc1ccccc12]

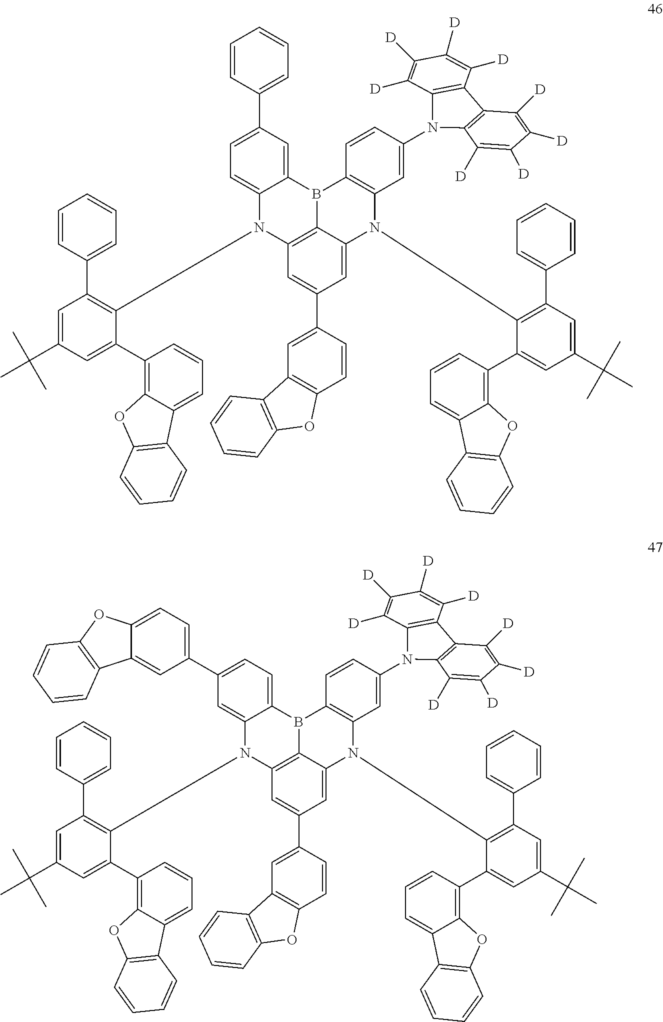

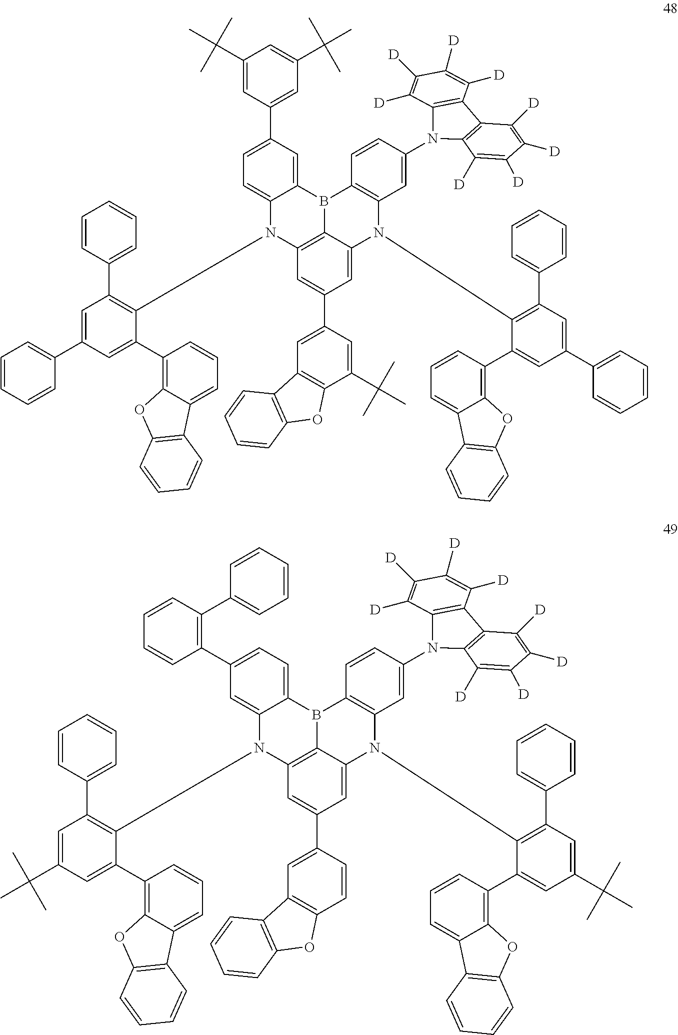

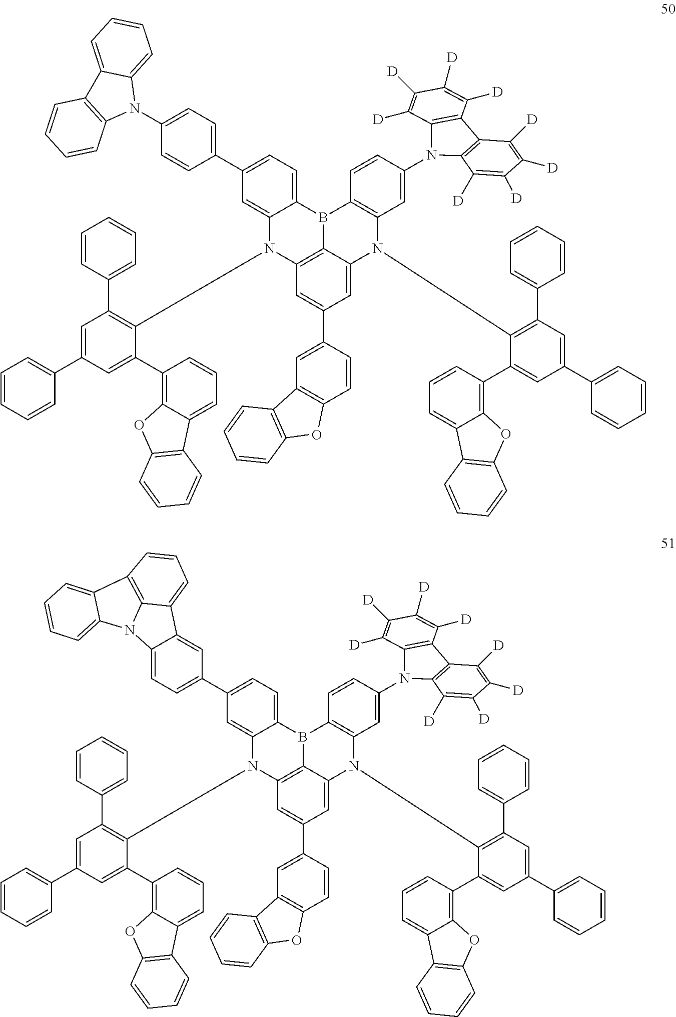

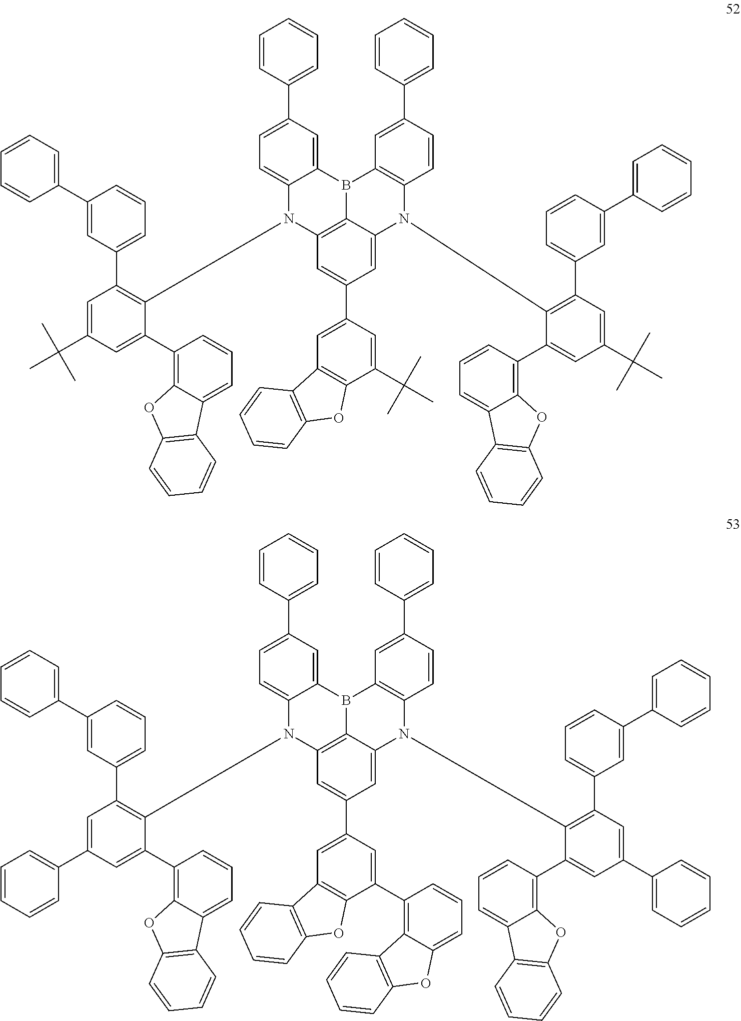 [SMILES: CC(C)(C)c1cc(-c2cccc(-c3ccccc3)c2)c(N2c3ccc(-c4ccccc4)cc3B3c4cc(-c5ccccc5)ccc4N(c4c(-c5cccc(-c6ccccc6)c5)cc(C(C)(C)C)cc4-c4cccc5c4oc4ccccc45)c4cc(-c5cc(C(C)(C)C)c6oc7ccccc7c6c5)cc2c43)c(-c2cccc3c2oc2ccccc23)c1 ; c1ccc(-c2cccc(-c3cc(-c4ccccc4)cc(-c4cccc5c4oc4ccccc45)c3N3c4ccc(-c5ccccc5)cc4B4c5cc(-c6ccccc6)ccc5N(c5c(-c6cccc(-c7ccccc7)c6)cc(-c6ccccc6)cc5-c5cccc6c5oc5ccccc56)c5cc(-c6cc(-c7cccc8oc9ccccc9c78)c7oc8ccccc8c7c6)cc3c54)c2)cc1]

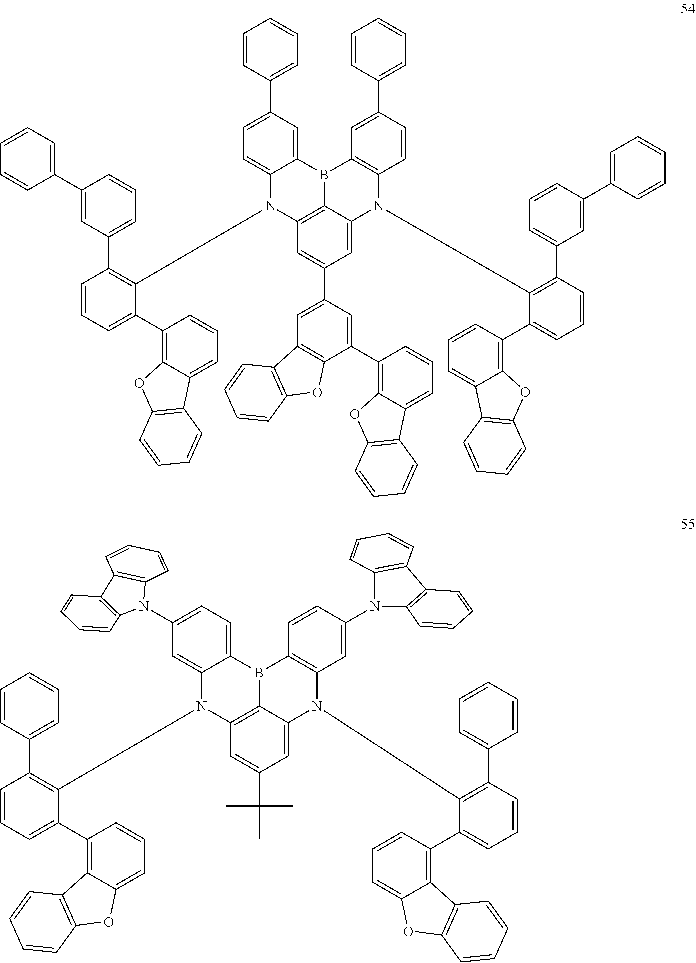

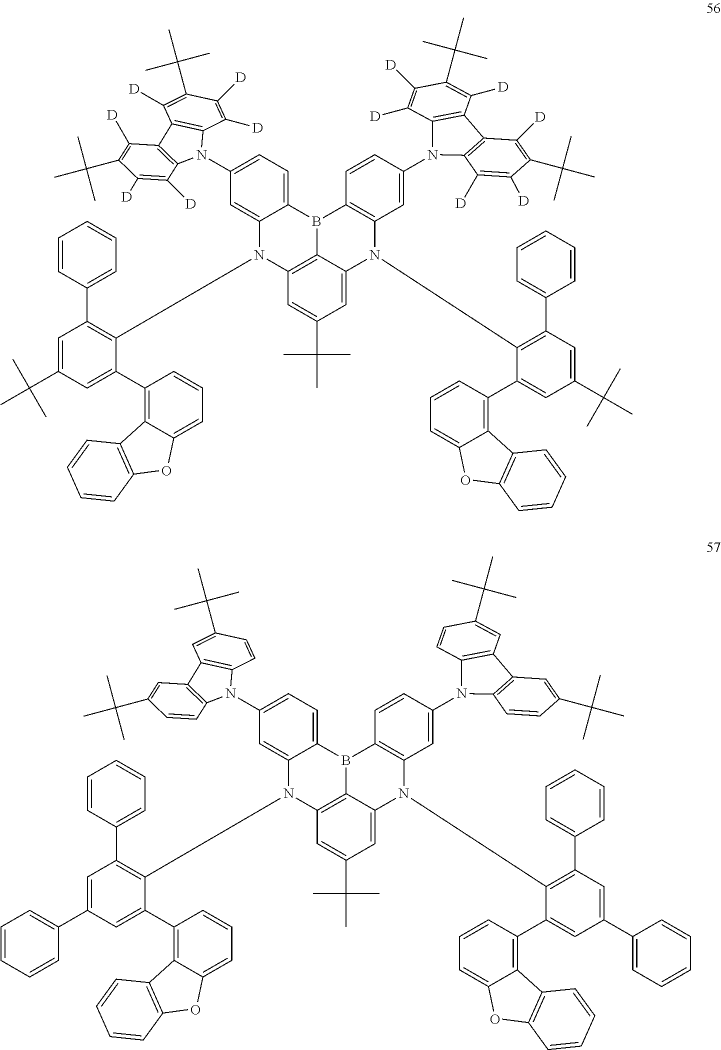

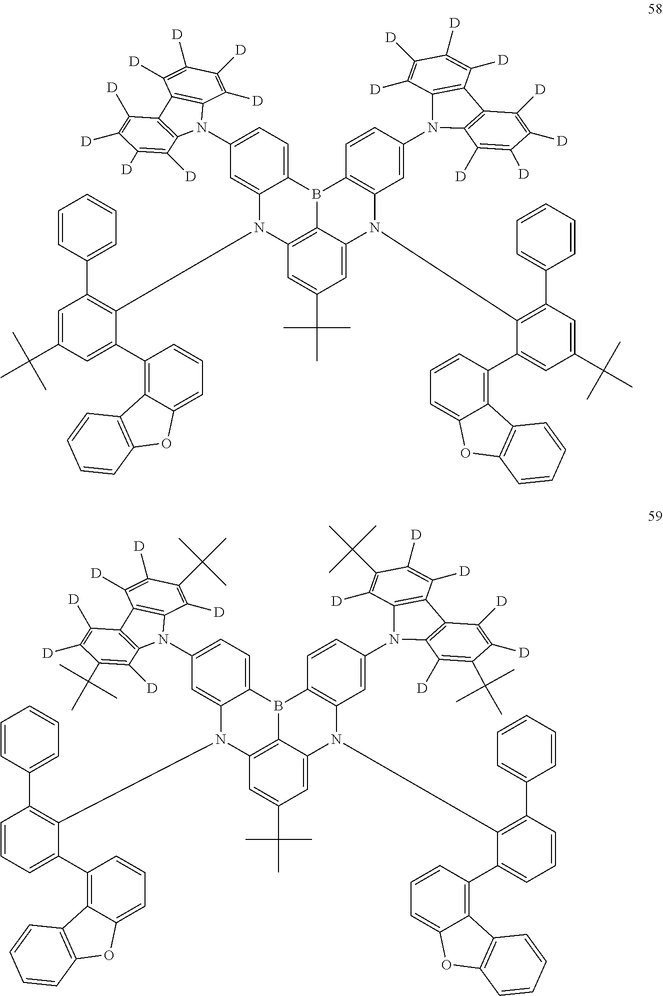

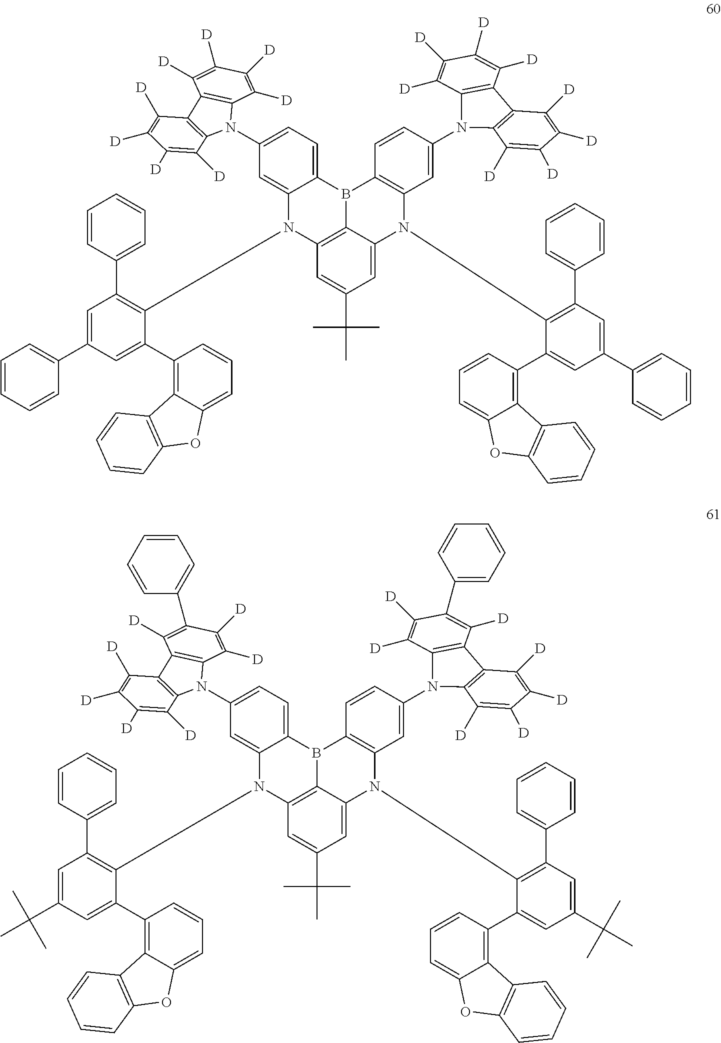

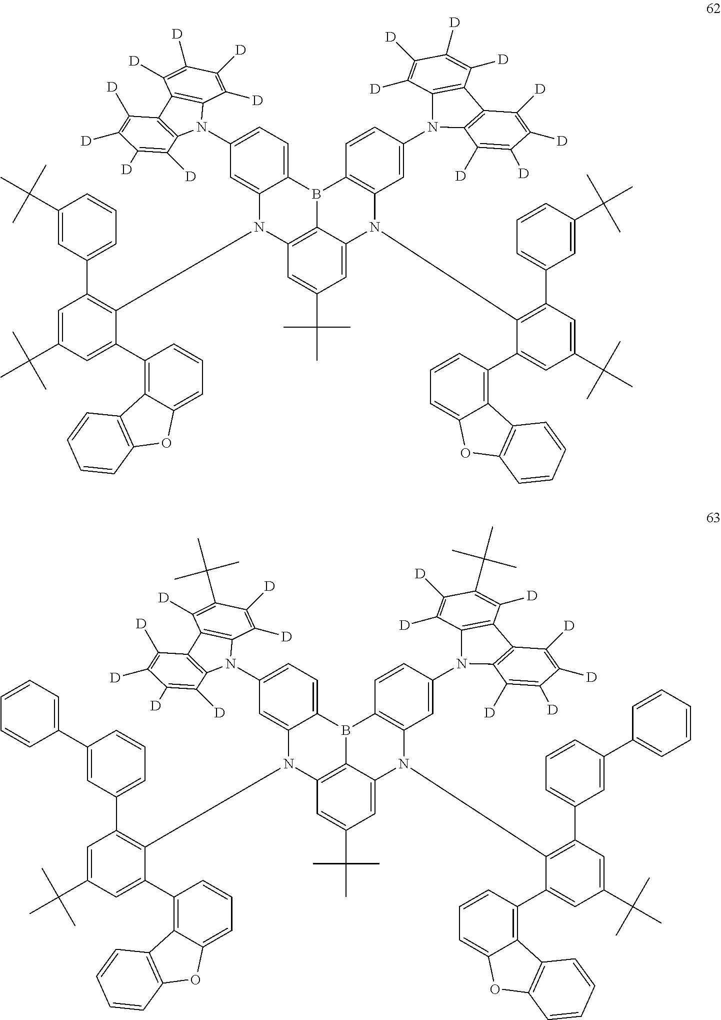

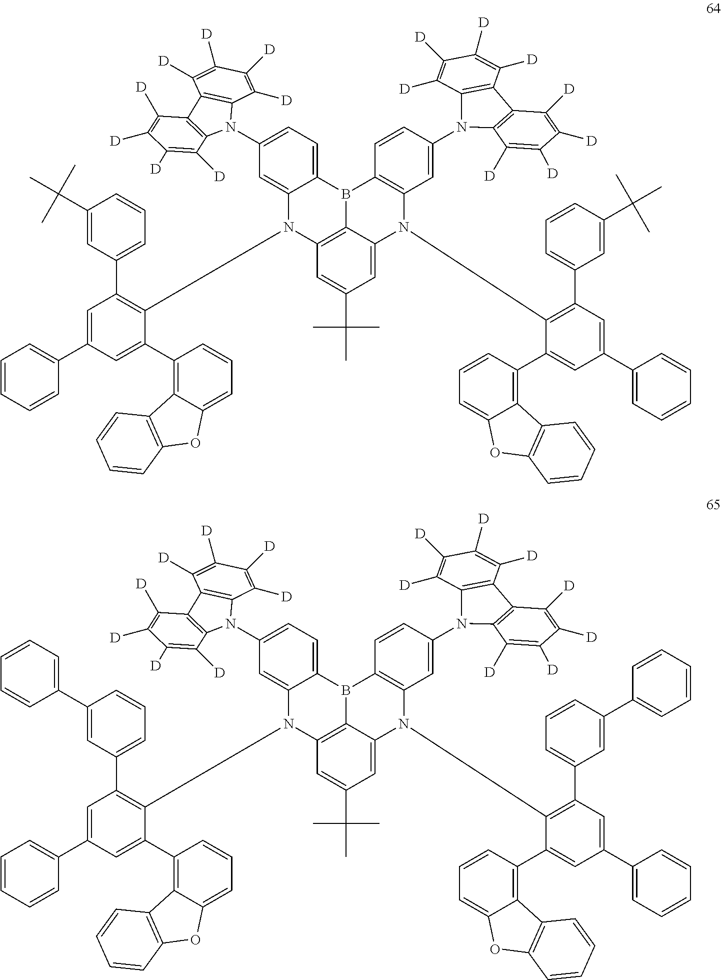

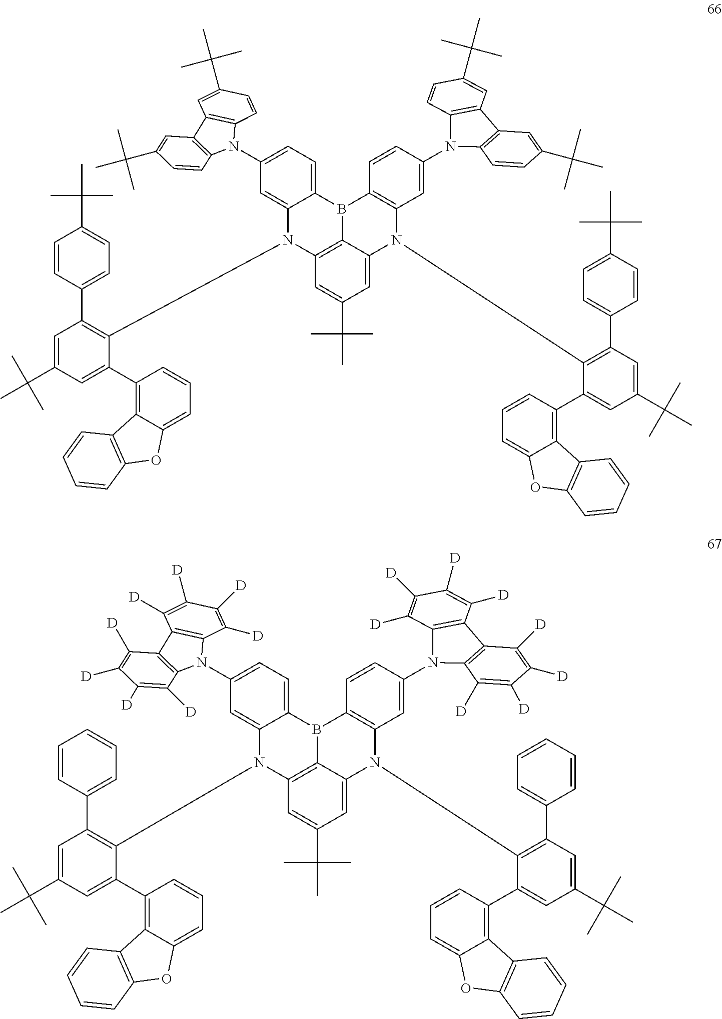

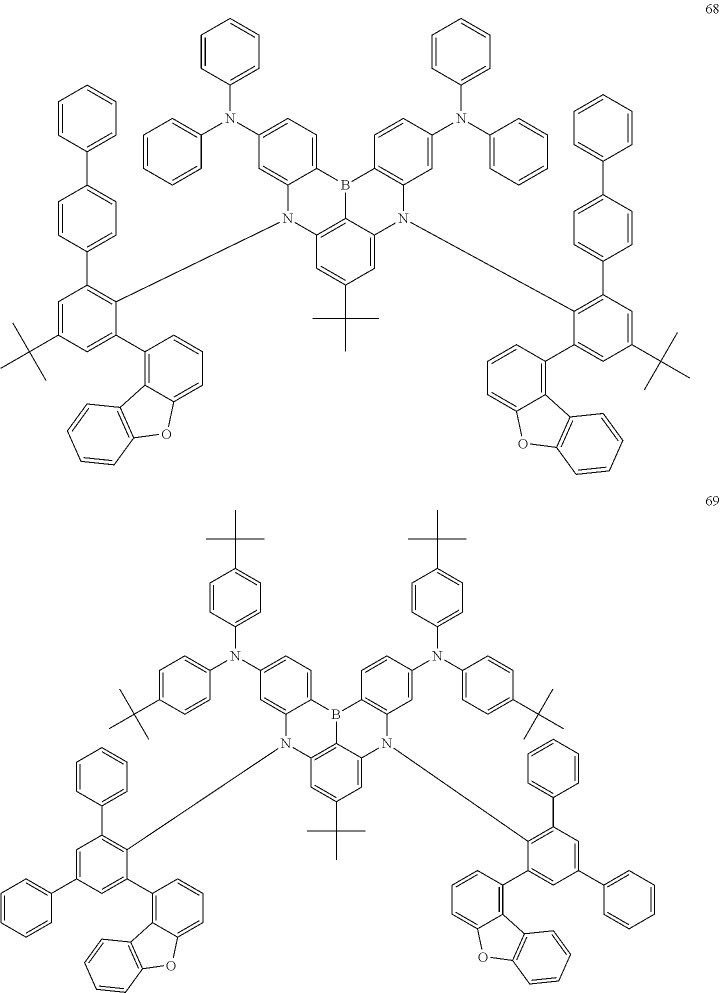 [SMILES: CC(C)(C)c1cc(-c2ccc(-c3ccccc3)cc2)c(N2c3cc(N(c4ccccc4)c4ccccc4)ccc3B3c4ccc(N(c5ccccc5)c5ccccc5)cc4N(c4c(-c5ccc(-c6ccccc6)cc5)cc(C(C)(C)C)cc4-c4cccc5oc6ccccc6c45)c4cc(C(C)(C)C)cc2c43)c(-c2cccc3oc4ccccc4c23)c1 ; CC(C)(C)c1ccc(N(c2ccc(C(C)(C)C)cc2)c2ccc3c(c2)N(c2c(-c4ccccc4)cc(-c4ccccc4)cc2-c2cccc4oc5ccccc5c24)c2cc(C(C)(C)C)cc4c2B3c2ccc(N(c3ccc(C(C)(C)C)cc3)c3ccc(C(C)(C)C)cc3)cc2N4c2c(-c3ccccc3)cc(-c3ccccc3)cc2-c2cccc3oc4ccccc4c23)cc1]

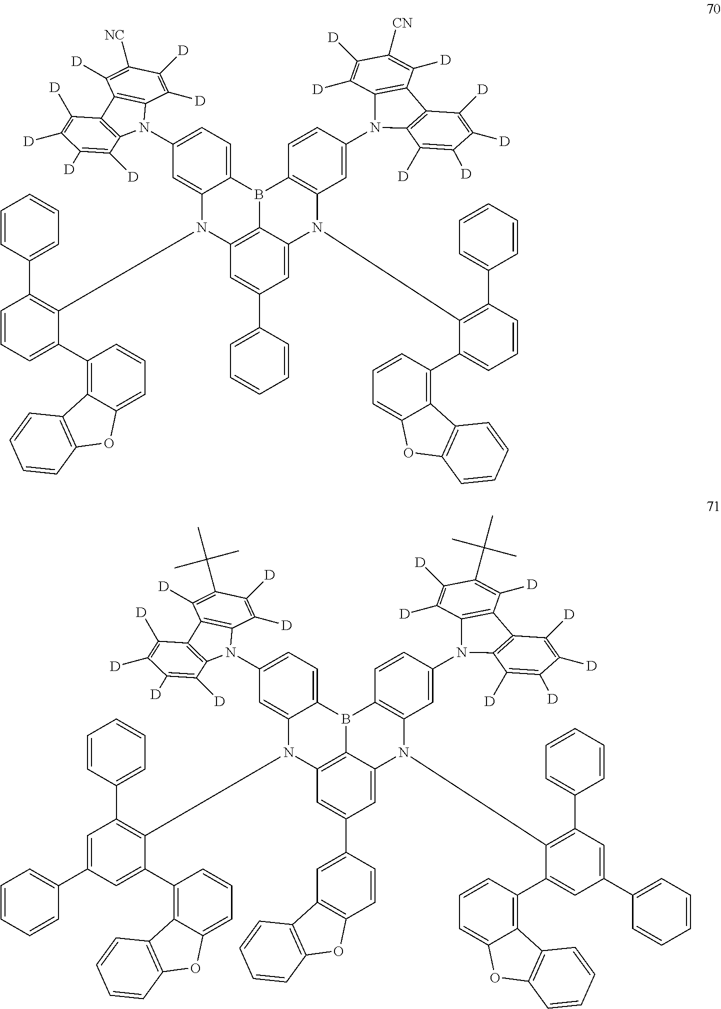

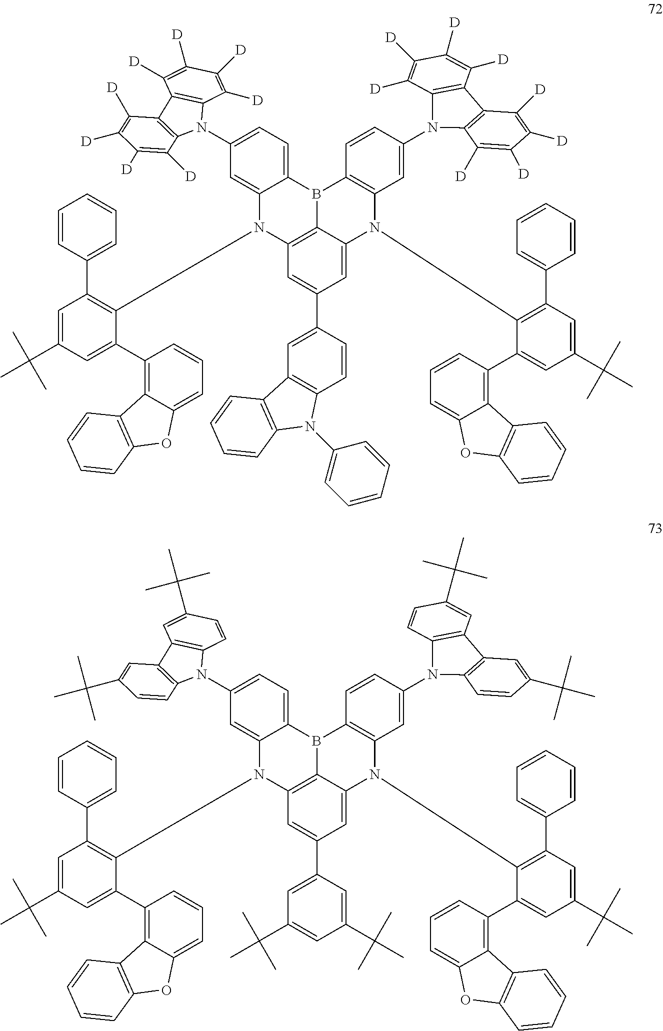

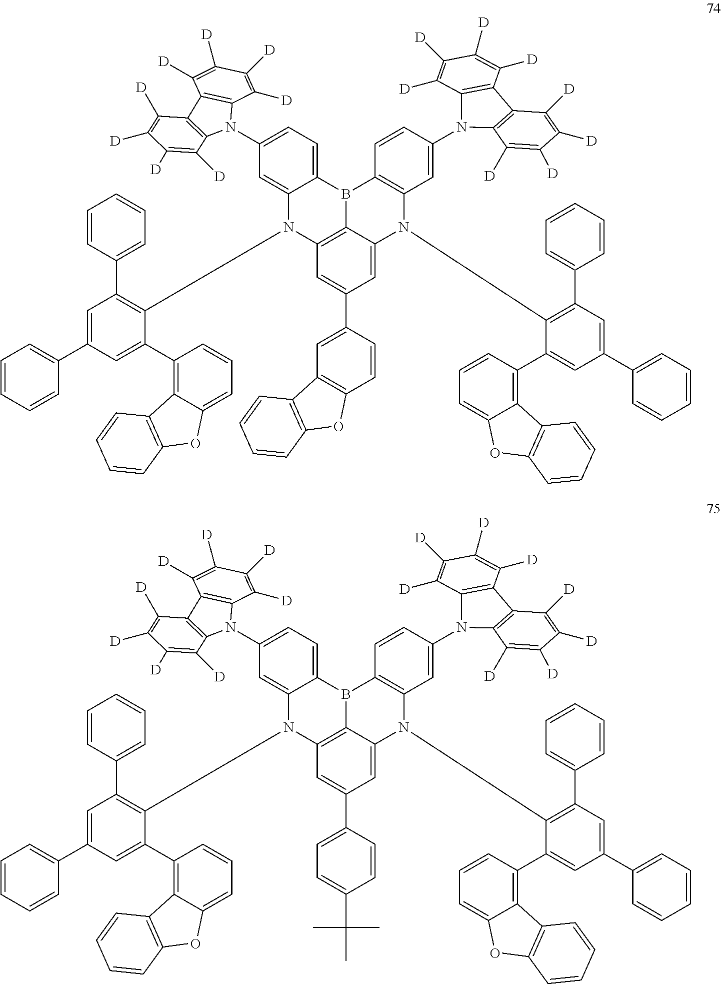

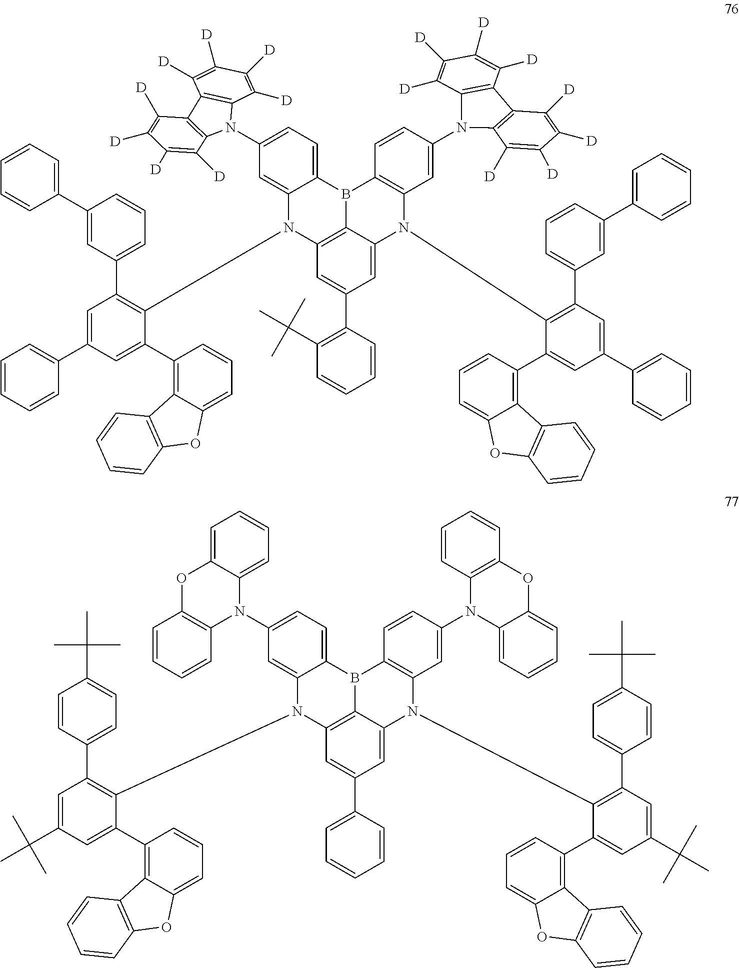

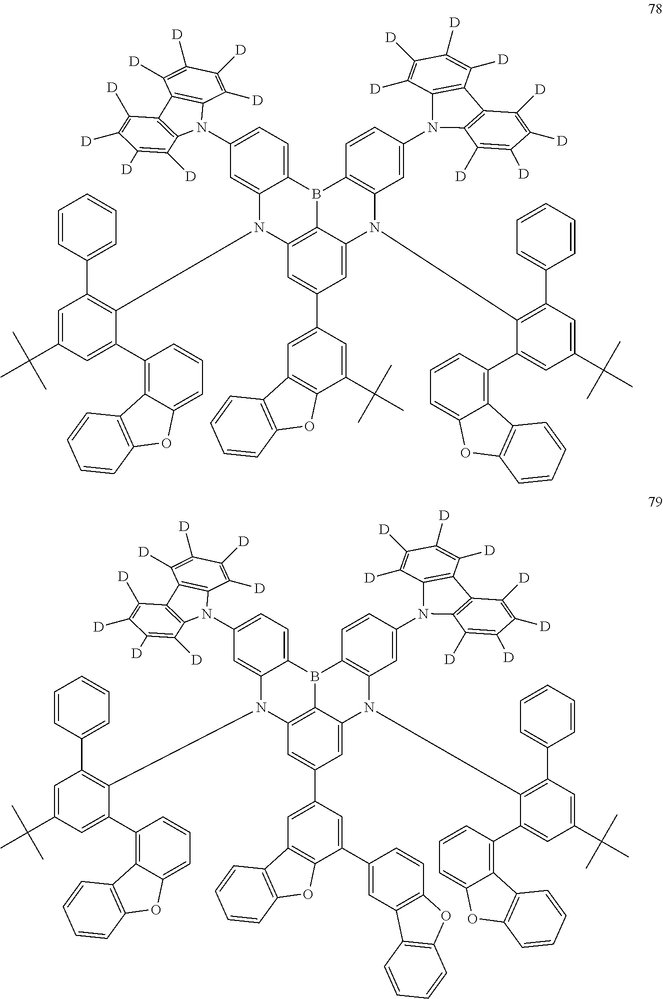

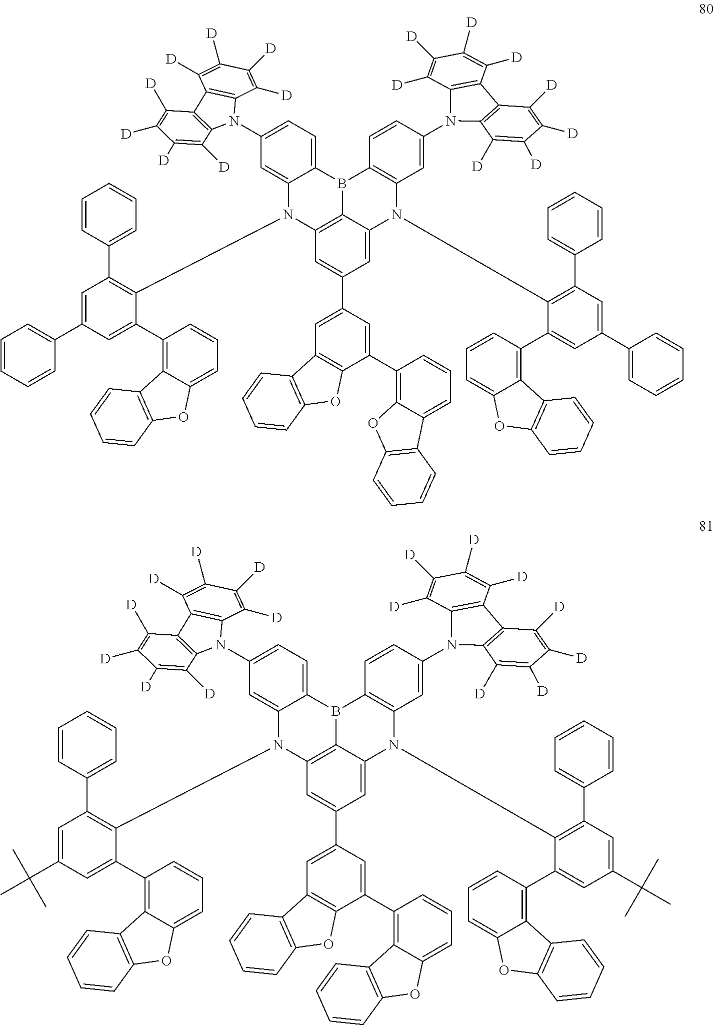

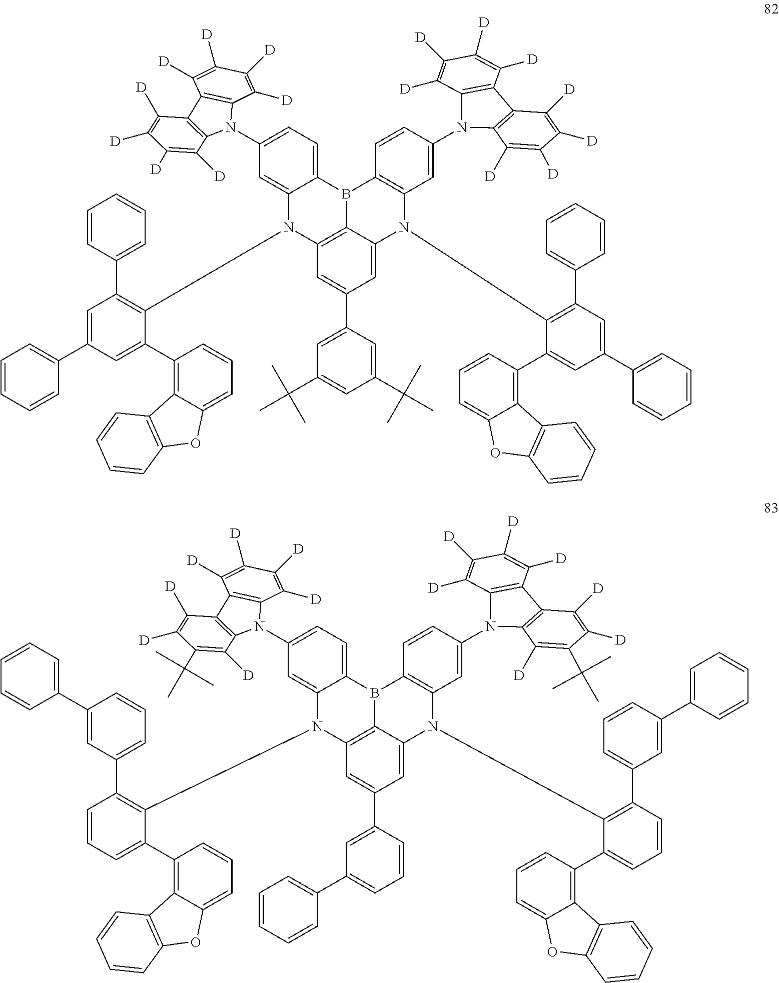

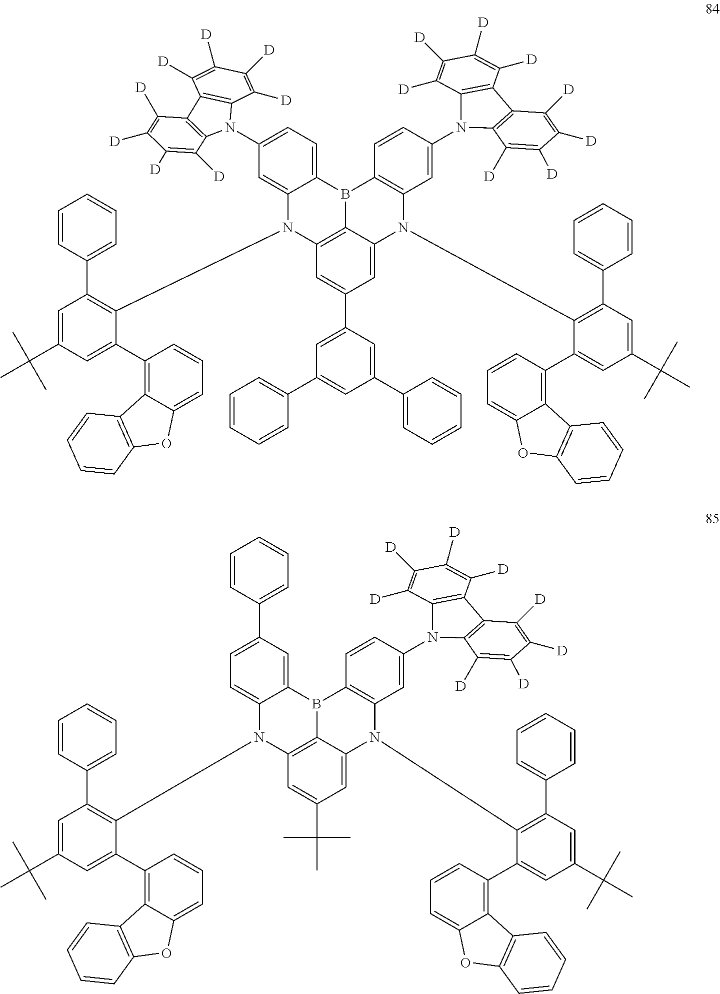

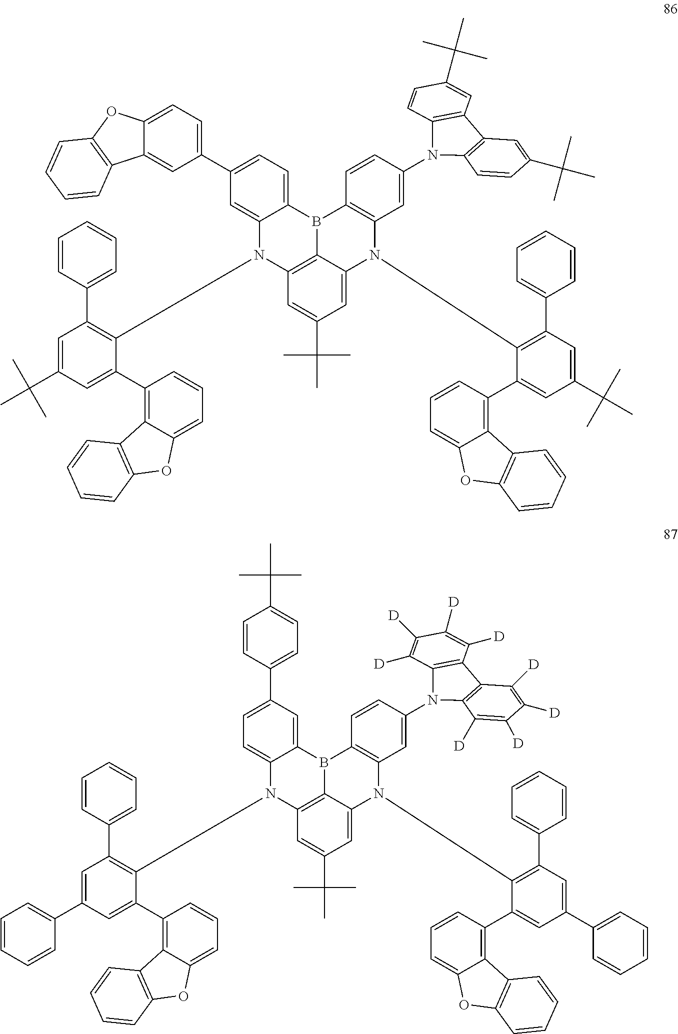 [SMILES: CC(C)(C)c1cc(-c2ccccc2)c(N2c3cc(-c4ccc5oc6ccccc6c5c4)ccc3B3c4ccc(-n5c6ccc(C(C)(C)C)cc6c6cc(C(C)(C)C)ccc65)cc4N(c4c(-c5ccccc5)cc(C(C)(C)C)cc4-c4cccc5oc6ccccc6c45)c4cc(C(C)(C)C)cc2c43)c(-c2cccc3oc4ccccc4c23)c1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3oc4ccccc4c13)c1cc(C(C)(C)C)cc3c1B2c1cc(-c2ccc(C(C)(C)C)cc2)ccc1N3c1c(-c2ccccc2)cc(-c2ccccc2)cc1-c1cccc2oc3ccccc3c12]

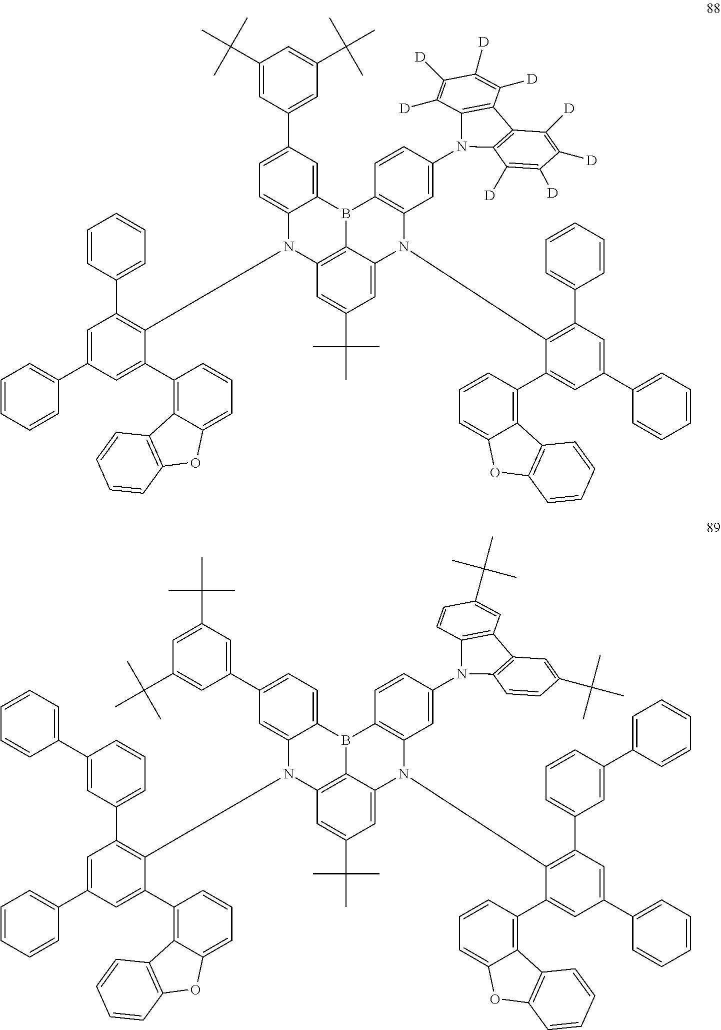 [SMILES: [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3oc4ccccc4c13)c1cc(C(C)(C)C)cc3c1B2c1cc(-c2cc(C(C)(C)C)cc(C(C)(C)C)c2)ccc1N3c1c(-c2ccccc2)cc(-c2ccccc2)cc1-c1cccc2oc3ccccc3c12 ; CC(C)(C)c1cc(-c2ccc3c(c2)N(c2c(-c4cccc(-c5ccccc5)c4)cc(-c4ccccc4)cc2-c2cccc4oc5ccccc5c24)c2cc(C(C)(C)C)cc4c2B3c2ccc(-n3c5ccc(C(C)(C)C)cc5c5cc(C(C)(C)C)ccc53)cc2N4c2c(-c3cccc(-c4ccccc4)c3)cc(-c3ccccc3)cc2-c2cccc3oc4ccccc4c23)cc(C(C)(C)C)c1]

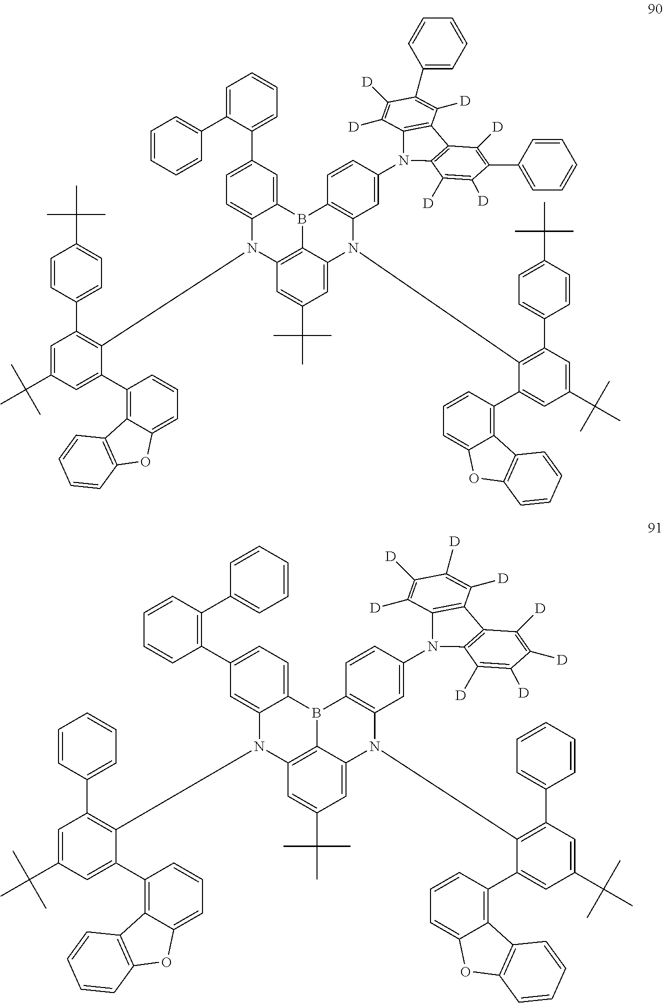

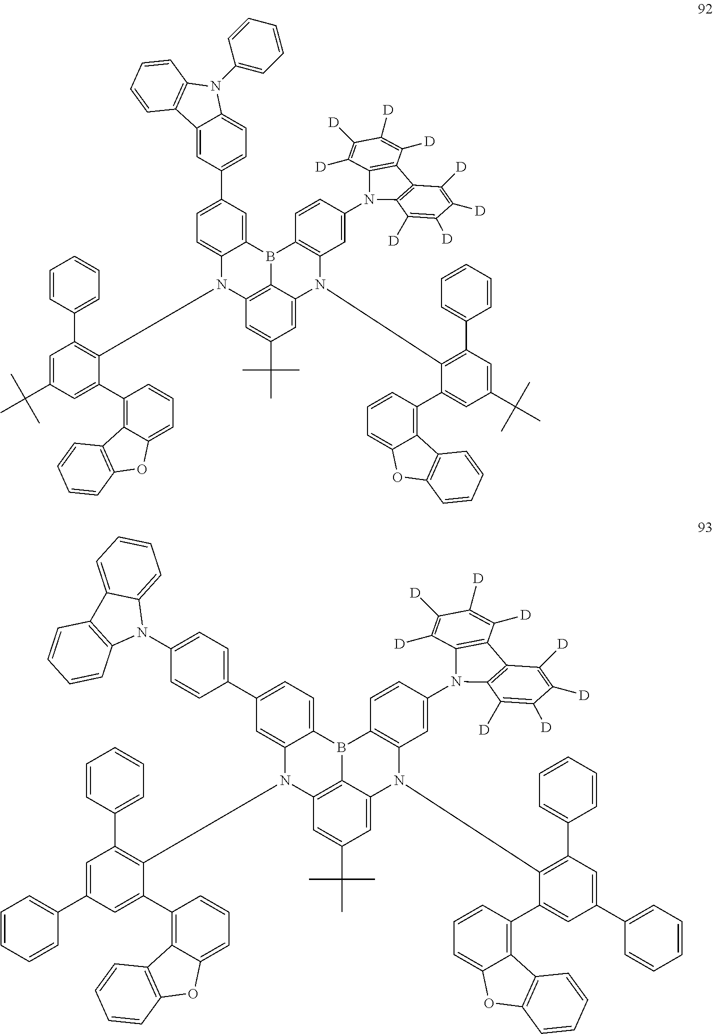 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc3oc4ccccc4c13)c1cc(C(C)(C)C)cc3c1B2c1cc(-c2ccc4c(c2)c2ccccc2n4-c2ccccc2)ccc1N3c1c(-c2ccccc2)cc(C(C)(C)C)cc1-c1cccc2oc3ccccc3c12 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3oc4ccccc4c13)c1cc(C(C)(C)C)cc3c1B2c1ccc(-c2ccc(-n4c5ccccc5c5ccccc54)cc2)cc1N3c1c(-c2ccccc2)cc(-c2ccccc2)cc1-c1cccc2oc3ccccc3c12]

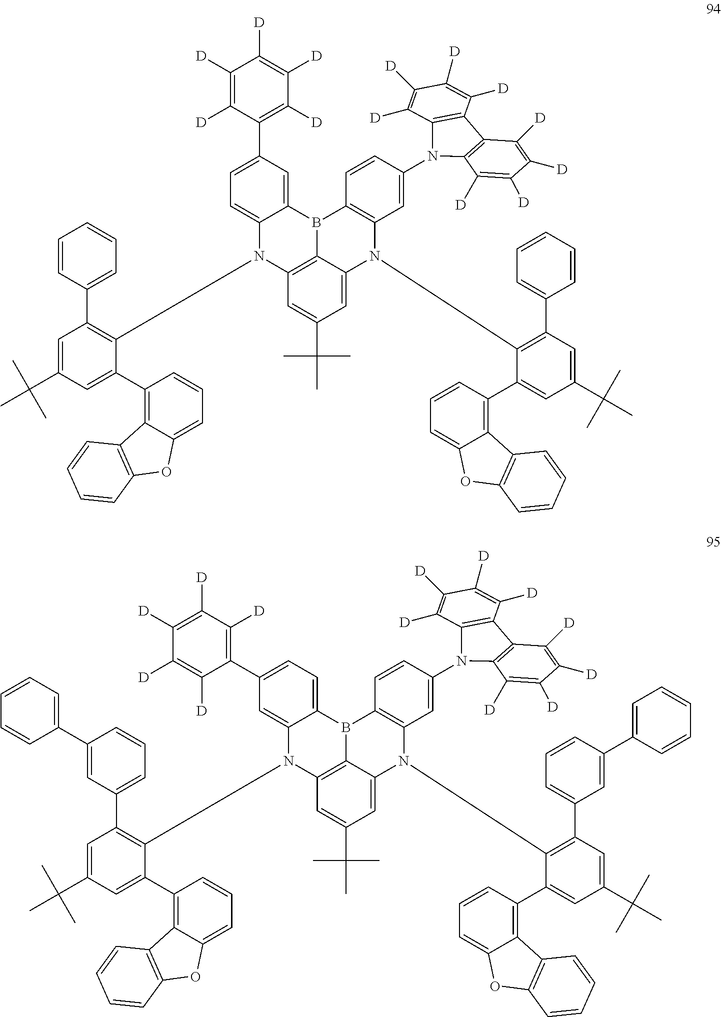

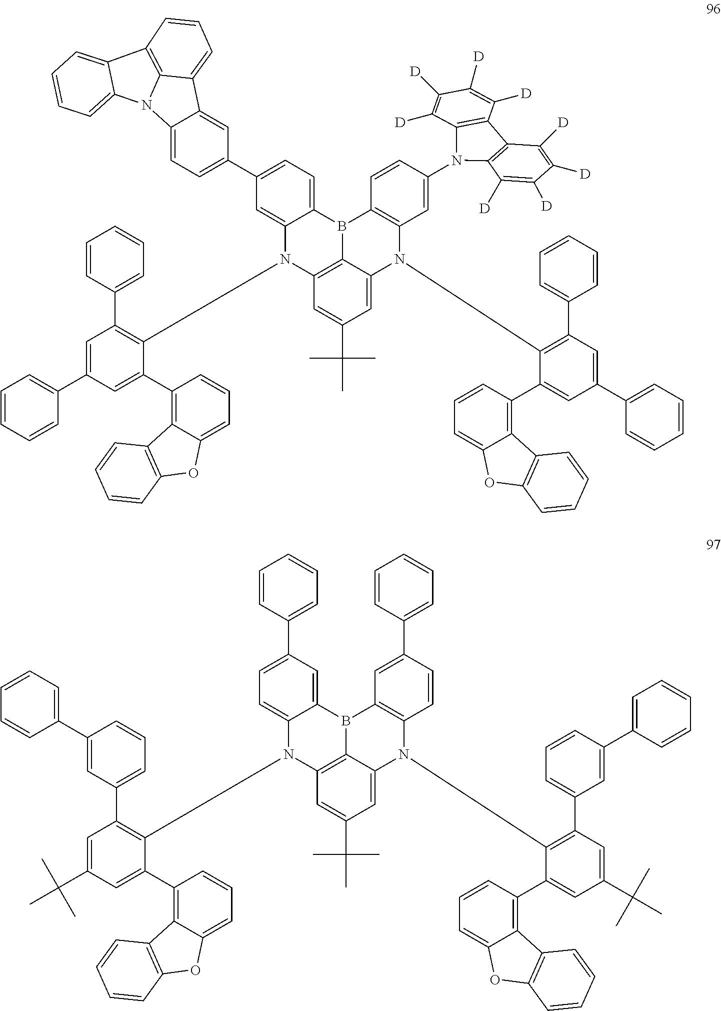 [SMILES: [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3oc4ccccc4c13)c1cc(C(C)(C)C)cc3c1B2c1ccc(-c2ccc4c(c2)c2cccc5c6ccccc6n4c52)cc1N3c1c(-c2ccccc2)cc(-c2ccccc2)cc1-c1cccc2oc3ccccc3c12 ; CC(C)(C)c1cc(-c2cccc(-c3ccccc3)c2)c(N2c3ccc(-c4ccccc4)cc3B3c4cc(-c5ccccc5)ccc4N(c4c(-c5cccc(-c6ccccc6)c5)cc(C(C)(C)C)cc4-c4cccc5oc6ccccc6c45)c4cc(C(C)(C)C)cc2c43)c(-c2cccc3oc4ccccc4c23)c1]

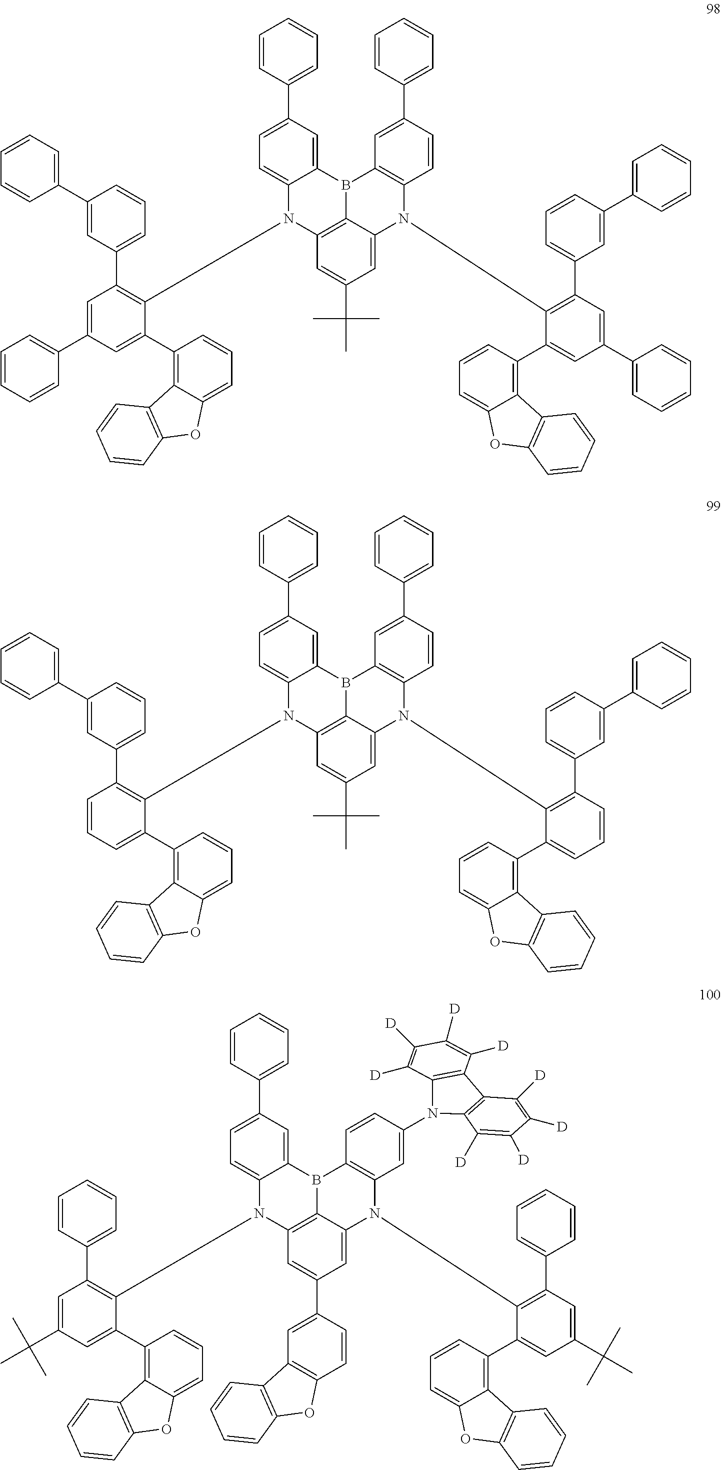

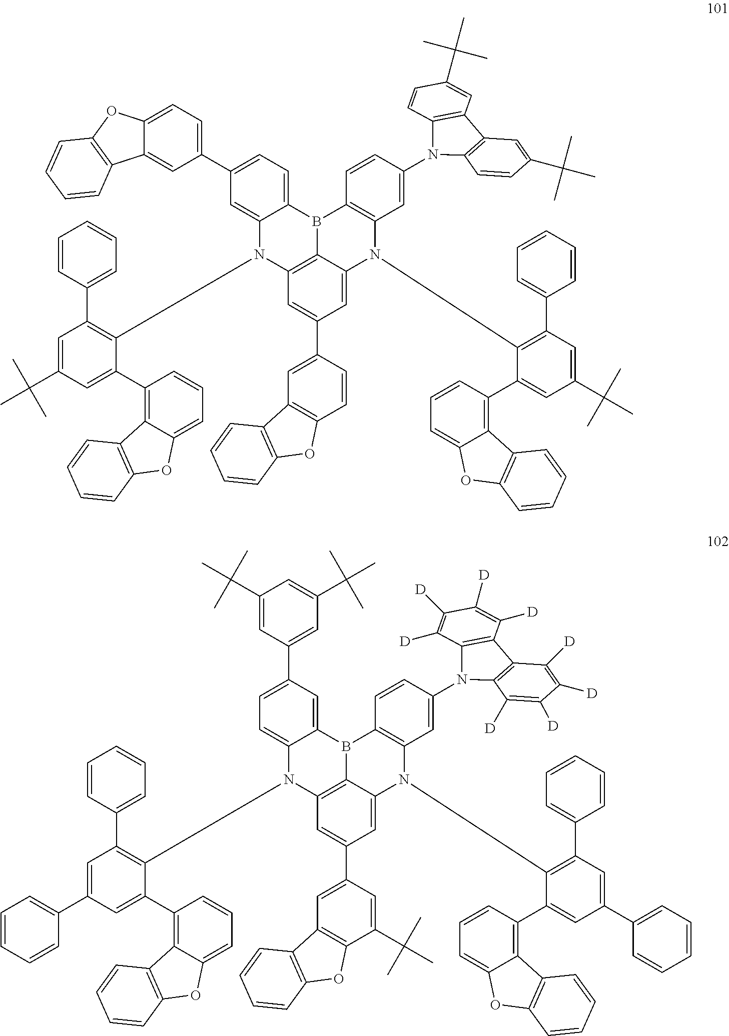 [SMILES: CC(C)(C)c1cc(-c2ccccc2)c(N2c3cc(-c4ccc5oc6ccccc6c5c4)ccc3B3c4ccc(-n5c6ccc(C(C)(C)C)cc6c6cc(C(C)(C)C)ccc65)cc4N(c4c(-c5ccccc5)cc(C(C)(C)C)cc4-c4cccc5oc6ccccc6c45)c4cc(-c5ccc6oc7ccccc7c6c5)cc2c43)c(-c2cccc3oc4ccccc4c23)c1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3oc4ccccc4c13)c1cc(-c3cc(C(C)(C)C)c4oc5ccccc5c4c3)cc3c1B2c1cc(-c2cc(C(C)(C)C)cc(C(C)(C)C)c2)ccc1N3c1c(-c2ccccc2)cc(-c2ccccc2)cc1-c1cccc2oc3ccccc3c12]

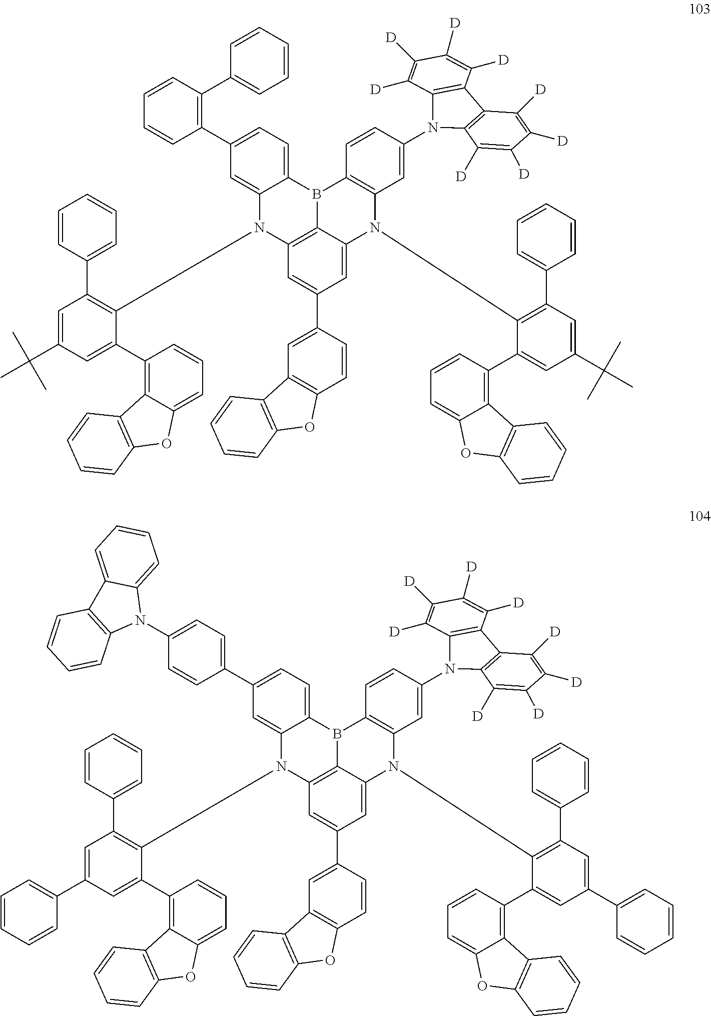 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc3oc4ccccc4c13)c1cc(-c3ccc4oc5ccccc5c4c3)cc3c1B2c1ccc(-c2ccccc2-c2ccccc2)cc1N3c1c(-c2ccccc2)cc(C(C)(C)C)cc1-c1cccc2oc3ccccc3c12 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3oc4ccccc4c13)c1cc(-c3ccc4oc5ccccc5c4c3)cc3c1B2c1ccc(-c2ccc(-n4c5ccccc5c5ccccc54)cc2)cc1N3c1c(-c2ccccc2)cc(-c2ccccc2)cc1-c1cccc2oc3ccccc3c12]

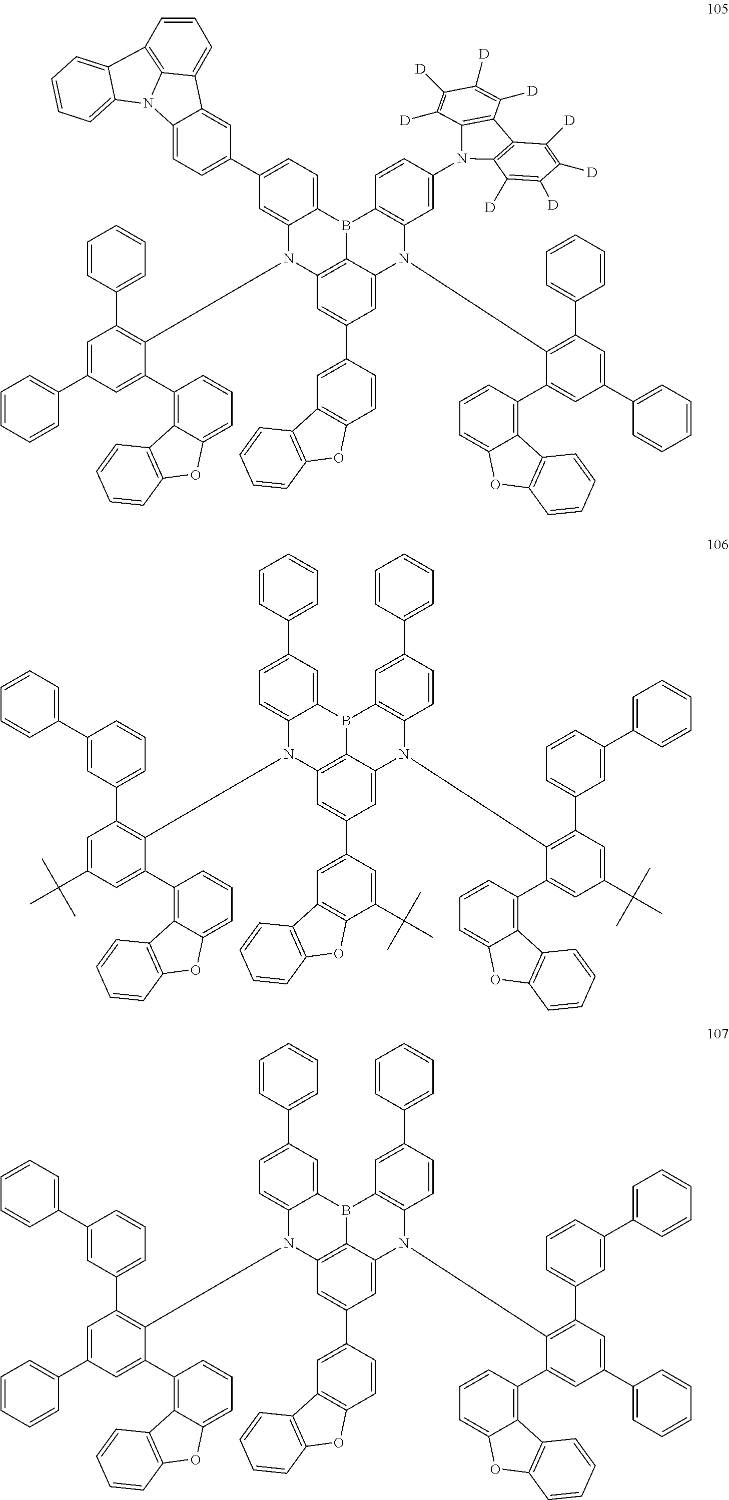

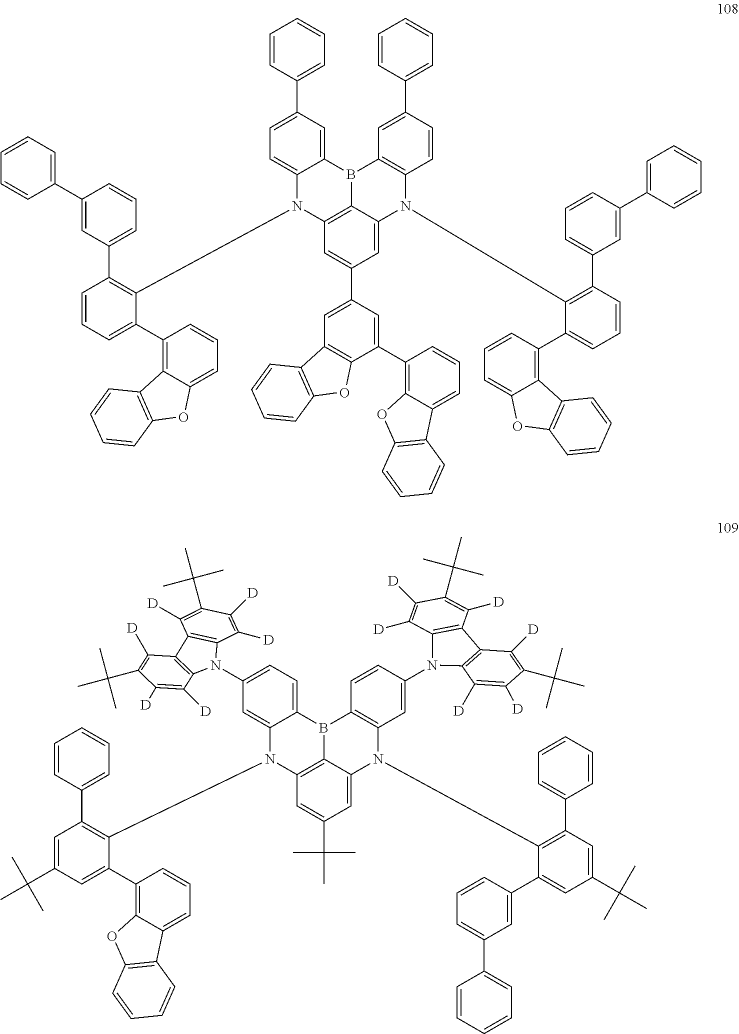 [SMILES: c1ccc(-c2cccc(-c3cccc(-c4cccc5oc6ccccc6c45)c3N3c4ccc(-c5ccccc5)cc4B4c5cc(-c6ccccc6)ccc5N(c5c(-c6cccc(-c7ccccc7)c6)cccc5-c5cccc6oc7ccccc7c56)c5cc(-c6cc(-c7cccc8c7oc7ccccc78)c7oc8ccccc8c7c6)cc3c54)c2)cc1 ; [2H]c1c(C(C)(C)C)c([2H])c2c3c([2H])c(C(C)(C)C)c([2H])c([2H])c3n(-c3ccc4c(c3)N(c3c(-c5ccccc5)cc(C(C)(C)C)cc3-c3cccc(-c5ccccc5)c3)c3cc(C(C)(C)C)cc5c3B4c3ccc(-n4c6c([2H])c([2H])c(C(C)(C)C)c([2H])c6c6c([2H])c(C(C)(C)C)c([2H])c([2H])c64)cc3N5c3c(-c4ccccc4)cc(C(C)(C)C)cc3-c3cccc4c3oc3ccccc34)c2c1[2H]]

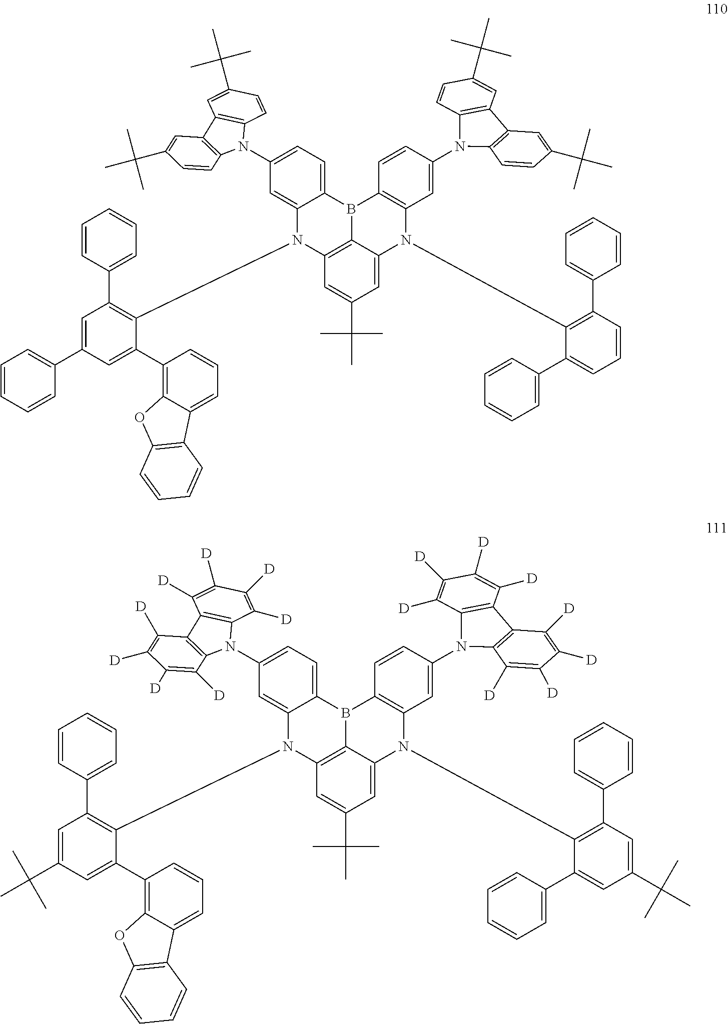 [SMILES: CC(C)(C)c1cc2c3c(c1)N(c1c(-c4ccccc4)cc(-c4ccccc4)cc1-c1cccc4c1oc1ccccc14)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1cccc2c1oc1ccccc12]

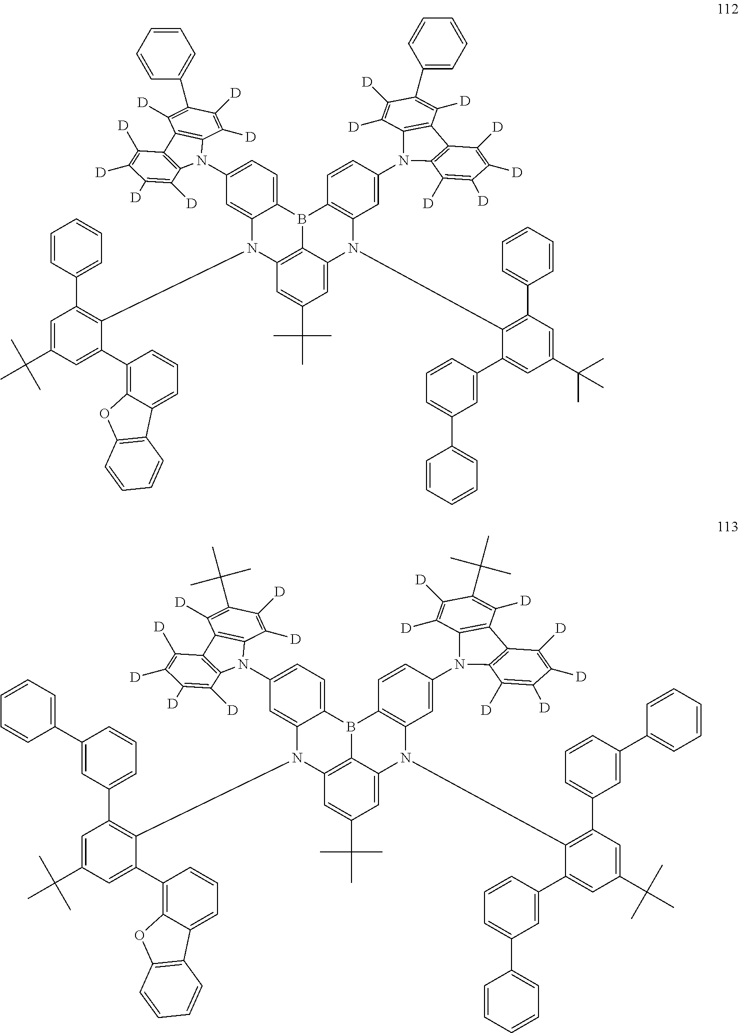

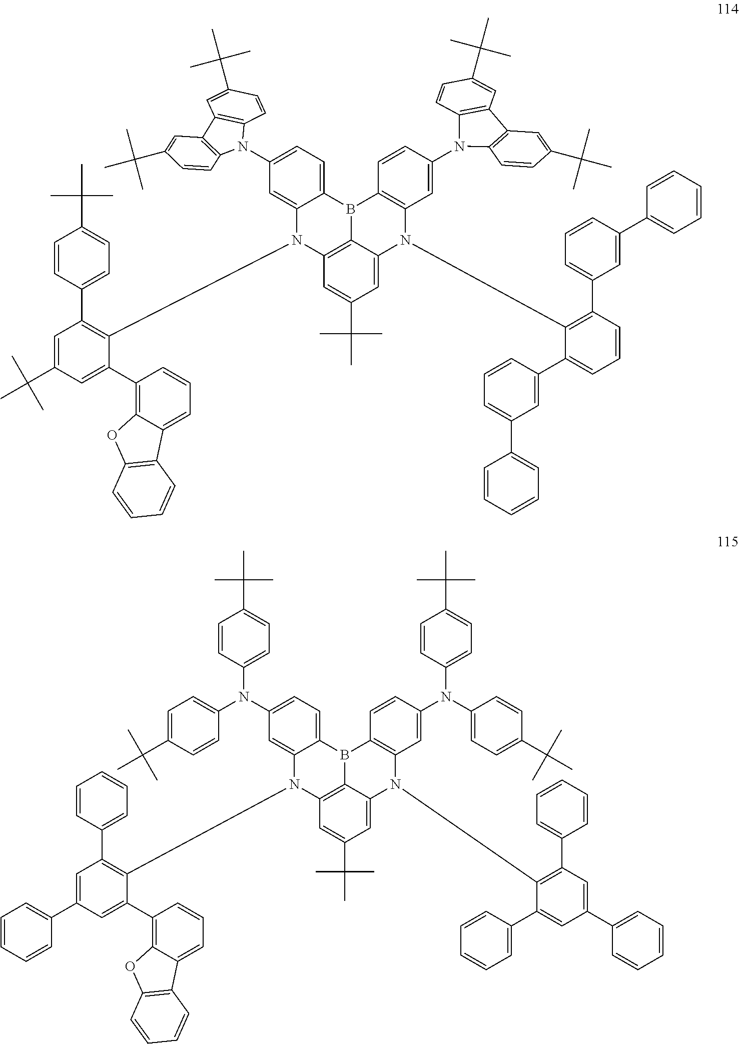 [SMILES: CC(C)(C)c1ccc(-c2cc(C(C)(C)C)cc(-c3cccc4c3oc3ccccc34)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5cccc(-c6ccccc6)c5)cccc4-c4cccc(-c5ccccc5)c4)c4cc(C(C)(C)C)cc2c43)cc1 ; CC(C)(C)c1ccc(N(c2ccc(C(C)(C)C)cc2)c2ccc3c(c2)N(c2c(-c4ccccc4)cc(-c4ccccc4)cc2-c2ccccc2)c2cc(C(C)(C)C)cc4c2B3c2ccc(N(c3ccc(C(C)(C)C)cc3)c3ccc(C(C)(C)C)cc3)cc2N4c2c(-c3ccccc3)cc(-c3ccccc3)cc2-c2cccc3c2oc2ccccc23)cc1]

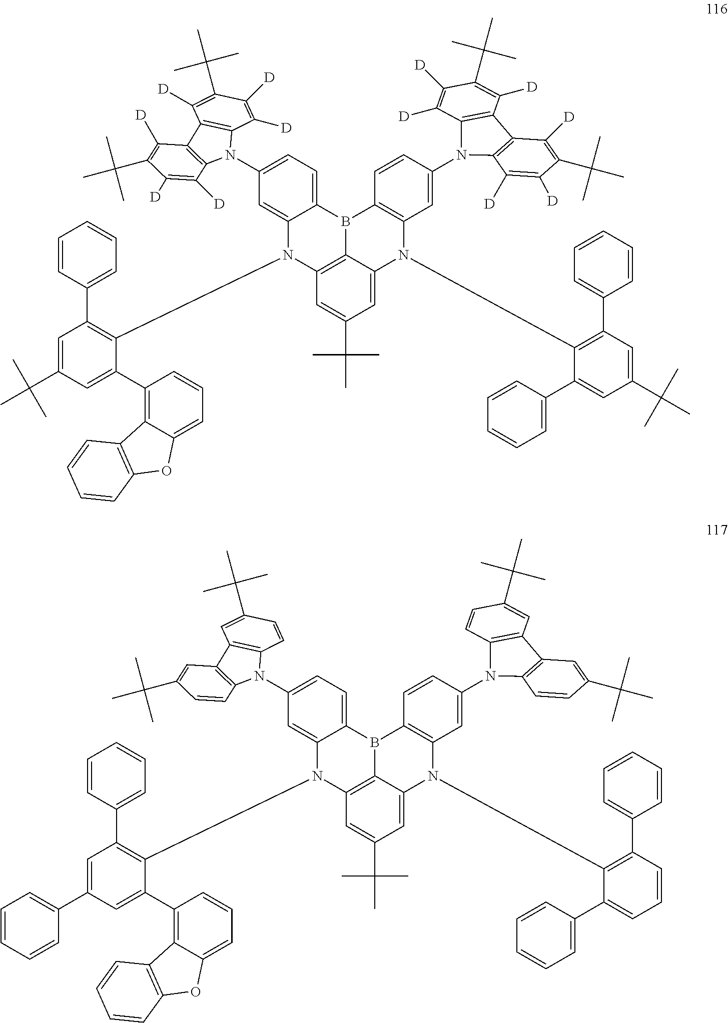 [SMILES: [2H]c1c(C(C)(C)C)c([2H])c2c3c([2H])c(C(C)(C)C)c([2H])c([2H])c3n(-c3ccc4c(c3)N(c3c(-c5ccccc5)cc(C(C)(C)C)cc3-c3ccccc3)c3cc(C(C)(C)C)cc5c3B4c3ccc(-n4c6c([2H])c([2H])c(C(C)(C)C)c([2H])c6c6c([2H])c(C(C)(C)C)c([2H])c([2H])c64)cc3N5c3c(-c4ccccc4)cc(C(C)(C)C)cc3-c3cccc4oc5ccccc5c34)c2c1[2H] ; CC(C)(C)c1cc2c3c(c1)N(c1c(-c4ccccc4)cc(-c4ccccc4)cc1-c1cccc4oc5ccccc5c14)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1c(-c2ccccc2)cccc1-c1ccccc1]

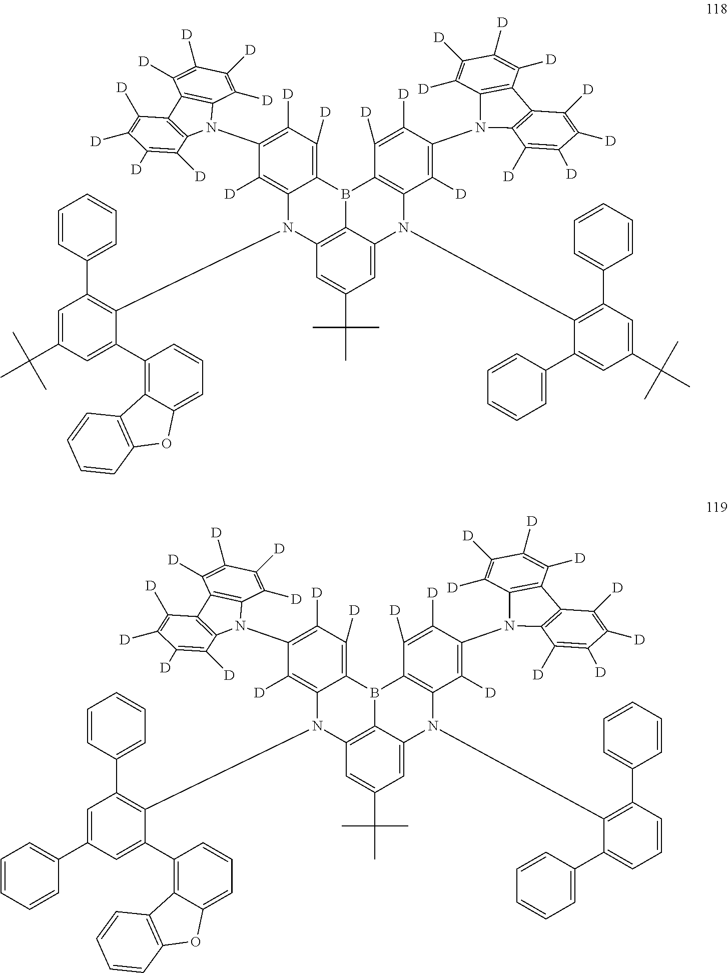

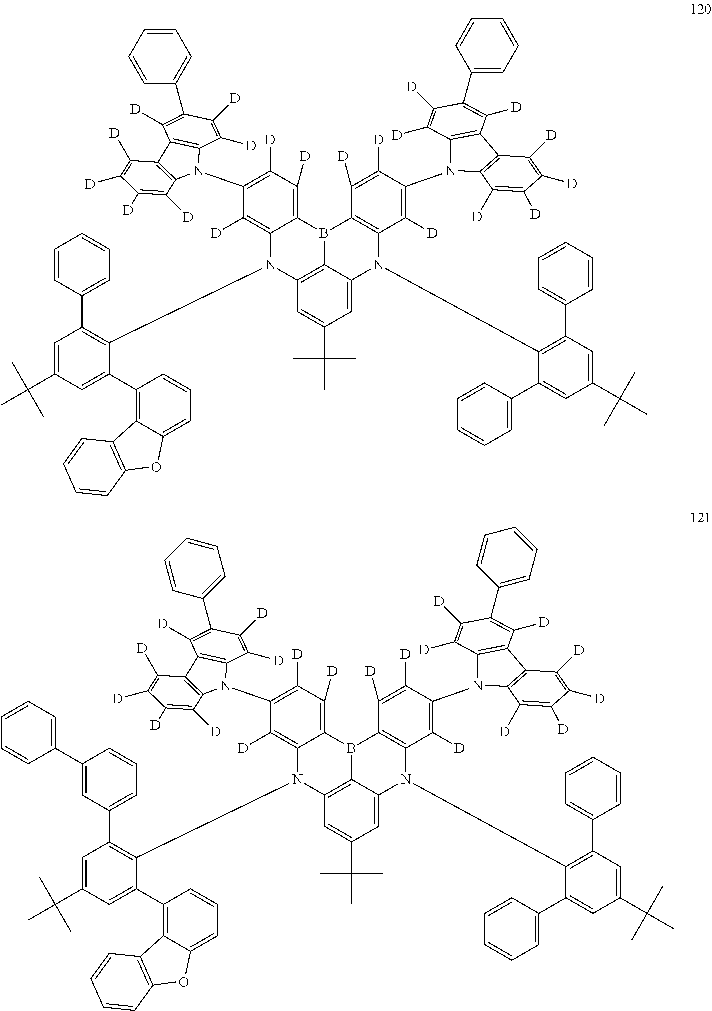

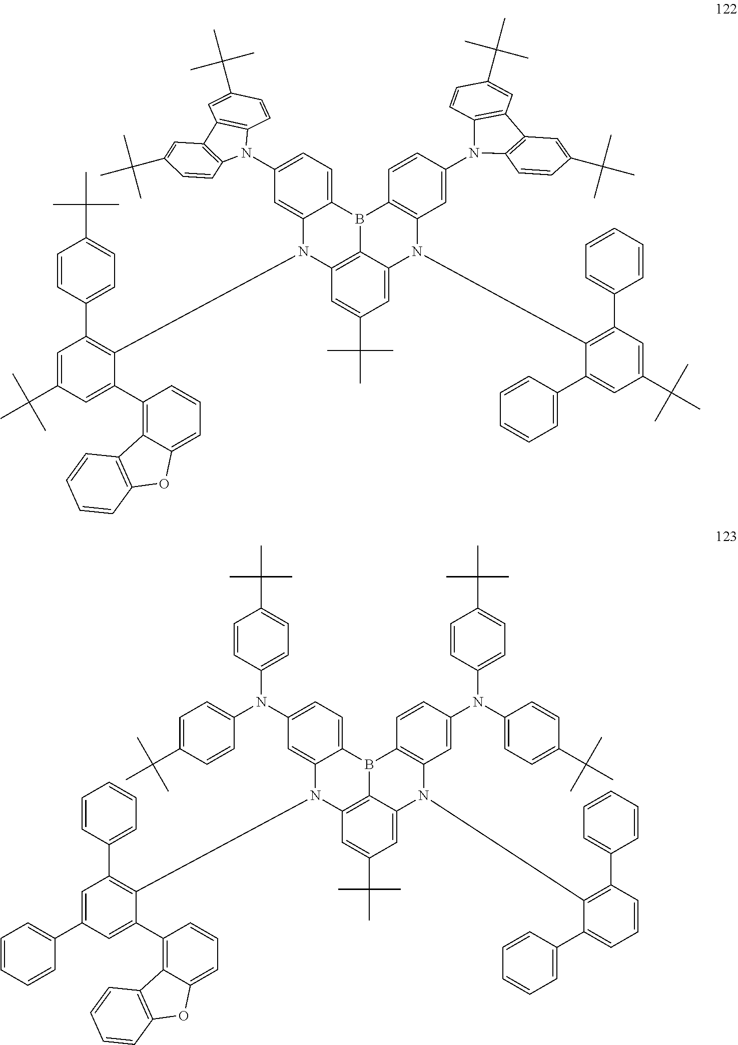 [SMILES: CC(C)(C)c1ccc(-c2cc(C(C)(C)C)cc(-c3cccc4oc5ccccc5c34)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(C(C)(C)C)cc2c43)cc1 ; CC(C)(C)c1ccc(N(c2ccc(C(C)(C)C)cc2)c2ccc3c(c2)N(c2c(-c4ccccc4)cccc2-c2ccccc2)c2cc(C(C)(C)C)cc4c2B3c2ccc(N(c3ccc(C(C)(C)C)cc3)c3ccc(C(C)(C)C)cc3)cc2N4c2c(-c3ccccc3)cc(-c3ccccc3)cc2-c2cccc3oc4ccccc4c23)cc1]

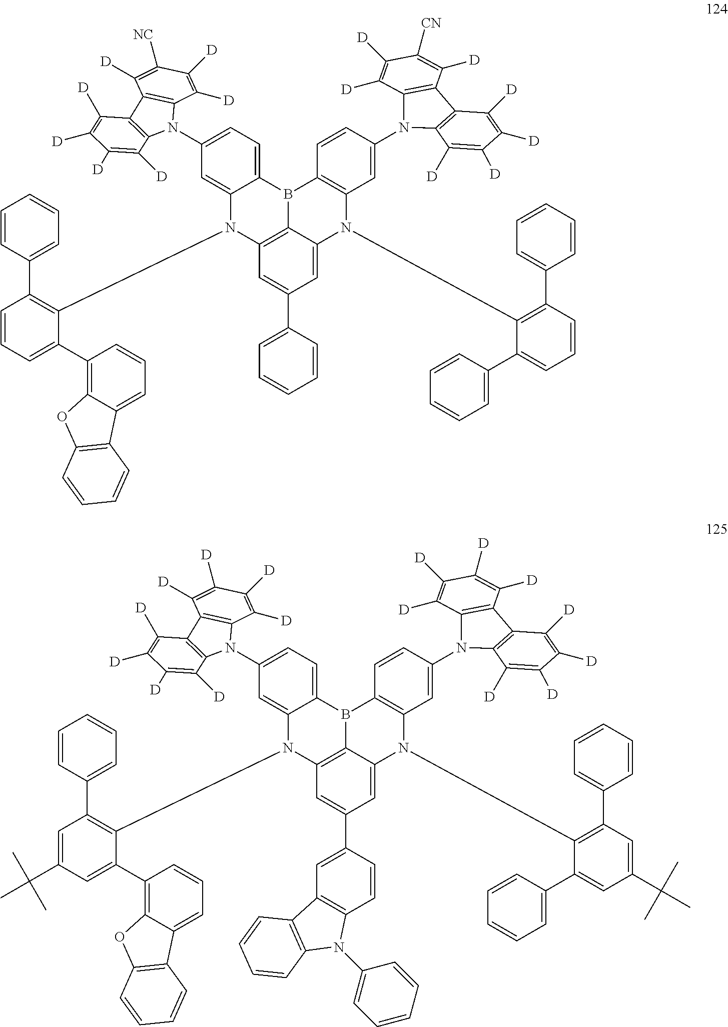

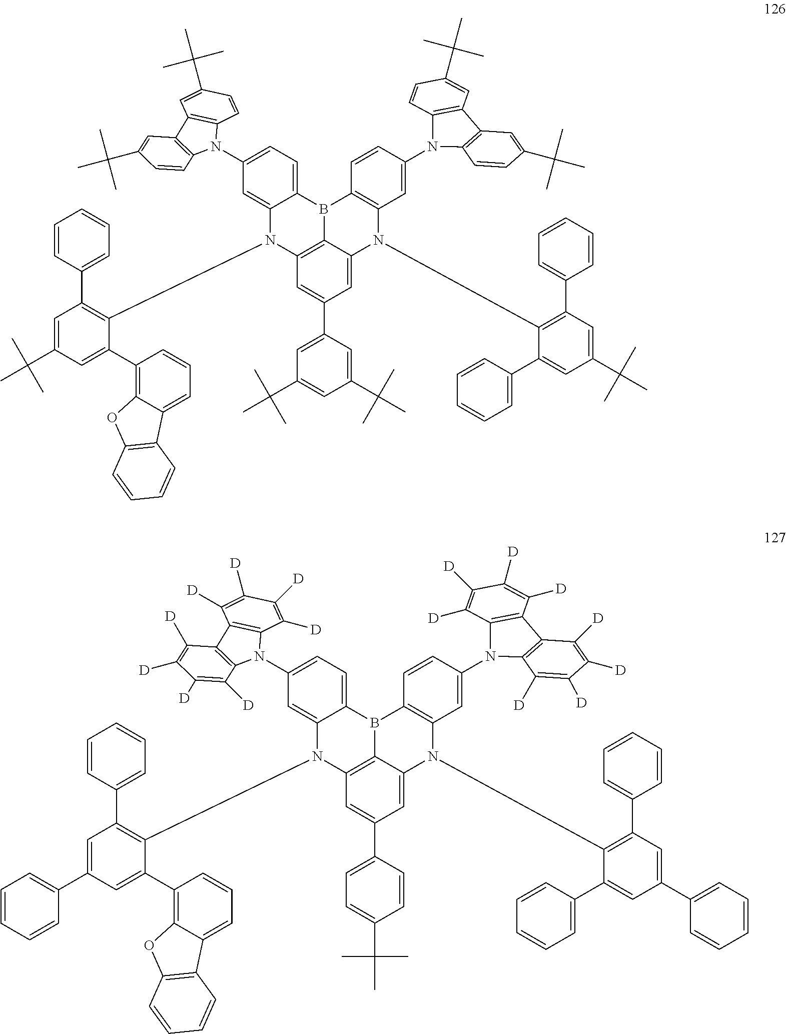

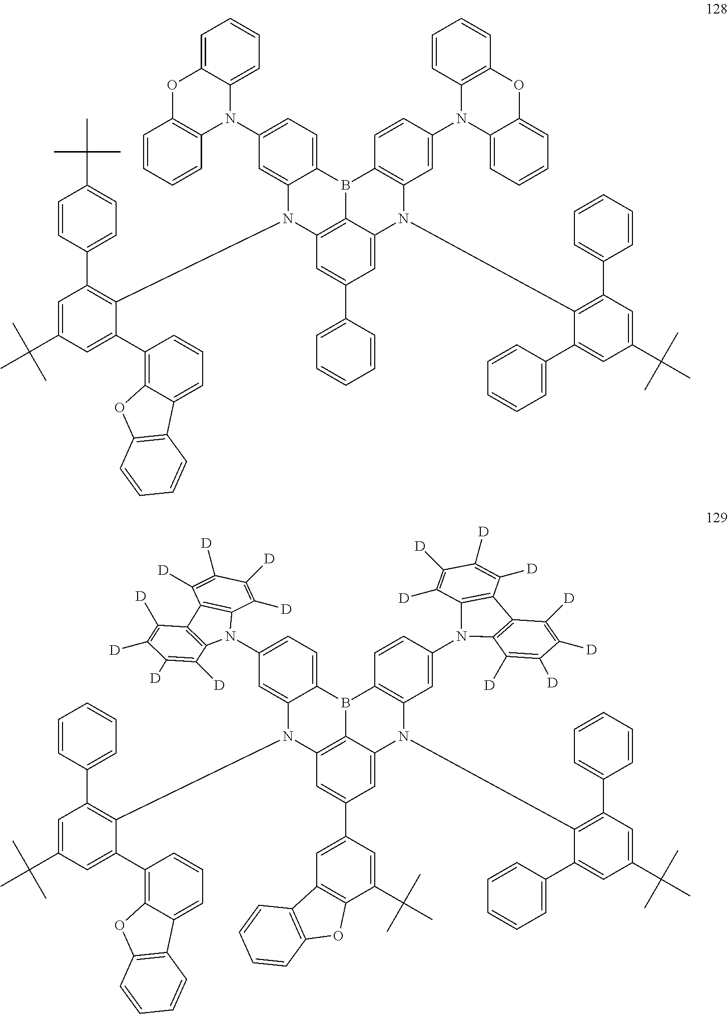

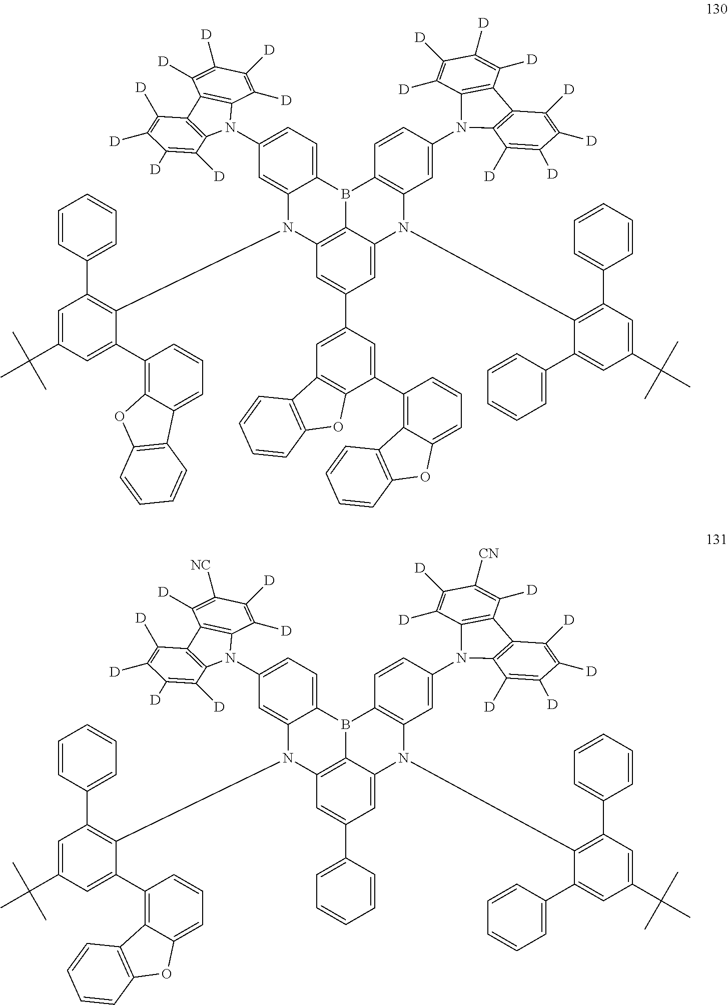

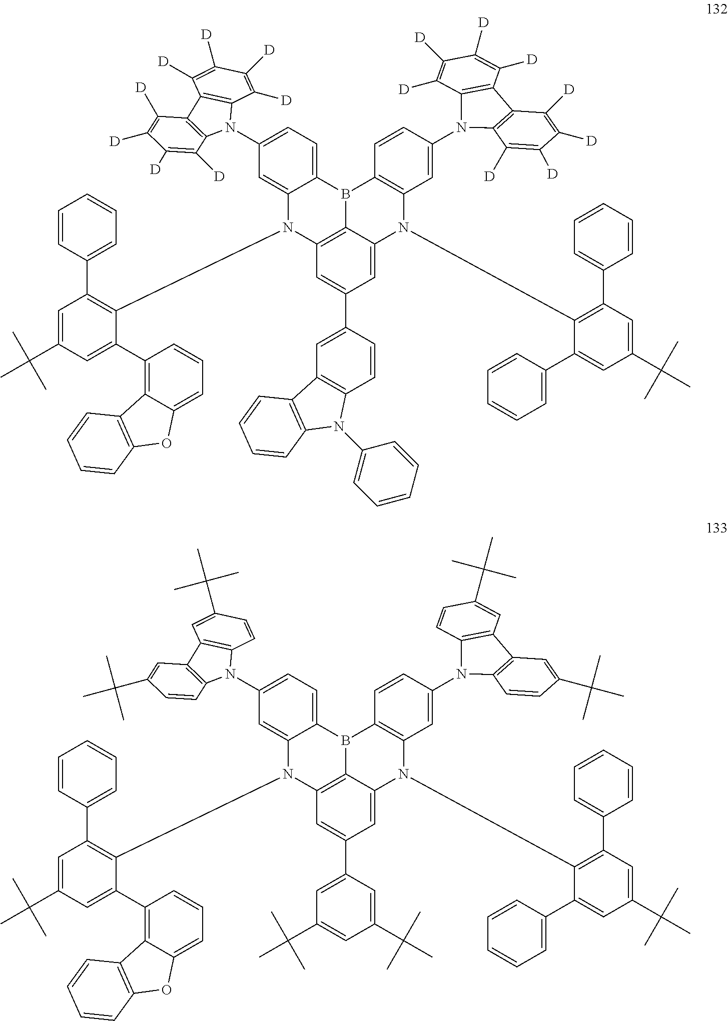

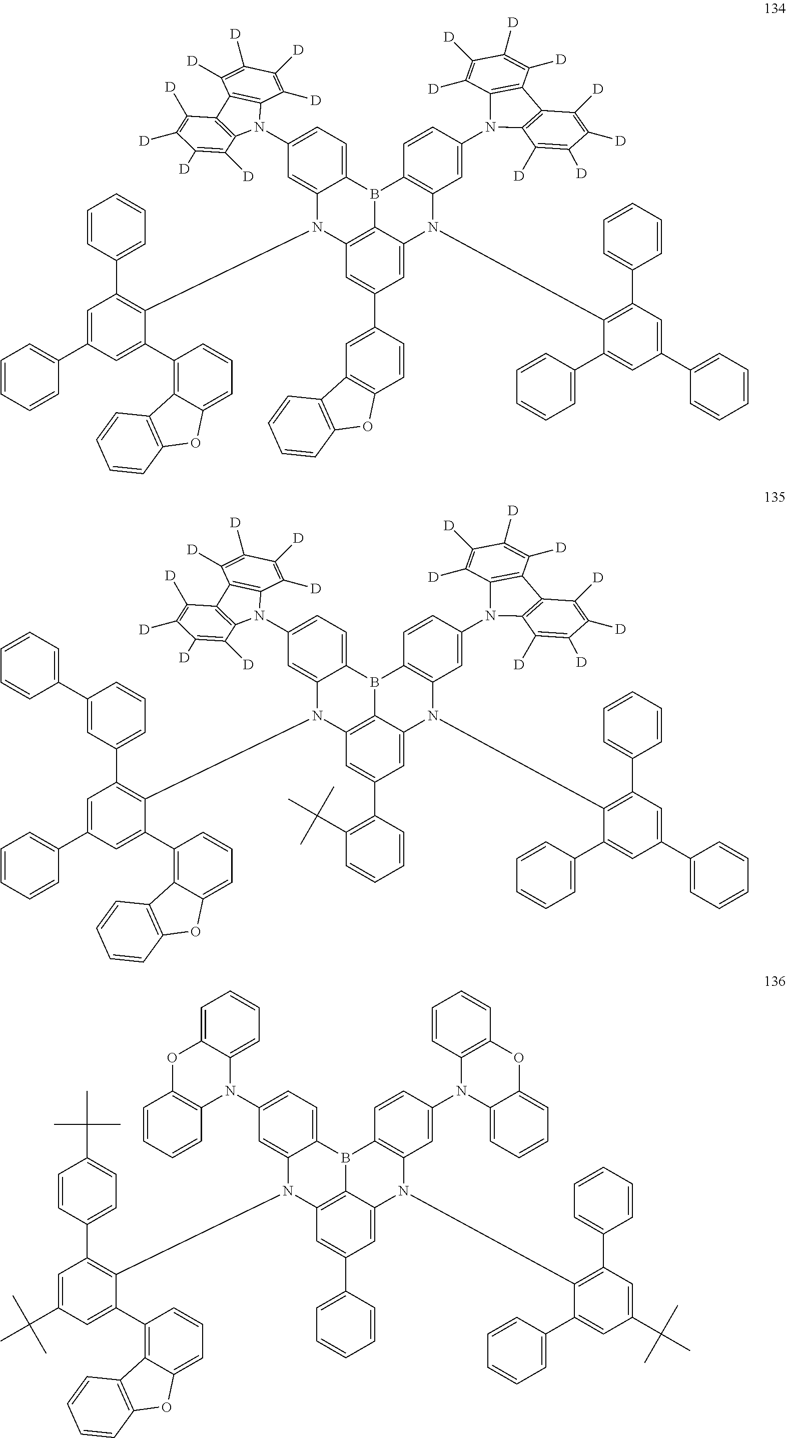

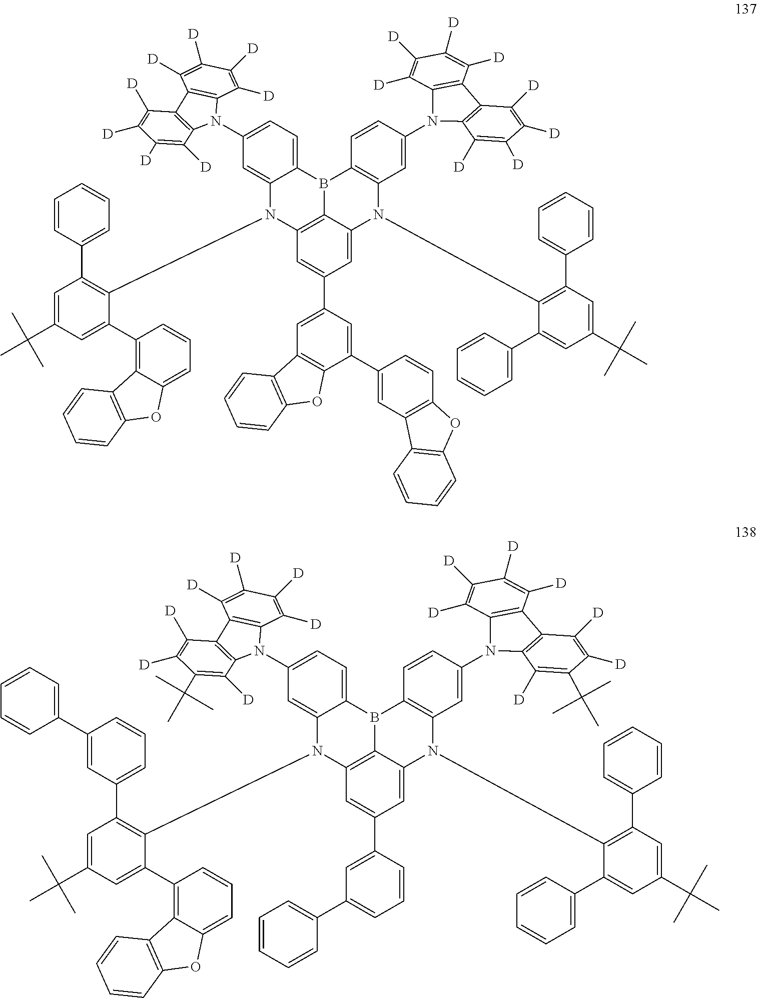

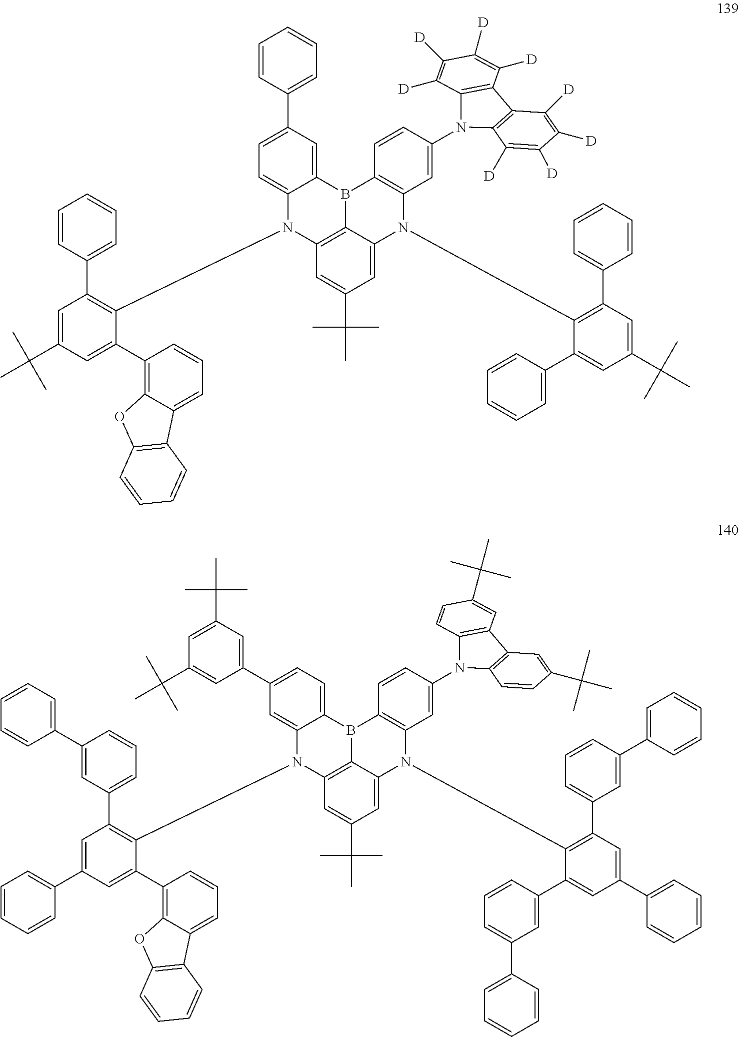 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2ccccc2)ccc1N3c1c(-c2ccccc2)cc(C(C)(C)C)cc1-c1cccc2c1oc1ccccc12 ; CC(C)(C)c1cc(-c2ccc3c(c2)N(c2c(-c4cccc(-c5ccccc5)c4)cc(-c4ccccc4)cc2-c2cccc4c2oc2ccccc24)c2cc(C(C)(C)C)cc4c2B3c2ccc(-n3c5ccc(C(C)(C)C)cc5c5cc(C(C)(C)C)ccc53)cc2N4c2c(-c3cccc(-c4ccccc4)c3)cc(-c3ccccc3)cc2-c2cccc(-c3ccccc3)c2)cc(C(C)(C)C)c1]

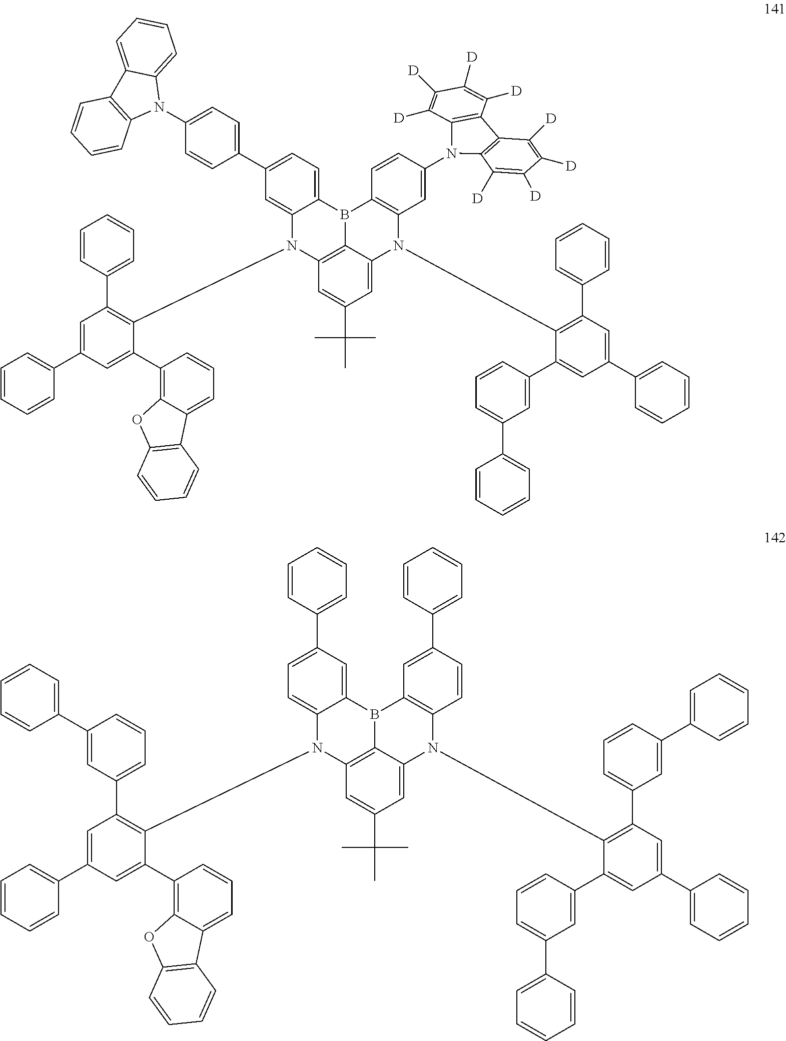 [SMILES: [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc(-c3ccccc3)c1)c1cc(C(C)(C)C)cc3c1B2c1ccc(-c2ccc(-n4c5ccccc5c5ccccc54)cc2)cc1N3c1c(-c2ccccc2)cc(-c2ccccc2)cc1-c1cccc2c1oc1ccccc12 ; CC(C)(C)c1cc2c3c(c1)N(c1c(-c4cccc(-c5ccccc5)c4)cc(-c4ccccc4)cc1-c1cccc4c1oc1ccccc14)c1ccc(-c4ccccc4)cc1B3c1cc(-c3ccccc3)ccc1N2c1c(-c2cccc(-c3ccccc3)c2)cc(-c2ccccc2)cc1-c1cccc(-c2ccccc2)c1]

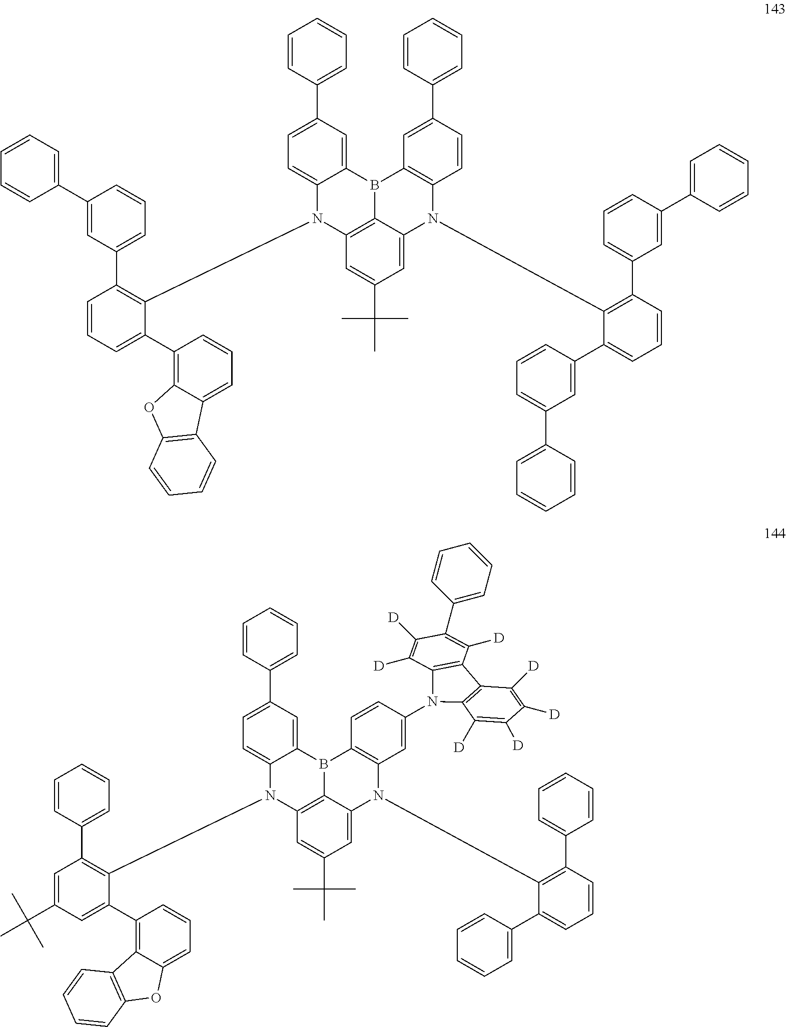 [SMILES: CC(C)(C)c1cc2c3c(c1)N(c1c(-c4cccc(-c5ccccc5)c4)cccc1-c1cccc4c1oc1ccccc14)c1ccc(-c4ccccc4)cc1B3c1cc(-c3ccccc3)ccc1N2c1c(-c2cccc(-c3ccccc3)c2)cccc1-c1cccc(-c2ccccc2)c1 ; [2H]c1c([2H])c([2H])c2c(c1[2H])c1c([2H])c(-c3ccccc3)c([2H])c([2H])c1n2-c1ccc2c(c1)N(c1c(-c3ccccc3)cccc1-c1ccccc1)c1cc(C(C)(C)C)cc3c1B2c1cc(-c2ccccc2)ccc1N3c1c(-c2ccccc2)cc(C(C)(C)C)cc1-c1cccc2oc3ccccc3c12]

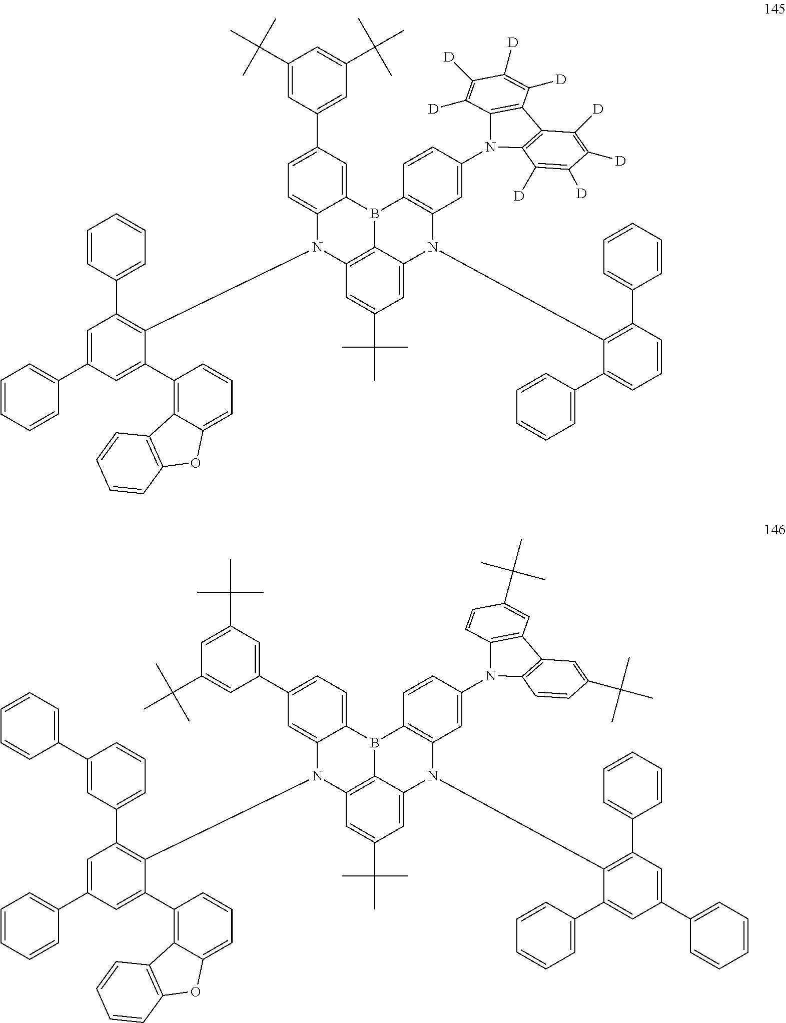 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1cc(-c2cc(C(C)(C)C)cc(C(C)(C)C)c2)ccc1N3c1c(-c2ccccc2)cc(-c2ccccc2)cc1-c1cccc2oc3ccccc3c12 ; CC(C)(C)c1cc(-c2ccc3c(c2)N(c2c(-c4cccc(-c5ccccc5)c4)cc(-c4ccccc4)cc2-c2cccc4oc5ccccc5c24)c2cc(C(C)(C)C)cc4c2B3c2ccc(-n3c5ccc(C(C)(C)C)cc5c5cc(C(C)(C)C)ccc53)cc2N4c2c(-c3ccccc3)cc(-c3ccccc3)cc2-c2ccccc2)cc(C(C)(C)C)c1]

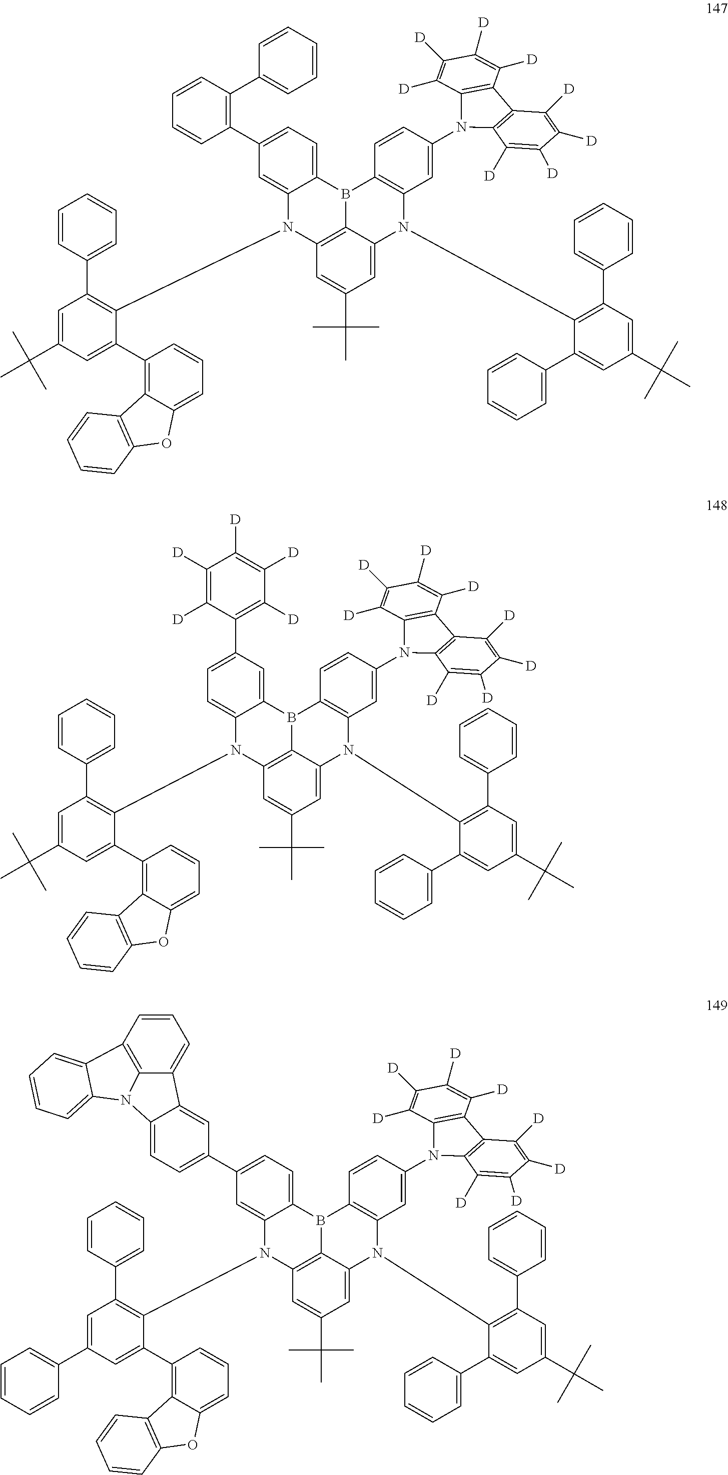

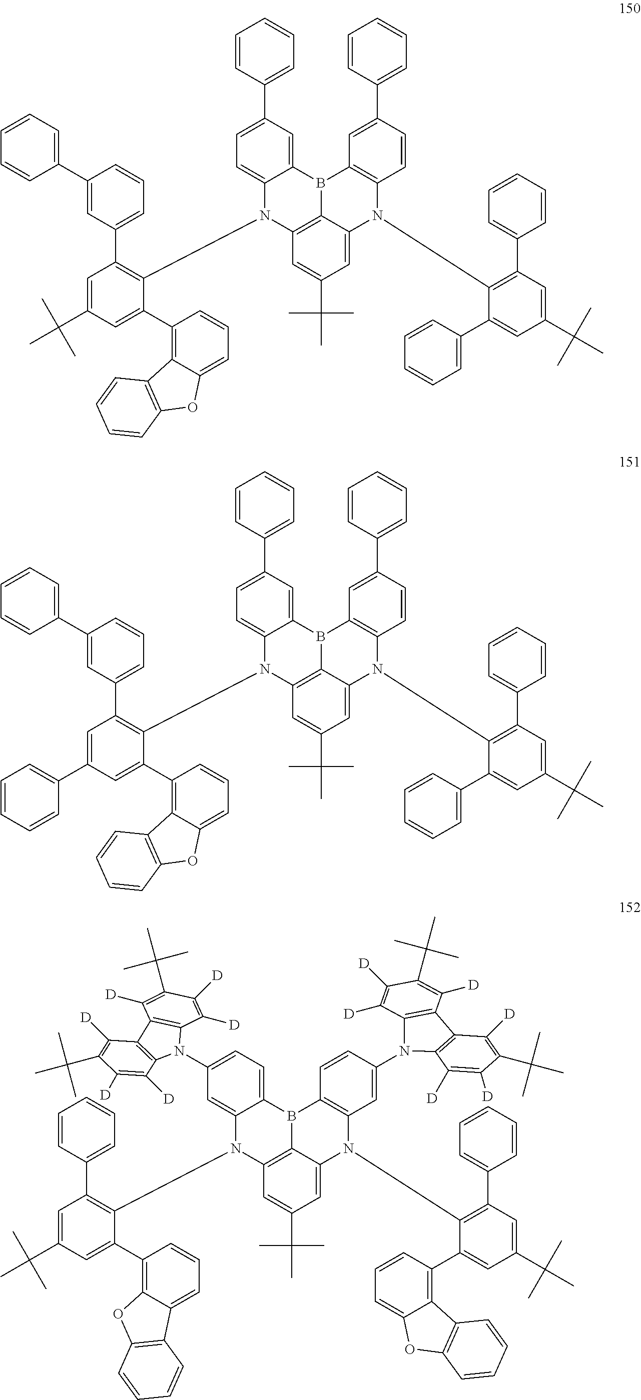

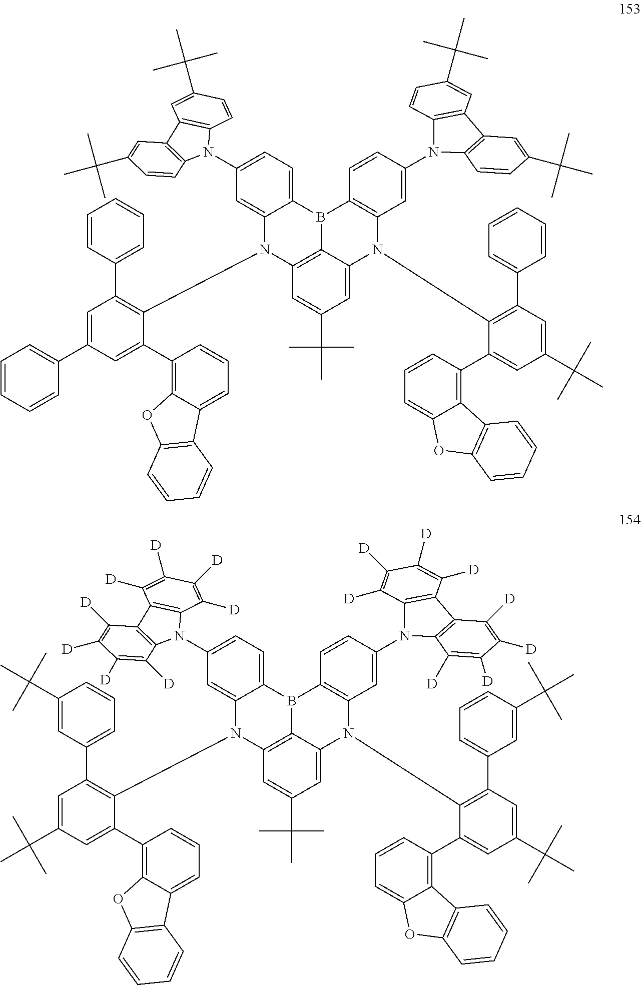

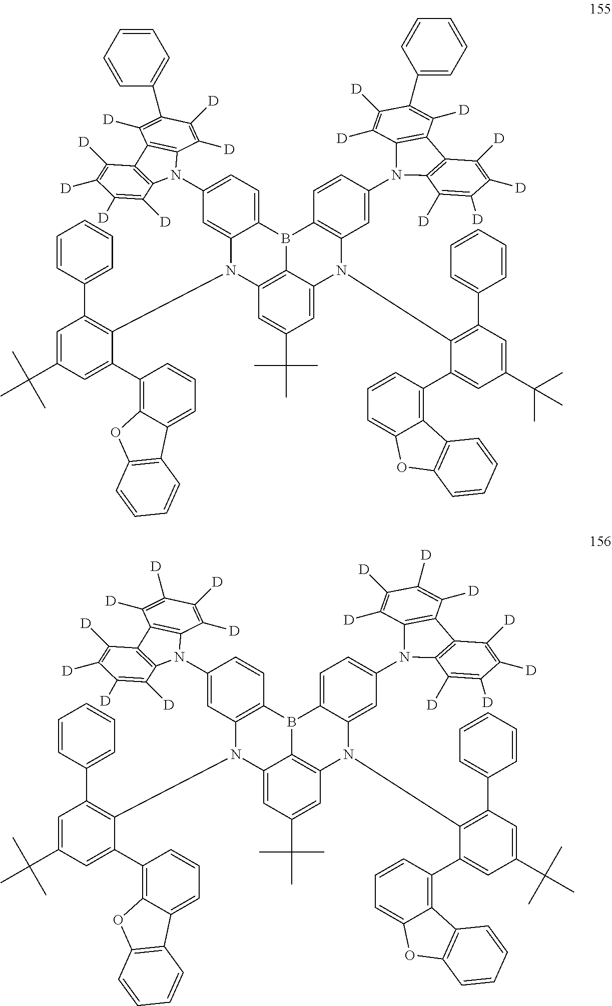

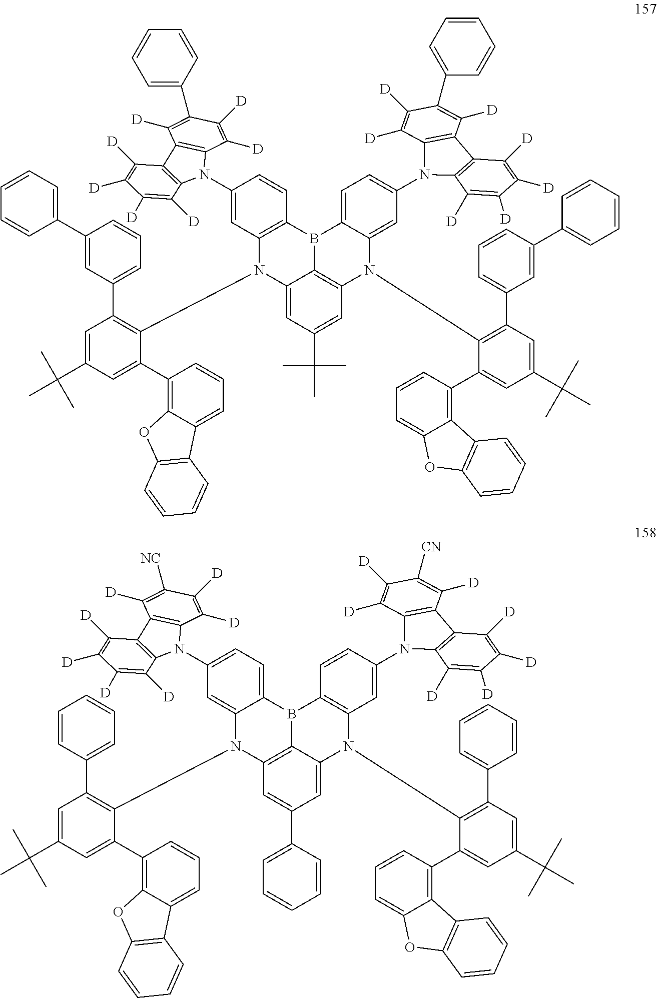

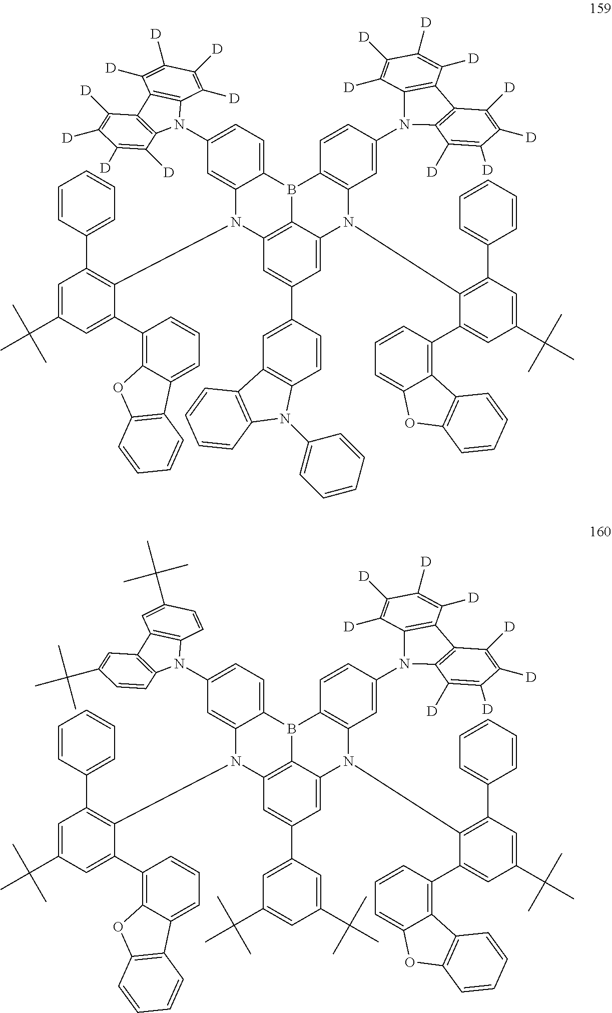

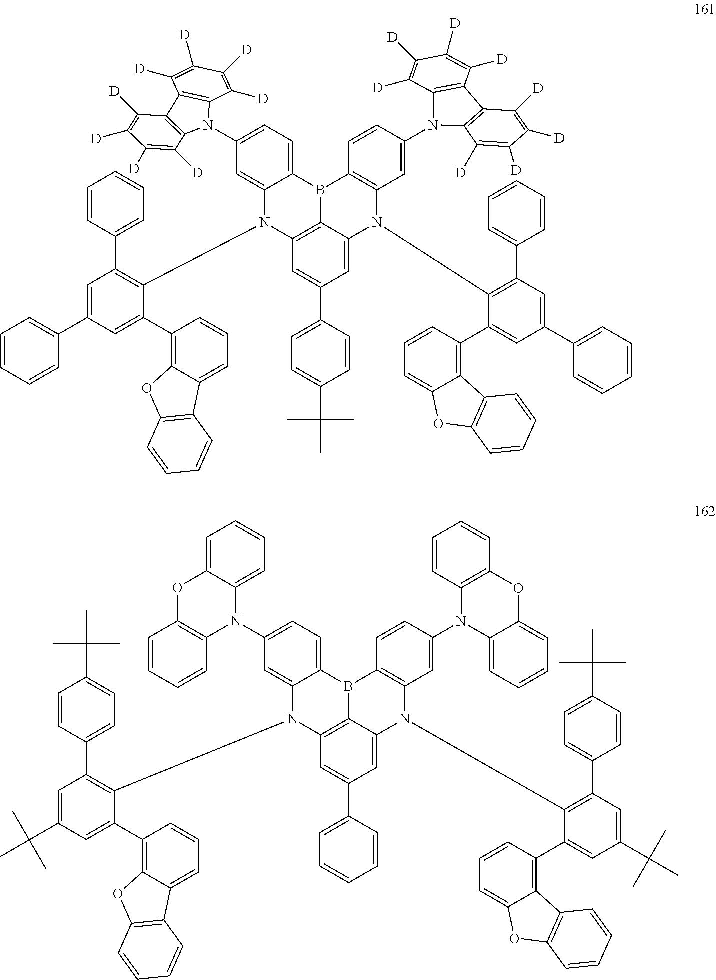

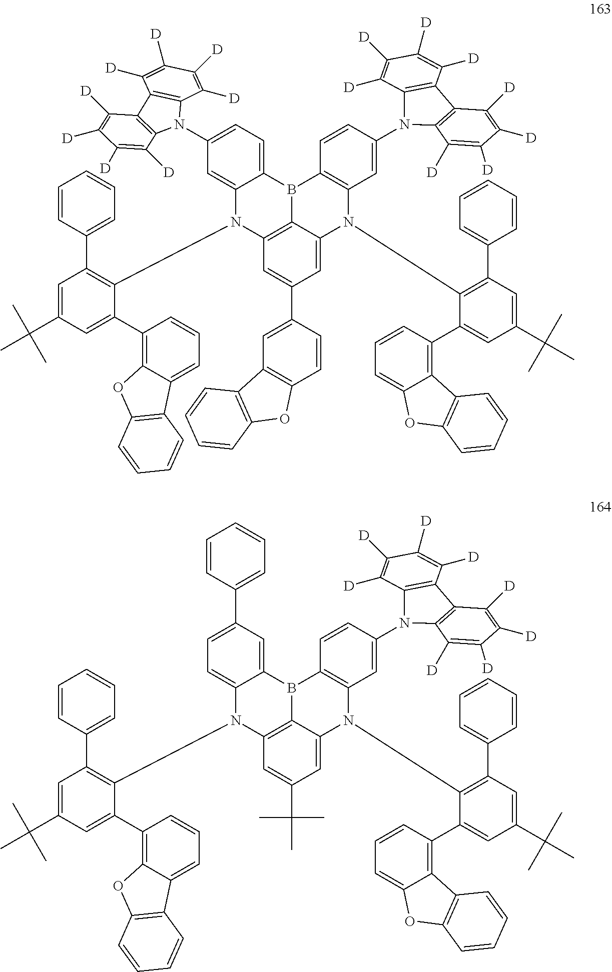

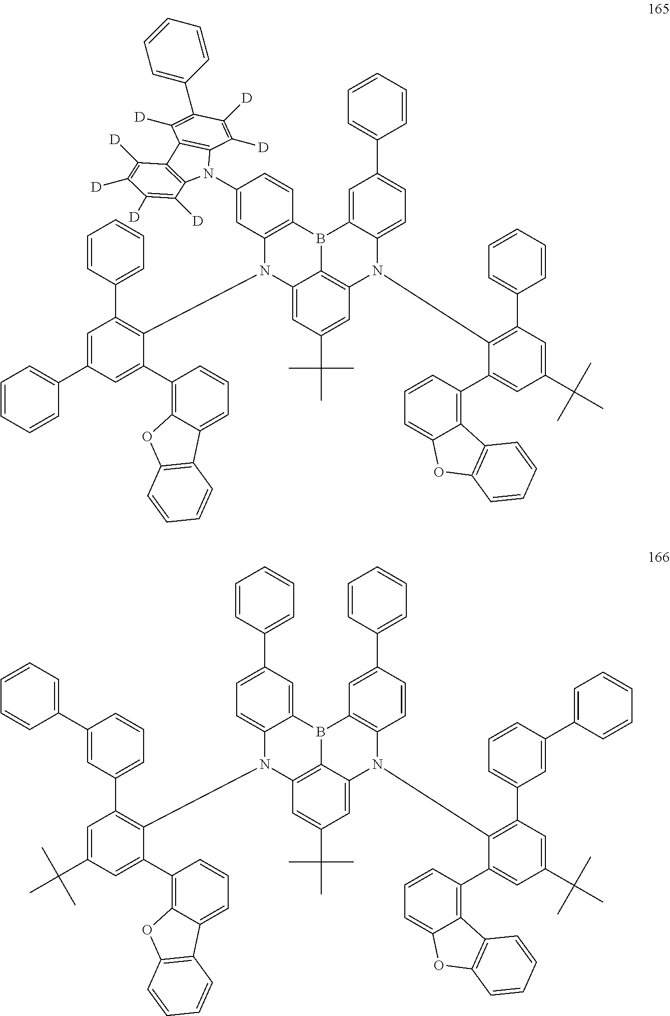 [SMILES: [2H]c1c([2H])c([2H])c2c(c1[2H])c1c([2H])c(-c3ccccc3)c([2H])c([2H])c1n2-c1ccc2c(c1)N(c1c(-c3ccccc3)cc(-c3ccccc3)cc1-c1cccc3c1oc1ccccc13)c1cc(C(C)(C)C)cc3c1B2c1cc(-c2ccccc2)ccc1N3c1c(-c2ccccc2)cc(C(C)(C)C)cc1-c1cccc2oc3ccccc3c12 ; CC(C)(C)c1cc(-c2cccc(-c3ccccc3)c2)c(N2c3ccc(-c4ccccc4)cc3B3c4cc(-c5ccccc5)ccc4N(c4c(-c5cccc(-c6ccccc6)c5)cc(C(C)(C)C)cc4-c4cccc5oc6ccccc6c45)c4cc(C(C)(C)C)cc2c43)c(-c2cccc3c2oc2ccccc23)c1]

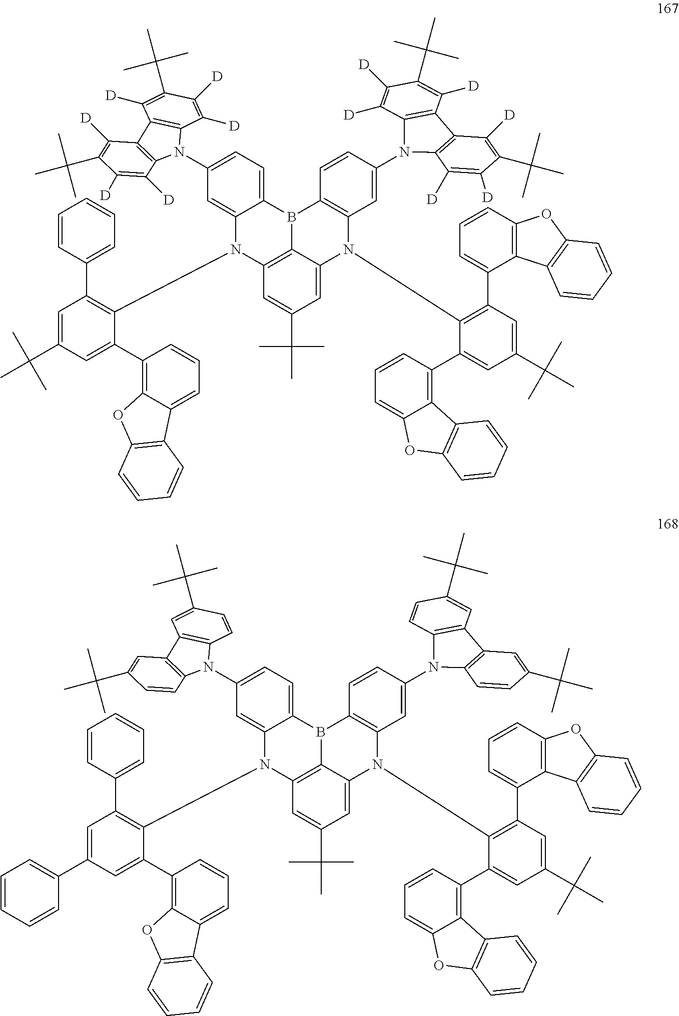

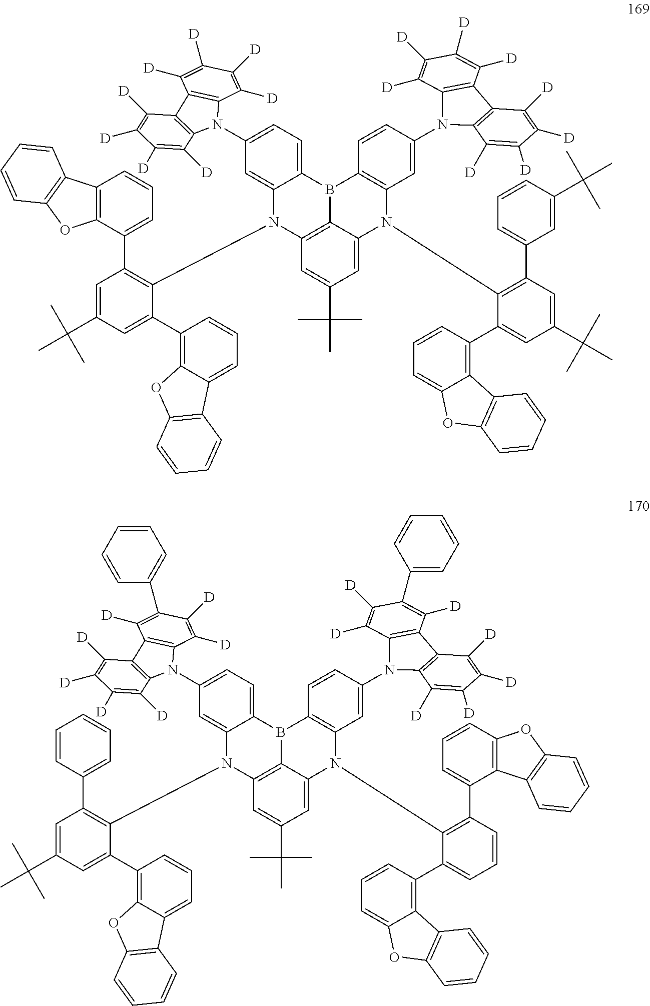

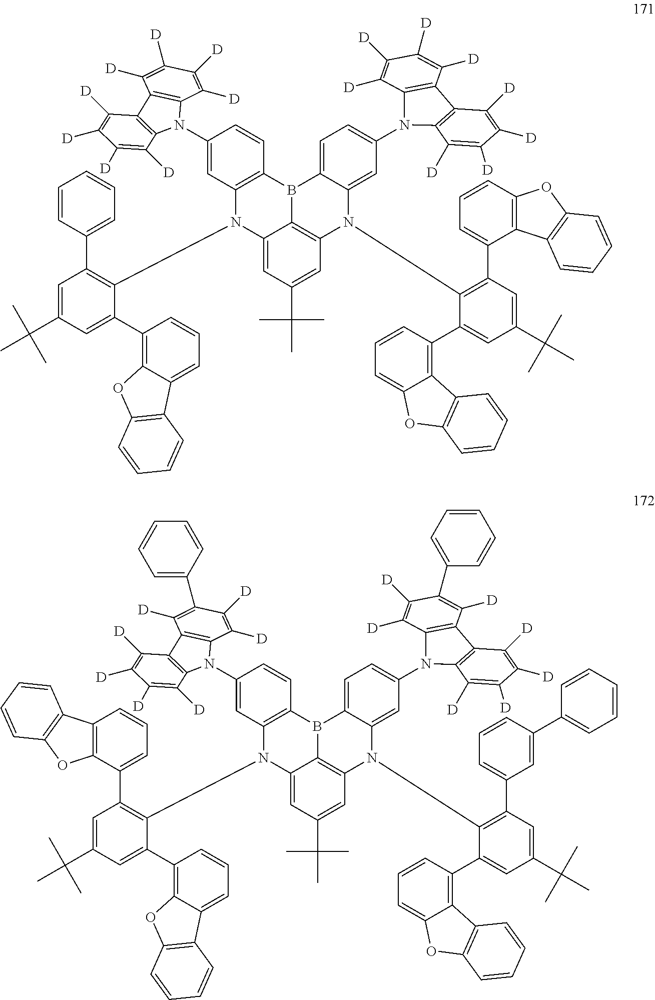

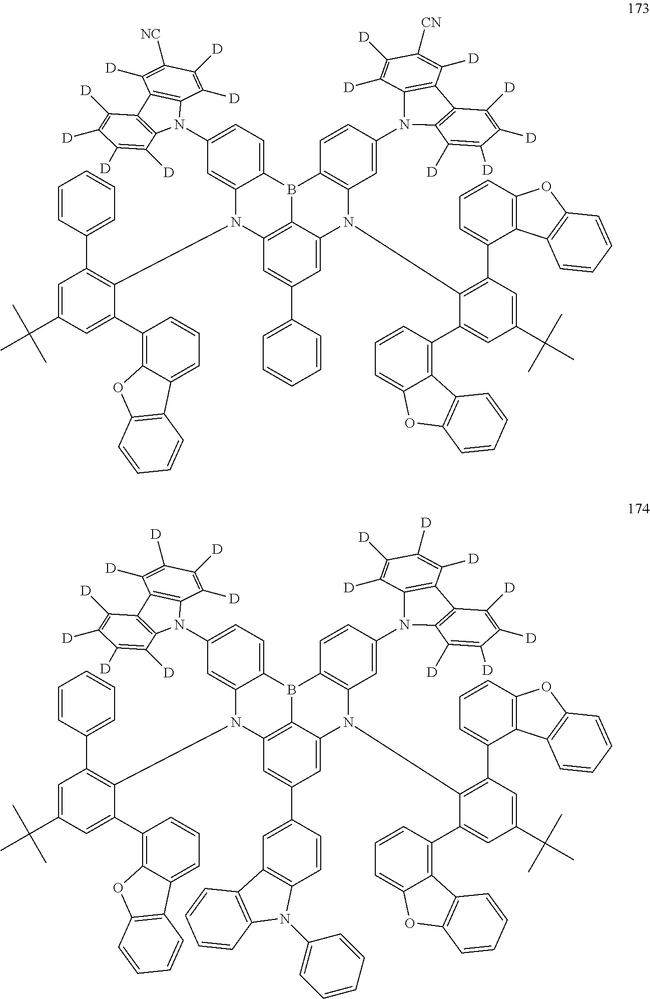

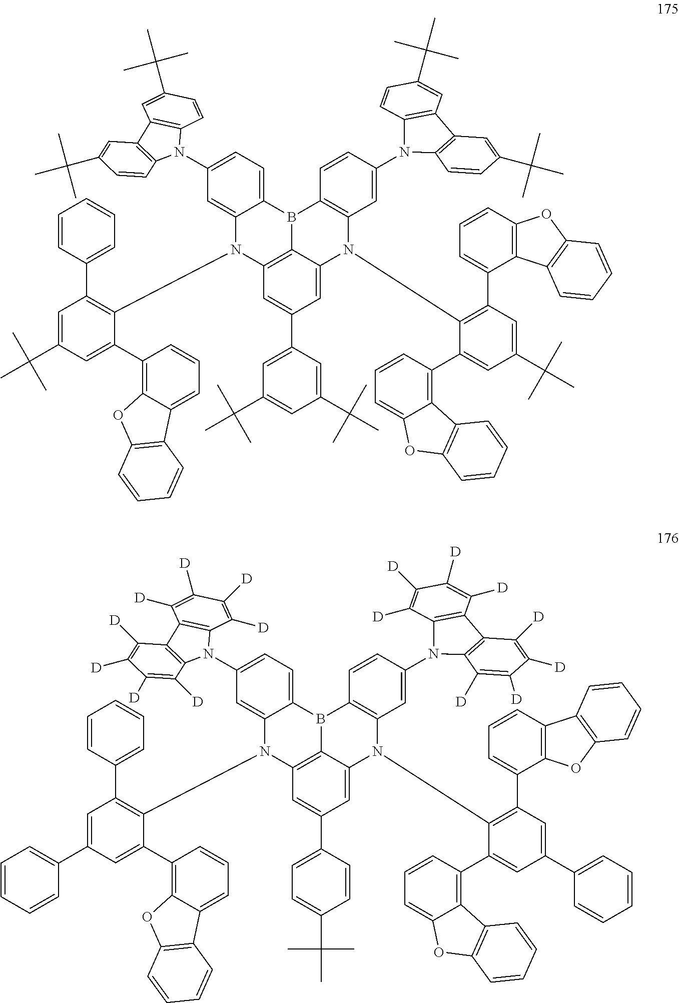

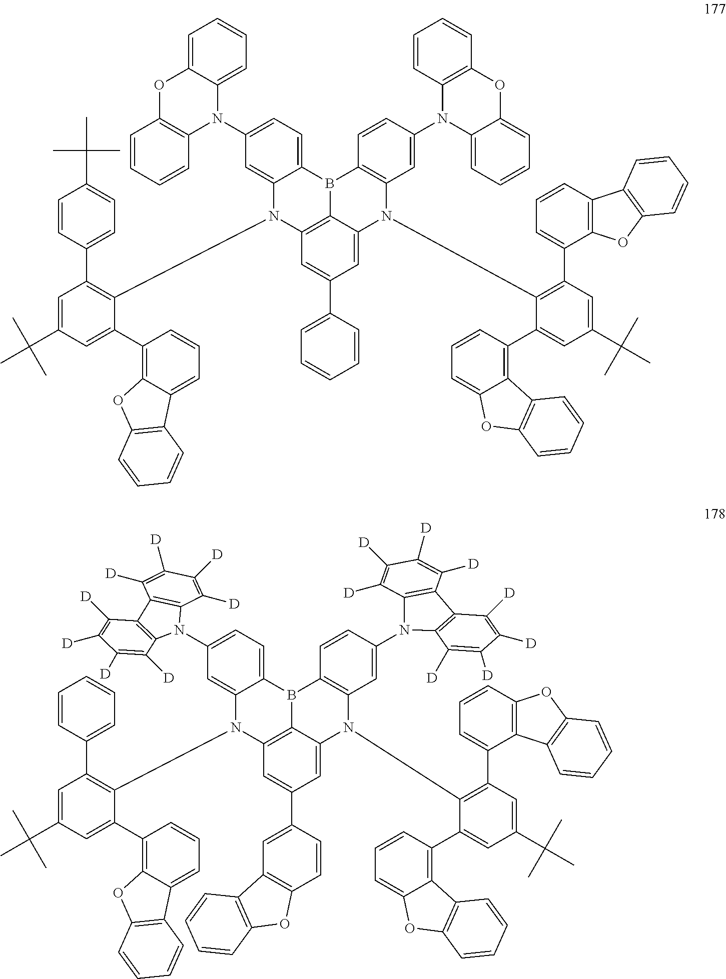

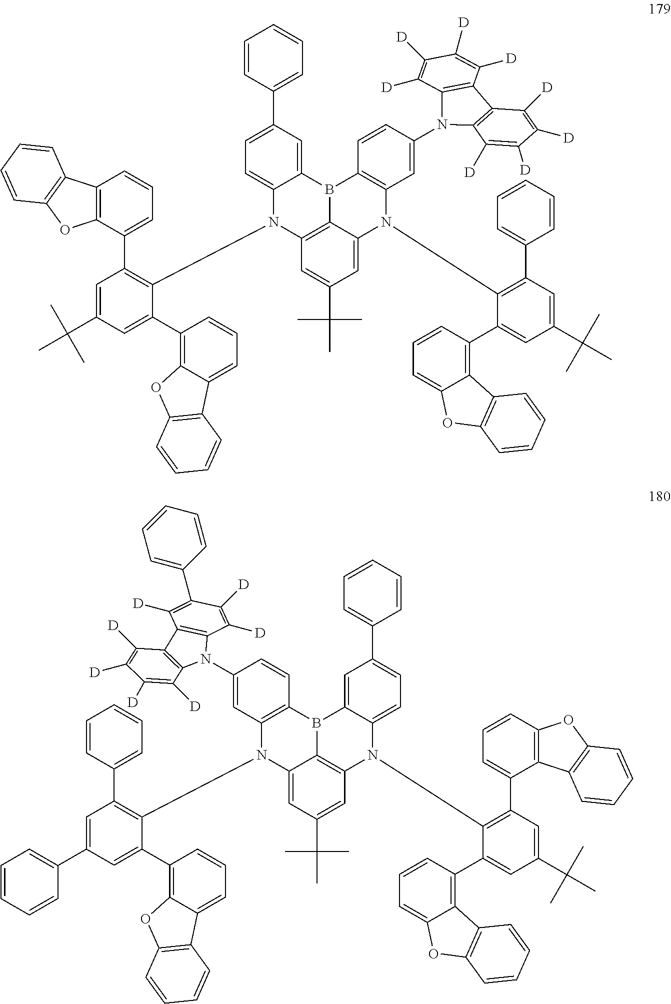

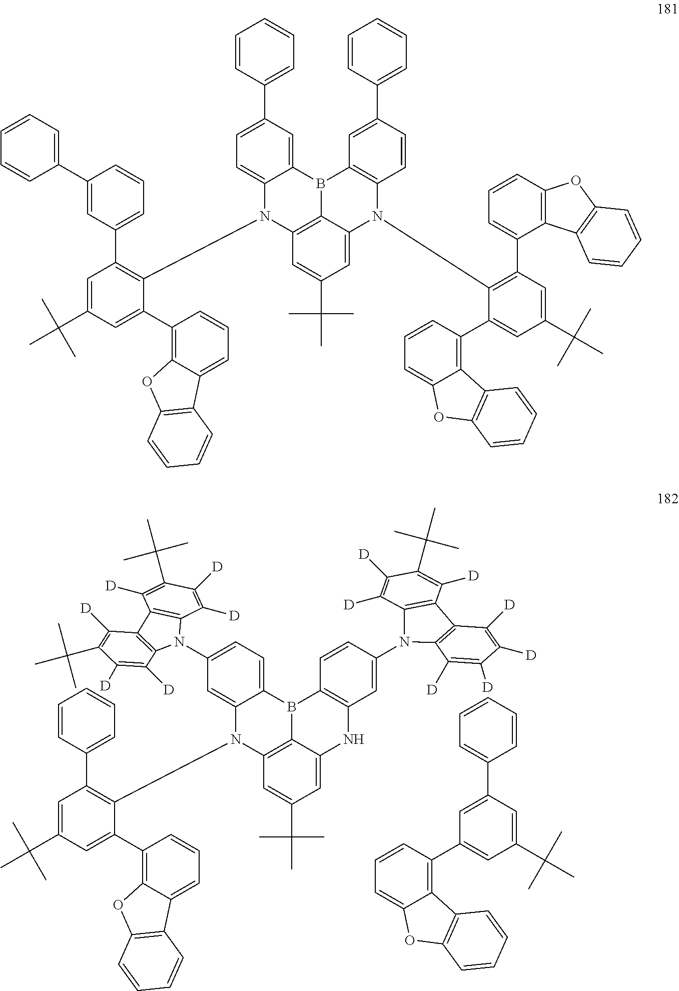

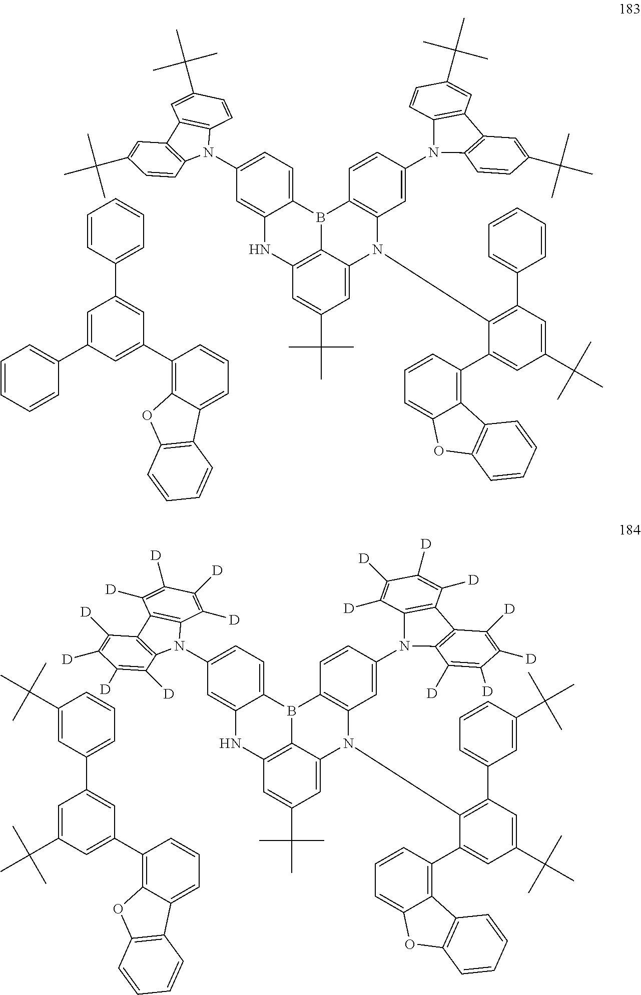

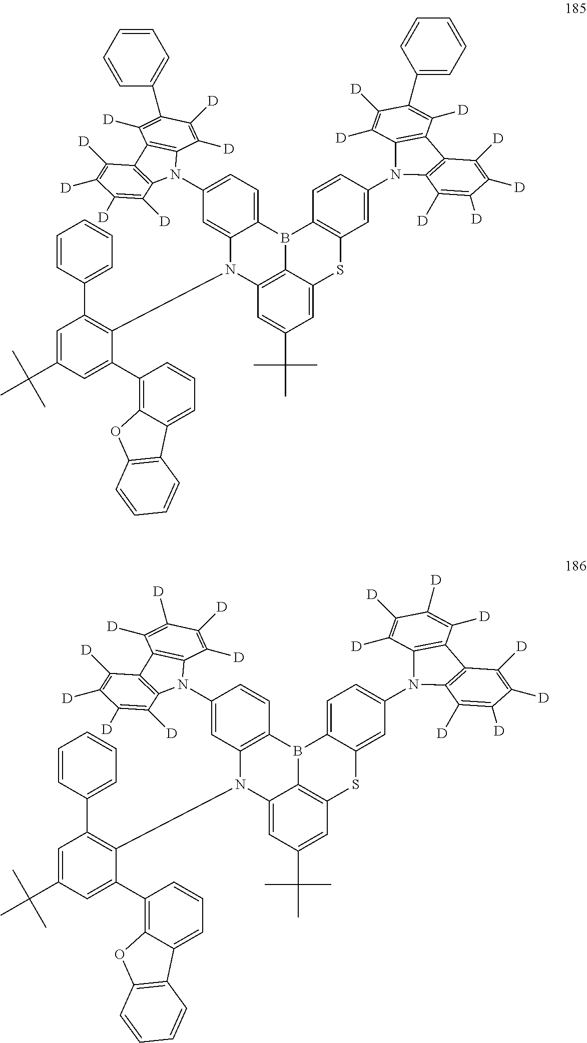 [SMILES: [2H]c1c([2H])c([2H])c2c(c1[2H])c1c([2H])c(-c3ccccc3)c([2H])c([2H])c1n2-c1ccc2c(c1)Sc1cc(C(C)(C)C)cc3c1B2c1ccc(-n2c4c([2H])c([2H])c([2H])c([2H])c4c4c([2H])c(-c5ccccc5)c([2H])c([2H])c42)cc1N3c1c(-c2ccccc2)cc(C(C)(C)C)cc1-c1cccc2c1oc1ccccc12 ; [2H]c1c([2H])c([2H])c2c(c1[2H])c1c([2H])c([2H])c([2H])c([2H])c1n2-c1ccc2c(c1)Sc1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1cccc2c1oc1ccccc12]

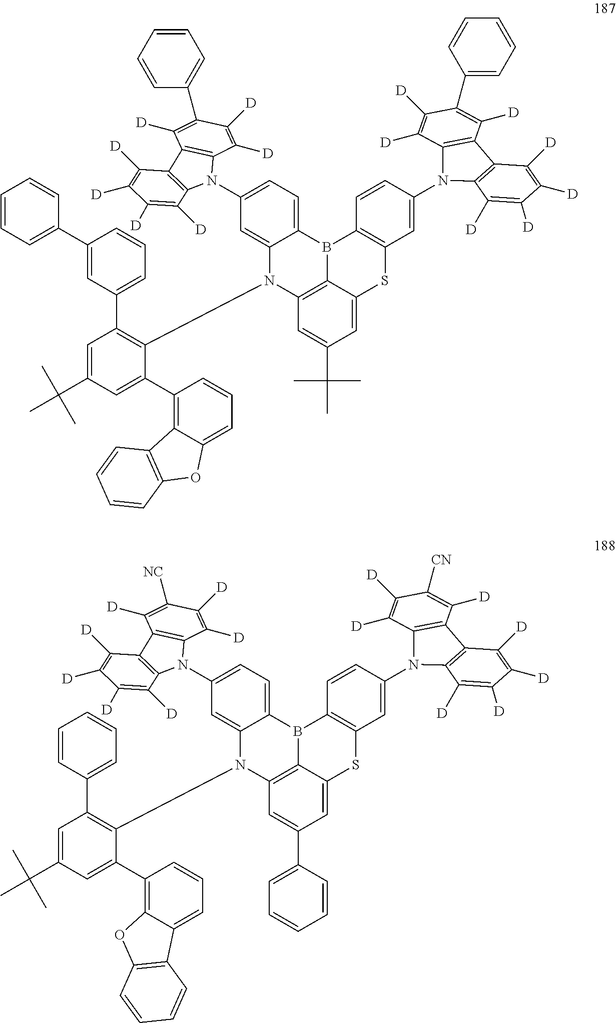 [SMILES: [2H]c1c([2H])c([2H])c2c(c1[2H])c1c([2H])c(-c3ccccc3)c([2H])c([2H])c1n2-c1ccc2c(c1)Sc1cc(C(C)(C)C)cc3c1B2c1ccc(-n2c4c([2H])c([2H])c([2H])c([2H])c4c4c([2H])c(-c5ccccc5)c([2H])c([2H])c42)cc1N3c1c(-c2cccc(-c3ccccc3)c2)cc(C(C)(C)C)cc1-c1cccc2oc3ccccc3c12 ; [2H]c1c([2H])c([2H])c2c(c1[2H])c1c([2H])c(C#N)c([2H])c([2H])c1n2-c1ccc2c(c1)Sc1cc(-c3ccccc3)cc3c1B2c1ccc(-n2c4c([2H])c([2H])c([2H])c([2H])c4c4c([2H])c(C#N)c([2H])c([2H])c42)cc1N3c1c(-c2ccccc2)cc(C(C)(C)C)cc1-c1cccc2c1oc1ccccc12]

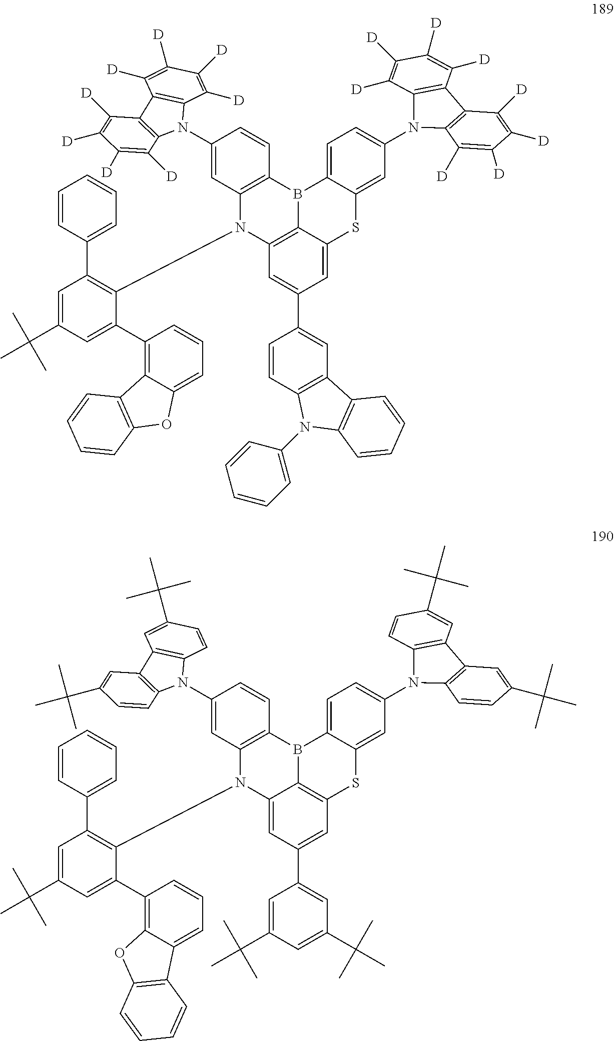 [SMILES: [2H]c1c([2H])c([2H])c2c(c1[2H])c1c([2H])c([2H])c([2H])c([2H])c1n2-c1ccc2c(c1)Sc1cc(-c3ccc4c(c3)c3ccccc3n4-c3ccccc3)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1cccc2oc3ccccc3c12 ; CC(C)(C)c1cc(-c2cc3c4c(c2)N(c2c(-c5ccccc5)cc(C(C)(C)C)cc2-c2cccc5c2oc2ccccc25)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2S3)cc(C(C)(C)C)c1]

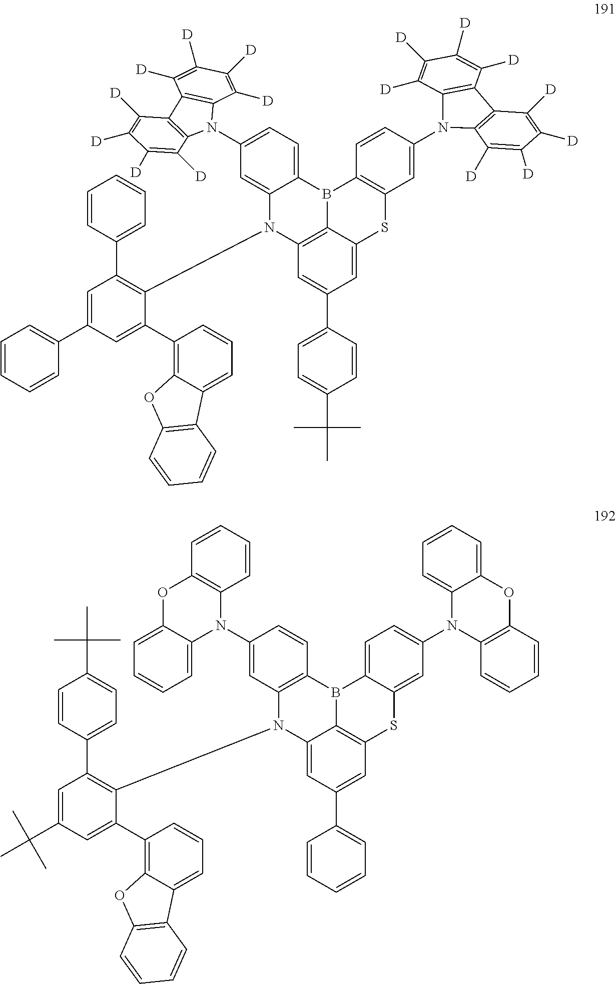 [SMILES: [2H]c1c([2H])c([2H])c2c(c1[2H])c1c([2H])c([2H])c([2H])c([2H])c1n2-c1ccc2c(c1)Sc1cc(-c3ccc(C(C)(C)C)cc3)cc3c1B2c1ccc(-n2c4c([2H])c([2H])c([2H])c([2H])c4c4c([2H])c([2H])c([2H])c([2H])c42)cc1N3c1c(-c2ccccc2)cc(-c2ccccc2)cc1-c1cccc2c1oc1ccccc12 ; CC(C)(C)c1ccc(-c2cc(C(C)(C)C)cc(-c3cccc4c3oc3ccccc34)c2N2c3cc(N4c5ccccc5Oc5ccccc54)ccc3B3c4ccc(N5c6ccccc6Oc6ccccc65)cc4Sc4cc(-c5ccccc5)cc2c43)cc1]

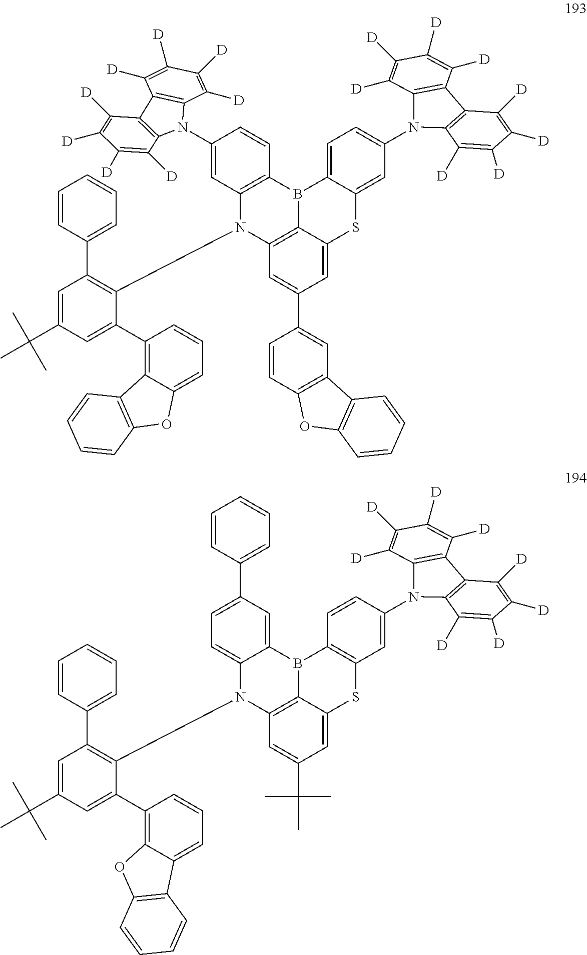 [SMILES: [2H]c1c([2H])c([2H])c2c(c1[2H])c1c([2H])c([2H])c([2H])c([2H])c1n2-c1ccc2c(c1)Sc1cc(-c3ccc4oc5ccccc5c4c3)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1cccc2oc3ccccc3c12 ; [2H]c1c([2H])c([2H])c2c(c1[2H])c1c([2H])c([2H])c([2H])c([2H])c1n2-c1ccc2c(c1)Sc1cc(C(C)(C)C)cc3c1B2c1cc(-c2ccccc2)ccc1N3c1c(-c2ccccc2)cc(C(C)(C)C)cc1-c1cccc2c1oc1ccccc12]

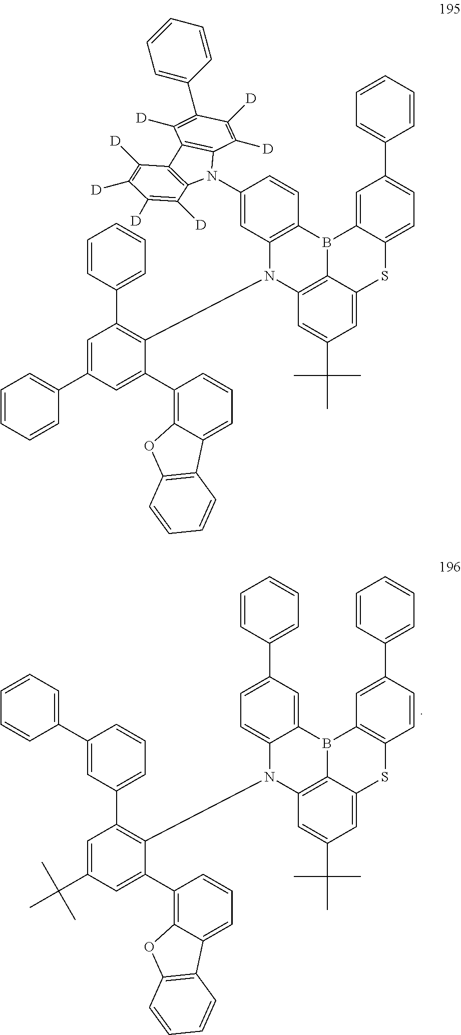 [SMILES: [2H]c1c([2H])c([2H])c2c(c1[2H])c1c([2H])c(-c3ccccc3)c([2H])c([2H])c1n2-c1ccc2c(c1)N(c1c(-c3ccccc3)cc(-c3ccccc3)cc1-c1cccc3c1oc1ccccc13)c1cc(C(C)(C)C)cc3c1B2c1cc(-c2ccccc2)ccc1S3 ; CC(C)(C)c1cc(-c2cccc(-c3ccccc3)c2)c(N2c3ccc(-c4ccccc4)cc3B3c4cc(-c5ccccc5)ccc4Sc4cc(C(C)(C)C)cc2c43)c(-c2cccc3c2oc2ccccc23)c1]

In Compound Group 1, D represents a deuterium atom, and CN represents a cyano group.

The fused polycyclic compound represented by Formula 1 includes a substituent represented by Formula 2, and thus may achieve high luminous efficiency and long service life.

The fused polycyclic compound represented by Formula 1 has a structure in which three aromatic rings are fused via a boron atom and at least one nitrogen atom, and includes the first substituent and the second substituent in the molecular structure. In the fused polycyclic compound, a first phenyl group is linked to the nitrogen atom, and the first substituent and the second substituent are each bonded to a carbon atom at an ortho position with respect to the carbon atom of the first phenyl group that is linked to the nitrogen atom. At least one of the first substituent and the second substituent includes a dibenzofuran moiety that is bonded to the first phenyl group at carbon 1 or carbon 4.

The fused polycyclic compound has a structure including a first phenyl group that is bonded to the nitrogen atom of the fused ring core, and a first substituent and a second substituent that are each bonded to the first phenyl group, and thus may exhibit improved luminous efficiency and element service life characteristics. The first phenyl group is bonded to the nitrogen atom and the first and second substituents are each bonded at an ortho position to the carbon atom of the first phenyl group that is to the nitrogen atom, thereby imparting a bulky structure and a long-extended structure, and thus may have a structure surrounding the fused ring core. Accordingly, it is possible to cover and protect the vacant p-orbital of the boron atom of the fused ring core. The inclusion of a bulky substituent having large steric hindrance effects increases the distance between adjacent molecules, thereby suppressing the Dexter energy transfer, and thus may suppress the deterioration of service life due that would be caused by an increase of triplet concentration.

Since at least one of the first substituent and the second substituent has a dibenzofuran moiety bonded to the first phenyl group at carbon 1 or carbon 4, such a dibenzofuran moiety having a relatively low electron density may be introduced into a highest occupied molecular orbital (HOMO) position of the first phenyl group, and thus, the HOMO energy level may be deepened and trap-assisted recombination may be suppressed. Thus, when the fused polycyclic compound having such a structure is used as a dopant material for the emission layer, the service life of the light emitting element may be further improved and the HOMO energy level may be prevented from being shallower, so that the desired emission wavelength and the HOMO energy level may be simultaneously satisfied. In this regard, low HOMO energy level characteristics further facilitates energy transfer from a host in the light emitting element, and thus efficiency may be improved. In the specification, a “shallow” energy level may indicate a reduction of an absolute value of the energy level from a vacuum level to a negative direction. In the specification a “deep” energy level may indicate an increase of an absolute value of the energy level from a vacuum level to a negative direction.

An emission spectrum of the fused polycyclic compound represented by Formula 1 may have a full width at half maximum (FWHM) in a range of about 10 nm to about 50 nm. For example, an emission spectrum of the fused polycyclic compound represented by Formula 1 may have a FWHM in a range of about 20 nm to about 40 nm. The emission spectrum of the fused polycyclic compound represented by Formula 1 may have a FWHM in any of the ranges described above, thereby improving luminous efficiency when applied to an element. When the fused polycyclic compound is used as a blue light emitting element material for a light emitting element, element service life may be improved.

The fused polycyclic compound represented by Formula 1 may be a thermally activated delayed fluorescence emitting material. In an embodiment, the fused polycyclic compound represented by Formula 1 may be a thermally activated delayed fluorescence dopant in which a difference (ΔE_{ST}) between a lowest triplet exciton energy level (T1 level) and a lowest singlet exciton energy level (S1 level) is less than or equal to about 0.6 eV. For example, the fused polycyclic compound represented by Formula 1 may be a thermally activated delayed fluorescence dopant having a difference (ΔE_{ST}) between a lowest triplet exciton energy level (T1 level) and a lowest singlet exciton energy level (S1 level) that is less than or equal to about 0.5 eV.

The fused polycyclic compound represented by Formula 1 may be a luminescent material having a central wavelength in a range of about 430 nm to about 490 nm. In an embodiment, when an emission layer includes a fused polycyclic compound represented by Formula 1, the emission layer may emit light having a central wavelength in a range of about 430 nm to about 490 nm. For example, the fused polycyclic compound represented by Formula 1 may be a blue thermally activated delayed fluorescence (TADF) dopant. However, embodiments are not limited thereto. When the fused polycyclic compound is used as a luminescent material, the fused polycyclic compound may be used as a dopant material that emits light in various wavelength regions, such as a red emitting dopant or a green emitting dopant.

In an embodiment, the emission layer EML in the light emitting element ED may emit delayed fluorescence. For example, the emission layer EML may emit thermally activated delayed fluorescence (TADF).

The emission layer EML of the light emitting element ED may emit blue light. For example, the emission layer EML of the light emitting element ED may emit blue light having a wavelength range of less than or equal to about 490 nm. However, embodiments are not limited thereto, and the emission layer EML may emit green light or red light.

The fused polycyclic compound may be included in the emission layer EML. The fused polycyclic compound may be included as a dopant material in the emission layer EML. The fused polycyclic compound may be a thermally activated delayed fluorescence material. The fused polycyclic compound may be used as a thermally activated delayed fluorescence dopant. For example, in the light emitting element ED according to an embodiment, the emission layer EML may include, as a thermally activated delayed fluorescence dopant, at least one compound selected from Compound Group 1 as described above. However, the use of the fused polycyclic compound is not limited thereto.

In an embodiment, the emission layer EML may include a first compound, which is the fused polycyclic compound represented by Formula 1, and the emission layer EML may further include at least one of a second compound represented by Formula HT-1, a third compound represented by Formula ET-1, and a fourth compound represented by Formula D-1.

In an embodiment, the emission layer EML may further include a second compound represented by Formula HT-1. In an embodiment, the second compound may be used as a hole transporting host material in the emission layer EML.

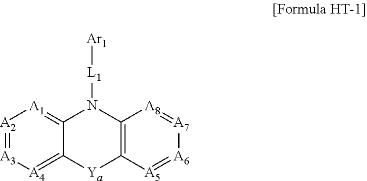

In Formula HT-1, A₁ to A₈ may each independently be N or C(R₄₁). For example, all of A₁ to A₈ may each independently be C(R₄₁). In an embodiment, one of A₁ to A₈ may be N, and the remainder of A₁ to A₈ may each independently be C(R₄₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments are not limited thereto.

In Formula HT-1, Yₐ may be a direct linkage, C(R₄₂)(R₄₃), or Si(R₄₄)(R₄₅). For example, the two benzene rings that are bonded to the nitrogen atom in Formula HT-1 may be bonded to each other via a direct linkage,

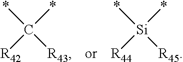

In Formula HT-1, when Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT-1, R₄₁ to R₄₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R₄₁ to R₄₅ may each independently be a hydrogen atom or a deuterium atom. For example, R₄₁ to R₄₅ may each independently be an unsubstituted methyl group or an unsubstituted phenyl group.

In an embodiment, the second compound represented by Formula HT-1 may be selected from Compound Group 2. In an embodiment, in the light emitting element ED, the second compound may include at least one compound selected from Compound Group 2.

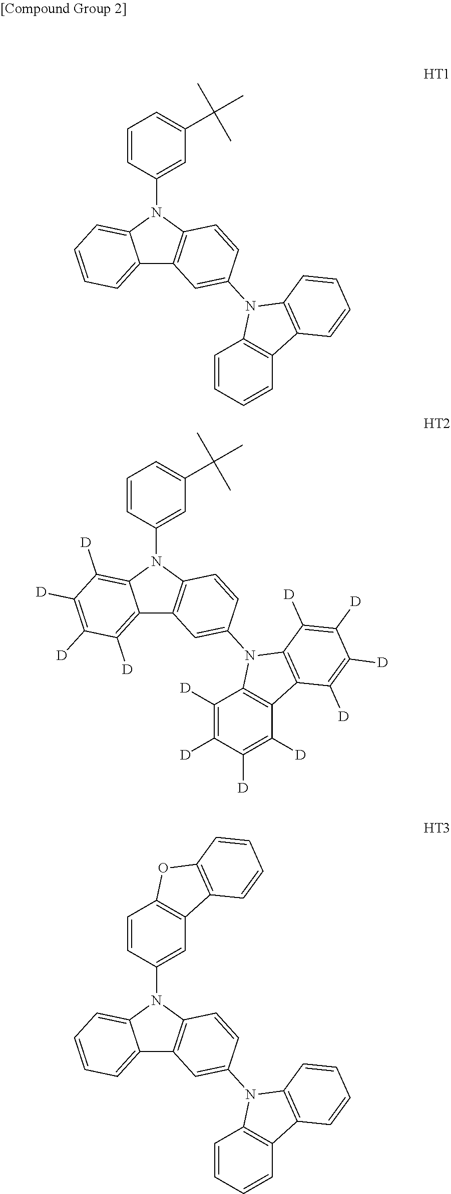

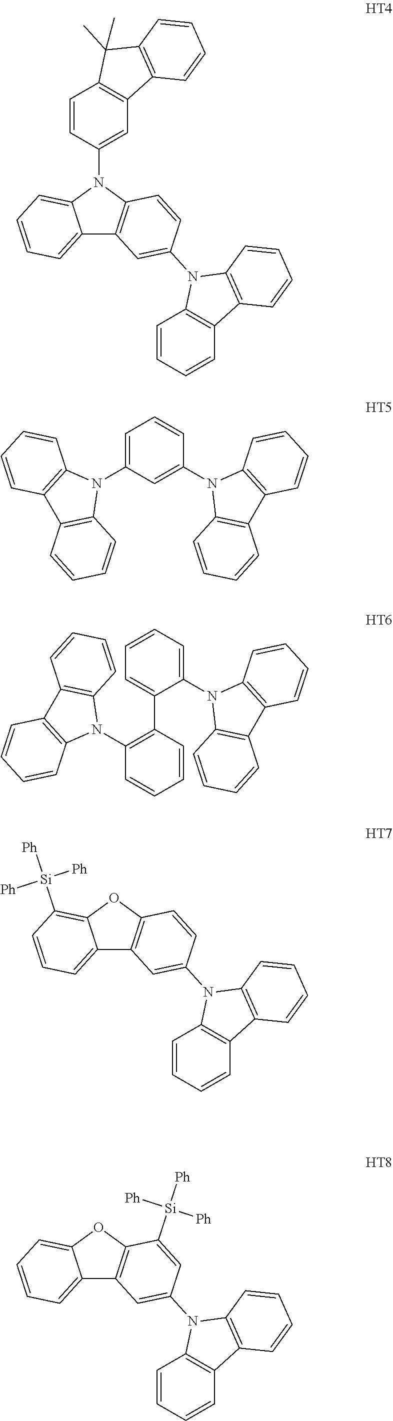 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

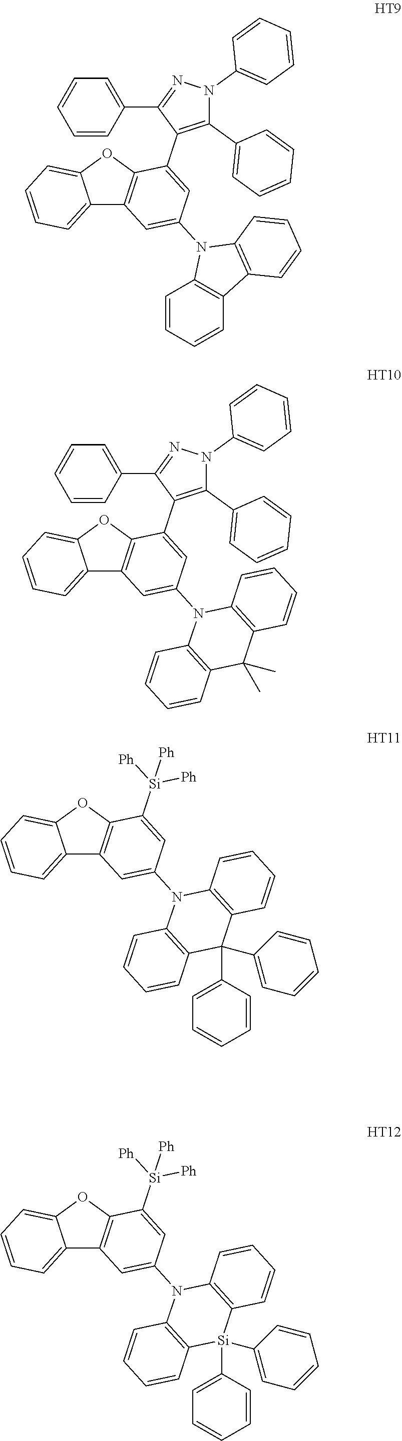

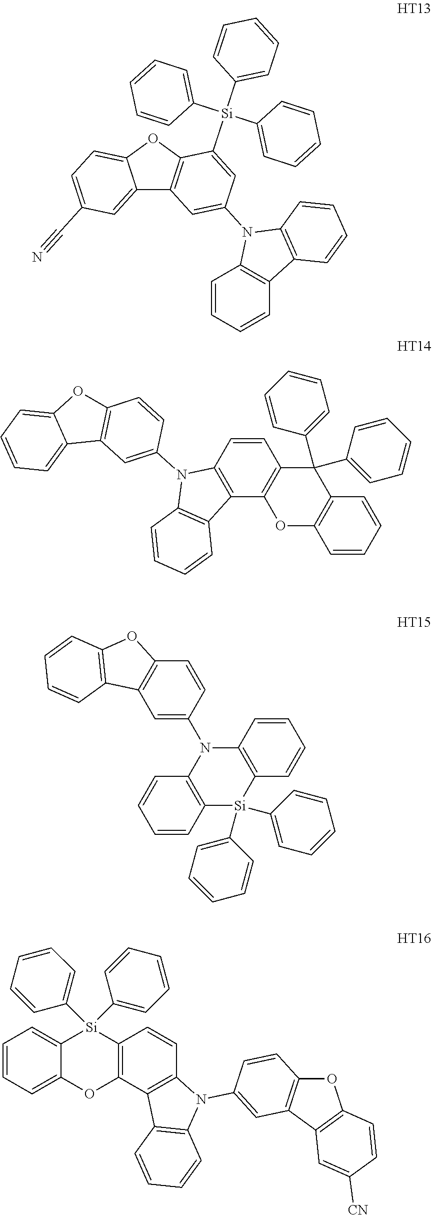 [SMILES: N#Cc1ccc2oc3c([Si](c4ccccc4)(c4ccccc4)c4ccccc4)cc(-n4c5ccccc5c5ccccc54)cc3c2c1 ; c1ccc(C2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

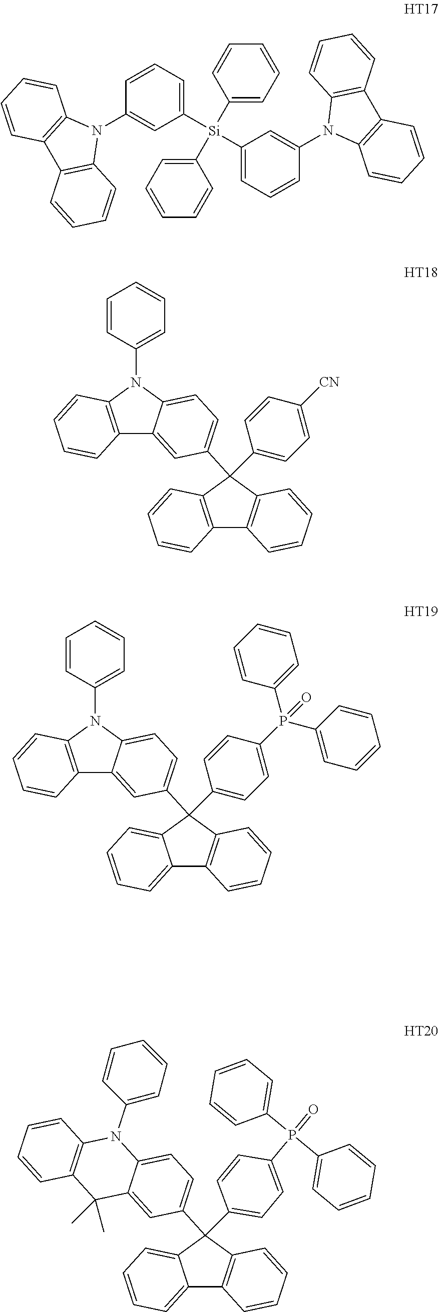 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

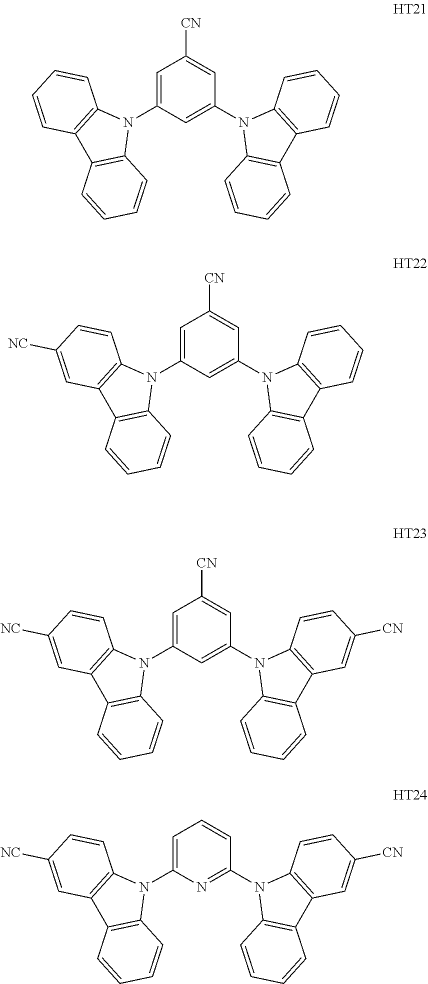 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

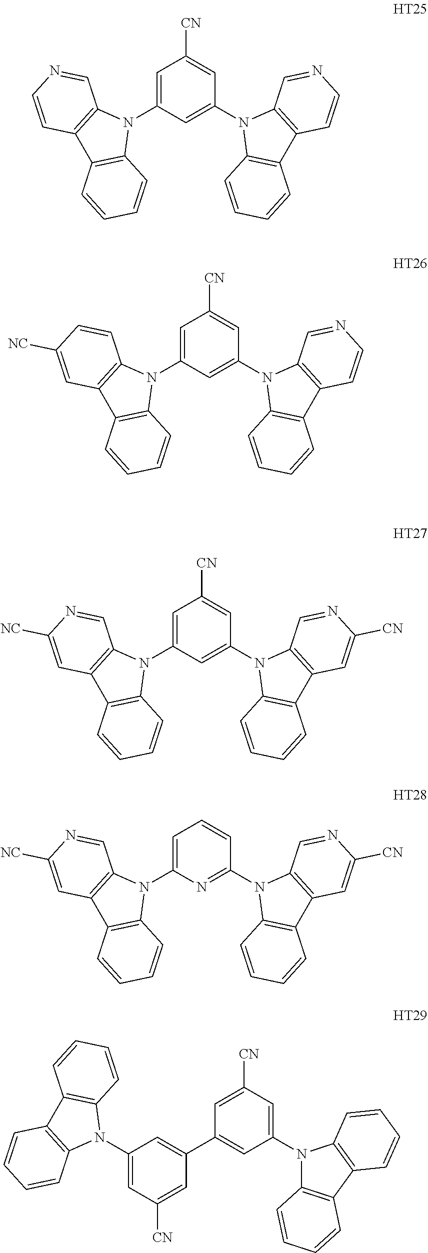 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1]

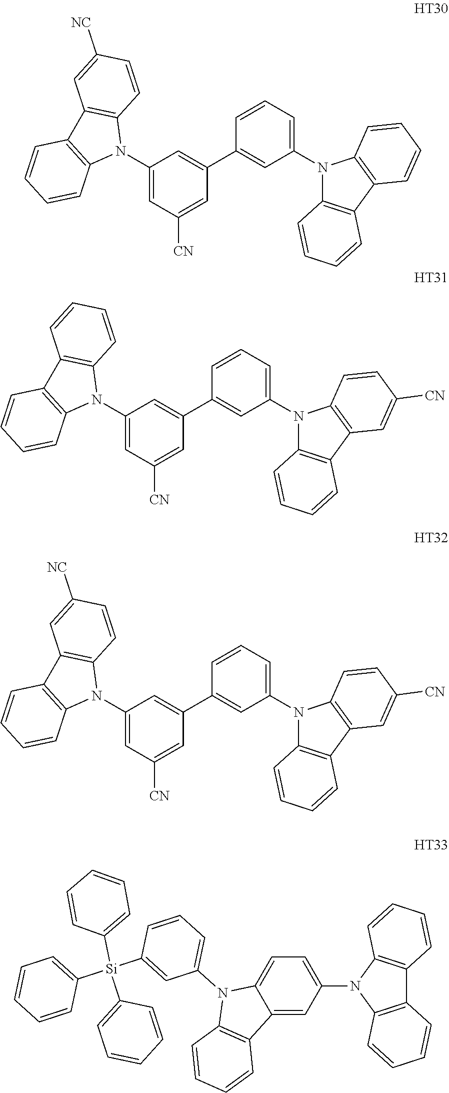 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

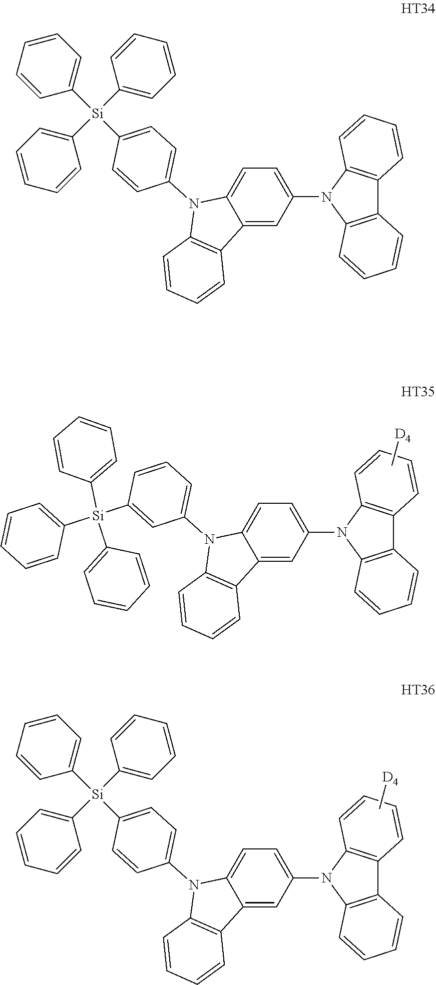

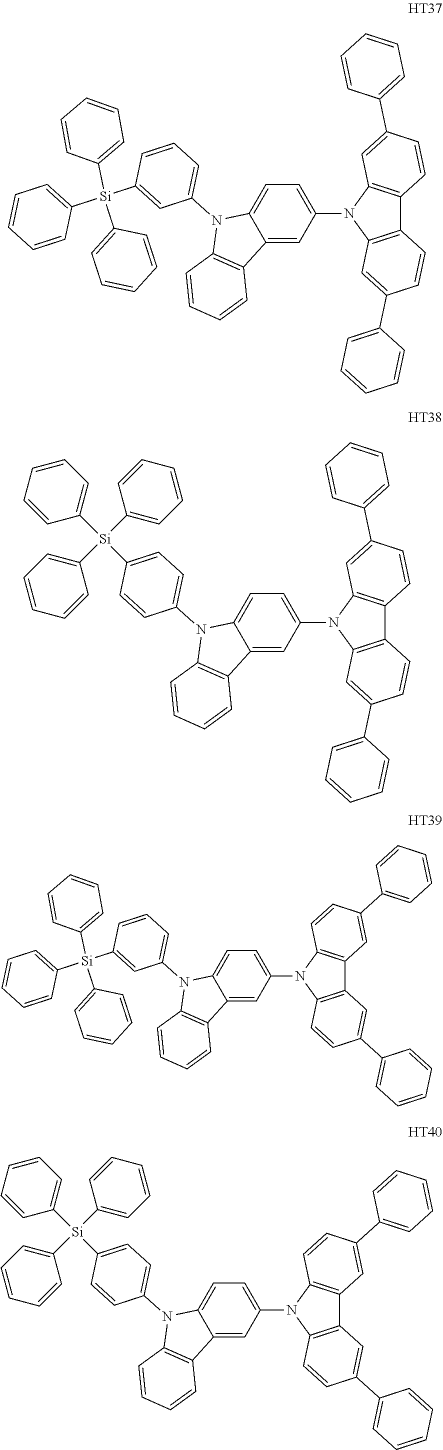 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

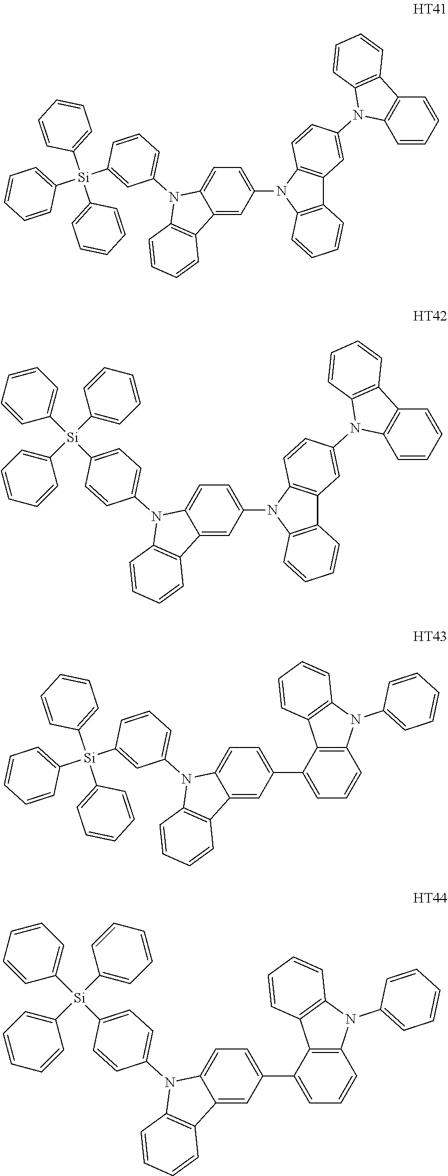 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

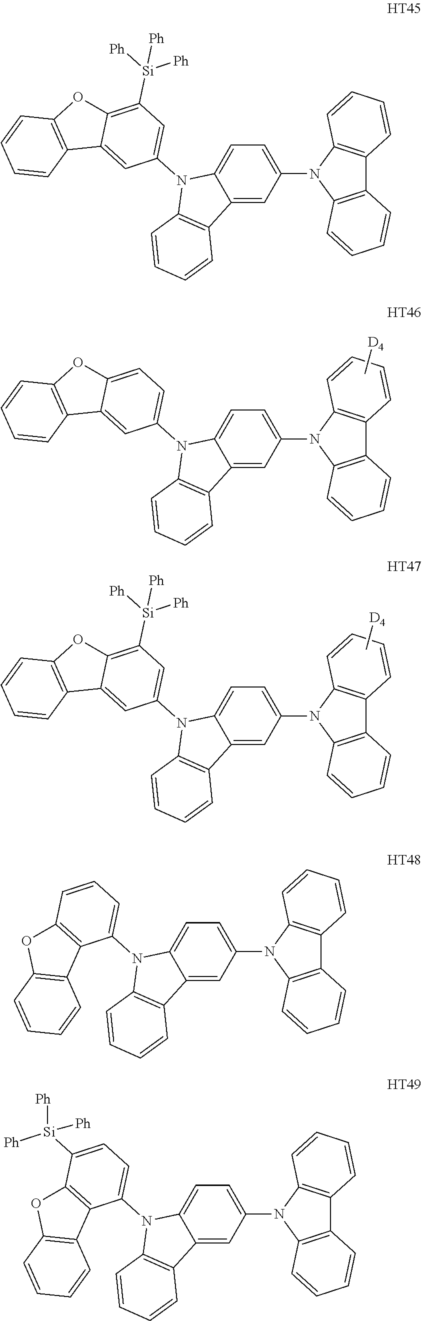

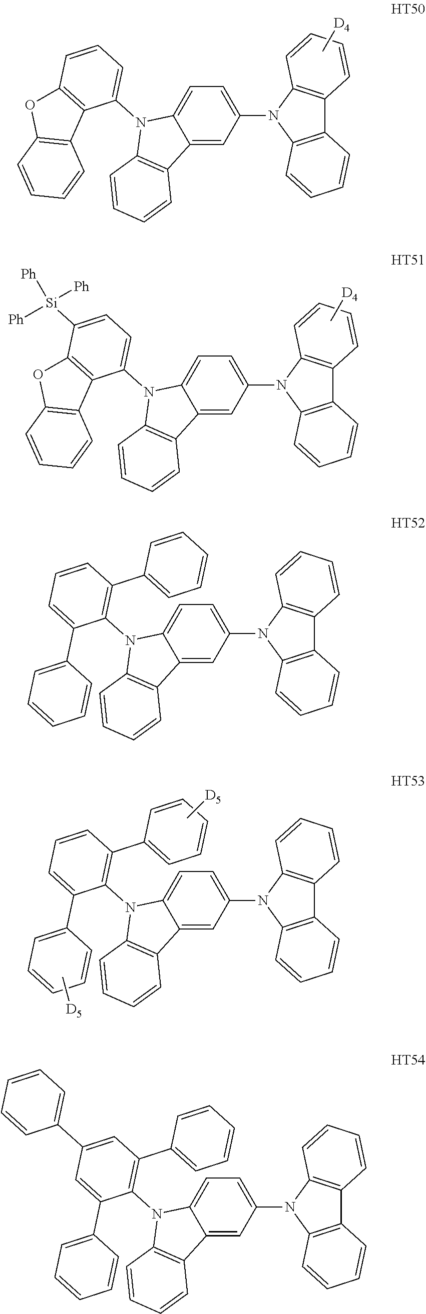

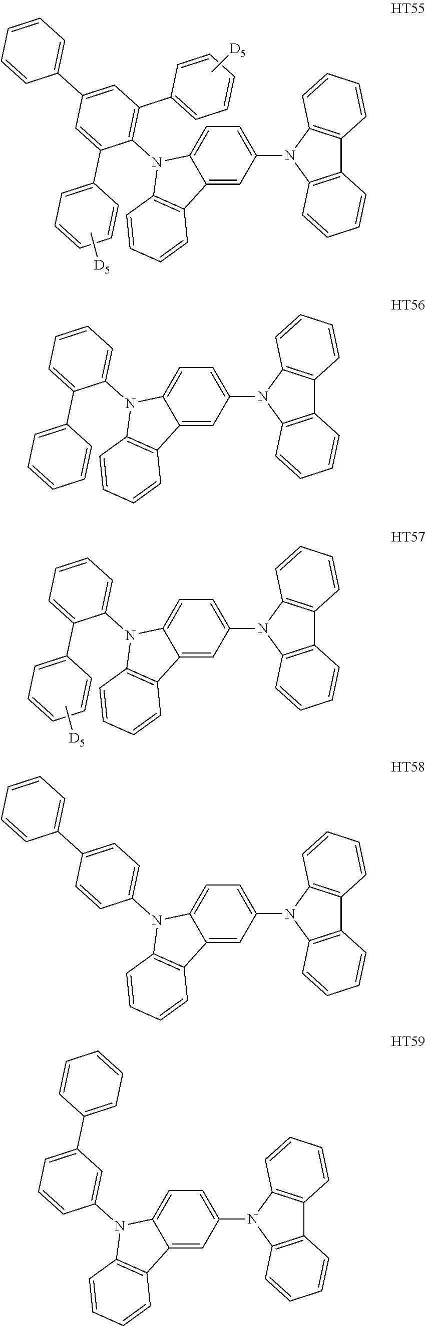

In Compound Group 2, D represents a deuterium atom, and Ph represents a substituted or unsubstituted phenyl group. For example, in Compound Group 2, Ph may represent an unsubstituted phenyl group.

In an embodiment, the emission layer EML may further include a third compound represented by Formula ET-1. In an embodiment, the third compound may be used as an electron transport host material in the emission layer EML.

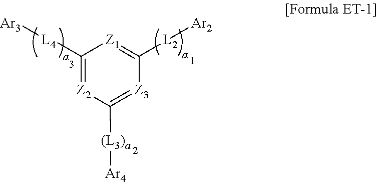

In Formula ET-1, at least one of Z₁ to Z₃ may each be N, and the remainder of Z₁ to Z₃ may each independently be C(R₄₆). For example, one of Z₁ to Z₃ may be N, and the remainder of Z₁ to Z₃ may each independently be C(R₄₆). Thus, the third compound represented by Formula ET-1 may include a pyridine moiety. As another example, two of Z₁ to Z₃ may each be N, and the remainder of Z₁ to Z₃ may be C(R₄₆). Thus, the third compound represented by Formula ET-1 may include a pyrimidine moiety. As yet another example, Z₁ to Z₃ may each be N. Thus, the third compound represented by Formula ET-1 may include a triazine moiety.

In Formula ET-1, R₄₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, a₁ to a₃ may each independently be an integer from 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group, or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula ET-1, when a₁ is 2 or greater, L₂ is a substituted or unsubstituted arylene group having 6 to 30 ring-forming carbon atoms or a substituted or unsubstituted heteroarylene group having 2 to 30 ring-forming carbon atoms; when a₂ is 2 or greater, L₃ is a substituted or unsubstituted arylene group having 6 to 30 ring-forming carbon atoms or a substituted or unsubstituted heteroarylene group having 2 to 30 ring-forming carbon atoms; and when a₃ is 2 or greater, L₄ may be a substituted or unsubstituted arylene group having 6 to 30 ring-forming carbon atoms or a substituted or unsubstituted heteroarylene group having 2 to 30 ring-forming carbon atoms.

In an embodiment, the third compound represented by Formula ET-1 may be selected from Compound Group 3. In an embodiment, in the light emitting element ED, the third compound may include at least one compound selected from Compound Group 3.

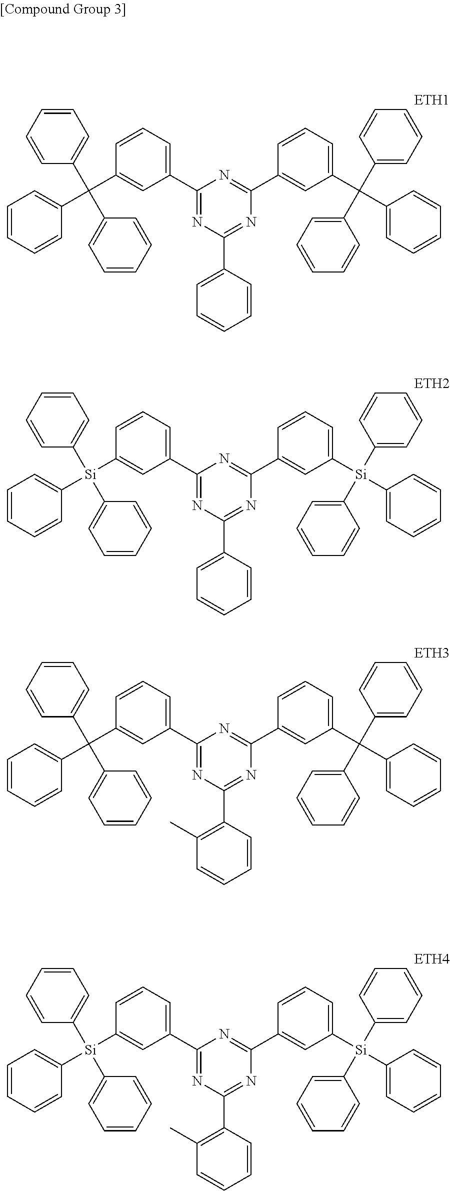 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

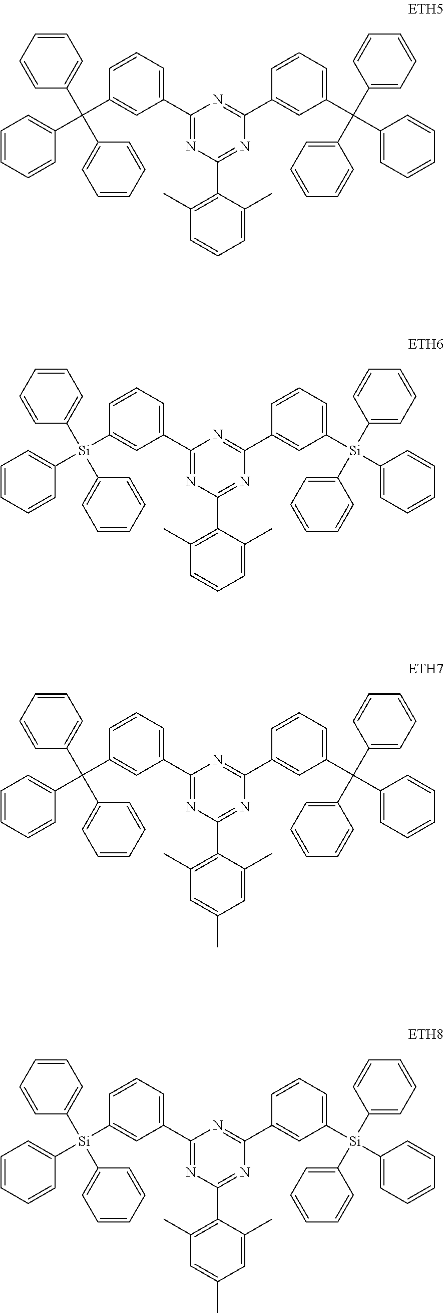 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

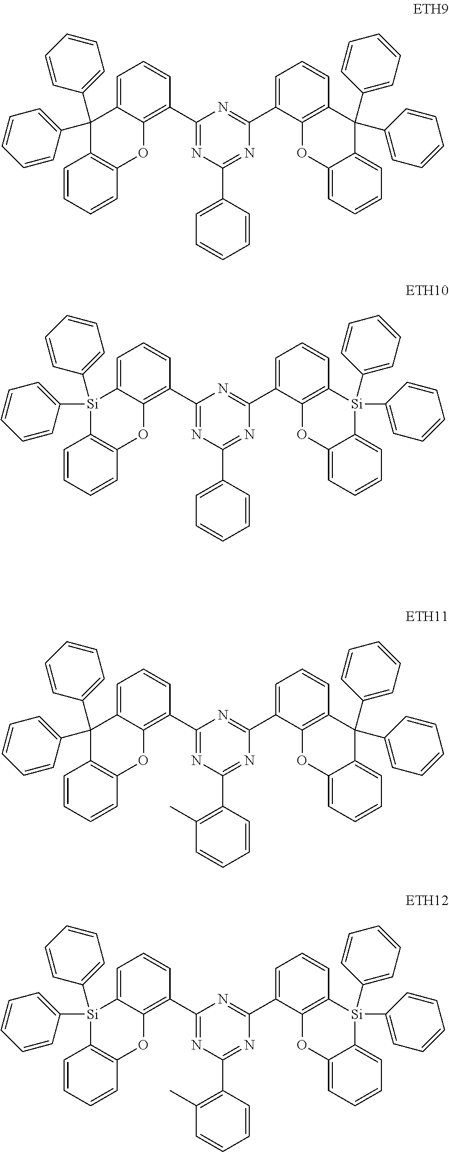 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

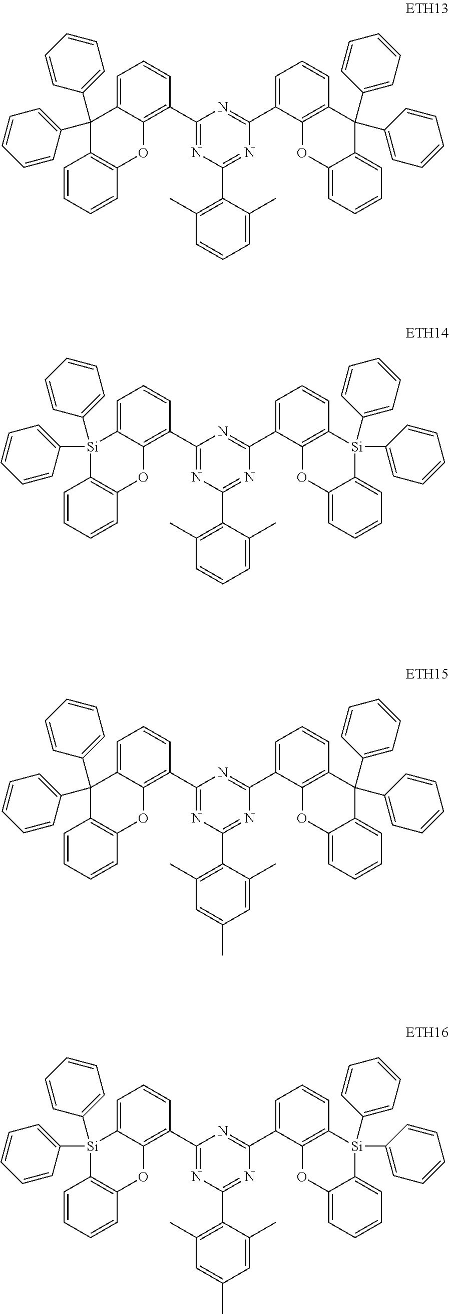 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

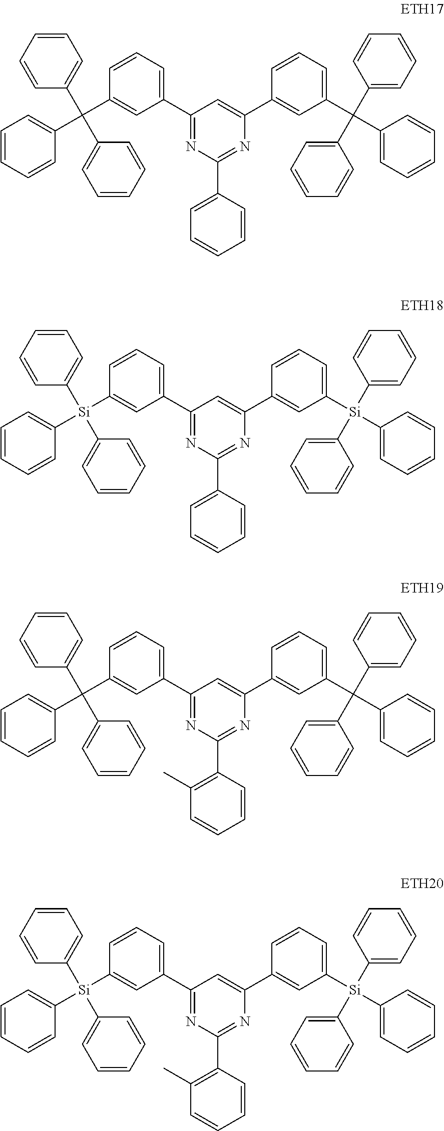 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

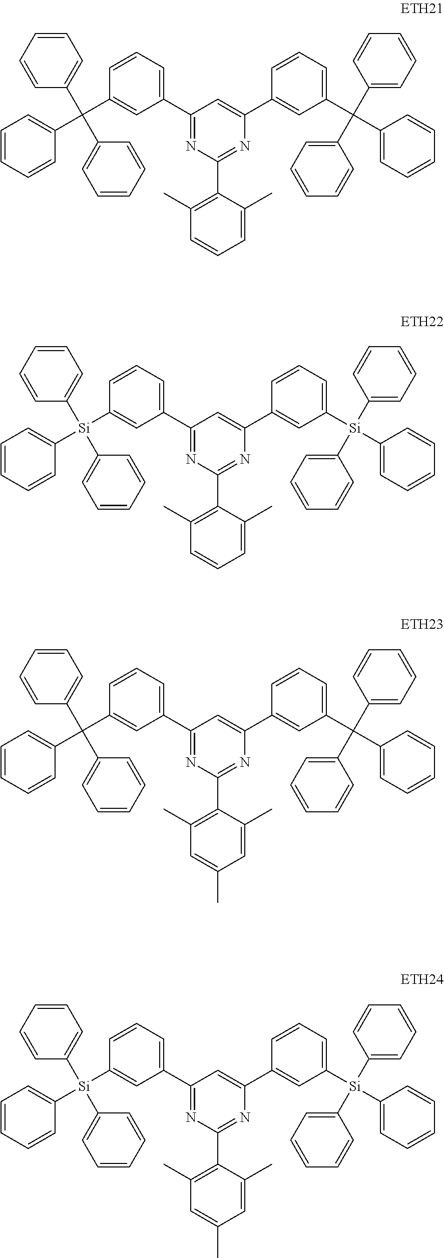 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

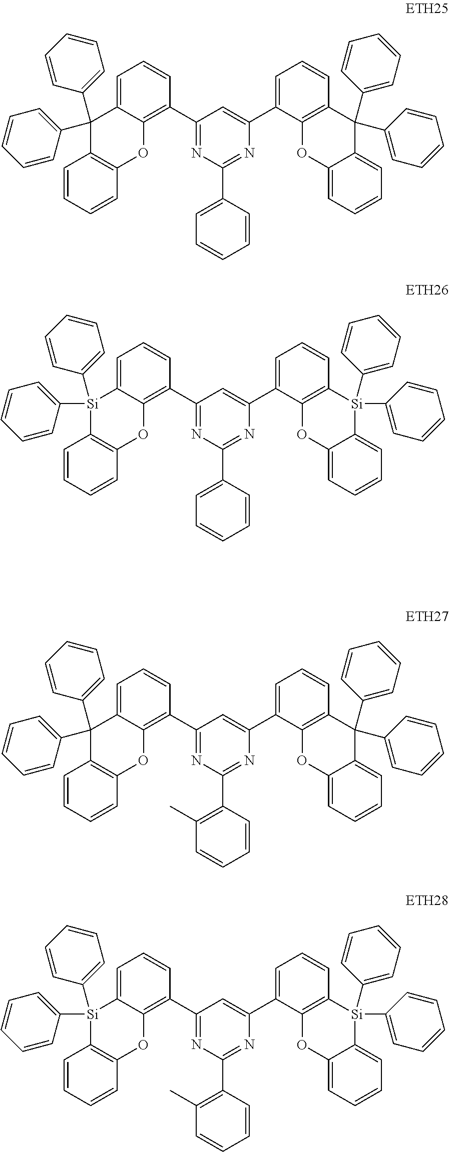 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

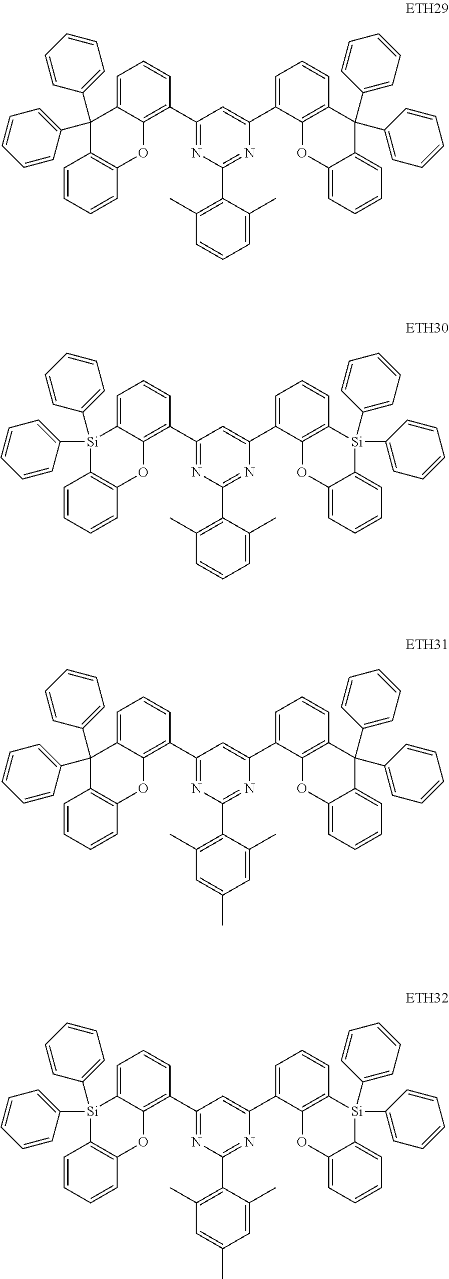 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

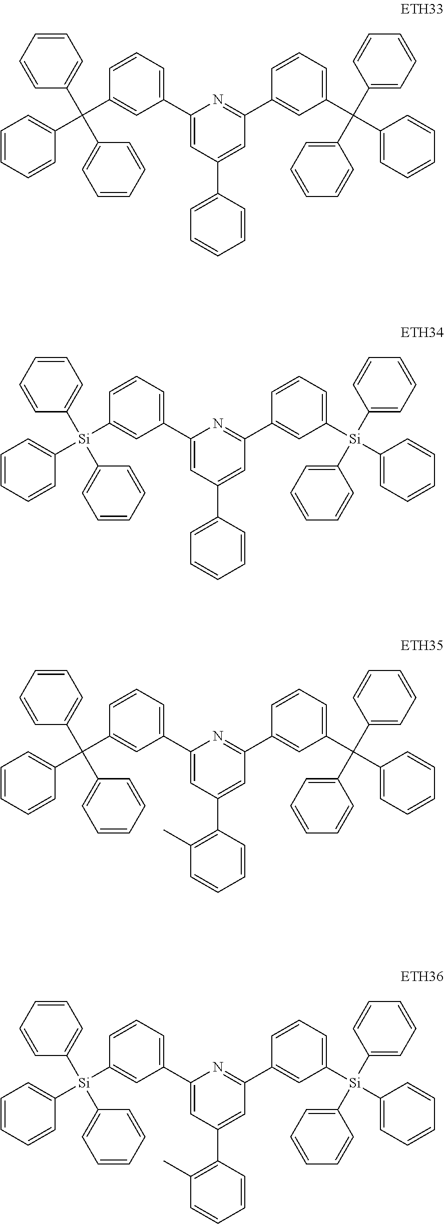 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

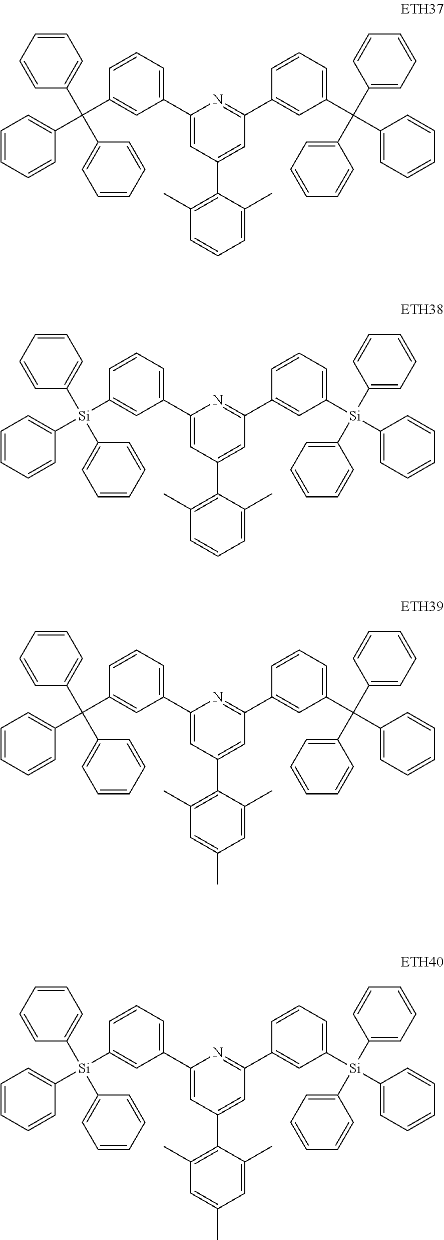 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

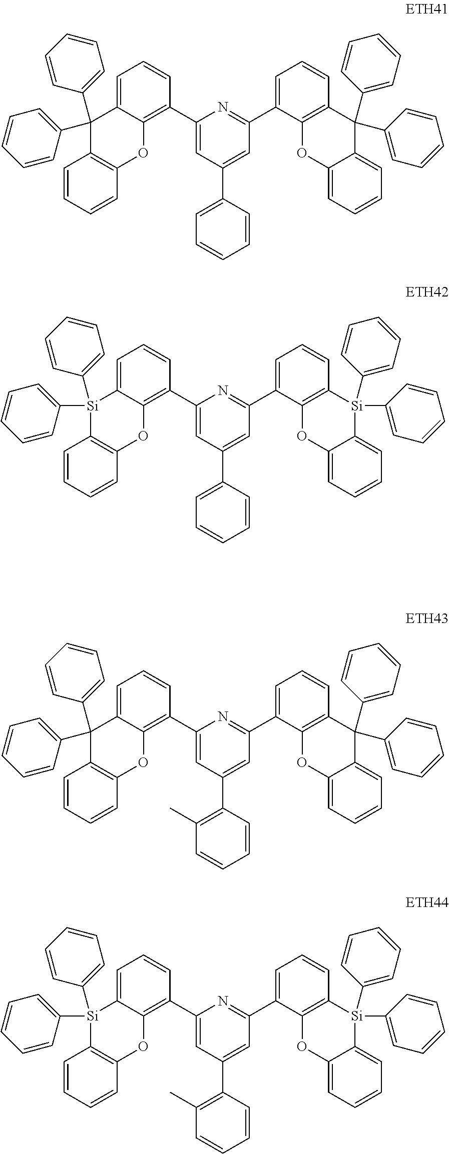 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

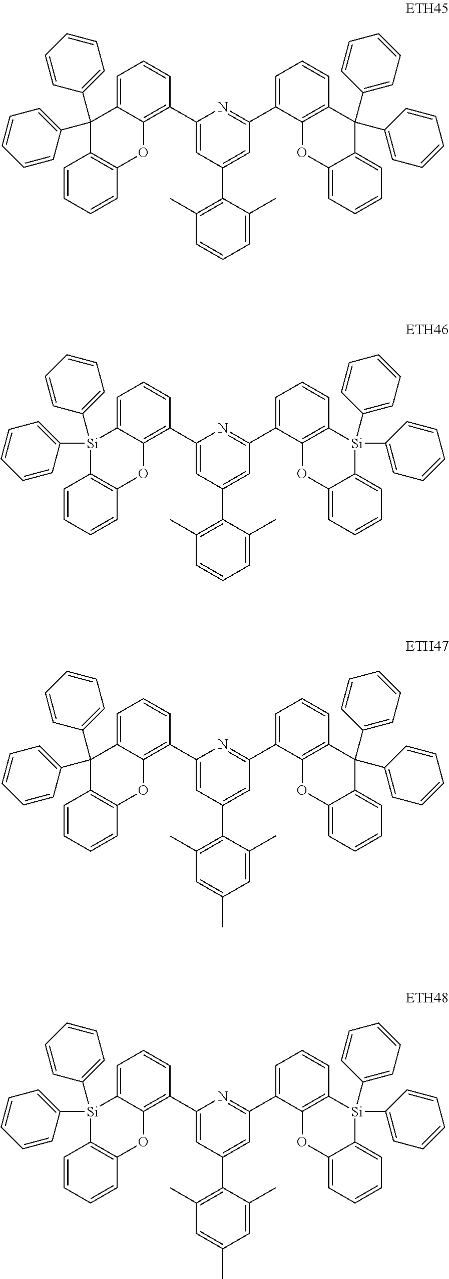 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

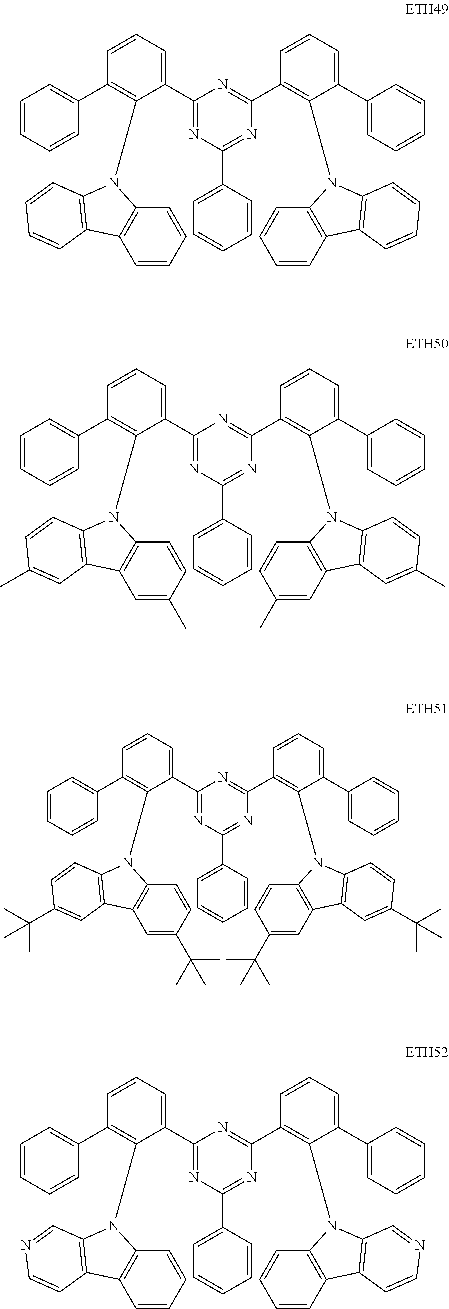

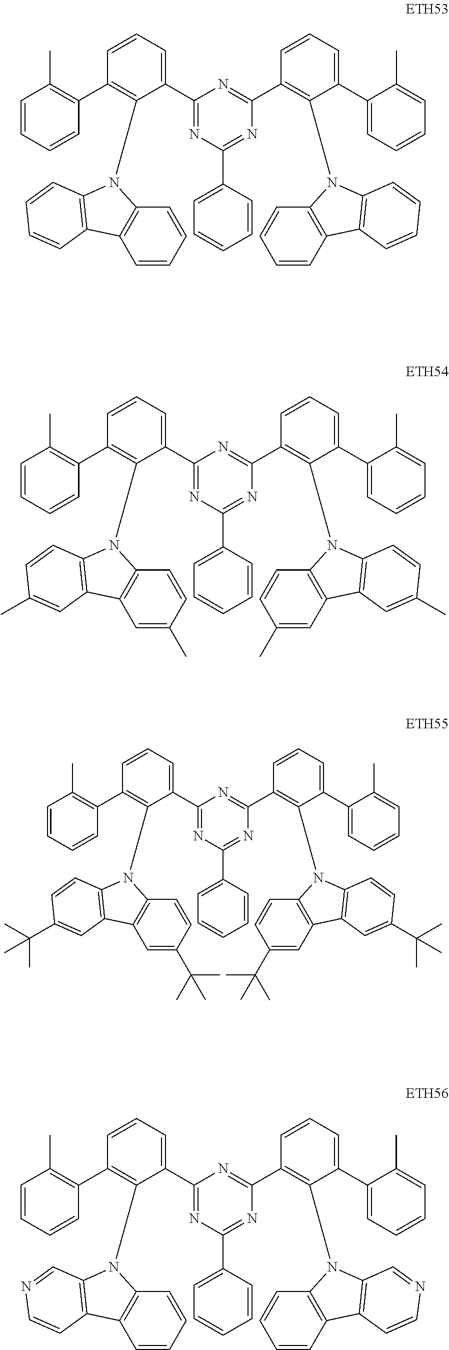

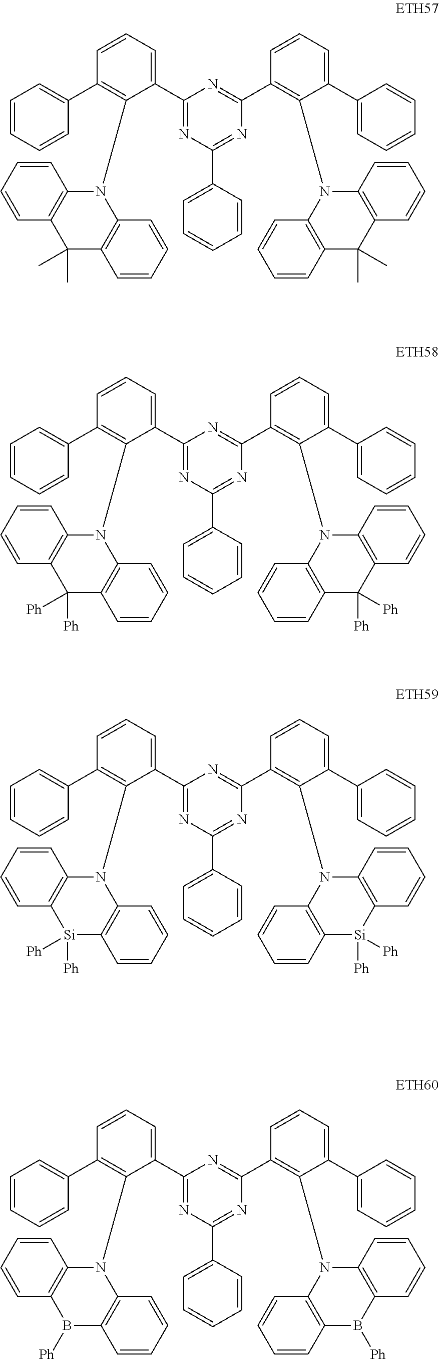

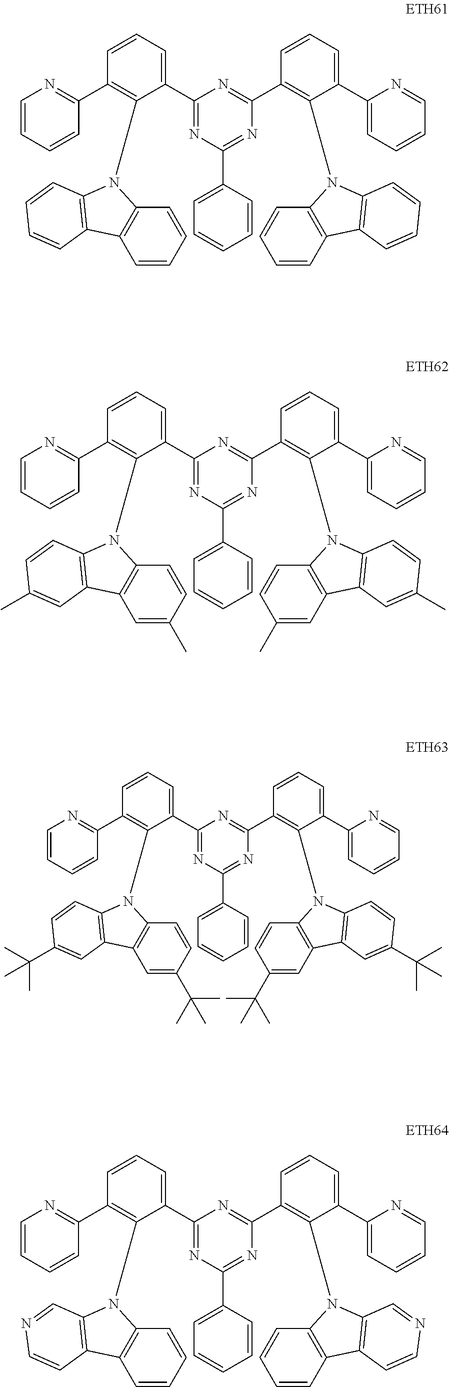

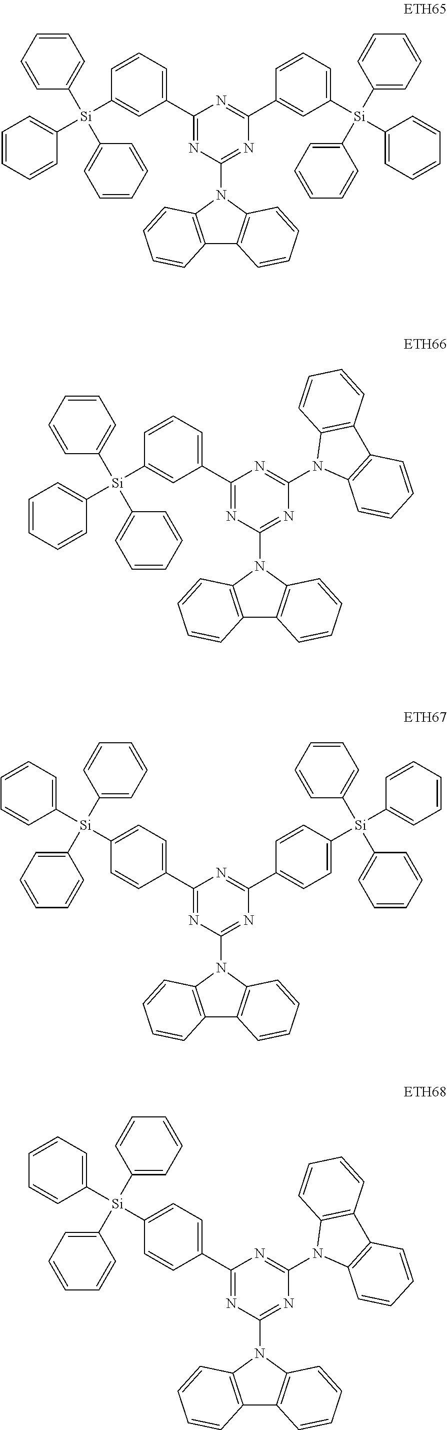 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

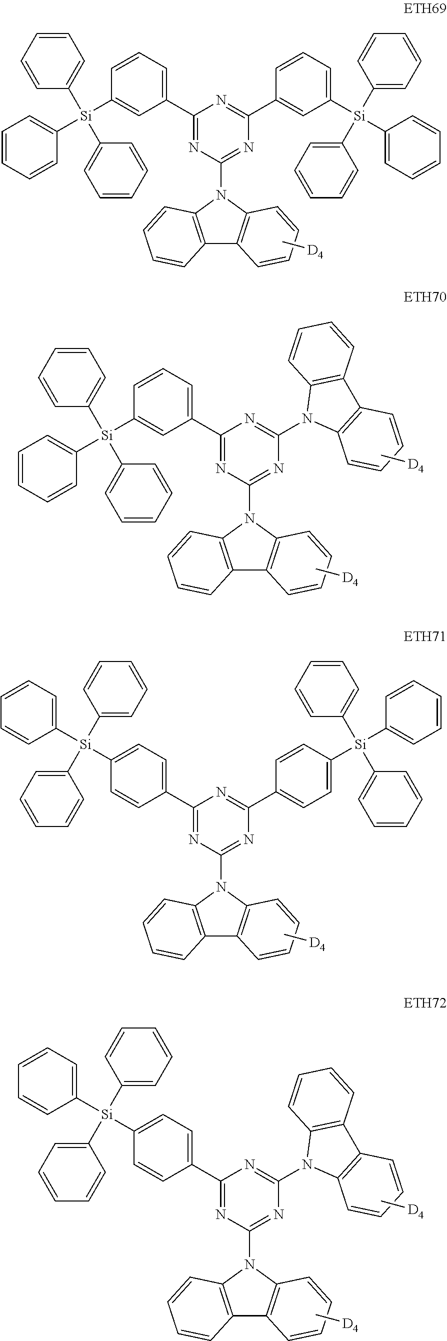

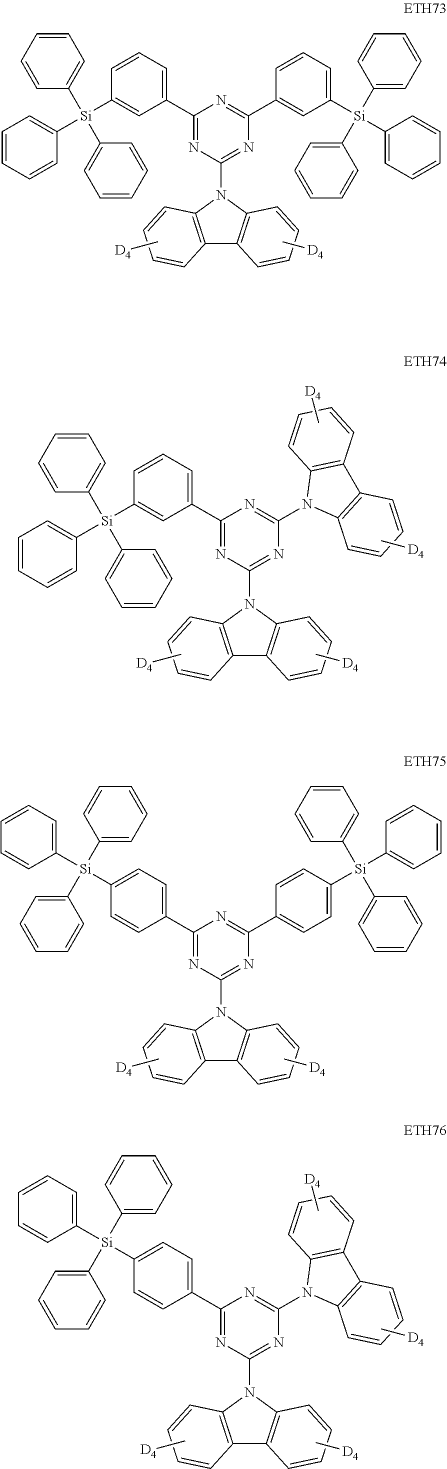

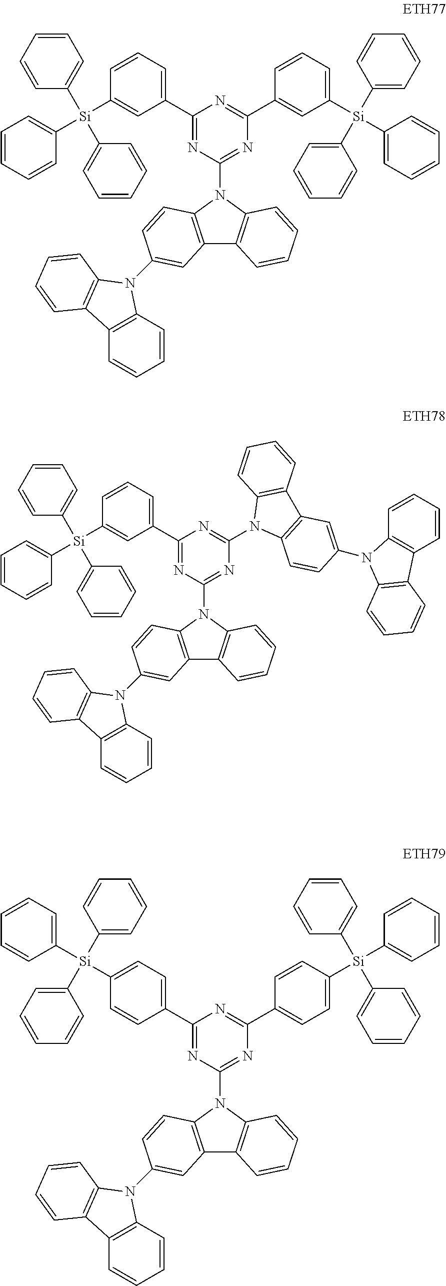 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

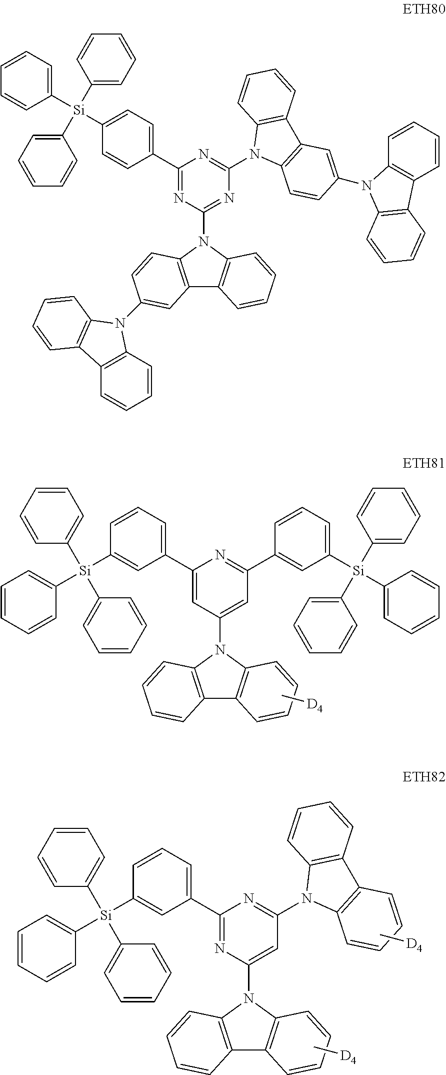

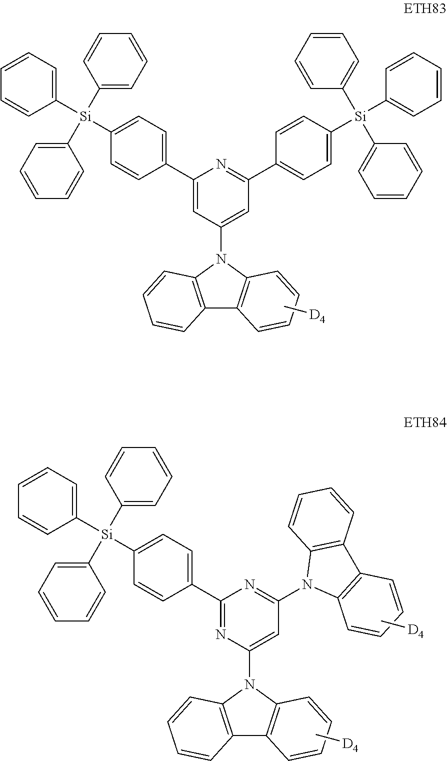

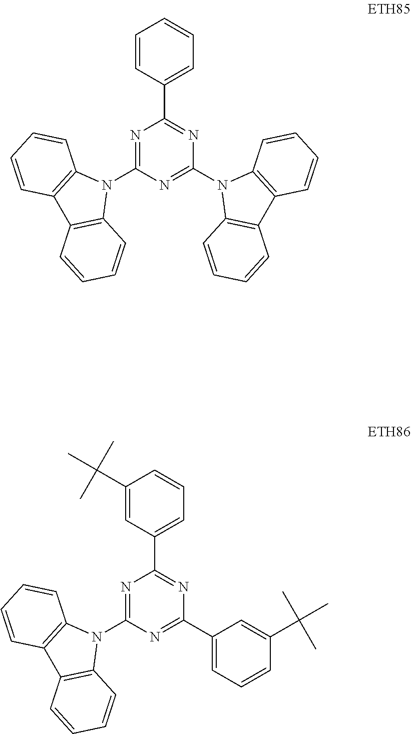 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In Compound Group 3, D represents a deuterium atom, and Ph represents an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy level of the exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, an absolute value of a triplet energy level (Ti) of the exciplex formed by the hole transporting host and the electron transporting host may be in a range of about 2.4 eV to about 3.0 eV. The triplet energy level of the exciplex may have a value that is smaller than an energy gap of each host material. The exciplex may have a triplet energy level less than or equal to about 3.0 eV, which is an energy gap between the hole transporting host and the electron transporting host.

In an embodiment, the emission layer EML may include a fourth compound, in addition to the first compound, the second compound, and the third compound as described above. The fourth compound may be used as a phosphorescent sensitizer in the emission layer EML. Energy may be transferred from the fourth compound to the first compound, thereby emitting light.

The emission layer EML may include a fourth compound that is an organometallic complex containing platinum (Pt) as a central metal atom and ligands connected to the central metal atom. In an embodiment, the emission layer EML may further include a fourth compound represented by Formula D-1:

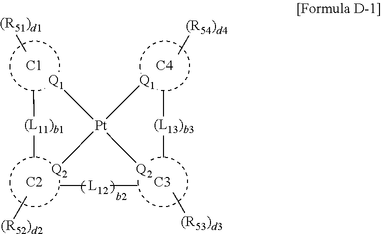

In Formula D-1, Q₁ to Q₄ may each independently C or N.

In Formula D-1, C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula D-1, L₁₁ to L₁₃ may each independently be a direct linkage, * —O—*, *—S—*

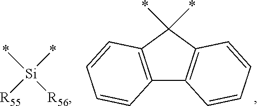

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, -* represents a bond to one of C1 to C4.

In Formula D-1, b1 to b3 may each independently be 0 or 1. If b1 is 0, C1 and C2 may not be directly linked to each other. If b2 is 0, C2 and C3 may not be directly linked to each other. If b3 is 0, C3 and C4 may not be directly linked to each other.

In Formula D-1, R₅₁ to R₅₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R₅₁ to R₅₆ may each independently be a substituted or unsubstituted methyl group or a substituted or unsubstituted t-butyl group.

In Formula D-1, d1 to d4 may each independently be an integer from 0 to 4. In Formula D-1, if d1 to d4 are each 0, the fourth compound may not be substituted with any of R₅₁ to R₅₄. A case where d1 to d4 are each 4 and all R₅₁ to R₅₄ groups are hydrogen atoms may be the same as a case where d1 to d4 are each 0. When d1 to d4 are each 2 or more, multiple groups of each of R₅₁ to R₅₄ may be the same as each other, or at least one group thereof may be different from the remainder.

In an embodiment, in Formula D-1, C1 to C4 may each independently be a substituted or unsubstituted hydrocarbon ring or a substituted or unsubstituted heterocycle that is represented by one of Formula C-1 to Formula C-4:

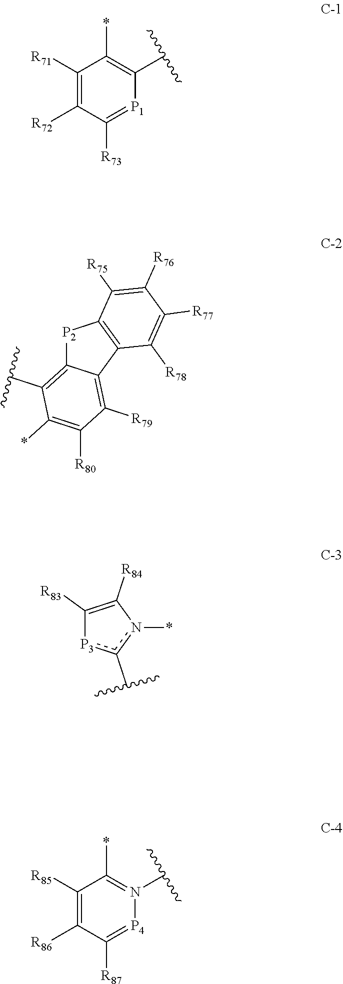

In Formula C-1 to Formula C-4, Pi may be C—* or C(R₇₄), P₂ may be N—* or N(R₈₁), P₃ may be N—* or N(R₈₂), and P₄ may be C—* or C(R₈₈).

In Formula C-1 to Formula C-4, R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula C-1 to Formula C-4,

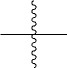

represents a bond to Pt, which is a central metal atom, and “-* represents a bond to a neighboring cyclic group (C1 to C4) or to a linker (L₁₁ to L₁₃).

In an embodiment, the emission layer EML may include the first compound represented by Formula 1, and at least one of the second compound, the third compound, and fourth compound. In an embodiment, the emission layer EML may include the first compound, the second compound, and the third compound. In the emission layer EML, the second compound and the third compound may form an exciplex, and energy may be transferred from the exciplex to the first compound, thereby emitting light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby emitting light. In an embodiment, the fourth compound may be a sensitizer. The fourth compound included in the emission layer EML of the light emitting element ED may serve as a sensitizer to transfer energy from the host to the first compound, which is a light emitting dopant. For example, the fourth compound, which serves as an auxiliary dopant, accelerates energy transfer to the first compound, which serves as a light emitting dopant, thereby increasing an emission ratio of the first compound. Therefore, the emission layer EML may have improved luminous efficiency. When energy transfer to the first compound is increased, excitons formed in the emission layer EML may not accumulate inside the emission layer EML and may emit light rapidly, so that deterioration of the device may be reduced. Therefore, the service life of the light emitting element ED may increase.

The light emitting element ED may include the first compound, the second compound, the third compound, and the fourth compound, and the emission layer EML may include the combination of two host materials and two dopant materials. In the light emitting element ED, the emission layer EML may include the second compound and the third compound, which are two different hosts, the first compound which emits delayed fluorescence, and the fourth compound which includes an organometallic complex, and thus the light emitting element ED may exhibit excellent luminous efficiency characteristics.

In an embodiment, the fourth compound represented by Formula D-1 may be selected from Compound Group 4. In an embodiment, in the light emitting element ED, the fourth compound may include at least one compound selected from Compound Group 4.

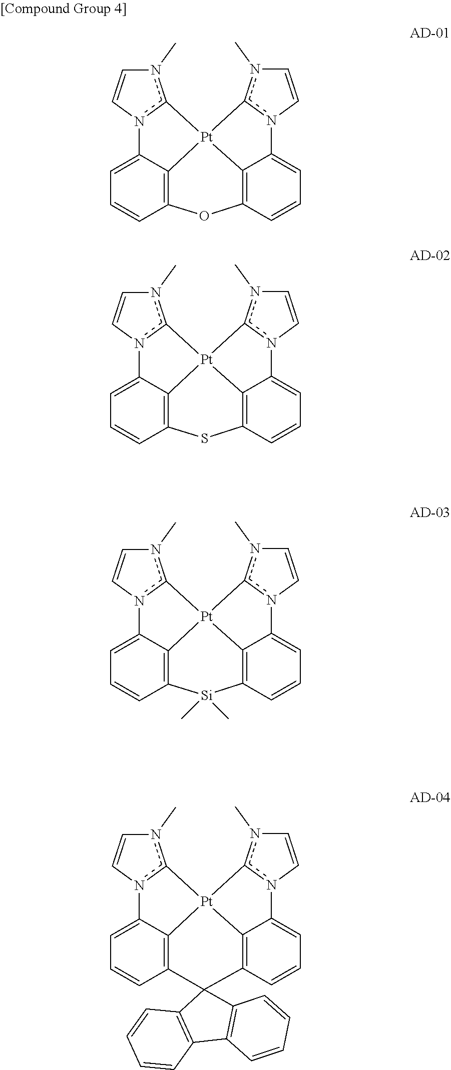

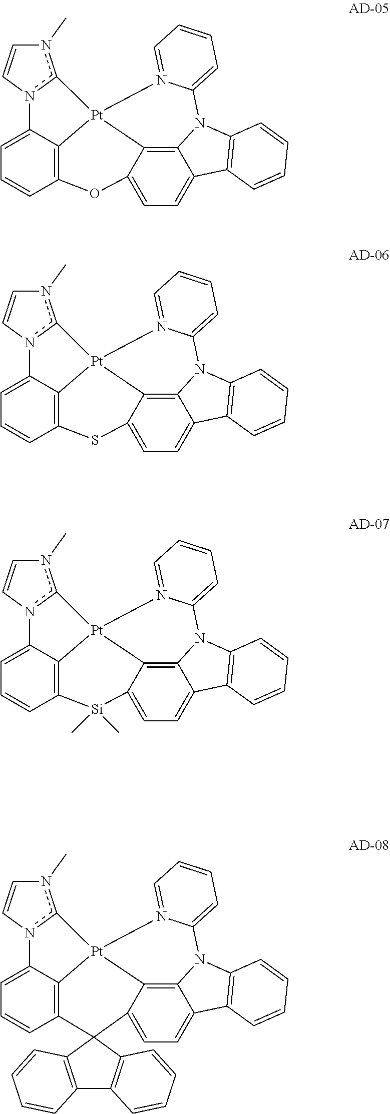

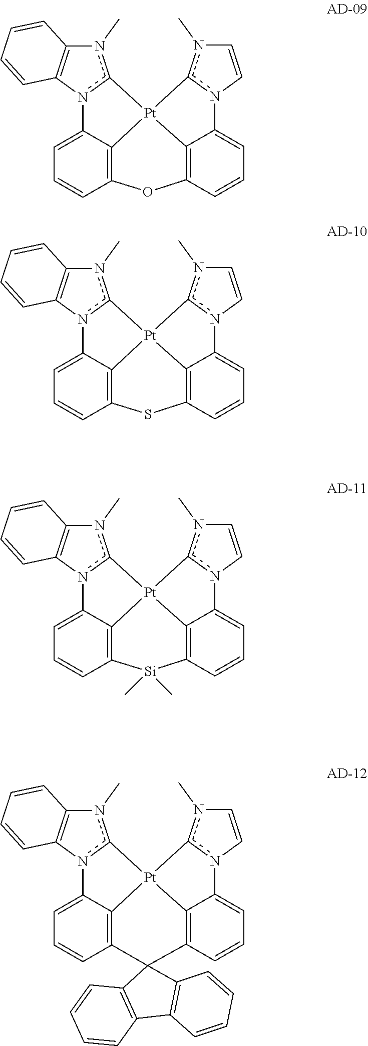

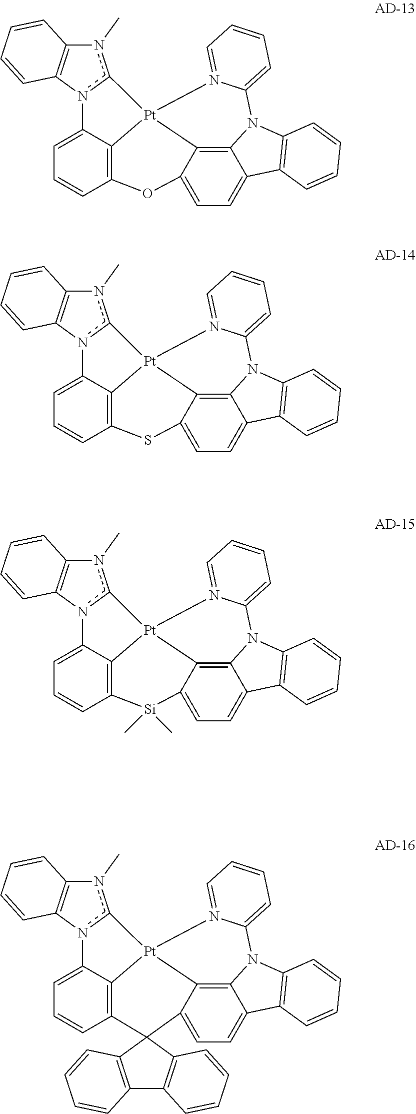

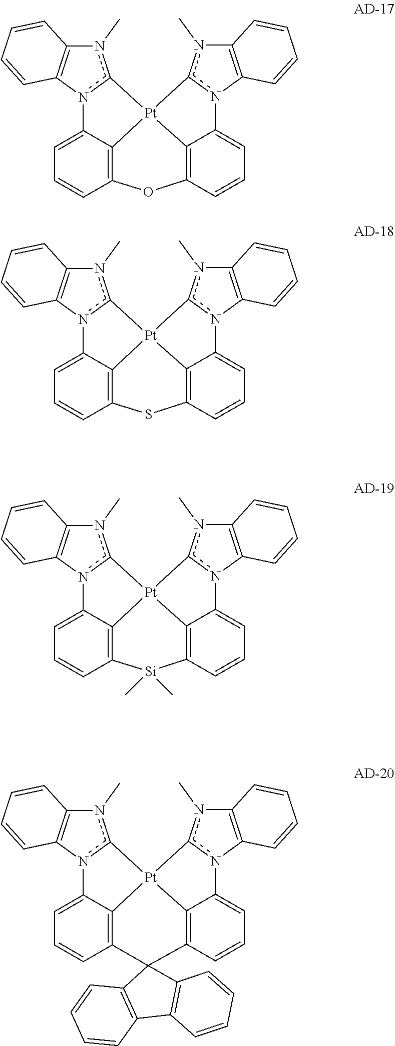

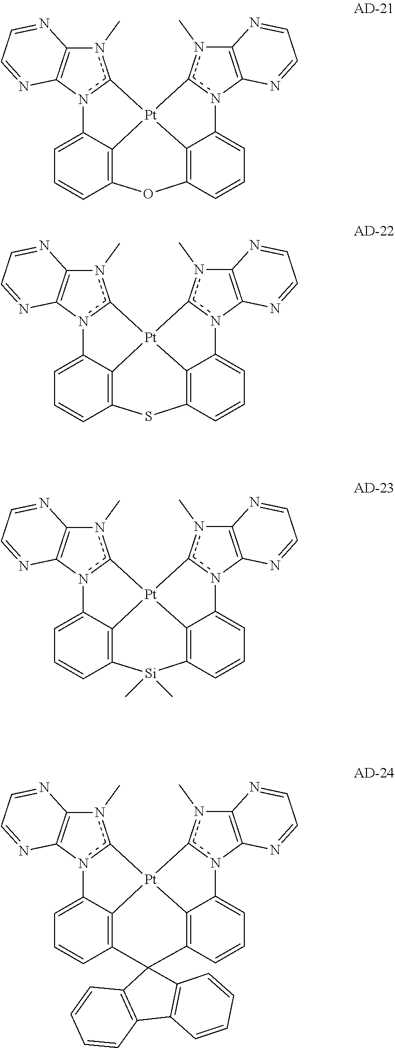

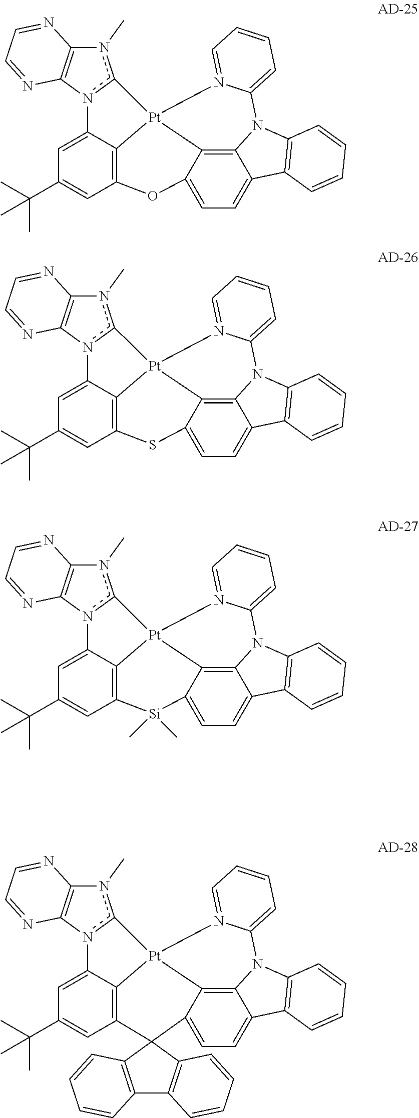

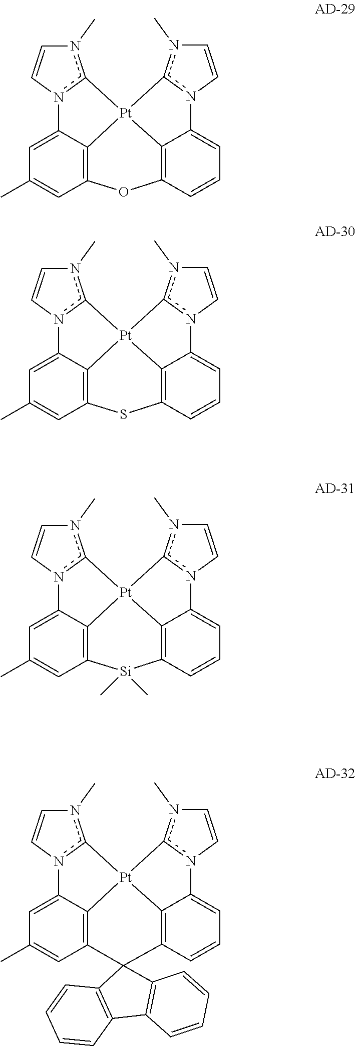

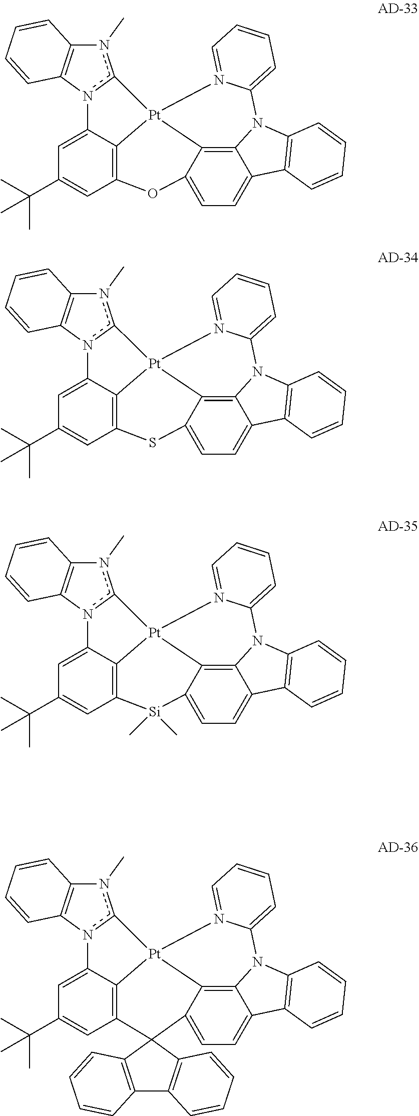

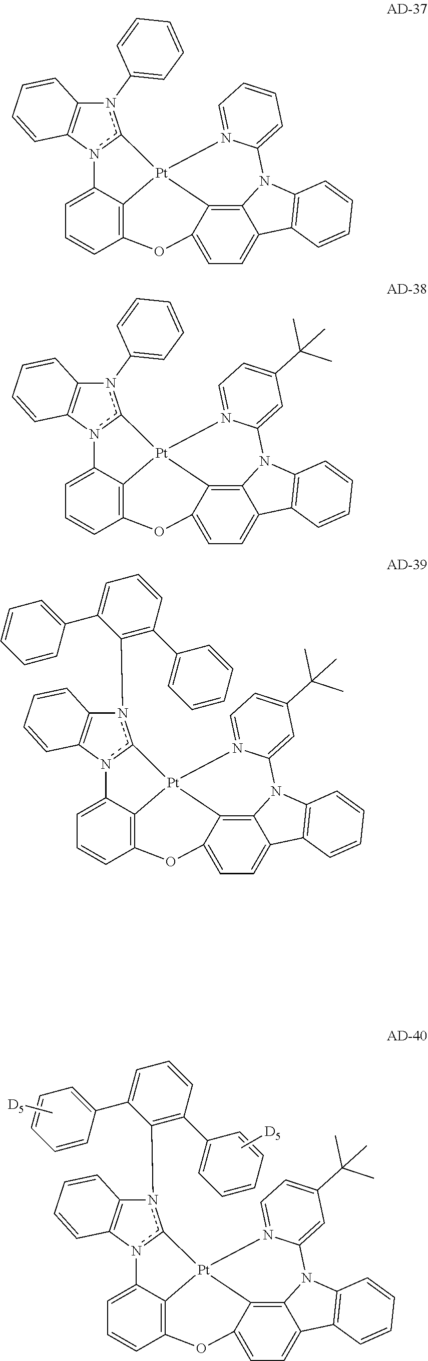

In Compound Group 4, D represents a deuterium atom.

When the emission layer EML in the light emitting element ED includes the first compound, the second compound, and the third compound, an amount of the first compound may be in a range of about 0.1 wt % to about 5 wt %, with respect to a total weight of the first compound, the second compound, and the third compound. However, embodiments are not limited thereto. When an amount of the first compound satisfies the above-described range, energy transfer from the second compound and the third compound to the first compound may increase, and thus the luminous efficiency and device service life may increase.

The combined amounts of the second compound and the third compound in the emission layer EML may be the remainder of the total weight of the first compound, the second compound, and the third compound, excluding the amount of the first compound. For example, a total amount of the second compound and the third compound in the emission layer EML may be in a range of about 65 wt % to about 95 wt %, with respect to a total weight of the first compound, the second compound, and the third compound.

Within the total amount of the second compound and the third compound in the emission layer EML, a weight ratio of the second compound to the third compound may be in a range of about 3:7 to about 7:3.

When the amounts of the second compound and the third compound satisfy the above-described ranges and ratios, a charge balance characteristic in the emission layer EML may be improved, and thus the luminous efficiency and device service life may increase.

When the amounts of the second compound and the third compound deviate from the above-described ranges and ratios, charge balance in the emission layer EML may not be achieved, and thus the luminous efficiency may be reduced and the device may readily deteriorate.

When the emission layer EML includes the fourth compound, an amount of the fourth compound in the emission layer EML may be in a range of about 10 wt % to about 30 wt %, with respect to a total weight of the first compound, the second compound, the third compound, and the fourth compound. However, embodiments are not limited thereto. When an amount of the fourth compound satisfies the above-described range, energy transfer from the host to the first compound, which is a light emitting dopant, may increase, so that a luminous ratio may be improved, and thus, luminous efficiency of the emission layer EML may be improved. When the amounts of the first compound, the second compound, the third compound, and the fourth compound included in the emission layer EML satisfy the above-described ranges and ratios, excellent luminous efficiency and long service life may be achieved.

In the light emitting element ED, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting element ED according to embodiments as shown in each of FIGS. 3 to 6, the emission layer EML may further include a host and a dopant of the related art, in addition to the above-described host and dopant. In an embodiment, the emission layer EML may include a compound represented by Formula E-1. The compound represented by Formula E-1 may be used as a fluorescent host material.

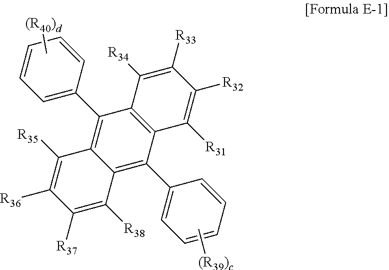

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, in Formula E-1, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19:

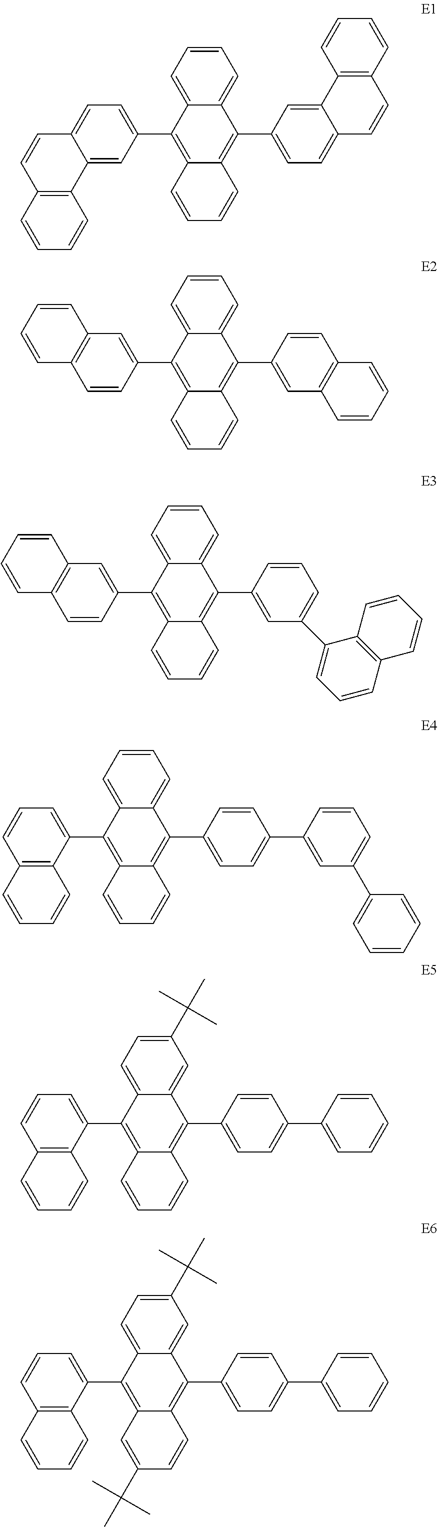

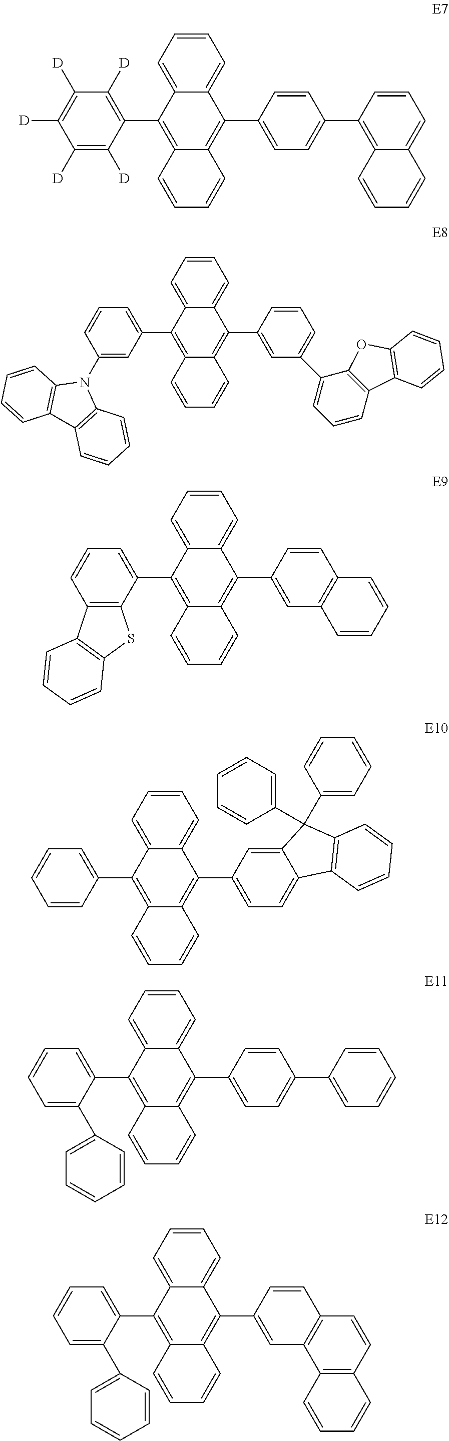

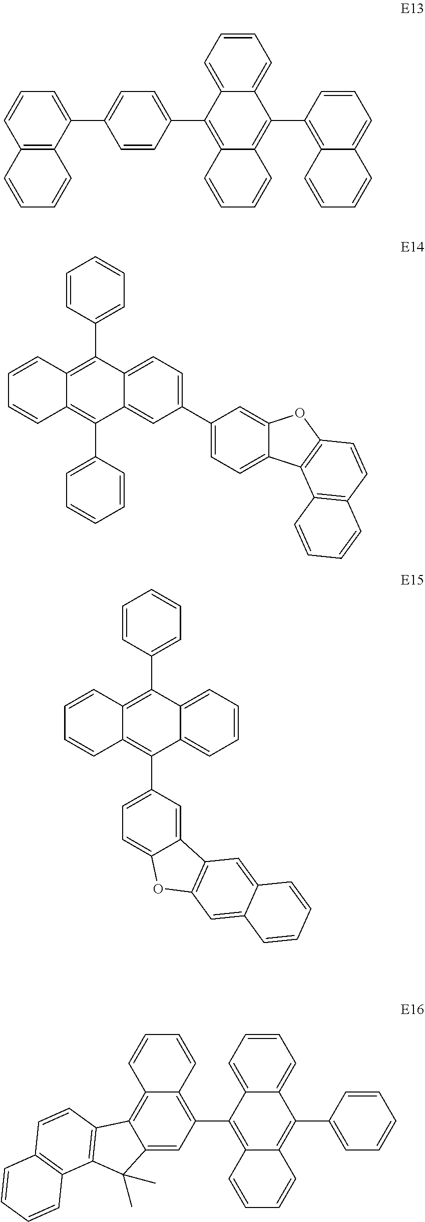

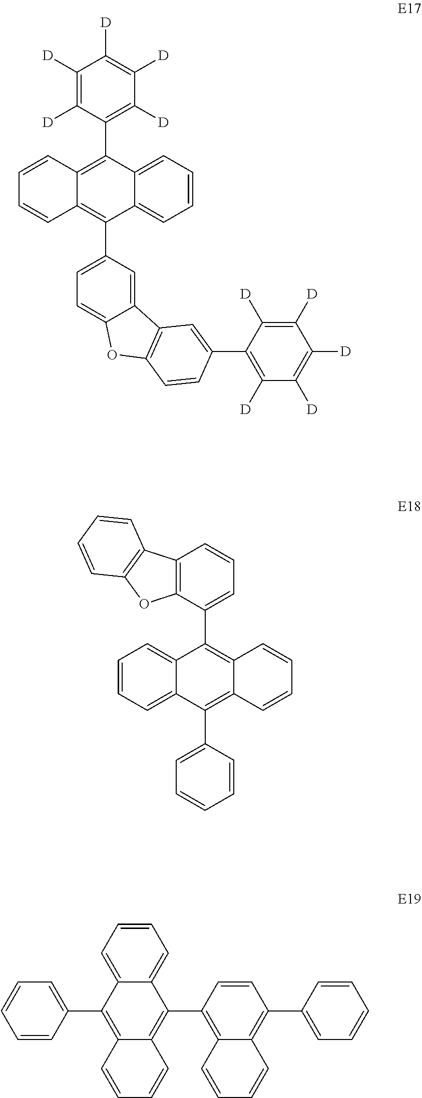

In an embodiment, the emission layer EML may include a compound represented by Formula E-2a or Formula E-2b. The compound represented by Formula E-2a or Formula E-2b may be used as a phosphorescent host material.

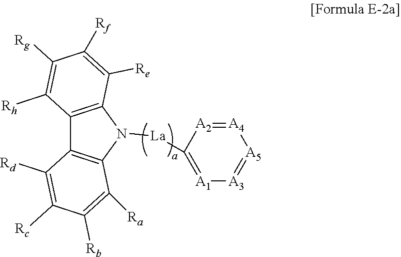

In Formula E-2a, a may be an integer from to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple Lₐ groups may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

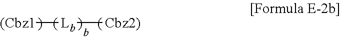

In Formula E-2b, Cbz1 and Cbz2 may each independently be an unsubstituted carbazole group, or a carbazole group substituted with an aryl group having 6 to 30 ring-forming carbon atoms. In Formula E-2b, Le may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or more, multiple Le groups may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any one compound selected from Compound Group E-2. However, the compounds listed in Compound Group E-2 are only examples, and the compound represented by Formula E-2a or Formula E-2b is not limited to Compound Group E-2.

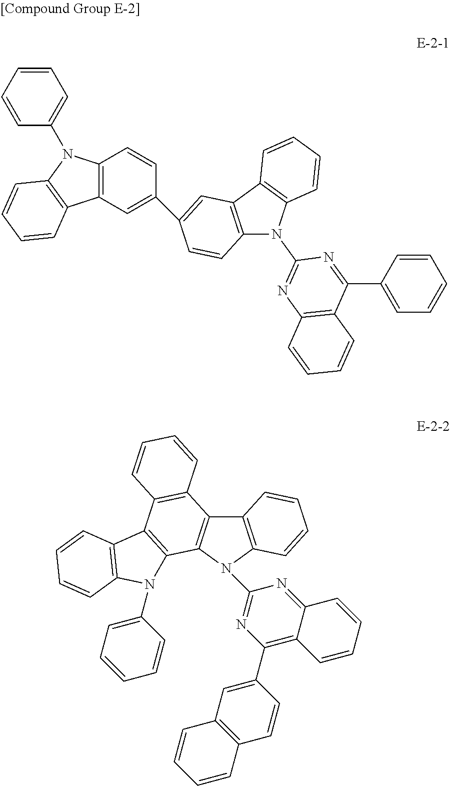 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1]

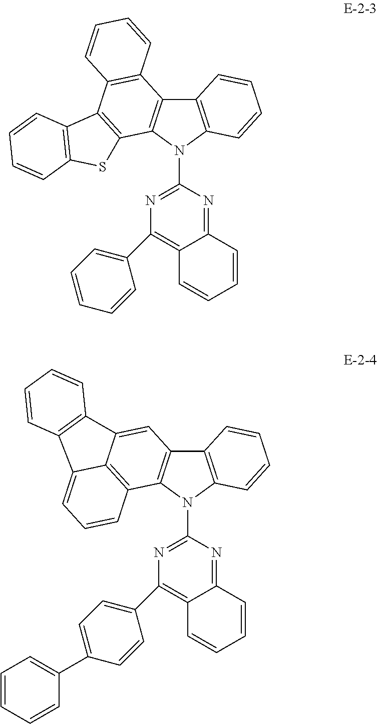 [SMILES: c1ccc(-c2nc(-n3c4ccccc4c4c5ccccc5c5c6ccccc6sc5c43)nc3ccccc23)cc1 ; c1ccc(-c2ccc(-c3nc(-n4c5ccccc5c5cc6c7c(cccc7c54)-c4ccccc4-6)nc4ccccc34)cc2)cc1]

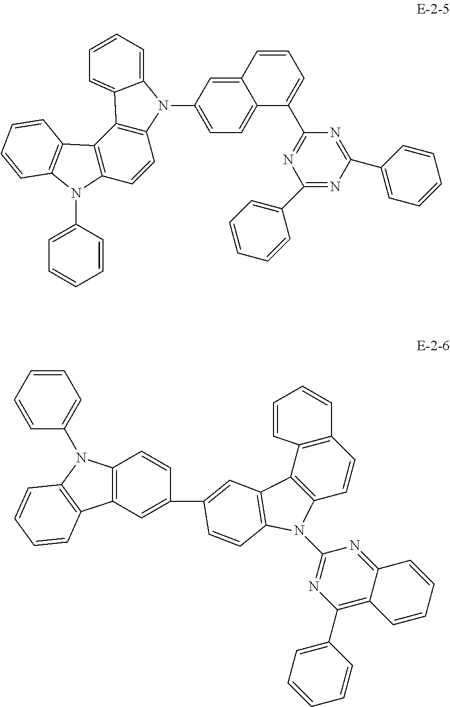 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

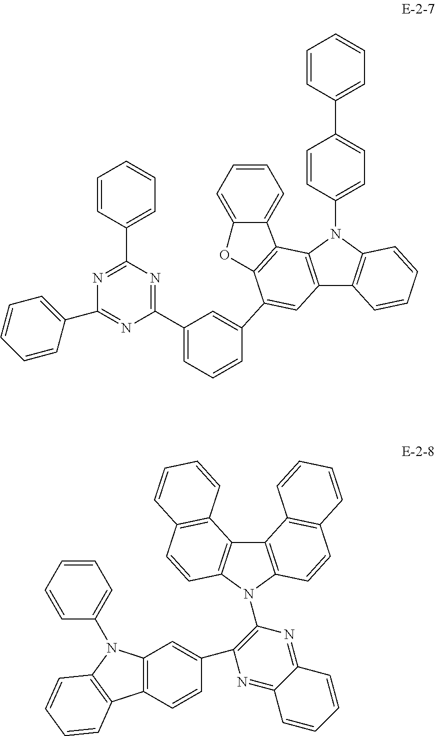 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

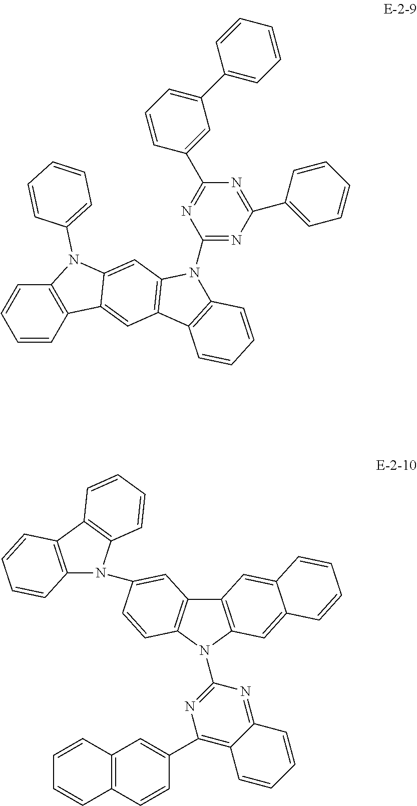 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1]

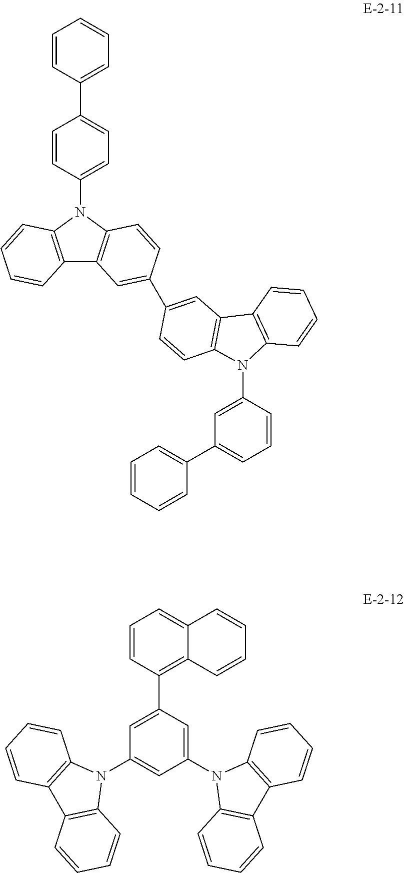 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

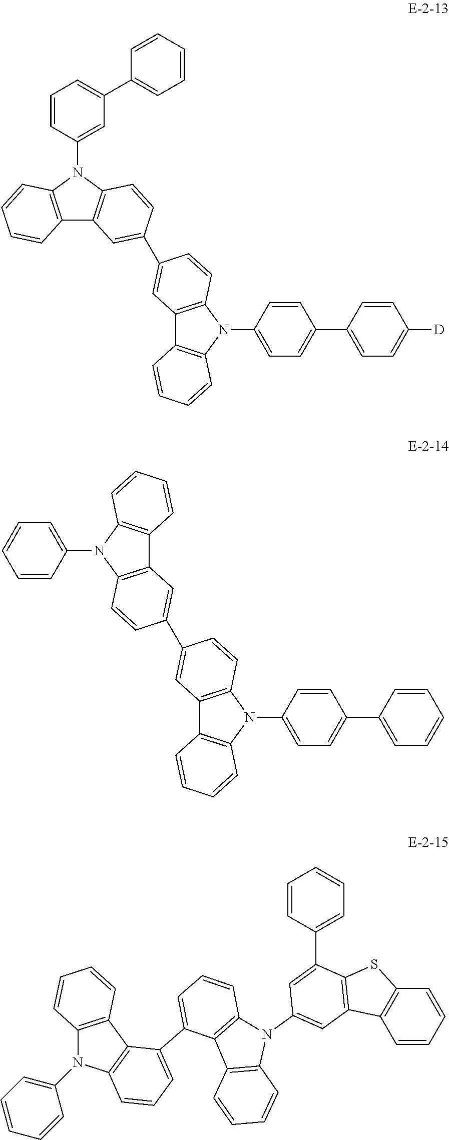 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

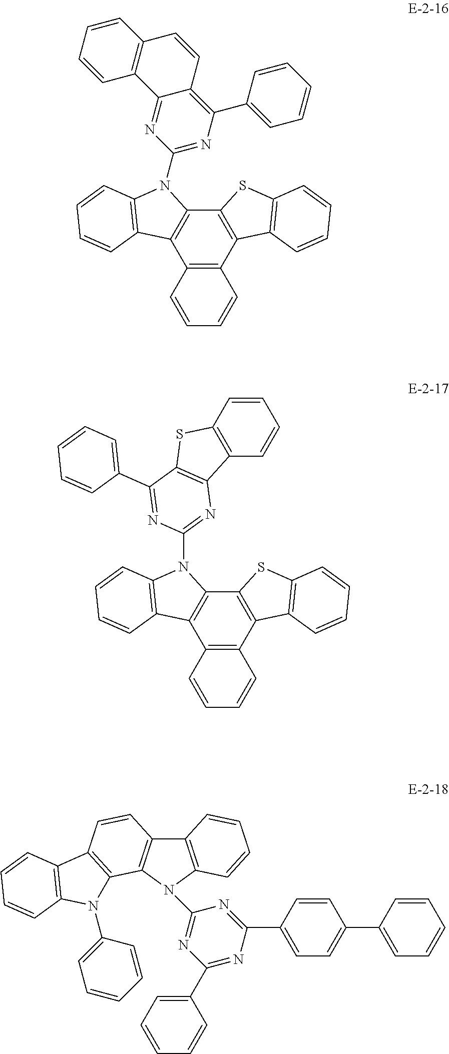 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

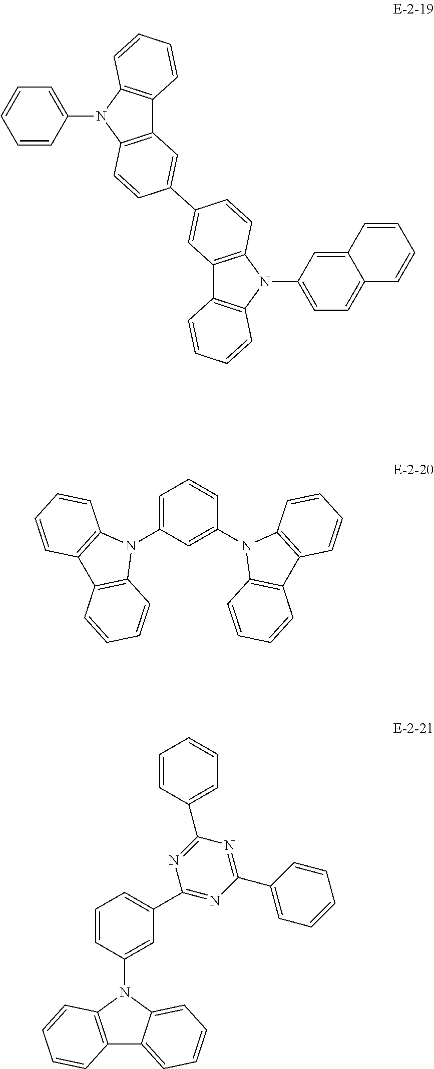 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

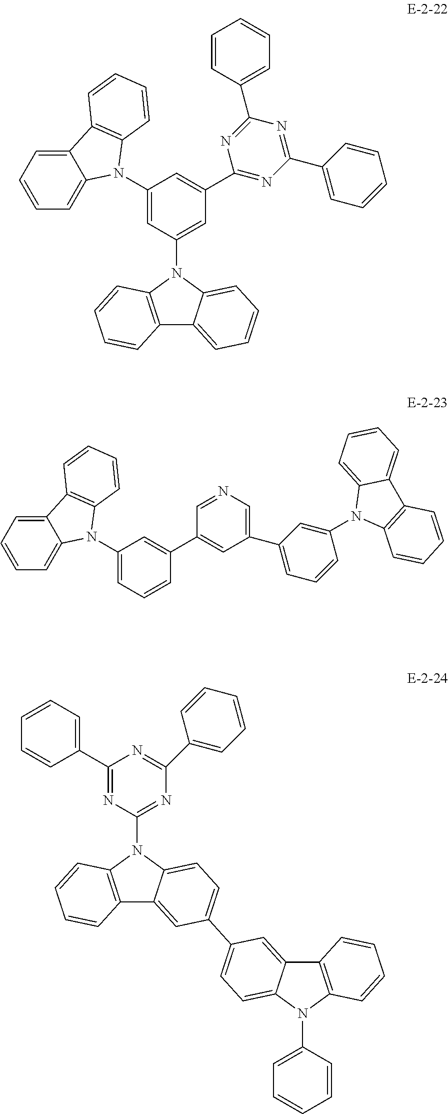 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

In an embodiment, the emission layer EML may include a compound represented by Formula M-a. The compound represented by Formula M-a may be used as a phosphorescent dopant material.

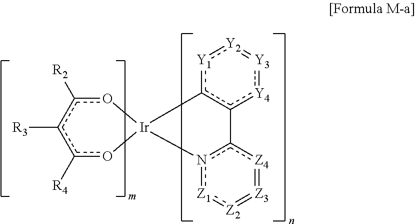

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

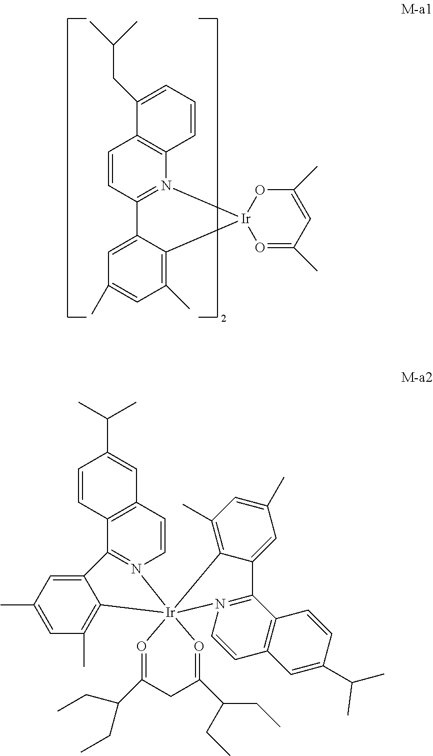

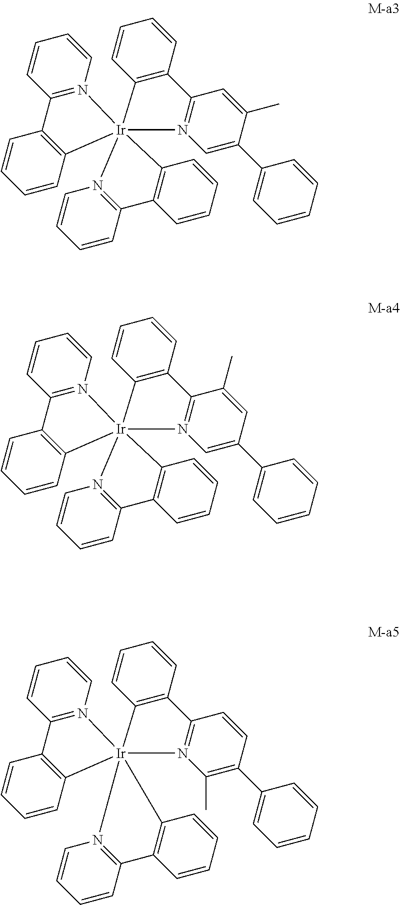

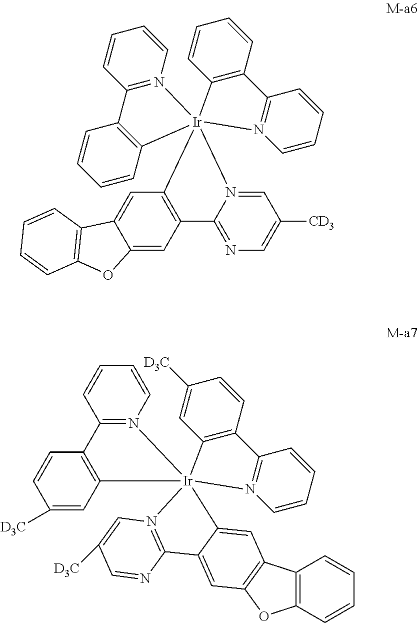

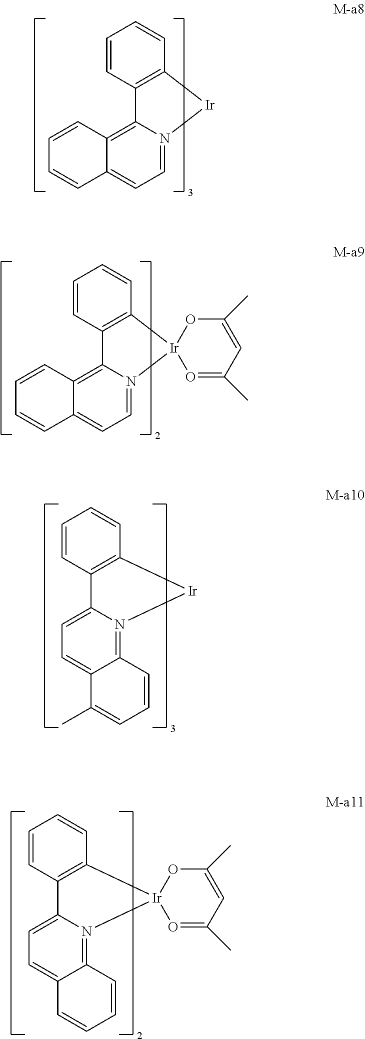

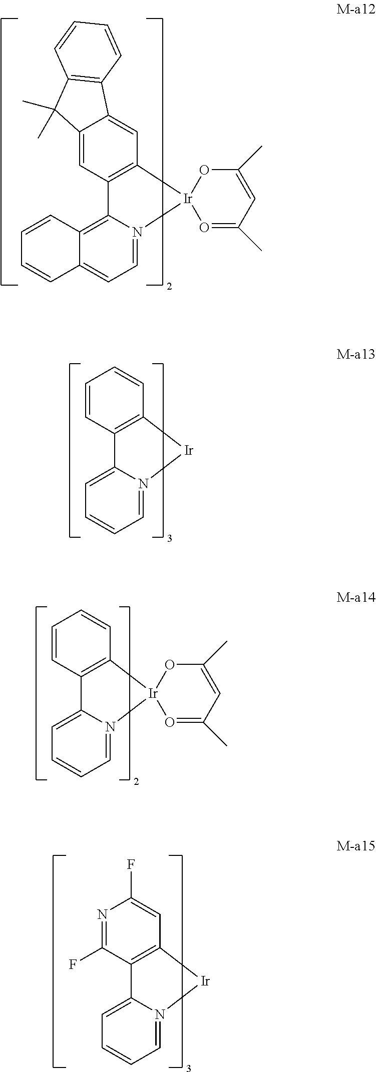

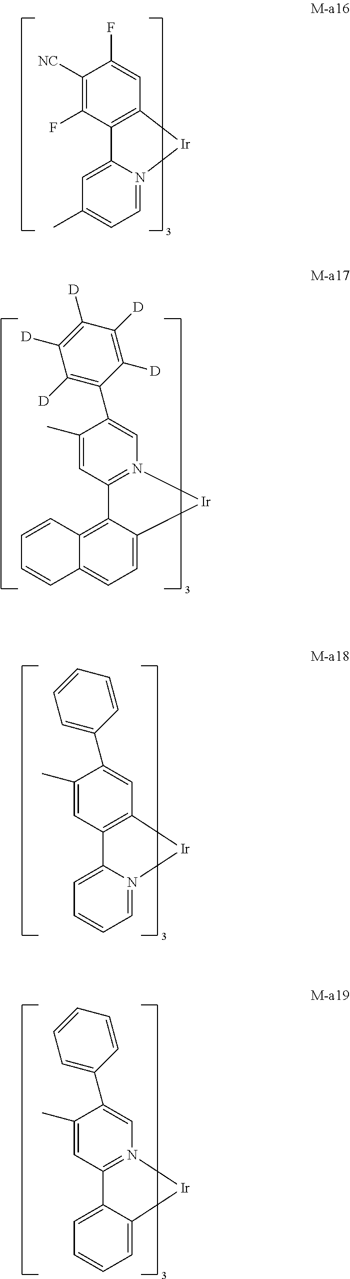

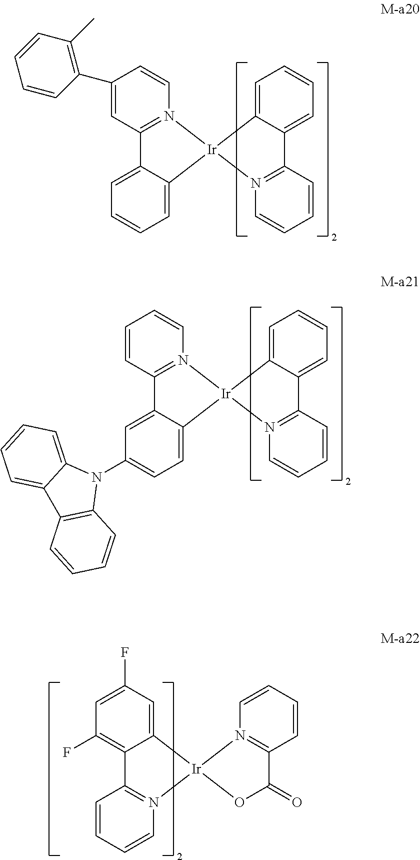

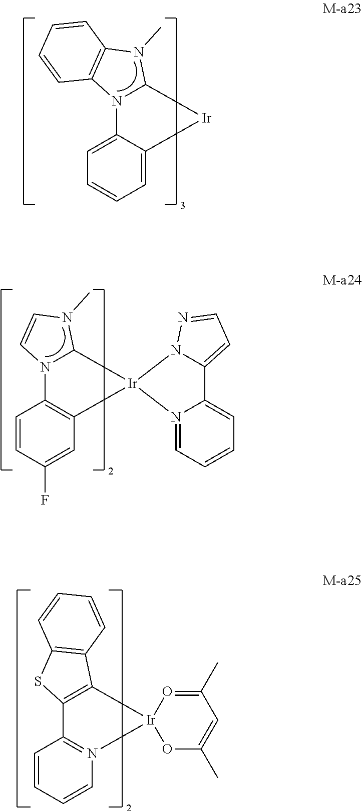

In an embodiment, the emission layer EML may include a compound represented by one Formula F-a to Formula F-c. The compound represented by one of Formula F-a to Formula F-c may be used as a fluorescence dopant material.

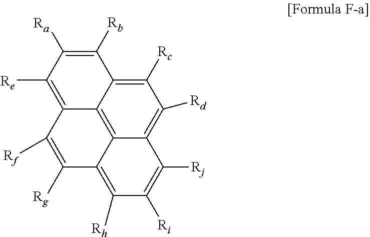

In Formula F-a, two of Rₐ to Rⱼ may each independently be substituted with a group represented by *—NAr₁Ar₂. The remainder of Rₐ to Rⱼ which are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ and Ar₂ may be a heteroaryl group containing O or S as a ring-forming atom.

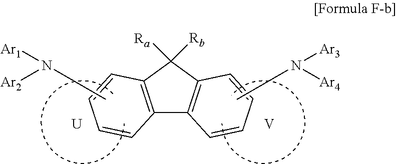

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ to Ar₄ may be a heteroaryl group containing O or S as a ring-forming atom.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. When the number of U or V is 1, a fused ring may be present at a portion indicated by U or V, and when the number of U or V is 0, a fused ring may not be present at the portion indicated by U or V. When the number of U is 0 and the number of V is 1, or when the number of U is 1 and the number of V is 0, a fused ring having a fluorene core of Formula F-b may be a cyclic compound having four rings. When the number of U and V is each 0, a fused ring having a fluorene core of Formula F-b may be a cyclic compound having three rings. When the number of U and V is each 1, a fused ring having a fluorene core of Formula F-b may be a cyclic compound having five rings.

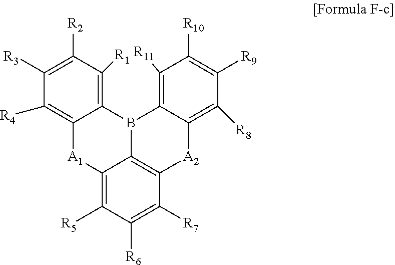

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula F-c, A₁ and A₂ may each independently be bonded to a substituent of an adjacent ring to form a fused ring. For example, when A₁ and A₂ are each independently N(Rₘ), A₁ may be bonded to R₄ or R₅ to form a ring. For example, A₂ may be bonded to R₇ or R₈ to form a ring.

In an embodiment, the emission layer EML may further include, as a dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2) (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

In an embodiment, the emission layer EML may include a quantum dot. The quantum dot may be a Group II-VI compound, a Group III-VI compound, a Group I-III-VI compound, a Group III-V compound, a Group III-II-V compound, a Group IV-VI compound, a Group IV element, a Group IV compound, or a combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof; or any combination thereof.

Examples of a Group III-VI compound may include: a binary compound such as In₂S₃ or In₂Se₃; a ternary compound such as InGaS₃ or InGaSe₃; or any combination thereof.

Examples of a Group I-III-VI compound may include: a ternary compound selected from the group consisting of AgInS, AgInS₂, CuInS, CuInS₂, AgGaS₂, CuGaS₂ CuGaO₂, AgGaO₂, AgAlO₂, and a mixture thereof; a quaternary compound such as AgInGaS₂ or CuInGaS₂; or any combination thereof.

Examples of a Group III-V compound may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; or any combination thereof. In an embodiment, a Group III-V compound may further include a Group II metal. For example, InZnP, etc., may be selected as a Group III-II-V compound.

Examples of a Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; or any combination thereof. Examples of a Group IV element may include Si, Ge, and a mixture thereof. Examples of a Group IV compound may include a binary compound selected from the group consisting of SiC, SiGe, and a mixture thereof.

Each element included in a polynary compound, such as a binary compound, a ternary compound, or a quaternary compound, may be present in a particle at a uniform concentration distribution or at a non-uniform concentration distribution. For example, a formula may indicate the elements included in a compound, but the ratio of elements in the compound may be different. For example, AgInGaS₂ may mean AgInₓGa₁₋ₓS₂ (where x is a real number from 0 to 1).

In an embodiment, a quantum dot may have a single structure, in which the concentration of each element included in the quantum dot is uniform, or a quantum dot may have a core-shell structure in which a quantum dot surrounds another quantum dot. For example, a material included in the core may be different from a material included in the shell.

The shell of the quantum dot may serve as a protection layer to prevent the chemical deformation of the core to maintain semiconductor properties, and/or may serve as a charging layer to impart electrophoresis properties to the quantum dot. The shell may be a single layer or multiple layers. An interface between the core and the shell may have a concentration gradient in which the concentration of an element that is present in the shell decreases towards the core.

In embodiments, the quantum dot may have the above-described core/shell structure including a core containing nanocrystals and a shell surrounding the core. Examples of a shell of a quantum dot may include a metal oxide, a non-metal oxide, a semiconductor compound, or a combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound such as MgAl₂O₄, CoFe₂O₄, NiFe₂O₄, or CoMn₂O₄; or any combination thereof. However, embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Color purity or color reproducibility may be improved within any of the above ranges. Light emitted through a quantum dot may be emitted in all directions, so that a wide viewing angle may be improved.

The form of a quantum dot is not particularly limited and may be any form used in the related art. For example, the quantum dot may have a spherical shape, a pyramidal shape, a multi-arm shape, or a cubic shape, or the quantum dot may be in the form of nanoparticles, nanotubes, nanowires, nanofibers, nanoplate particles, etc.

As a size of the quantum dot is adjusted or an elemental ratio of a quantum dot compound is adjusted, it is possible to control the energy band gap, and thus light in various wavelength ranges may be obtained from a quantum dot. Therefore, a quantum dot as described above (using different sizes of quantum dots or different elemental ratios in a quantum dot compound) may be implemented, so that a light emitting device may emit light in various wavelengths. For example, a size of a quantum dot or an elemental ratio in a quantum dot compound may each independently be adjusted to emit red light, green light, and/or blue light. For example, quantum dots may be configured to emit white light by combining various colors of light.

In the light emitting element ED according to an embodiment as shown in each of FIGS. 3 to 6, the electron transport region ETR may be provided on the emission layer EML.

The electron transport region ETR may include at least one of a hole blocking layer HBL, an electron transport layer ETL, and an electron injection layer EIL, but embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In other embodiment, the electron transport region ETR may have a single layer structure formed different materials, or may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto. The electron transport region ETR may have a thickness in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-2:

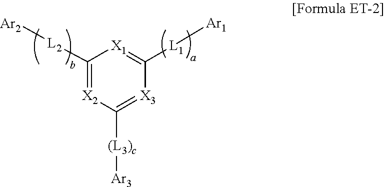

In Formula ET-2, at least one of X₁ to X₃ may each be N; and the remainder of X₁ to X₃ may each independently be C(Rₐ). In Formula ET-2, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound.

However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebg₂), 9,10-di(naphthalene-2-yl)anthracene (ADN), 1,3-bis[3,5-di(pyridin-3-yl)phenyl]benzene (BmPyPhB), or a mixture thereof.

In an embodiment, the electron transport region ETR may include at least one compound selected from Compound ET1 to Compound ET36:

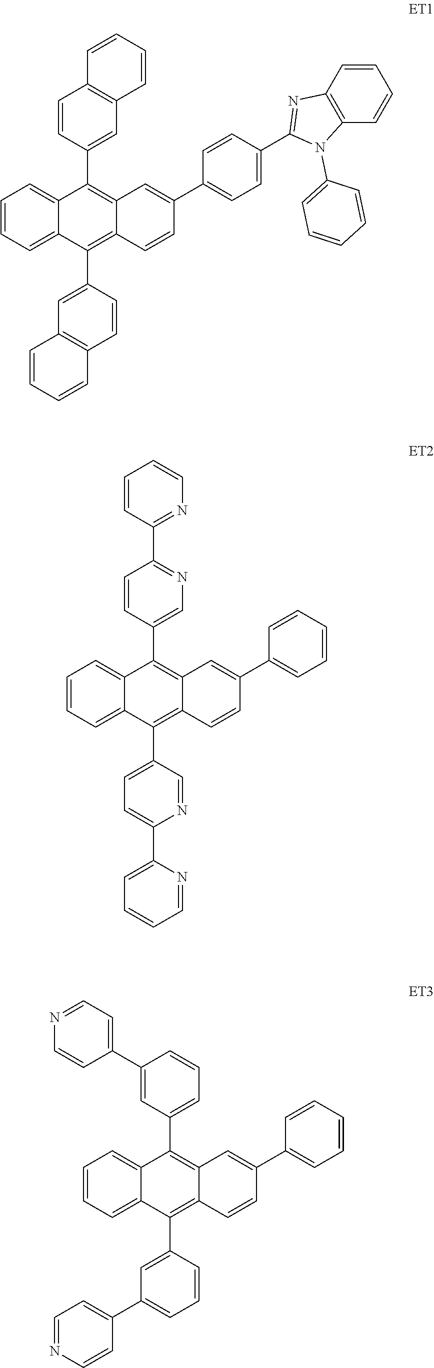 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

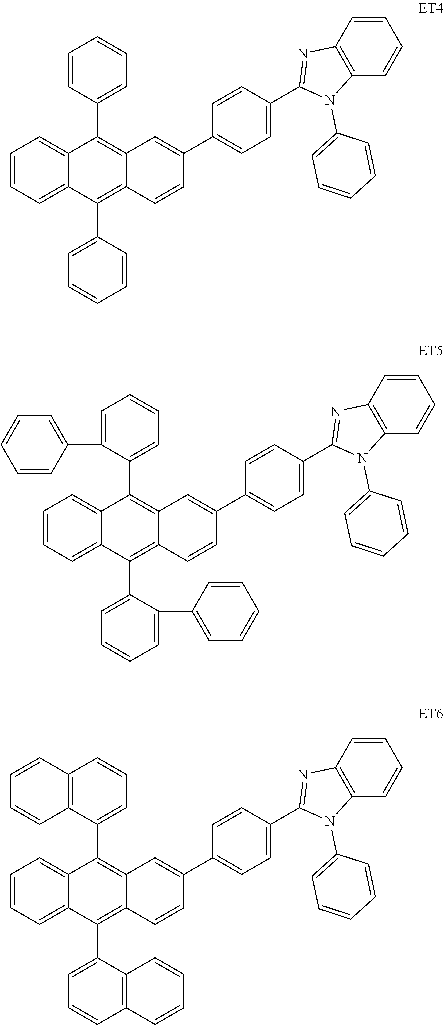 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

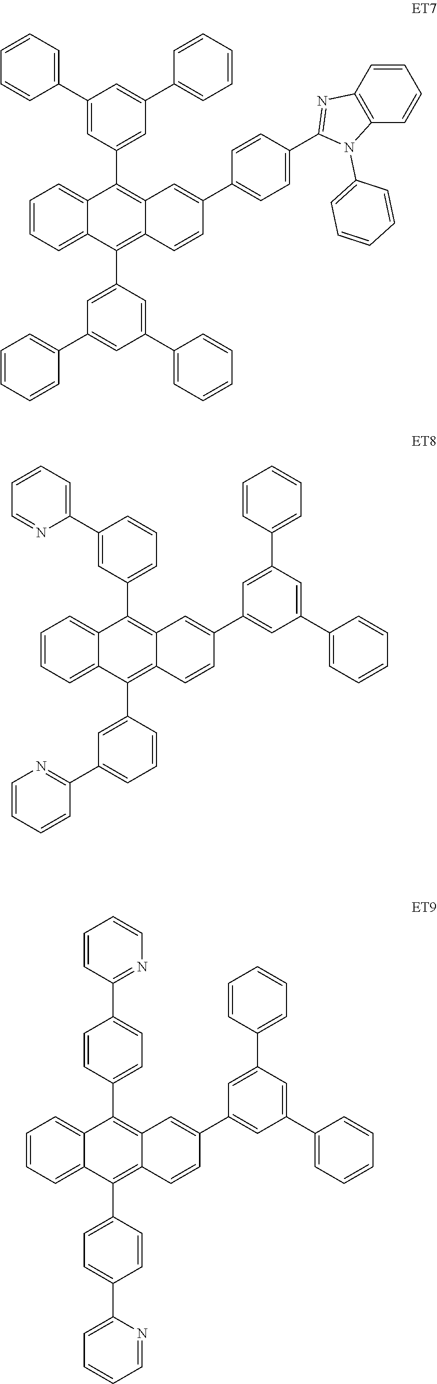 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

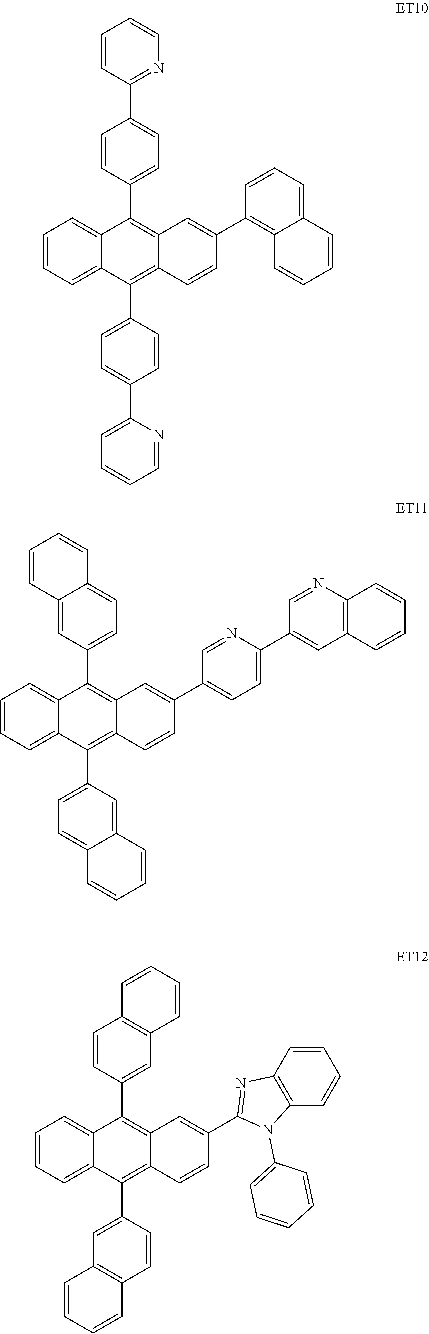 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

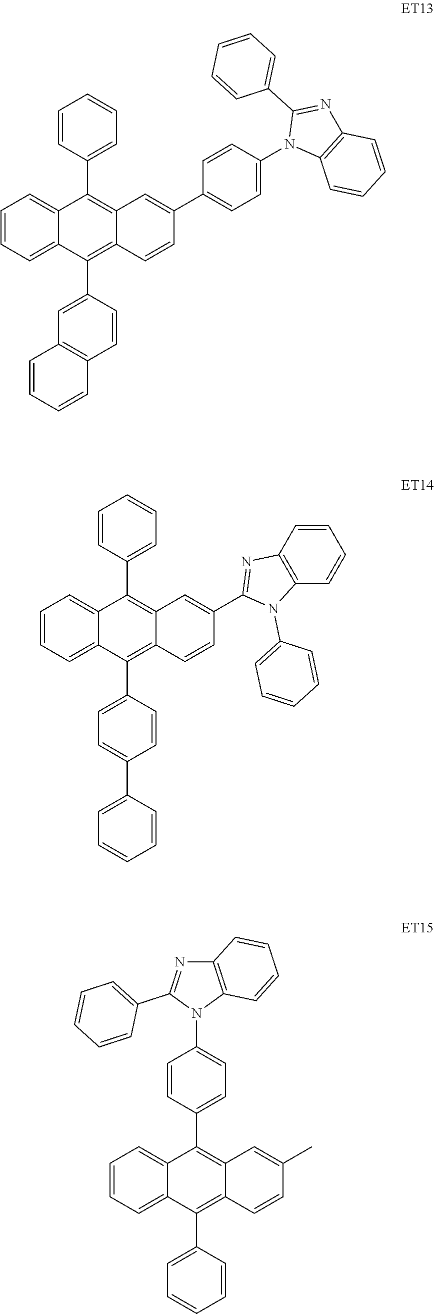 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

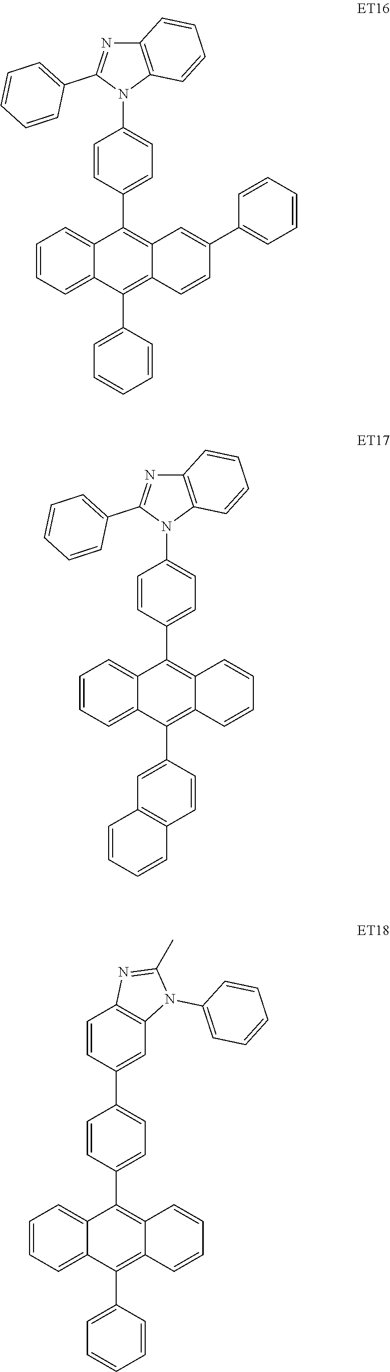 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

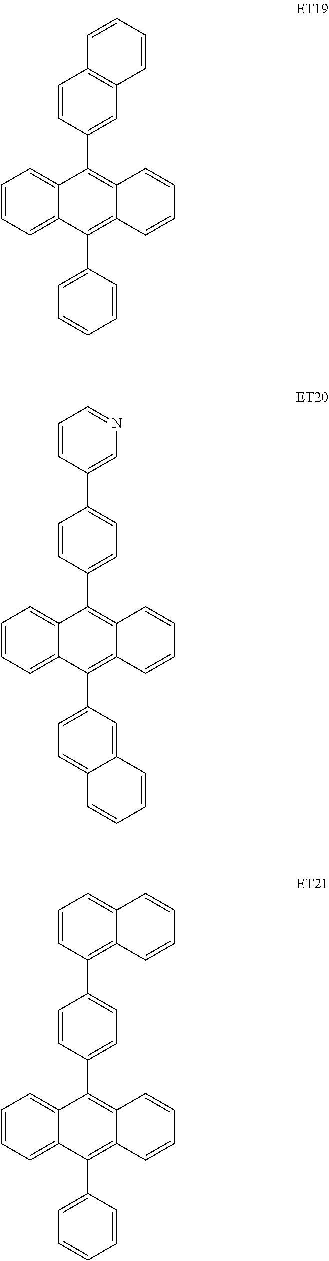

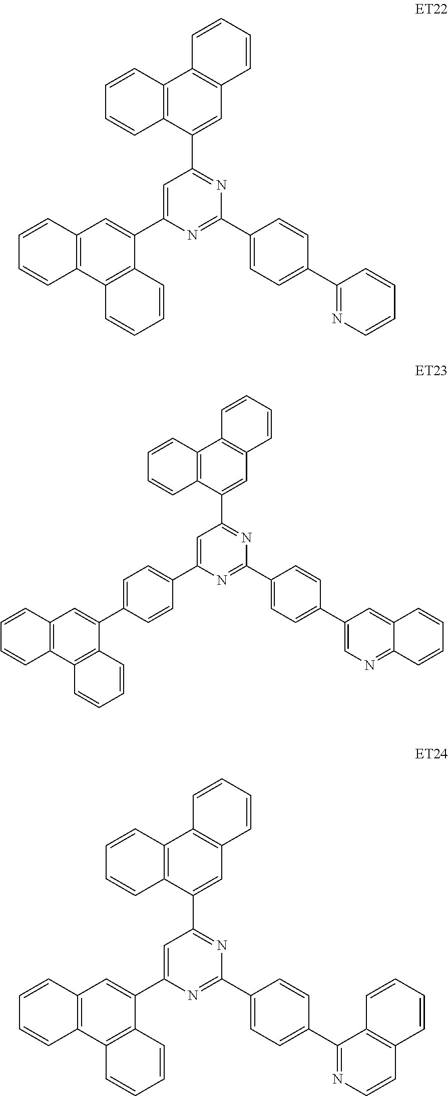 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

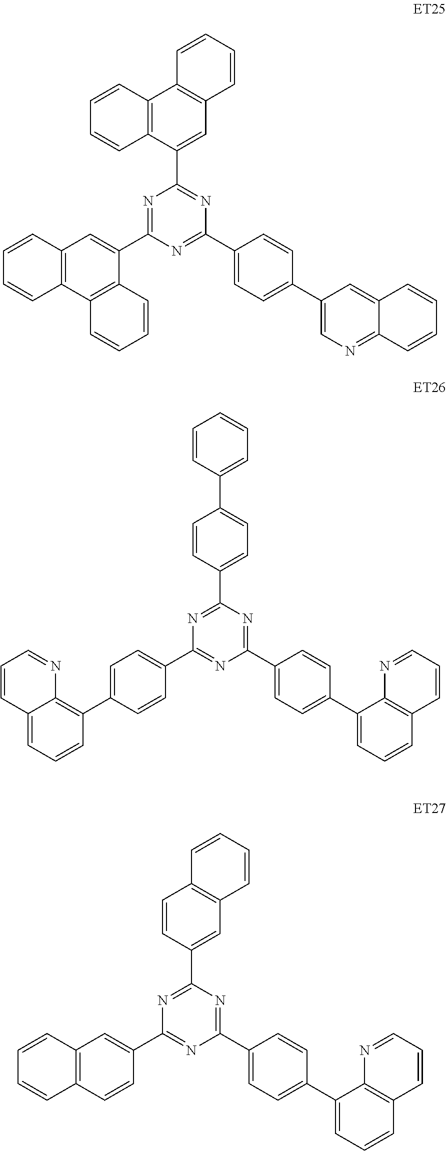 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

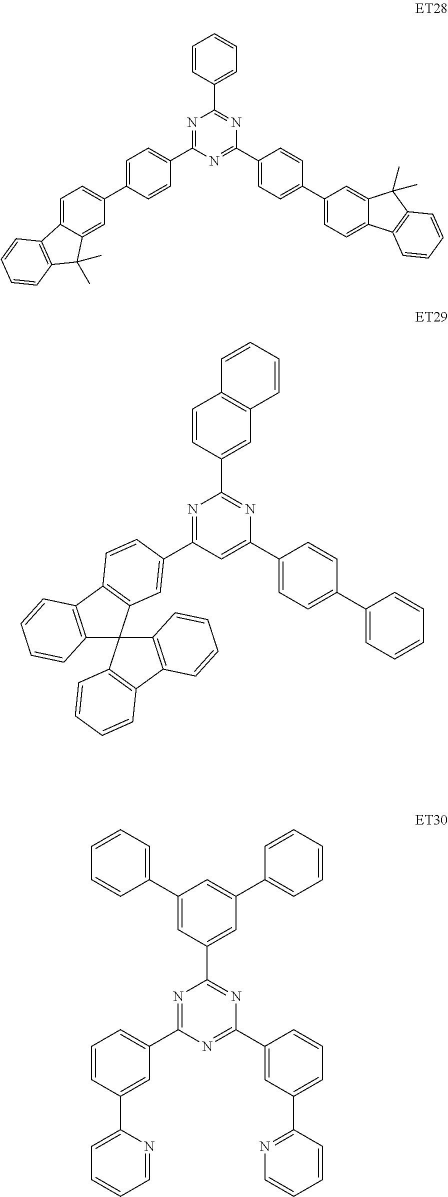 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

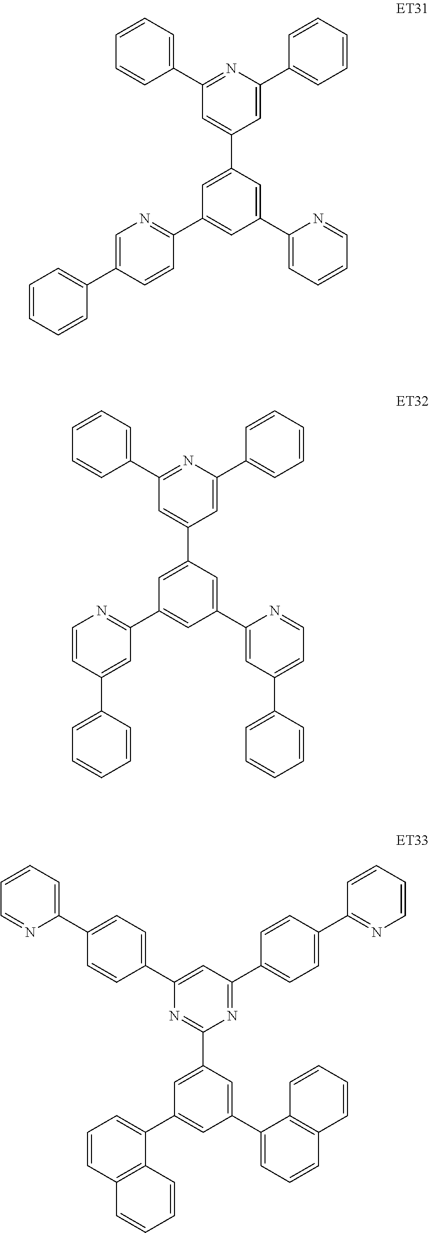 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

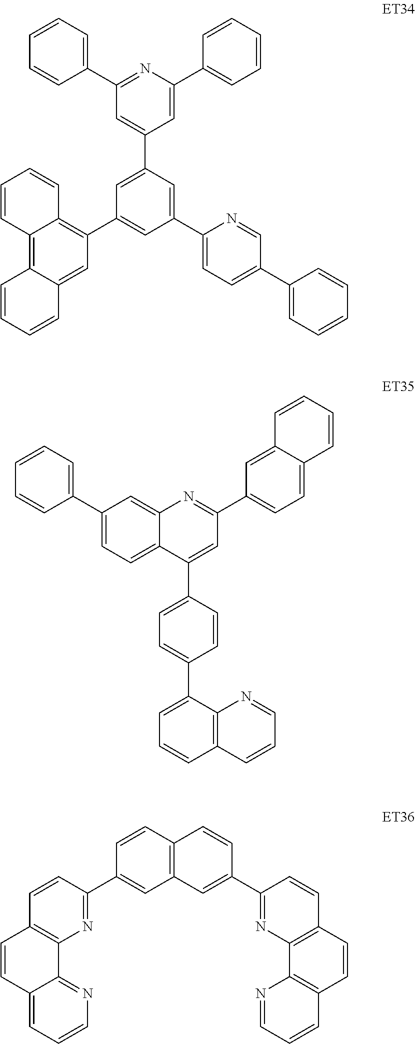 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include: a metal halide such as LiF, NaCl, CsF, RbCl, RbI, CuI, and KI; a lanthanide metal such as Yb; or a co-deposited material of a metal halide and a lanthanide metal. For example, the electron transport region ETR may include KI:Yb, RbI:Yb, LiF:Yb, etc., as a co-deposited material. The electron transport region ETR may be formed using a metal oxide such as Li₂O or BaO, or 8-hydroxyl-lithium quinolate (Liq), etc., but embodiments are not limited thereto. The electron transport region ETR may also be formed of a mixture material of an electron transport material and an insulating organometallic salt. The insulating organometallic salt may be a material having an energy band gap equal to or greater than about 4 eV. For example, the insulating organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen), in addition to the above-described materials, but embodiments are not limited thereto.

The electron transport region ETR may include the above-described compounds of the electron transport region in at least one of an electron injection layer EIL, an electron transport layer ETL, or a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In an embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL includes an inorganic material, the inorganic material may include an alkaline metal compound (e.g., LiF), an alkaline earth metal compound (e.g., MgF₂), SiON, SiNₓ, SiOy, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or may include an epoxy resin, or an acrylate such as methacrylate. However, embodiments are not limited thereto. In an embodiment, the capping layer CPL may include at least one of Compounds P1 to P5:

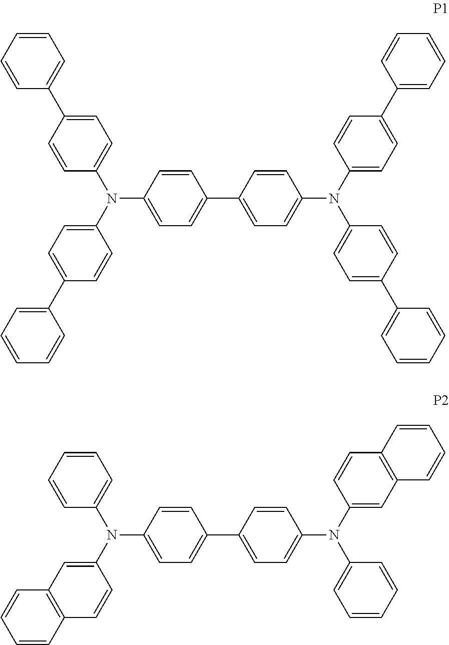 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

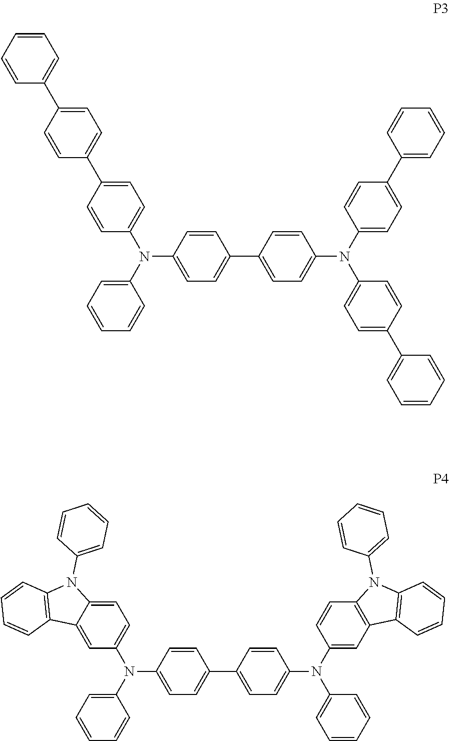 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

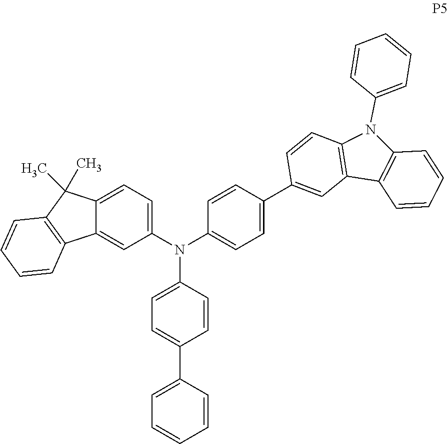 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6 with respect to light in a wavelength range of about 550 nm to about 660 nm.

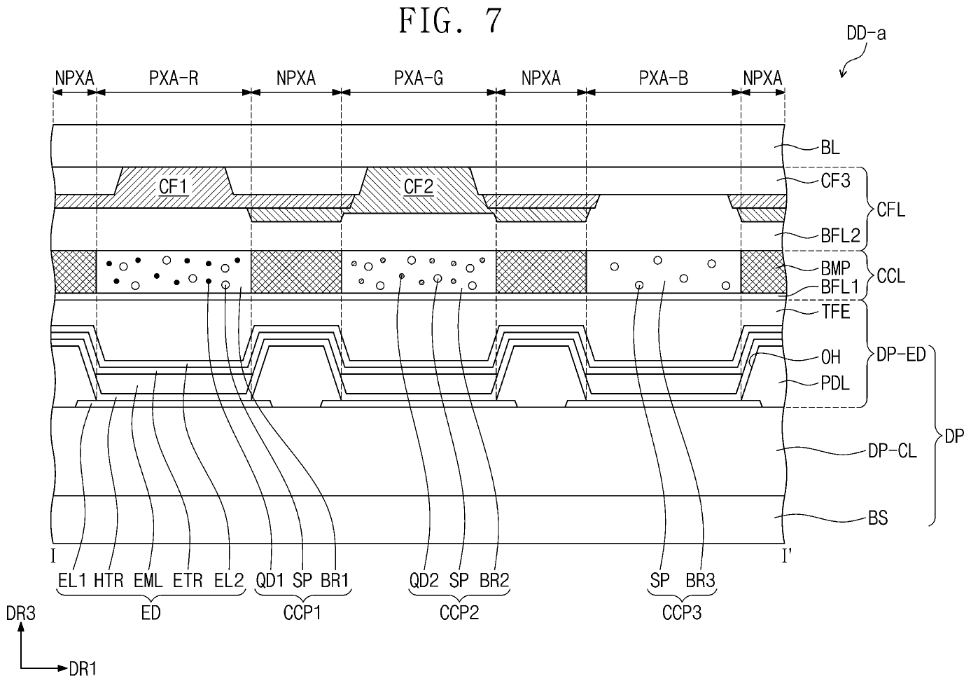

FIGS. 7 to 10 are each a schematic cross-sectional view of a display apparatus according to an embodiment. In the descriptions of the display apparatuses according to embodiments as shown in FIGS. 7 to 10, the features which have been described above with respect to FIGS. 1 to 6 will not explained again, and the differing features will be described.

Referring to FIG. 7, the display apparatus DD-a according to an embodiment may include a display panel DP including a display device layer DP-ED, a light control layer CCL disposed on the display panel DP, and a color filter layer CFL.

In an embodiment shown in FIG. 7, the display panel DP may include a base layer BS, a circuit layer DP-CL provided on the base layer BS, and the display device layer DP-ED, and the display device layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 7 may be the same as a structure of a light emitting element ED according to one of FIGS. 3 to 6 as described above.

The emission layer EML of the light emitting element ED included in the display apparatus DD-a according to an embodiment may include the fused polycyclic compound according to an embodiment as described above.

Referring to FIG. 7, the emission layer EML may be disposed in an opening OH defined in a pixel defining film PDL. For example, the emission layer EML, which is separated by the pixel defining film PDL and correspondingly provided to each of the light emitting regions PXA-R, PXA-G, and PXA-B, may emit light in a same wavelength range. In the display apparatus DD-a, the emission layer EML may emit blue light. Although not shown in the drawings, in an embodiment, the emission layer EML may be provided as a common layer for each of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and may emit the resulting light. For example, the light control layer CCL may a layer containing a quantum dot or a layer containing a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3, which are spaced apart from each other, but embodiments are not limited thereto. In FIG. 7, it is shown that the divided patterns BMP do not overlap the light control parts CCP1, CCP2, and CCP3, but the edges of the light control parts CCP1, CCP2, and CCP3 may overlap at least a portion of the divided patterns BMP.

The light control layer CCL may include a first light control part CCP1 including a first quantum dot QD1 that converts first color light provided from the light emitting element ED into second color light, a second light control part CCP2 including a second quantum dot QD2 that converts the first color light into third color light, and a third light control part CCP3 that transmits the first color light.

In an embodiment, the first light control part CCP1 may provide red light, which is the second color light, and the second light control part CCP2 may provide green light, which is the third color light. The third light control part CCP3 may provide blue light by transmitting the blue light which is the first color light provided from the light emitting element ED. For example, the first quantum dot QD1 may be a red quantum dot, and the second quantum dot QD2 may be a green quantum dot. The quantum dots QD1 and QD2 may each be a quantum dot as described above.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include a quantum dot but may include the scatterer SP.

The scatterer SP may be inorganic particles. For example, the scatterer SP may include at least one of TiO₂, ZnO, Al₂O₃, SiO₂, and hollow sphere silica. The scatterer SP may include one of TiO₂, ZnO, Al₂O₃, SiO₂, and hollow sphere silica, or may be a mixture of at least two materials selected from TiO₂, ZnO, Al₂O₃, SiO₂, and hollow sphere silica.

The first light control part CCP1, the second light control part CCP2, and the third light control part CCP3 may each include base resins BR1, BR2, and BR3, in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may block the light control parts CCP1, CCP2, and CCP3 from exposure to moisture/oxygen. The barrier layer BFL1 may cover the light control parts CCP1, CCP2, and CCP3. A barrier layer BFL2 may be provided between the light control parts CCP1, CCP2, and CCP3 and the color filter layer CFL.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may each independently further include an organic film. The barrier layers BFL1 and BFL2 may be formed of a single layer or of multiple layers.

In the display apparatus DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated but may be provided as one filter.

Although not shown in the drawings, the color filter layer CFL may further include a light shielding part (not shown). The light shielding part (not shown) may be a black matrix. The light shielding part (not shown) may include an organic light shielding material or an inorganic light shielding material, each including a black pigment or dye. The light shielding part (not shown) may prevent light leakage, and may separate boundaries between adjacent filters CF1, CF2, and CF3.

The first to third filters CF1, CF2, and CF3 may be disposed to respectively correspond to the red light emitting region PXA-R, the green light emitting region PXA-G, and the blue light emitting region PXA-B.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer.

Although not shown in the drawings, in an embodiment, the base substrate BL may be omitted.

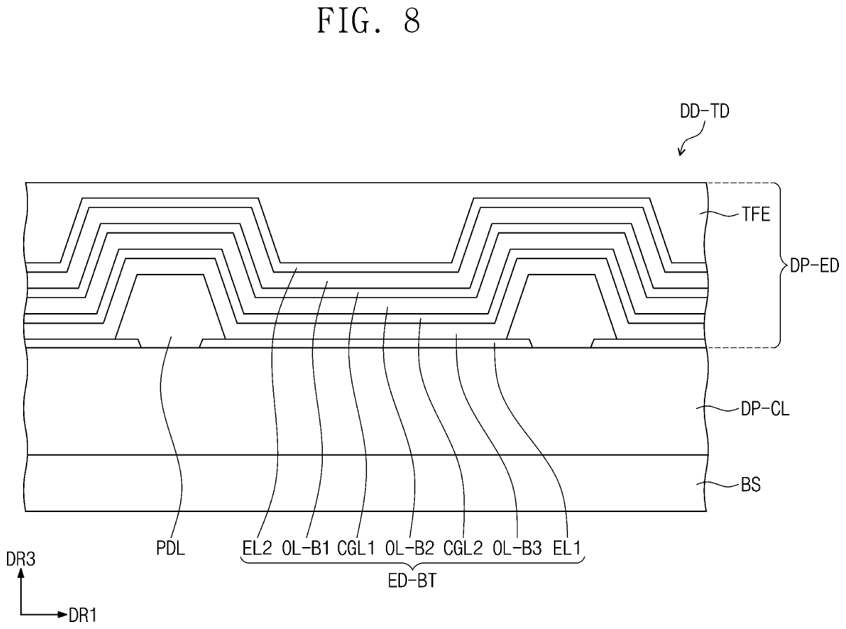

FIG. 8 is a schematic cross-sectional view of a portion of a display apparatus according to an embodiment. In the display apparatus DD-TD according to an embodiment, the light emitting element ED-BT may include light emitting structures OL-B1, OL-B2, and OL-B3. The light emitting element ED-BT may include a first electrode EL1 and a second electrode EL2 which face each other, and the light emitting structures OL-B1, OL-B2, and OL-B3 stacked in a thickness direction between the first electrode EL1 and the second electrode EL2. The light emitting structures OL-B1, OL-B2, and OL-B3 may each include an emission layer EML (FIG. 7), and a hole transport region HTR and an electron transport region ETR disposed with the emission layer EML (FIG. 7) located therebetween.

For example, the light emitting element ED-BT included in the display apparatus DD-TD may be a light emitting element having a tandem structure and including multiple emission layers.

In an embodiment illustrated in FIG. 8, light emitted from each of the light emitting structures OL-B1, OL-B2, and OL-B3 may be blue light. However, embodiments are not limited thereto, and the light emitted from each of the light emitting structures OL-B1, OL-B2, and OL-B3 may have wavelength ranges that are different from each other. For example, the light emitting element ED-BT that includes the light emitting structures OL-B1, OL-B2, and OL-B3, which emit light having wavelength ranges that are different from each other, may emit white light.

Charge generation layers CGL1 and CGL2 may each be disposed between adjacent light emitting structures among the light emitting structures OL-B1, OL-B2, and OL-B3. Charge generation layers CGL1 and CGL2 may each independently include a p-type charge generation layer and/or an n-type charge generation layer.

In an embodiment, at least one of the light emitting structures OL-B1, OL-B2, and OL-B3 included in the display apparatus DD-TD may include the fused polycyclic compound of an embodiment as described herein. For example, at least one of the emission layers included in the light emitting element ED-BT may include the fused polycyclic compound.

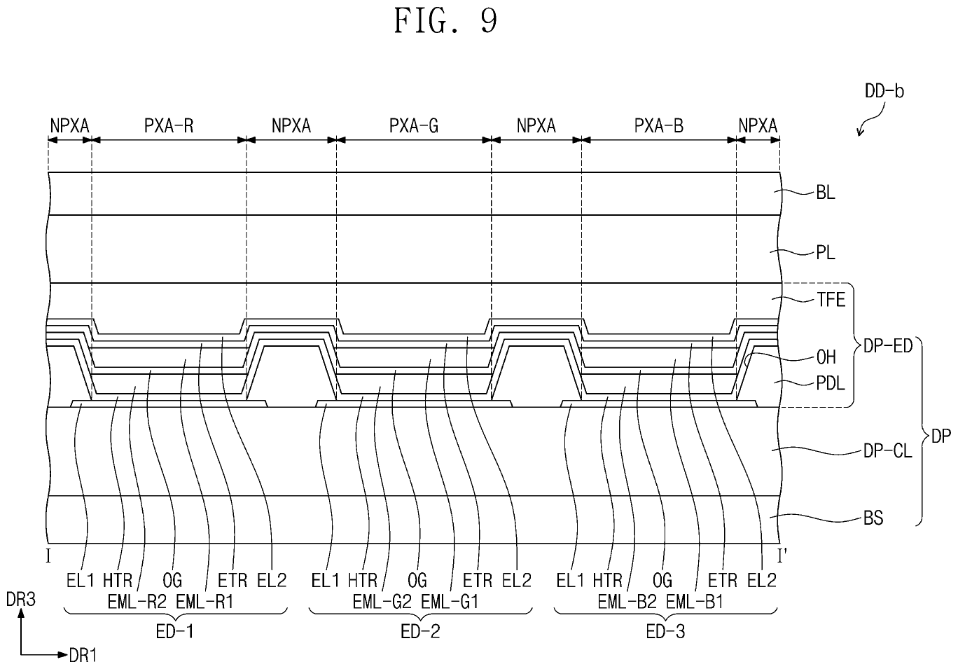

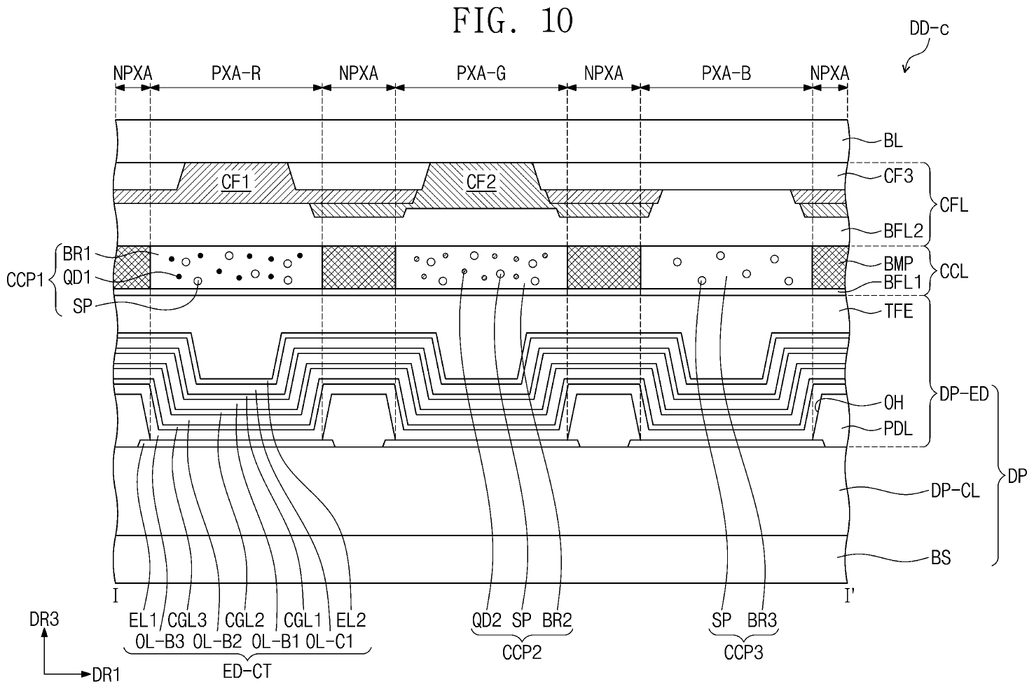

Referring to FIG. 9, the display apparatus DD-b according to an embodiment may include light emitting elements ED-1, ED-2, and ED-3 in which two emission layers are stacked.

In comparison to the display apparatus DD shown in FIG. 2, the embodiment shown in FIG. 9 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer for all of the first to third light emitting elements ED-1, ED-2, and ED-3.

However, embodiments are not limited thereto, and the emission auxiliary part OG may be provided by being patterned in the openings OH defined in the pixel defining film PDL.

The first red emission layer EML-R1, the first green emission layer EML-G1, and the first blue emission layer EML-B1 may each be disposed between the emission auxiliary part OG and the electron transport region ETR. The second red emission layer EML-R2, the second green emission layer EML-G2, and the second blue emission layer EML-B2 may each be disposed between the hole transport region HTR and the emission auxiliary part OG.

For example, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2, which are stacked in that order. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2, which are stacked in that order. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2, which are stacked in that order.

An optical auxiliary layer PL may be disposed on the display device layer DP-ED. The optical auxiliary layer PL may include a polarizing layer. The optical auxiliary layer PL may be disposed on the display panel DP and may control light that is reflected at the display panel DP from an external light. Although not shown in the drawings, in an embodiment, the optical auxiliary layer PL may be omitted from the display apparatus DD-b.

At least one emission layer included in the display apparatus DD-b shown in FIG. 9 may include the fused polycyclic compound according to an embodiment. For example, in an embodiment, at least one of the first blue emission layer EML-B1 and the second blue emission layer EML-B2 may include the fused polycyclic compound.

In contrast to FIGS. 8 and 9, FIG. 10 shows a display apparatus DD-c that is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may each be disposed between adjacent light emitting structures among the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelength regions from each other.

The charge generation layers CGL1, CGL2, and CGL3 which are disposed between adjacent light emitting structures among the first to fourth light emitting structures OL-B1, OL-B2, OL-B3, and OL-C1 may each independently include a p-type charge generation layer and/or an n-type charge generation layer.

In the display apparatus DD-c, at least one of the light emitting structures OL-B1, OL-B2, OL-B3, and OL-C1 may each independently include the fused polycyclic compound according to an embodiment. For example, in an embodiment, at least one of the first to third light emitting structures OL-B1, OL-B2, and OL-B3 may each include the fused polycyclic compound.

The light emitting element ED according to an embodiment may include the fused polycyclic compound represented by Formula 1 in at least one functional layer disposed between the first electrode EL1 and the second electrode EL2, thereby exhibiting excellent luminous efficiency and improved service life characteristics. For example, the emission layer EML of the light emitting element ED may include the fused polycyclic compound, and the light emitting element ED may exhibit long service life characteristics.

In an embodiment, an electronic apparatus may include a display apparatus including multiple light emitting elements, and a control part which controls the display apparatus. The electronic apparatus may be a device that is activated according to an electrical signal. The electronic apparatus may include display apparatuses according to various embodiments. For example, the electronic apparatus may be not only large-sized electronic apparatuses, such as a vehicle, a television, a monitor, or a billboard, but the electronic apparatus may also be a small-sized or a medium-sized electronic apparatus, such as a personal computer, a laptop computer, a personal digital terminal, a display apparatus for a vehicle, a game console, a portable electronic device, or a camera.

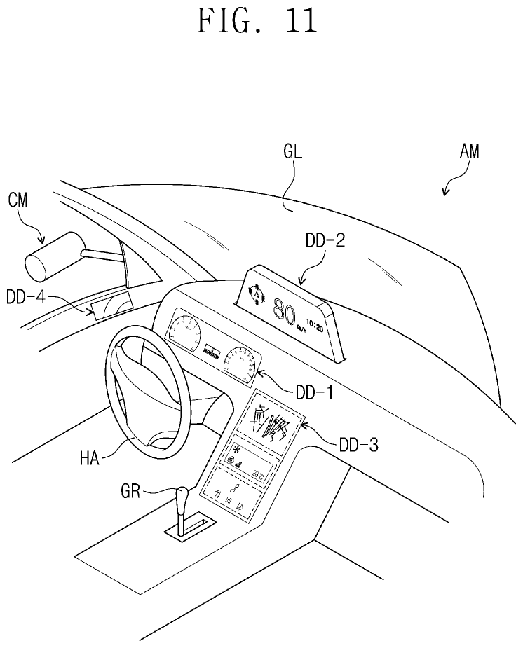

FIG. 11 is a schematic perspective view of a vehicle AM in which first to fourth display apparatuses DD-1, DD-2, DD-3, and DD-4 are disposed. At least one of the first to fourth display apparatuses DD-1, DD-2, DD-3, and DD-4 may have a structure according to one of display apparatuses DD, DD-TD, DD-a, DD-b, and DD-c as, described with reference to FIGS. 1, 2, and 7 to 10.

FIG. 11 illustrates a vehicle AM, but this is only an example, and the first to fourth display apparatuses DD-1, DD-2, DD-3, and DD-4 may be disposed in various transportation means such as bicycles, motorcycles, trains, ships, and airplanes. In an embodiment, at least one of the first to fourth display apparatuses DD-1, DD-2, DD-3, and DD-4 having a structure according to one of display apparatuses DD, DD-TD, DD-a, DD-b, and DD-c may be employed in a personal computer, a laptop computer, a personal digital terminal, a game console, a portable electronic device, a television, a monitor, an outdoor billboard, or the like. However, these are merely presented as examples, and thus may be employed in other electronic apparatuses.

At least one of the first to fourth display apparatus DD-1, DD-2, DD-3, and DD-4 may each independently include a light emitting element ED according to an embodiment as described in reference to FIGS. 3 to 6. The light emitting element ED may include a fused polycyclic compound according to an embodiment. At least one of the first to fourth display apparatus DD-1, DD-2, DD-3, and DD-4 may include a light emitting element ED including a fused polycyclic compound according to an embodiment, thereby improving a display service life.

Referring to FIG. 11, the vehicle AM may include a steering wheel HA and a gearshift GR for driving the vehicle AM. The vehicle AM may include a front window GL that is disposed so as to face the driver.

The first display apparatus DD-1 may be disposed in a first region that overlaps the steering wheel HA. For example, the first display apparatus DD-1 may be a digital cluster which displays first information of the vehicle AM. The first information may include a first scale which indicates a driving speed of the vehicle AM, a second scale which indicates an engine speed (for example, as revolutions per minute (RPM)), a fuel gauge, etc. The first scale and the second scale may each be displayed as a digital image.

The second display apparatus DD-2 may be disposed in a second region facing the driver's seat and overlapping the front window GL. The driver's seat may be a seat where the steering wheel HA is disposed. For example, the second display apparatus DD-2 may be a head up display (HUD) which displays second information of the vehicle AM. The second display apparatus DD-2 may be optically transparent. The second information may include digital numbers which indicate a driving speed, and may further include information such as the current time. Although not shown in the drawings, in an embodiment, the second information of the second display apparatus DD-2 may be projected to the front window GL to be displayed.

The third display apparatus DD-3 may be disposed in a third region adjacent to the gearshift GR. For example, the third display apparatus DD-3 may be a center information display (CID) for a vehicle that displays third information, and the third display apparatus DD-3 may be disposed between the driver's seat and the passenger seat and. The passenger seat may be a seat that is spaced apart from the driver's seat with the gearshift GR disposed therebetween. The third information may include information about traffic (e.g., navigation information), playing music or radio or a video (or an image), temperatures inside the vehicle AM, etc.

The fourth display apparatus DD-4 may be spaced apart from the steering wheel HA and the gearshift GR, and may be disposed in a fourth region adjacent to a side of the vehicle AM. For example, the fourth display apparatus DD-4 may be a digital side-view mirror which displays fourth information. The fourth display apparatus DD-4 may display an image outside the vehicle AM taken by a camera module CM disposed outside the vehicle AM. The fourth information may include an image outside the vehicle AM.

The first to fourth information as described above are only presented as examples, and the first to fourth display apparatuses DD-1, DD-2, DD-3, and DD-4 may further display information about the interior and exterior of the vehicle AM. The first to fourth information may include information that is different from each other. However, embodiments are not limited thereto, and a part of the first to fourth information may include the same information as one another.

Hereinafter, a fused polycyclic according to an embodiment and a light emitting element according to an embodiment will be described in detail with reference to the Examples and the Comparative Examples. The Examples described below are only provided as illustrations to assist in understanding the disclosure, and the scope thereof is not limited thereto.

### EXAMPLES

### 1. Synthesis of Fused Polycyclic Compound

A synthesis method of the fused polycyclic compound according to an embodiment will be described by illustrating the synthesis methods of Compounds 4, 11, 20, 54, 60, 73, and 97. The synthesis methods of the fused polycyclic compounds as described below are provided only as examples, and synthesis methods of the fused polycyclic compound according to embodiments is not limited to the following examples.

### (1) Synthesis of Compound 4

### (Synthesis of Intermediate 4-1)

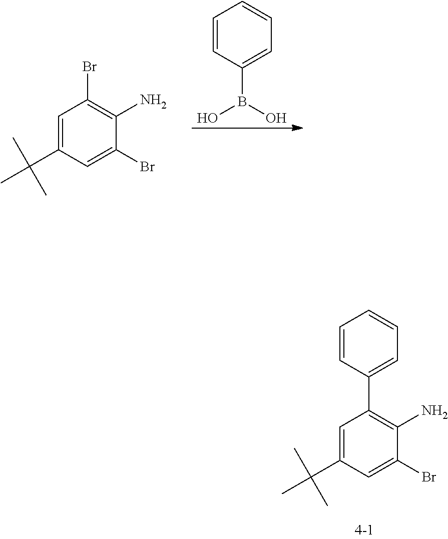 [SMILES: CC(C)(C)c1cc(Br)c(N)c(Br)c1 ; OB(O)c1ccccc1 ; CC(C)(C)c1cc(Br)c(N)c(-c2ccccc2)c1]

2,6-dibromo-4-(tert-butyl)aniline (1 eq), phenylboronic acid (0.7 eq), Pd(PPh₃)₄ (0.05 eq), and K₂CO₃ (3 eq) were dissolved in a mixed solution of water and THF (2:1), and the resultant mixture was stirred at about 80° C. for about 6 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using n-hexane to obtain Intermediate 4-1. (yield: 45%)

### (Synthesis of Intermediate 4-2)

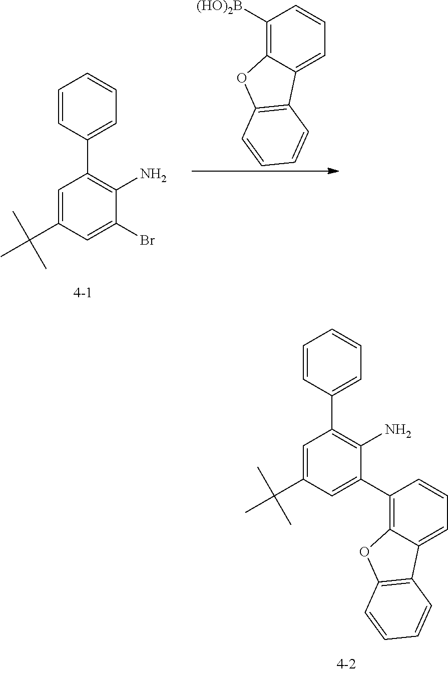 [SMILES: CC(C)(C)c1cc(Br)c(N)c(-c2ccccc2)c1 ; OB(O)c1cccc2c1oc1ccccc12 ; CC(C)(C)c1cc(-c2ccccc2)c(N)c(-c2cccc3c2oc2ccccc23)c1]

Intermediate 4-1 (1 eq), dibenzo[b,d]furan-4-ylboronic acid (1.5 eq), Pd(PPh₃)₄ (0.05 eq), and K₂CO₃ (3 eq) were dissolved in a mixed solution of water and THF (2:1), and the resultant mixture was stirred at about 90° C. for about 24 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 4-2. (yield: 75%)

### (Synthesis of Intermediate 4-3)

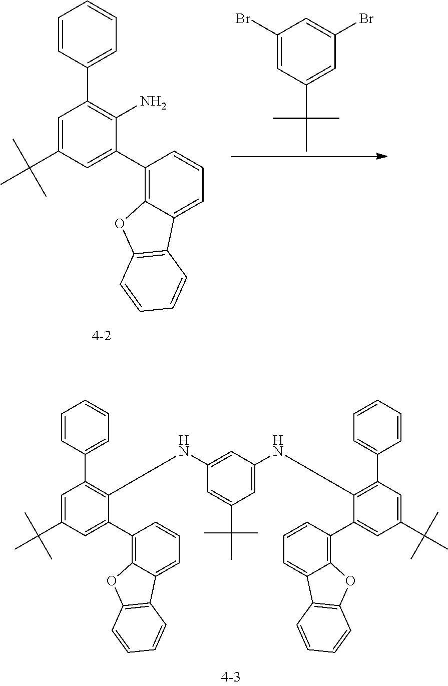 [SMILES: CC(C)(C)c1cc(-c2ccccc2)c(N)c(-c2cccc3c2oc2ccccc23)c1 ; CC(C)(C)c1cc(Br)cc(Br)c1 ; CC(C)(C)c1cc(Nc2c(-c3ccccc3)cc(C(C)(C)C)cc2-c2cccc3c2oc2ccccc23)cc(Nc2c(-c3ccccc3)cc(C(C)(C)C)cc2-c2cccc3c2oc2ccccc23)c1]

1,3-dibromo-5-(tert-butyl)benzene (1 eq), Intermediate 4-2 (2 eq), tris(dibenzylideneacetone)dipalladium(0) (0.05 eq), tri-tert-butylphosphine (0.1 eq), and sodium tert-butoxide (3 eq) were dissolved in o-xylene, and the resultant mixture was stirred at about 140° C. for about 12 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 4-3. (yield: 61%)

### (Synthesis of Intermediate 4-4)

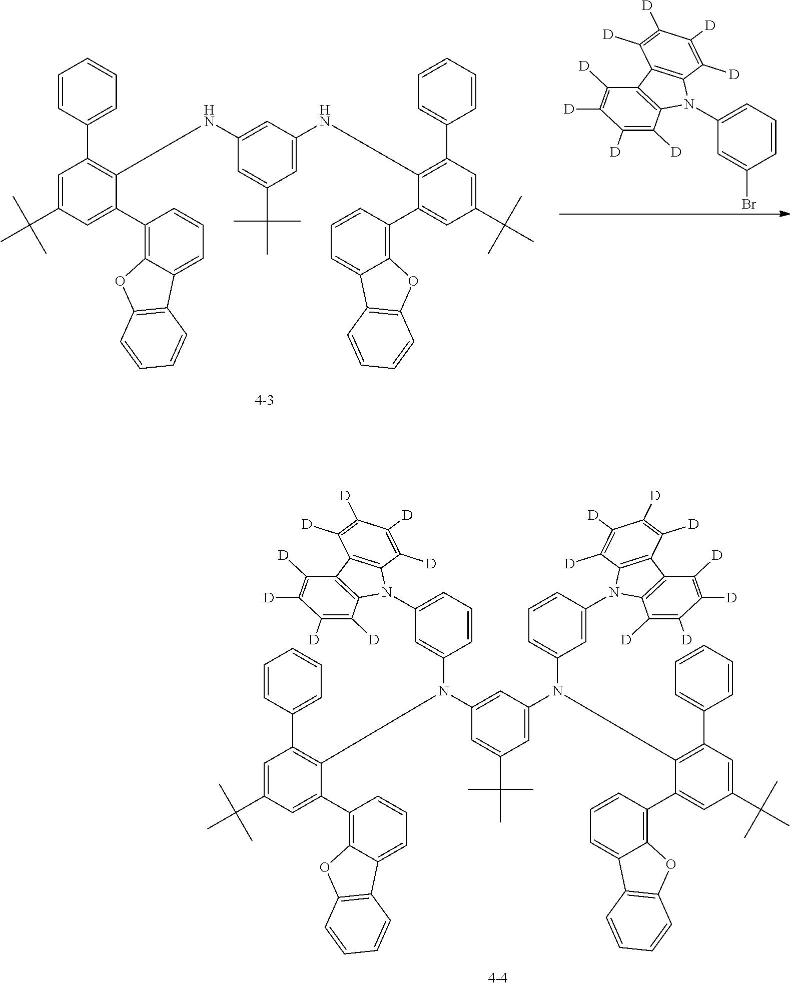

Intermediate 4-3 (1 eq), 9-(3-bromophenyl)-9H-carbazole-1,2,3,4,5,6,7,8-d8 (2.5 eq), tris(dibenzylideneacetone)dipalladium(0) (0.25 eq), tri-tert-butylphosphine (0.4 eq), and sodium tert-butoxide (5 eq) were dissolved in o-xylene, and the resultant mixture was stirred at about 160° C. for about 72 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 4-4. (yield: 38%)

### (Synthesis of Compound 4)

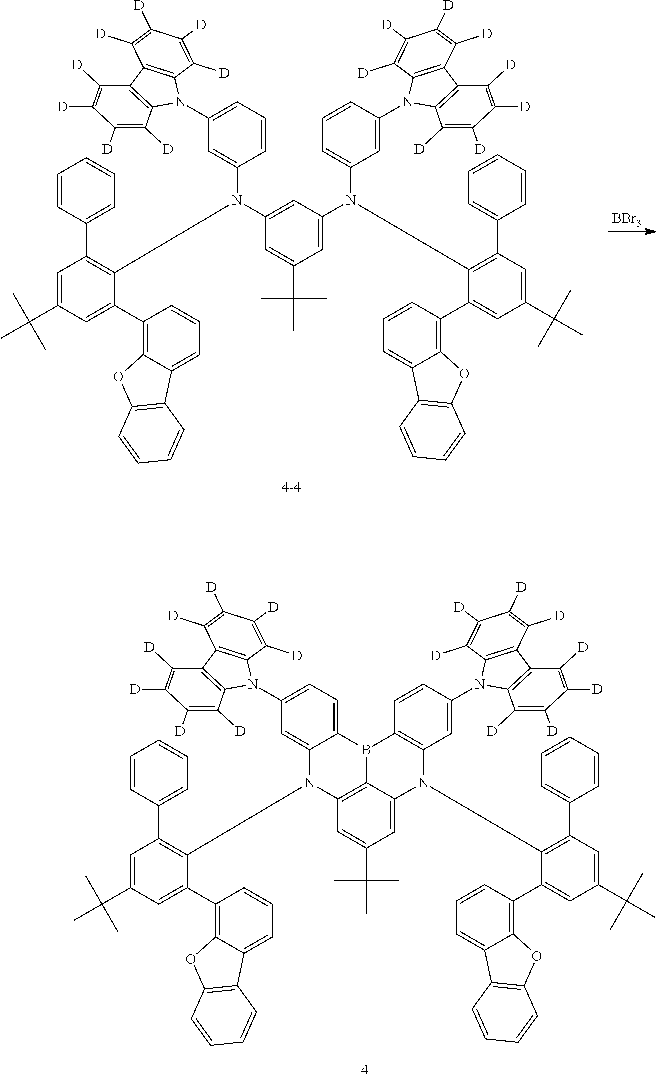

Intermediate 4-4 (1 eq) was dissolved in ortho dichlorobenzene, the mixture was cooled to about 0° C., and BBr₃ (3 eq) was slowly injected thereto in a nitrogen atmosphere. After dropping was completed, the temperature was elevated to about 180° C., and the mixture was stirred for about 48 hours. After cooling, the reaction was terminated by slowly dropping triethylamine in the flask containing the reactant, and ethyl alcohol was added to the reactant, followed by extraction and filtration to obtain solids. The obtained solids were purified by column chromatography using MC and n-hexane, and were subjected to recrystallization using toluene and acetone to obtain Compound 4. (yield: 3%)

### (2) Synthesis of Compound 11

### (Synthesis of Intermediate 11-1)

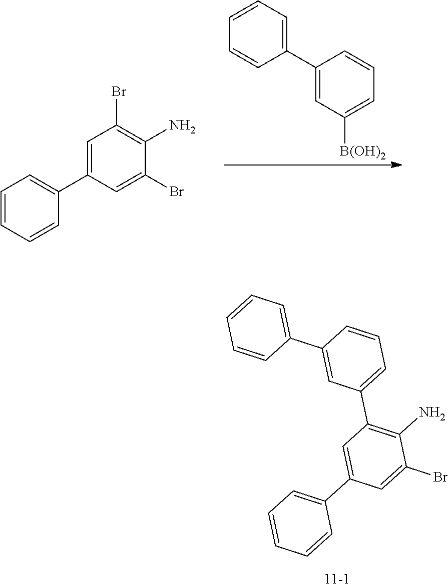 [SMILES: Nc1c(Br)cc(-c2ccccc2)cc1Br ; OB(O)c1cccc(-c2ccccc2)c1 ; Nc1c(Br)cc(-c2ccccc2)cc1-c1cccc(-c2ccccc2)c1]

3,5-dibromo-[1,1′-biphenyl]-4-amine (1 eq), [1,1′-biphenyl]-3-ylboronic acid (1 eq), Pd(PPh₃)₄ (0.05 eq), and K₂CO₃ (3 eq) were dissolved in a mixed solution of water and THF (2:1), and the resultant mixture was stirred at about 80° C. for about 12 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 11-1. (yield: 57%)

### (Synthesis of Intermediate 11-2)

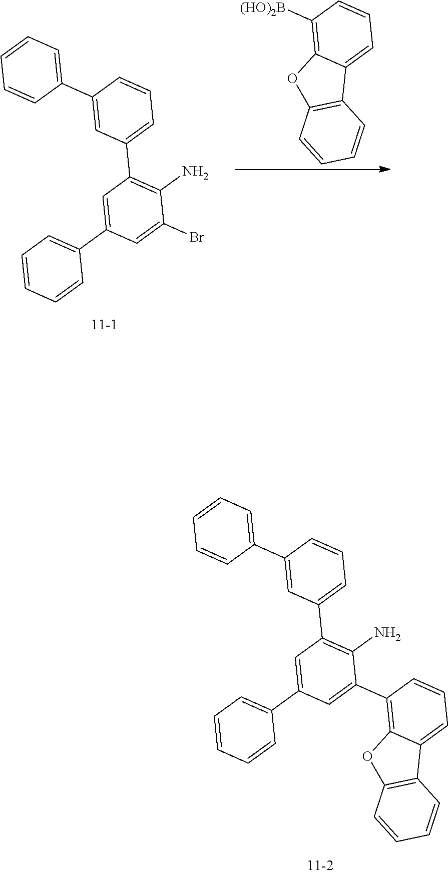 [SMILES: Nc1c(Br)cc(-c2ccccc2)cc1-c1cccc(-c2ccccc2)c1 ; OB(O)c1cccc2c1oc1ccccc12 ; Nc1c(-c2cccc(-c3ccccc3)c2)cc(-c2ccccc2)cc1-c1cccc2c1oc1ccccc12]

Intermediate 1-1 (1 eq), dibenzo[b,d]furan-4-ylboronic acid (1.2 eq), Pd(PPh₃)₄ (0.05 eq), and K₂CO₃ (3 eq) were dissolved in a mixed solution of water and THF (2:1), and the resultant mixture was stirred at about 80° C. for about 12 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 11-2. (yield: 79%)

### (Synthesis of Intermediate 11-3)

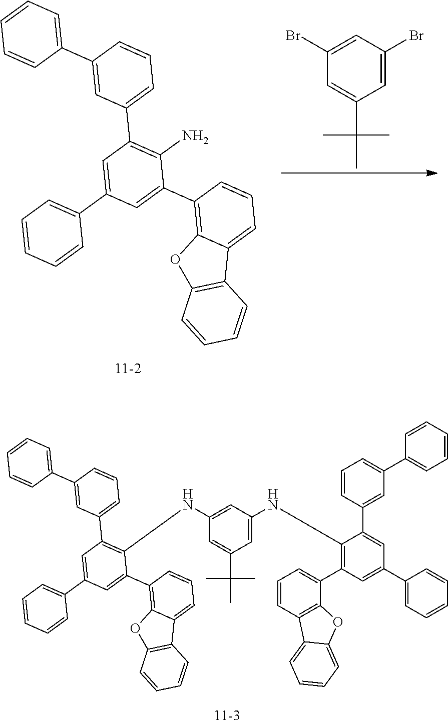 [SMILES: Nc1c(-c2cccc(-c3ccccc3)c2)cc(-c2ccccc2)cc1-c1cccc2c1oc1ccccc12 ; CC(C)(C)c1cc(Br)cc(Br)c1 ; CC(C)(C)c1cc(Nc2c(-c3cccc(-c4ccccc4)c3)cc(-c3ccccc3)cc2-c2cccc3c2oc2ccccc23)cc(Nc2c(-c3cccc(-c4ccccc4)c3)cc(-c3ccccc3)cc2-c2cccc3c2oc2ccccc23)c1]

1,3-dibromo-5-(tert-butyl)benzene (1 eq), Intermediate 11-2 (2 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 12 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 11-3. (yield: 73%)

### (Synthesis of Intermediate 11-4)

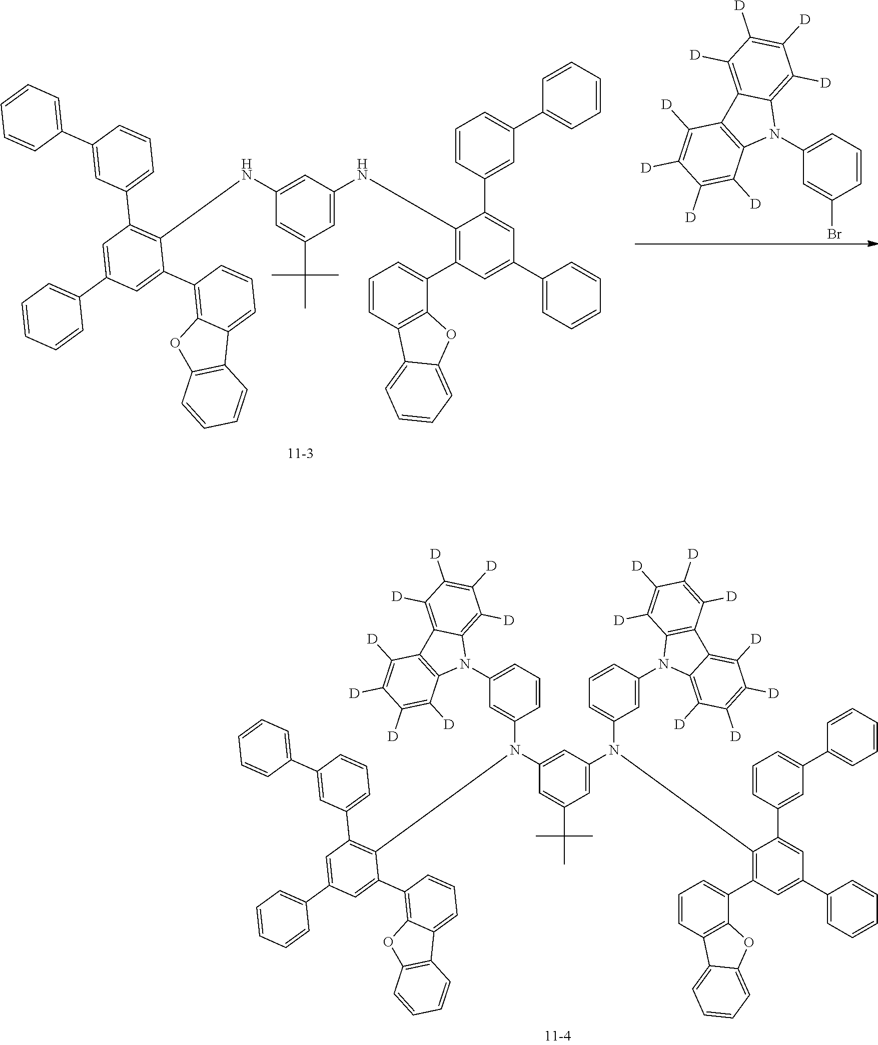

Intermediate 11-3 (1 eq), 9-(3-bromophenyl)-9H-carbazole-D8 (4 eq), tris(dibenzylideneacetone)dipalladium(0) (0.2 eq), tri-tert-butylphosphine (0.4 eq), and sodium tert-butoxide (3 eq) were dissolved in o-xylene, and the resultant mixture was stirred at about 150° C. for about 48 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 11-4. (yield: 41%)

### (Synthesis of Compound 11)

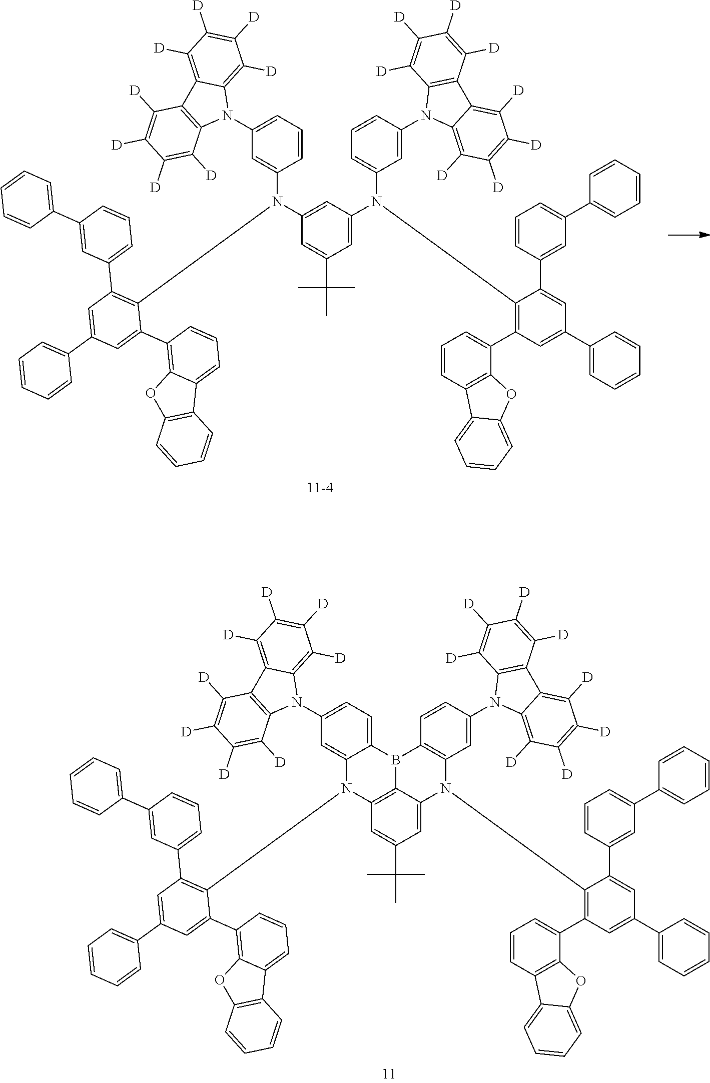

Intermediate 11-4 (1 eq) was dissolved in ortho dichlorobenzene, the mixture was cooled to about 0° C., and BBr₃ (5 eq) was slowly injected thereto in a nitrogen atmosphere. After dropping was completed, the temperature was elevated to about 180° C., and the mixture was stirred for about 24 hours. After cooling, the reaction was terminated by slowly dropping triethylamine in the flask containing the reactant, and ethyl alcohol was added to the reactant, followed by extraction and filtration to obtain solids. The obtained solids were purified by column chromatography using MC and n-hexane, and were subjected to recrystallization using toluene and acetone to obtain Compound 11. (yield: 3%)

### (3) Synthesis of Compound 20

### (Synthesis of Intermediate 20-1)

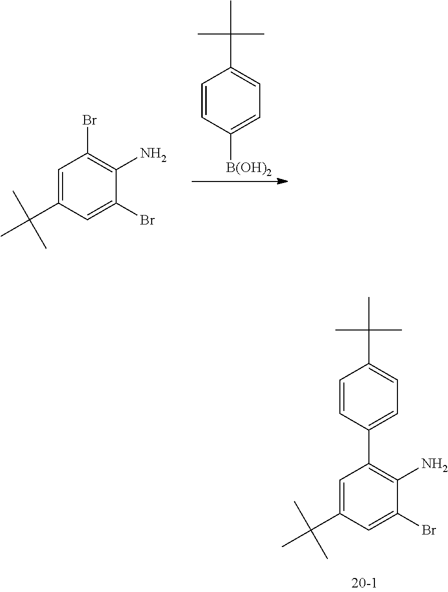 [SMILES: CC(C)(C)c1cc(Br)c(N)c(Br)c1 ; CC(C)(C)c1ccc(B(O)O)cc1 ; CC(C)(C)c1ccc(-c2cc(C(C)(C)C)cc(Br)c2N)cc1]

2,6-dibromo-4-(tert-butyl)aniline (1 eq), (4-(tert-butyl)phenyl)boronic acid (1 eq), Pd(PPh₃)₄ (0.05 eq), and K₂CO₃ (3 eq) were dissolved in a mixed solution of water and THF (2:1), and the resultant mixture was stirred at about 80° C. for about 12 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 20-1. (yield: 42%)

### (Synthesis of Intermediate 20-2)

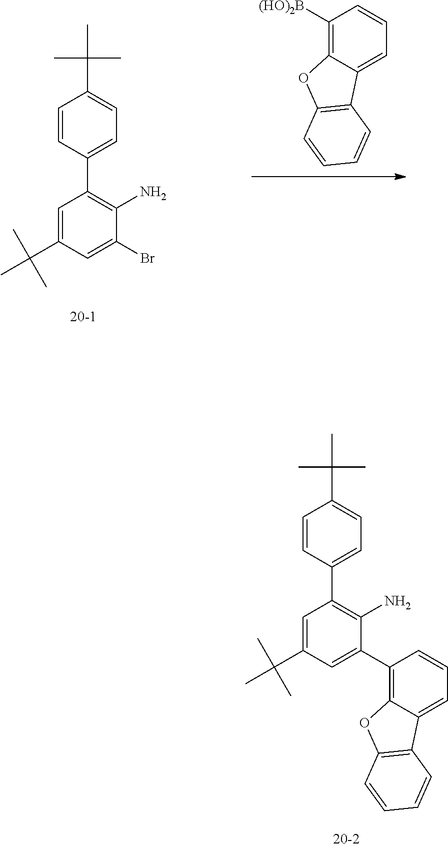 [SMILES: CC(C)(C)c1ccc(-c2cc(C(C)(C)C)cc(Br)c2N)cc1 ; OB(O)c1cccc2c1oc1ccccc12 ; CC(C)(C)c1ccc(-c2cc(C(C)(C)C)cc(-c3cccc4c3oc3ccccc34)c2N)cc1]

Intermediate 20-1 (1 eq), dibenzo[b,d]furan-4-ylboronic acid (1.2 eq), Pd(PPh₃)₄ (0.05 eq), and K₂CO₃ (3 eq) were dissolved in a mixed solution of water and THF (2:1), and the resultant mixture was stirred at about 80° C. for about 12 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 20-2. (yield: 68%)

### (Synthesis of Intermediate 20-3)

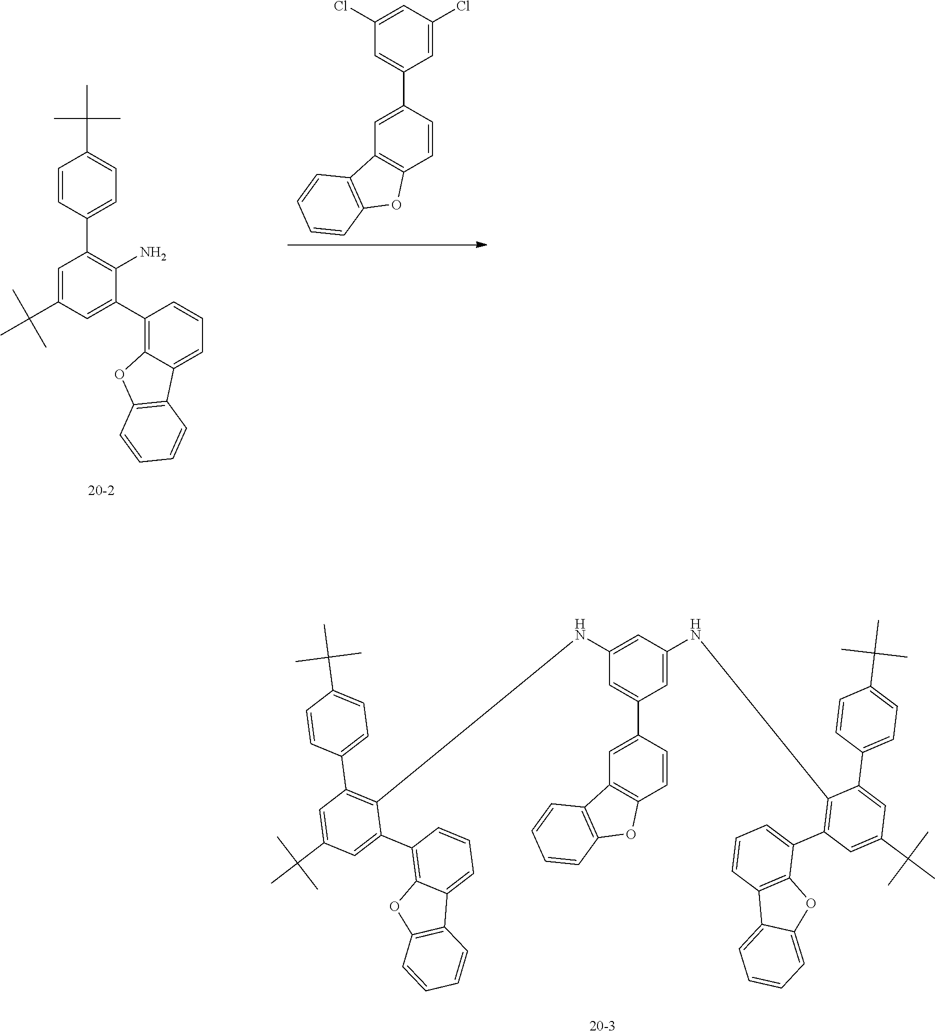 [SMILES: CC(C)(C)c1ccc(-c2cc(C(C)(C)C)cc(-c3cccc4c3oc3ccccc34)c2N)cc1 ; Clc1cc(Cl)cc(-c2ccc3oc4ccccc4c3c2)c1 ; CC(C)(C)c1ccc(-c2cc(C(C)(C)C)cc(-c3cccc4c3oc3ccccc34)c2Nc2cc(Nc3c(-c4ccc(C(C)(C)C)cc4)cc(C(C)(C)C)cc3-c3cccc4c3oc3ccccc34)cc(-c3ccc4oc5ccccc5c4c3)c2)cc1]

2-(3,5-dichlorophenyl)dibenzo[b,d]furan (1 eq), Intermediate 20-2 (2 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 24 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 20-3. (yield: 70%)

### (Synthesis of Intermediate 20-4)

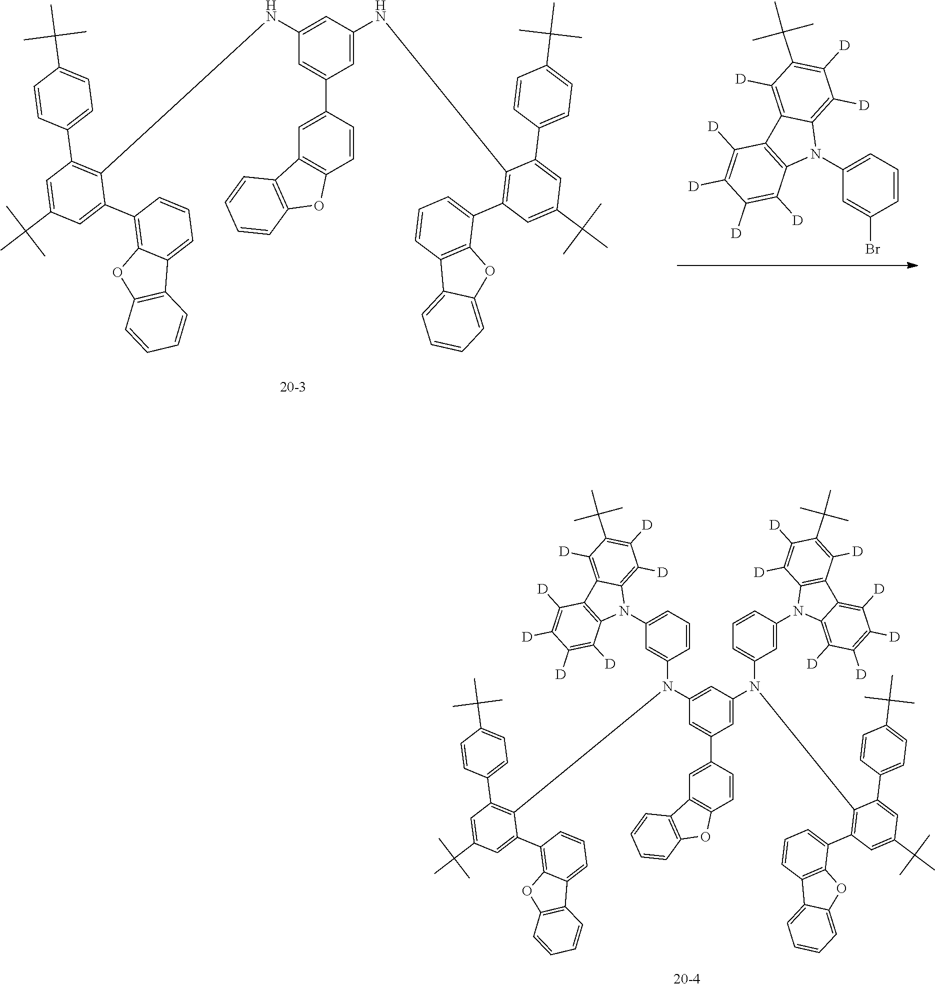

Intermediate 20-3 (1 eq), 9-(3-bromophenyl)-3-(tert-butyl)-9H-carbazole-D7 (4 eq), tris(dibenzylideneacetone)dipalladium(0) (0.2 eq), tri-tert-butylphosphine (0.4 eq), and sodium tert-butoxide (3 eq) were dissolved in o-xylene, and the resultant mixture was stirred at about 150° C. for about 48 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 20-4. (yield: 36%)

### (Synthesis of Compound 20)

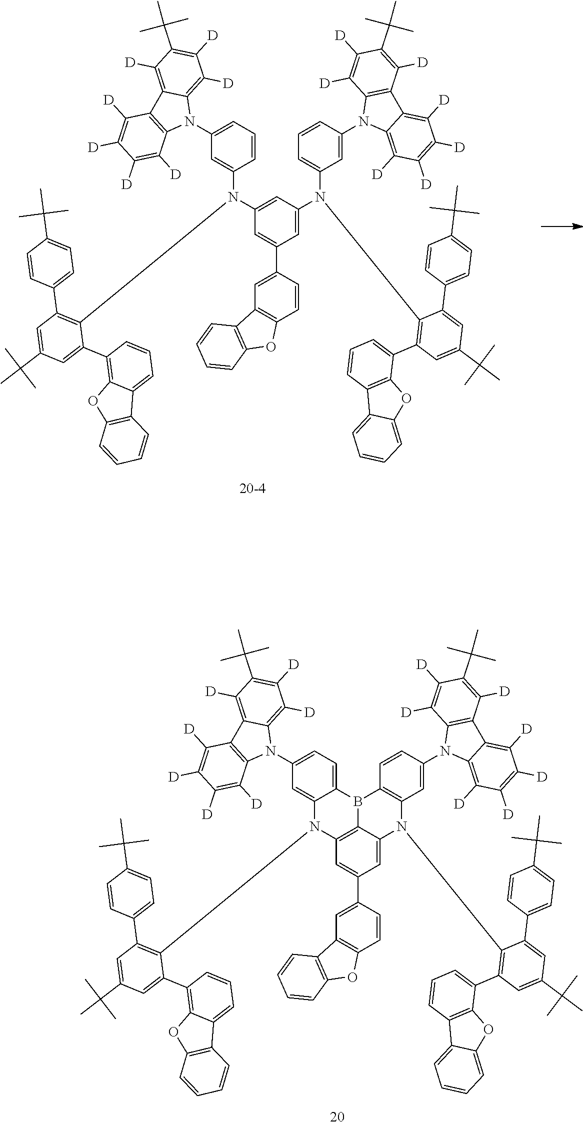

Intermediate 20-4 (1 eq) was dissolved in ortho dichlorobenzene, the mixture was cooled to about 0° C., and BBr₃ (5 eq) was slowly injected thereto in a nitrogen atmosphere. After dropping was completed, the temperature was elevated to about 180° C., and the mixture was stirred for about 24 hours. After cooling, the reaction was terminated by slowly dropping triethylamine in the flask containing the reactant, and ethyl alcohol was added to the reactant, followed by extraction and filtration to obtain solids. The obtained solids were purified by column chromatography using MC and n-hexane, and were subjected to recrystallization using toluene and acetone to obtain Compound 20. (yield: 4%)

### (4) Synthesis of Compound 54

### (Synthesis of Intermediate 54-1)

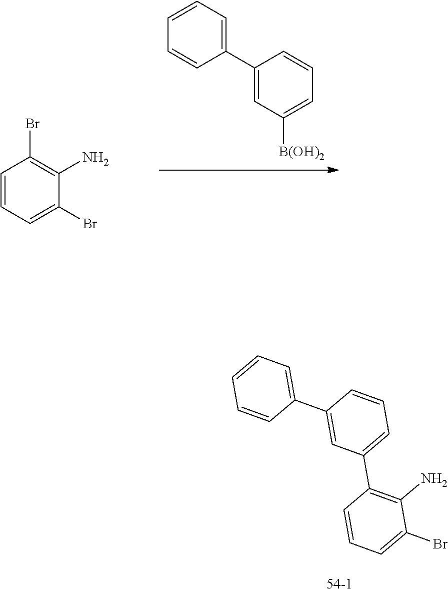 [SMILES: Nc1c(Br)cccc1Br ; OB(O)c1cccc(-c2ccccc2)c1 ; Nc1c(Br)cccc1-c1cccc(-c2ccccc2)c1]

2,6-dibromoaniline (1 eq), [1,1′-biphenyl]-3-ylboronic acid (1 eq), Pd(PPh₃)₄ (0.05 eq), and K₂CO₃ (3 eq) were dissolved in a mixed solution of water and THF (2:1), and the resultant mixture was stirred at about 80° C. for about 12 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 54-1. (yield: 45%)

### (Synthesis of Intermediate 54-2)

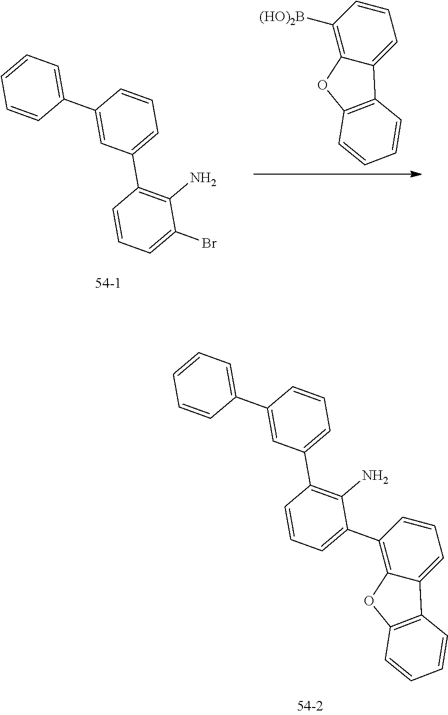 [SMILES: Nc1c(Br)cccc1-c1cccc(-c2ccccc2)c1 ; OB(O)c1cccc2c1oc1ccccc12 ; Nc1c(-c2cccc(-c3ccccc3)c2)cccc1-c1cccc2c1oc1ccccc12]

Intermediate 54-1 (1 eq), dibenzo[b,d]furan-4-ylboronic acid (1.2 eq), Pd(PPh₃)₄ (0.05 eq), and K₂CO₃ (3 eq) were dissolved in a mixed solution of water and THF (2:1), and the resultant mixture was stirred at about 80° C. for about 12 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 54-2. (yield: 75%)

### (Synthesis of Intermediate 54-3)

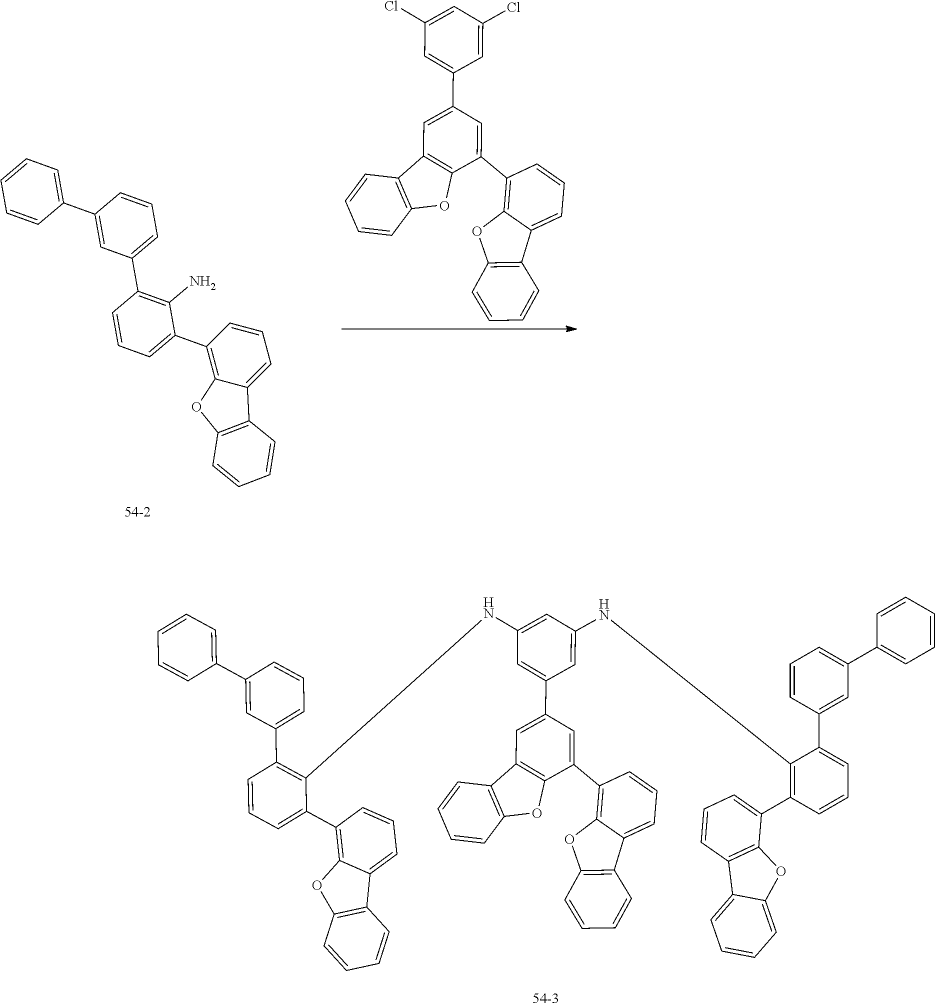 [SMILES: Nc1c(-c2cccc(-c3ccccc3)c2)cccc1-c1cccc2c1oc1ccccc12 ; Clc1cc(Cl)cc(-c2cc(-c3cccc4c3oc3ccccc34)c3oc4ccccc4c3c2)c1 ; c1ccc(-c2cccc(-c3cccc(-c4cccc5c4oc4ccccc45)c3Nc3cc(Nc4c(-c5cccc(-c6ccccc6)c5)cccc4-c4cccc5c4oc4ccccc45)cc(-c4cc(-c5cccc6c5oc5ccccc56)c5oc6ccccc6c5c4)c3)c2)cc1]

2-(3,5-dichlorophenyl)-4,4′-bidibenzo[b,d]furan (1 eq), Intermediate 54-2 (2 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 24 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 54-3. (yield: 66%)

### (Synthesis of Intermediate 54-4)

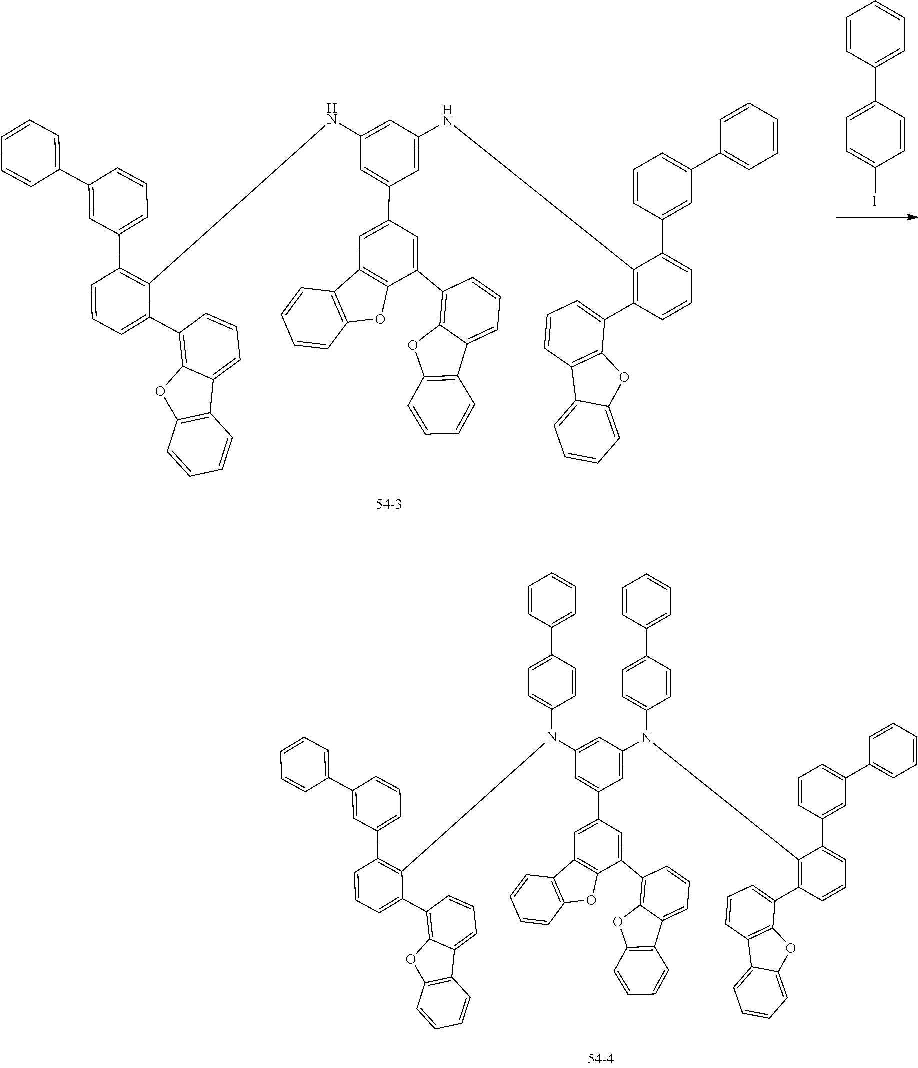

Intermediate 54-3 (1 eq), 4-iodo-1,1′-biphenyl (4 eq), tris(dibenzylideneacetone)dipalladium(0) (0.2 eq), tri-tert-butylphosphine (0.4 eq), and sodium tert-butoxide (3 eq) were dissolved in o-xylene, and the resultant mixture was stirred at about 150° C. for about 48 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 54-4. (yield: 34%)

### (Synthesis of Compound 54)

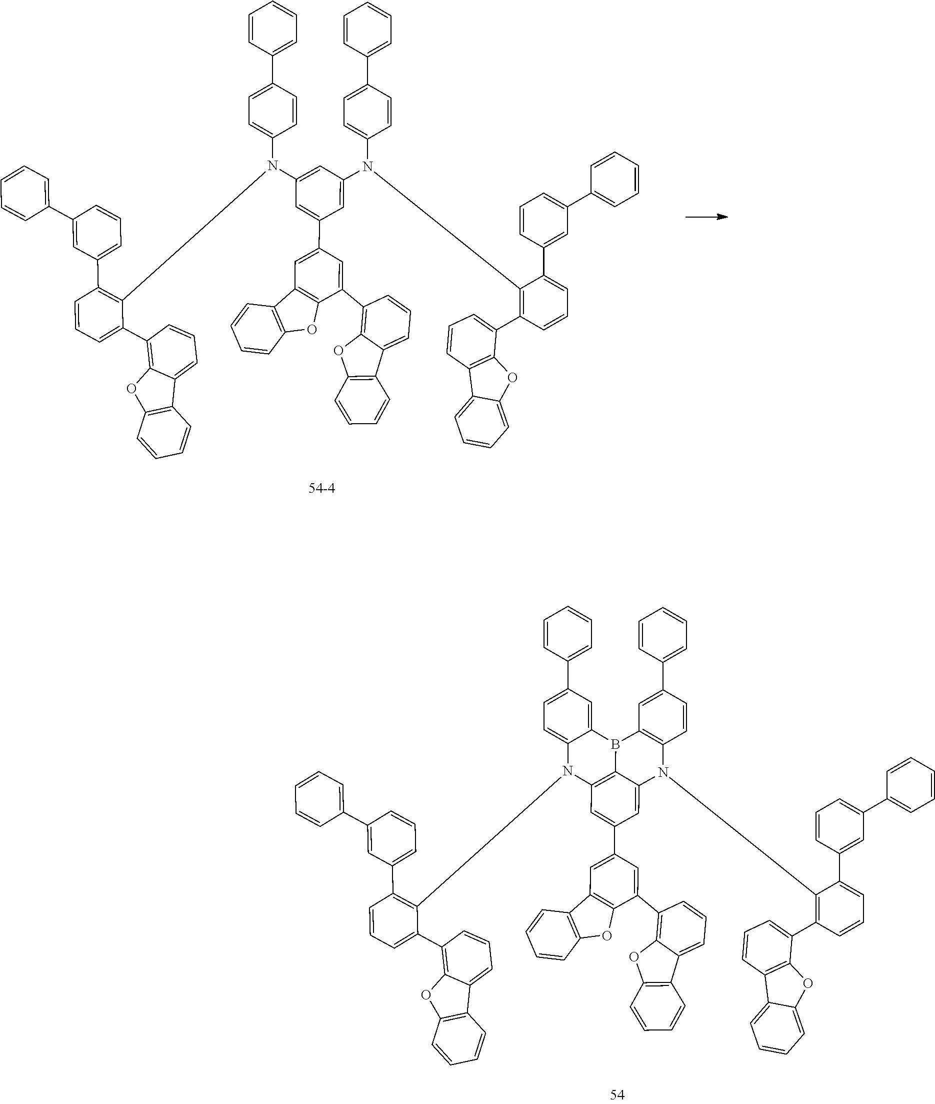 [SMILES: c1ccc(-c2ccc(N(c3cc(-c4cc(-c5cccc6c5oc5ccccc56)c5oc6ccccc6c5c4)cc(N(c4ccc(-c5ccccc5)cc4)c4c(-c5cccc(-c6ccccc6)c5)cccc4-c4cccc5c4oc4ccccc45)c3)c3c(-c4cccc(-c5ccccc5)c4)cccc3-c3cccc4c3oc3ccccc34)cc2)cc1 ; c1ccc(-c2cccc(-c3cccc(-c4cccc5c4oc4ccccc45)c3N3c4ccc(-c5ccccc5)cc4B4c5cc(-c6ccccc6)ccc5N(c5c(-c6cccc(-c7ccccc7)c6)cccc5-c5cccc6c5oc5ccccc56)c5cc(-c6cc(-c7cccc8c7oc7ccccc78)c7oc8ccccc8c7c6)cc3c54)c2)cc1]

Intermediate 54-4 (1 eq) was dissolved in ortho dichlorobenzene, the mixture was cooled to about 0° C., and BBr₃ (5 eq) was slowly injected thereto in a nitrogen atmosphere. After dropping was completed, the temperature was elevated to about 180° C., and the mixture was stirred for about 24 hours. After cooling, the reaction was terminated by slowly dropping triethylamine in the flask containing the reactant, and ethyl alcohol was added to the reactant, followed by extraction and filtration to obtain solids. The obtained solids were purified by column chromatography using MC and n-hexane, and were subjected to recrystallization using toluene and acetone to obtain Compound 54. (yield: 3%)

### (5) Synthesis of Compound 58

### (Synthesis of Intermediate 58-1)

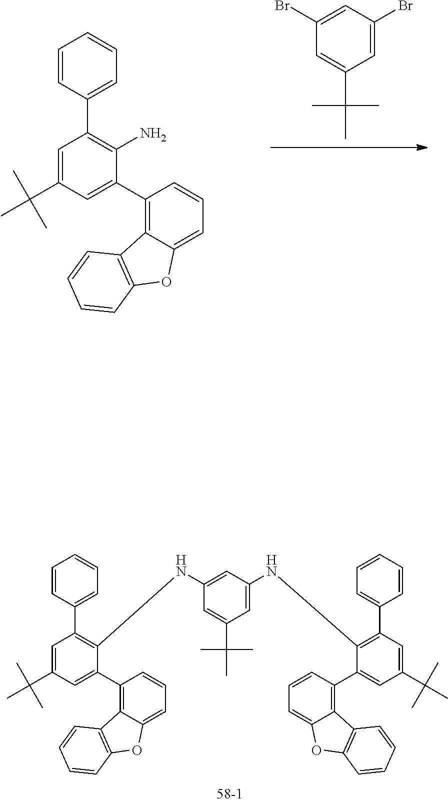 [SMILES: CC(C)(C)c1cc(-c2ccccc2)c(N)c(-c2cccc3oc4ccccc4c23)c1 ; CC(C)(C)c1cc(Br)cc(Br)c1 ; CC(C)(C)c1cc(Nc2c(-c3ccccc3)cc(C(C)(C)C)cc2-c2cccc3oc4ccccc4c23)cc(Nc2c(-c3ccccc3)cc(C(C)(C)C)cc2-c2cccc3oc4ccccc4c23)c1]

1,3-dibromo-5-(tert-butyl)benzene (1 eq), 5-(tert-butyl)-3-(Dibenzo[b,d]furan-1-yl)-[1,1′-biphenyl]-2-amine (2 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 12 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 58-1. (yield: 65%)

### (Synthesis of Intermediate 58-2)

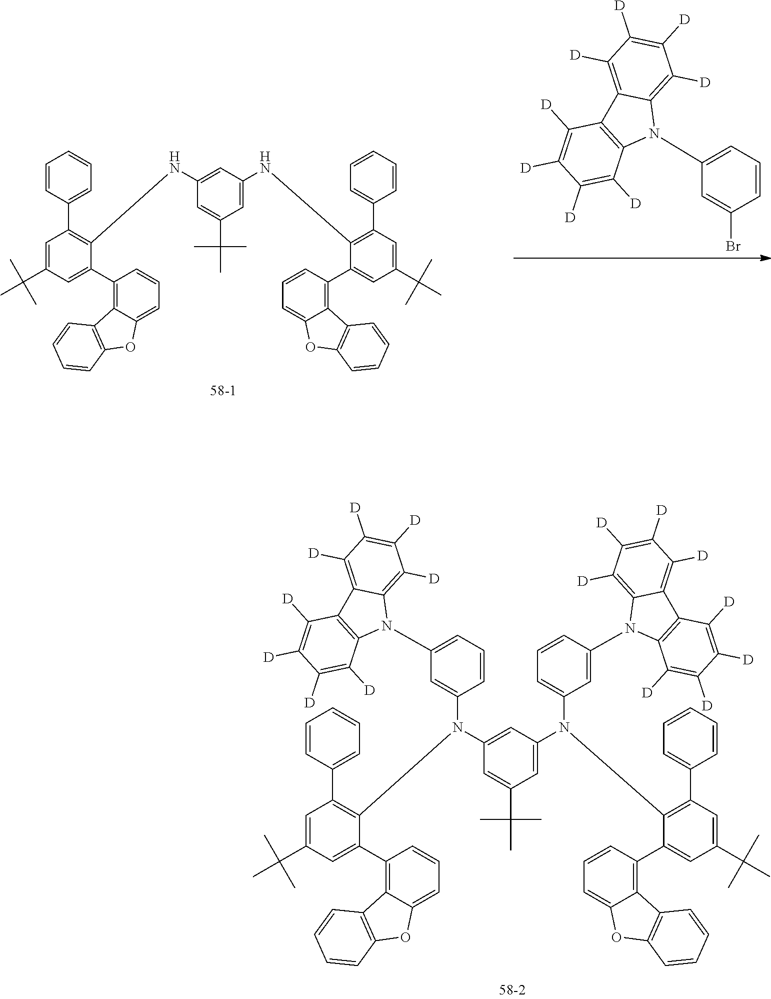 [SMILES: CC(C)(C)c1cc(Nc2c(-c3ccccc3)cc(C(C)(C)C)cc2-c2cccc3oc4ccccc4c23)cc(Nc2c(-c3ccccc3)cc(C(C)(C)C)cc2-c2cccc3oc4ccccc4c23)c1 ; [2H]c1c([2H])c([2H])c2c(c1[2H])c1c([2H])c([2H])c([2H])c([2H])c1n2-c1cccc(Br)c1 ; [2H]c1c([2H])c([2H])c2c(c1[2H])c1c([2H])c([2H])c([2H])c([2H])c1n2-c1cccc(N(c2cc(N(c3cccc(-n4c5c([2H])c([2H])c([2H])c([2H])c5c5c([2H])c([2H])c([2H])c([2H])c54)c3)c3c(-c4ccccc4)cc(C(C)(C)C)cc3-c3cccc4oc5ccccc5c34)cc(C(C)(C)C)c2)c2c(-c3ccccc3)cc(C(C)(C)C)cc2-c2cccc3oc4ccccc4c23)c1]

Intermediate 58-1 (1 eq), 9-(3-bromophenyl)-9H-carbazole-D8 (4 eq), tris(dibenzylideneacetone)dipalladium(0) (0.15 eq), tri-tert-butylphosphine (0.3 eq), and sodium tert-butoxide (4 eq) were dissolved in o-xylene, and the resultant mixture was stirred at about 150° C. for about 60 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 58-2. (yield: 32%)

### (Synthesis of Compound 58)

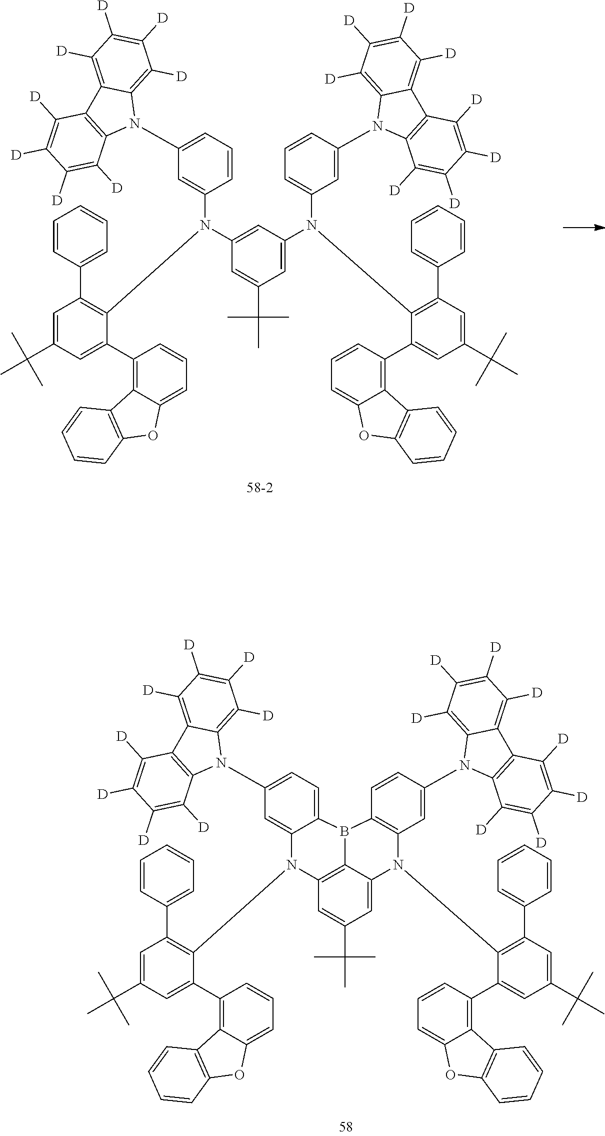

Intermediate 58-2 (1 eq) was dissolved in ortho dichlorobenzene, the mixture was cooled to about 0° C., and BBr₃ (5 eq) was slowly injected thereto in a nitrogen atmosphere. After dropping was completed, the temperature was elevated to about 180° C., and the mixture was stirred for about 24 hours. After cooling, the reaction was terminated by slowly dropping triethylamine in the flask containing the reactant, and ethyl alcohol was added to the reactant, followed by extraction and filtration to obtain solids. The obtained solids were purified by column chromatography using MC and n-hexane, and were subjected to recrystallization using toluene and acetone to obtain Compound 58. (yield: 2%)

### (6) Synthesis of Compound 60

### (Synthesis of Intermediate 60-1)

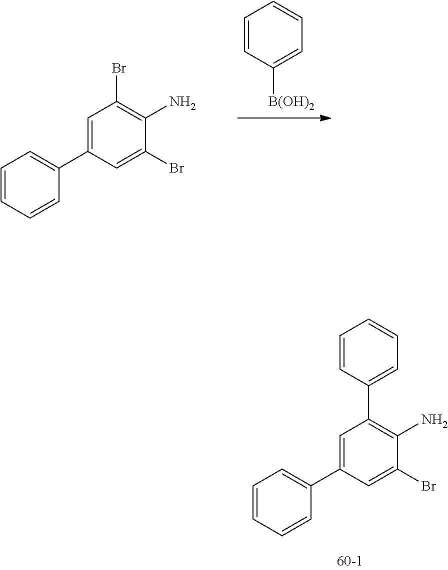 [SMILES: Nc1c(Br)cc(-c2ccccc2)cc1Br ; OB(O)c1ccccc1 ; Nc1c(Br)cc(-c2ccccc2)cc1-c1ccccc1]

3,5-dibromo-[1,1′-biphenyl]-4-amine (1 eq), phenylboronic acid (1 eq), Pd(PPh₃)₄ (0.05 eq), and K₂CO₃ (3 eq) were dissolved in a mixed solution of water and THF (2:1), and the resultant mixture was stirred at about 80° C. for about 12 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 60-1. (yield: 47%)

### (Synthesis of Intermediate 60-2)

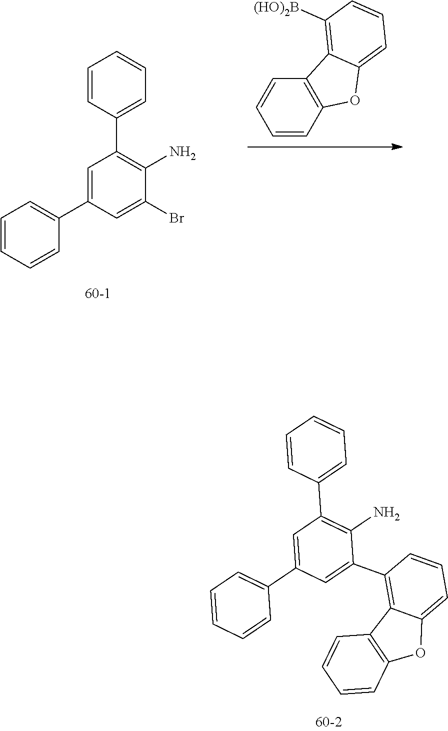 [SMILES: Nc1c(Br)cc(-c2ccccc2)cc1-c1ccccc1 ; OB(O)c1cccc2oc3ccccc3c12 ; Nc1c(-c2ccccc2)cc(-c2ccccc2)cc1-c1cccc2oc3ccccc3c12]

Intermediate 60-1 (1 eq), dibenzo[b,d]furan-1-ylboronic acid (1.2 eq), Pd(PPh₃)₄ (0.05 eq), and K₂CO₃ (3 eq) were dissolved in a mixed solution of water and THF (2:1), and the resultant mixture was stirred at about 80° C. for about 12 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 60-2. (yield: 71%)

### (Synthesis of Intermediate 60-3)

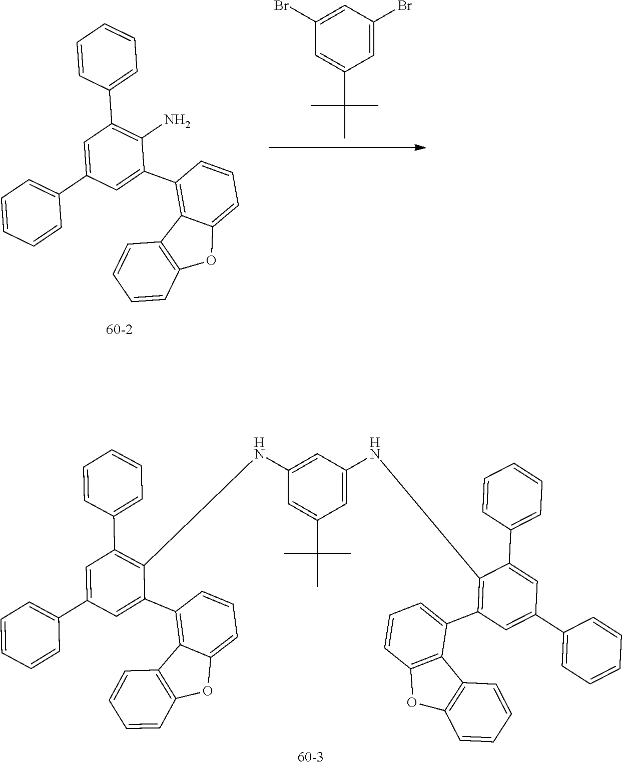 [SMILES: Nc1c(-c2ccccc2)cc(-c2ccccc2)cc1-c1cccc2oc3ccccc3c12 ; CC(C)(C)c1cc(Br)cc(Br)c1 ; CC(C)(C)c1cc(Nc2c(-c3ccccc3)cc(-c3ccccc3)cc2-c2cccc3oc4ccccc4c23)cc(Nc2c(-c3ccccc3)cc(-c3ccccc3)cc2-c2cccc3oc4ccccc4c23)c1]

1,3-dibromo-5-(tert-butyl)benzene (1 eq), Intermediate 60-2 (2 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 24 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 60-3. (yield: 67%)

### (Synthesis of Intermediate 60-4)

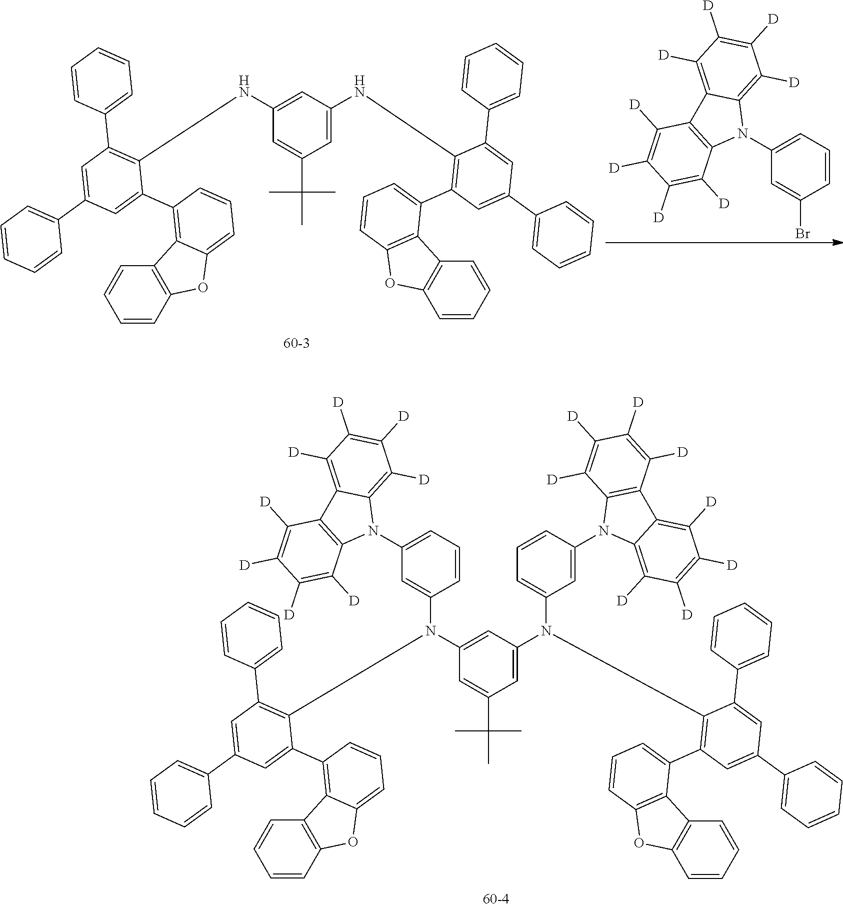 [SMILES: CC(C)(C)c1cc(Nc2c(-c3ccccc3)cc(-c3ccccc3)cc2-c2cccc3oc4ccccc4c23)cc(Nc2c(-c3ccccc3)cc(-c3ccccc3)cc2-c2cccc3oc4ccccc4c23)c1 ; [2H]c1c([2H])c([2H])c2c(c1[2H])c1c([2H])c([2H])c([2H])c([2H])c1n2-c1cccc(Br)c1 ; [2H]c1c([2H])c([2H])c2c(c1[2H])c1c([2H])c([2H])c([2H])c([2H])c1n2-c1cccc(N(c2cc(N(c3cccc(-n4c5c([2H])c([2H])c([2H])c([2H])c5c5c([2H])c([2H])c([2H])c([2H])c54)c3)c3c(-c4ccccc4)cc(-c4ccccc4)cc3-c3cccc4oc5ccccc5c34)cc(C(C)(C)C)c2)c2c(-c3ccccc3)cc(-c3ccccc3)cc2-c2cccc3oc4ccccc4c23)c1]

Intermediate 60-3 (1 eq), 9-(3-bromophenyl)-9H-carbazole-D8 (4 eq), tris(dibenzylideneacetone)dipalladium(0) (0.2 eq), tri-tert-butyiphosphine (0.4 eq), and sodium tert-butoxide (3 eq) were dissolved in o-xylene, and the resultant mixture was stirred at about 150° C. for about 48 hours. After cooling, the mixture was washed three times with ethyl acetate and water, and subjected to liquid separation to obtain an organic layer. The obtained organic layer was dried over MgS04, and dried under reduced pressure. The resulting product was purified by column chromatography using MC and n-hexane to obtain Intermediate 60-4. (yield: 39%)

### (Synthesis of Compound 60)

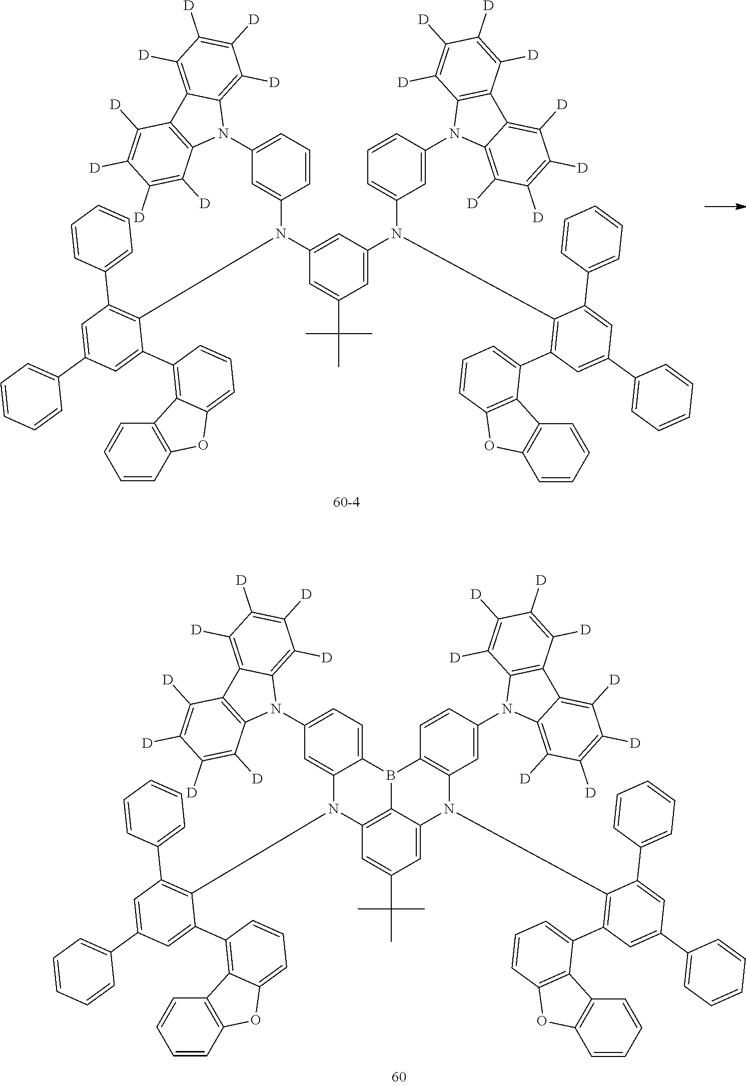

Intermediate 60-4 (1 eq) was dissolved in ortho dichlorobenzene, the mixture was cooled to about 0° C., and BBr₃ (5 eq) was slowly injected thereto in a nitrogen atmosphere. After dropping was completed, the temperature was elevated to about 180° C., and the mixture was stirred for about 24 hours. After cooling, the reaction was terminated by slowly dropping triethylamine in the flask containing the reactant, and ethyl alcohol was added to the reactant, followed by extraction and filtration to obtain solids. The obtained solids were purified by column chromatography using MC and n-hexane, and were subjected to recrystallization using toluene and acetone to obtain Compound 60. (yield: 3%)

### (7) Synthesis of Compound 73

### (Synthesis of Intermediate 73-1)

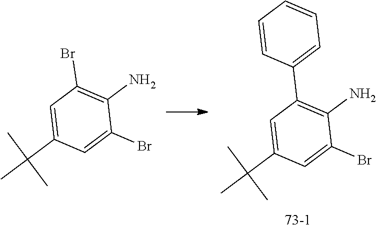 [SMILES: CC(C)(C)c1cc(Br)c(N)c(Br)c1 ; CC(C)(C)c1cc(Br)c(N)c(-c2ccccc2)c1]

2,6-dibromo-4-(tert-butyl)aniline (1 eq), phenylboronic acid (1 eq), Pd(PPh₃)₄ (0.05 eq), and K₂CO₃ (3 eq) were dissolved in a mixed solution of water and THF (2:1), and the resultant mixture was stirred at about 80° C. for about 12 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 73-1. (yield: 44%)

### (Synthesis of Intermediate 73-2)

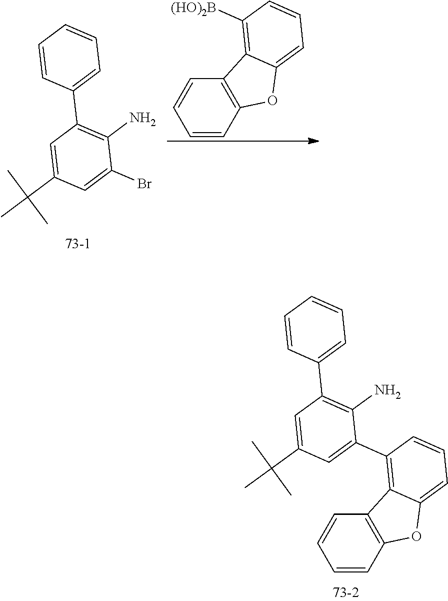

Intermediate 73-1 (1 eq), dibenzo[b,d]furan-1-ylboronic acid (1.2 eq), Pd(PPh₃)₄ (0.05 eq), and K₂CO₃ (3 eq) were dissolved in a mixed solution of water and THF (2:1), and the resultant mixture was stirred at about 80° C. for about 12 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 73-2. (yield: 70%)

### (Synthesis of Intermediate 73-3)

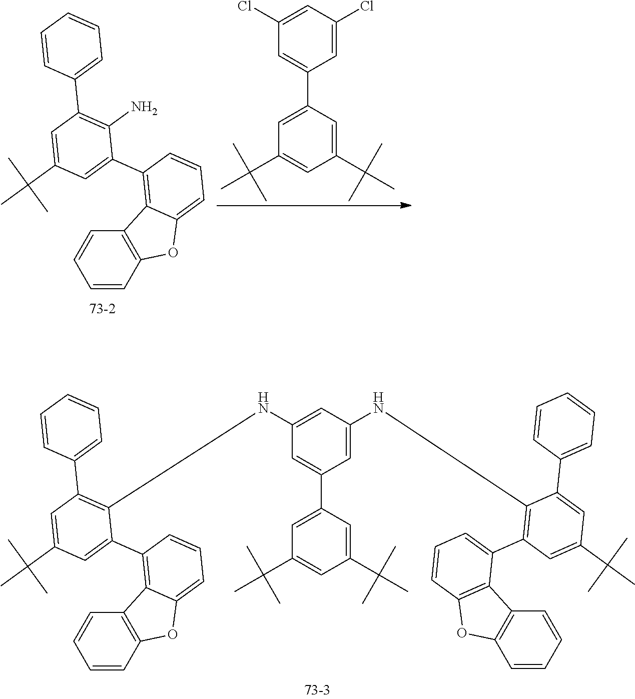

3,5-di-tert-butyl-3′,5′-dichloro-1,1′-biphenyl (1 eq), Intermediate 73-2 (2 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 24 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 73-3. (yield: 72%)

### (Synthesis of Intermediate 73-4)

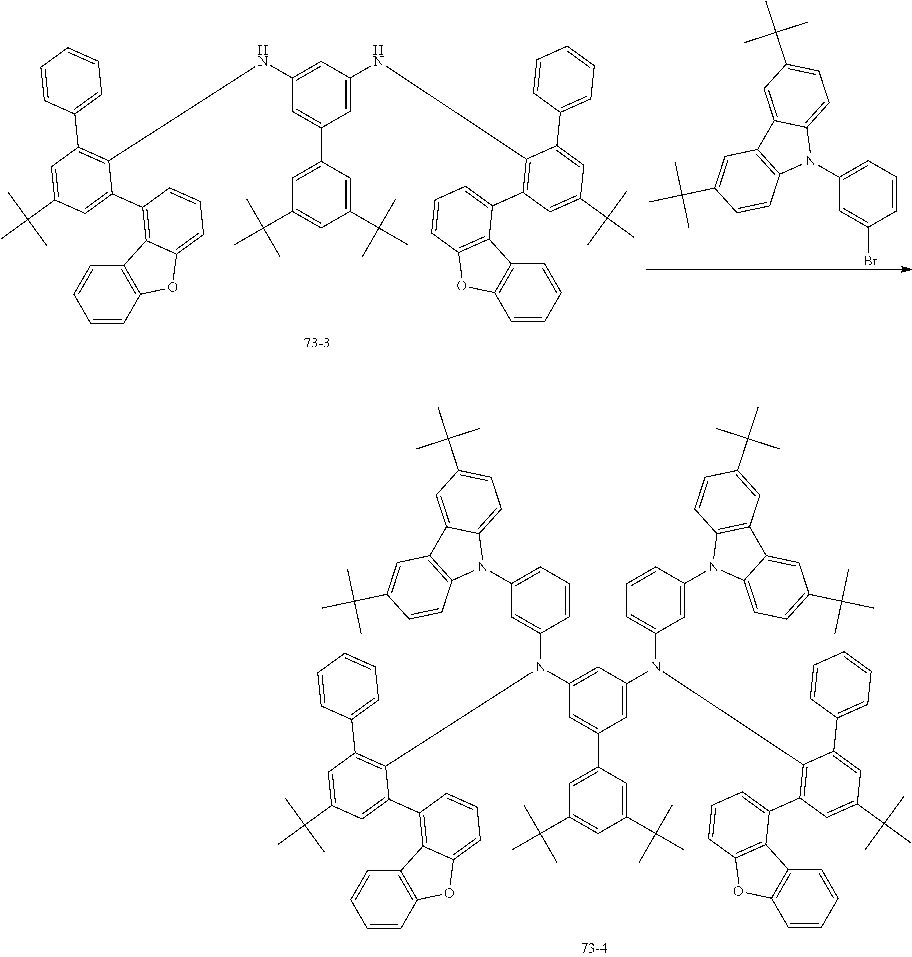

Intermediate 73-3 (1 eq), 9-(3-bromophenyl)-3,6-di-tert-butyl-9H-carbazole (4 eq), tris(dibenzylideneacetone)dipalladium(0) (0.2 eq), tri-tert-butylphosphine (0.4 eq), and sodium tert-butoxide (3 eq) were dissolved in o-xylene, and the resultant mixture was stirred at about 150° C. for about 48 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 73-4. (yield: 35%)

### (Synthesis of Compound 73)

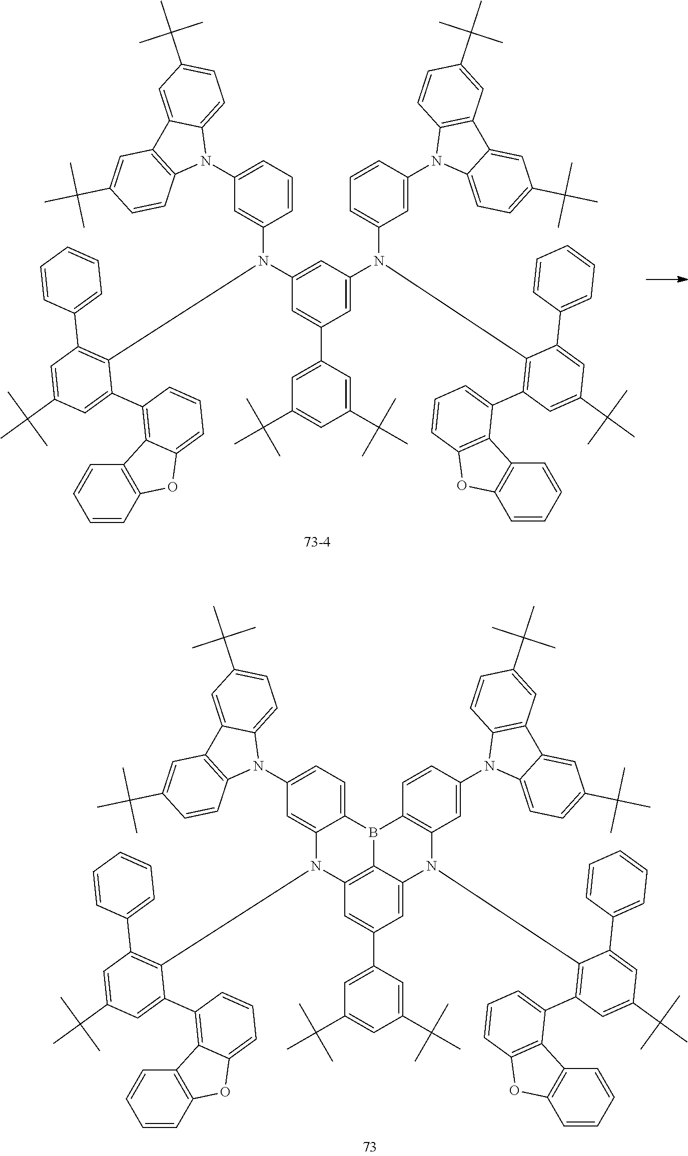

Intermediate 73-4 (1 eq) was dissolved in ortho dichlorobenzene, the mixture was cooled to about 0° C., and BBr₃ (5 eq) was slowly injected thereto in a nitrogen atmosphere. After dropping was completed, the temperature was elevated to about 180° C., and the mixture was stirred for about 24 hours. After cooling, the reaction was terminated by slowly dropping triethylamine in the flask containing the reactant, and ethyl alcohol was added to the reactant, followed by extraction and filtration to obtain solids. The obtained solids were purified by column chromatography using MC and n-hexane, and were subjected to recrystallization using toluene and acetone to obtain Compound 73. (yield: 3%)

### (8) Synthesis of Compound 97

### (Synthesis of Intermediate 97-1)

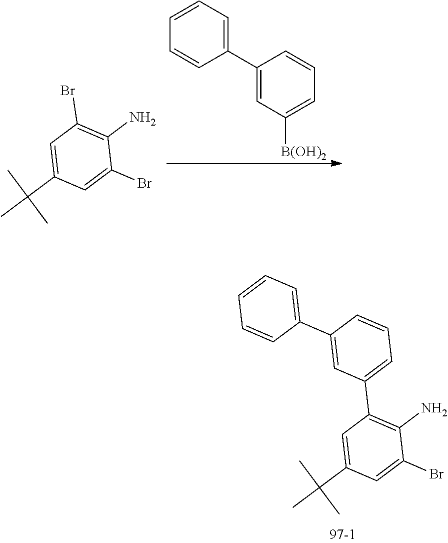 [SMILES: CC(C)(C)c1cc(Br)c(N)c(Br)c1 ; OB(O)c1cccc(-c2ccccc2)c1 ; CC(C)(C)c1cc(Br)c(N)c(-c2cccc(-c3ccccc3)c2)c1]

2,6-dibromo-4-(tert-butyl)aniline (1 eq), [1,1′-biphenyl]-3-ylboronic acid (1 eq), Pd(PPh₃)₄ (0.05 eq), and K₂CO₃ (3 eq) were dissolved in a mixed solution of water and THF (2:1), and the resultant mixture was stirred at about 80° C. for about 12 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 97-1. (yield: 40%)

### (Synthesis of Intermediate 97-2)

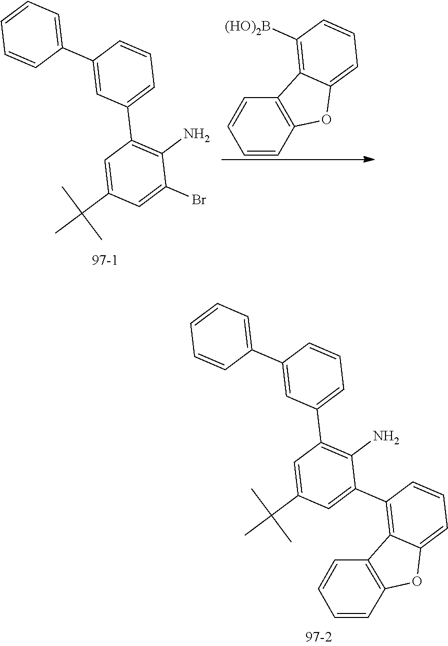

Intermediate 97-1 (1 eq), dibenzo[b,d]furan-1-ylboronic acid (1.2 eq), Pd(PPh₃)₄ (0.05 eq), and K₂CO₃ (3 eq) were dissolved in a mixed solution of water and THF (2:1), and the resultant mixture was stirred at about 80° C. for about 12 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 97-2. (yield: 75%)

### (Synthesis of Intermediate 97-3)

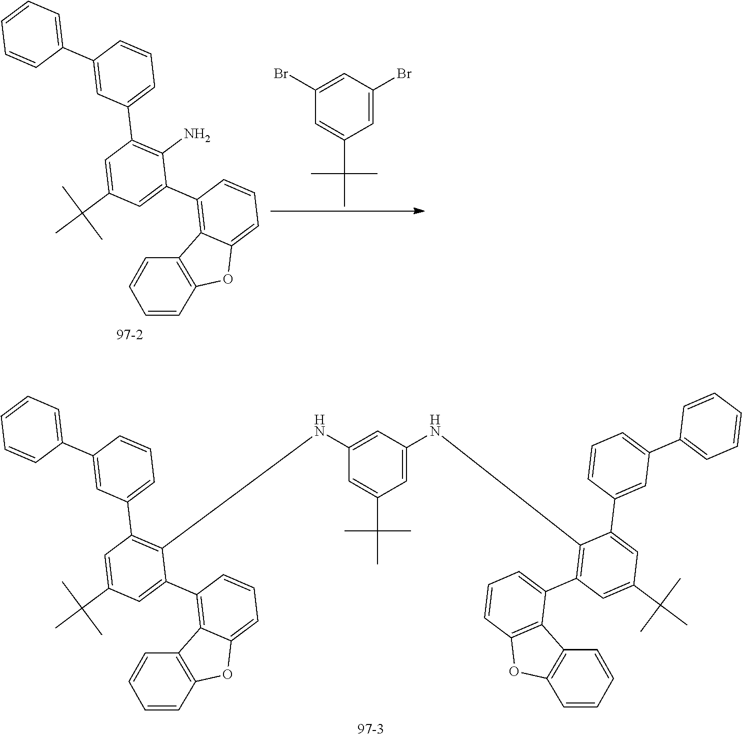 [SMILES: CC(C)(C)c1cc(-c2cccc(-c3ccccc3)c2)c(N)c(-c2cccc3oc4ccccc4c23)c1 ; CC(C)(C)c1cc(Br)cc(Br)c1 ; CC(C)(C)c1cc(Nc2c(-c3cccc(-c4ccccc4)c3)cc(C(C)(C)C)cc2-c2cccc3oc4ccccc4c23)cc(Nc2c(-c3cccc(-c4ccccc4)c3)cc(C(C)(C)C)cc2-c2cccc3oc4ccccc4c23)c1]

1,3-dibromo-5-(tert-butyl)benzene (1 eq), Intermediate 97-2 (2 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 110° C. for about 24 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 97-3. (yield: 58%)

### (Synthesis of Intermediate 97-4)

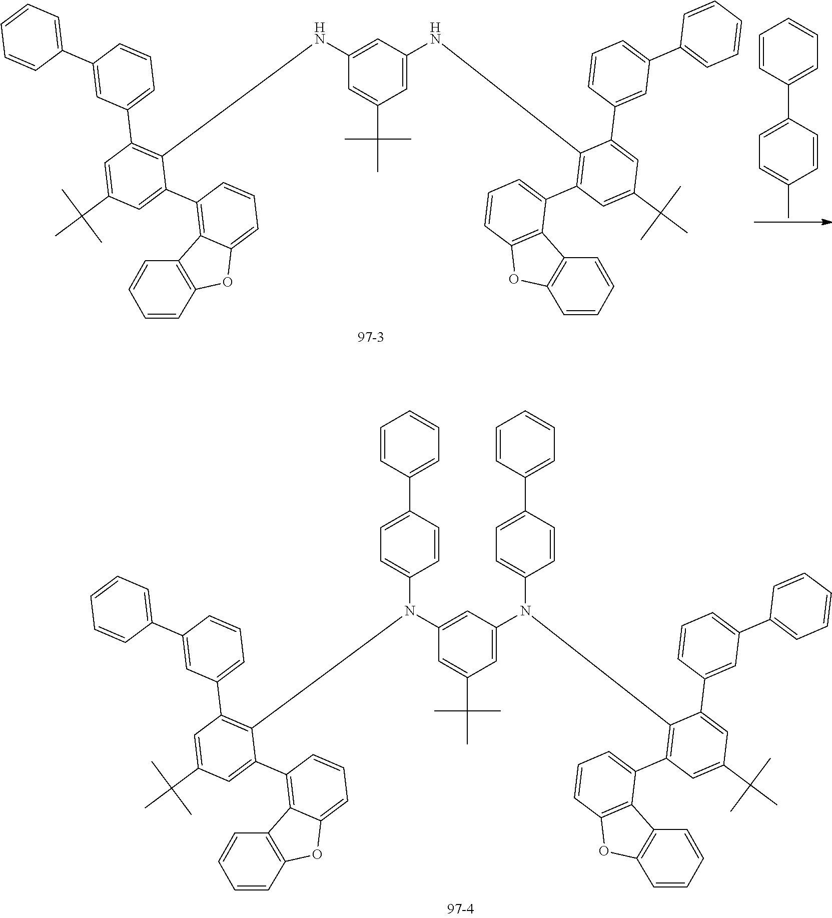

Intermediate 97-3 (1 eq), 4-iodo-1,1′-biphenyl (4 eq), tris(dibenzylideneacetone)dipalladium(0) (0.2 eq), tri-tert-butylphosphine (0.4 eq), and sodium tert-butoxide (3 eq) were dissolved in o-xylene, and the resultant mixture was stirred at about 150° C. for about 48 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 97-4. (yield: 32%)

### (Synthesis of Compound 97)

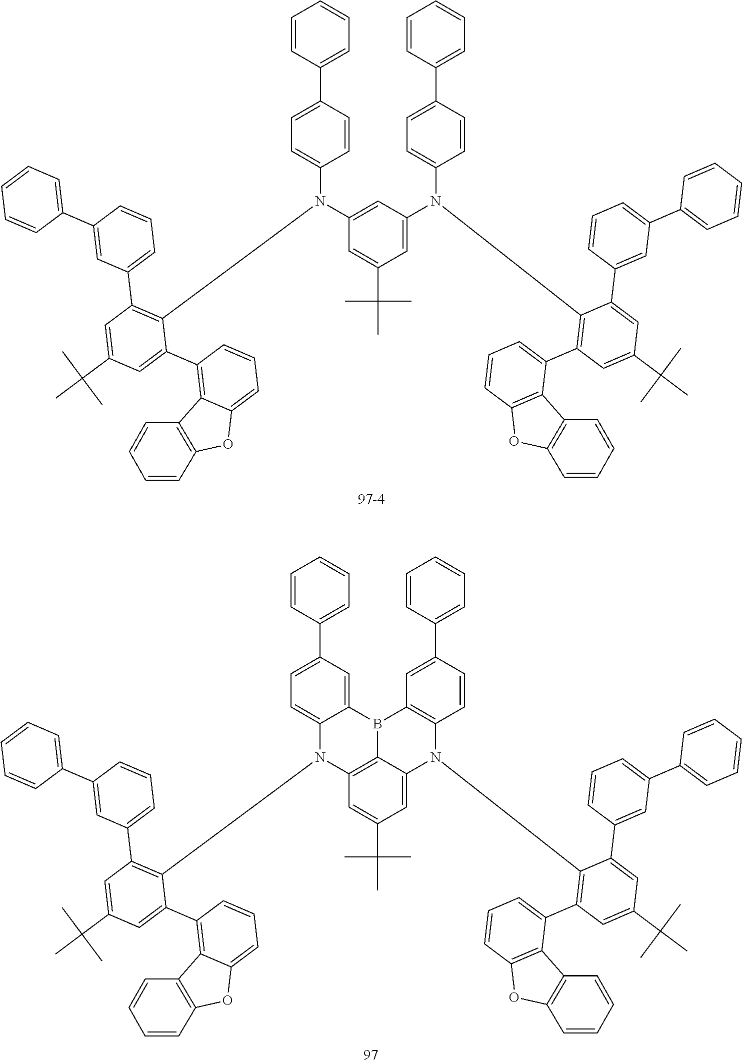 [SMILES: CC(C)(C)c1cc(N(c2ccc(-c3ccccc3)cc2)c2c(-c3cccc(-c4ccccc4)c3)cc(C(C)(C)C)cc2-c2cccc3oc4ccccc4c23)cc(N(c2ccc(-c3ccccc3)cc2)c2c(-c3cccc(-c4ccccc4)c3)cc(C(C)(C)C)cc2-c2cccc3oc4ccccc4c23)c1 ; CC(C)(C)c1cc(-c2cccc(-c3ccccc3)c2)c(N2c3ccc(-c4ccccc4)cc3B3c4cc(-c5ccccc5)ccc4N(c4c(-c5cccc(-c6ccccc6)c5)cc(C(C)(C)C)cc4-c4cccc5oc6ccccc6c45)c4cc(C(C)(C)C)cc2c43)c(-c2cccc3oc4ccccc4c23)c1]

Intermediate 97-4 (1 eq) was dissolved in ortho dichlorobenzene, the mixture was cooled to about 0° C., and BBr₃ (5 eq) was slowly injected thereto in a nitrogen atmosphere. After dropping was completed, the temperature was elevated to about 180° C., and the mixture was stirred for about 24 hours. After cooling, the reaction was terminated by slowly dropping triethylamine in the flask containing the reactant, and ethyl alcohol was added to the reactant, followed by extraction and filtration to obtain solids. The obtained solids were purified by column chromatography using MC and n-hexane, and were subjected to recrystallization using toluene and acetone to obtain Compound 97. (yield: 2%)

### (9) Synthesis of Compound 118

### (Synthesis of Intermediate 118-1)

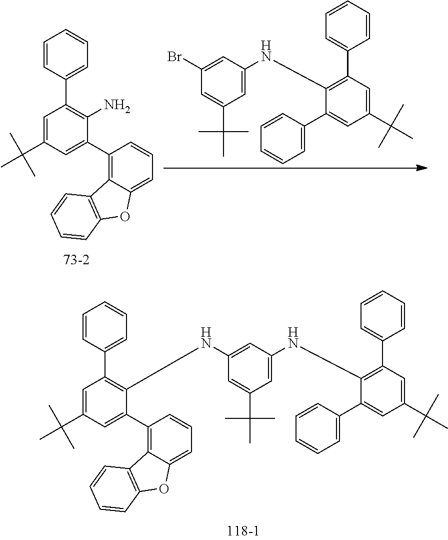 [SMILES: CC(C)(C)c1cc(-c2ccccc2)c(N)c(-c2cccc3oc4ccccc4c23)c1 ; CC(C)(C)c1cc(Br)cc(Nc2c(-c3ccccc3)cc(C(C)(C)C)cc2-c2ccccc2)c1 ; CC(C)(C)c1cc(Nc2c(-c3ccccc3)cc(C(C)(C)C)cc2-c2ccccc2)cc(Nc2c(-c3ccccc3)cc(C(C)(C)C)cc2-c2cccc3oc4ccccc4c23)c1]

Intermediate 73-2 (1 eq), N-(3-bromo-5-(tert-butyl)phenyl)-5′-(tert-butyl)-[1,1′:3′,1″-terphenyl]-2′-amine (1 eq), tris(dibenzylideneacetone)dipalladium(0) (0.05 eq), tri-tert-butylphosphine (0.1 eq), and sodium tert-butoxide (3 eq) were dissolved in toluene, and the resultant mixture was stirred at about 100° C. for about 12 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 118-1. (yield: 76%)

### (Synthesis of Intermediate 118-2)

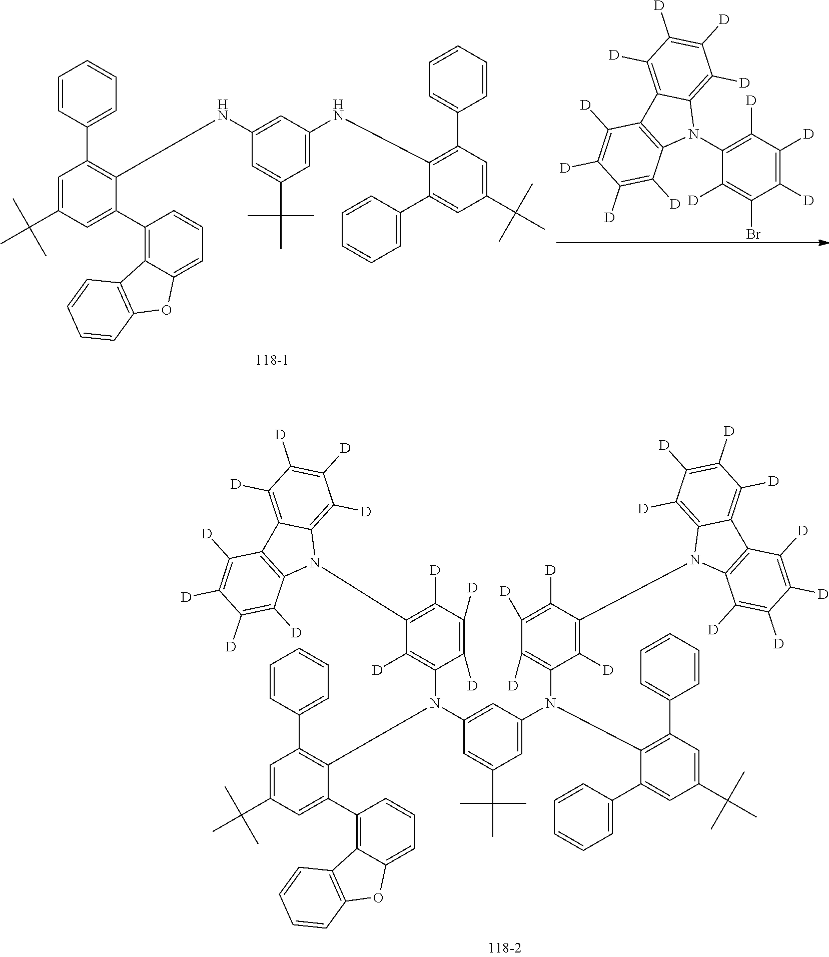

Intermediate 118-1 (1 eq), 9-(3-bromophenyl)-9H-carbazole-D12 (3.5 eq), tris(dibenzylideneacetone)dipalladium(0) (0.15 eq), tri-tert-butylphosphine (0.3 eq), and sodium tert-butoxide (4 eq) were dissolved in o-xylene, and the resultant mixture was stirred at about 150° C. for about 60 hours. After cooling, the mixture was washed three times with ethyl acetate and water, and subjected to liquid separation to obtain an organic layer. The obtained organic layer was dried over MgSO₄, and dried under reduced pressure. The resulting product was purified by column chromatography using MC and n-hexane to obtain Intermediate 118-2. (yield: 29%)

### (Synthesis of Compound 118)

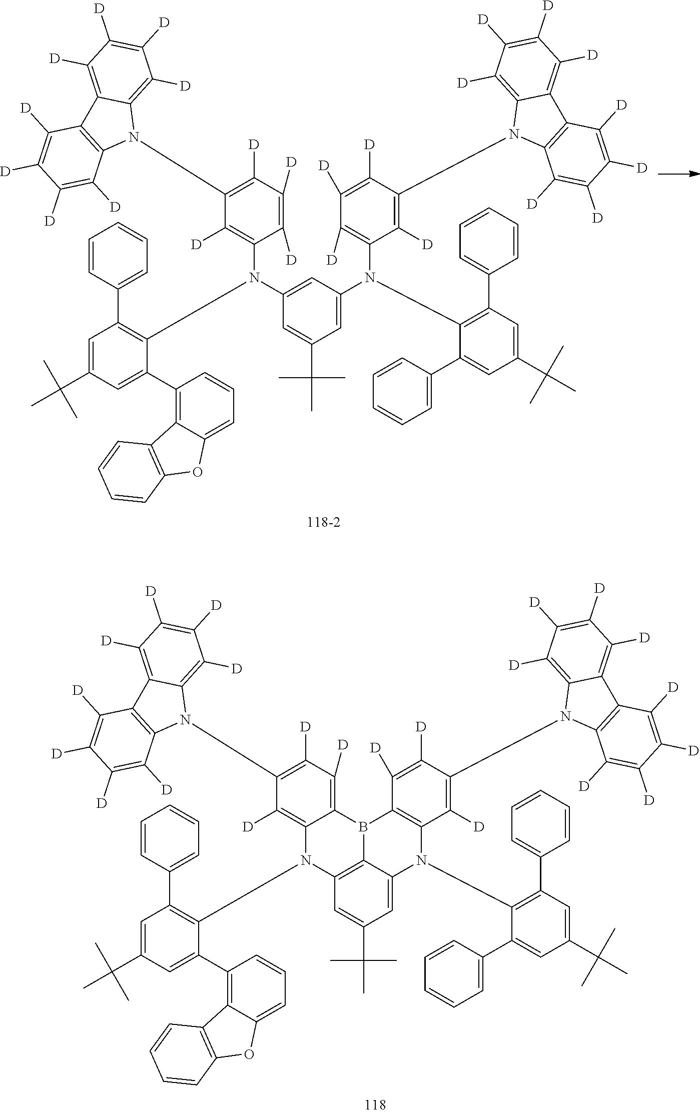

Intermediate 118-2 (1 eq) was dissolved in ortho dichlorobenzene, the mixture was cooled to about 0° C., and BBr₃ (5 eq) was slowly injected thereto in a nitrogen atmosphere. After dropping was completed, the temperature was elevated to about 180° C., and the mixture was stirred for about 24 hours. After cooling, the reaction was terminated by slowly dropping triethylamine in the flask containing the reactant, and ethyl alcohol was added to the reactant, followed by extraction and filtration to obtain solids. The obtained solids were purified by column chromatography using MC and n-hexane, and were subjected to recrystallization using toluene and acetone to obtain Compound 118. (yield: 3%)

### 1. Manufacture and Evaluation of Light Emitting Elements

The light emitting element of an example including the fused polycyclic compound of an example in an emission layer was manufactured as follows. Compounds 4, 11, 20, 54, 58, 60, 73, 97, and 118, which are Example Compounds as described above, were used as dopant materials of the emission layers to manufacture the light emitting elements of Examples 1 to 9, respectively. Comparative Examples 1 to 4 correspond to the light emitting elements manufactured by using Comparative Example Compounds c1 to c4 as dopant materials of the emission layers, respectively.

### [Example Compounds]

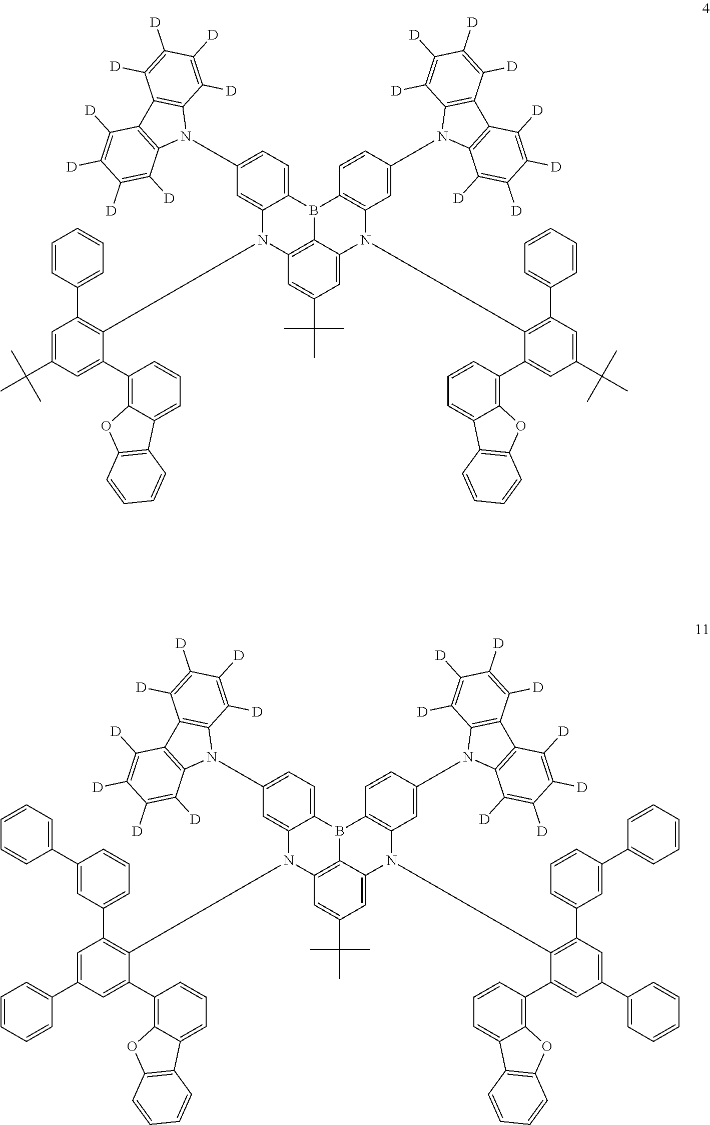

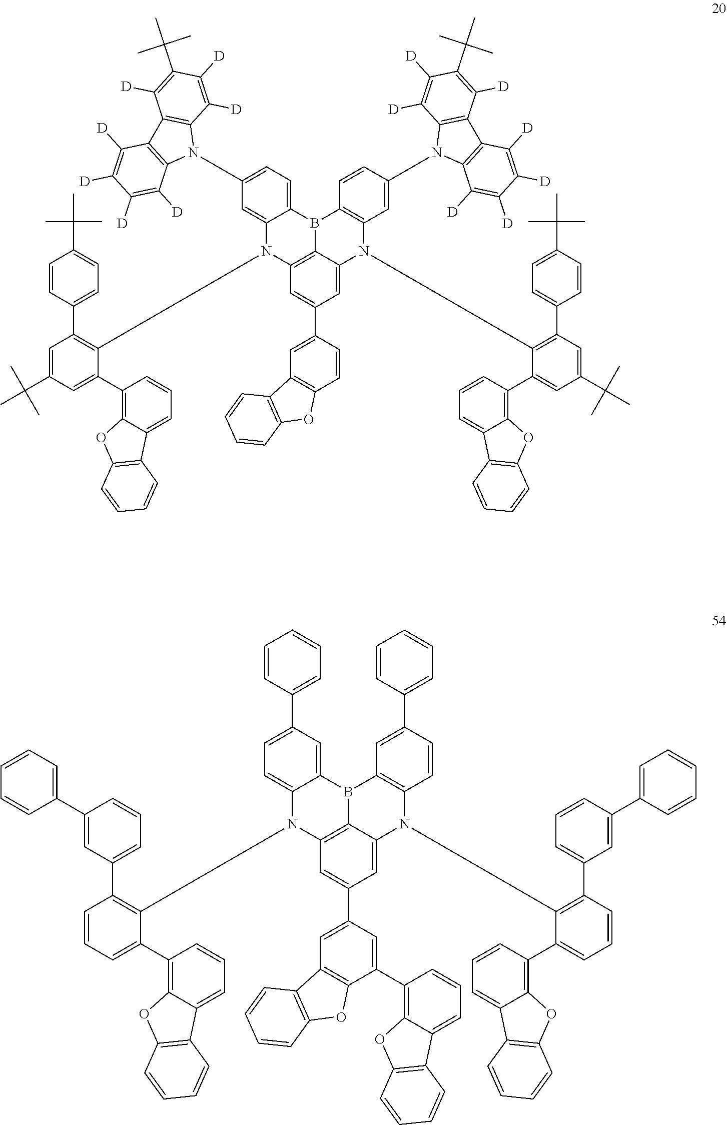

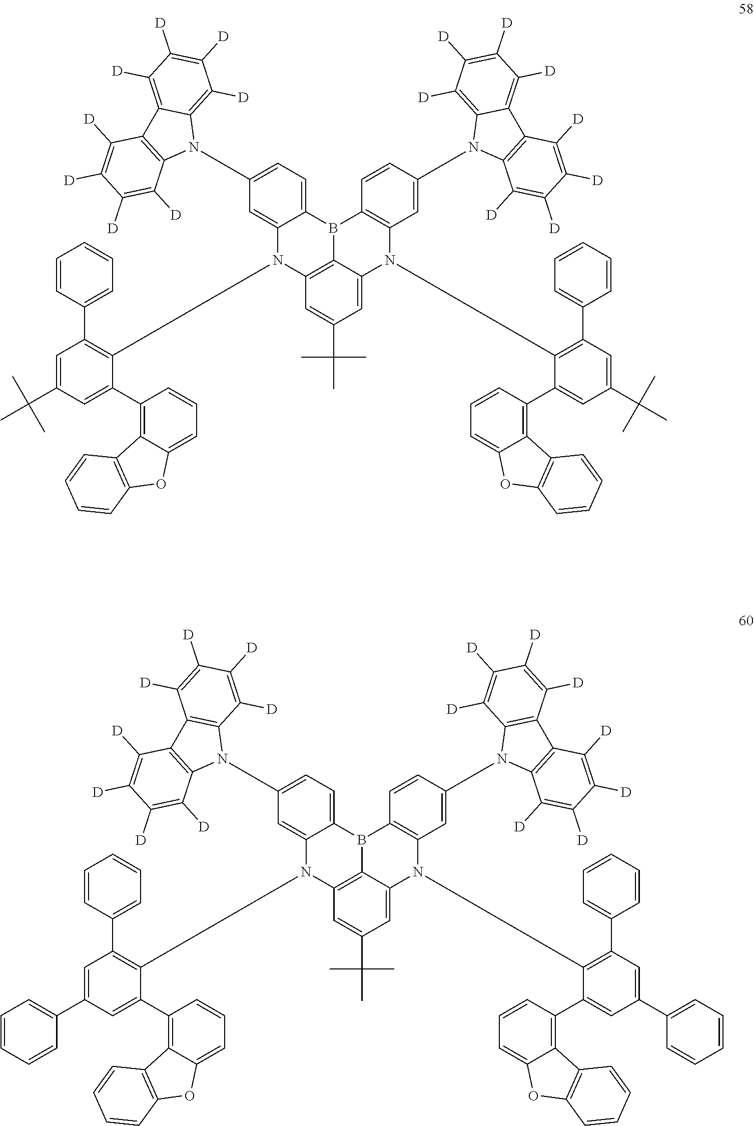

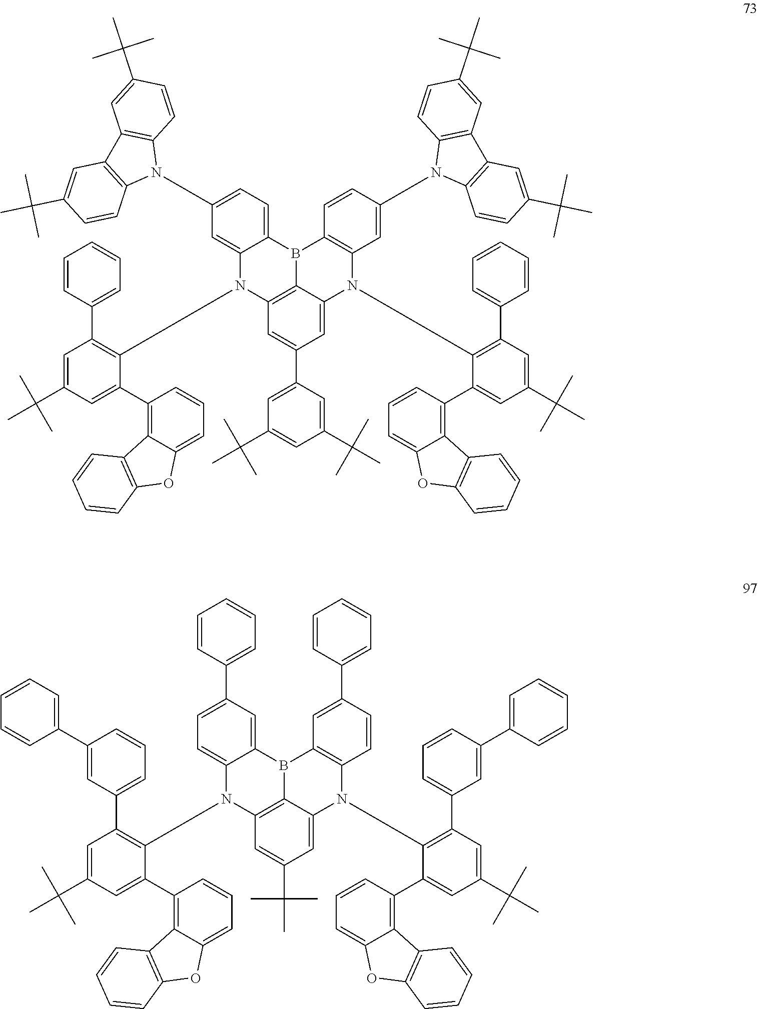 [SMILES: CC(C)(C)c1cc(-c2cc3c4c(c2)N(c2c(-c5ccccc5)cc(C(C)(C)C)cc2-c2cccc5oc6ccccc6c25)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2c(-c3ccccc3)cc(C(C)(C)C)cc2-c2cccc3oc4ccccc4c23)cc(C(C)(C)C)c1 ; CC(C)(C)c1cc(-c2cccc(-c3ccccc3)c2)c(N2c3ccc(-c4ccccc4)cc3B3c4cc(-c5ccccc5)ccc4N(c4c(-c5cccc(-c6ccccc6)c5)cc(C(C)(C)C)cc4-c4cccc5oc6ccccc6c45)c4cc(C(C)(C)C)cc2c43)c(-c2cccc3oc4ccccc4c23)c1]

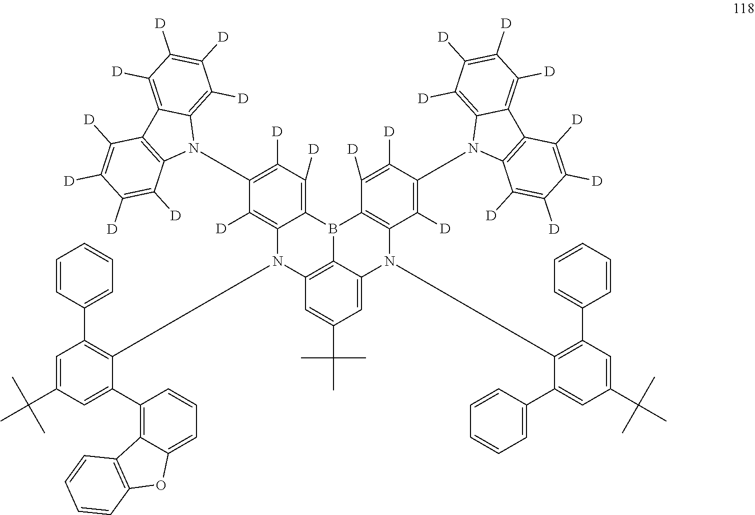 [SMILES: [2H]c1c([2H])c(-n2c3c([2H])c([2H])c([2H])c([2H])c3c3c([2H])c([2H])c([2H])c([2H])c32)c([2H])c2c1B1c3c(cc(C(C)(C)C)cc3N(c3c(-c4ccccc4)cc(C(C)(C)C)cc3-c3cccc4oc5ccccc5c34)c3c([2H])c(-n4c5c([2H])c([2H])c([2H])c([2H])c5c5c([2H])c([2H])c([2H])c([2H])c54)c([2H])c([2H])c31)N2c1c(-c2ccccc2)cc(C(C)(C)C)cc1-c1ccccc1]

### [Comparative Example Compounds]

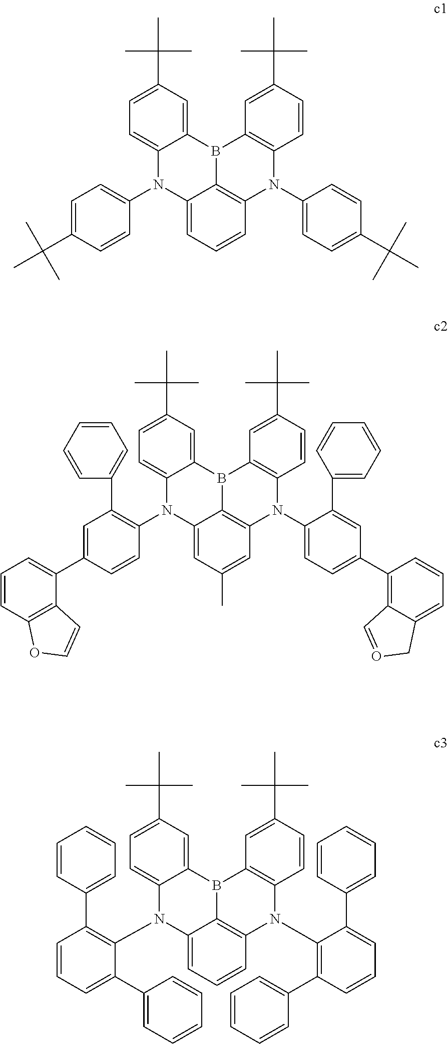

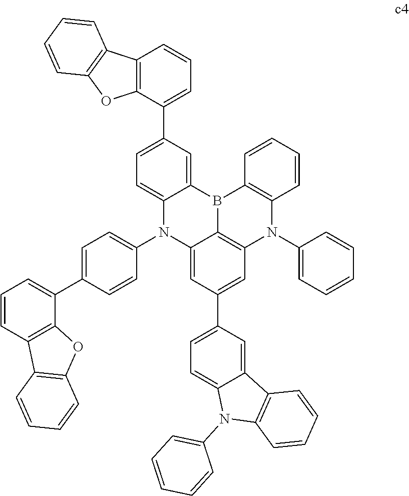 [SMILES: c1ccc(N2c3ccccc3B3c4cc(-c5cccc6c5oc5ccccc56)ccc4N(c4ccc(-c5cccc6c5oc5ccccc56)cc4)c4cc(-c5ccc6c(c5)c5ccccc5n6-c5ccccc5)cc2c43)cc1]

### (Manufacture of Light Emitting Elements)

In the light emitting elements of the Examples and the Comparative Examples, a glass substrate (made by Corning Co.), on which an ITO electrode of about 15 Ω/cm² (about 1,200 Å) is formed as an anode, was cut to a size of about 50 mm×50 mm×0.7 mm, cleansed by ultrasonic waves using isopropyl alcohol and pure water for about five minutes each, and irradiated with ultraviolet rays for about 30 minutes and exposed to ozone and cleansed. The glass substrate was installed on a vacuum deposition apparatus.

NPD was deposited on the upper portion of the anode to form a 300 k-thick hole injection layer, HT-1-1 was deposited on the upper portion of the hole injection layer to form a 200 Å-thick hole transport layer, and CzSi was deposited on the upper portion of the hole transport layer to form a 100 Å-thick emission-auxiliary layer.

A host compound in which the second compound and the third compound according to an embodiment were mixed at a ratio of about 1:1, the fourth compound, and an Example Compound or a Comparative Example Compound were co-deposited at a weight ratio of about 85:14:1 to form a 350 Å-thick emission layer, and ETH2 of Compound Group 3 as described above was deposited in vacuum to form a 50 Å-thick hole blocking layer. On the hole blocking layer, a mixed layer of CNNPTRZ and Liq was deposited at a weight ratio of 4.0:6.0 to form a 310 Å-thick electron transport layer, Yb was deposited on the electron transport layer to form a 15 Å-thick electron injection layer, and Mg was deposited in vacuum to form an 800 A-thick cathode, thereby manufacturing an organic electroluminescence element.

Each layer was formed by a vacuum deposition method. HT60 from Compound Group 2 as described above was used as the second compound, and ETH66 from Compound Group 3 as described above was used as the third compound, and AD-38 from Compound Group 4 as described above was used as the fourth compound.

Compounds used for manufacturing the light emitting elements of the Examples and the Comparative Examples are disclosed below. The materials below were used to manufacture the devices by subjecting commercial products to sublimation purification.

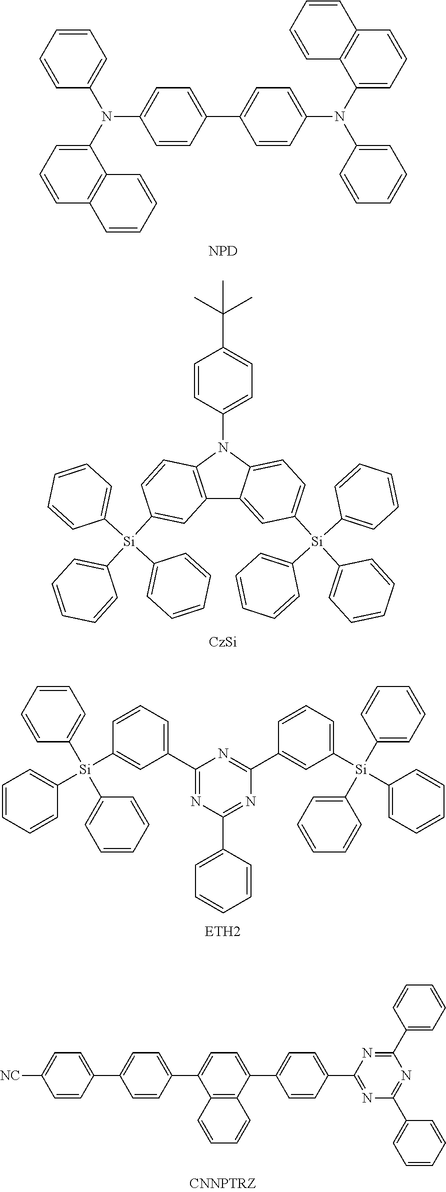 [SMILES: c1ccc(N(c2ccc(-c3ccc(N(c4ccccc4)c4cccc5ccccc45)cc3)cc2)c2cccc3ccccc23)cc1 ; "NPD" ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; N#Cc1ccc(-c2ccc(-c3ccc(-c4ccc(-c5nc(-c6ccccc6)nc(-c6ccccc6)n5)cc4)c4ccccc34)cc2)cc1]

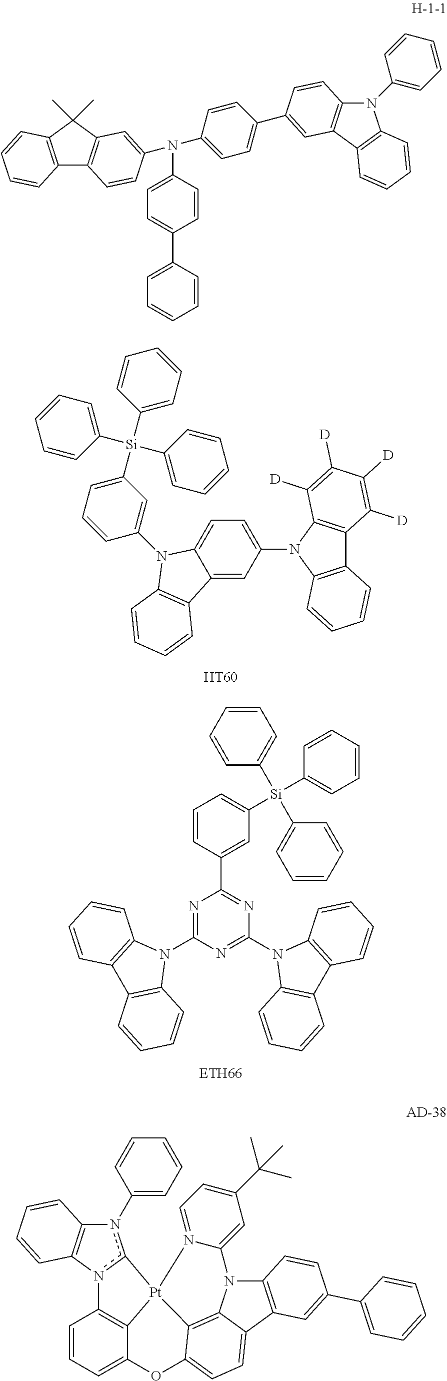

### (Evaluation of Light Emitting Element Characteristics)

Efficiency and service life of the light emitting elements manufactured with Compounds 4, 11, 20, 54, 58, 60, 73, 97, and 118 and Comparative Example Compounds c1 to c4 as described above were evaluated. Evaluation results of the light emitting elements in Examples 1 to 9 and Comparative Examples 1 to 4 are listed in Table 1. To evaluate the characteristics of the light emitting elements manufactured in Examples 1 to 9 and Comparative Examples 1 to 4, each of the driving voltages (V), luminous efficiencies (Cd/A), and emission wavelengths at a current density of 1,000 cd/m² was measured by using Keithley MU 236 and a luminance meter PR650, and the results are listed in Table 1. The time taken to reach 95% brightness relative to an initial brightness was measured as a service life (T95), a service life ratio was calculated on the basis of the element of Comparative Example 1, and the results are listed in Table 1.

TABLE 1

| | | | | | | | Service |
|---|---|---|---|---|---|---|---|
| | Host (second | | | Driving | | Emission | life |
| | compound:third | Fourth | First | voltage | Efficiency | wavelength | ratio |
| | compound = 5:5) | compound | compound | (V) | (cd/A) | (nm) | (T95) |
| Example 1 | HT60/ETH66 | AD-38 | Compound 4 | 4.4 | 26.1 | 461 | 6.4 |
| Example 2 | HT60/ETH66 | AD-38 | Compound 11 | 4.5 | 25.6 | 461 | 6.1 |
| Example 3 | HT60/ETH66 | AD-38 | Compound 20 | 4.5 | 25.4 | 461 | 5.9 |
| Example 4 | HT60/ETH66 | AD-38 | Compound 54 | 4.5 | 25.3 | 462 | 5.8 |
| Example 5 | HT60/ETH66 | AD-38 | Compound 58 | 4.5 | 24.9 | 458 | 6.3 |
| Example 6 | HT60/ETH66 | AD-38 | Compound 60 | 4.4 | 25.6 | 458 | 6.1 |
| Example 7 | HT60/ETH66 | AD-38 | Compound 73 | 4.5 | 25.8 | 460 | 6.2 |
| Example 8 | HT60/ETH66 | AD-38 | Compound 97 | 4.5 | 25.6 | 461 | 6.1 |
| Example 9 | HT60/ETH66 | AD-38 | Compound 118 | 4.6 | 25.5 | 459 | 6.7 |
| Comparative | HT60/ETH66 | AD-38 | Comparative | 5.6 | 18.8 | 463 | 1 |
| Example 1 | | | Example | | | | |
| | | | Compound c1 | | | | |
| Comparative | HT60/ETH66 | AD-38 | Comparative | 5.3 | 19.5 | 462 | 1.8 |
| Example 2 | | | Example | | | | |
| | | | Compound c2 | | | | |
| Comparative | HT60/ETH66 | AD-38 | Comparative | 5.2 | 18.3 | 457 | 3.6 |
| Example 3 | | | Example | | | | |
| | | | Compound c3 | | | | |
| Comparative | HT60/ETH66 | AD-38 | Comparative | 5.4 | 16.4 | 468 | 2.1 |
| Example 4 | | | Example | | | | |
| | | | Compound c4 | | | | |

Referring to the results of Table 1, it may be confirmed that the light emitting elements of the Examples, in which the fused polycyclic compounds according to the Examples are used as a luminescent material, have improved luminous efficiency and service life characteristics as compared with the Comparative Examples.

It may be confirmed that the Example Compounds include the first phenyl group and the first substituent and the second substituent linked to the first phenyl group, and at least one of the first substituent or the second substituent has a structure including the dibenzofuran moiety linked to the first phenyl group at carbon 1 or carbon 4, thereby exhibiting high luminous efficiency and improved service life characteristics when applied to the light emitting element as compared to the Comparative Examples. The Example Compounds have a structure including the fused ring core containing two heteroatoms including at least one boron atom and at least one nitrogen atom, and including the phenyl group linked to the nitrogen atom forming the fused ring core and the first substituent and the second substituent linked to the phenyl group, thereby exhibiting a deep HOMO energy level. Thus, trap-assisted recombination, which is a cause of element deterioration, is suppressed, and thus the luminous efficiency and service life characteristics may be improved. Therefore, when the Example Compounds are applied to the light emitting elements, high luminous efficiency and a long service life may be achieved.

The light emitting element according to an Example includes the first compound according to an Example as a light emitting dopant of a thermally activated delayed fluorescence (TADF) light emitting element, and thus may achieve high element efficiency, for example, in a blue wavelength region.

It may be confirmed that Comparative Example Compound c1 included in Comparative Example 1 has the same fused ring core structure as the fused polycyclic compound, but does not include the first phenyl group linked to the nitrogen atom, the first substituent, or the second substituent, and thus, when the compound is applied to a light emitting element, the element has low luminous efficiency, a short element service life, and a high driving voltage.

Comparative Example Compound c2 included in Comparative Example 2 has a structure in which the hydrogen of a pentagonal ring that is chemically unstable is exposed to the outside, and thus when the compound is applied to an element, the element has a shorter service life compared to Example Compounds. Comparative Example Compound c2 has a methyl group attached to an aryl group that generates radicals as well as benzylic protons, and thus, corresponds to a compound structure generally unfavorable to the element service life. Therefore, it may be confirmed that when Comparative Example Compound c2 is applied to a light emitting element, the element has a low luminous efficiency and a short element service life, and a high driving voltage.

Since Comparative Example Compound c3 included in Comparative Example 3 has a very shallow HOMO level as in Comparative Example Compound c1, when Comparative Example Compound c3 is applied to an element, the efficiency and service life of the element are reduced by roll-off due to an increase in triplet concentration as compared to the Example Compounds.

Comparative Example Compound c4 included in Comparative Example 4 has very high planarity since the fused rings are linked to the multi-resonance core by conjugation with a linear linking structure, and thus the interaction with surrounding molecules is increased, so that Comparative Example Compound c4 is vulnerable to Dexter energy transfer (electron exchange), which is a short-range transfer, and thus it is suggested that Comparative Example Compound c4 is disadvantageous in the service life when applied to an element as compared to Example Compounds due to an increase in triplet exciton concentration.

The light emitting element of an embodiment may exhibit improved element characteristics with high efficiency and a long service life.

The fused polycyclic compound of an embodiment may be included in the emission layer of the light emitting element to contribute to high efficiency and a long service life of the light emitting element.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode facing the first electrode; and
an emission layer disposed between the first electrode and the second electrode, wherein
the emission layer includes a first compound represented by Formula 1: 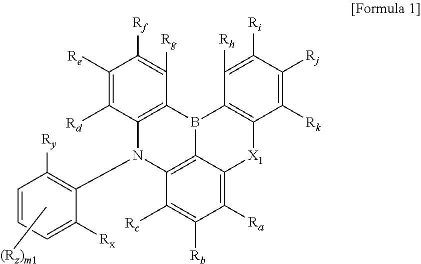
wherein in Formula 1,
X₁ is O, S, or N(R₁),
R₁ is a substituted or unsubstituted aryl group having 6 to 30 ring-forming carbon atoms, or a substituted or unsubstituted heteroaryl group having 2 to 30 ring-forming carbon atoms, or is bonded to an adjacent group to form a ring,
Rₐ to Rₖ and R_{z} are each independently a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
Rₓ and R_{y} are each independently a substituted or unsubstituted aryl group having 6 to 30 ring-forming carbon atoms, a substituted or unsubstituted heteroaryl group having 2 to 30 ring-forming carbon atoms, or a group represented by Formula 2,
m1 is an integer from 0 to 3, and
at least one of Rₓ and R_{y} is each independently a group represented by Formula 2: 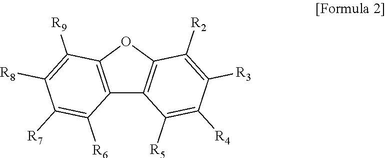
wherein in Formula 2,
R₂ to R₉ are each independently a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
except that R₂ or R₅ is a position linked to Formula 1.

2. The light emitting element of claim 1, further comprising:
a hole transport region disposed between the first electrode and the emission layer; and
an electron transport region disposed between the emission layer and the second electrode.

3. The light emitting element of claim 1, wherein the emission layer emits delayed fluorescence.

4. The light emitting element of claim 1, wherein the emission layer emits light having a central wavelength in a range of about 430 nm to about 490 nm.

5. The light emitting element of claim 1, wherein the group represented by Formula 2 is represented by Formula 2-1 or Formula 2-2: 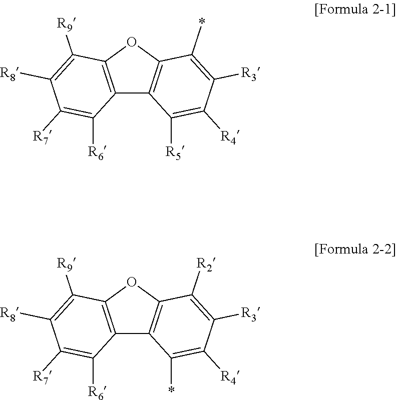
wherein in Formula 2-1 and Formula 2-2,
R₂′ to R₉′ are each independently a hydrogen atom, a deuterium atom, or a substituted or unsubstituted phenyl group, and
-* is a position linked to Formula 1.

6. The light emitting element of claim 1, wherein the first compound is represented by one of Formula 1-1 to Formula 1-3: 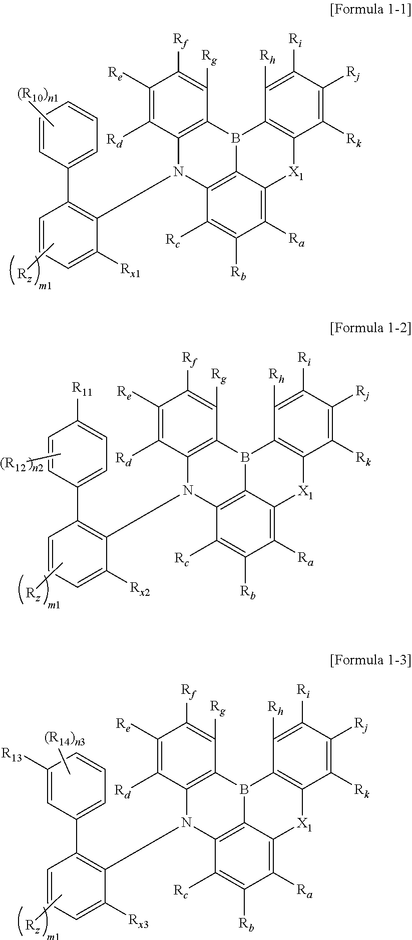
wherein in Formula 1-1 to Formula 1-3,
Rₓ₁ to Rₓ3 are each independently a group represented by Formula 2,
R₁₀, R₁₂, and R₁₄ are each independently a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₁₁ and R₁₃ are each independently a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n1 is an integer from 0 to 5,
n2 and n3 are each independently an integer from 0 to 4, and
Rₐ to Rₖ, R_{z}, m1, and X₁ are the same as defined in Formula 1.

7. The light emitting element of claim 1, wherein the first compound is represented by Formula 3: 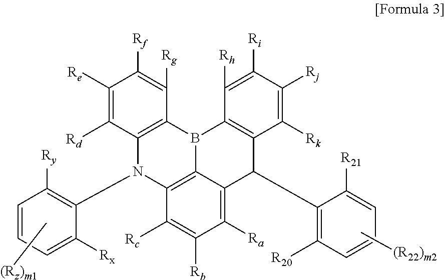
wherein in Formula 3,
R₂₀ and R₂₁ are each independently a substituted or unsubstituted aryl group having 6 to 30 ring-forming carbon atoms, a substituted or unsubstituted heteroaryl group having 2 to 30 ring-forming carbon atoms, or a group represented by Formula 2,
R₂₂ is a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or is bonded to an adjacent group to form a ring,
m2 is an integer from 0 to 3, and
Rₐ to Rₖ, Rₓ, R_{y}, R_{z}, and m1 are the same as defined in Formula 1.

8. The light emitting element of claim 7, wherein in Formula 3,
Rₓ and R₂₀ are the same, and
R_{y} and R₂₁ are the same.

9. The light emitting element of claim 1, wherein the first compound is represented by one of Formula 4-1 to Formula 4-3: 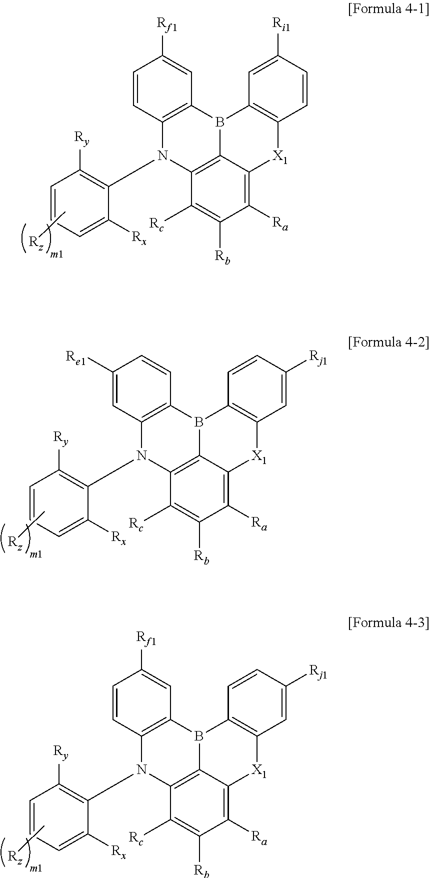
wherein in Formula 4-1 to Formula 4-3,
Rₑ₁, R_{f1}, Rᵢ₁, and Rⱼ₁ are each independently a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
Rₐ to R_{c}, X₁, Rₓ, R_{y}, R_{z}, and m1 are the same as defined in Formula 1.

10. The light emitting element of claim 1, wherein in Formula 1,
R_{d} to Rₖ are each independently a hydrogen atom, a deuterium atom, a substituted or unsubstituted phenyl group, a substituted or unsubstituted diphenylamine group, a substituted or unsubstituted carbazole group, a substituted or unsubstituted phenoxazine group, or a substituted or unsubstituted indolocarbazole group.

11. The light emitting element of claim 1, wherein the first compound is represented by Formula 5: 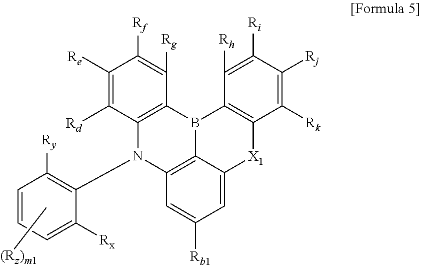
wherein in Formula 5,
R_{b1} is a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
R_{d} to Rₖ, X₁, Rₓ, R_{y}, R_{z}, and m1 are the same as defined in Formula 1.

12. The light emitting element of claim 1, wherein the first compound is represented by Formula 6: 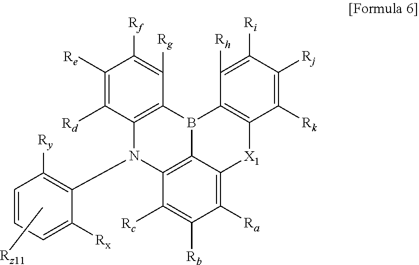
wherein in Formula 6,
R_{z11} is a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
Rₐ to Rₖ, X₁, Rₓ, and R_{y} are the same as defined in Formula 1.

13. The light emitting element of claim 1, wherein the first compound comprises at least one compound selected from Compound Group 1:

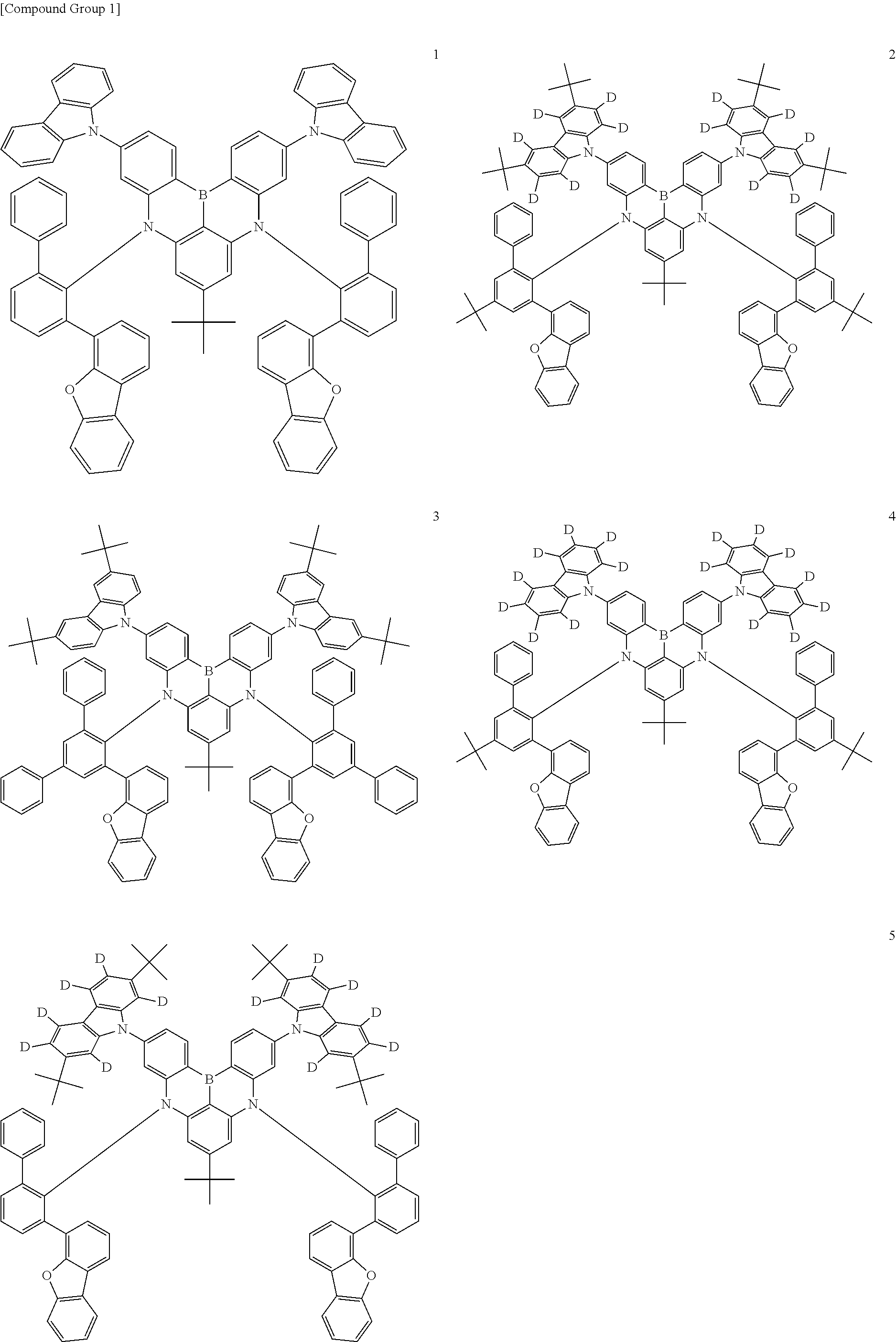

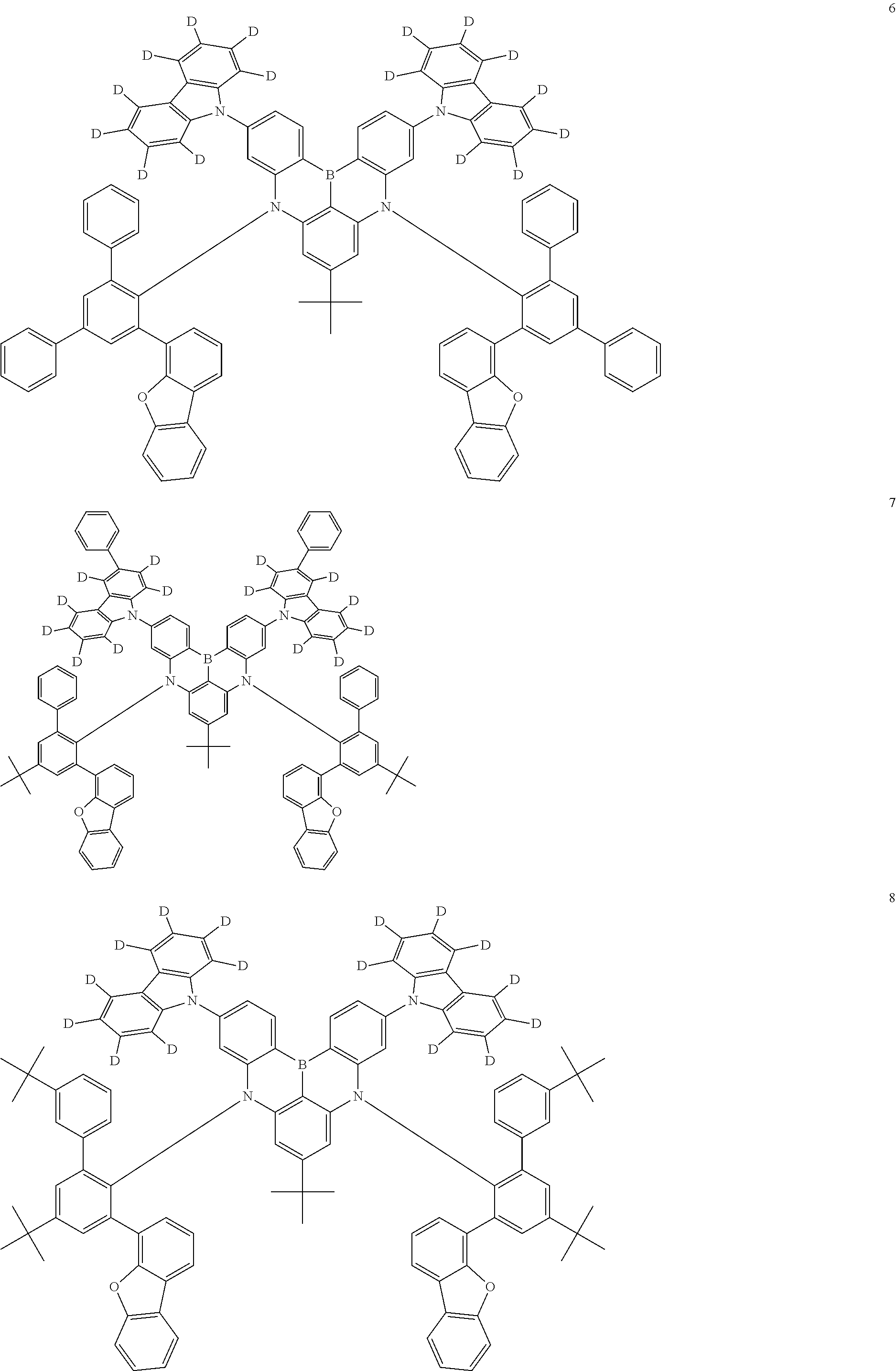

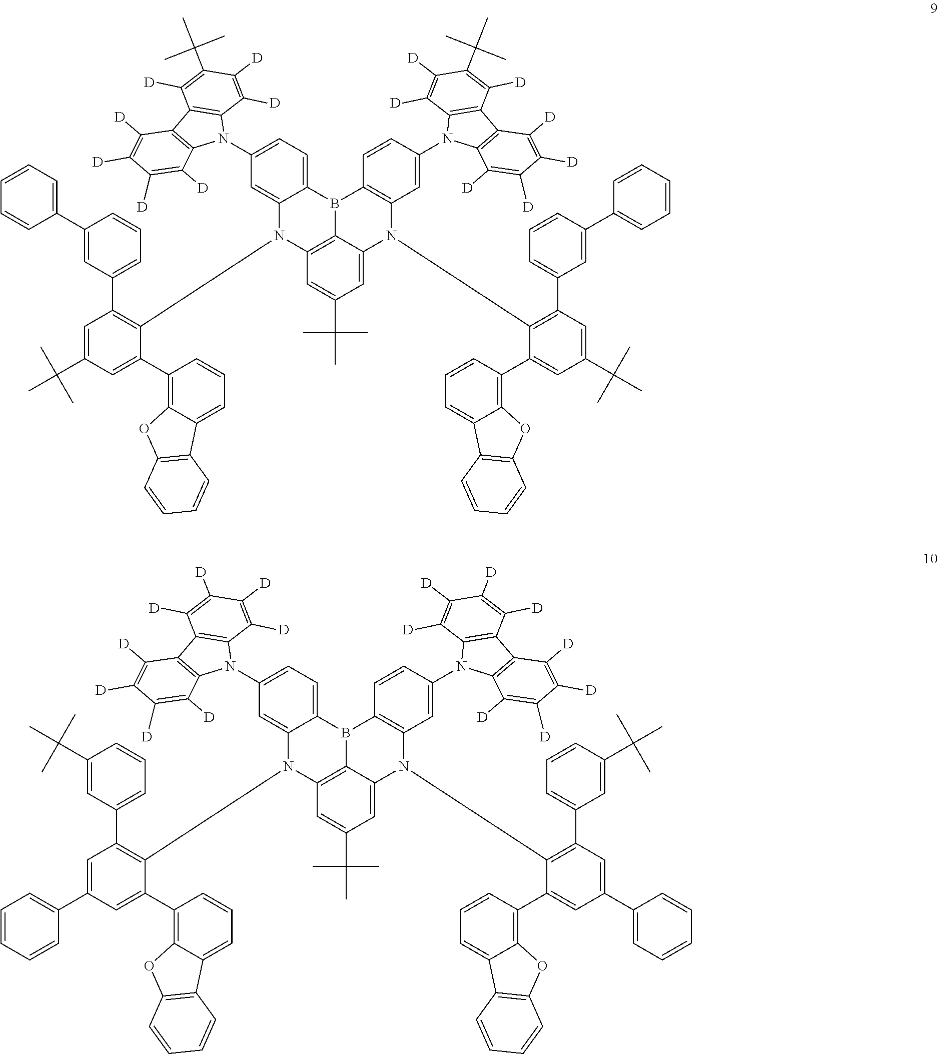

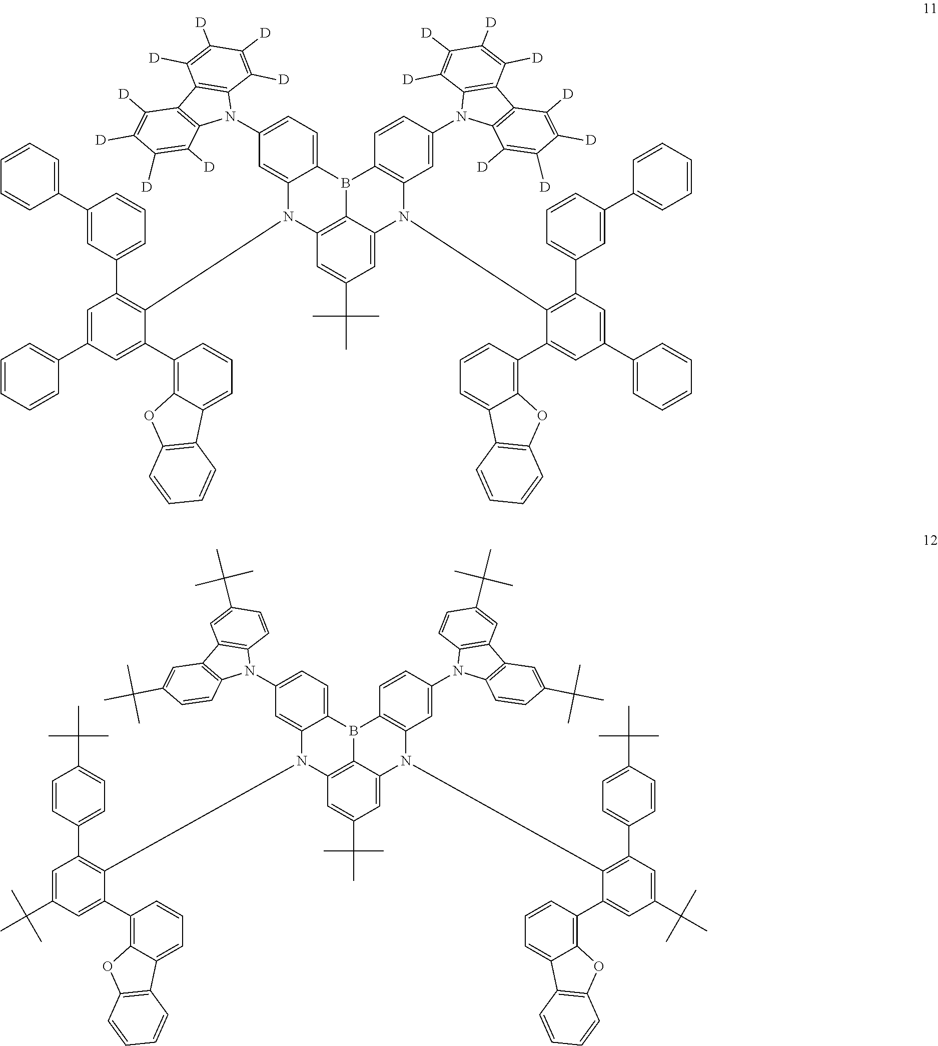

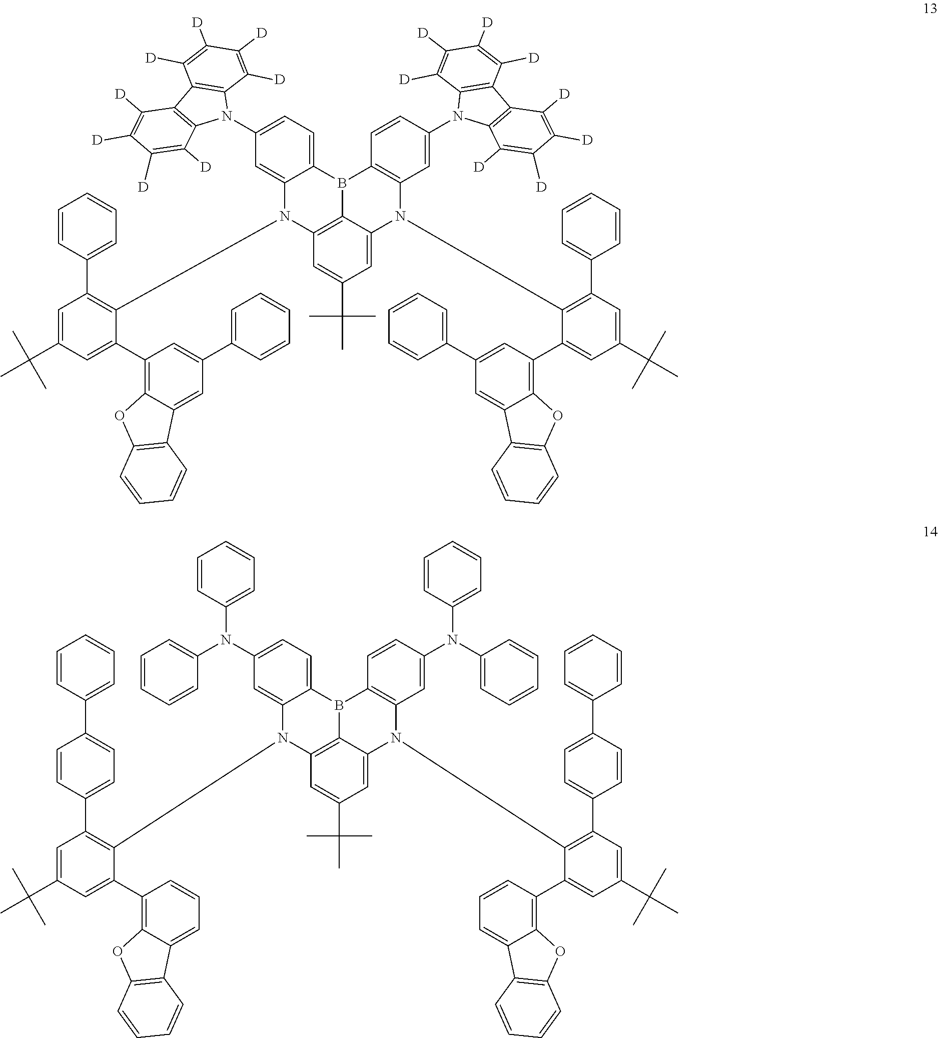

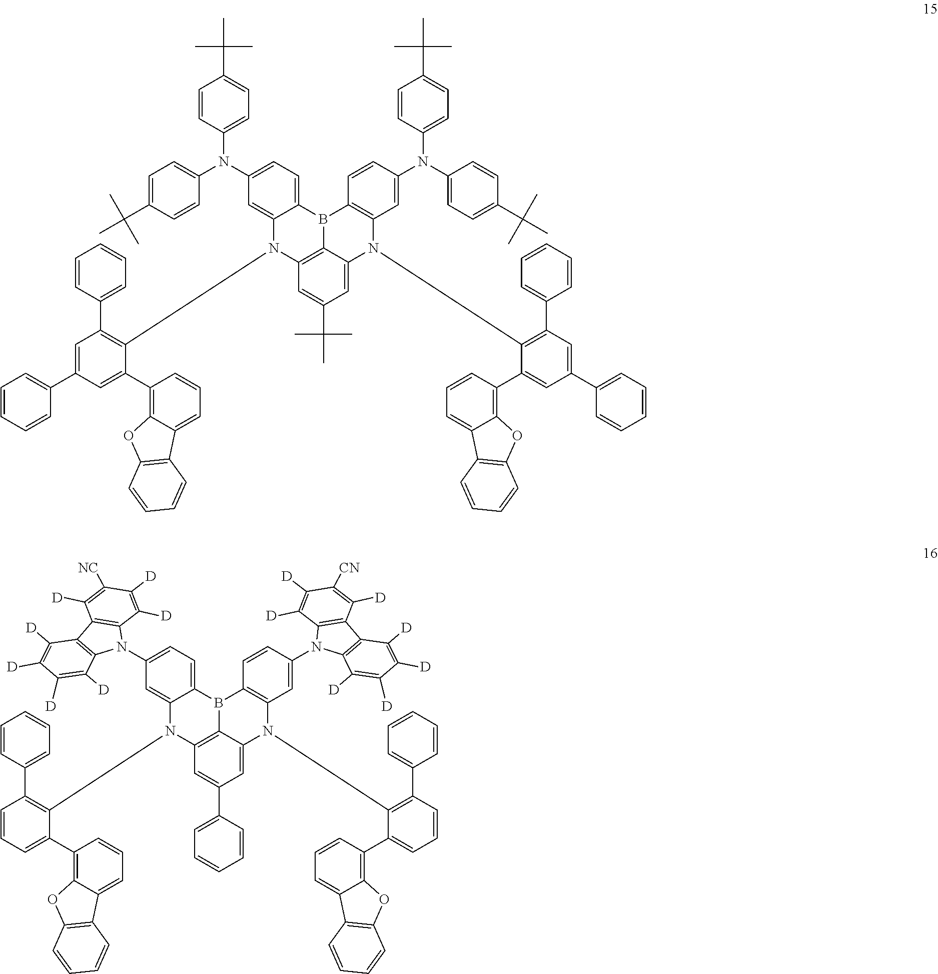 [SMILES: CC(C)(C)c1ccc(N(c2ccc(C(C)(C)C)cc2)c2ccc3c(c2)N(c2c(-c4ccccc4)cc(-c4ccccc4)cc2-c2cccc4c2oc2ccccc24)c2cc(C(C)(C)C)cc4c2B3c2ccc(N(c3ccc(C(C)(C)C)cc3)c3ccc(C(C)(C)C)cc3)cc2N4c2c(-c3ccccc3)cc(-c3ccccc3)cc2-c2cccc3c2oc2ccccc23)cc1 ; [2H]c1c([2H])c([2H])c2c(c1[2H])c1c([2H])c(C#N)c([2H])c([2H])c1n2-c1ccc2c(c1)N(c1c(-c3ccccc3)cccc1-c1cccc3c1oc1ccccc13)c1cc(-c3ccccc3)cc3c1B2c1ccc(-n2c4c([2H])c([2H])c([2H])c([2H])c4c4c([2H])c(C#N)c([2H])c([2H])c42)cc1N3c1c(-c2ccccc2)cccc1-c1cccc2c1oc1ccccc12]

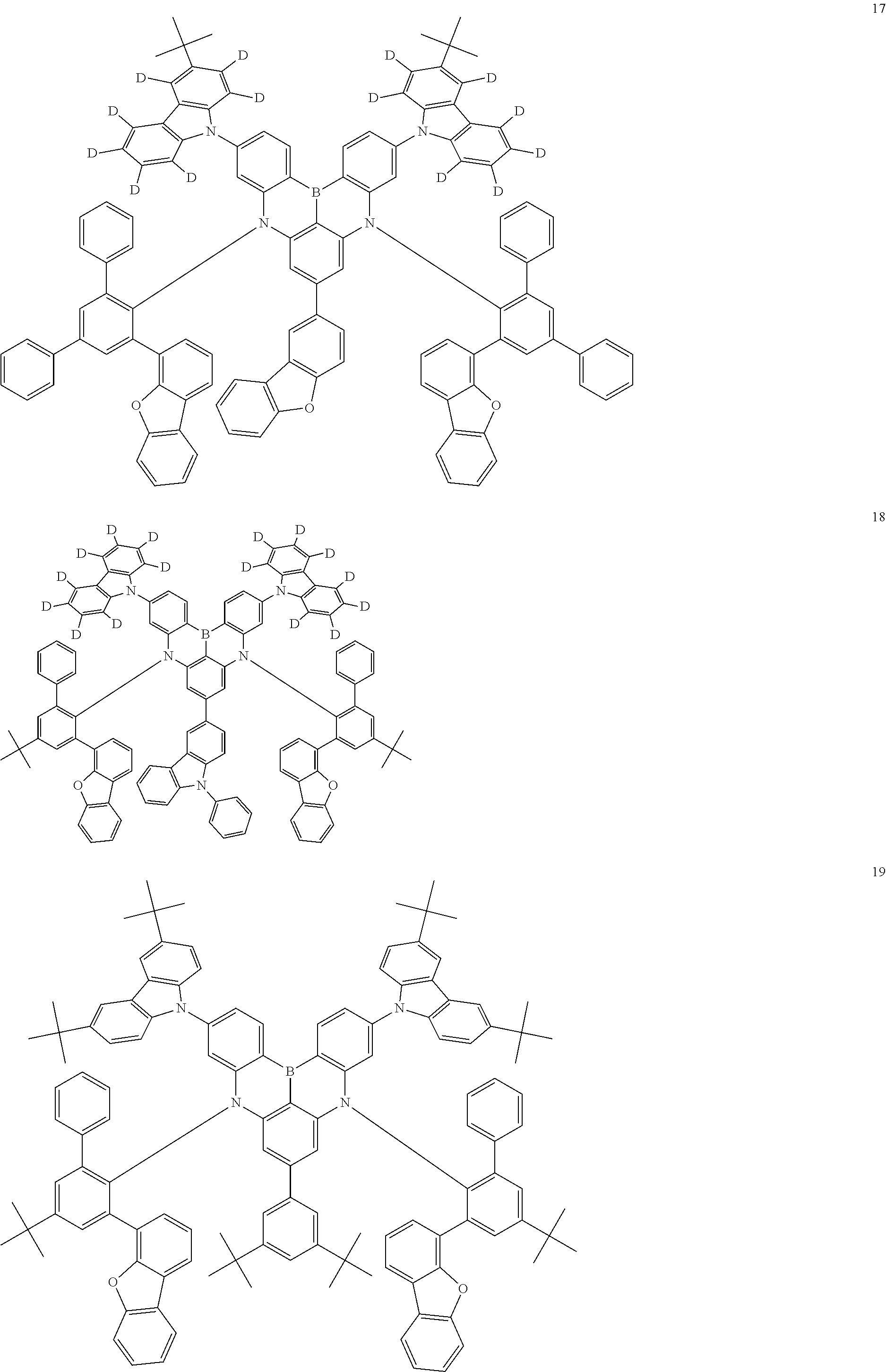

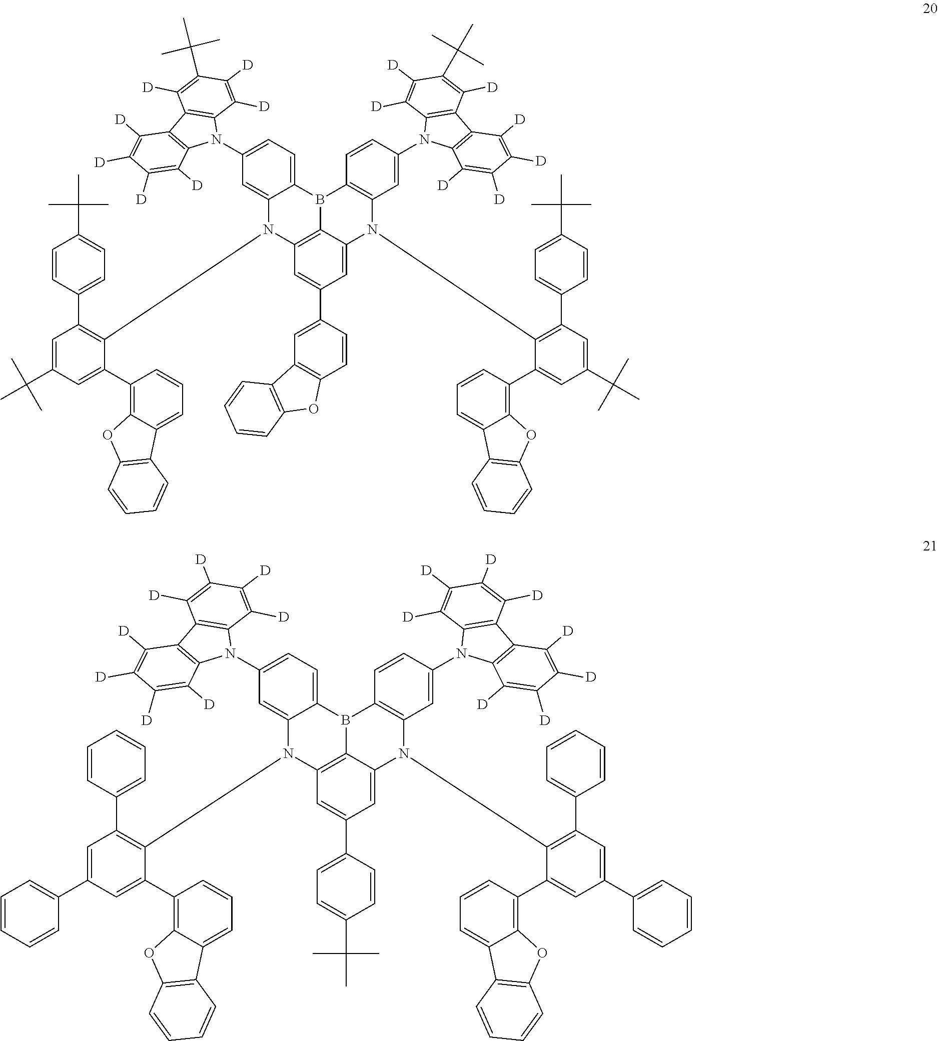

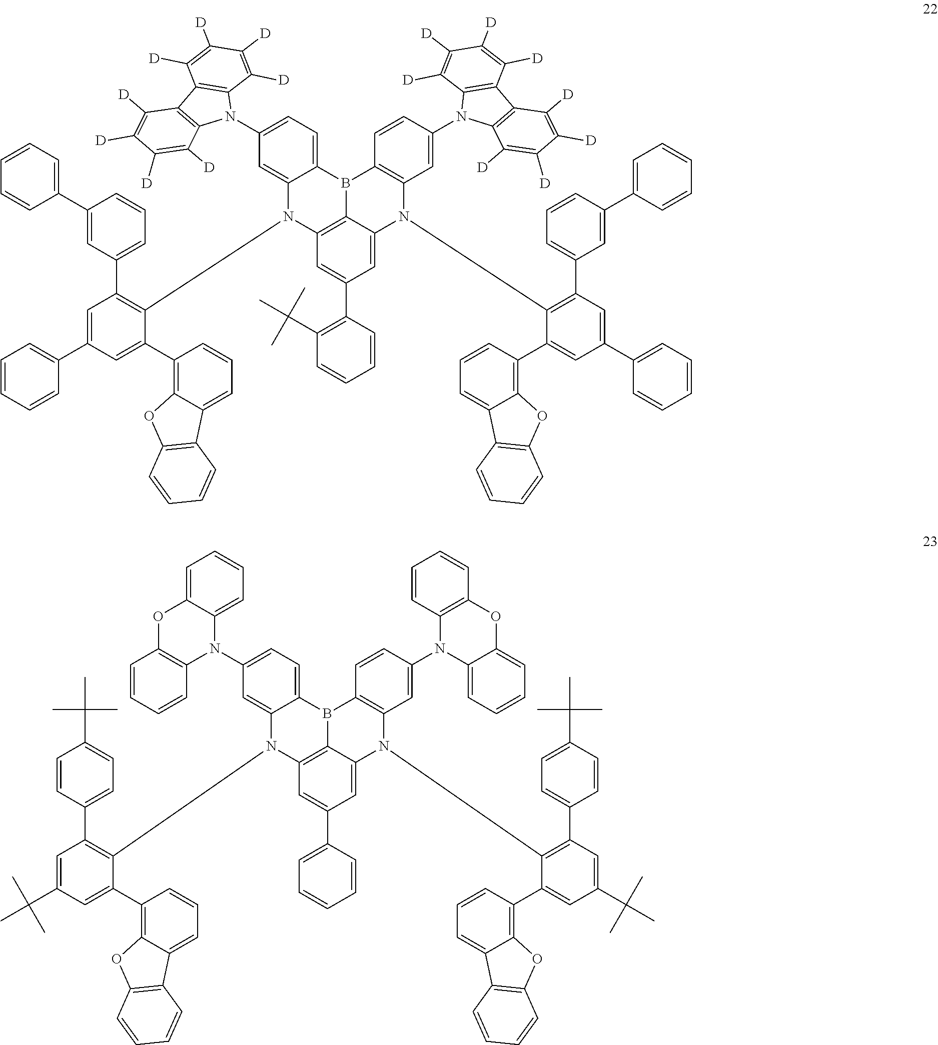

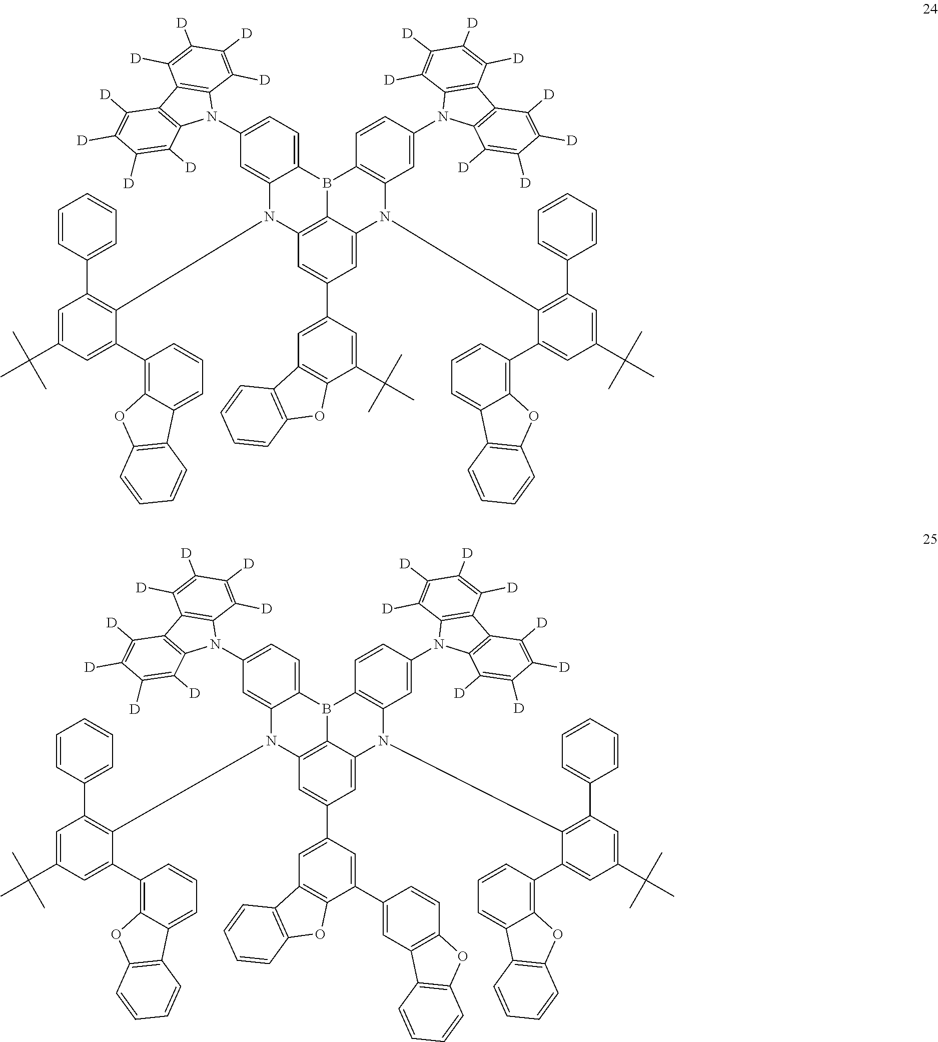

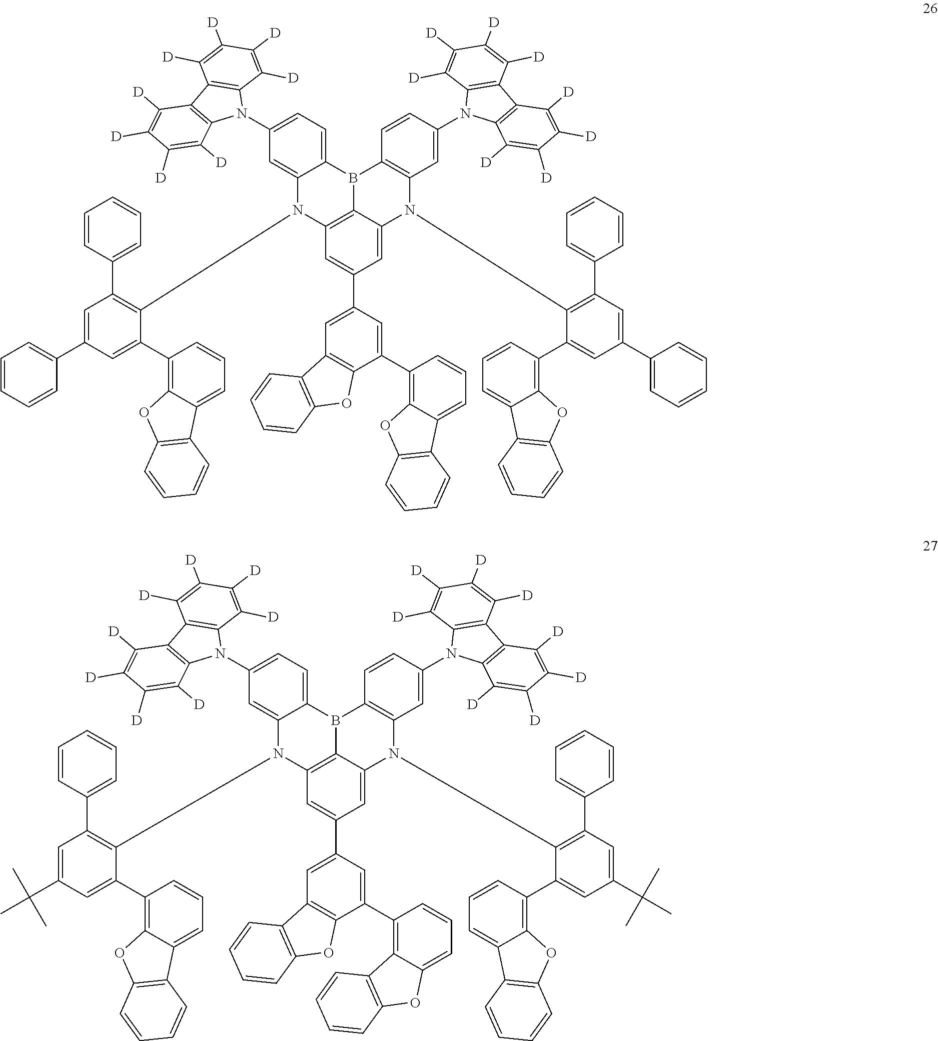

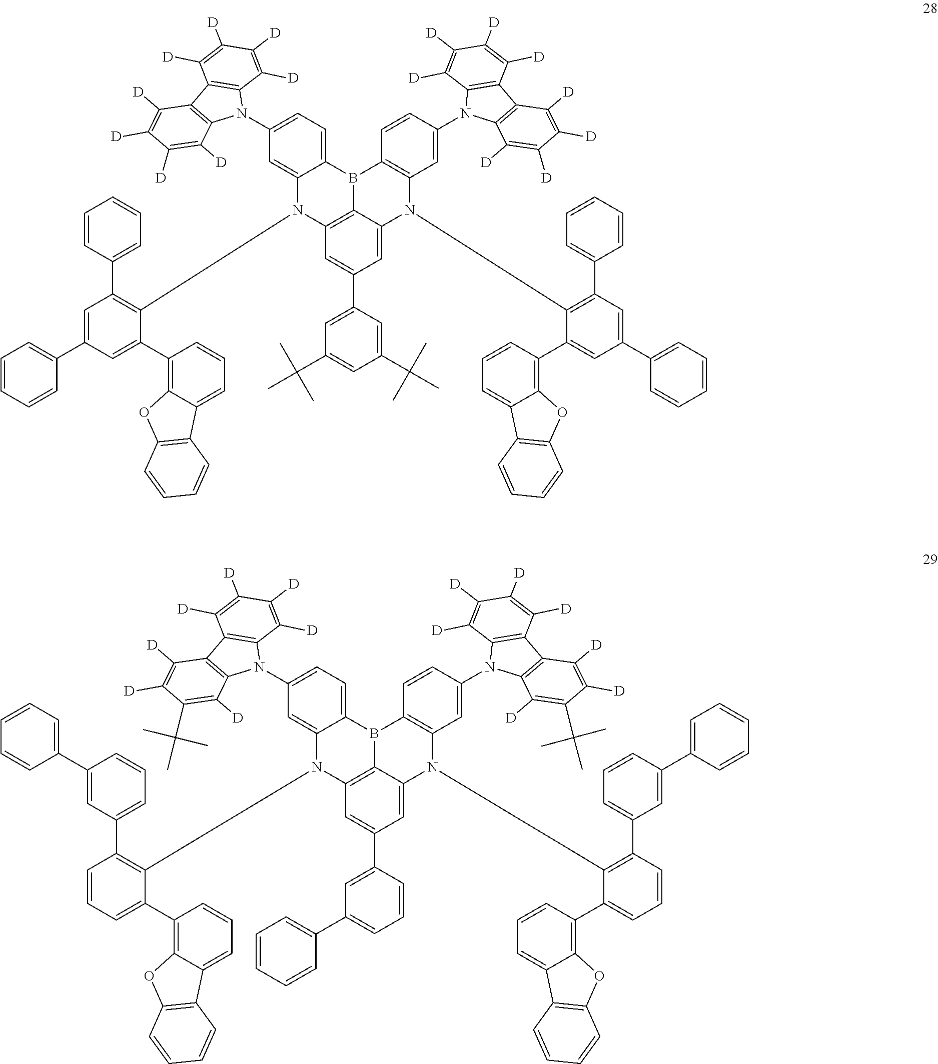

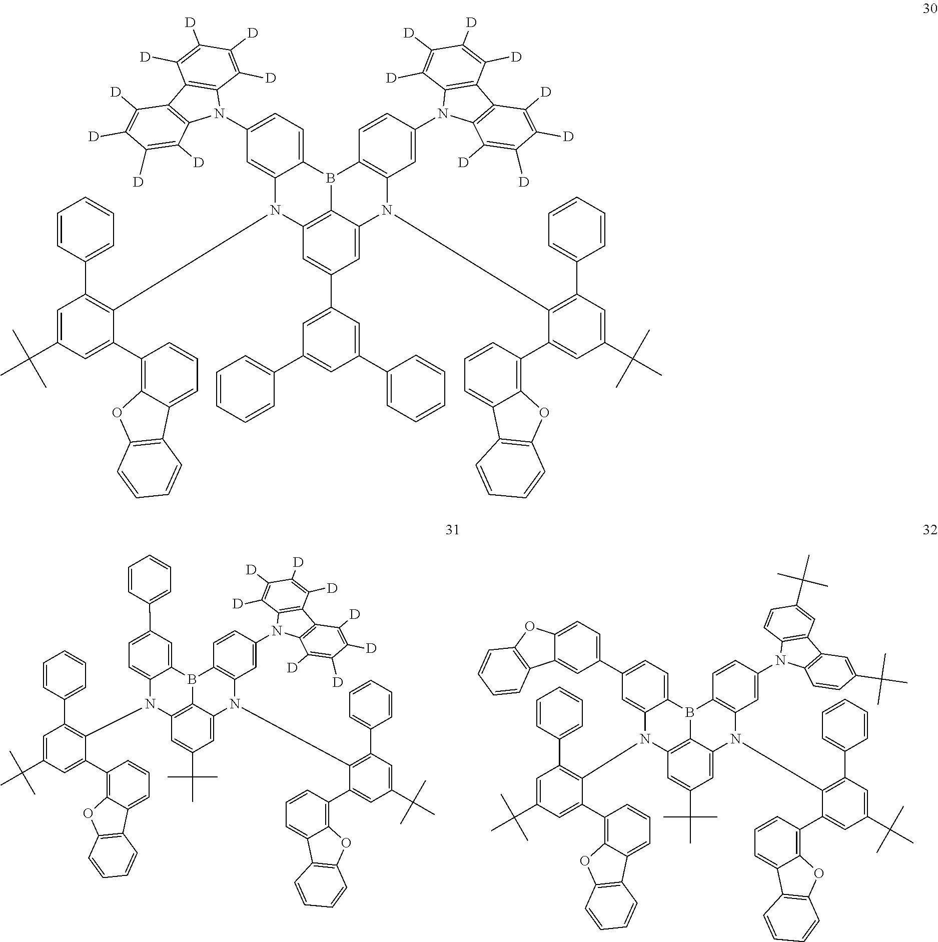

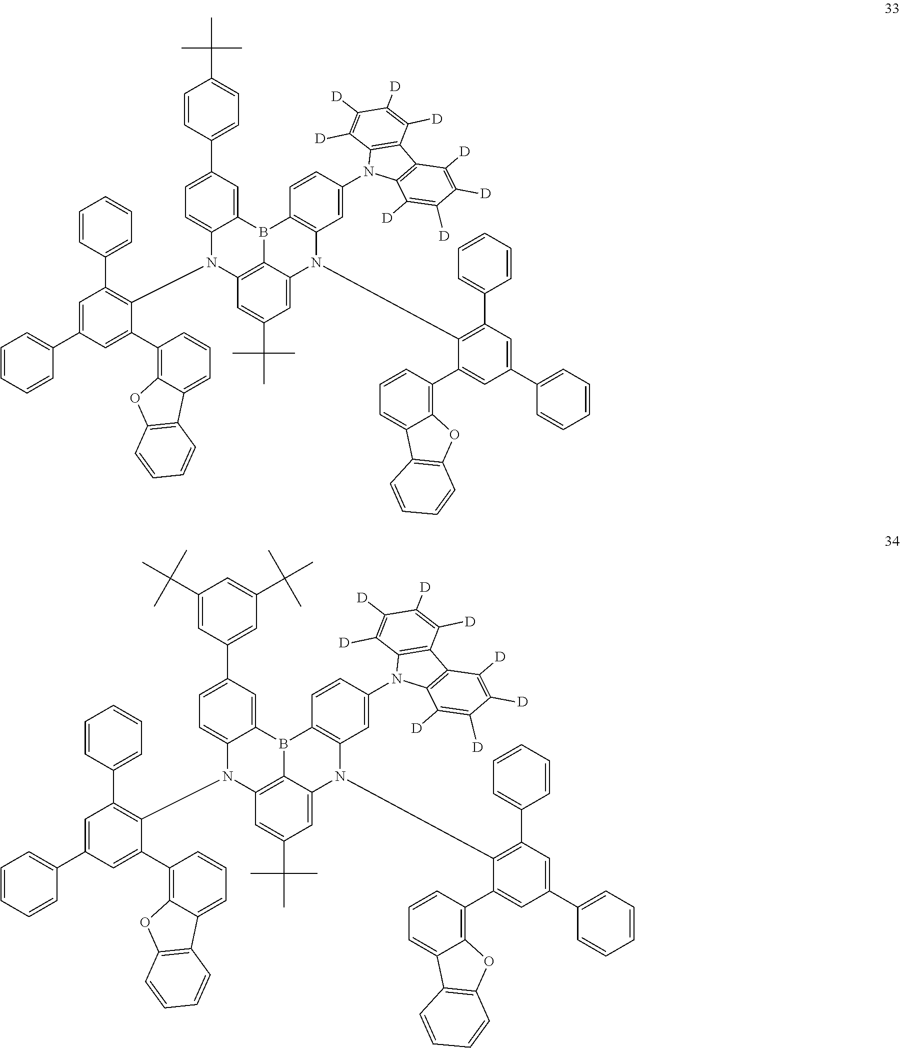 [SMILES: [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3c1oc1ccccc13)c1cc(C(C)(C)C)cc3c1B2c1cc(-c2ccc(C(C)(C)C)cc2)ccc1N3c1c(-c2ccccc2)cc(-c2ccccc2)cc1-c1cccc2c1oc1ccccc12 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3c1oc1ccccc13)c1cc(C(C)(C)C)cc3c1B2c1cc(-c2cc(C(C)(C)C)cc(C(C)(C)C)c2)ccc1N3c1c(-c2ccccc2)cc(-c2ccccc2)cc1-c1cccc2c1oc1ccccc12]

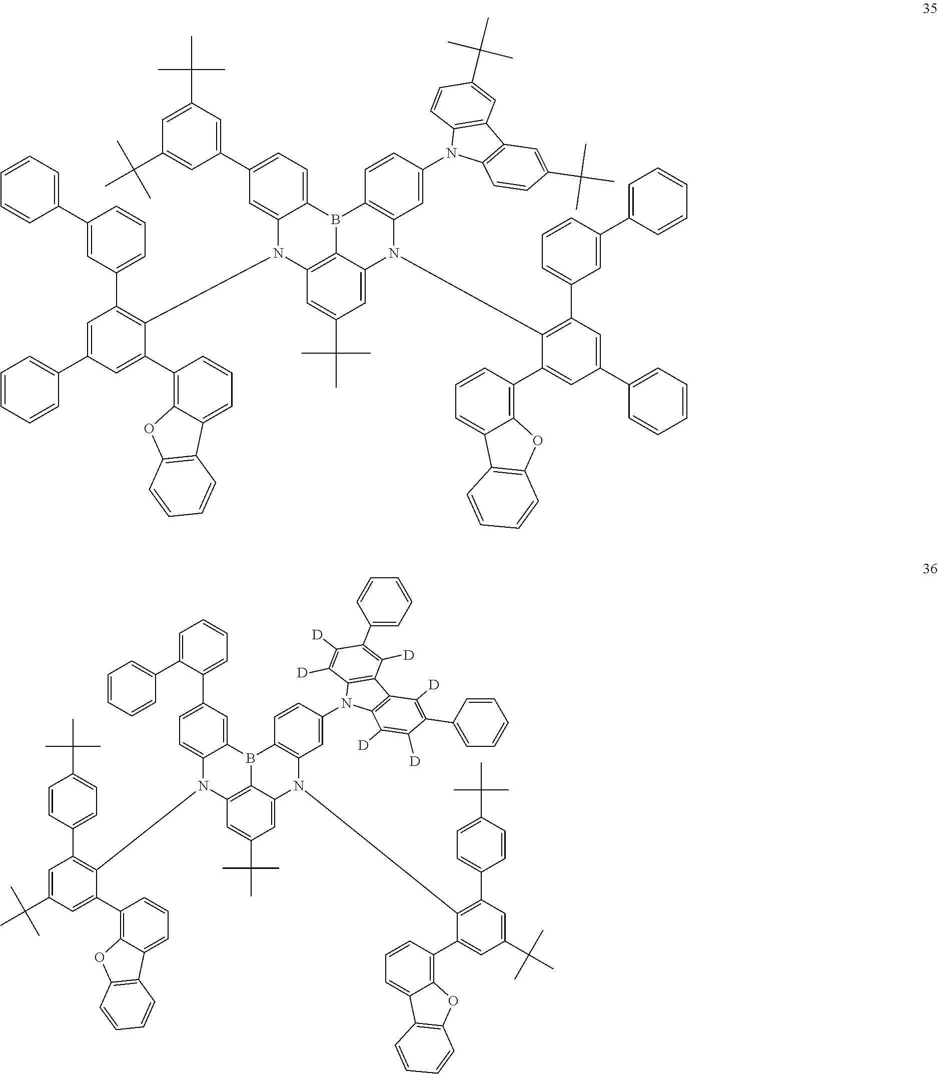 [SMILES: CC(C)(C)c1cc(-c2ccc3c(c2)N(c2c(-c4cccc(-c5ccccc5)c4)cc(-c4ccccc4)cc2-c2cccc4c2oc2ccccc24)c2cc(C(C)(C)C)cc4c2B3c2ccc(-n3c5ccc(C(C)(C)C)cc5c5cc(C(C)(C)C)ccc53)cc2N4c2c(-c3cccc(-c4ccccc4)c3)cc(-c3ccccc3)cc2-c2cccc3c2oc2ccccc23)cc(C(C)(C)C)c1 ; [2H]c1c(-c2ccccc2)c([2H])c2c3c([2H])c(-c4ccccc4)c([2H])c([2H])c3n(-c3ccc4c(c3)N(c3c(-c5ccc(C(C)(C)C)cc5)cc(C(C)(C)C)cc3-c3cccc5c3oc3ccccc35)c3cc(C(C)(C)C)cc5c3B4c3cc(-c4ccccc4-c4ccccc4)ccc3N5c3c(-c4ccc(C(C)(C)C)cc4)cc(C(C)(C)C)cc3-c3cccc4c3oc3ccccc34)c2c1[2H]]

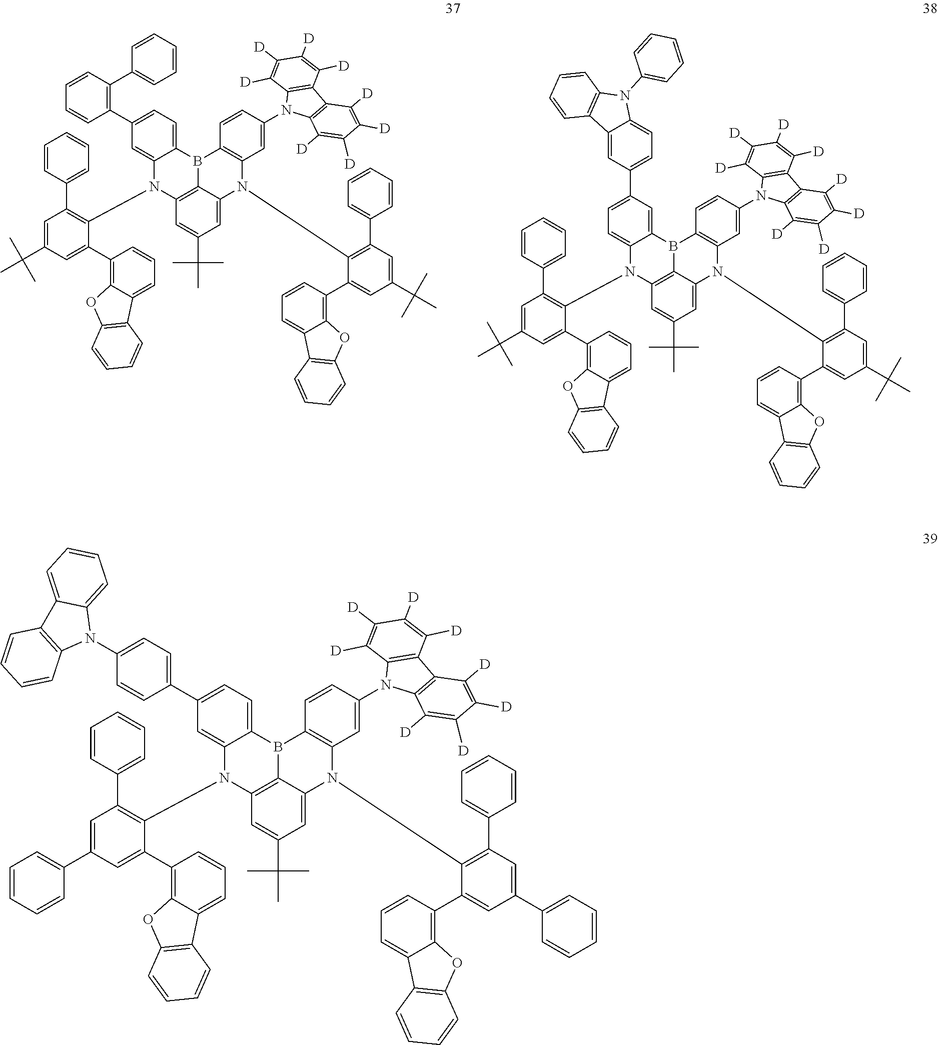

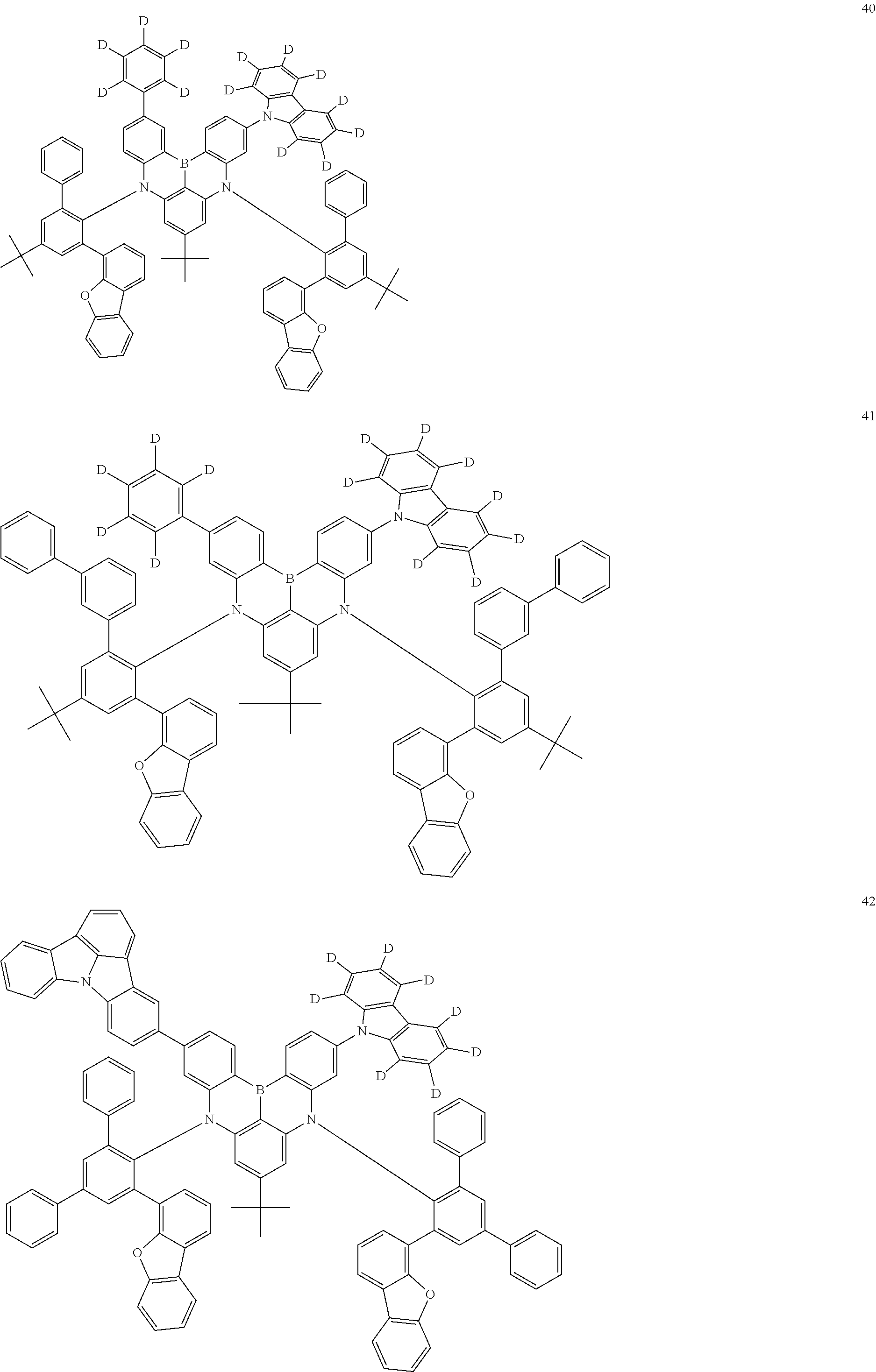

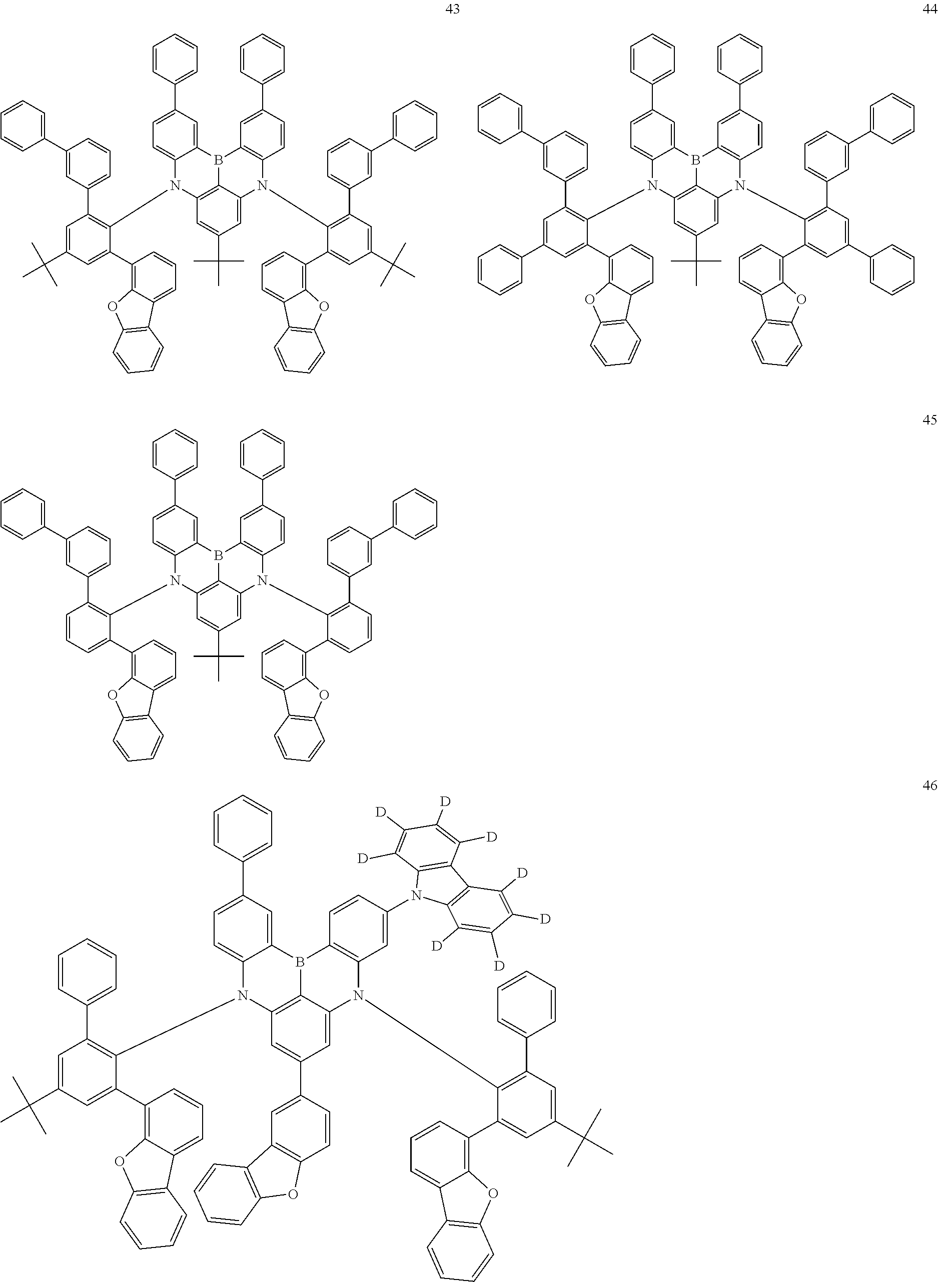

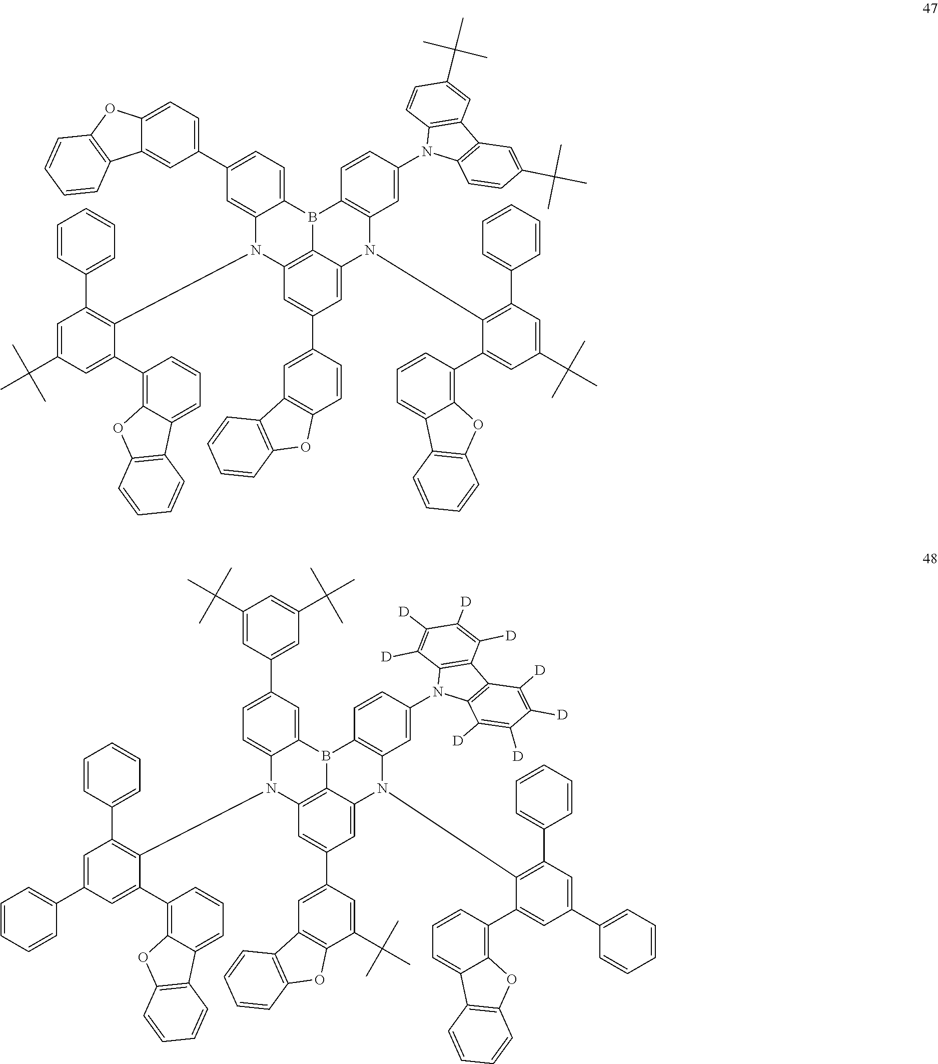 [SMILES: CC(C)(C)c1cc(-c2ccccc2)c(N2c3cc(-c4ccc5oc6ccccc6c5c4)ccc3B3c4ccc(-n5c6ccc(C(C)(C)C)cc6c6cc(C(C)(C)C)ccc65)cc4N(c4c(-c5ccccc5)cc(C(C)(C)C)cc4-c4cccc5c4oc4ccccc45)c4cc(-c5ccc6oc7ccccc7c6c5)cc2c43)c(-c2cccc3c2oc2ccccc23)c1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3c1oc1ccccc13)c1cc(-c3cc(C(C)(C)C)c4oc5ccccc5c4c3)cc3c1B2c1cc(-c2cc(C(C)(C)C)cc(C(C)(C)C)c2)ccc1N3c1c(-c2ccccc2)cc(-c2ccccc2)cc1-c1cccc2c1oc1ccccc12]

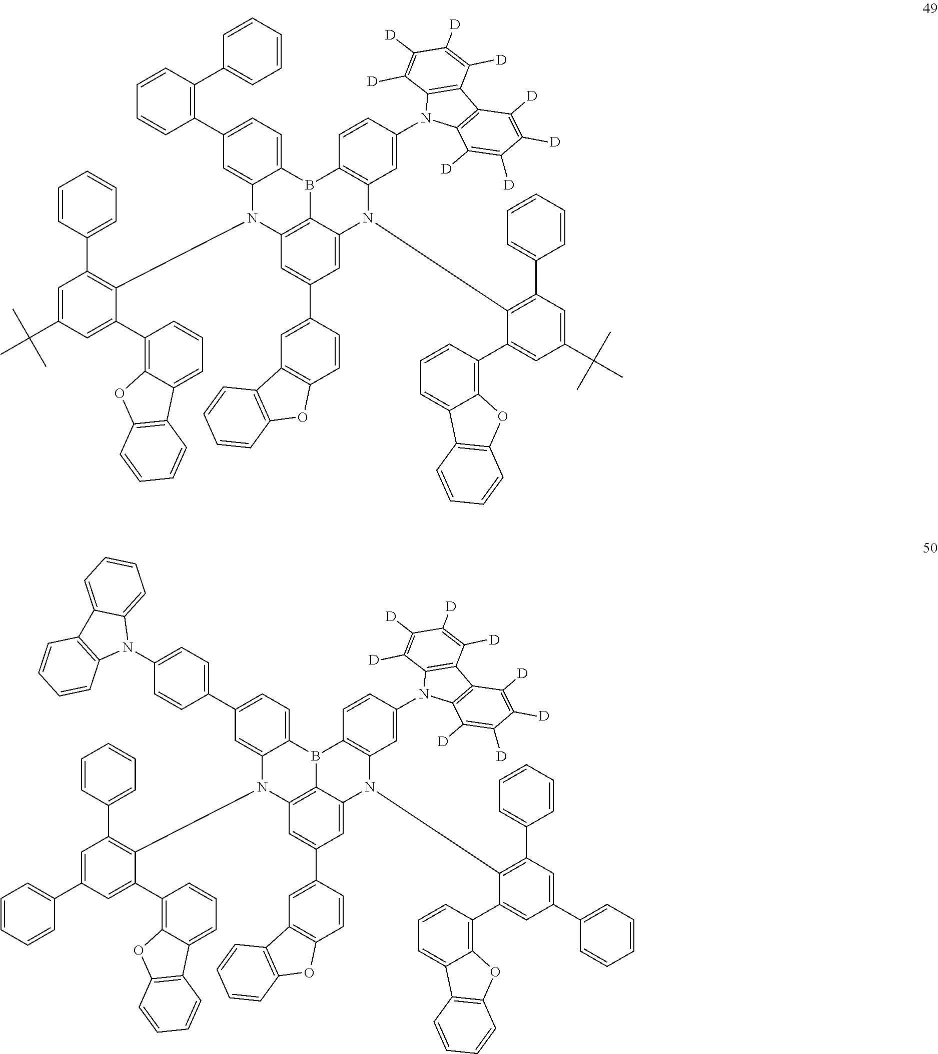 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc3c1oc1ccccc13)c1cc(-c3ccc4oc5ccccc5c4c3)cc3c1B2c1ccc(-c2ccccc2-c2ccccc2)cc1N3c1c(-c2ccccc2)cc(C(C)(C)C)cc1-c1cccc2c1oc1ccccc12 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3c1oc1ccccc13)c1cc(-c3ccc4oc5ccccc5c4c3)cc3c1B2c1ccc(-c2ccc(-n4c5ccccc5c5ccccc54)cc2)cc1N3c1c(-c2ccccc2)cc(-c2ccccc2)cc1-c1cccc2c1oc1ccccc12]

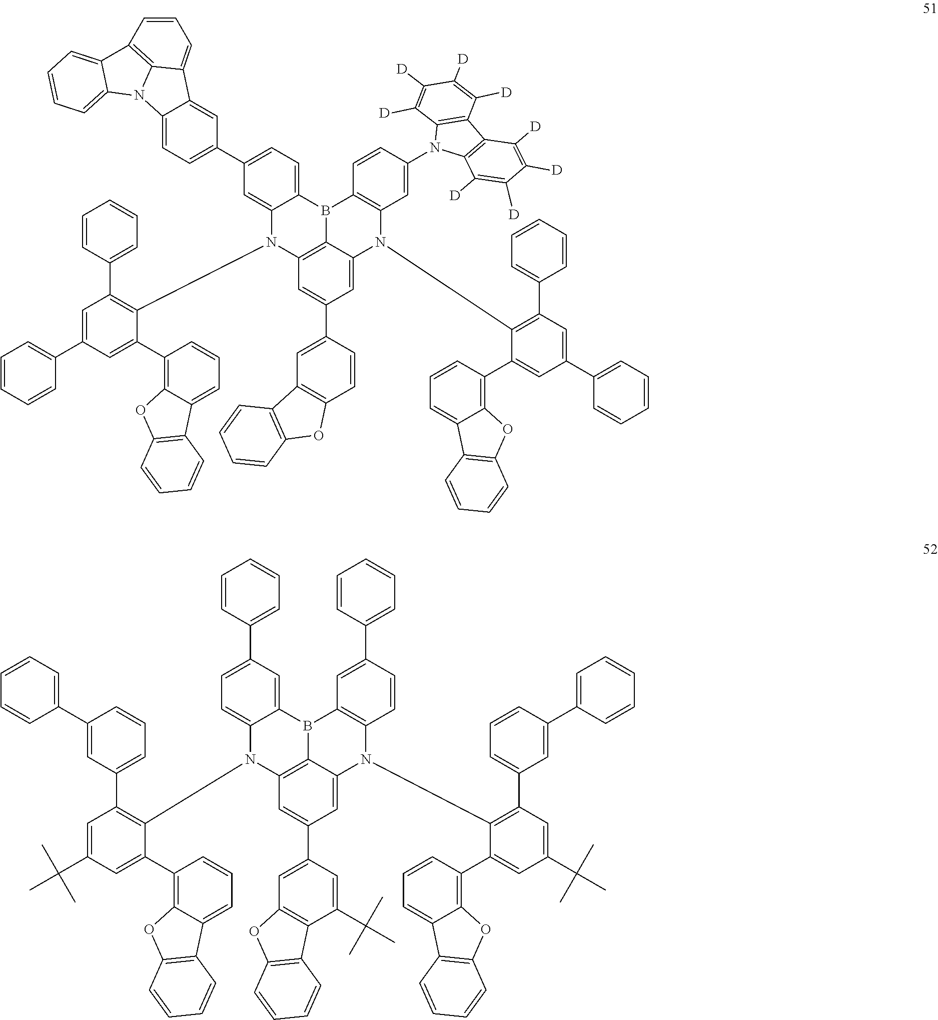 [SMILES: [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3c1oc1ccccc13)c1cc(-c3ccc4oc5ccccc5c4c3)cc3c1B2c1ccc(-c2ccc4c(c2)c2cccc5c6ccccc6n4c52)cc1N3c1c(-c2ccccc2)cc(-c2ccccc2)cc1-c1cccc2c1oc1ccccc12 ; CC(C)(C)c1cc(-c2cccc(-c3ccccc3)c2)c(N2c3ccc(-c4ccccc4)cc3B3c4cc(-c5ccccc5)ccc4N(c4c(-c5cccc(-c6ccccc6)c5)cc(C(C)(C)C)cc4-c4cccc5c4oc4ccccc45)c4cc(-c5cc(C(C)(C)C)c6c(c5)oc5ccccc56)cc2c43)c(-c2cccc3c2oc2ccccc23)c1]

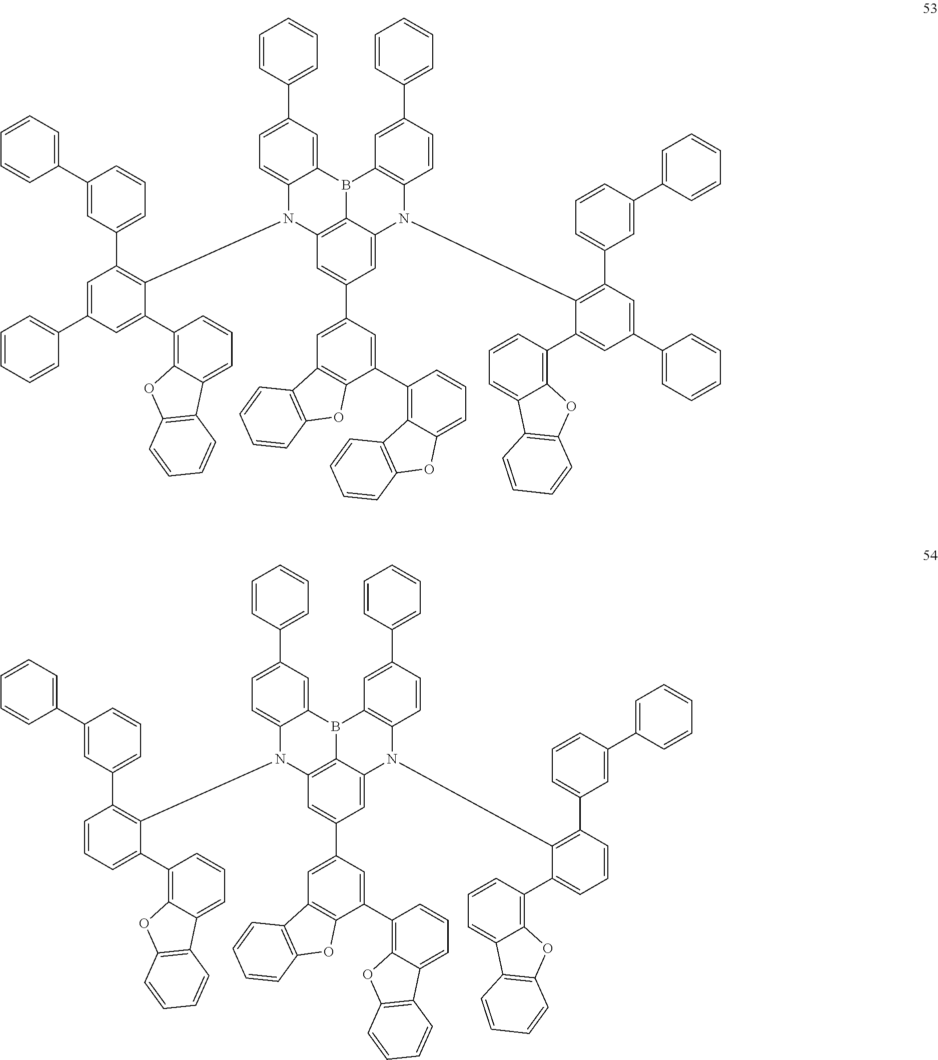 [SMILES: c1ccc(-c2cccc(-c3cc(-c4ccccc4)cc(-c4cccc5c4oc4ccccc45)c3N3c4ccc(-c5ccccc5)cc4B4c5cc(-c6ccccc6)ccc5N(c5c(-c6cccc(-c7ccccc7)c6)cc(-c6ccccc6)cc5-c5cccc6c5oc5ccccc56)c5cc(-c6cc(-c7cccc8oc9ccccc9c78)c7oc8ccccc8c7c6)cc3c54)c2)cc1 ; c1ccc(-c2cccc(-c3cccc(-c4cccc5c4oc4ccccc45)c3N3c4ccc(-c5ccccc5)cc4B4c5cc(-c6ccccc6)ccc5N(c5c(-c6cccc(-c7ccccc7)c6)cccc5-c5cccc6c5oc5ccccc56)c5cc(-c6cc(-c7cccc8c7oc7ccccc78)c7oc8ccccc8c7c6)cc3c54)c2)cc1]

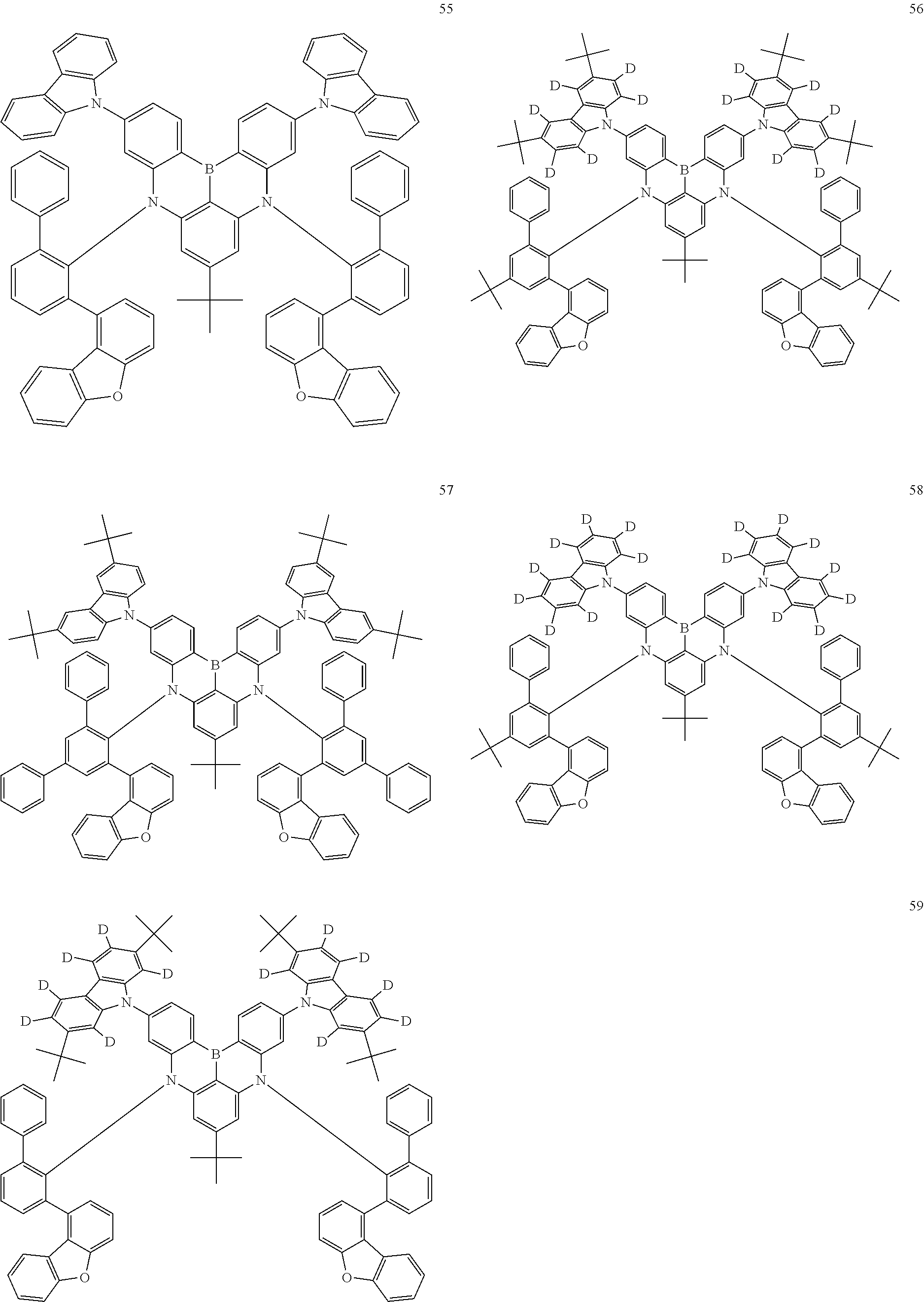

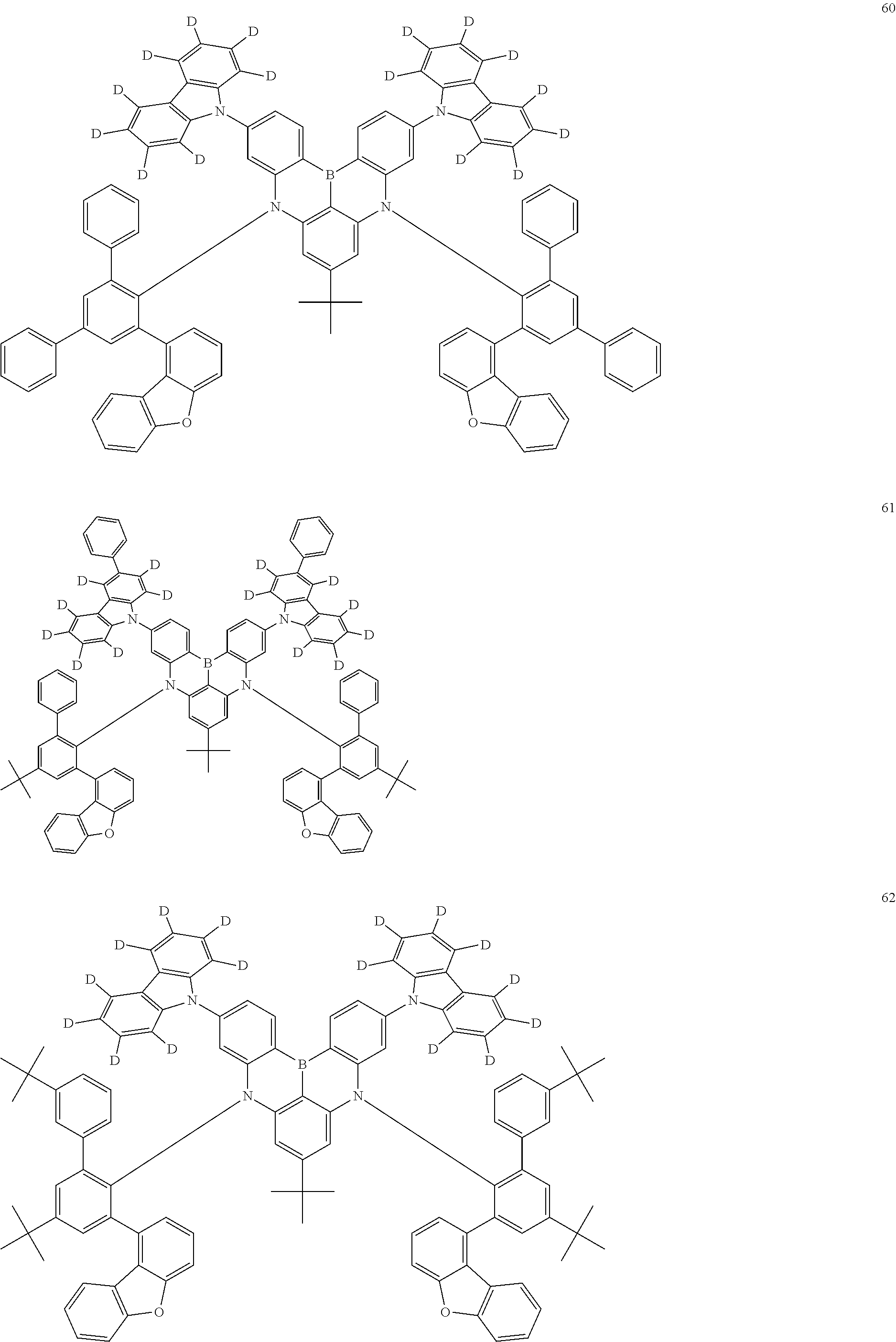

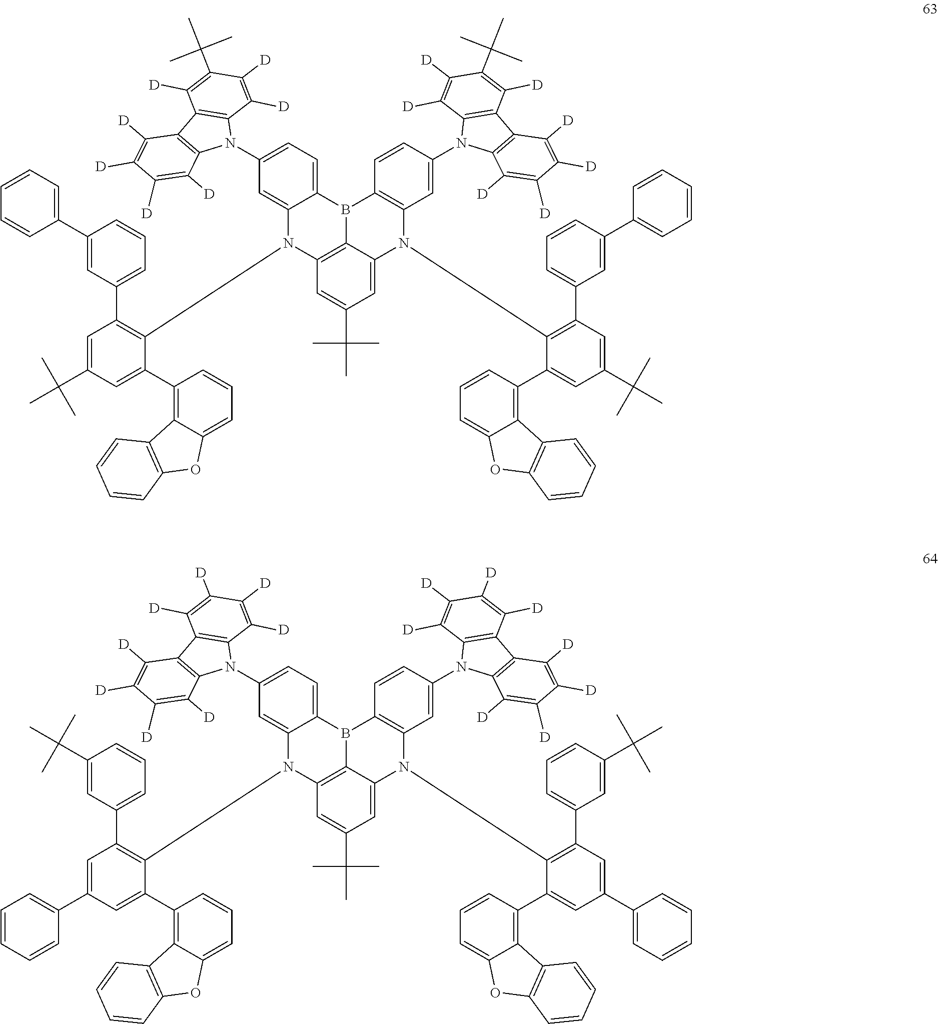

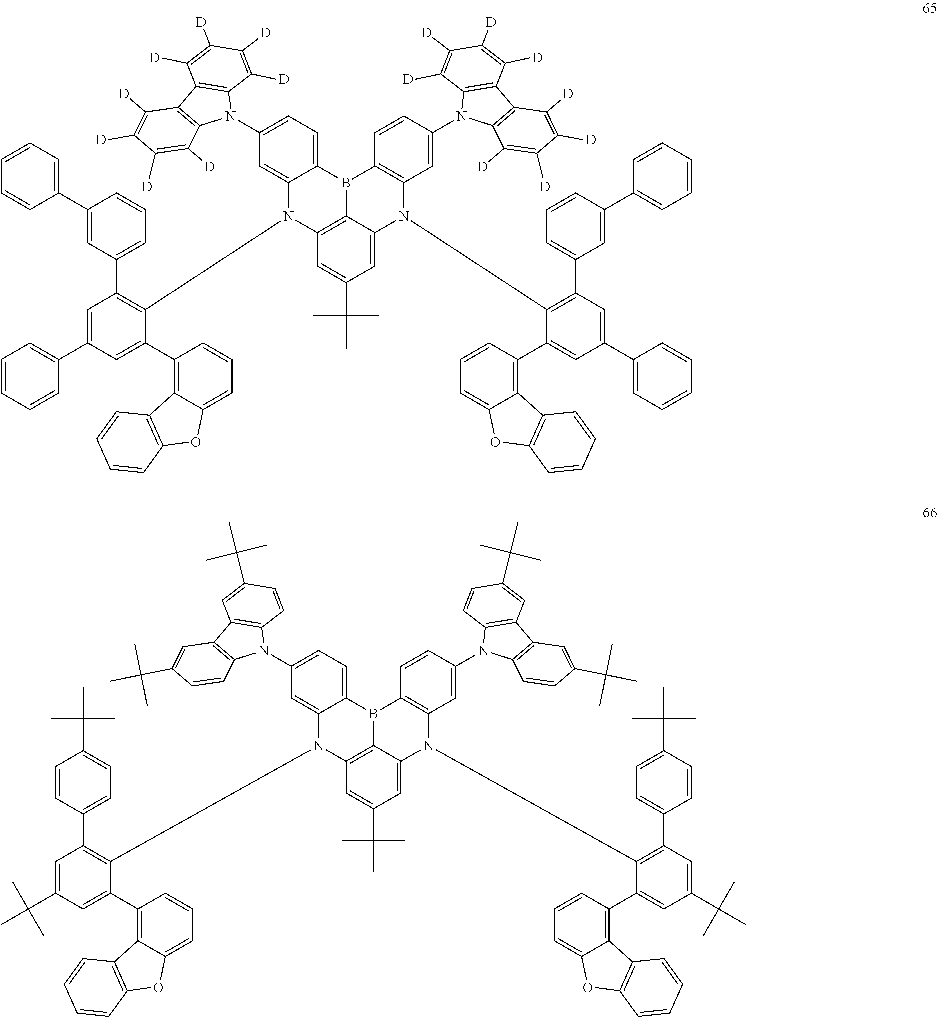

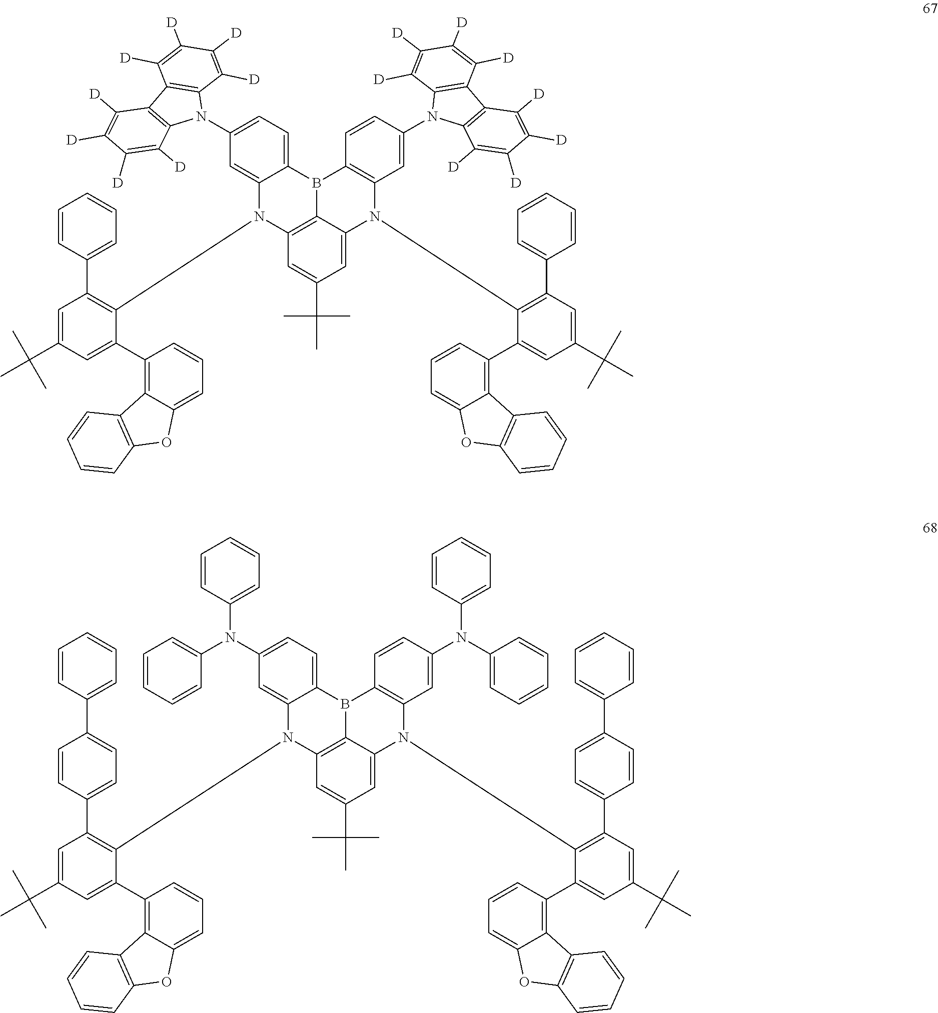

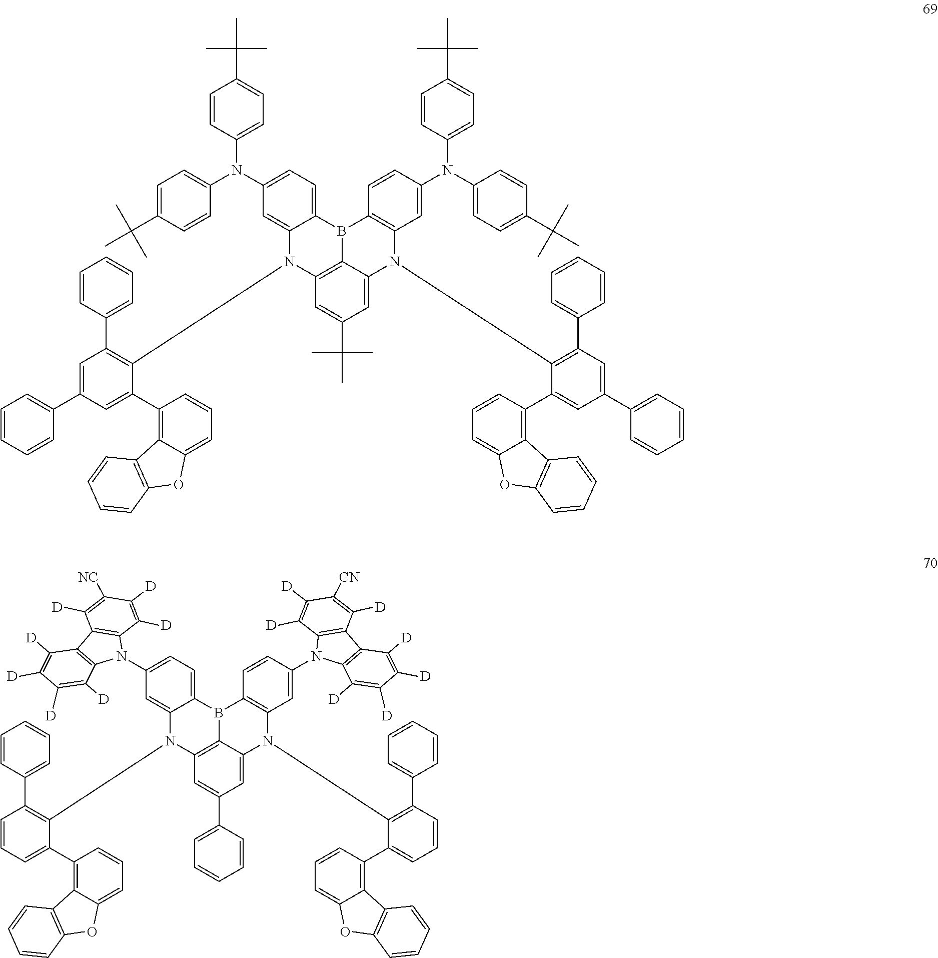 [SMILES: CC(C)(C)c1ccc(N(c2ccc(C(C)(C)C)cc2)c2ccc3c(c2)N(c2c(-c4ccccc4)cc(-c4ccccc4)cc2-c2cccc4oc5ccccc5c24)c2cc(C(C)(C)C)cc4c2B3c2ccc(N(c3ccc(C(C)(C)C)cc3)c3ccc(C(C)(C)C)cc3)cc2N4c2c(-c3ccccc3)cc(-c3ccccc3)cc2-c2cccc3oc4ccccc4c23)cc1 ; [2H]c1c([2H])c([2H])c2c(c1[2H])c1c([2H])c(C#N)c([2H])c([2H])c1n2-c1ccc2c(c1)N(c1c(-c3ccccc3)cccc1-c1cccc3oc4ccccc4c13)c1cc(-c3ccccc3)cc3c1B2c1ccc(-n2c4c([2H])c([2H])c([2H])c([2H])c4c4c([2H])c(C#N)c([2H])c([2H])c42)cc1N3c1c(-c2ccccc2)cccc1-c1cccc2oc3ccccc3c12]

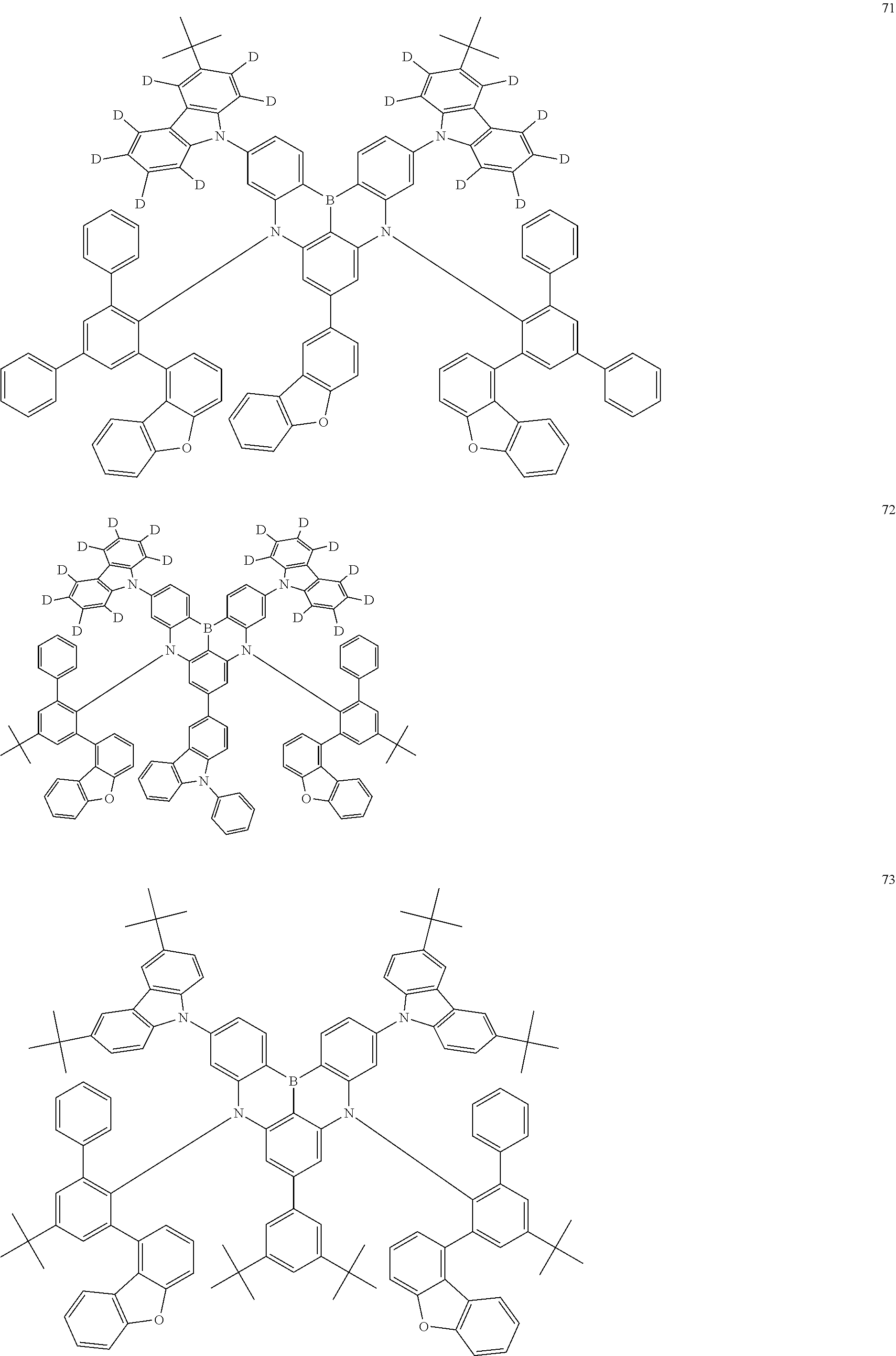

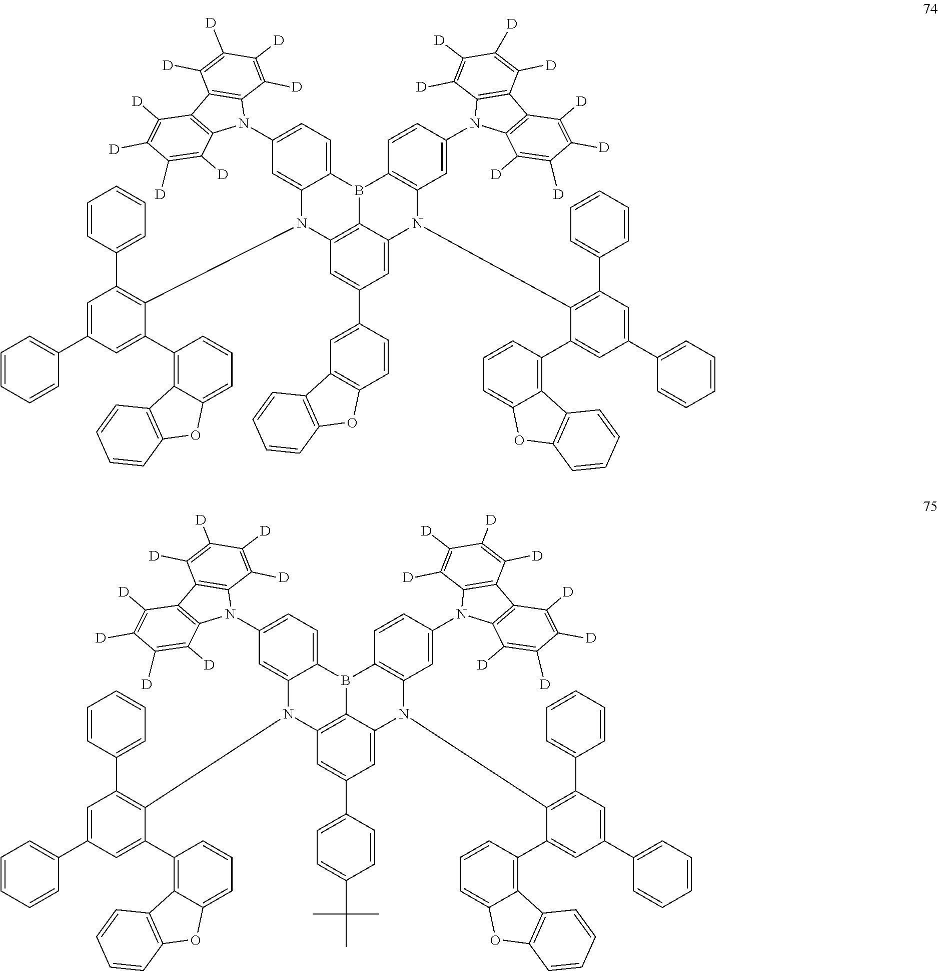

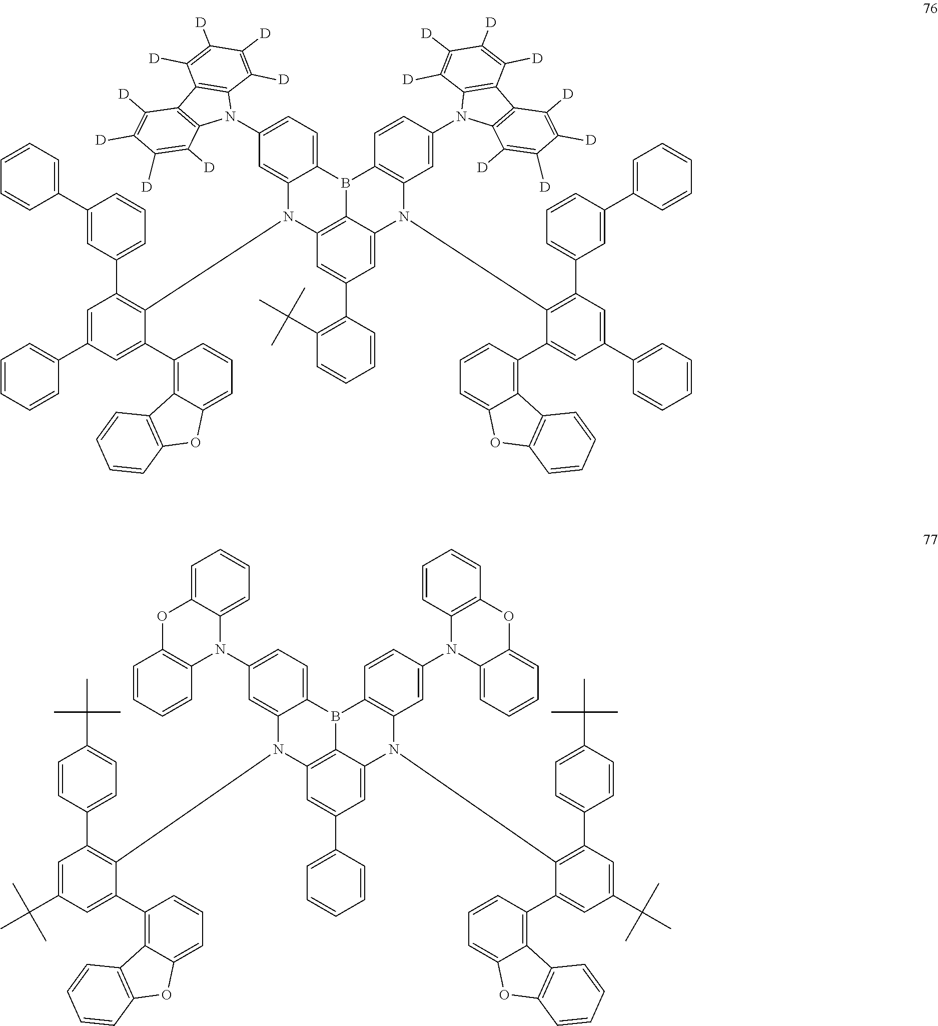

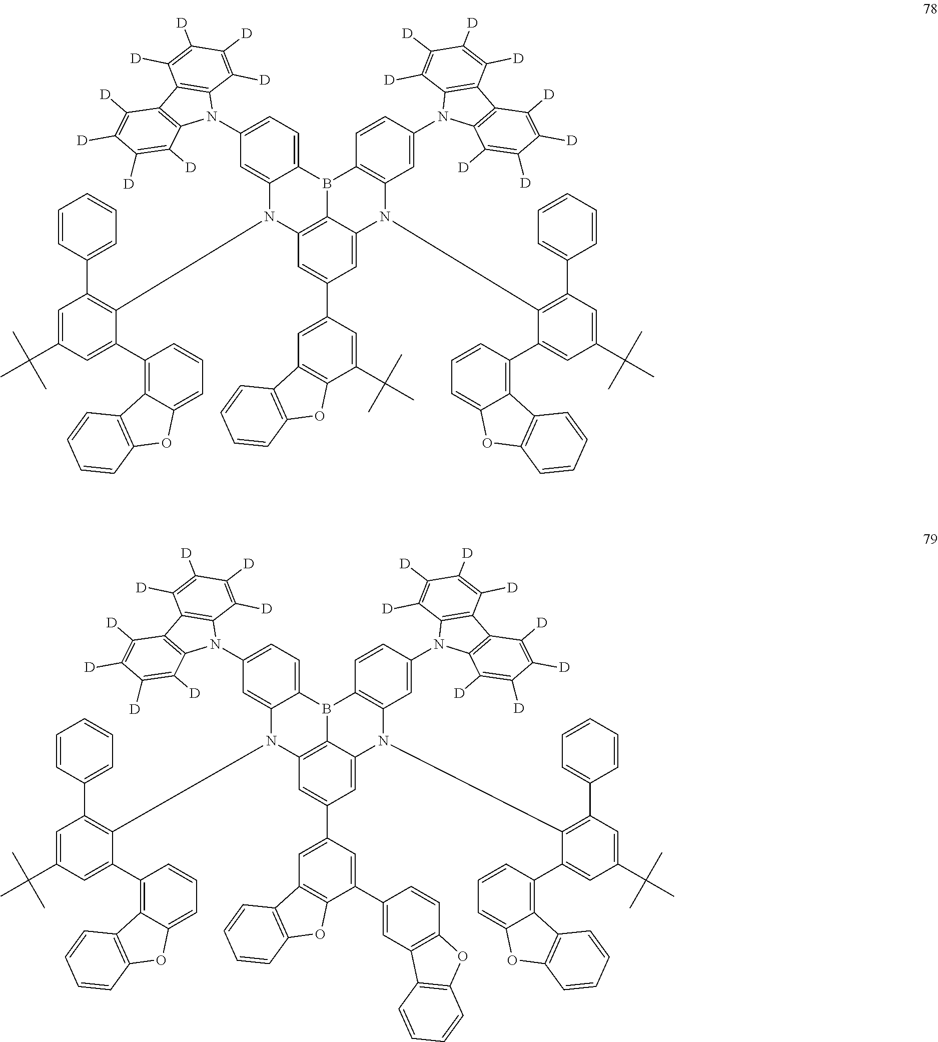

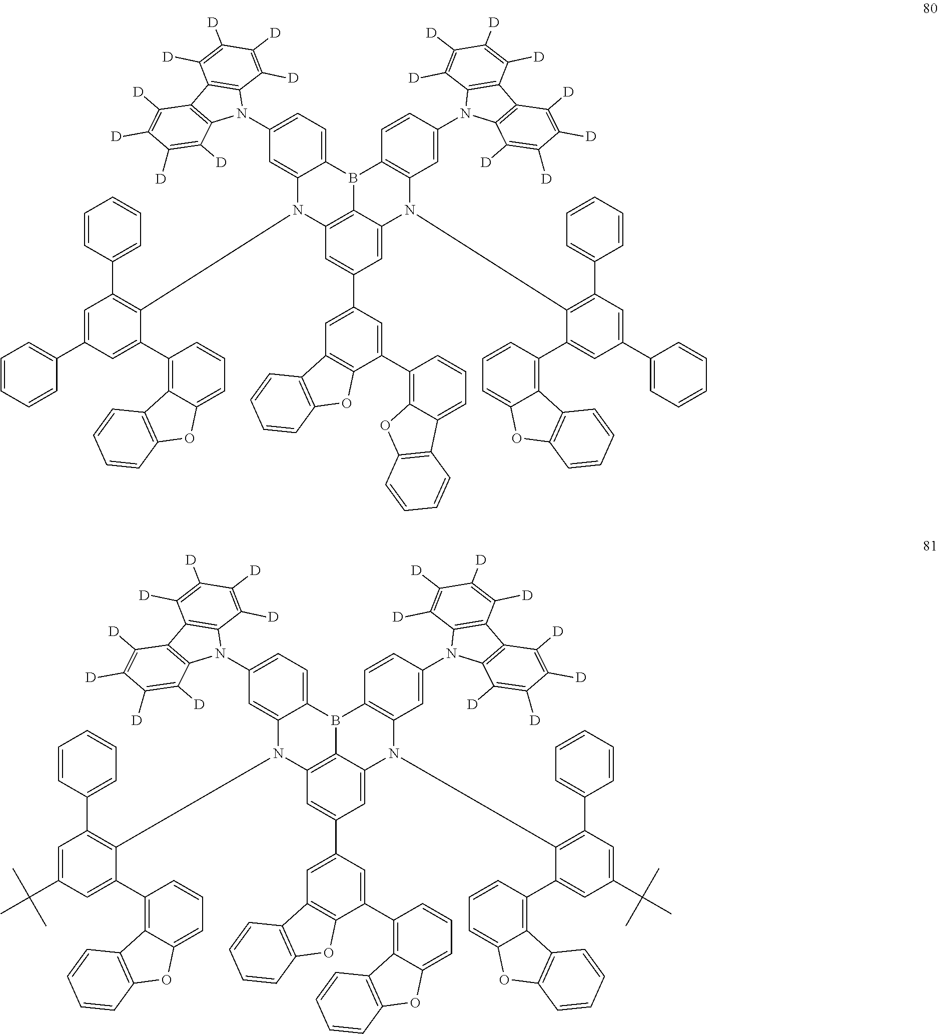

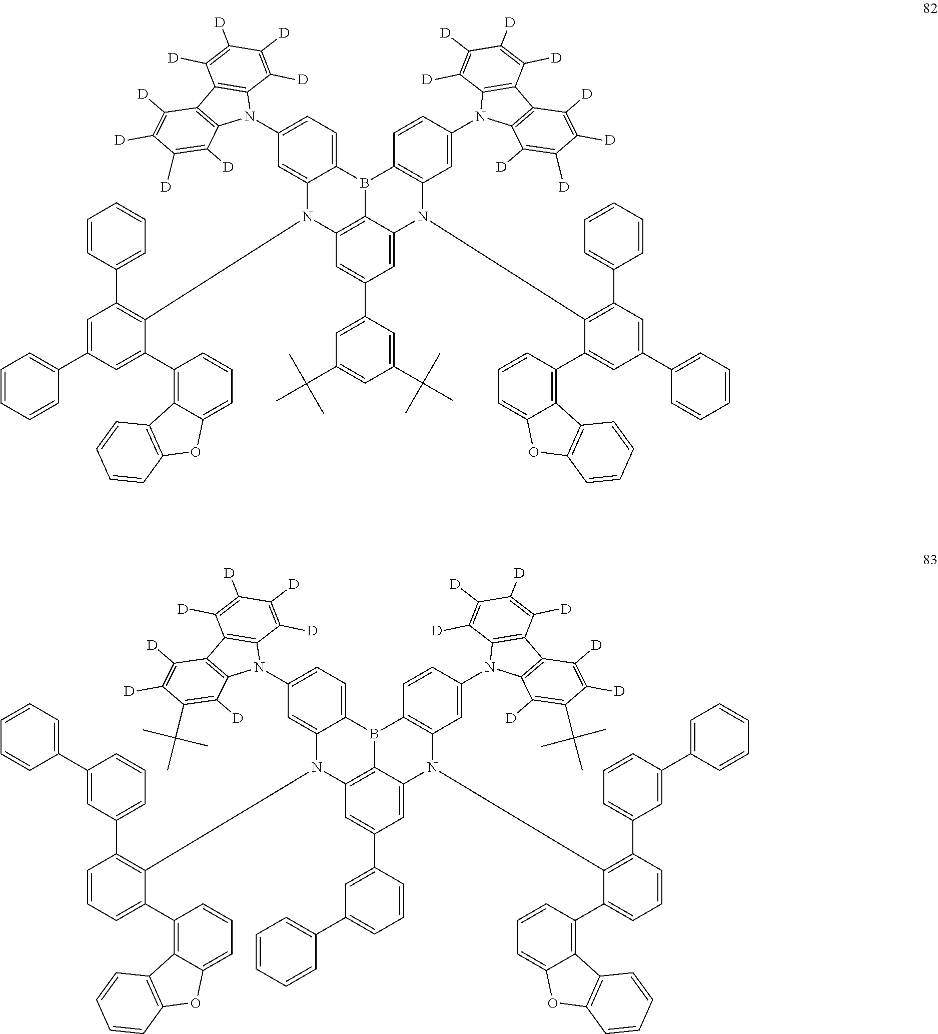

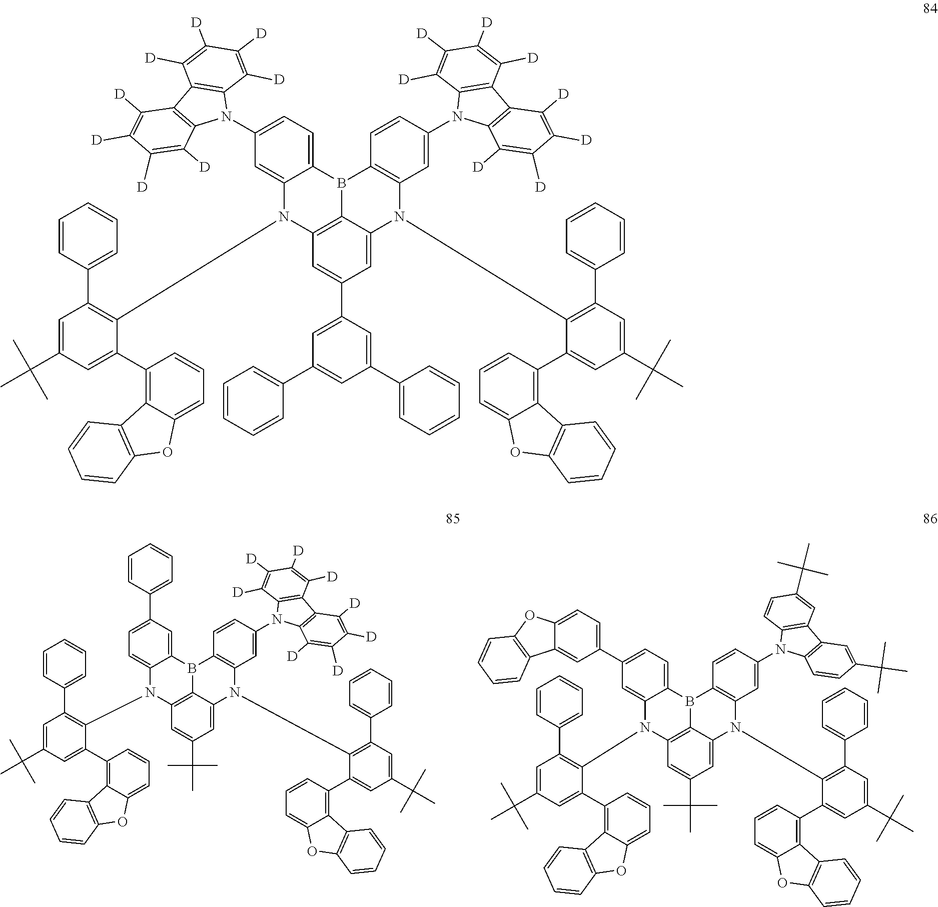

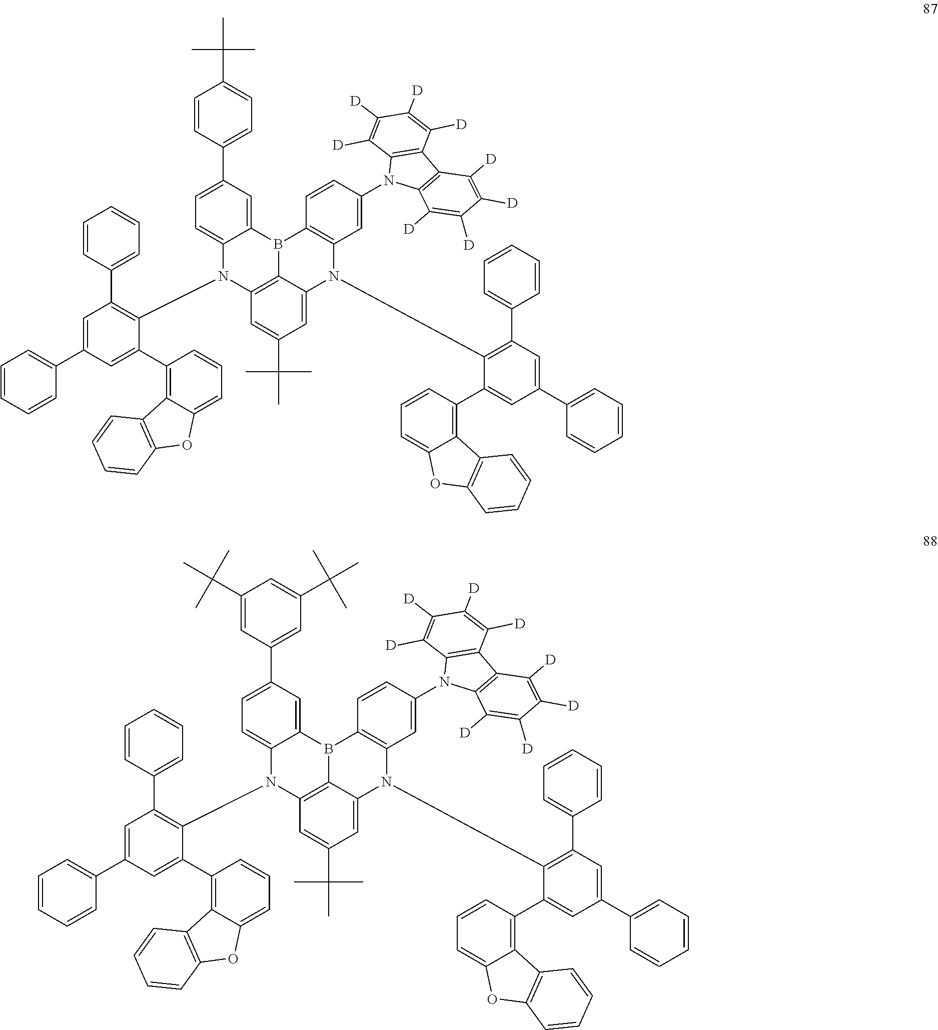 [SMILES: [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3oc4ccccc4c13)c1cc(C(C)(C)C)cc3c1B2c1cc(-c2ccc(C(C)(C)C)cc2)ccc1N3c1c(-c2ccccc2)cc(-c2ccccc2)cc1-c1cccc2oc3ccccc3c12 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3oc4ccccc4c13)c1cc(C(C)(C)C)cc3c1B2c1cc(-c2cc(C(C)(C)C)cc(C(C)(C)C)c2)ccc1N3c1c(-c2ccccc2)cc(-c2ccccc2)cc1-c1cccc2oc3ccccc3c12]

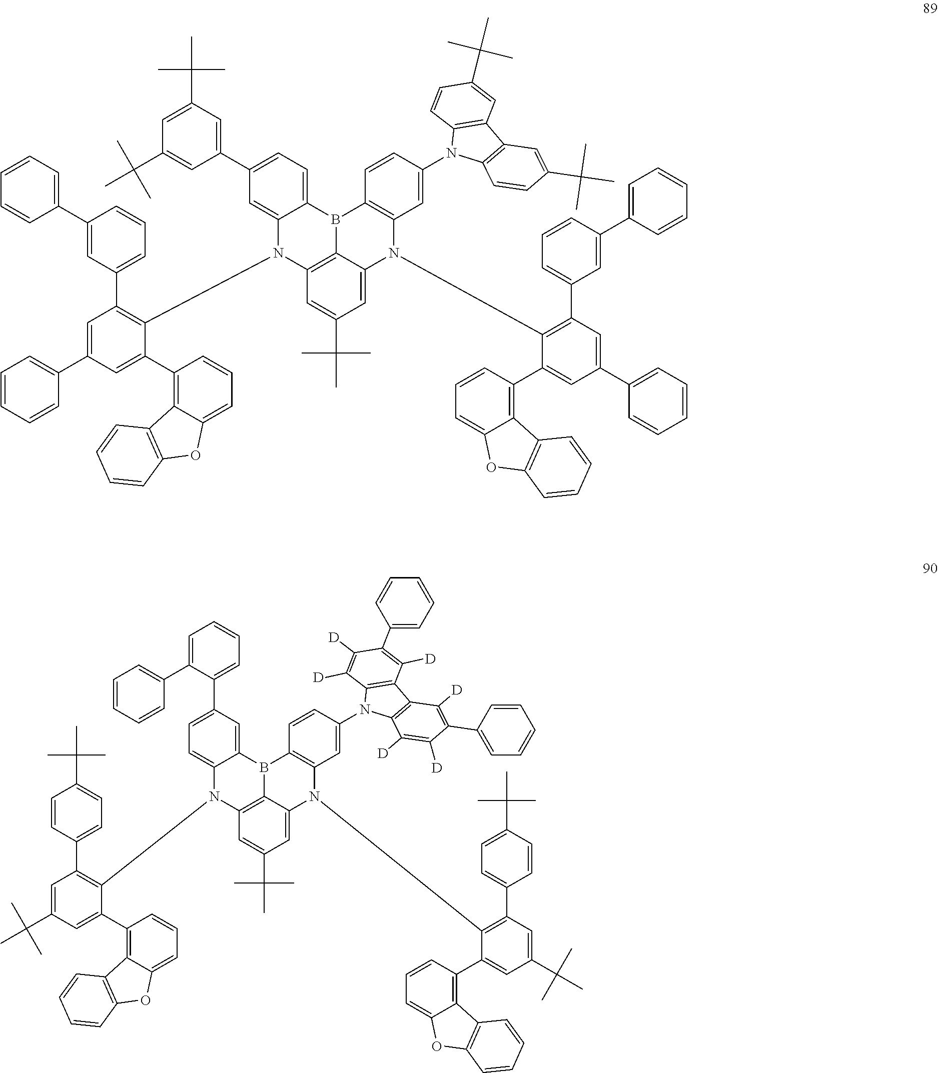 [SMILES: CC(C)(C)c1cc(-c2ccc3c(c2)N(c2c(-c4cccc(-c5ccccc5)c4)cc(-c4ccccc4)cc2-c2cccc4oc5ccccc5c24)c2cc(C(C)(C)C)cc4c2B3c2ccc(-n3c5ccc(C(C)(C)C)cc5c5cc(C(C)(C)C)ccc53)cc2N4c2c(-c3cccc(-c4ccccc4)c3)cc(-c3ccccc3)cc2-c2cccc3oc4ccccc4c23)cc(C(C)(C)C)c1 ; [2H]c1c(-c2ccccc2)c([2H])c2c3c([2H])c(-c4ccccc4)c([2H])c([2H])c3n(-c3ccc4c(c3)N(c3c(-c5ccc(C(C)(C)C)cc5)cc(C(C)(C)C)cc3-c3cccc5oc6ccccc6c35)c3cc(C(C)(C)C)cc5c3B4c3cc(-c4ccccc4-c4ccccc4)ccc3N5c3c(-c4ccc(C(C)(C)C)cc4)cc(C(C)(C)C)cc3-c3cccc4oc5ccccc5c34)c2c1[2H]]

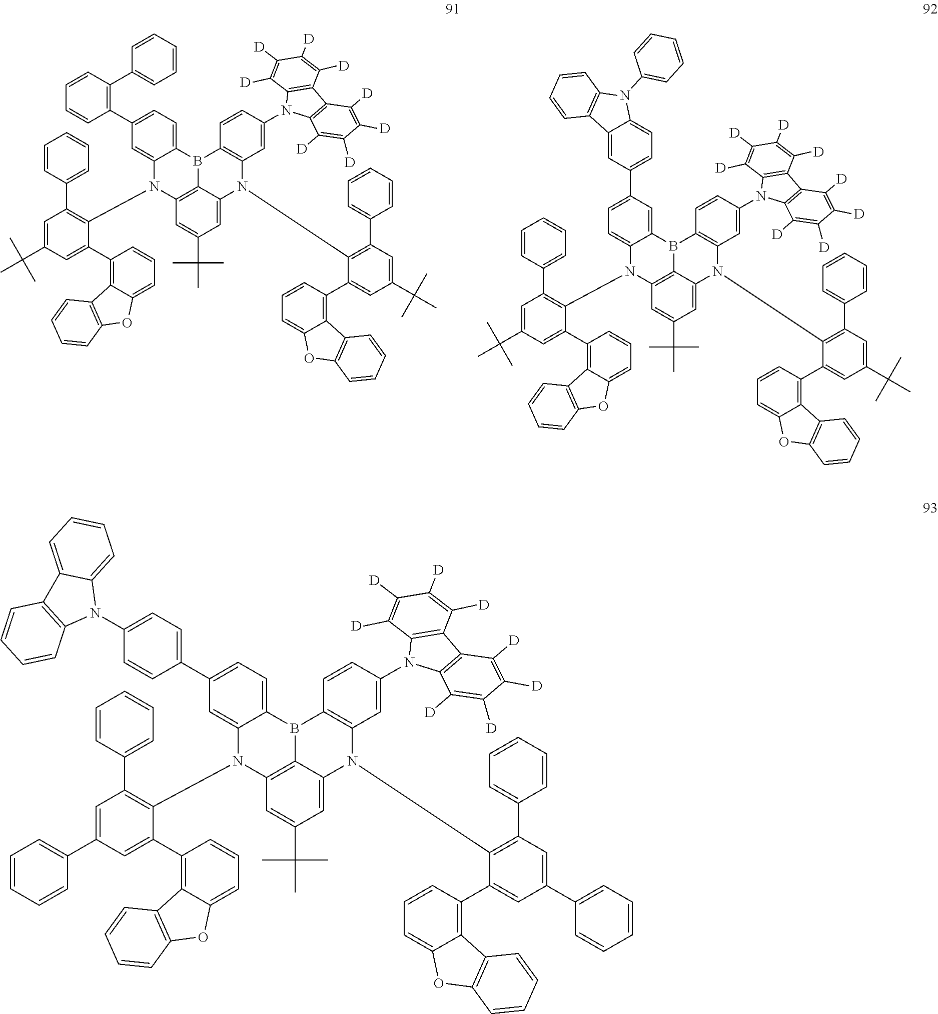

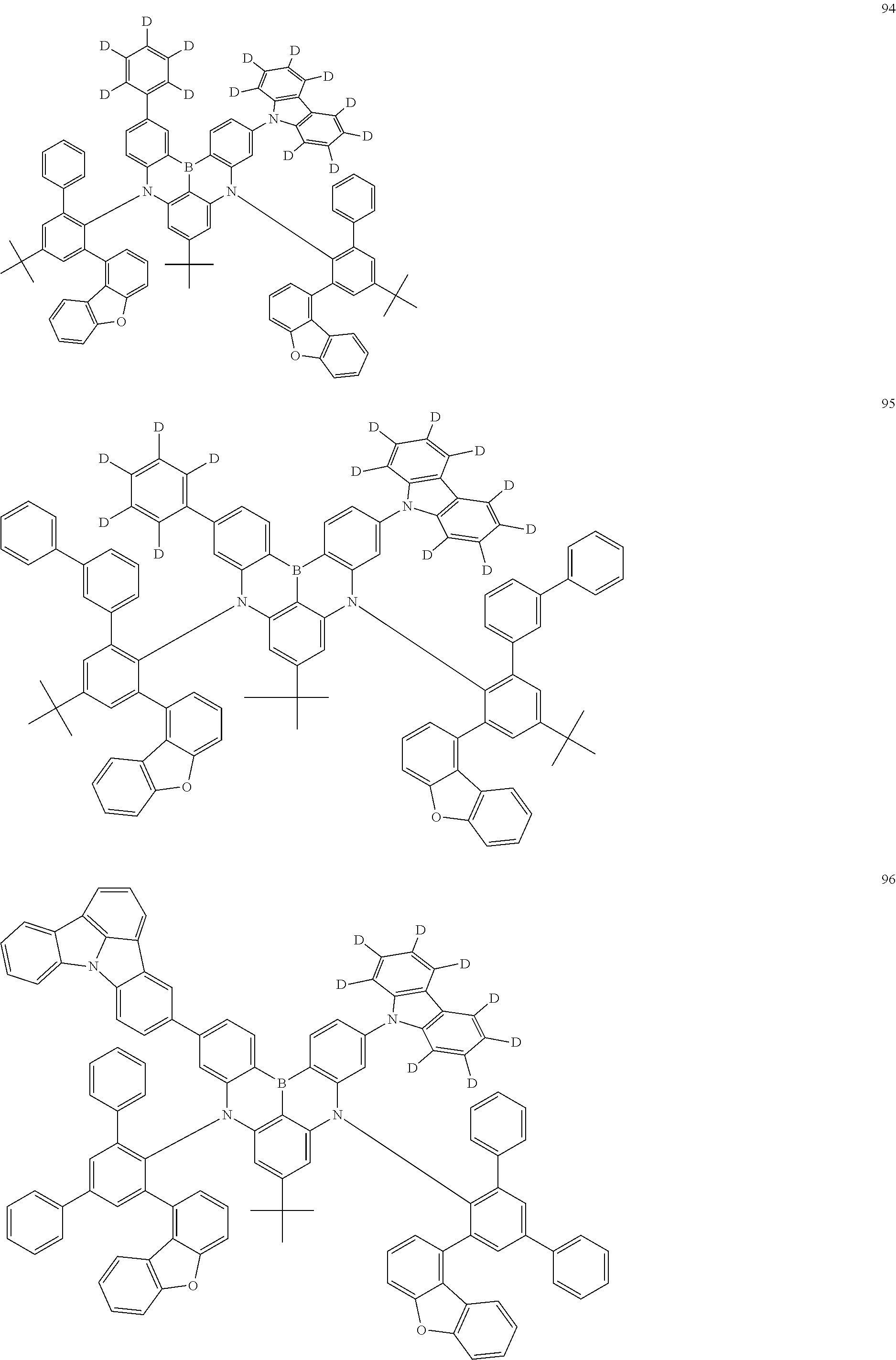

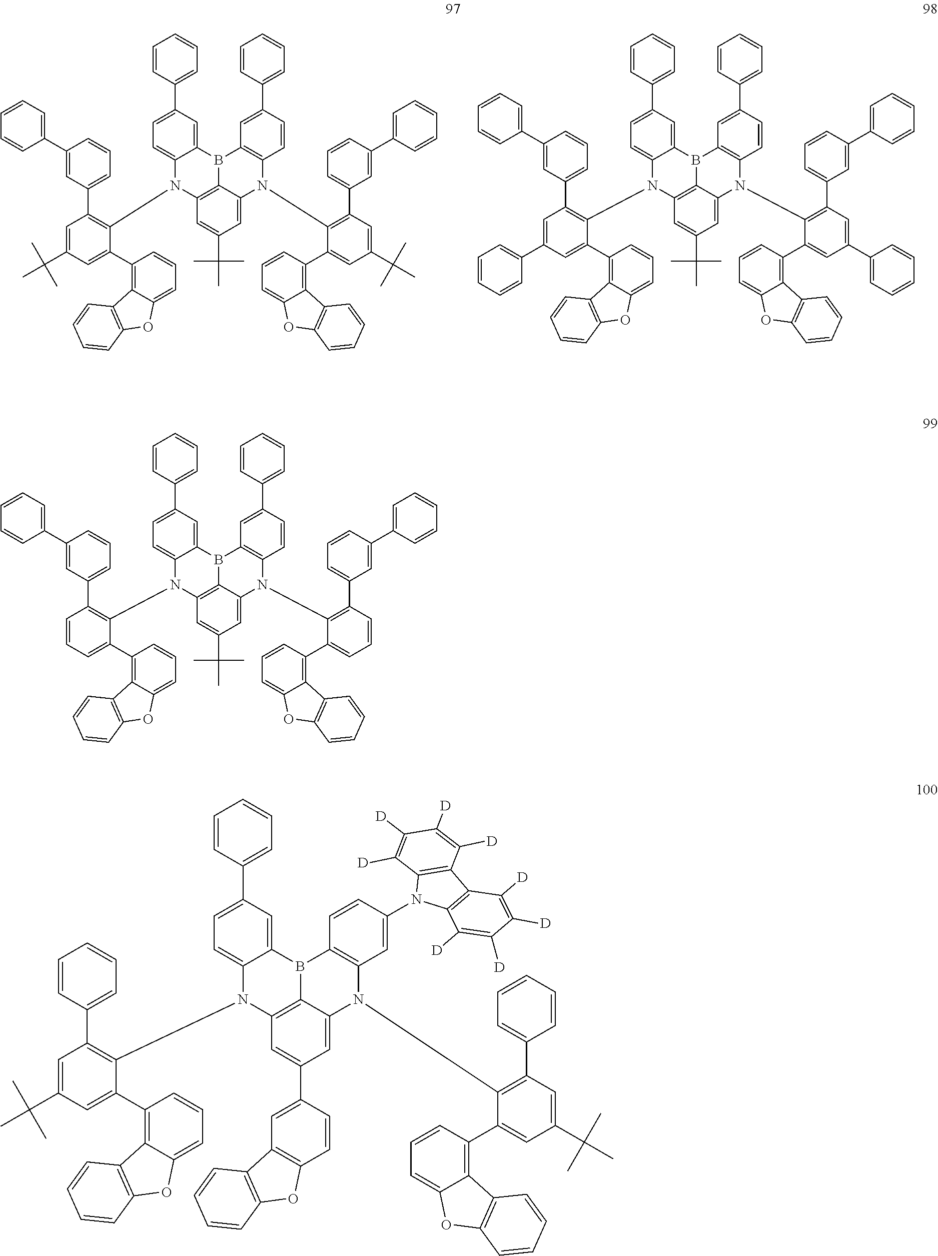

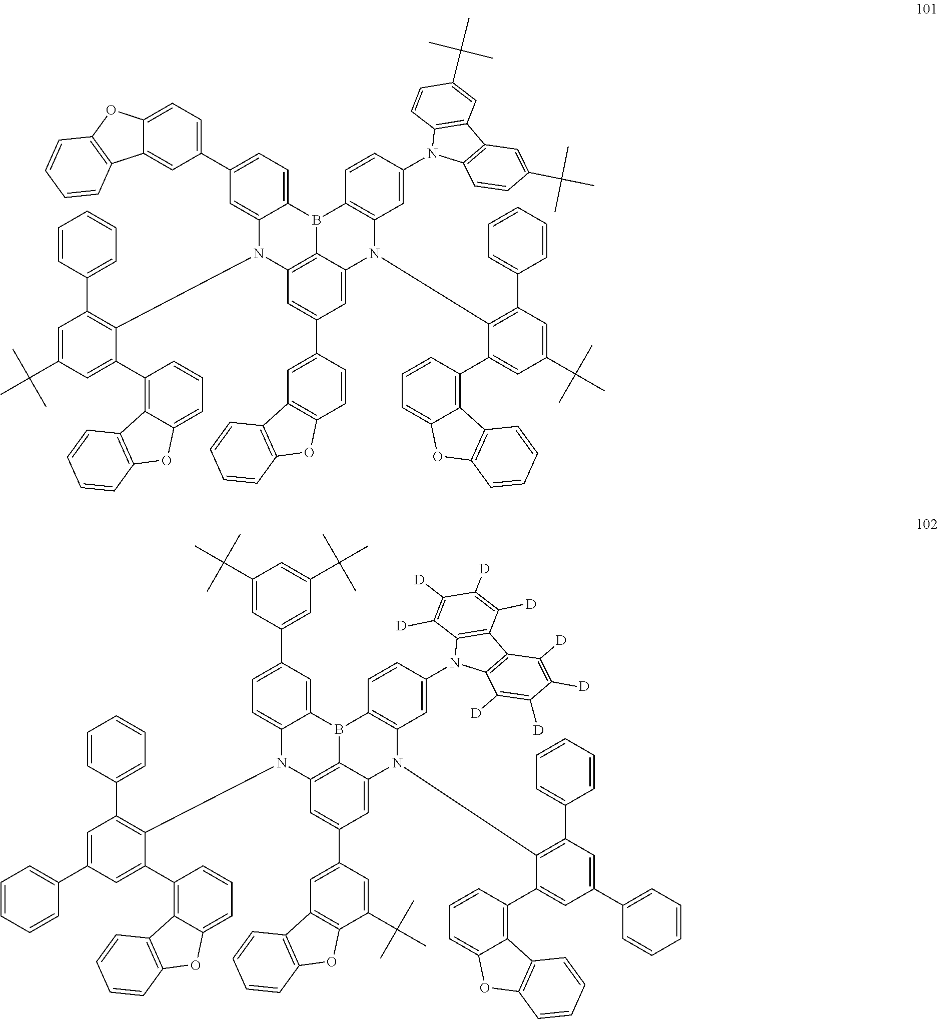 [SMILES: CC(C)(C)c1cc(-c2ccccc2)c(N2c3cc(-c4ccc5oc6ccccc6c5c4)ccc3B3c4ccc(-n5c6ccc(C(C)(C)C)cc6c6cc(C(C)(C)C)ccc65)cc4N(c4c(-c5ccccc5)cc(C(C)(C)C)cc4-c4cccc5oc6ccccc6c45)c4cc(-c5ccc6oc7ccccc7c6c5)cc2c43)c(-c2cccc3oc4ccccc4c23)c1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3oc4ccccc4c13)c1cc(-c3cc(C(C)(C)C)c4oc5ccccc5c4c3)cc3c1B2c1cc(-c2cc(C(C)(C)C)cc(C(C)(C)C)c2)ccc1N3c1c(-c2ccccc2)cc(-c2ccccc2)cc1-c1cccc2oc3ccccc3c12]

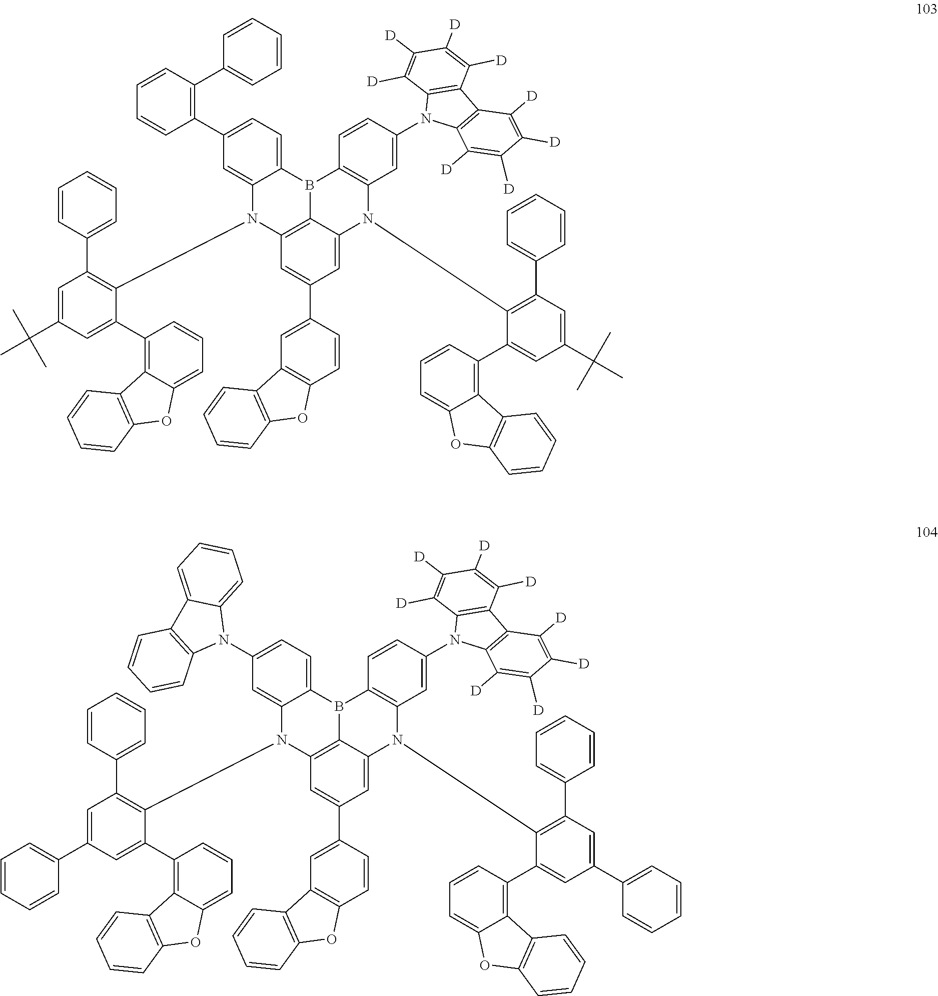 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc3oc4ccccc4c13)c1cc(-c3ccc4oc5ccccc5c4c3)cc3c1B2c1ccc(-c2ccccc2-c2ccccc2)cc1N3c1c(-c2ccccc2)cc(C(C)(C)C)cc1-c1cccc2oc3ccccc3c12 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3oc4ccccc4c13)c1cc(-c3ccc4oc5ccccc5c4c3)cc3c1B2c1ccc(-n2c4ccccc4c4ccccc42)cc1N3c1c(-c2ccccc2)cc(-c2ccccc2)cc1-c1cccc2oc3ccccc3c12]

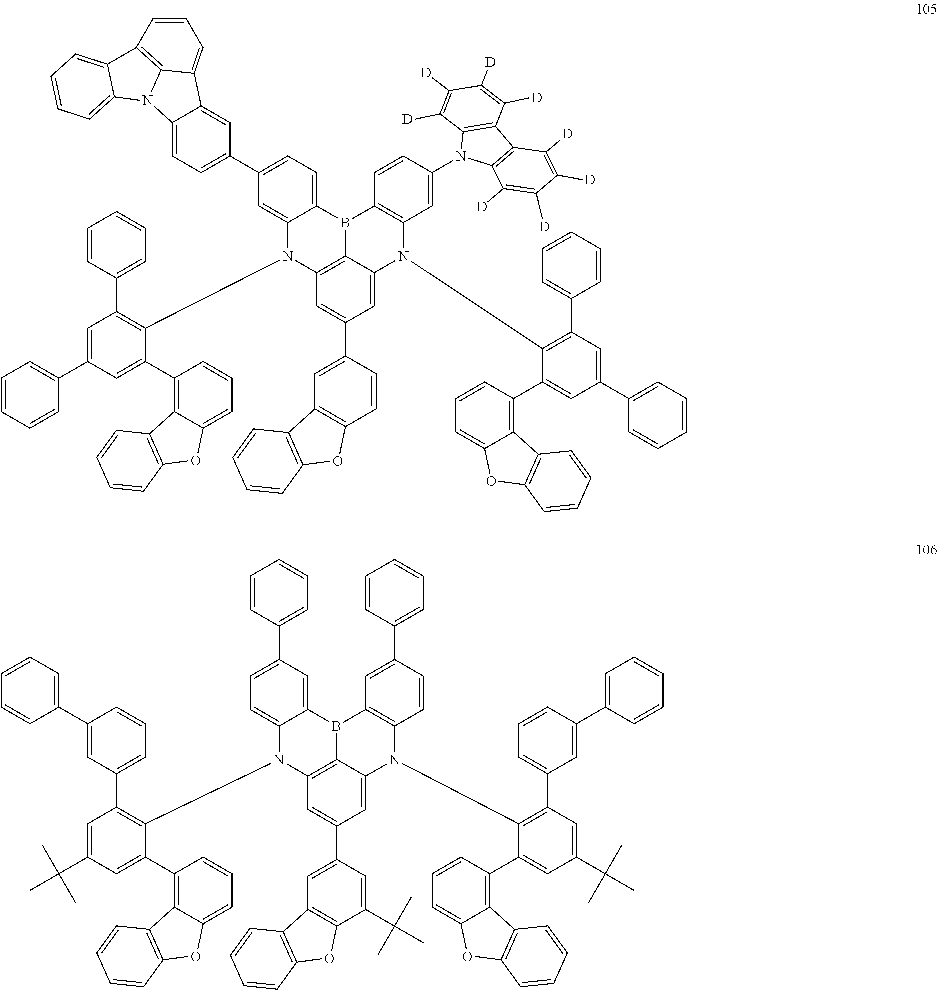 [SMILES: [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc3oc4ccccc4c13)c1cc(-c3ccc4oc5ccccc5c4c3)cc3c1B2c1ccc(-c2ccc4c(c2)c2cccc5c6ccccc6n4c52)cc1N3c1c(-c2ccccc2)cc(-c2ccccc2)cc1-c1cccc2oc3ccccc3c12 ; CC(C)(C)c1cc(-c2cccc(-c3ccccc3)c2)c(N2c3ccc(-c4ccccc4)cc3B3c4cc(-c5ccccc5)ccc4N(c4c(-c5cccc(-c6ccccc6)c5)cc(C(C)(C)C)cc4-c4cccc5oc6ccccc6c45)c4cc(-c5cc(C(C)(C)C)c6oc7ccccc7c6c5)cc2c43)c(-c2cccc3oc4ccccc4c23)c1]

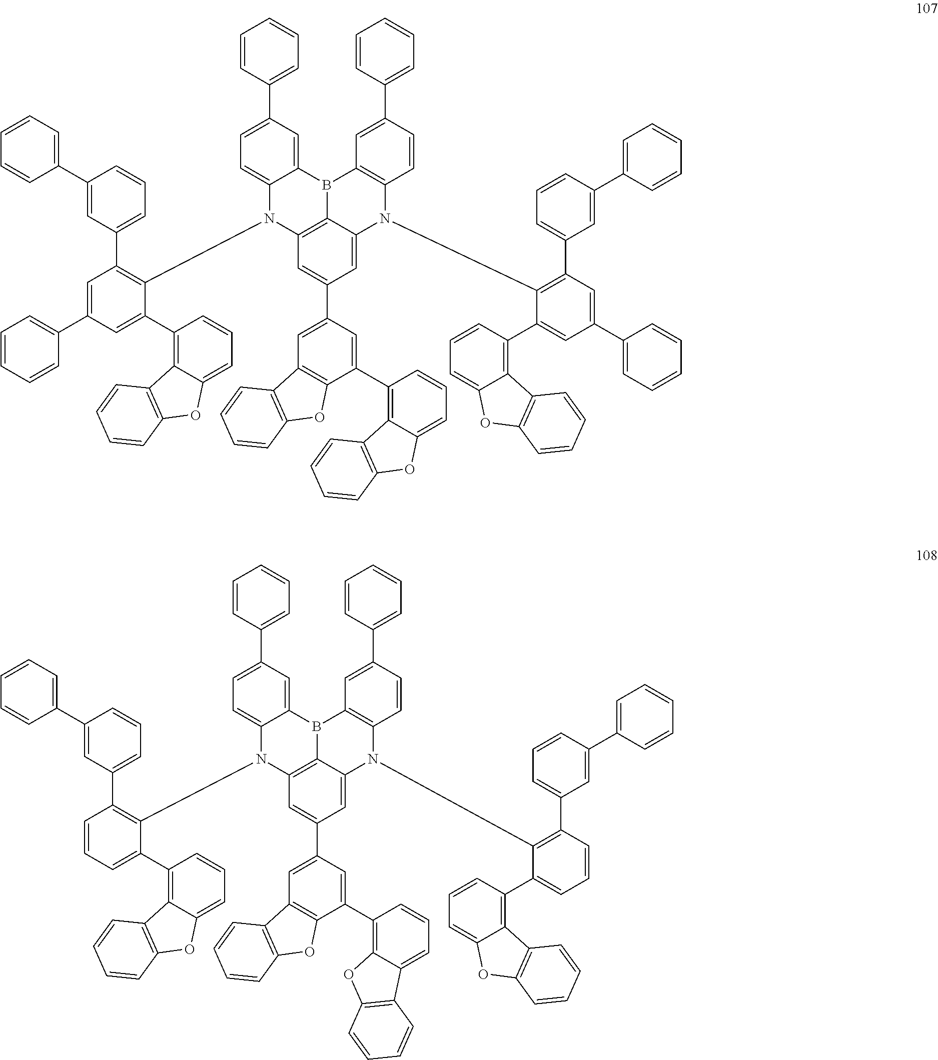 [SMILES: c1ccc(-c2cccc(-c3cc(-c4ccccc4)cc(-c4cccc5oc6ccccc6c45)c3N3c4ccc(-c5ccccc5)cc4B4c5cc(-c6ccccc6)ccc5N(c5c(-c6cccc(-c7ccccc7)c6)cc(-c6ccccc6)cc5-c5cccc6oc7ccccc7c56)c5cc(-c6cc(-c7cccc8oc9ccccc9c78)c7oc8ccccc8c7c6)cc3c54)c2)cc1 ; c1ccc(-c2cccc(-c3cccc(-c4cccc5oc6ccccc6c45)c3N3c4ccc(-c5ccccc5)cc4B4c5cc(-c6ccccc6)ccc5N(c5c(-c6cccc(-c7ccccc7)c6)cccc5-c5cccc6oc7ccccc7c56)c5cc(-c6cc(-c7cccc8c7oc7ccccc78)c7oc8ccccc8c7c6)cc3c54)c2)cc1]

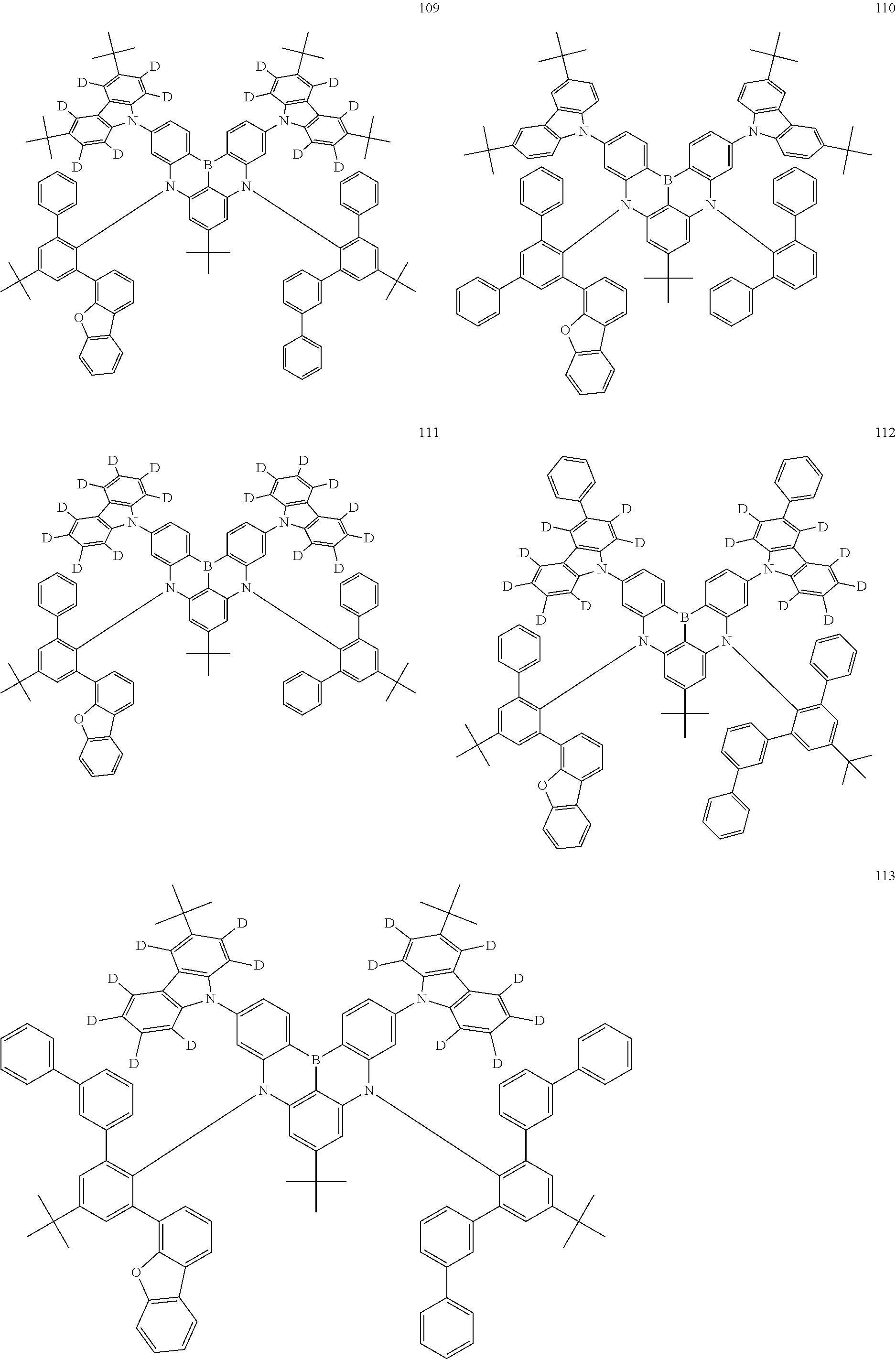

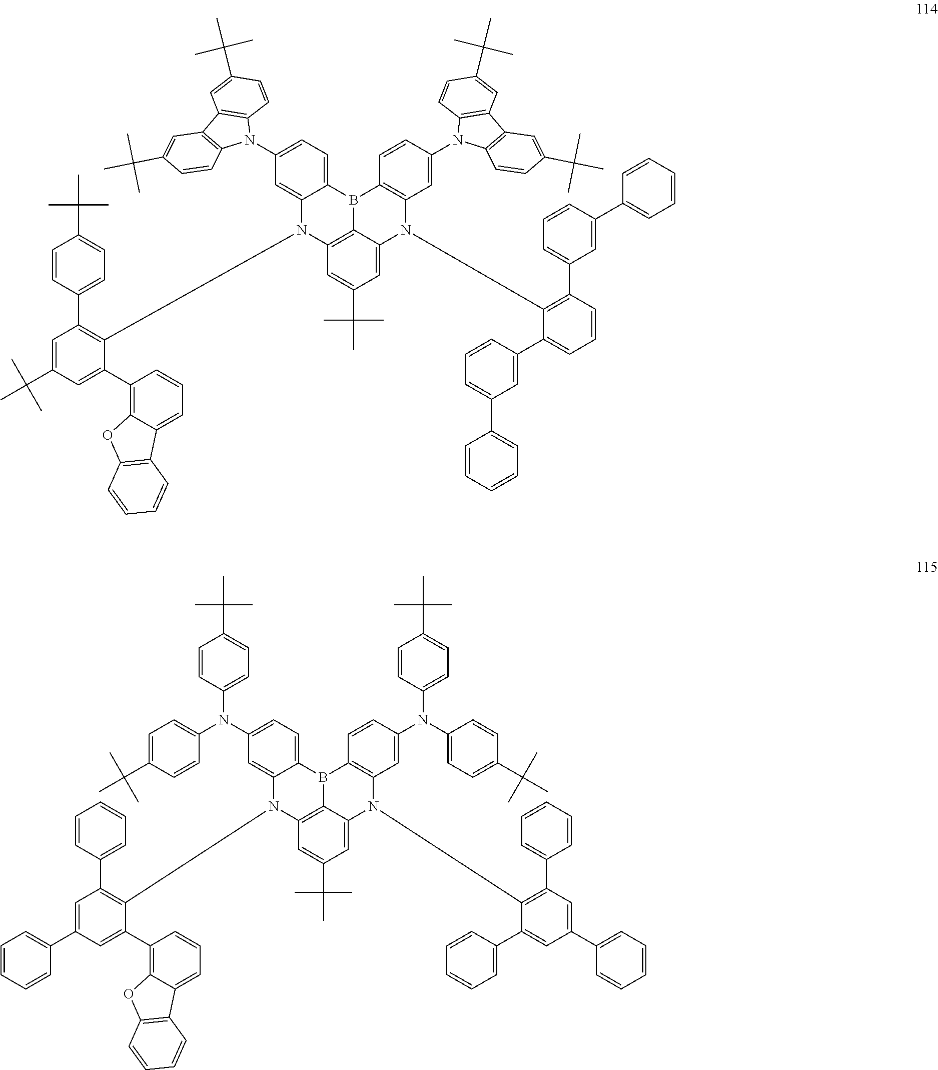 [SMILES: CC(C)(C)c1ccc(-c2cc(C(C)(C)C)cc(-c3cccc4c3oc3ccccc34)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5cccc(-c6ccccc6)c5)cccc4-c4cccc(-c5ccccc5)c4)c4cc(C(C)(C)C)cc2c43)cc1 ; CC(C)(C)c1ccc(N(c2ccc(C(C)(C)C)cc2)c2ccc3c(c2)N(c2c(-c4ccccc4)cc(-c4ccccc4)cc2-c2ccccc2)c2cc(C(C)(C)C)cc4c2B3c2ccc(N(c3ccc(C(C)(C)C)cc3)c3ccc(C(C)(C)C)cc3)cc2N4c2c(-c3ccccc3)cc(-c3ccccc3)cc2-c2cccc3c2oc2ccccc23)cc1]

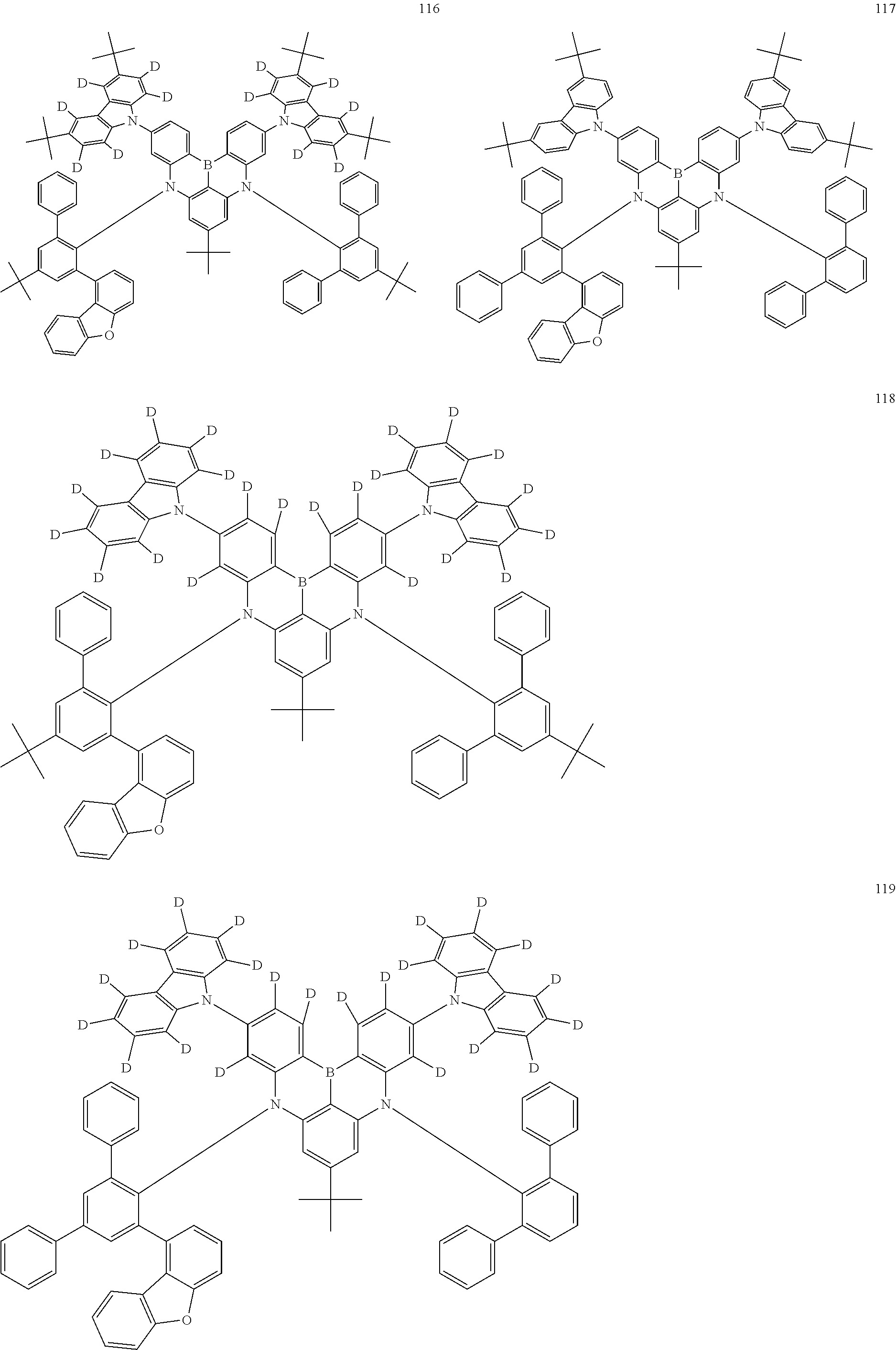

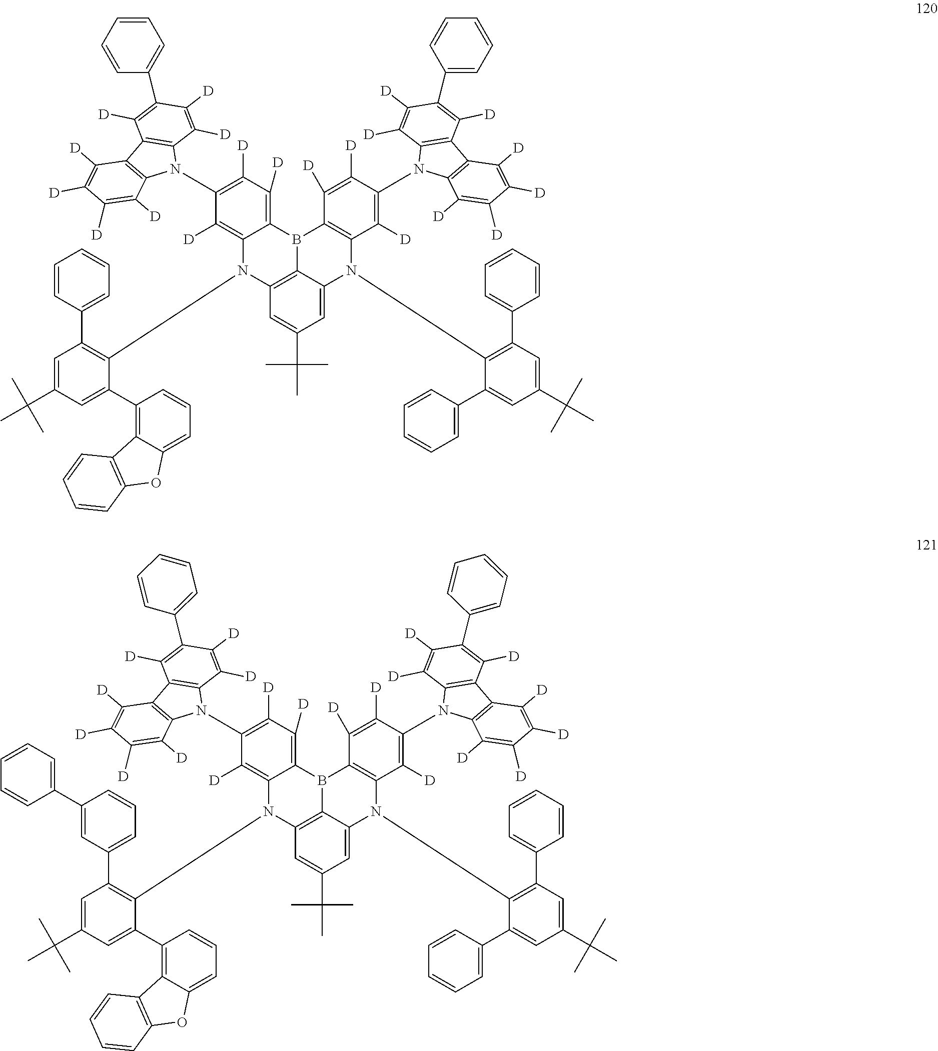

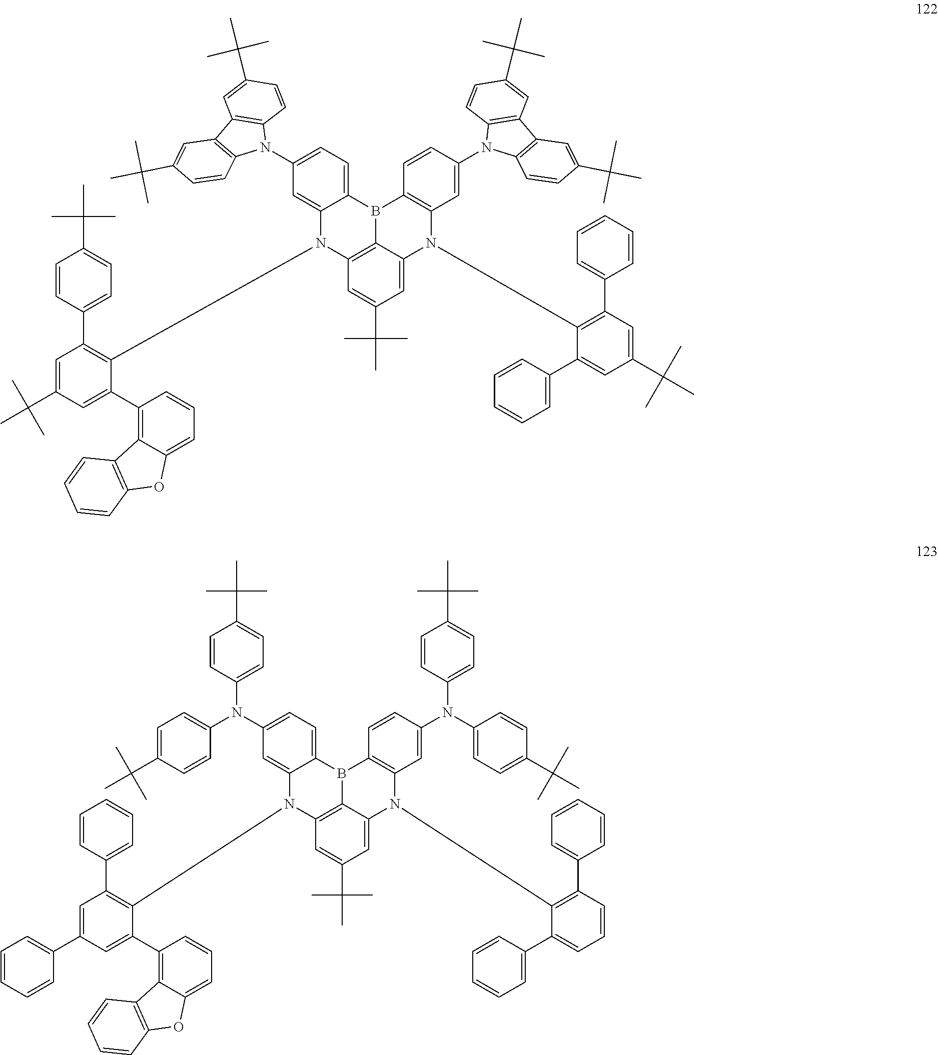 [SMILES: CC(C)(C)c1ccc(-c2cc(C(C)(C)C)cc(-c3cccc4oc5ccccc5c34)c2N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4cc(C(C)(C)C)cc2c43)cc1 ; CC(C)(C)c1ccc(N(c2ccc(C(C)(C)C)cc2)c2ccc3c(c2)N(c2c(-c4ccccc4)cccc2-c2ccccc2)c2cc(C(C)(C)C)cc4c2B3c2ccc(N(c3ccc(C(C)(C)C)cc3)c3ccc(C(C)(C)C)cc3)cc2N4c2c(-c3ccccc3)cc(-c3ccccc3)cc2-c2cccc3oc4ccccc4c23)cc1]

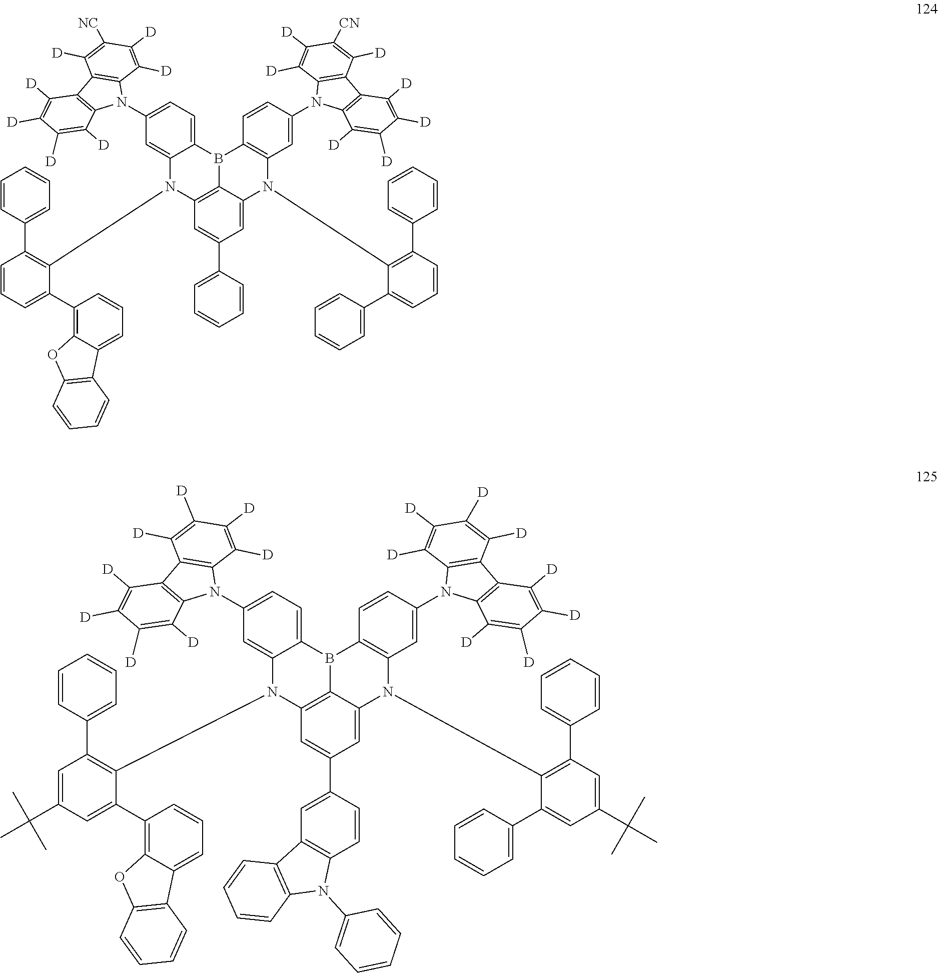

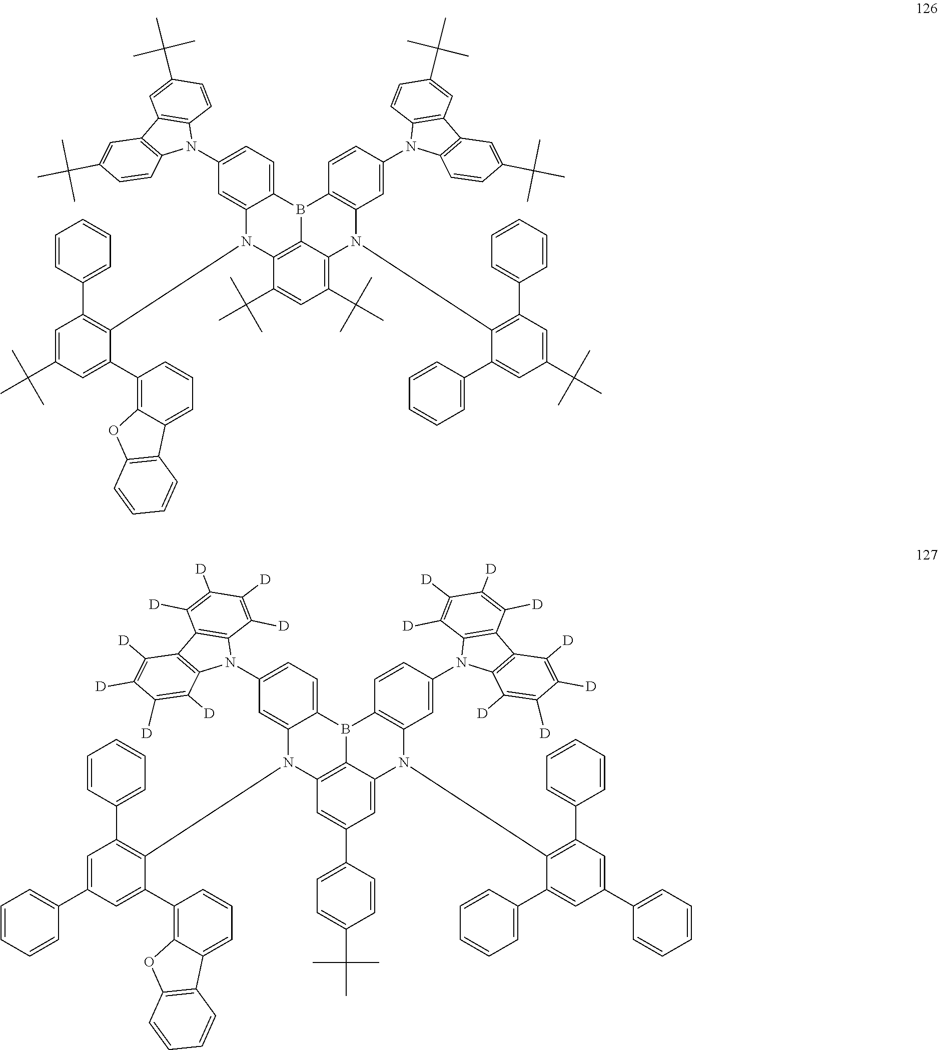

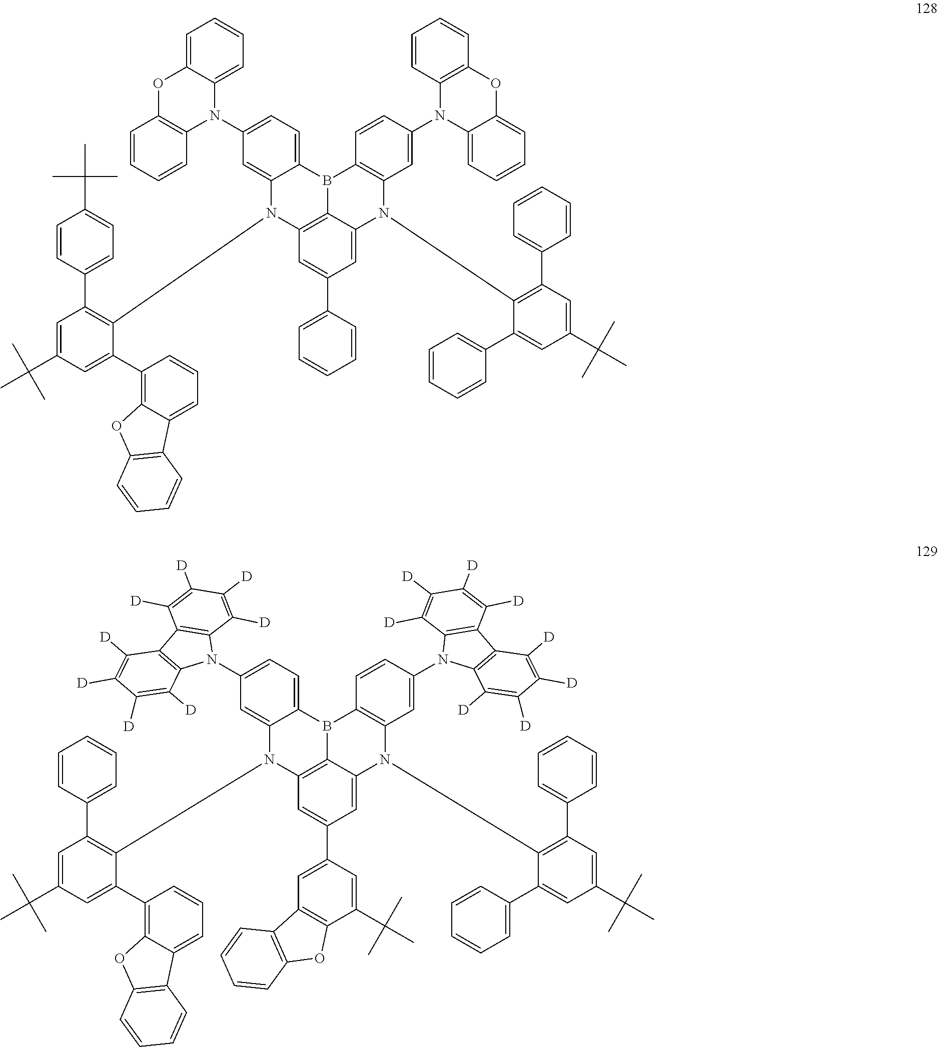

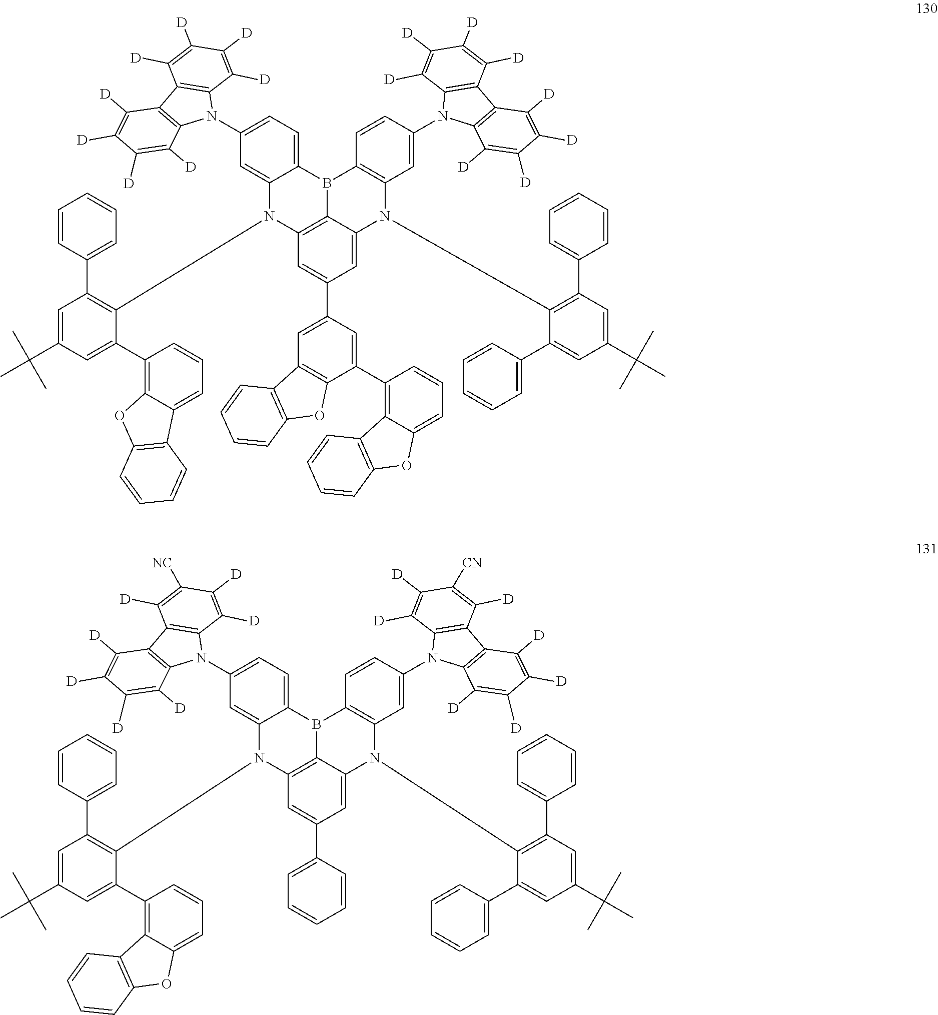

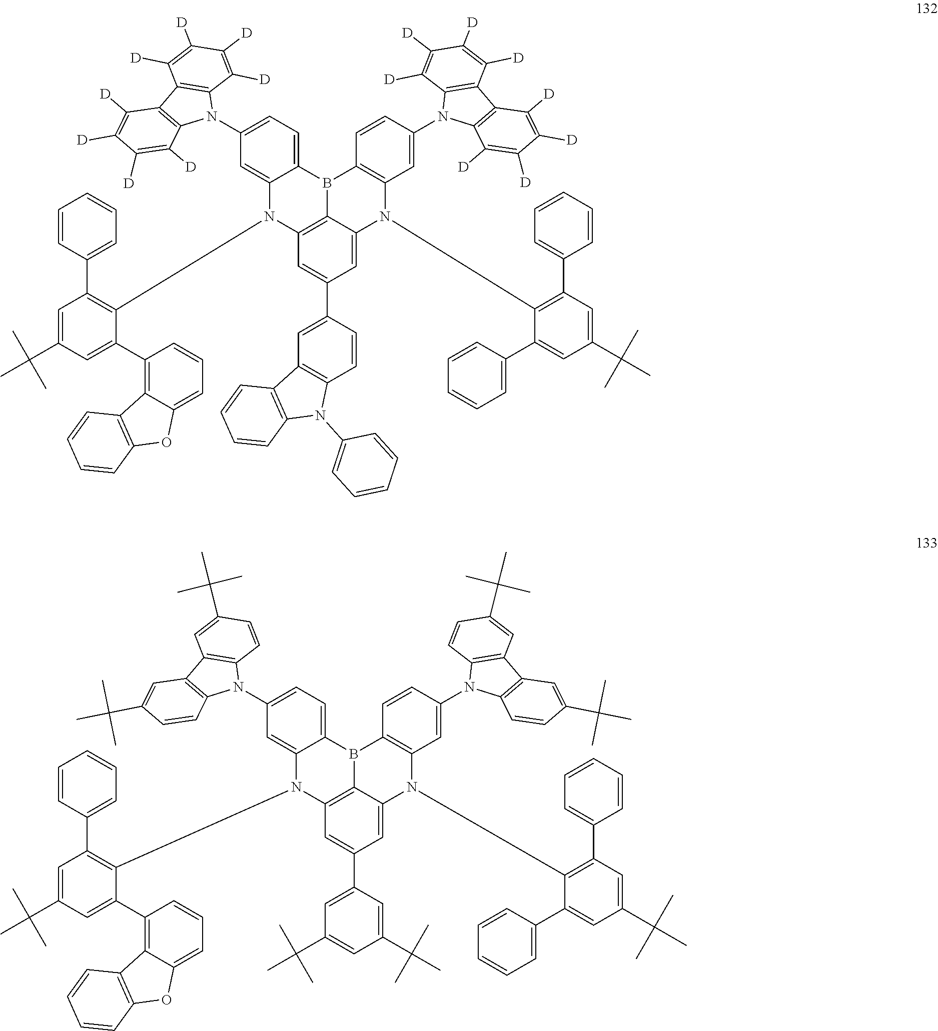

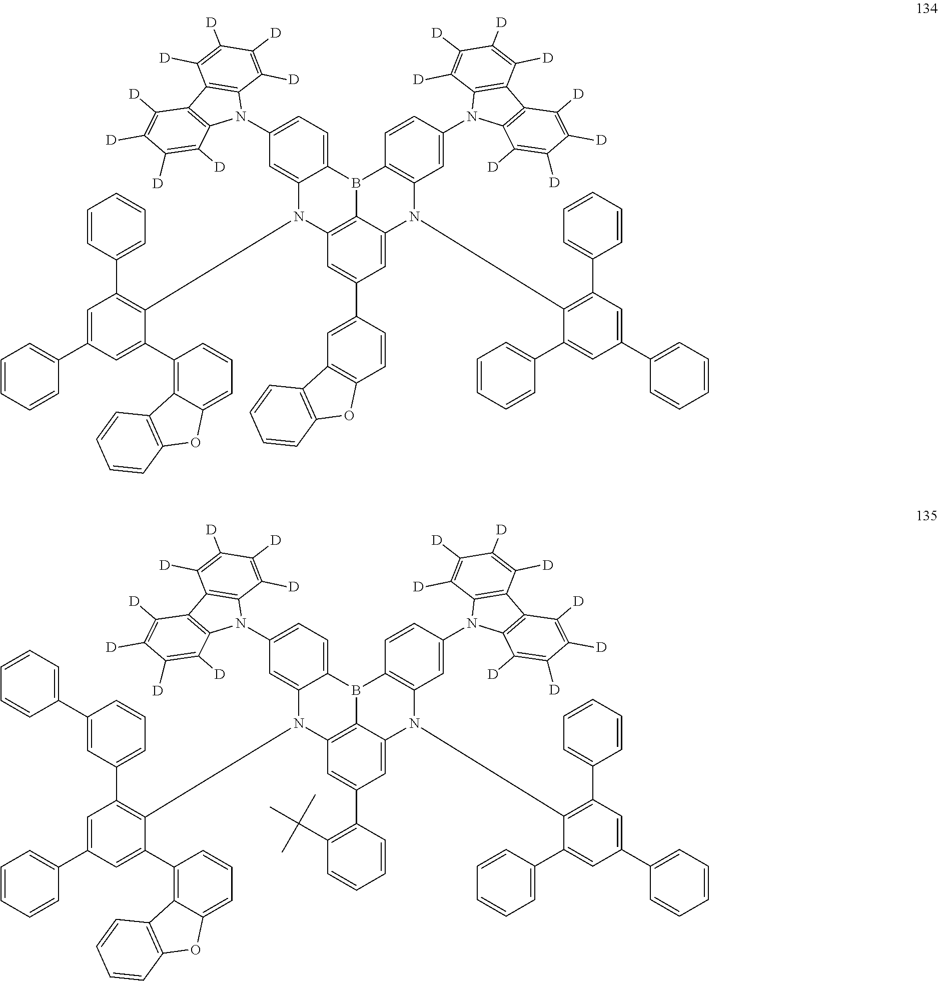

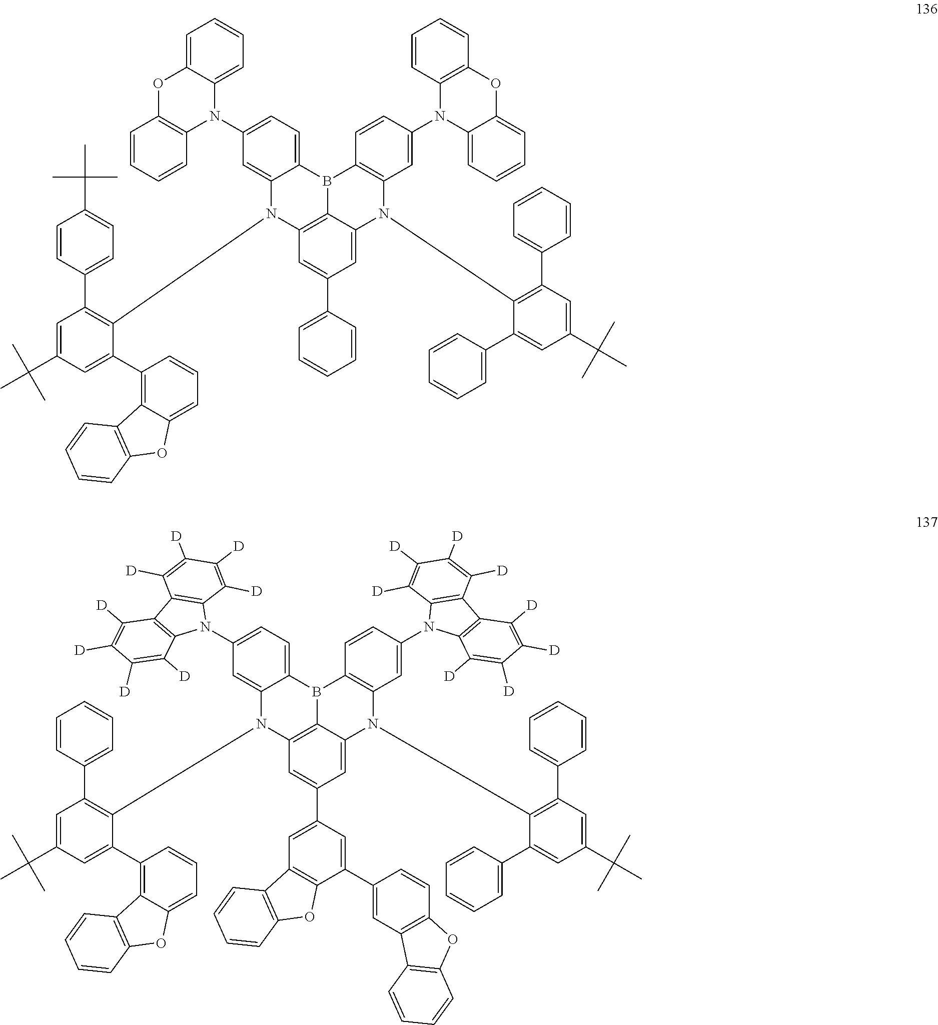

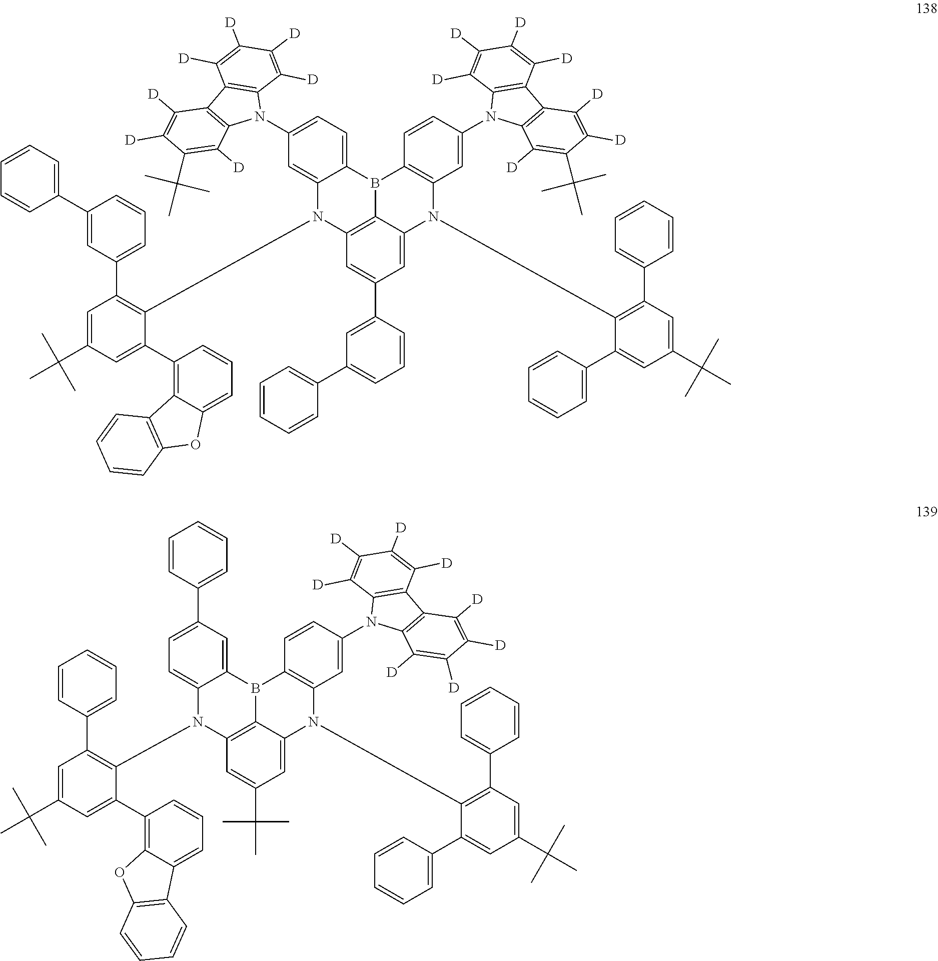

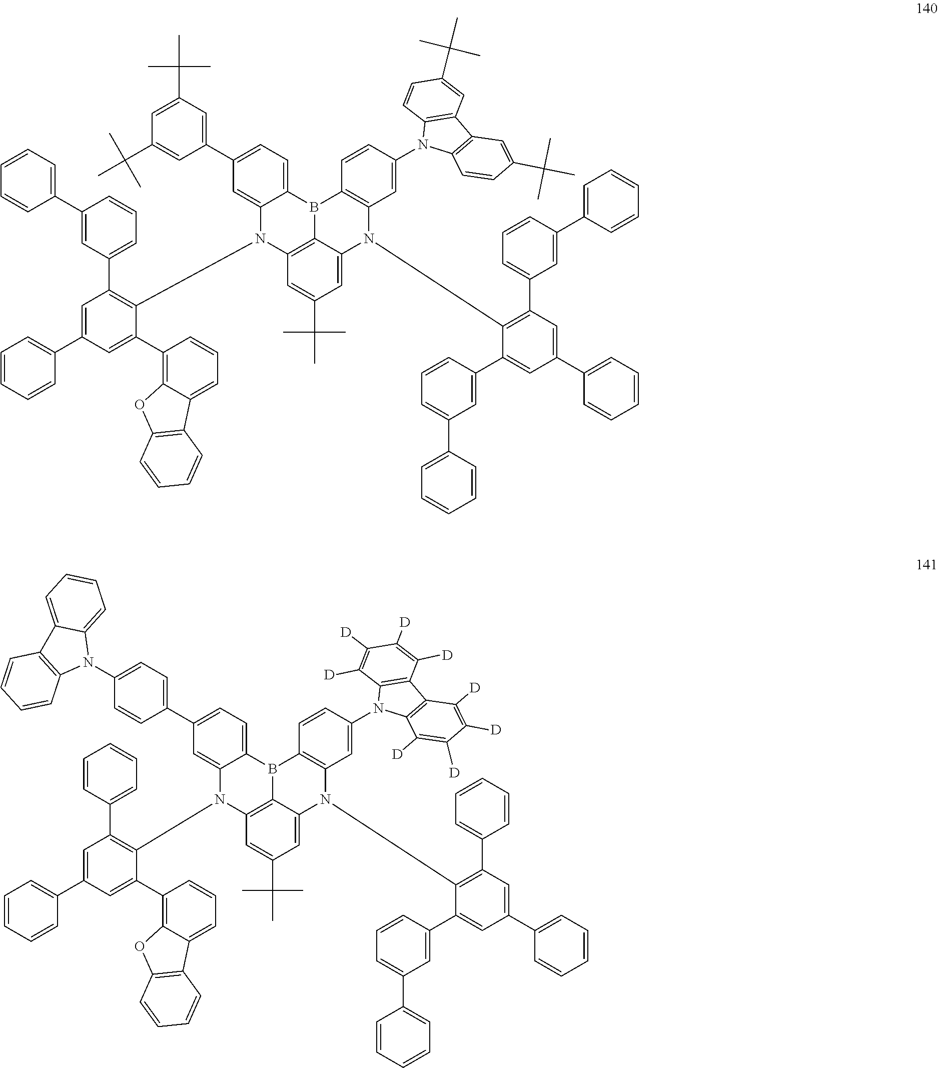 [SMILES: CC(C)(C)c1cc(-c2ccc3c(c2)N(c2c(-c4cccc(-c5ccccc5)c4)cc(-c4ccccc4)cc2-c2cccc4c2oc2ccccc24)c2cc(C(C)(C)C)cc4c2B3c2ccc(-n3c5ccc(C(C)(C)C)cc5c5cc(C(C)(C)C)ccc53)cc2N4c2c(-c3cccc(-c4ccccc4)c3)cc(-c3ccccc3)cc2-c2cccc(-c3ccccc3)c2)cc(C(C)(C)C)c1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1cccc(-c3ccccc3)c1)c1cc(C(C)(C)C)cc3c1B2c1ccc(-c2ccc(-n4c5ccccc5c5ccccc54)cc2)cc1N3c1c(-c2ccccc2)cc(-c2ccccc2)cc1-c1cccc2c1oc1ccccc12]

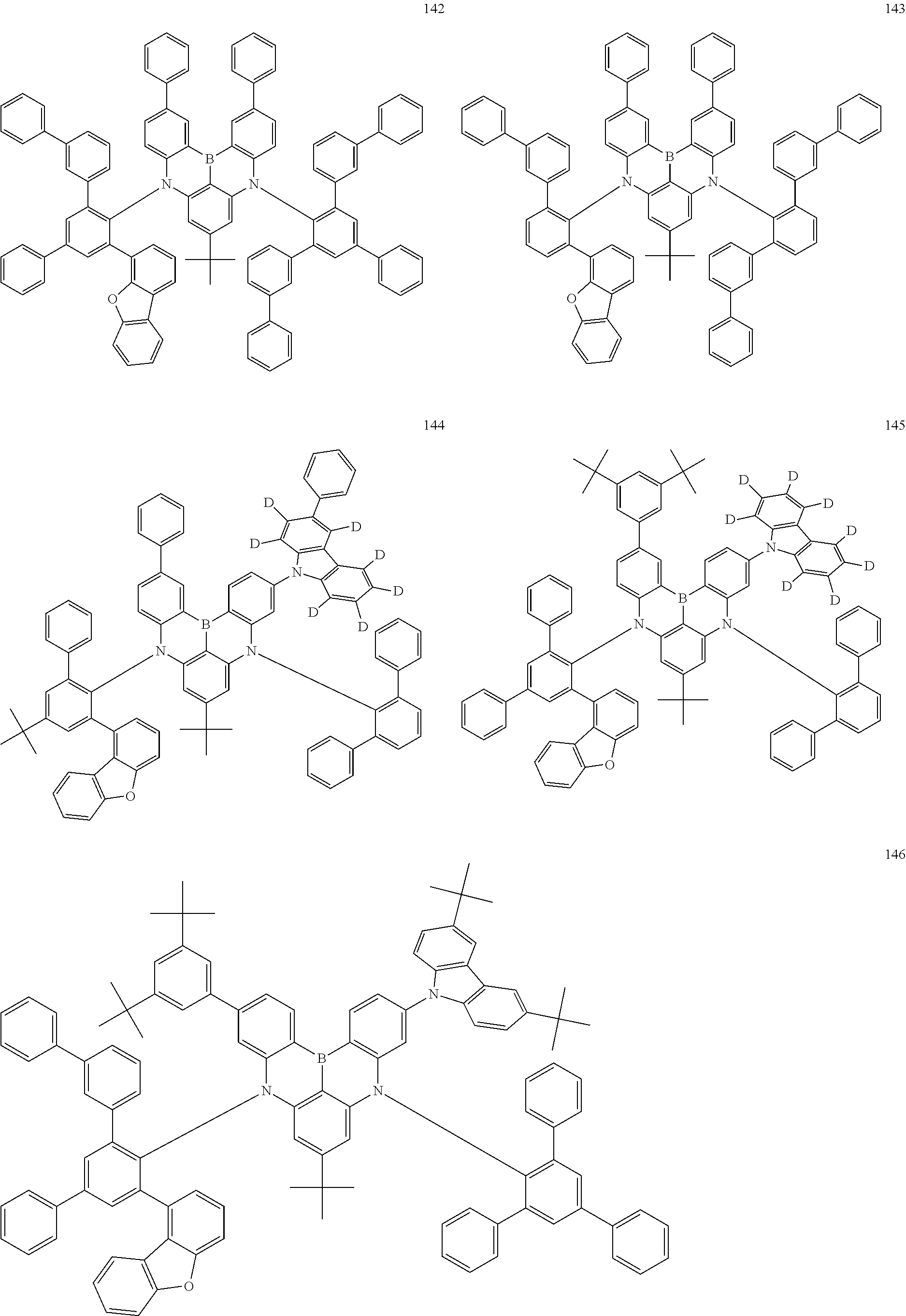

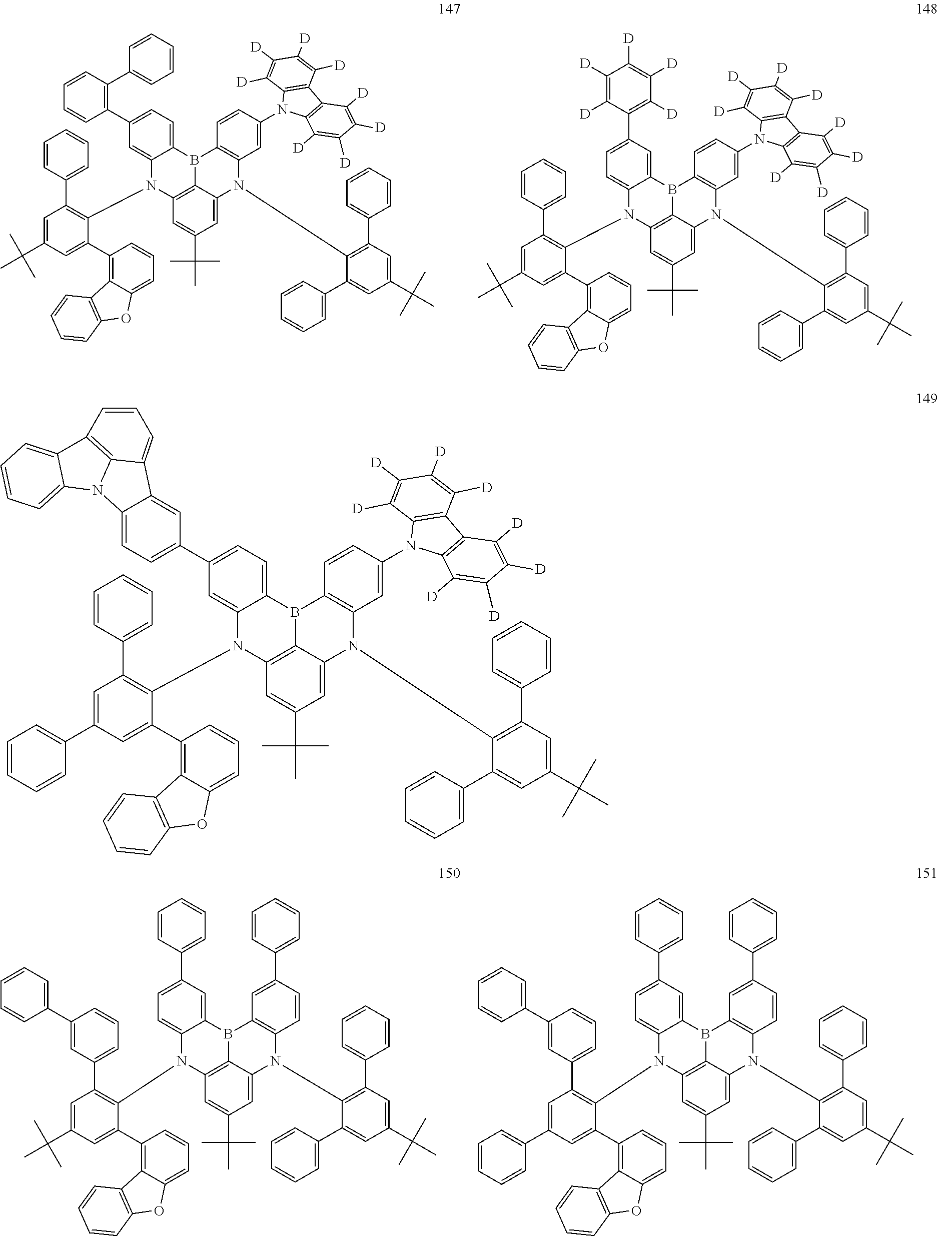

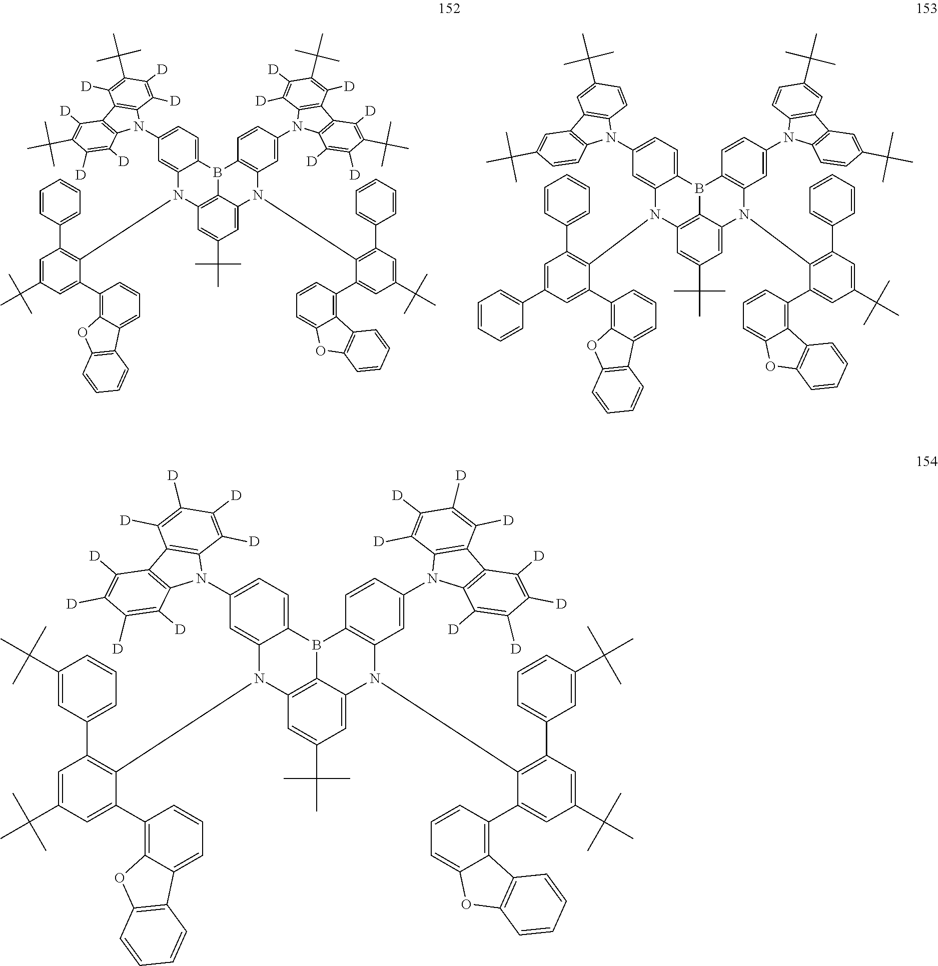

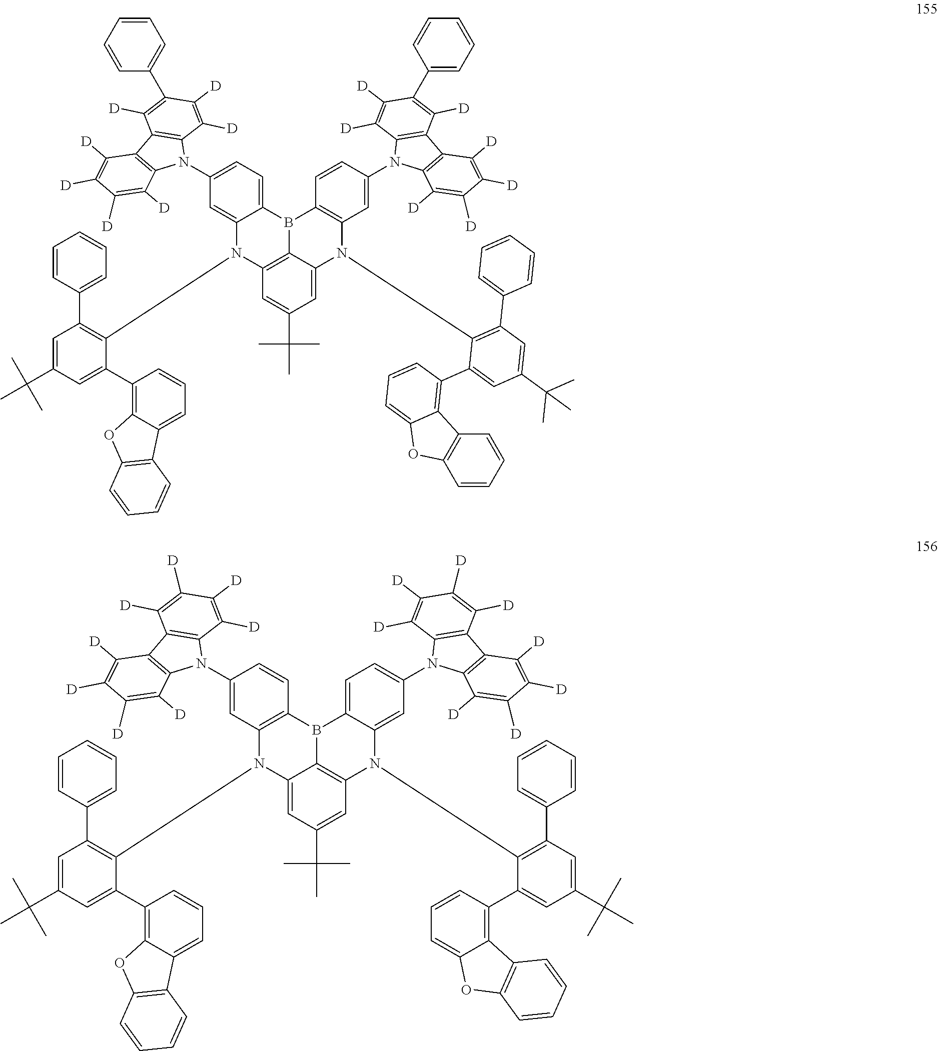

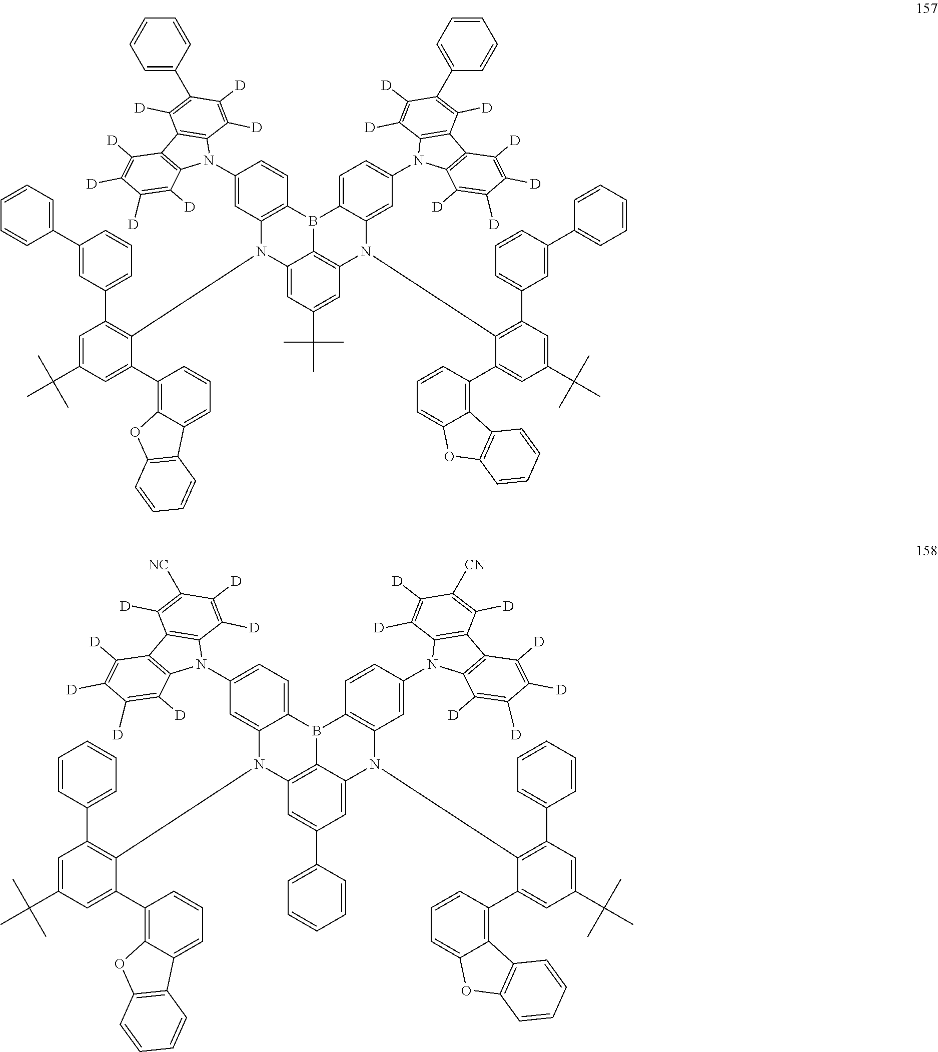

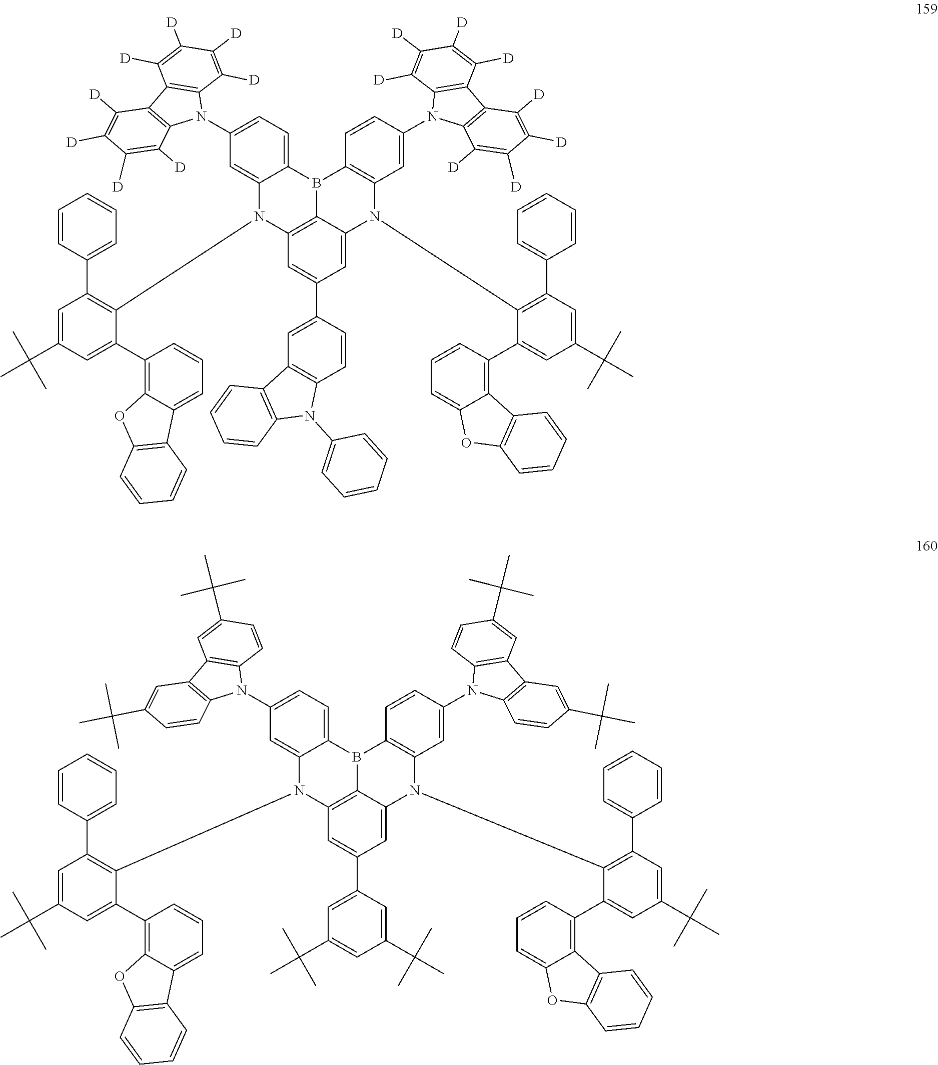

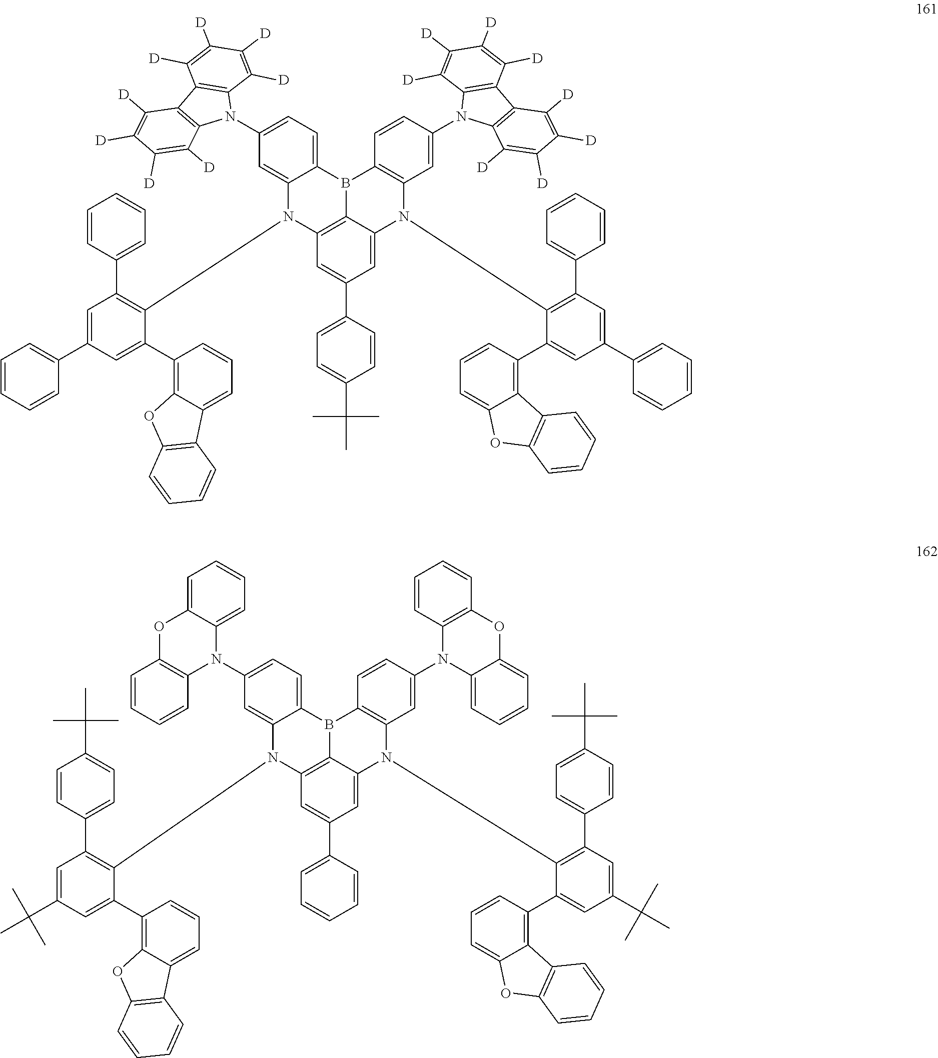

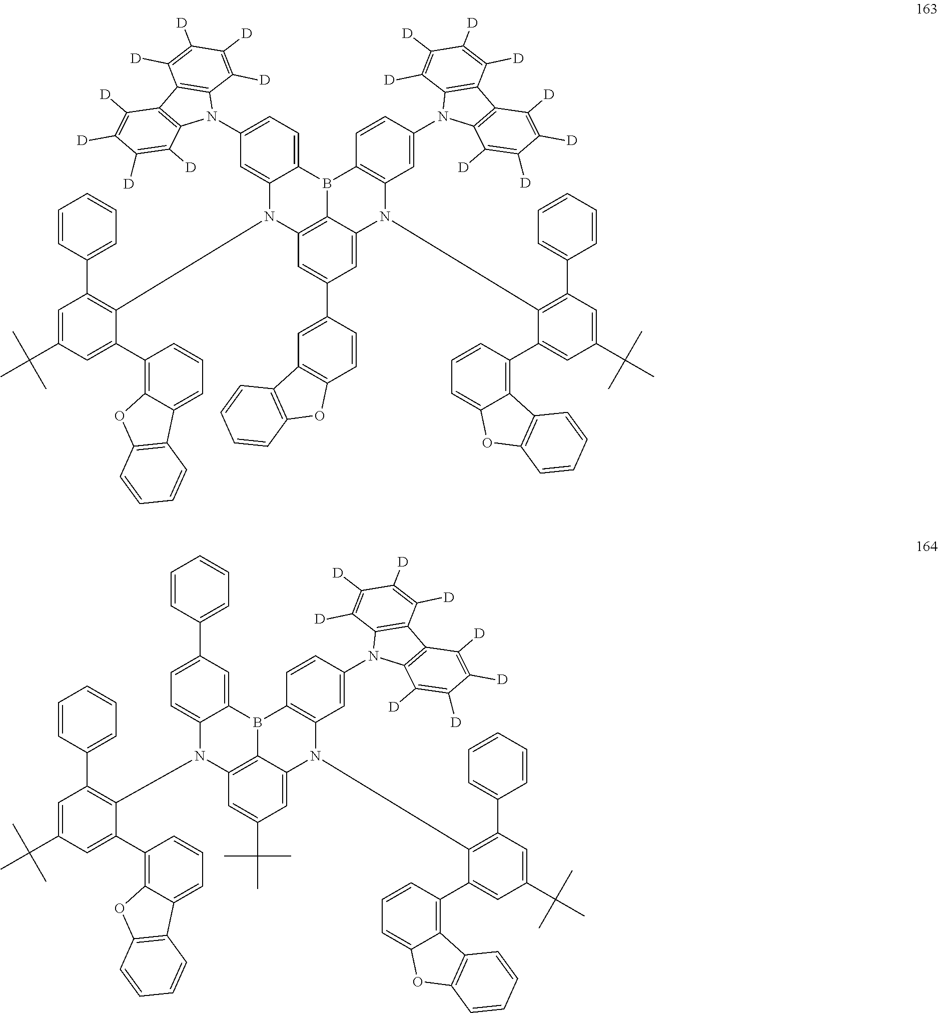

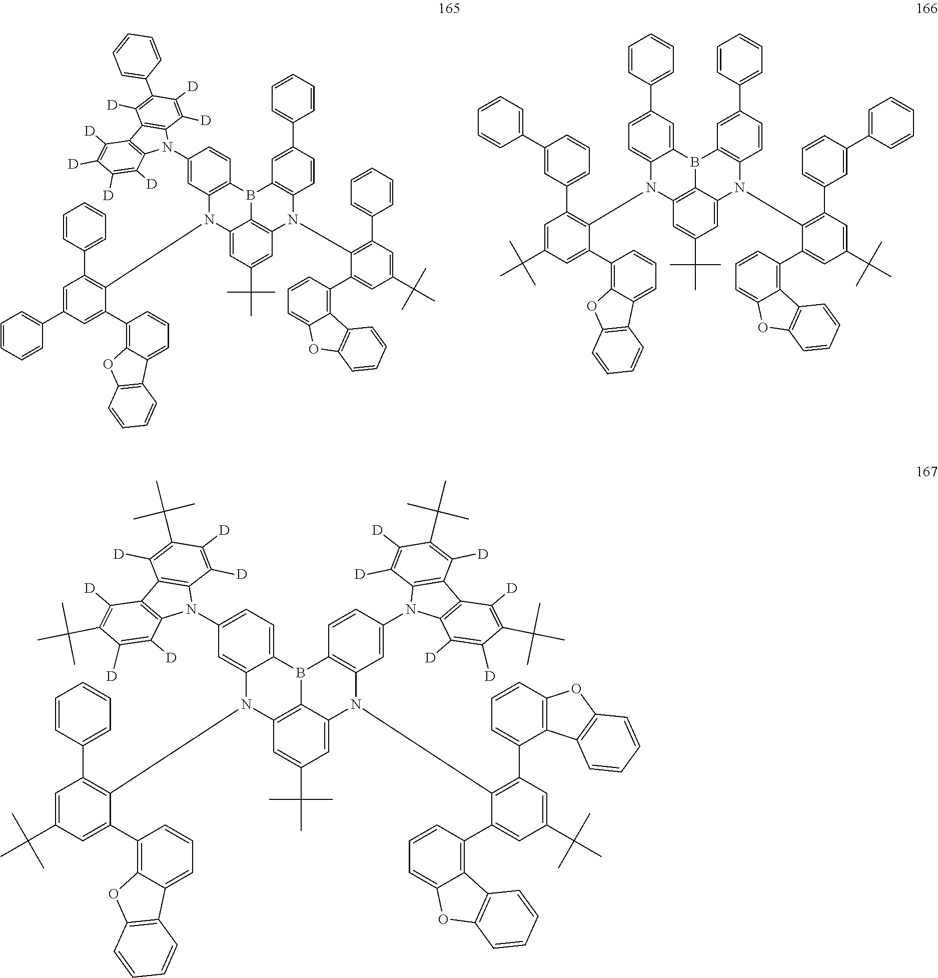

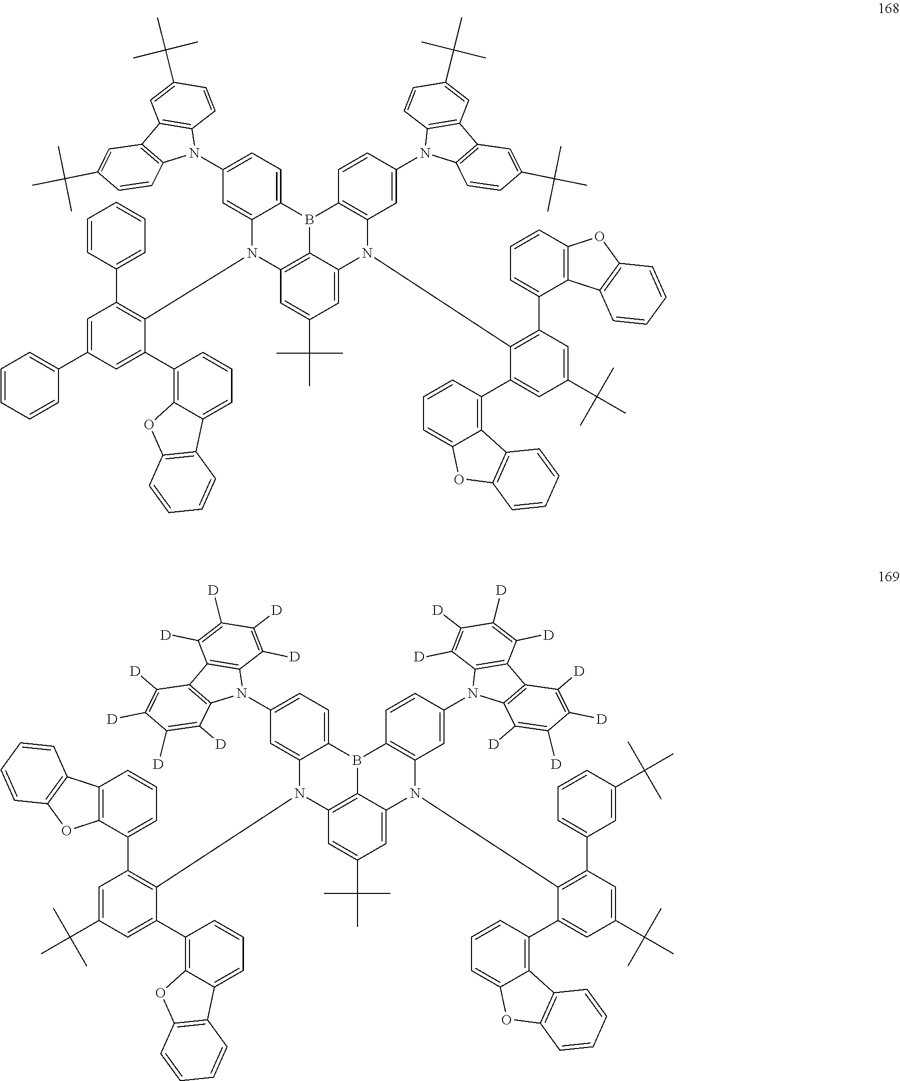

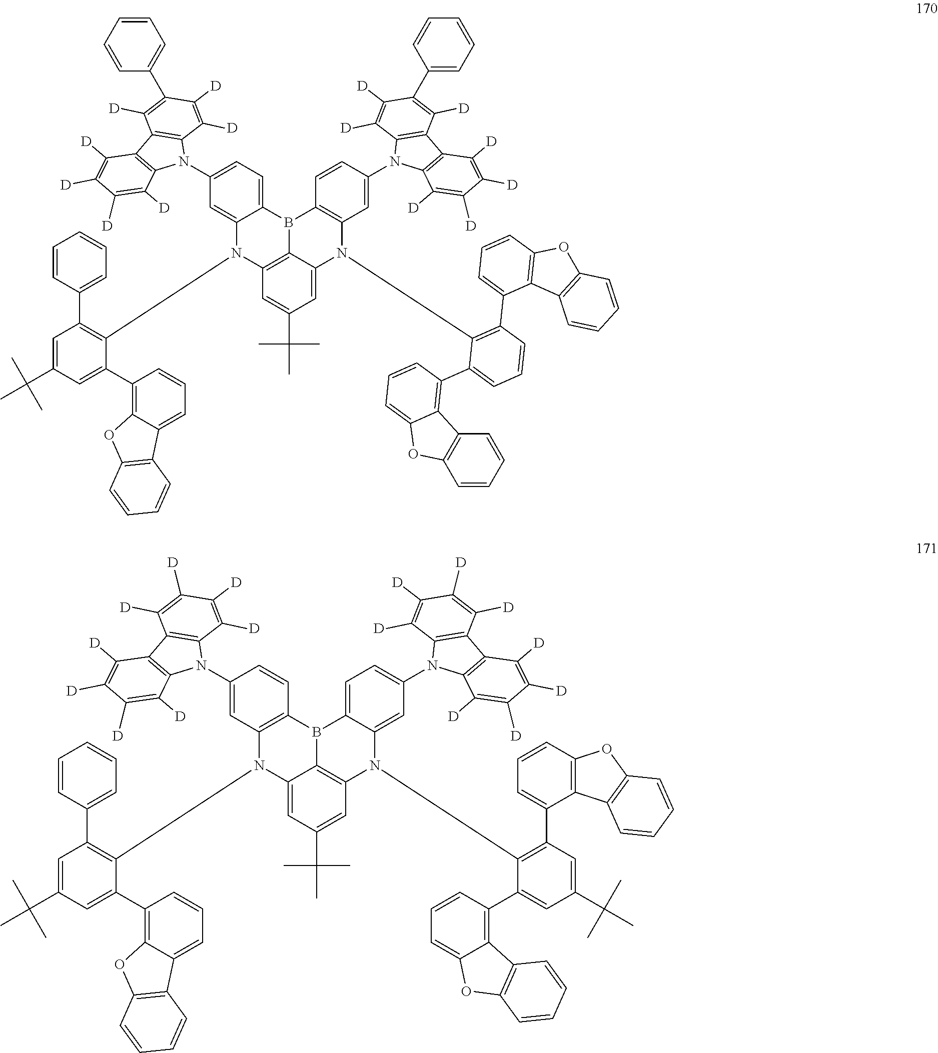

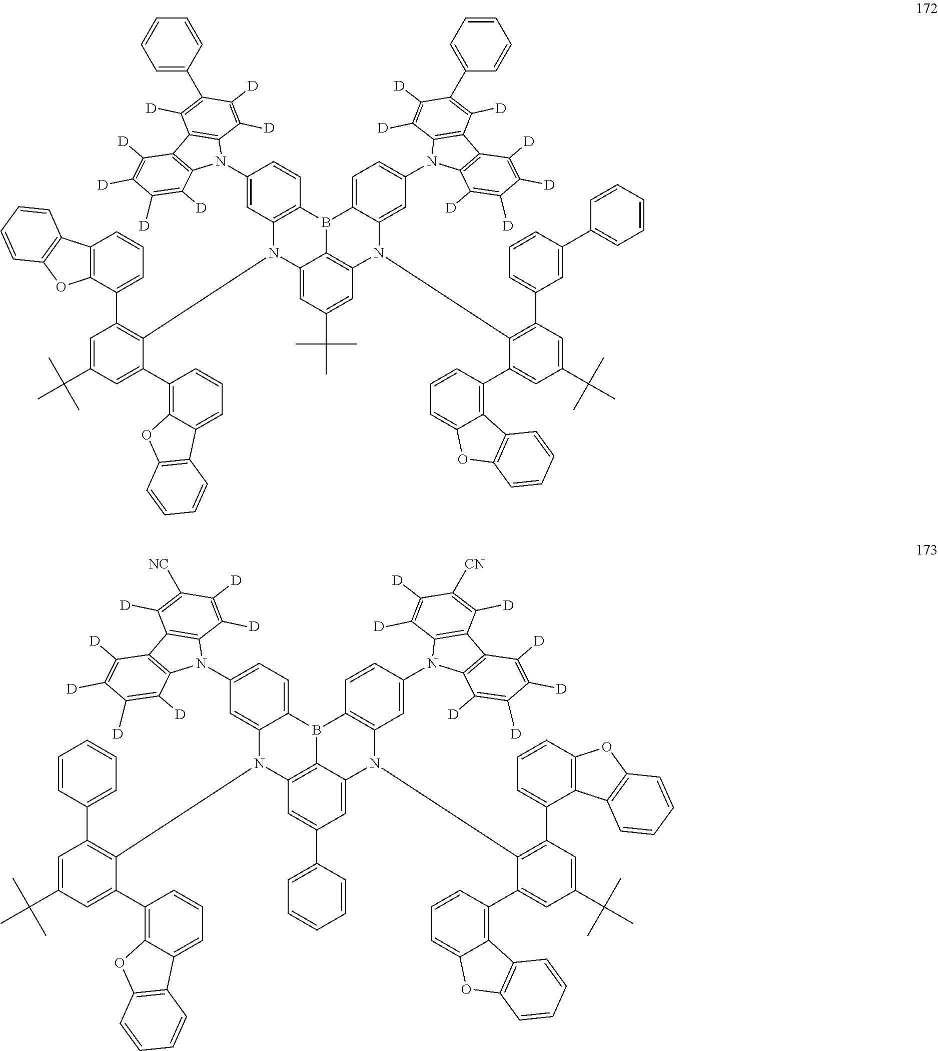

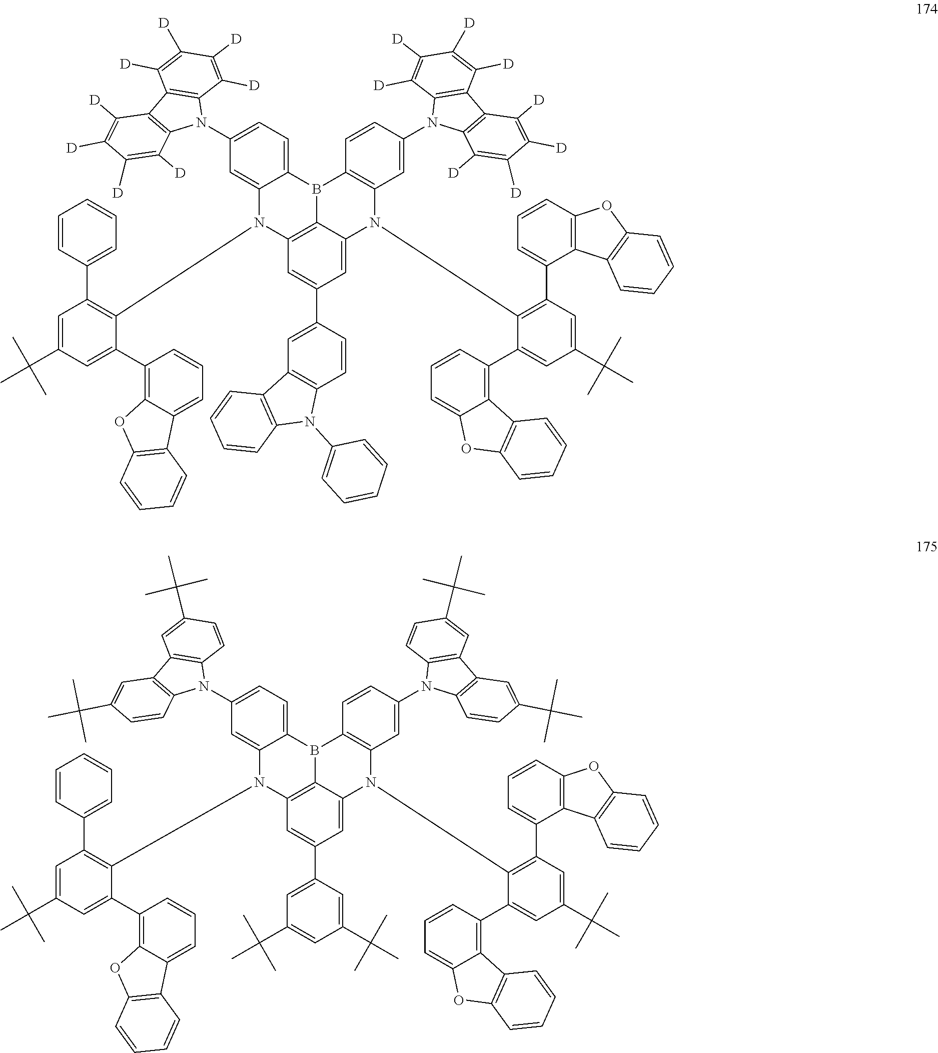

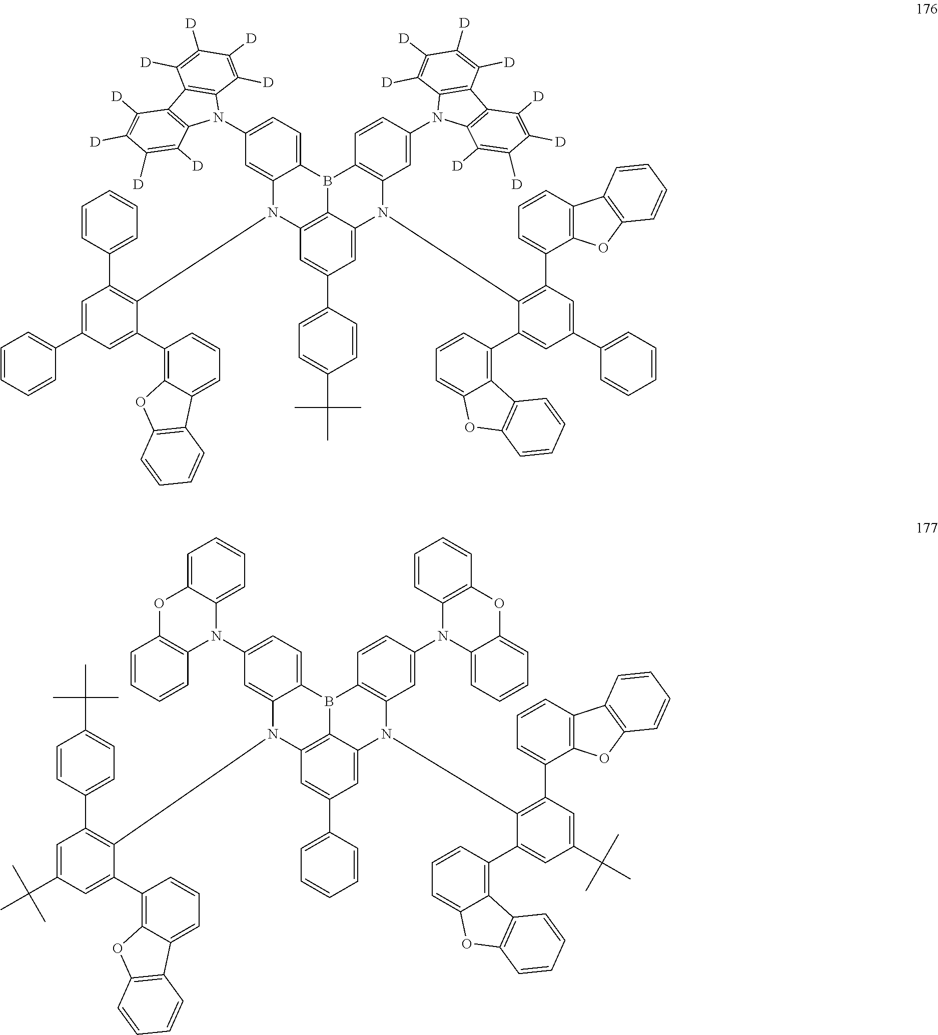

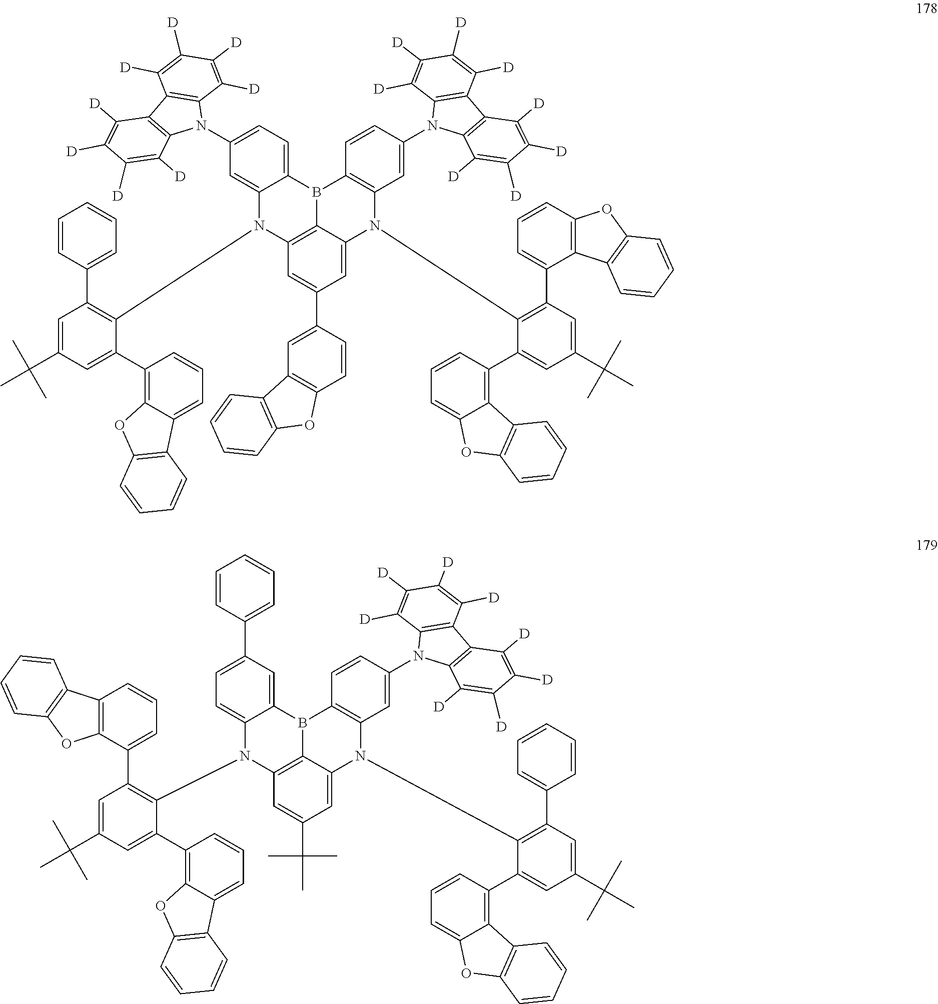

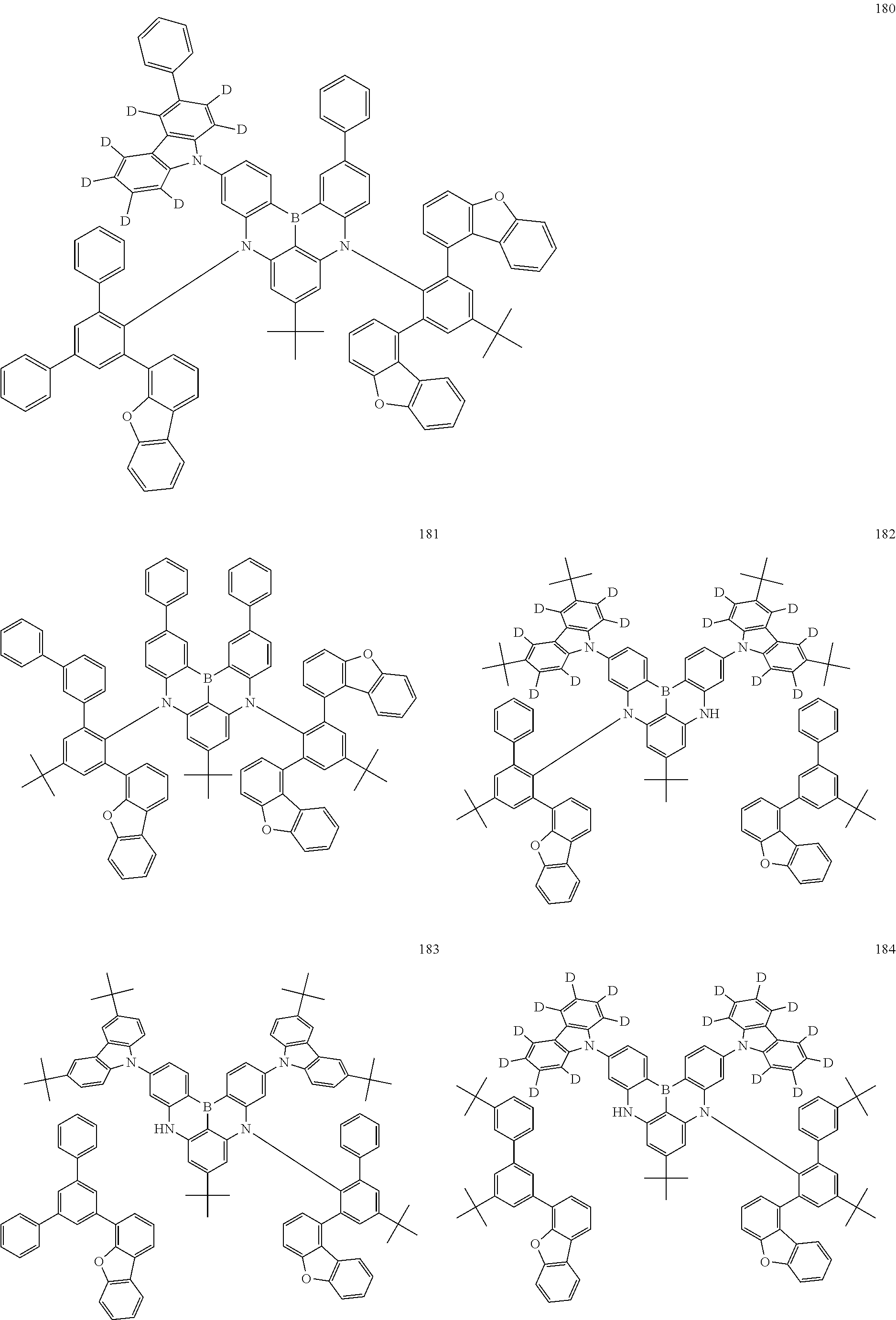

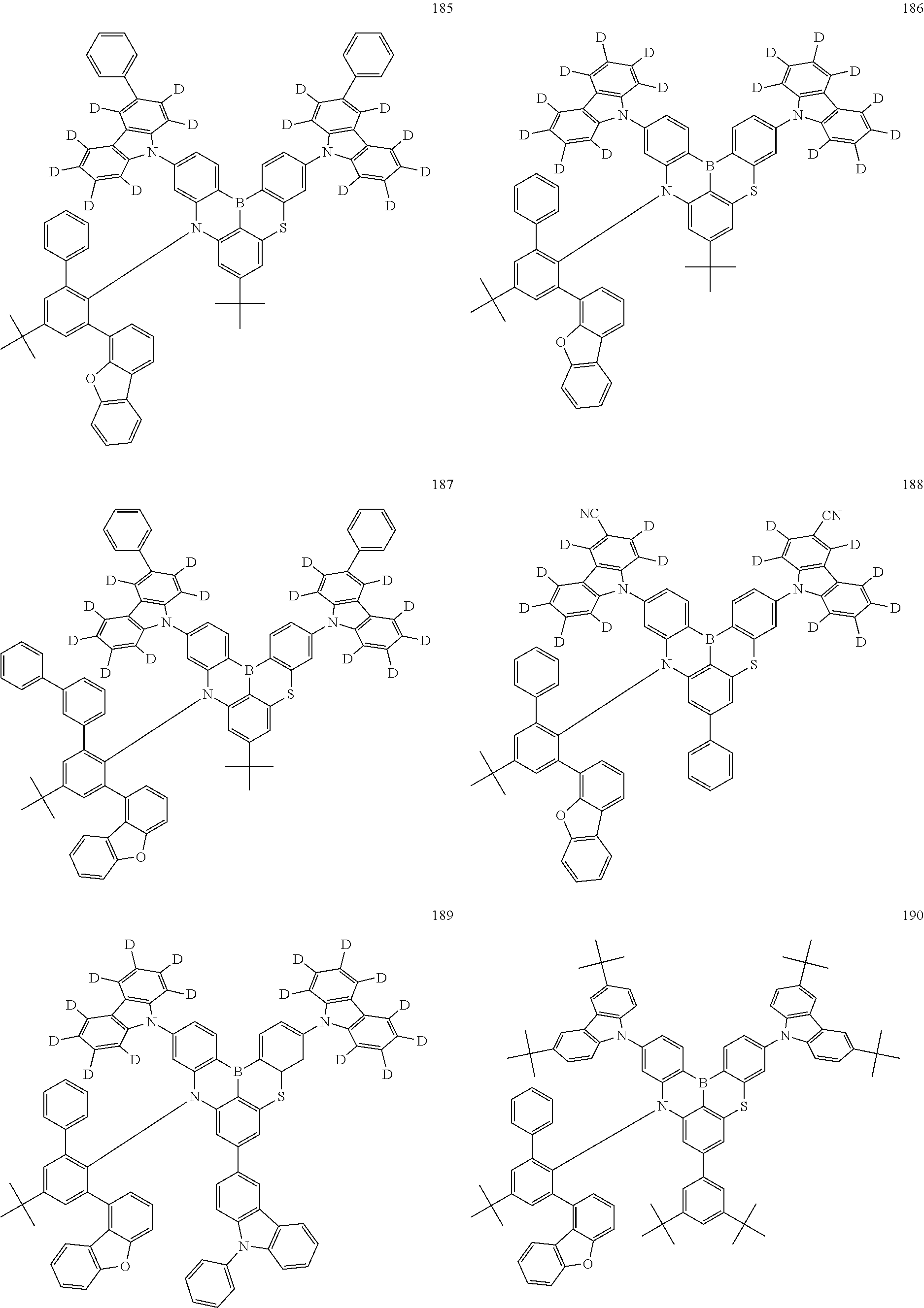

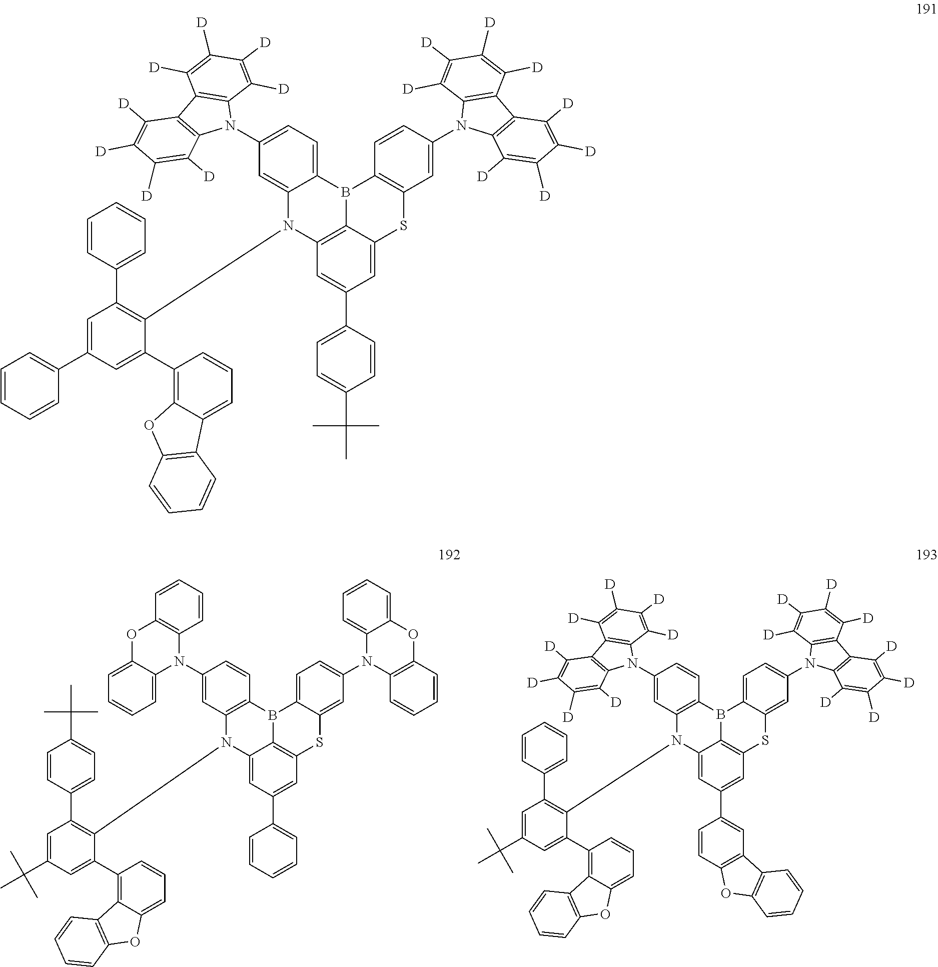

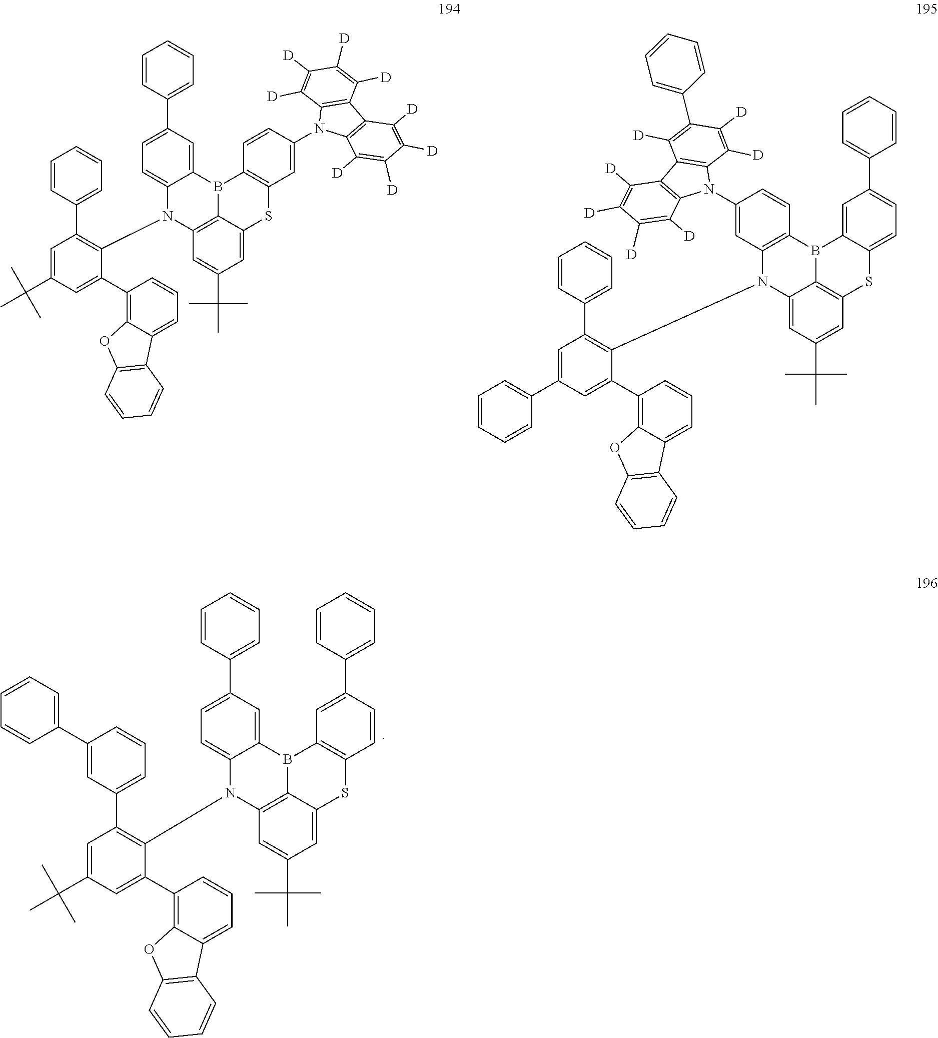 [SMILES: [2H]c1c([2H])c([2H])c2c(c1[2H])c1c([2H])c([2H])c([2H])c([2H])c1n2-c1ccc2c(c1)Sc1cc(C(C)(C)C)cc3c1B2c1cc(-c2ccccc2)ccc1N3c1c(-c2ccccc2)cc(C(C)(C)C)cc1-c1cccc2c1oc1ccccc12 ; [2H]c1c([2H])c([2H])c2c(c1[2H])c1c([2H])c(-c3ccccc3)c([2H])c([2H])c1n2-c1ccc2c(c1)N(c1c(-c3ccccc3)cc(-c3ccccc3)cc1-c1cccc3c1oc1ccccc13)c1cc(C(C)(C)C)cc3c1B2c1cc(-c2ccccc2)ccc1S3 ; CC(C)(C)c1cc(-c2cccc(-c3ccccc3)c2)c(N2c3ccc(-c4ccccc4)cc3B3c4cc(-c5ccccc5)ccc4Sc4cc(C(C)(C)C)cc2c43)c(-c2cccc3c2oc2ccccc23)c1]

14. The light emitting element of claim 1, wherein the emission layer further comprises at least one of a second compound represented by Formula HT-1 and a third compound represented by Formula ET-1: 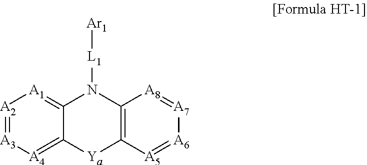
wherein in Formula HT-1,
A₁ to A₈ are each independently N or C(R₄₁),
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, C(R₄₂)(R₄₃), or Si(R₄₄)(R₄₅),
Ar₁ is a substituted or unsubstituted aryl group having 6 to 30 ring-forming carbon atoms or a substituted or unsubstituted heteroaryl group having 2 to 30 ring-forming carbon atoms, and
R₄₁ to R₄₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring; 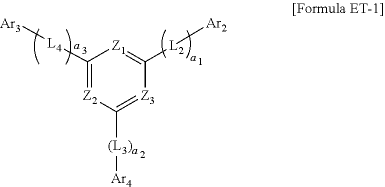
wherein in Formula ET-1,
at least one of Z₁ to Z₃ is each N,
the remainder of Z₁ to Z₃ are each independently C(R₄₆),
R₄₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group of 2 to 60 ring-forming carbon atoms,
a₁ to a₃ are each independently an integer from 0 to 10,
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms,
when a₁ is 2 or greater, L₂ is a substituted or unsubstituted arylene group having 6 to 30 ring-forming carbon atoms or a substituted or unsubstituted heteroarylene group having 2 to 30 ring-forming carbon atoms,
when a₂ is 2 or greater, L₃ is a substituted or unsubstituted arylene group having 6 to 30 ring-forming carbon atoms or a substituted or unsubstituted heteroarylene group having 2 to 30 ring-forming carbon atoms,
when a₃ is 2 or greater, L₄ is a substituted or unsubstituted arylene group having 6 to 30 ring-forming carbon atoms or a substituted or unsubstituted heteroarylene group having 2 to 30 ring-forming carbon atoms, and
Ar₂ to Ar₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

15. The light emitting element of claim 1, wherein the emission layer further includes a fourth compound represented by Formula D-1: 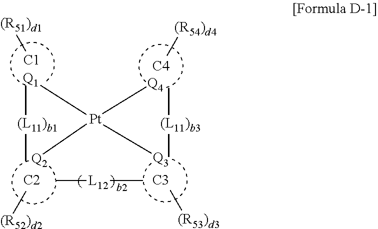
wherein in Formula D-1,
Q₁ to Q₄ are each independently C or N,
C1 to C4 are each independently a substituted or unsubstituted hydrocarbon ring having 5 to 30 ring-forming carbon atoms or a substituted or unsubstituted heterocycle having 2 to 30 ring-forming carbon atoms,
L₁₁ to L₁₃ are each independently a direct linkage, *—O—*, *—S—*, 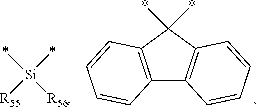
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b1 to b3 are each independently 0 or 1,
R₅₁ to R₅₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
d1 to d4 are each independently an integer from 0 to 4.

16. A fused polycyclic compound represented by Formula 1: 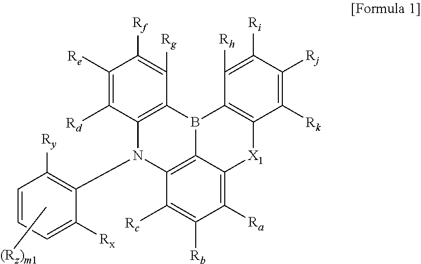
wherein in Formula 1,
X₁ is O, S, or N(R₁),
R₁ is a substituted or unsubstituted aryl group having 6 to 30 ring-forming carbon atoms, or a substituted or unsubstituted heteroaryl group having 2 to 30 ring-forming carbon atoms, or is bonded to an adjacent group to form a ring,
Rₐ to Rₖ and R_{z} are each independently a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
Rₓ and R_{y} are each independently a substituted or unsubstituted aryl group having 6 to 30 ring-forming carbon atoms, a substituted or unsubstituted heteroaryl group having 2 to 30 ring-forming carbon atoms, or a group represented by Formula 2,
m1 is an integer from 0 to 3, and
at least one of Rₓ and R_{y} is each independently a group represented by Formula 2: 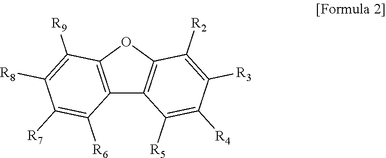
wherein in Formula 2,
R₂ to R₉ are each independently a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
except that one of R₂ and R₅ is a position linked to Formula 1.

17. The fused polycyclic compound of claim 16, wherein the group represented by Formula 2 is represented by Formula 2-1 or Formula 2-2: 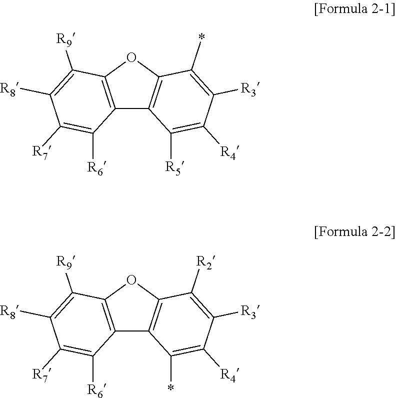
wherein in Formula 2-1 and Formula 2-2,
R₂′ to R₉′ are each independently a hydrogen atom, a deuterium atom, or a substituted or unsubstituted phenyl group, and
-* is a position linked to Formula 1.

18. The fused polycyclic compound of claim 16, wherein the fused polycyclic compound represented by Formula 1 is represented by one of Formula 1-1 to Formula 1-3: 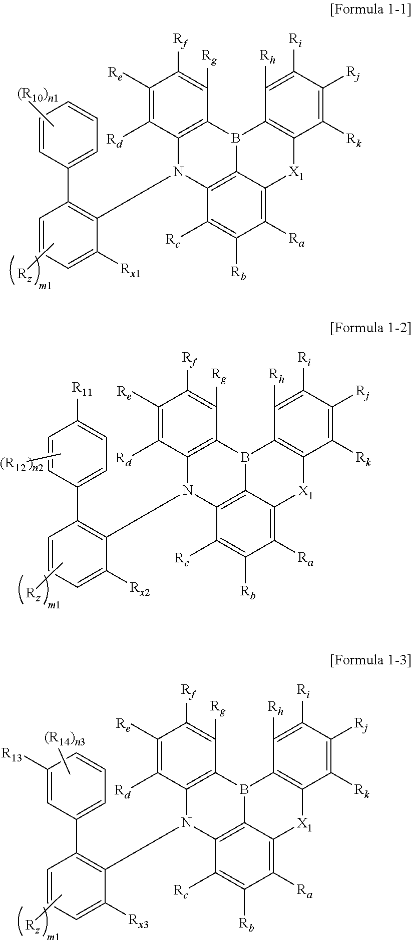
wherein in Formula 1-1 to Formula 1-3,
Rₓ₁ to Rₓ3 are each independently a group represented by Formula 2,
R₁₀, R₁₂, and R₁₄ are each independently a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₁₁ and R₁₃ are each independently a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n1 is an integer from 0 to 5,
n2 and n3 are each independently an integer from 0 to 4, and
Rₐ to Rₖ, R_{z}, m1, and X₁ are the same as defined in Formula 1.

19. The fused polycyclic compound of claim 16, wherein the fused polycyclic compound represented by Formula 1 is represented by Formula 3: 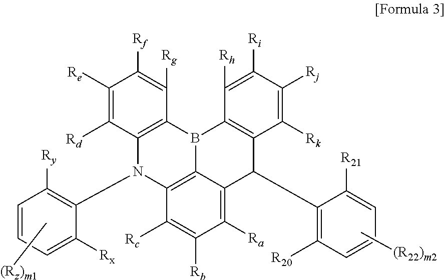
wherein in Formula 3,
R₂₀ and R₂₁ are each independently a substituted or unsubstituted aryl group having 6 to 30 ring-forming carbon atoms, a substituted or unsubstituted heteroaryl group having 2 to 30 ring-forming carbon atoms, or a group represented by Formula 2,
R₂₂ is a hydrogen atom, a deuterium atom, a halogen atom, a cyano group, a nitro group, a substituted or unsubstituted amine group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or is bonded to an adjacent group to form a ring,
m2 is an integer from 0 to 3, and
Rₐ to Rₖ, Rₓ, R_{y}, R_{z}, and m1 are the same as defined in Formula 1.

20. The fused polycyclic compound of claim 16, wherein the fused polycyclic compound is selected from Compound Group 1: 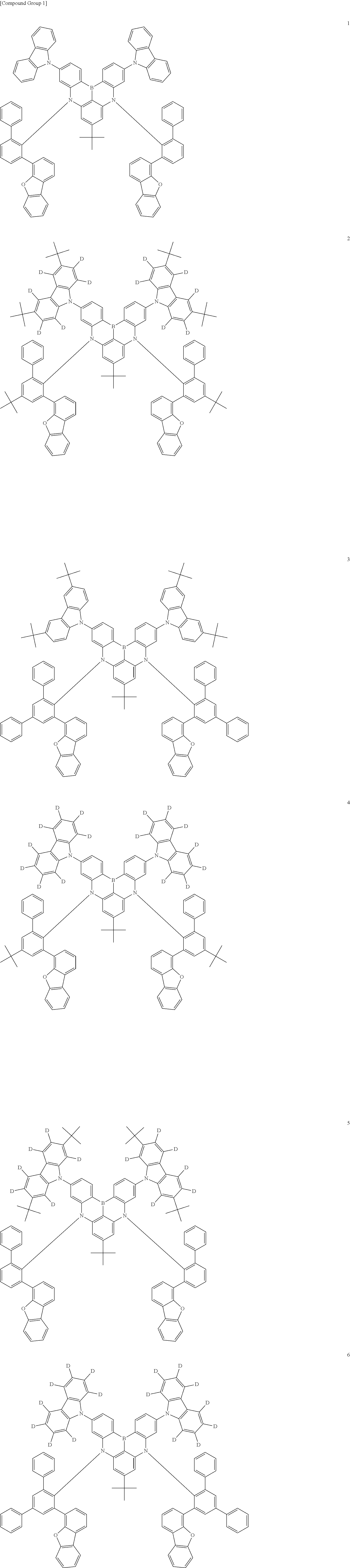 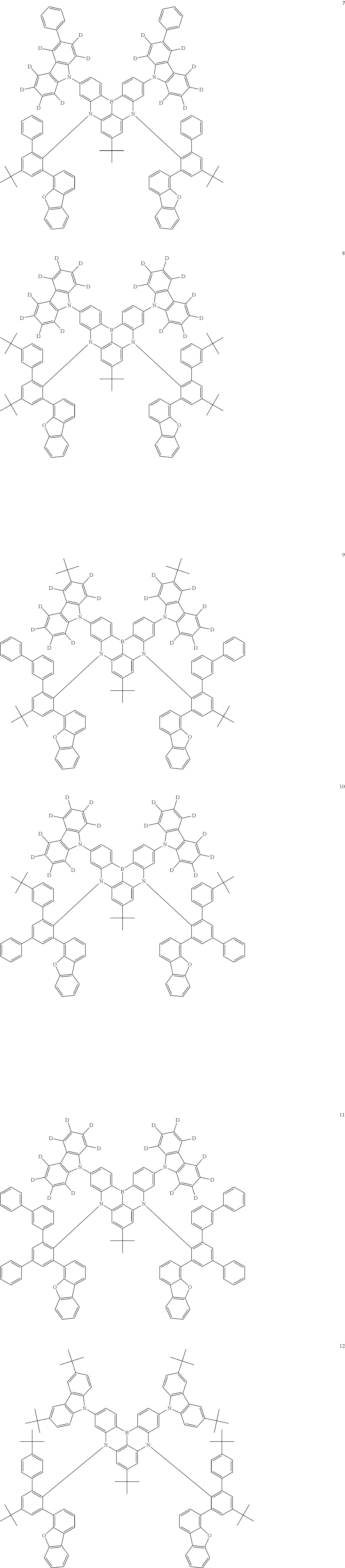 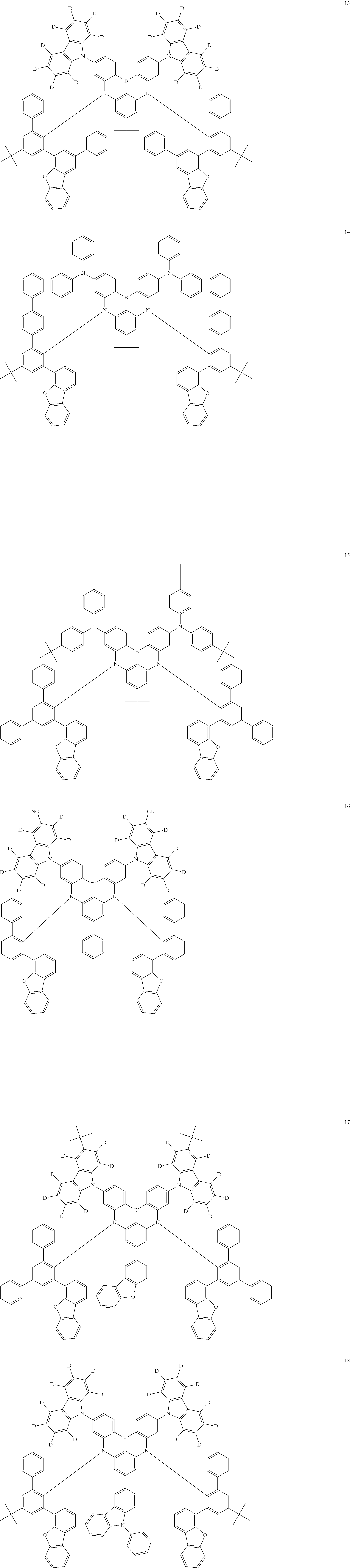 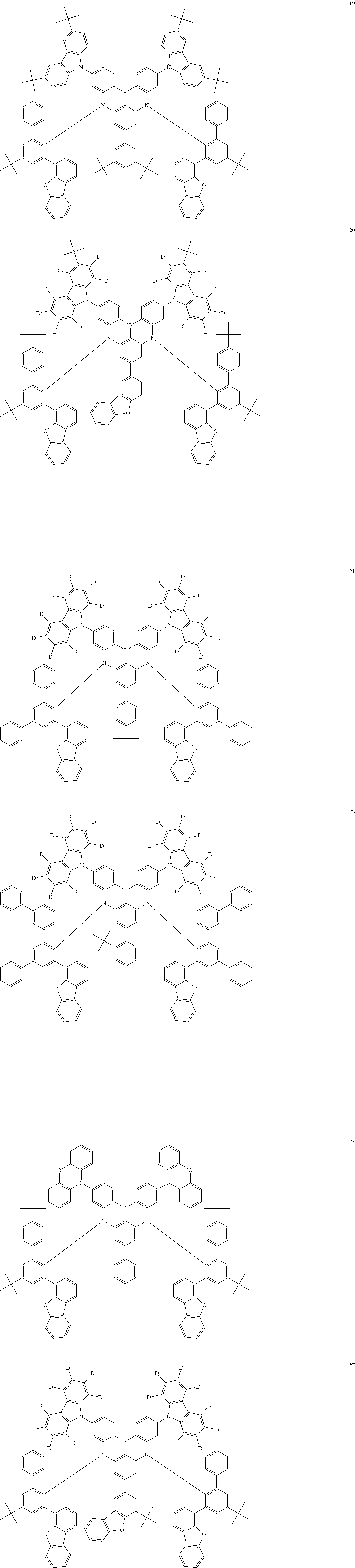 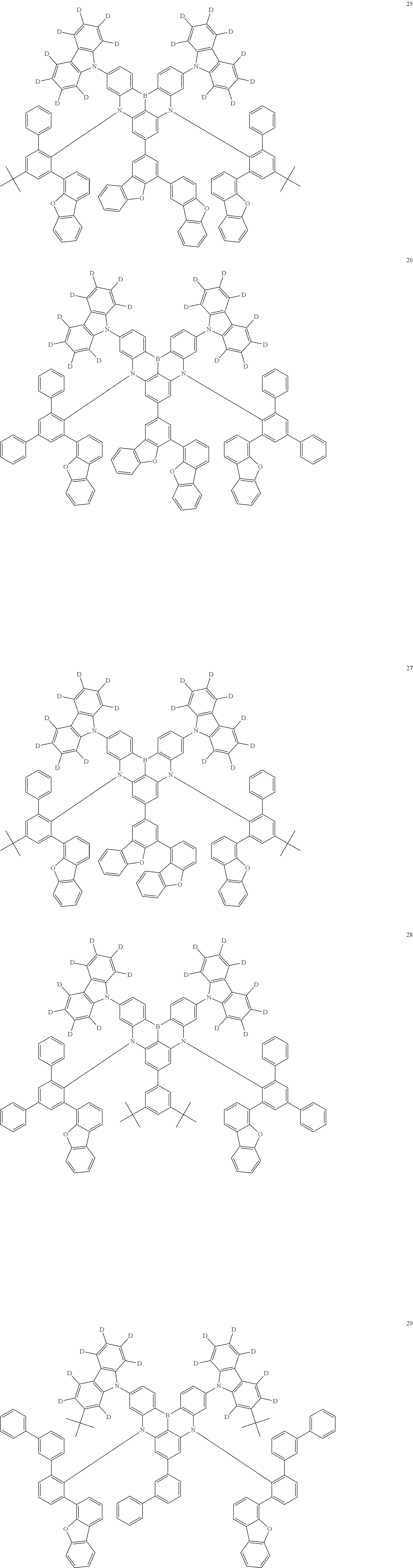 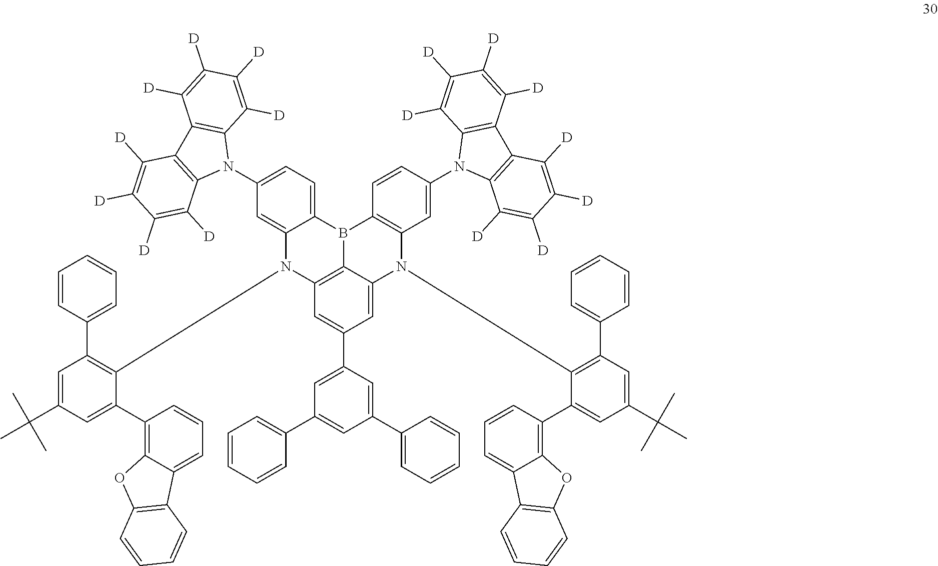 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc3c1oc1ccccc13)c1cc(-c3cc(-c4ccccc4)cc(-c4ccccc4)c3)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1cccc2c1oc1ccccc12] [chemical structure] 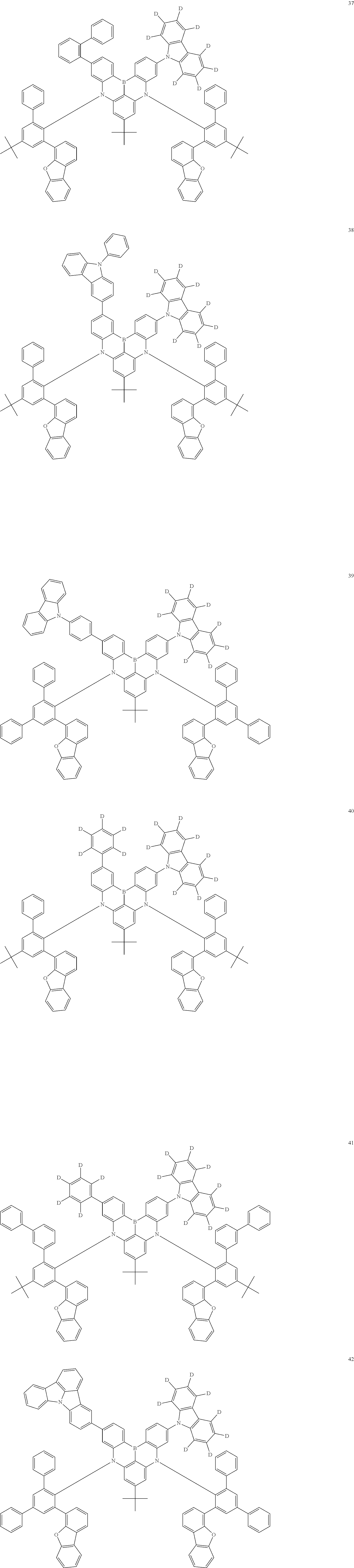 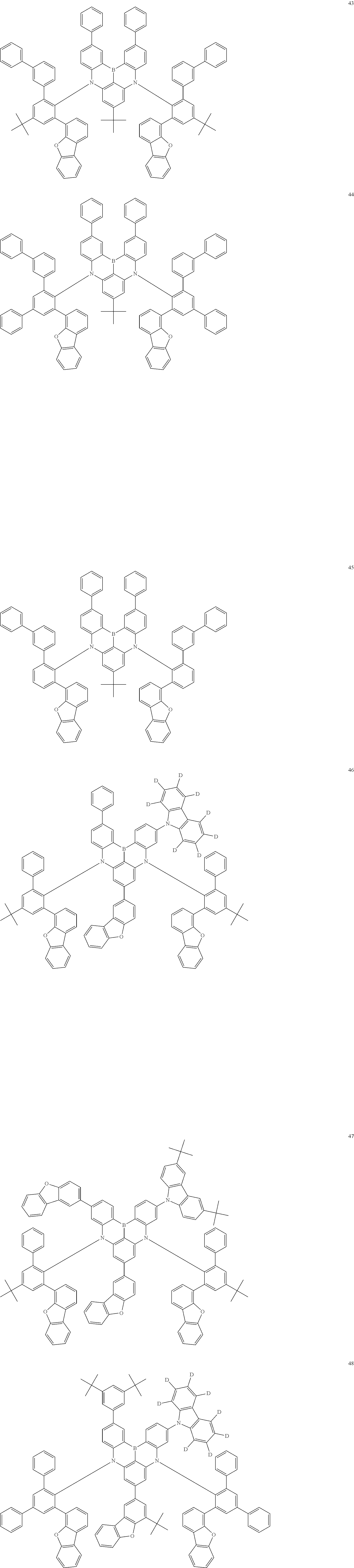 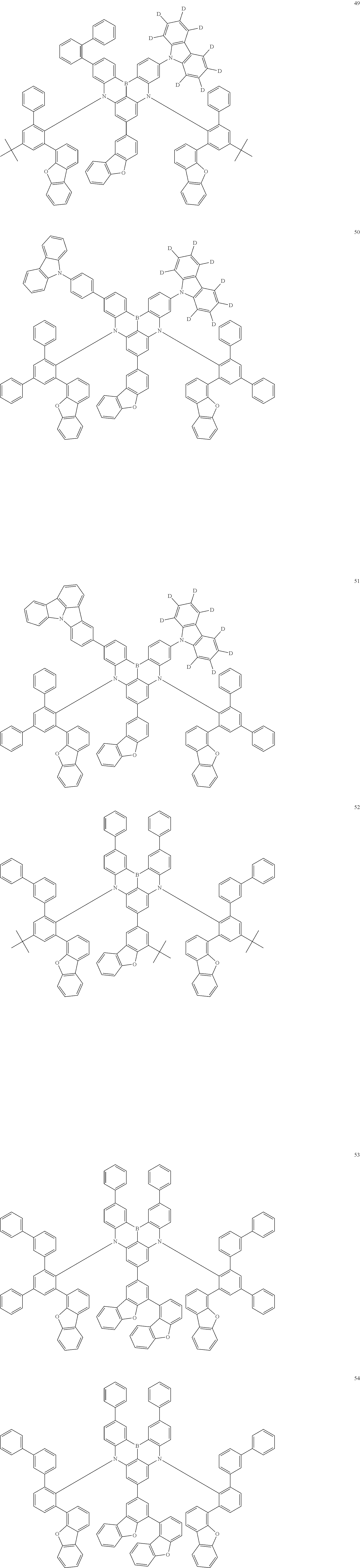 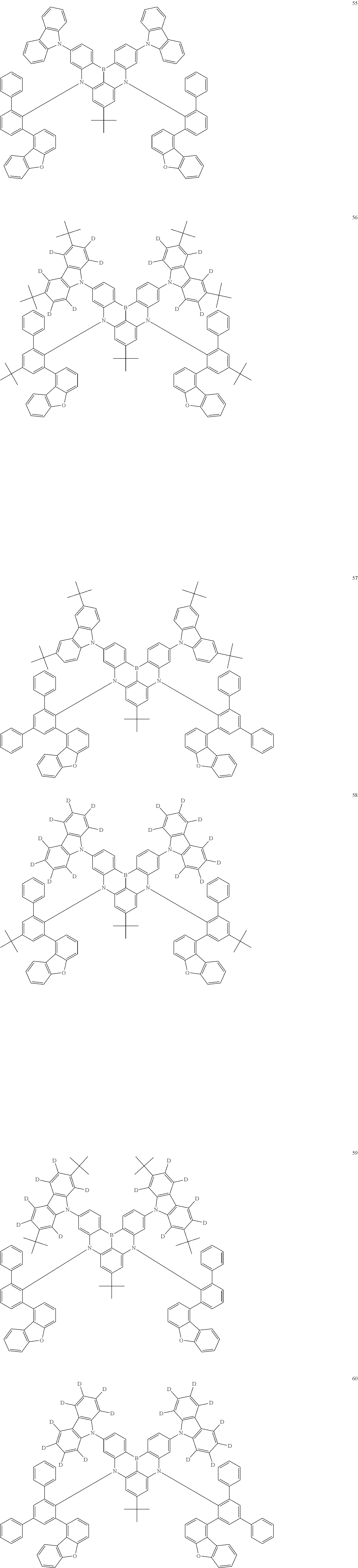 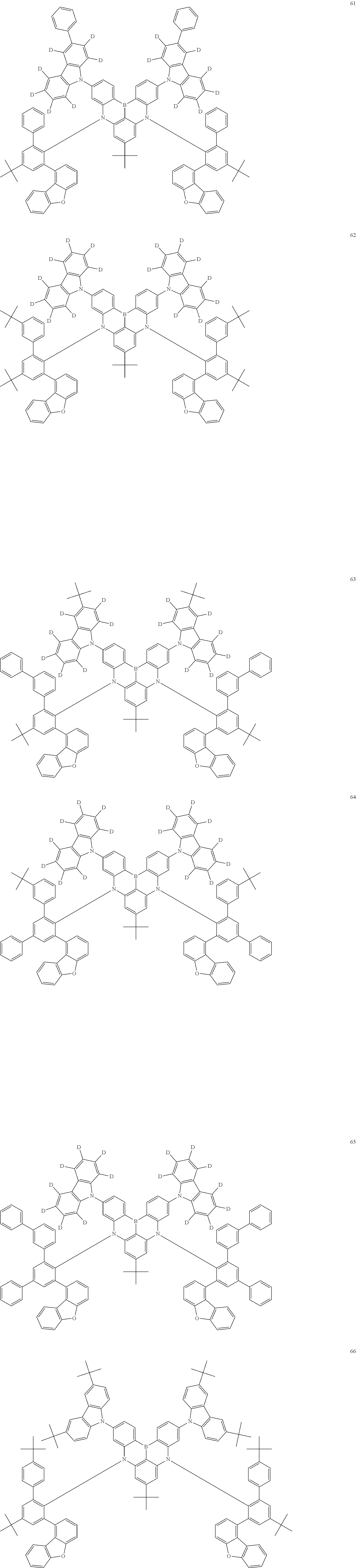 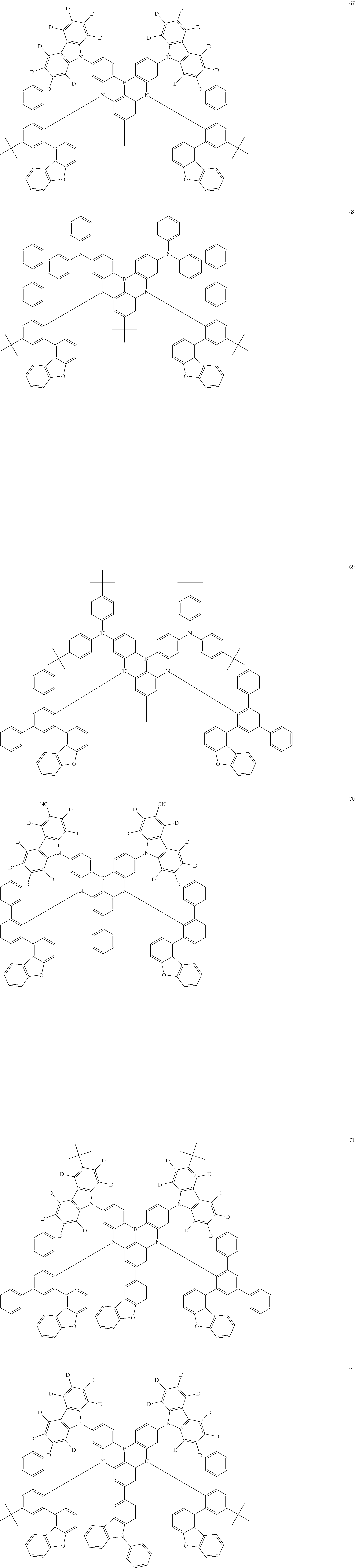 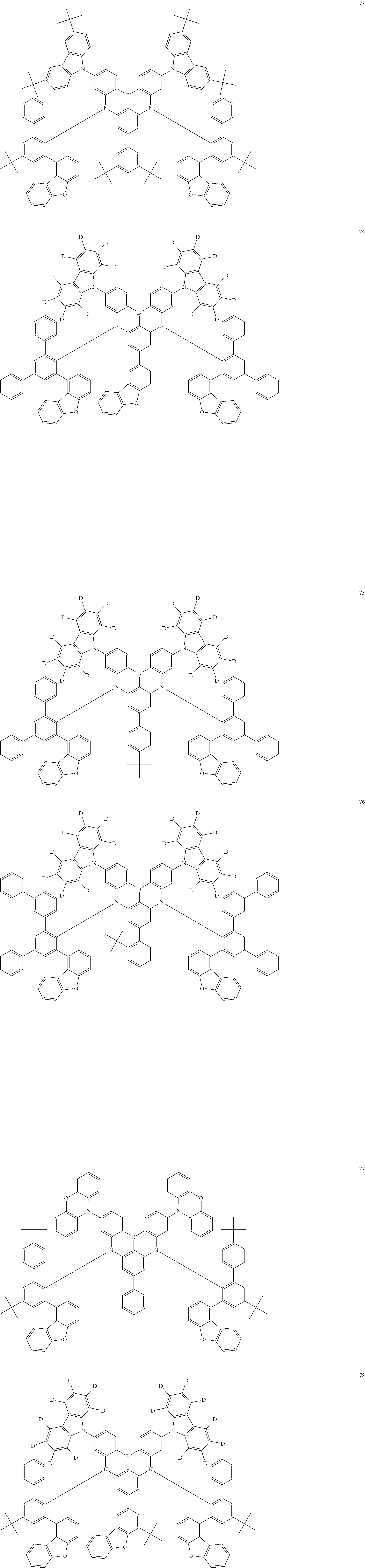 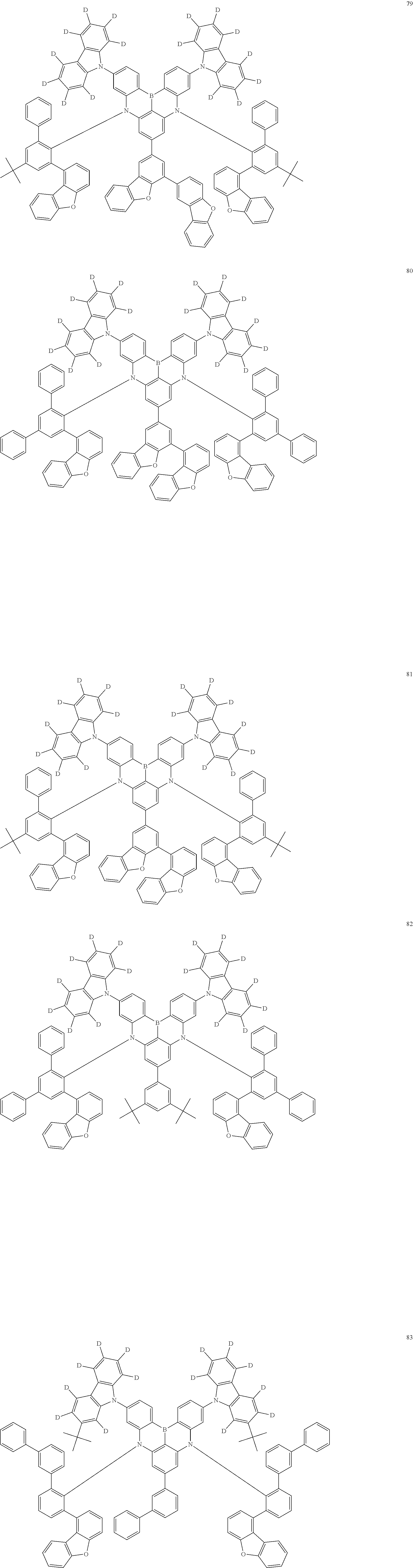 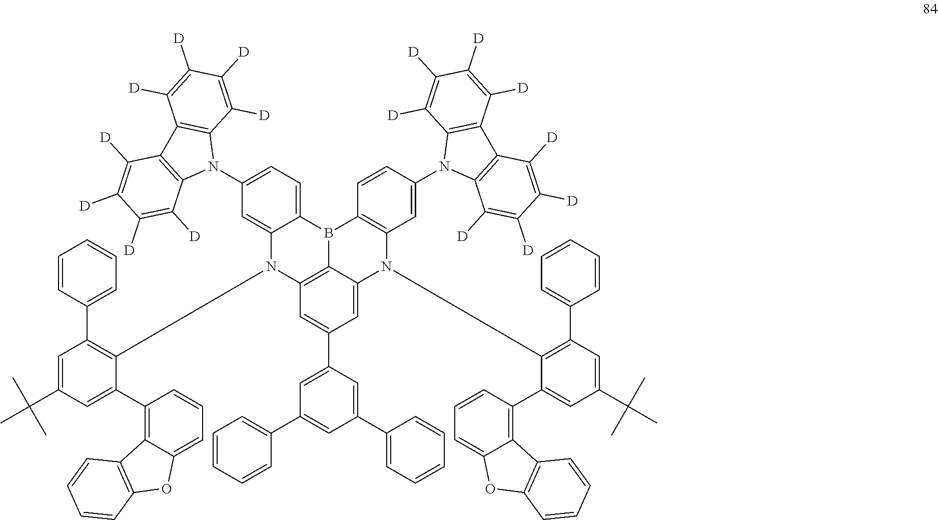 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cccc3oc4ccccc4c13)c1cc(-c3cc(-c4ccccc4)cc(-c4ccccc4)c3)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1cccc2oc3ccccc3c12] 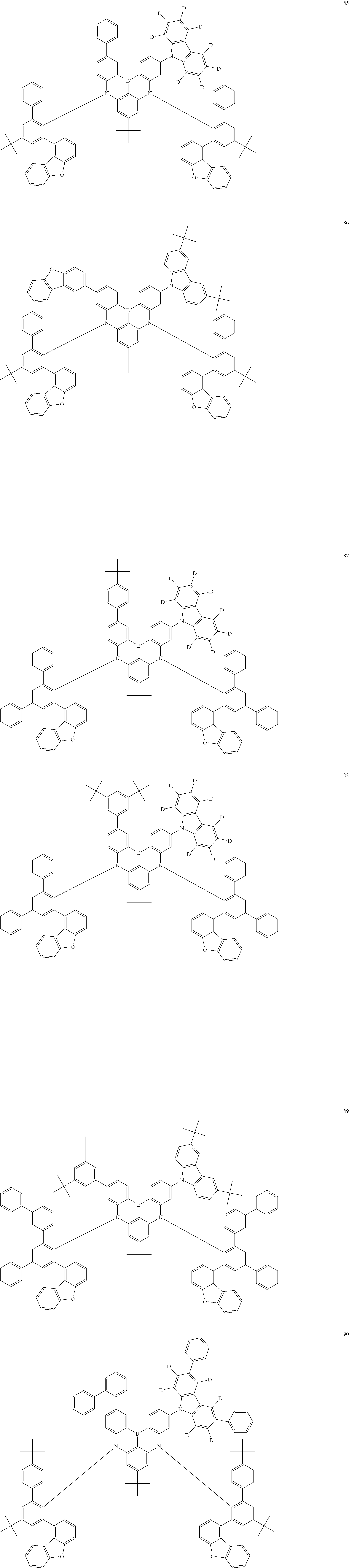 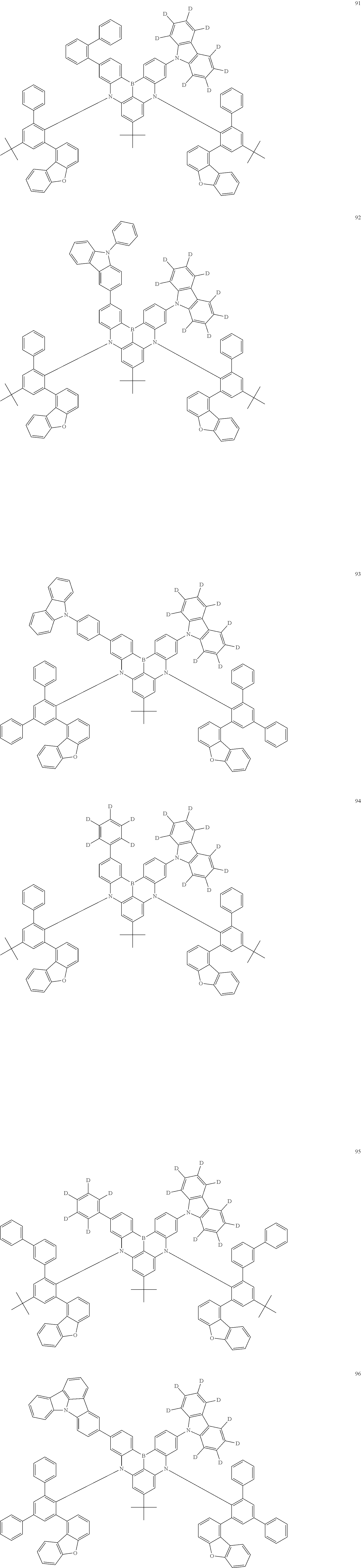 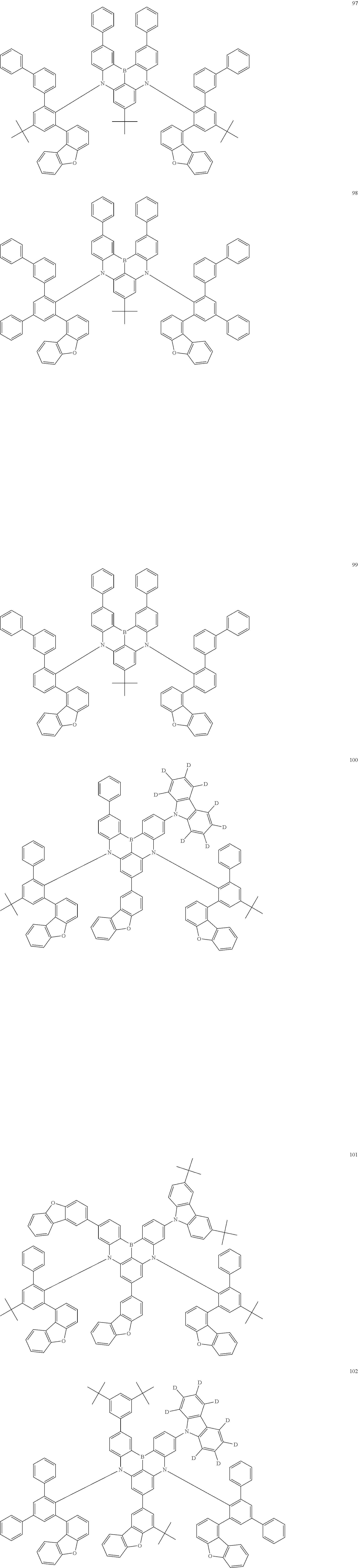 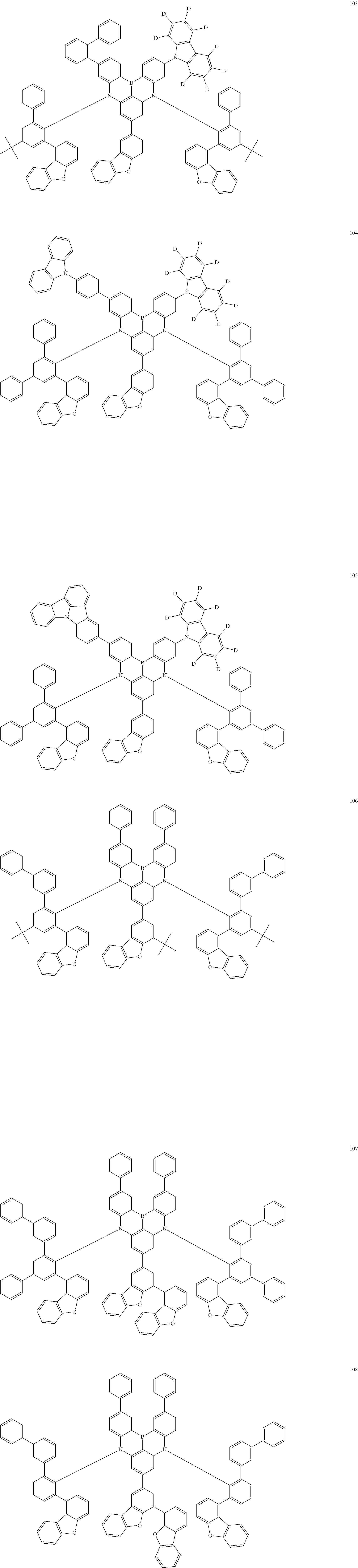 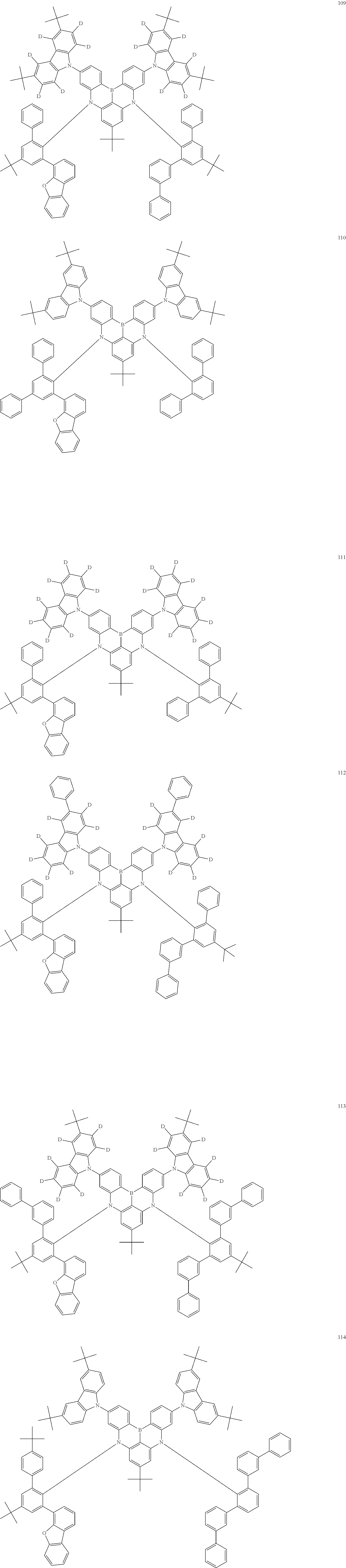 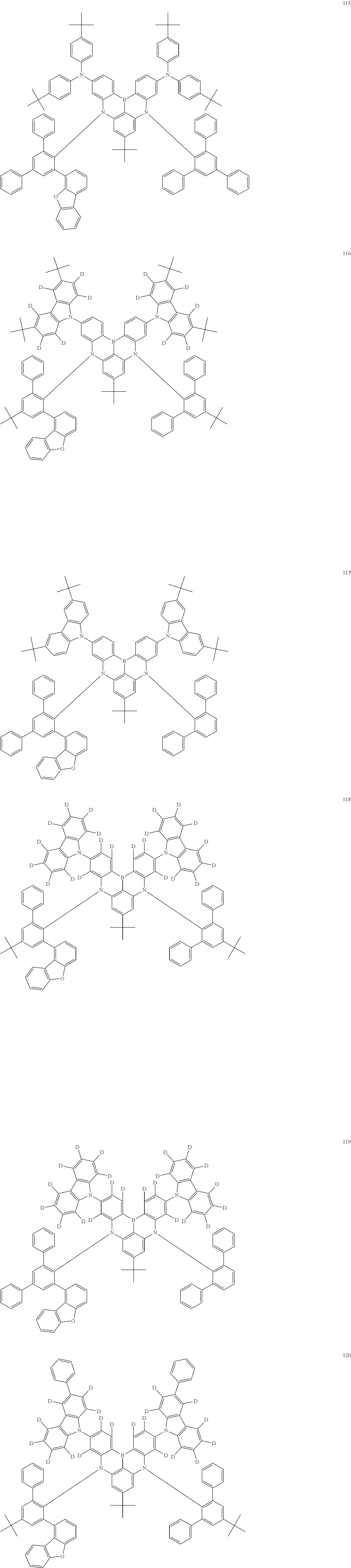 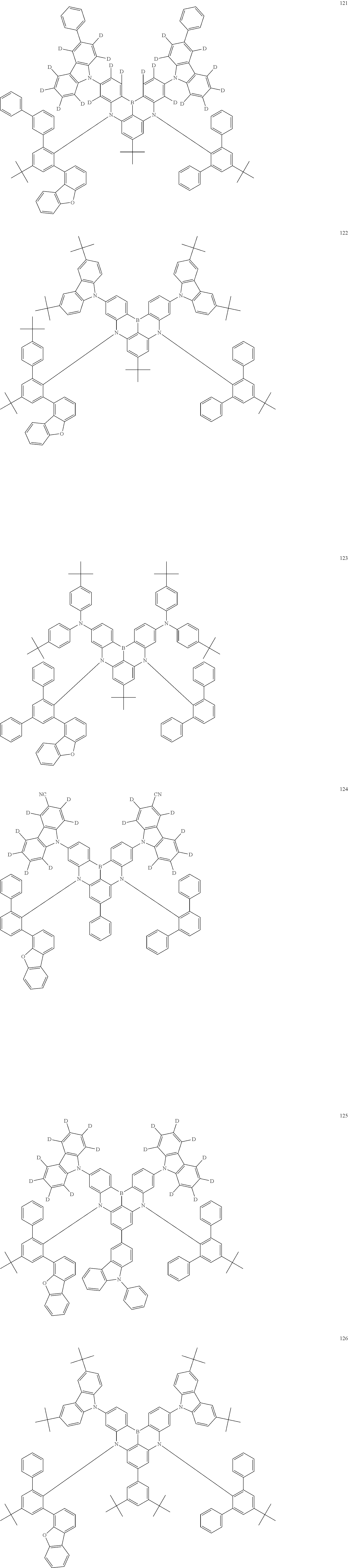 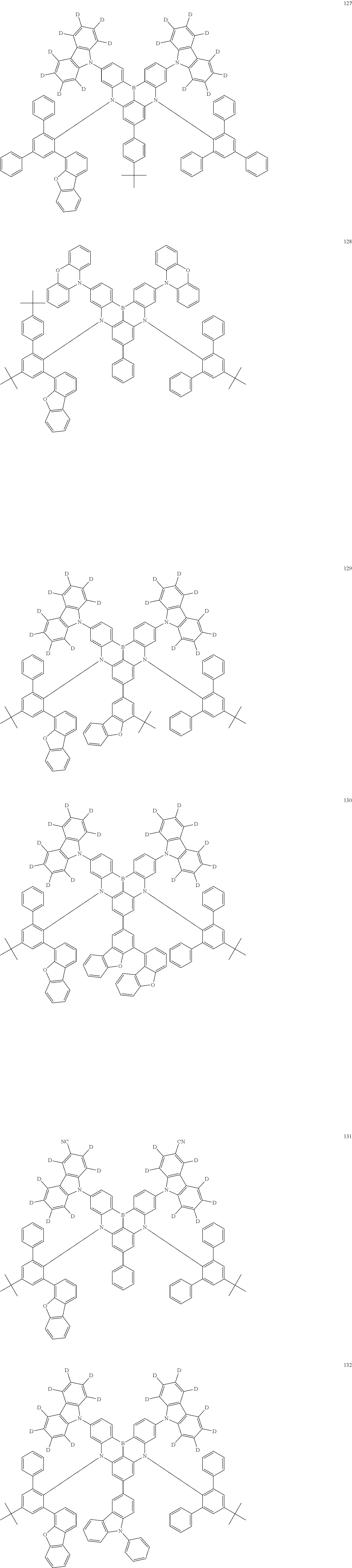 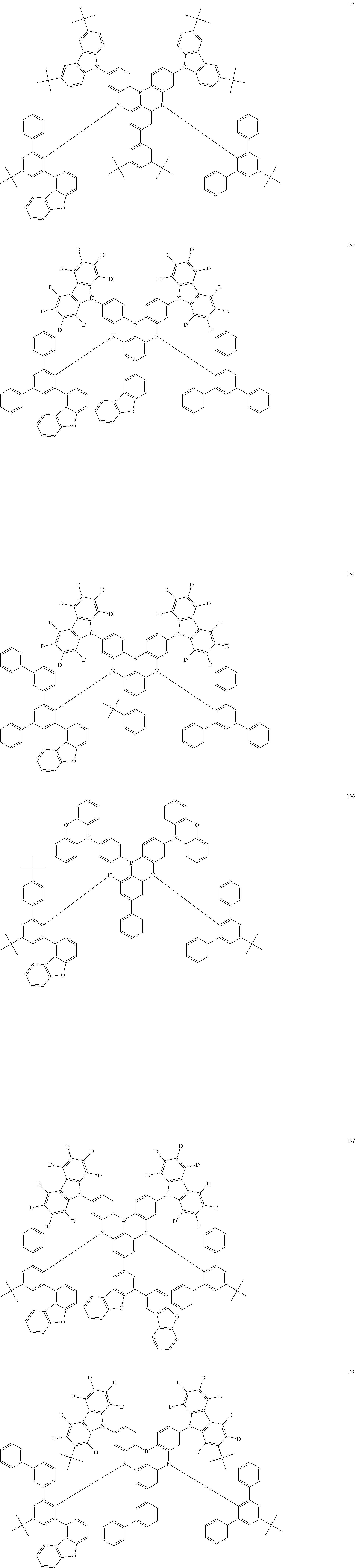 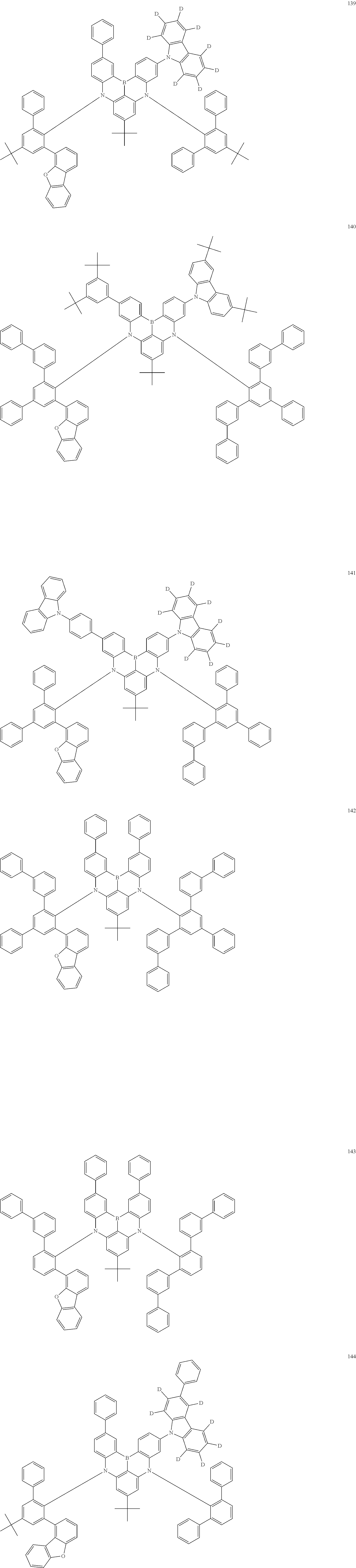 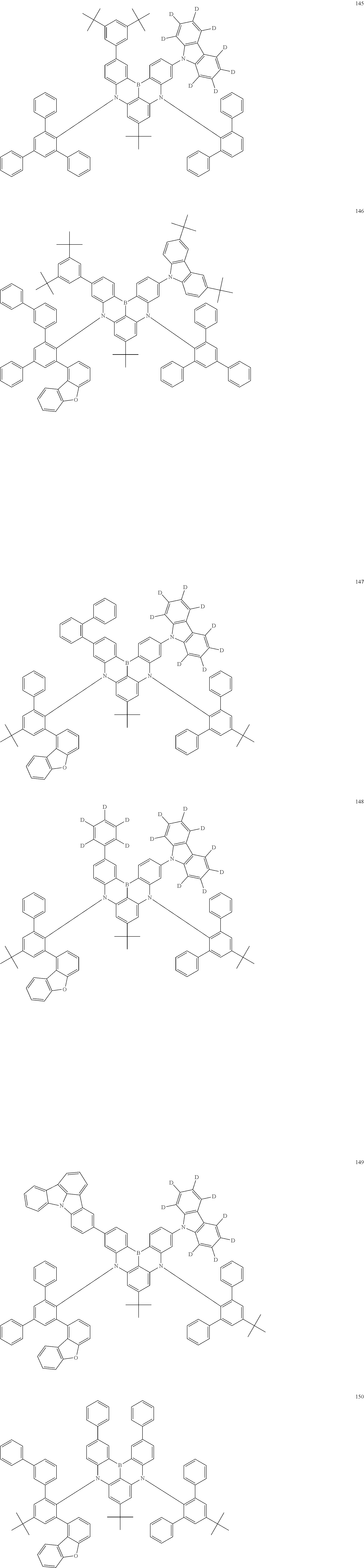 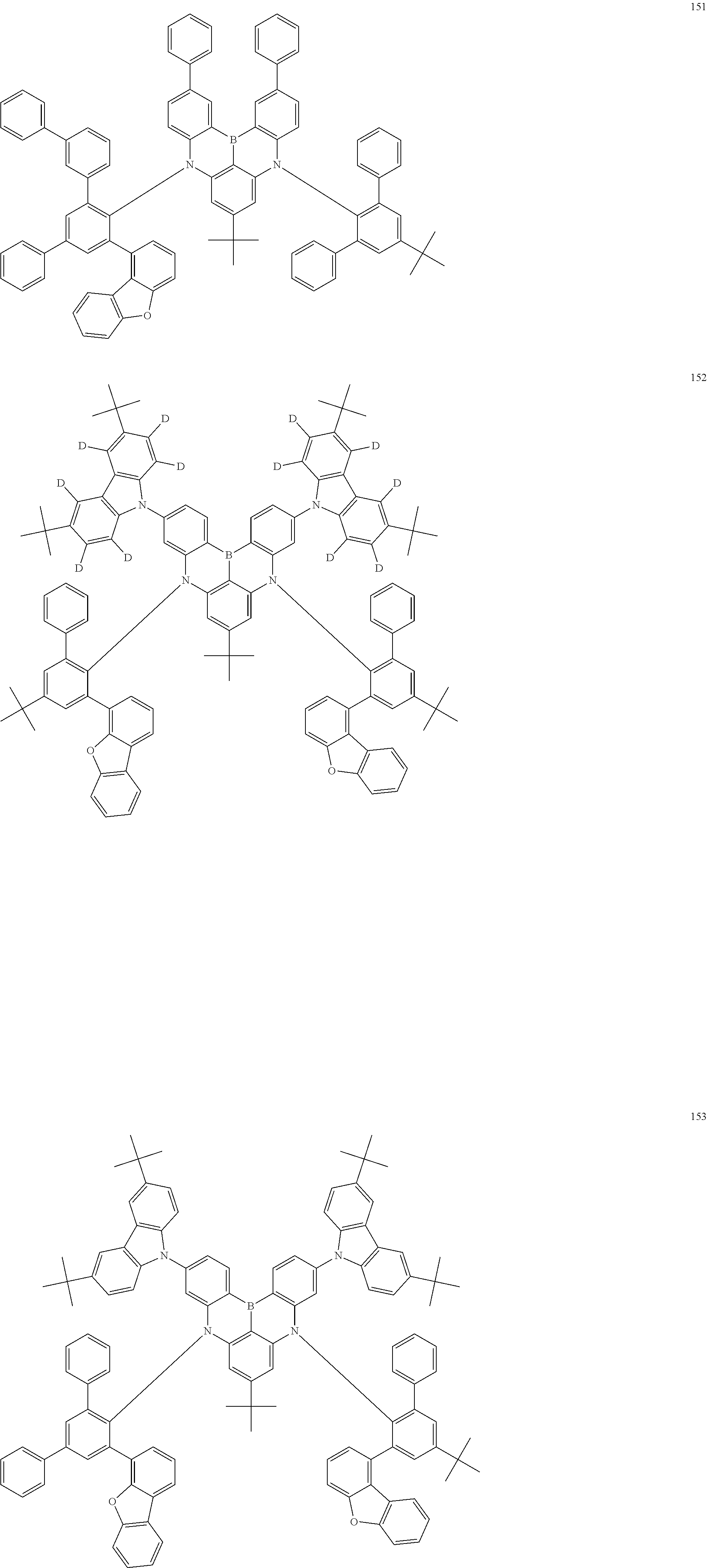 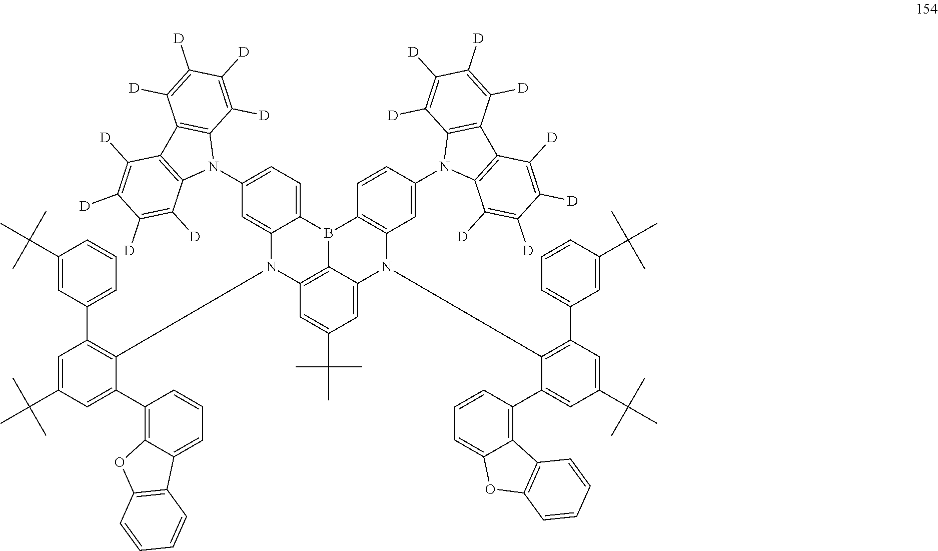 [SMILES: [2H]c1c([2H])c([2H])c2c(c1[2H])c1c([2H])c([2H])c([2H])c([2H])c1n2-c1ccc2c(c1)N(c1c(-c3cccc(C(C)(C)C)c3)cc(C(C)(C)C)cc1-c1cccc3c1oc1ccccc13)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2cccc(C(C)(C)C)c2)cc(C(C)(C)C)cc1-c1cccc2oc3ccccc3c12] 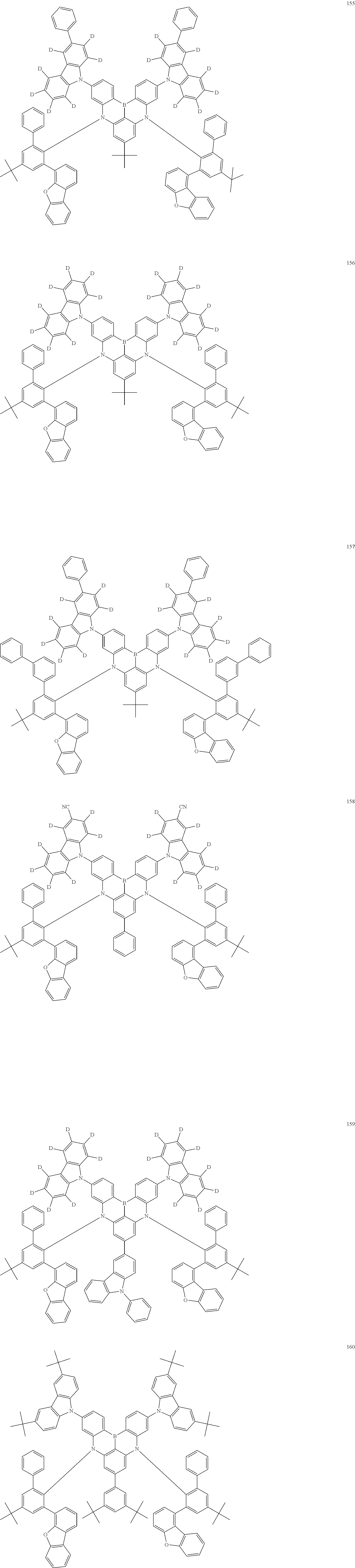 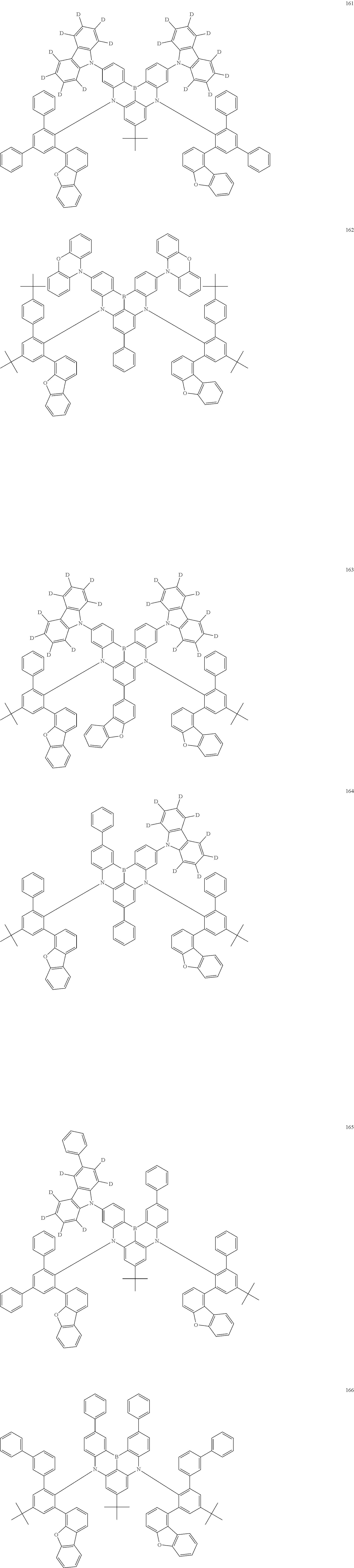 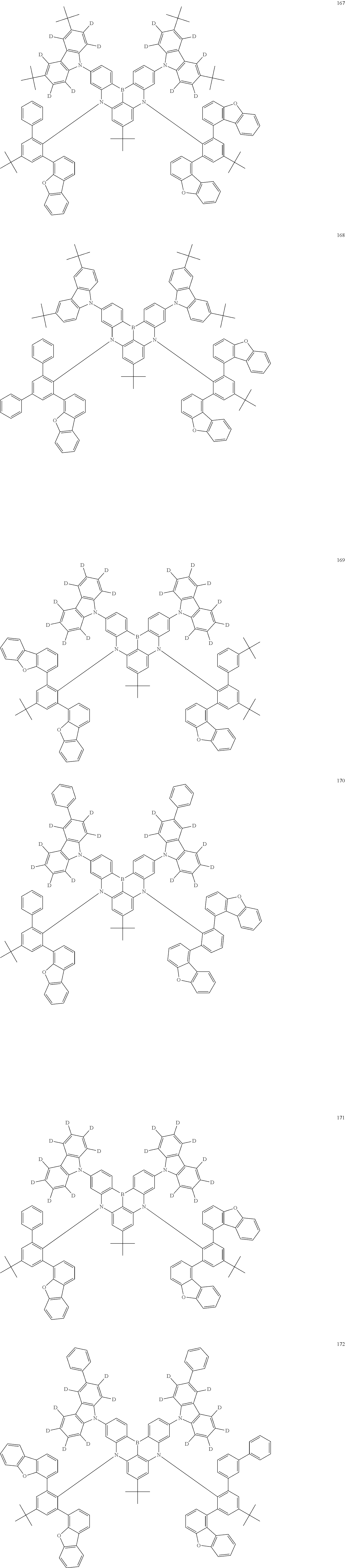 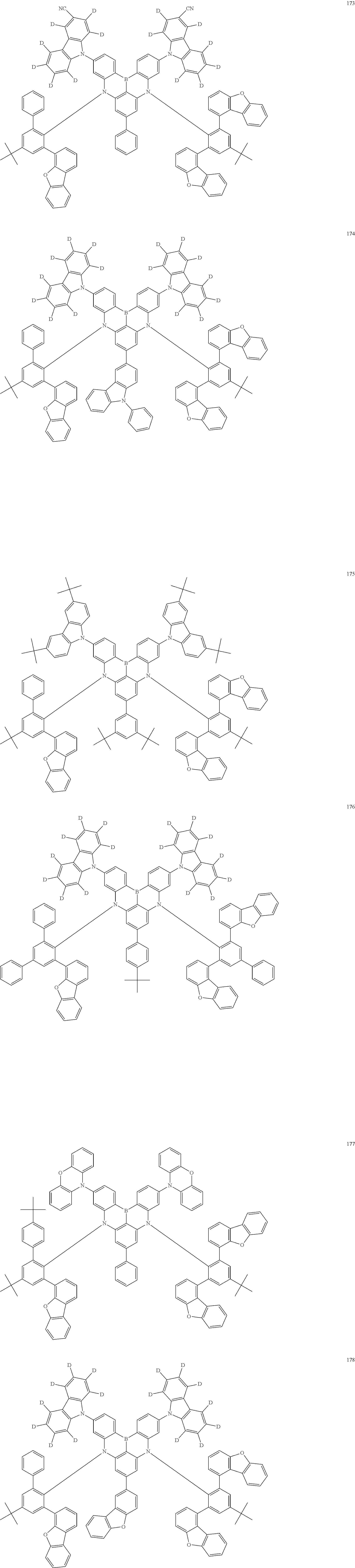 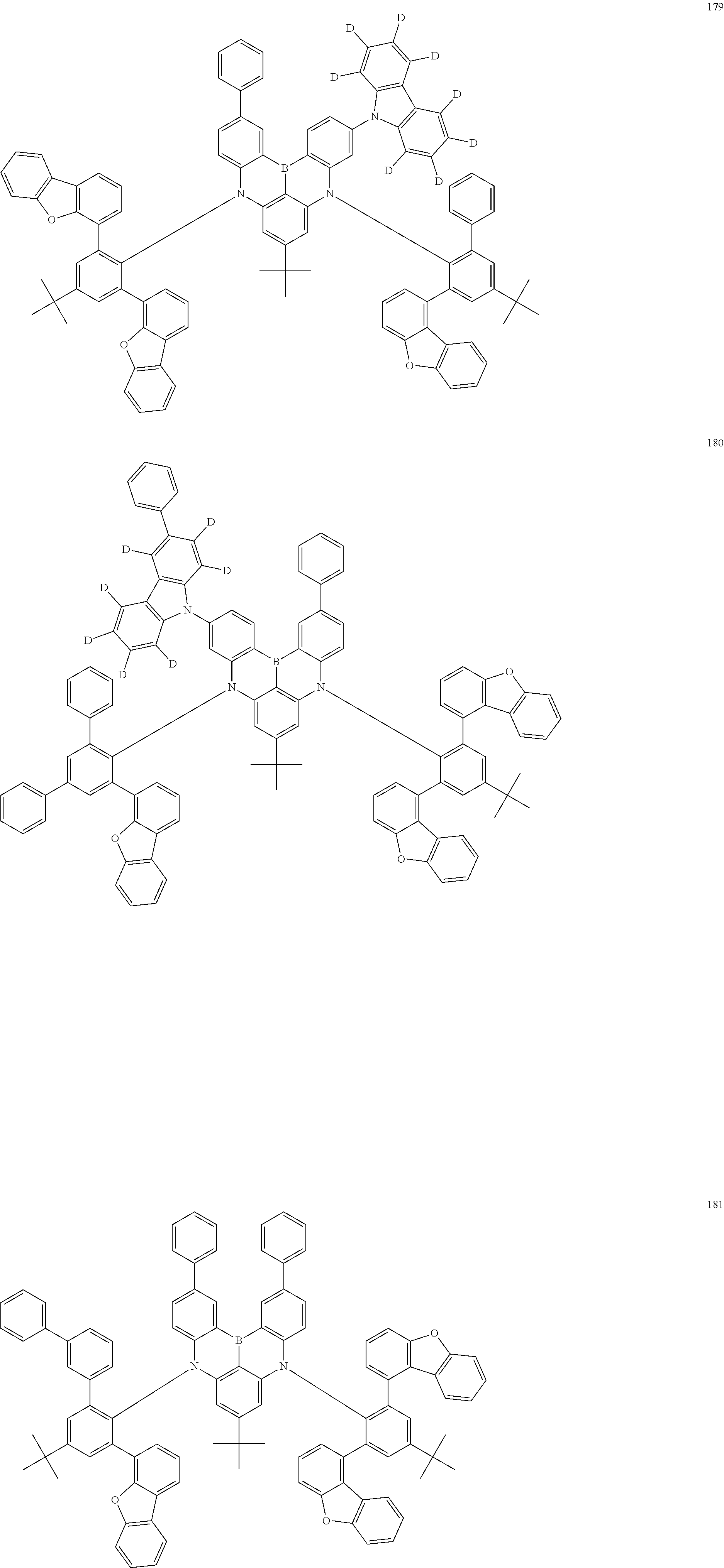 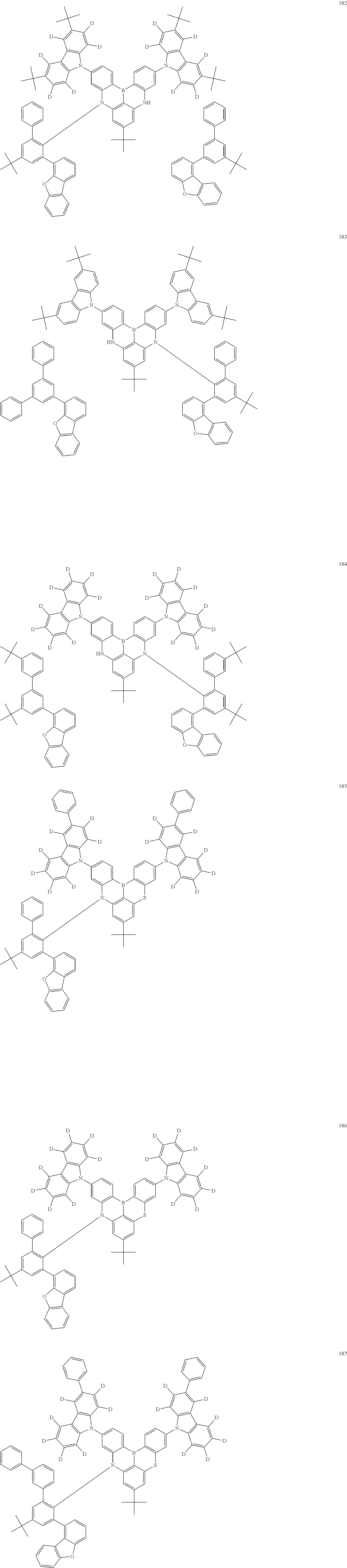 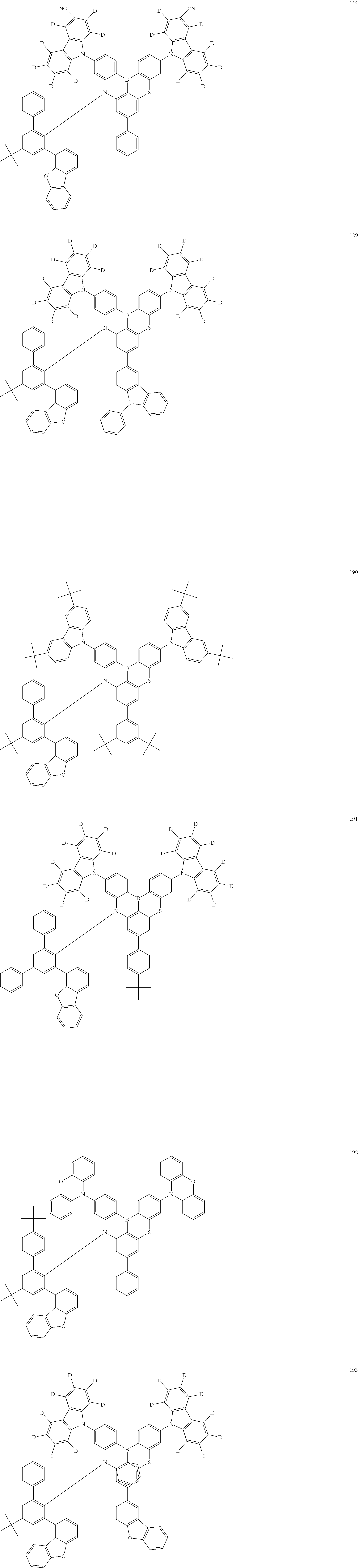 [chemical structure]
